(19) United States
(12) Patent Application Publication
(10) Pub. No.: US 2024/0260292 A1
(43) Pub. Date: Aug. 1, 2024

(54) LIGHT EMITTING ELEMENT AND POLYCYCLIC COMPOUND FOR THE SAME

(71) Applicant: Samsung Display Co., Ltd., Yongin-si (KR)

(72) Inventors: Hirokazu KUWABARA, Yokohama (JP); Keigo HOSHI, Yokohama (JP); Ryuhei FURUE, Yokohama (JP)

(73) Assignee: Samsung Display Co., Ltd., Yongin-si (KR)

(21) Appl. No.: 18/529,142

(22) Filed: Dec. 5, 2023

(30) Foreign Application Priority Data
Dec. 6, 2022 (KR) 10-2022-0169170

(51) Int. Cl. H10K 50/11; C07F 5/02; C09K 11/06; H10K 85/30; H10K 85/60

(52) U.S. Cl. CPC H10K 50/11; C07F 5/02; C09K 11/06; H10K 85/346; H10K 85/658; C07B 2200/05

(57) ABSTRACT

Embodiments provide a light emitting element that includes a first electrode, a second electrode disposed on the first electrode, and an emission layer disposed between the first electrode and the second electrode, wherein the emission layer includes a compound represented by Formula 1, thereby exhibiting long service life characteristics. Formula 1 is explained in the specification.

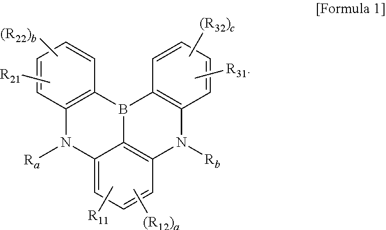

### CROSS-REFERENCE TO RELATED APPLICATION(S)

This application claims priority to and benefits of Korean Patent Application No. 10-2022-0169170 under 35 U.S.C. § 119, filed on Dec. 6, 2022, in the Korean Intellectual Property Office, the entire contents of which are incorporated herein by reference.

### BACKGROUND

### 1. Technical Field

Embodiments relate to a light emitting element and a polycyclic compound used therein.

### 2. Description of the Related Art

Active development continues for an organic electroluminescence display device as an image display device. Unlike liquid crystal display devices and the like, the organic electroluminescence display device is a so-called self-luminescent display device in which holes and electrons injected from a first electrode and a second electrode recombine in an emission layer, so that a luminescent material including an organic compound in the emission layer emits light to achieve display.

In the application of an organic electroluminescence device to a display device, there is a demand for an organic electroluminescence device having a low driving voltage, high luminous efficiency, and a long service life, and continuous development is required on materials for an organic electroluminescence device that are capable of stably achieving such characteristics.

In order to implement an organic electroluminescence device with high efficiency, technologies on phosphorescence emission which uses energy in a triplet state or on delayed fluorescence emission which uses the generating phenomenon of singlet excitons by the collision of triplet excitons (triplet-triplet annihilation, TTA) are being developed. Development is currently directed to a material for thermally activated delayed fluorescence (TADF) using delayed fluorescence phenomenon.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a light emitting element in which service life is improved.

Embodiments also provide a polycyclic compound which is a material for a light emitting element, the material improving a service life.

An embodiment provides a light emitting element which may include: a first electrode; a second electrode disposed on the first electrode; and an emission layer disposed between the first electrode and the second electrode, wherein the emission layer may include a first compound represented by Formula 1, and at least one of a second compound and a third compound:

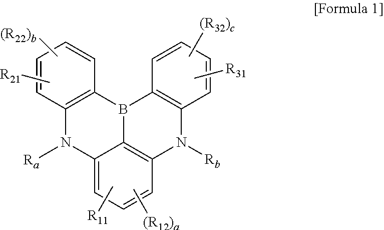

In Formula 1, a may be an integer from 0 to 2; b and c may each independently be an integer from 0 to 3; at least one of R₁₁, R₂₁, or R₃₁ may be a group represented by Formula 2; the remainder of R₁₁, R₂₁, or R₃₁ may each independently be a hydrogen atom, a deuterium atom, a halogen atom, a cyano group, a substituted or unsubstituted amine group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring; R₁₂, R₂₂, R₃₂, Rₐ, and R_{b} may each independently be a hydrogen atom, a deuterium atom, a halogen atom, a cyano group, a substituted or unsubstituted amine group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring; and at least one hydrogen atom in Formula 1 may be optionally substituted with a deuterium atom.

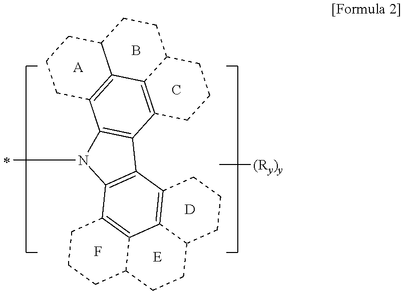

In Formula 2, at least one of A to F may each be a benzene ring; the remainder of A to F may be absent; y may be an integer from 0 to 16; R_{y} may be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; and at least one hydrogen atom in Formula 2 may be optionally substituted with a deuterium atom.

In an embodiment, the first compound may be represented by Formula 3:

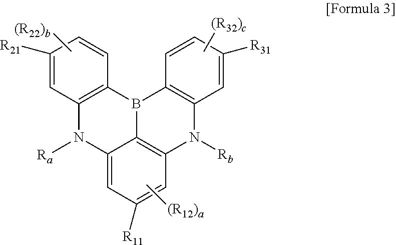

In Formula 3, a, b, c, Rₐ, R_{b}, R₁₁, R₂₁, R₃₁, R₁₂, R₂₂, and R₃₂ are the same as defined in Formula 1; and at least one hydrogen atom in Formula 3 may be optionally substituted with a deuterium atom.

In an embodiment, the first compound may be represented by Formula 4-1 or Formula 4-2:

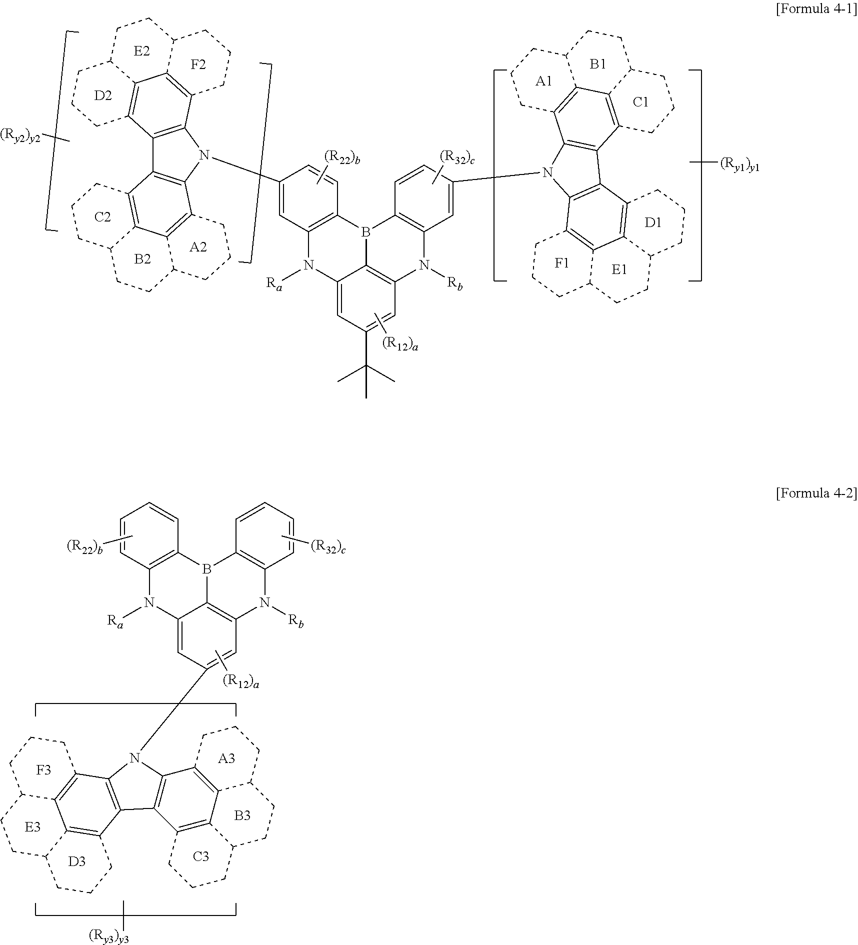

In Formula 4-1, at least one of A1 to F1 may each be a benzene ring; the remainder of A1 to F1 may be absent; at least one of A2 to F2 may each be a benzene ring; the remainder of A2 to F2 may be absent; y₁ and y₂ may each independently be an integer from 0 to 16; R_{y1} and R_{y2} may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; a, b, c, Rₐ, R_{b}, R₁₂, R₂₂, and R₃₂ are the same as defined in Formula 1; and at least one hydrogen atom in Formula 4-1 may be optionally substituted with a deuterium atom.

In Formula 4-2, at least one of A3 to F3 may each be a benzene ring; the remainder of A3 to F3 may be absent; y₃ may be an integer from 0 to 16; R_{y3} may be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; a, b, c, Rₐ, R_{b}, R₁₂, R₂₂, and R₃₂ are the same as defined in Formula 1; and at least one hydrogen atom in Formula 4-2 may be optionally substituted a with deuterium atom.

In an embodiment, the first compound may be represented by Formula 5:

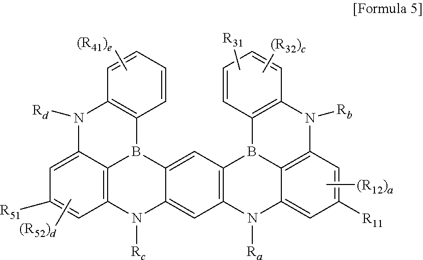

In Formula 5, R₁₁ may be a group represented by Formula 2; R₅₁ may be a group represented by Formula 2, a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; d may be an integer from 0 to 2; e may be an integer from 0 to 4; R₃₁, R₄₁, R₅₂, R_{c}, and R_{d} may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; a, c, Rₐ, R_{b}, R₁₂, and R₃₂ are the same as defined in Formula 1; and at least one hydrogen atom in Formula 5 may be optionally substituted with a deuterium atom.

In an embodiment, a group represented by Formula 2 may be represented by one of Formula 6-1 to Formula 6-14:

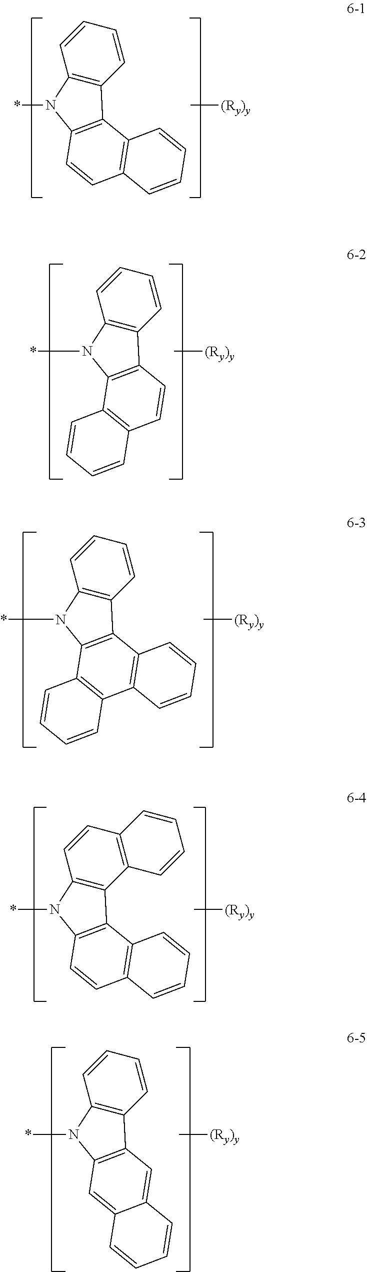

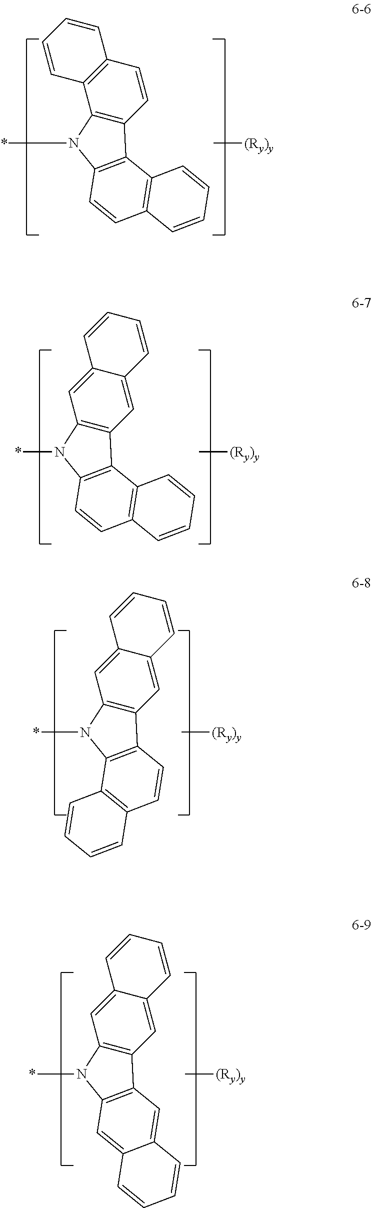

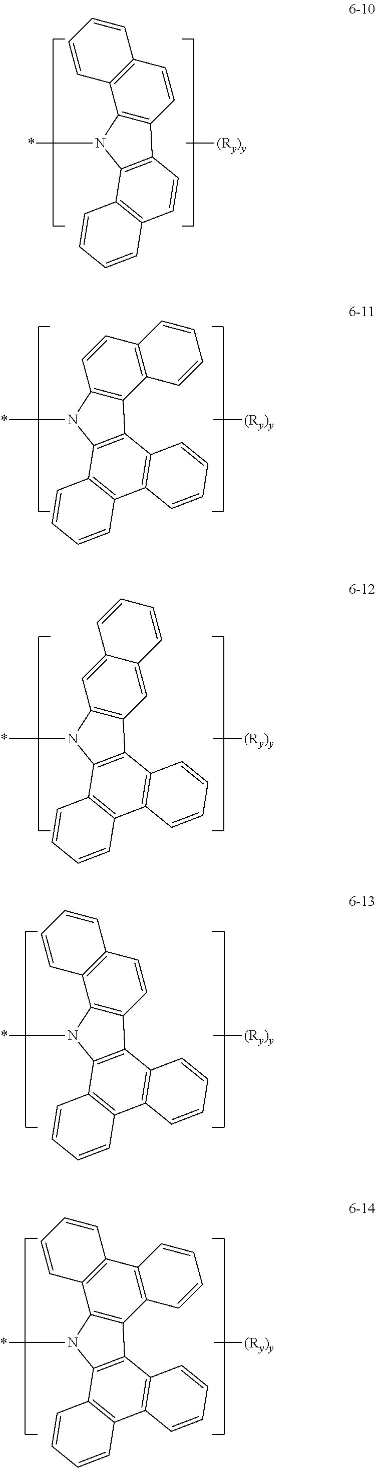

In Formula 6-1 to Formula 6-14, y and R_{y} are the same as defined in Formula 2; and at least one hydrogen atom in one of Formula 6-1 to Formula 6-14 may be optionally substituted with a deuterium atom.

In an embodiment, in Formula 2, R_{y} may be a hydrogen atom, a deuterium atom, a t-butyl group, a substituted or unsubstituted phenyl group, a substituted or unsubstituted naphthyl group, a substituted or unsubstituted phenanthryl group, or a substituted or unsubstituted propylphenyl group.

In an embodiment, the second compound may be represented by Formula HT-1:

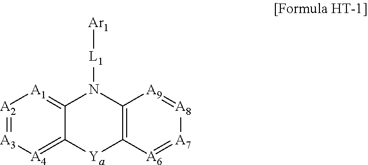

In Formula HT-1, A₁ to A₄ and A₆ to A₉ may each independently be N or C(R₄₁); L₁ may be a direct linkage, a substituted or unsubstituted arylene group having 6 to 30 ring-forming carbon atoms, or a substituted or unsubstituted heteroarylene group having 2 to 30 ring-forming carbon atoms; Yₐ may be a direct linkage, C(R₄₂)(R₄₃), or Si(R₄₄)(R₄₅); Ar₁ may be a substituted or unsubstituted aryl group having 6 to 30 ring-forming carbon atoms, or a substituted or unsubstituted heteroaryl group having 2 to 30 ring-forming carbon atoms; and R₄₁ to R₄₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms.

In an embodiment, the third compound may be represented by Formula ET-1:

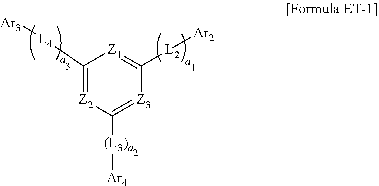

In Formula ET-1, at least one of Z₁ to Z₃ may each be N; the remainder of Z₁ to Z₃ may each independently be C(Rₐ₃); Rₐ₃ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; a₁ to a₃ may each independently be an integer from 0 to 10; L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms; and Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In an embodiment, the emission layer may further include a fourth compound, and the fourth compound may be represented by Formula D-1:

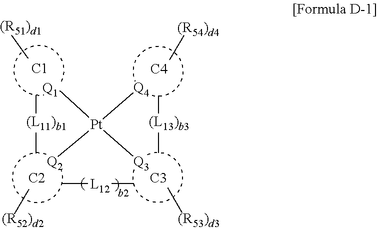

In Formula D-1, Q₁ to Q₄ may each independently be C or N; and C1 to C4 may each independently be a substituted or unsubstituted hydrocarbon ring group having 5 to 30 ring-forming carbon atoms or a substituted or unsubstituted heterocyclic group having 2 to 30 ring-forming carbon atoms; and
L₁₁ to L₁₃ may each independently be a direct linkage,

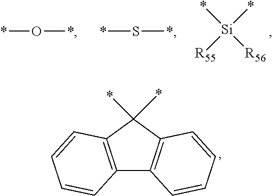

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms; in L₁₁ to L₁₃, —* represents a bond linked to one of C1 to C4; b1 to b3 may each independently be 0 or 1; R₅₁ to R₅₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring; and d1 to d4 may each independently be an integer from 0 to 4.

In an embodiment, the emission layer may include the first compound, the second compound, the third compound, and the fourth compound.

In an embodiment, the emission layer may emit blue light.

In an embodiment, the emission layer may emit thermally activated delayed fluorescence.

In an embodiment, the emission layer may include at least one compound selected from Compound Group 1, which is described below.

An embodiment provides a polycyclic compound which may be represented by Formula 1:

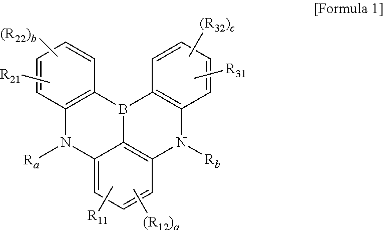

In Formula 1, a may be an integer from 0 to 2; b and c may each independently be an integer from 0 to 3; at least one of R₁₁, R₂₁, or R₃₁ may be a group represented by Formula 2; the remainder of R₁₁, R₂₁, and R₃₁ may each independently be a hydrogen atom, a deuterium atom, a halogen atom, a cyano group, a substituted or unsubstituted amine group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring; R₁₂, R₂₂, R₃₂, Rₐ, and R_{b} may each independently be a hydrogen atom, a deuterium atom, a halogen atom, a cyano group, a substituted or unsubstituted amine group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring; and at least one hydrogen atom in Formula 1 may be optionally substituted with a deuterium atom.

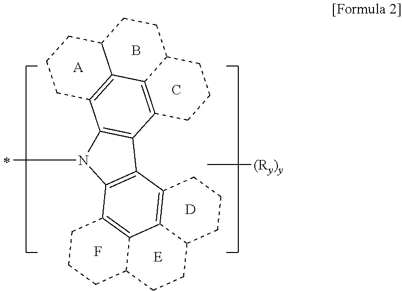

In Formula 2, at least one of A to F may each be a benzene ring; the remainder of A to F may be absent; y may be an integer from 0 to 16; R_{y} may be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; and at least one hydrogen atom in Formula 2 may be optionally substituted with a deuterium atom.

In an embodiment, Formula 1 may be represented by Formula 3:

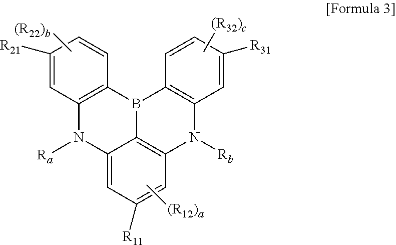

In Formula 3,

a, b, c, Rₐ, R_{b}, R₁₁, R₁₂, R₂₁, R₂₂, R₃₁, and R₃₂ are the same as defined in Formula 1; and at least one hydrogen atom in Formula 3 may be optionally substituted with a deuterium atom.

In an embodiment, Formula 3 may be represented by Formula 4-1 or Formula 4-2:

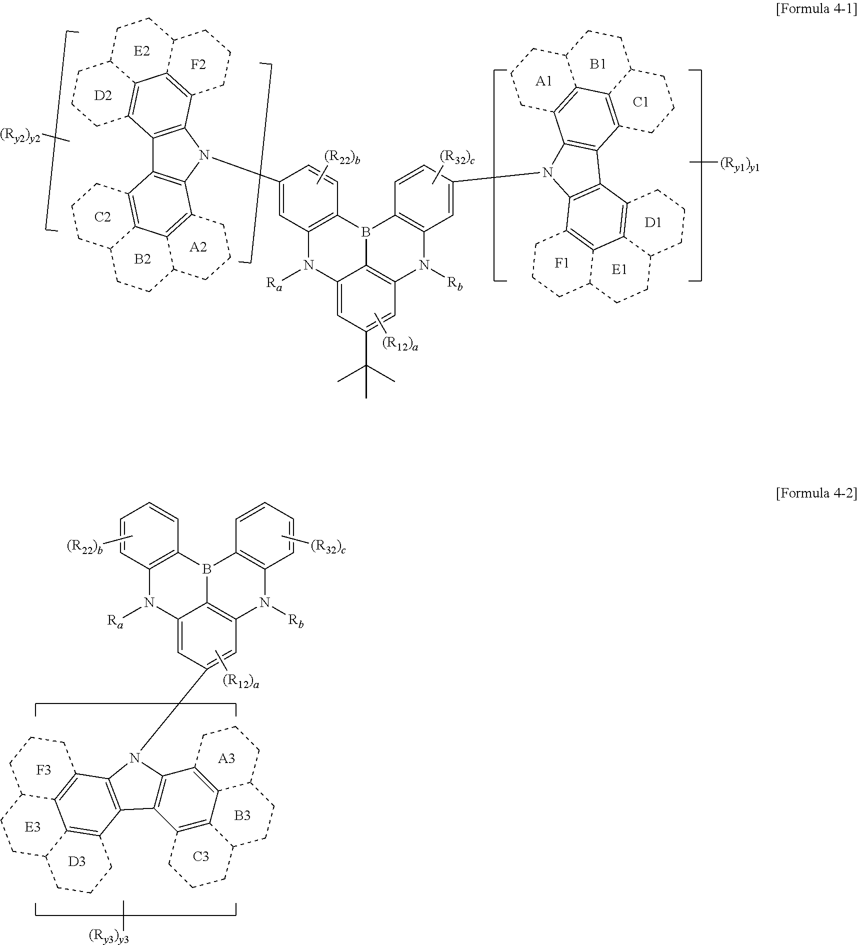

In Formula 4-1, at least one of A1 to F1 may each be a benzene ring; the remainder of A1 to F1 may be absent; at least one of A2 to F2 may each be a benzene ring; the remainder of A2 to F2 may be absent; y₁ and y₂ may each independently be an integer from 0 to 16; R_{y1} and R_{y2} may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; a, b, c, Rₐ, R_{b}, R₁₂, R₂₂, and R₃₂ are the same as defined in Formula 1; and at least one hydrogen atom in Formula 4-1 may be optionally substituted with a deuterium atom; and

in Formula 4-2, at least one of A3 to F3 may each be a benzene ring; the remainder of A3 to F3 may be absent; y₃ may be an integer from 0 to 16; R_{y3} may be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; a, b, c, Rₐ, R_{b}, R₁₂, R₂₂, and R₃₂ are the same as defined in Formula 1; and at least one hydrogen atom in Formula 4-2 may be optionally substituted with a deuterium atom.

In an embodiment, Formula 1 may be represented by Formula 5:

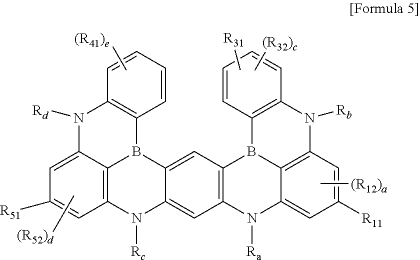

In Formula 5, R₁₁ may be a group represented by Formula 2; R₅₁ may be a group represented by Formula 2, a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; d may be an integer from 0 to 2; e may be an integer from 0 to 4; R₃₁, R₄₁, R₅₂, R_{c}, and R_{d} may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; a, c, Rₐ, R_{b}, R₁₂, and R₃₂ are the same as defined in Formula 1; and at least one hydrogen atom in Formula 5 may be optionally substituted with a deuterium atom.

In an embodiment, a group represented by Formula 2 may be represented by one of Formula 6-1 to Formula 6-14:

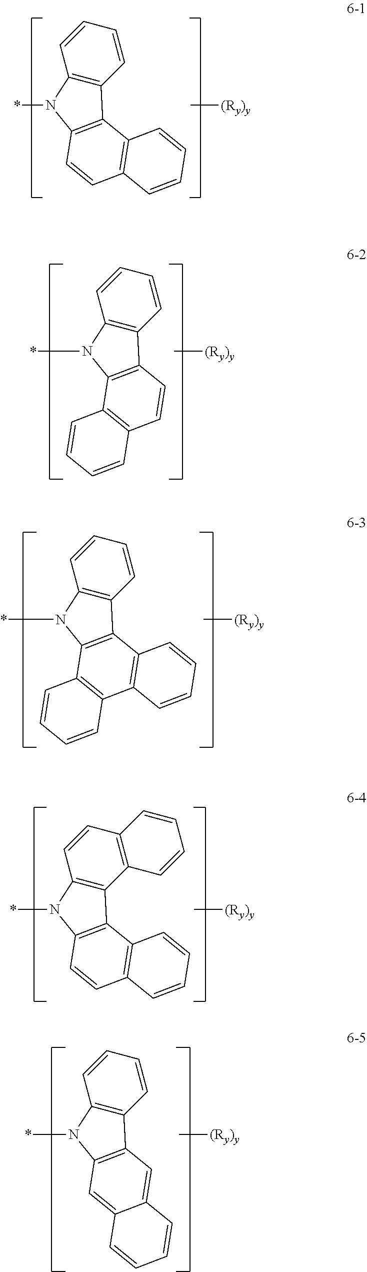

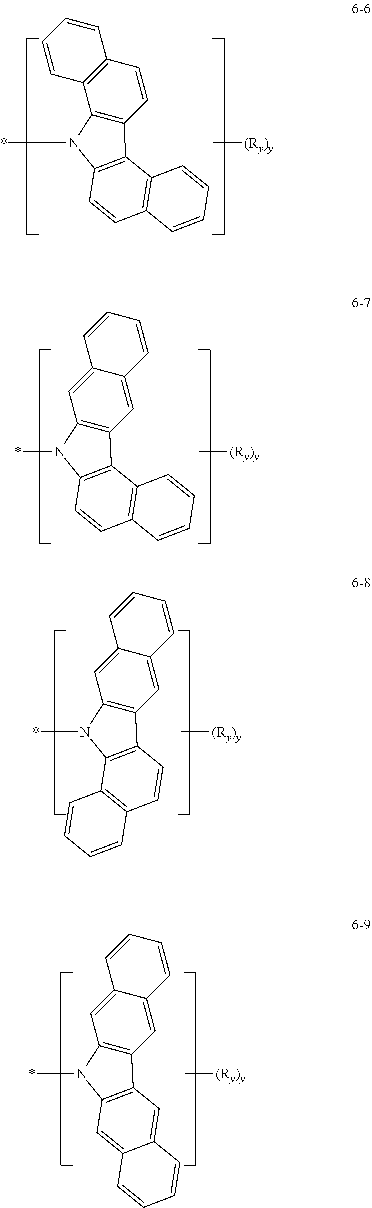

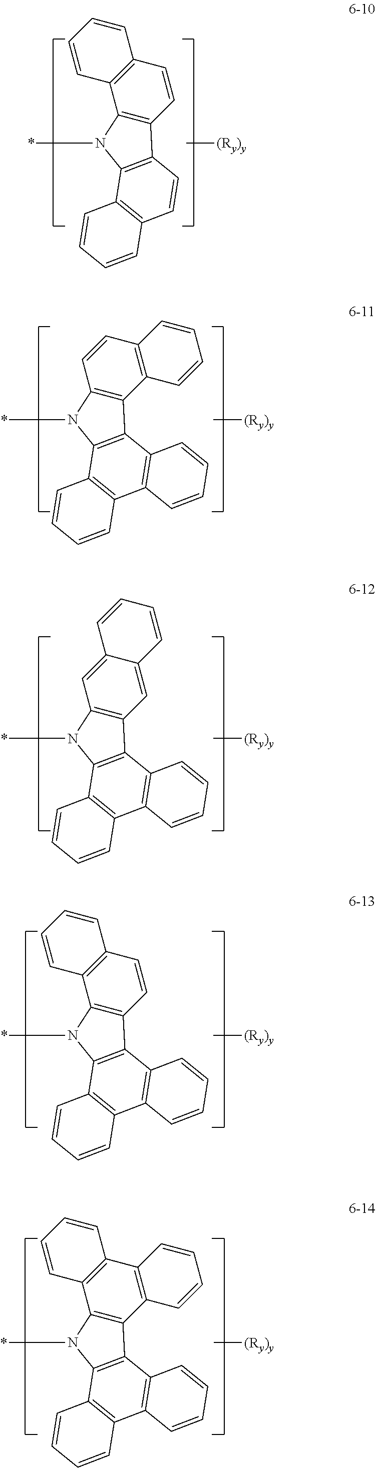

In Formula 6-1 to Formula 6-14, y and R_{y} are the same as defined in Formula 2; and at least one hydrogen atom in one of Formula 6-1 to Formula 6-14 may be optionally substituted with a deuterium atom.

In an embodiment, in Formula 2, R_{y} may be a hydrogen atom, a deuterium atom, a t-butyl group, a substituted or unsubstituted phenyl group, a substituted or unsubstituted naphthyl group, a substituted or unsubstituted phenanthryl group, or a substituted or unsubstituted propylphenyl group.

In an embodiment, the polycyclic compound represented by Formula 1 may be selected from Compound Group 1, which is described below.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display device according to an embodiment;

FIG. 2 is a schematic cross-sectional view of a display device according to an embodiment;

FIG. 3 is a schematic cross-sectional view of a light emitting element according to an embodiment;

FIG. 4 is a schematic cross-sectional view of a light emitting element according to an embodiment;

FIG. 5 is a schematic cross-sectional view of a light emitting element according to an embodiment;

FIG. 6 is a schematic cross-sectional view of a light emitting element according to an embodiment;

FIG. 7 and FIG. 8 are each a schematic cross-sectional view of a display device according to an embodiment;

FIG. 9 is a schematic cross-sectional view of a display device according to an embodiment;

FIG. 10 is a schematic cross-sectional view of display device according to an embodiment; and

FIG. 11 is a schematic perspective view of an electronic device including display devices according to embodiments.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for case of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group or it may be interpreted as a phenyl group substituted with a phenyl group.

In the specification, the term “bonded to an adjacent group to form a ring” may be interpreted as a group that is bonded to an adjacent group to form a substituted or unsubstituted hydrocarbon ring or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, or an iodine atom.

In the specification, an alkyl group may be a linear, branched, or cyclic type. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbon atoms in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group including at least one carbon-carbon double bond in the middle or a terminus of an alkyl group having 2 or more carbon atoms. An alkenyl group may be linear or branched. The number of carbon atoms in an alkenyl group is not particularly limited, but may be 2 to 30, 2 to 20, or 2 to 10. Examples of an alkenyl group may include a vinyl group, a 1-butenyl group, a 1-pentenyl group, a 1,3-butadienyl group, a styrenyl group, a styryl vinyl group, etc., but embodiments are not limited thereto.

In the specification, an alkynyl group may be a hydrocarbon group including at least one carbon-carbon triple bond in the middle or a terminus of an alkyl group having 2 or more carbon atoms. An alkynyl group may be linear or branched. Although the number of carbon atoms is not particularly limited, it may be 2 to 30, 2 to 20, or 2 to 10. Examples of an alkynyl group may include an ethynyl group, a propynyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in the aryl group may be 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but the embodiment of the inventive concept is not limited thereto.

In the specification, a fluorenyl group may be substituted, and two substituents may be bonded to each other to form a spiro structure. Examples of a substituted fluorenyl group are as follows. However, embodiments are not limited thereto.

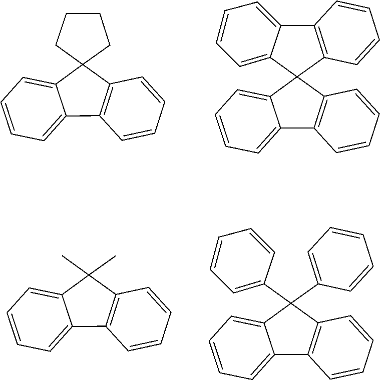

In the specification, a heterocyclic group may be any functional group or substituent derived from a ring containing at least one of B, O, N, P, Si, Se or S as a heteroatom. A heterocyclic group may be an aliphatic heterocyclic group and an aromatic heterocyclic group. An aromatic heterocyclic group may be a heteroaryl group. An aliphatic heterocycle and an aromatic heterocycle may each independently be monocyclic or polycyclic.

In the specification, a heterocyclic group may contain at least one of B, O, N, P, Si, Se or S as a heteroatom. If a heterocyclic group contains two or more heteroatoms, the two or more heteroatoms may be the same as or different from each other. A heterocyclic group may be a monocyclic or polycyclic, and includes a heteroaryl group. The number of ring-forming carbon atoms in the heterocyclic group may be 2 to 30, 2 to 20, or 2 to 10.

In the specification, an aliphatic heterocyclic group may include at least one of B, O, N, P, Si, Se or S as a heteroatom. The number of ring-forming carbon atoms in an aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

In the specification, a heteroaryl group may include at least one of B, O, N, P, Si, or S as a heteroatom. If a heteroaryl group includes two or more heteroatoms, the two or more heteroatoms may be the same as or different from each other. A heteroaryl group may be monocyclic or a polycyclic. The number of ring-forming carbon atoms in a heteroaryl group may be 2 to 60, 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in an amino group is not particularly limited, but may be 1 to 30. An amino group may be an alkyl amino group, an aryl amino group, or a heteroaryl amino group. Examples of an amino group may include a methylamino group, a dimethylamino group, a phenylamino group, a diphenylamino group, a naphthylamino group, a 9-methyl-anthracenylamino group, etc., but embodiments are not limited thereto.

In the specification, the number of carbon atoms in a carbonyl group is not particularly limited, but may be 1 to 40, 1 to 30, or 1 to 20. For example, a carbonyl group may have one of the following structures, but embodiments are not limited thereto.

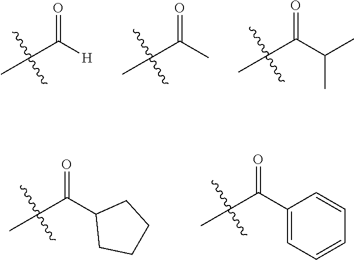

In the specification, the number of carbon atoms in a sulfinyl group or a sulfonyl group is not particularly limited, but may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments are not limited thereto.

In the specification, an oxy group may be an oxygen atom that is bonded to an alkyl group or an aryl group as defined above. An oxy group may be an alkoxy group or an aryl oxy group. An alkoxy group may be linear, branched, or cyclic. The number of carbon atoms in an alkoxy group is not particularly limited, but may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or an aryl group as defined above. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, an alkenyl group may be linear or branched. The number of carbon atoms in an alkenyl group is not particularly limited, but may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, the number of carbon atoms in an amine group is not particularly limited, but may be 1 to 30. The amine group may be an alkyl amine group or an aryl amine group. Examples of the amine group may include a methylamine group, a dimethylamine group, a phenylamine group, a diphenylamine group, a naphthylamine group, a 9-methyl-anthracenylamine group, a triphenylamine group, etc., but embodiments are not limited thereto.

In the specification, an alkyl group in an alkylthio group, an alkylsulfoxy group, an alkylaryl group, an alkylamino group, an alkyl boron group, an alkyl silyl group, or an alkyl amine group may be the same as an example of the alkyl group described above.

In the specification, an aryl group in an aryloxy group, an arylthio group, an arylsulfoxy group, an arylamino group, an arylboron group, an arylsilyl group, or an arylamine group may be the same as an example of the aryl group described above.

In the specification, a direct linkage may be a single bond.

In the specification, the symbols

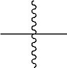

and —* each represent a bonding site to a neighboring atom in a corresponding formula or moiety.

Hereinafter, embodiments will be described with reference to the accompanying drawings.

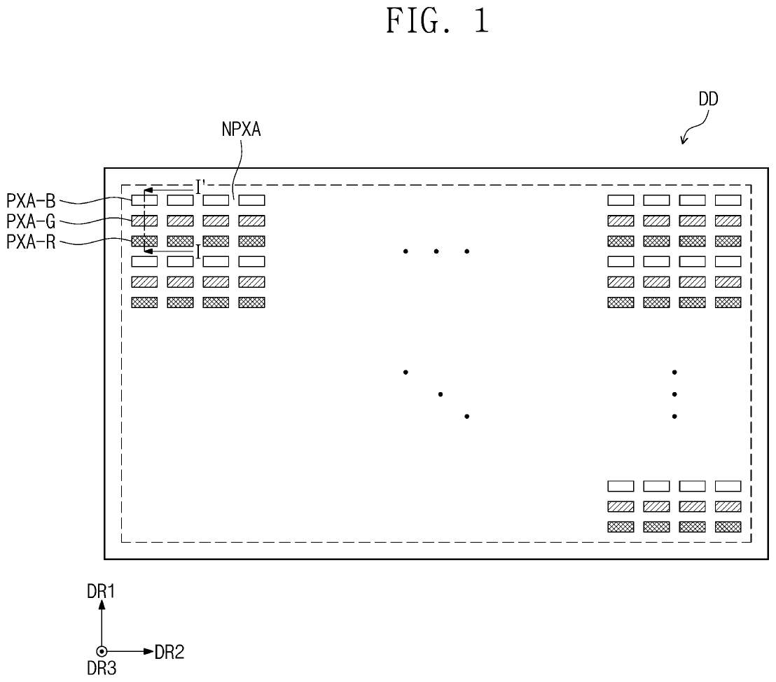

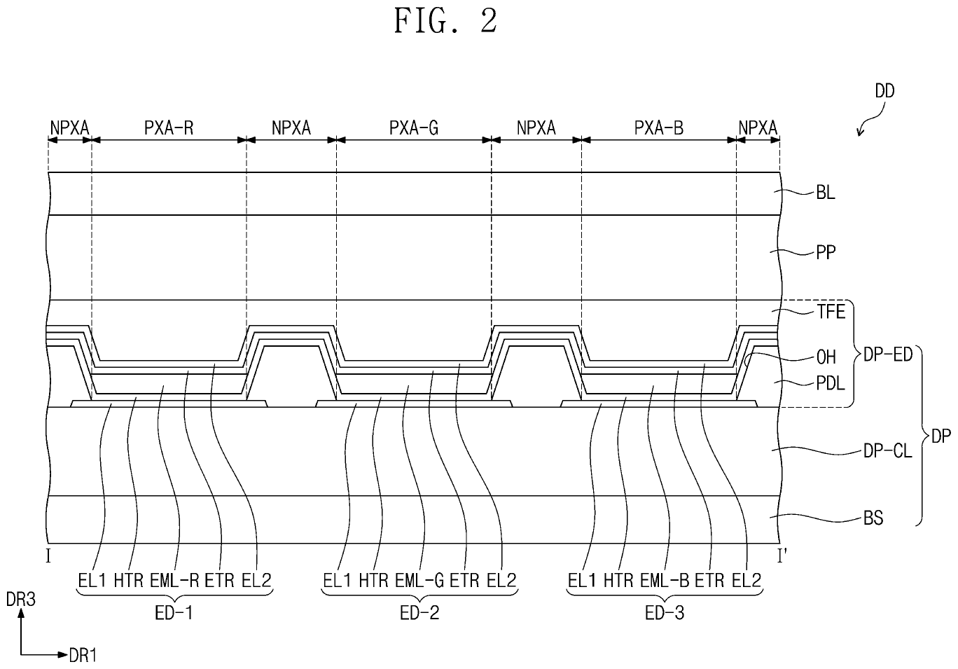

FIG. 1 is a schematic plan view illustrating an embodiment of a display device DD. FIG. 2 is a schematic cross-sectional view of the display device DD according to an embodiment. FIG. 2 is a schematic cross-sectional view illustrating a part taken along line I-I′ of FIG. 1.

The display device DD may include a display panel DP and an optical layer PP disposed on the display panel DP. The display panel DP includes light emitting elements ED-1, ED-2, and ED-3. The display device DD may include light emitting elements ED-1, ED-2, and ED-3. The optical layer PP may be disposed on the display panel DP to control light reflected at the display panel DP from an external light. The optical layer PP may include, for example, a polarization layer or a color filter layer. Although not shown in the drawing, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display element layer DP-ED and the base substrate BL. The filling layer (not shown) may be an organic material layer. The filling layer (not shown) may include at least one of an acrylic-based resin, a silicone-based resin, or an epoxy-based resin.

The display panel DP may include a base layer BS, a circuit layer DP-CL provided on the base layer BS, and the display element layer DP-ED. The display element layer DP-ED may include a pixel defining film PDL, the light emitting elements ED-1, ED-2, and ED-3 disposed between portions of the pixel defining film PDL, and an encapsulation layer TFE disposed on the light emitting elements ED-1, ED-2, and ED-3.

The base layer BS may provide a base surface on which the display element layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). Each of the transistors (not shown) may include a control electrode, an input electrode, and an output electrode. For example, the circuit layer DP-CL may include a switching transistor and a driving transistor for driving the light emitting elements ED-1, ED-2, and ED-3 of the display element layer DP-ED.

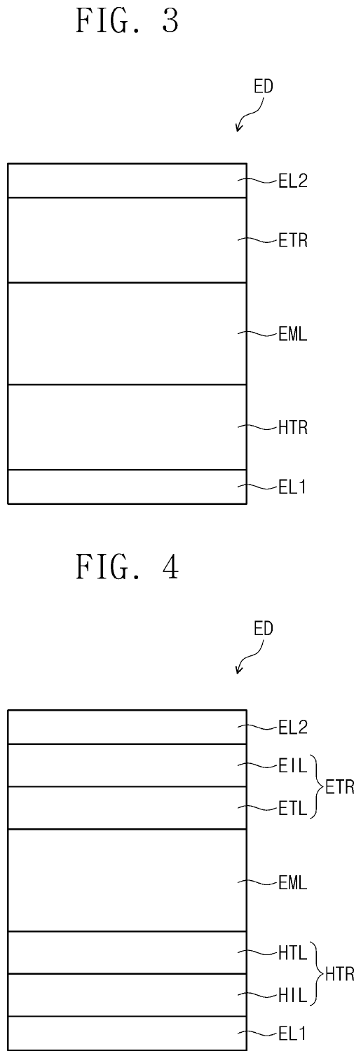

Each of the light emitting elements ED-1, ED-2, and ED-3 may have a structure of a light emitting element ED according to an embodiment in one of FIGS. 3 to 6, which will be described later. Each of the light emitting elements ED-1, ED-2, and ED-3 may include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light emitting elements ED-1, ED-2, and ED-3 are disposed in openings OH defined in the pixel defining film PDL, and the hole transport region HTR, the electron transport region ETR, and the second electrode EL2 are each provided as a common layer for all of the light emitting elements ED-1, ED-2, and ED-3. However, the embodiments are not limited thereto. Although not shown in FIG. 2, the hole transport region HTR and the electron transport region ETR in an embodiment may each be provided by being patterned inside the openings OH defined in the pixel defining film PDL. For example, in an embodiment, the hole transport region HTR, the emission layers EML-R, EML-G, and EML-B, and the electron transport region ETR of the light emitting elements ED-1, ED-2, and ED-3 may be provided by being patterned by an inkjet printing method.

The encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be formed by laminating a single layer or multiple layers. The encapsulation layer TFE may include at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film may protect the display element layer DP-ED from moisture and/or oxygen, and the encapsulation-organic film may protect the display element layer DP-ED from foreign substances such as dust particles. The encapsulation-inorganic film may include silicon nitride, silicon oxynitride, silicon oxide, titanium oxide, aluminum oxide, or the like, but embodiments are not particularly limited thereto. The encapsulation-organic film may include an acrylic-based compound, an epoxy-based compound, or the like. The encapsulation-organic film may include a photopolymerizable organic material, but embodiments are not particularly limited thereto.

The encapsulation layer TFE may be disposed on the second electrode EL2 and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region in which light generated by the respective light emitting elements ED-1, ED-2, and ED-3 is emitted. The light emitting regions PXA-R, PXA-G, and PXA-B may be spaced apart from each other in a plan view.

The light emitting regions PXA-R, PXA-G, and PXA-B may each be a region separated by the pixel defining film PDL. The non-light emitting regions NPXA may be areas between the adjacent light emitting areas PXA-R, PXA-G, and PXA-B, which correspond to the pixel defining film PDL. In an embodiment, the light emitting regions PXA-R, PXA-G, and PXA-B may each correspond to a pixel. The pixel defining film PDL may separate the light emitting elements ED-1, ED-2, and ED-3. The emission layers EML-R, EML-G, and EML-B of the light emitting elements ED-1, ED-2, and ED-3 may be disposed in openings OH defined in the pixel defining film PDL and separated from each other.

The light emitting regions PXA-R, PXA-G, and PXA-B may be arranged into groups according to the color of light generated from the light emitting elements ED-1, ED-2, and ED-3. In the display device DD according to an embodiment illustrated in FIGS. 1 and 2, three light emitting regions PXA-R, PXA-G, and PXA-B, which emit red light, green light, and blue light, respectively, are illustrated. For example, the display device DD according to an embodiment may include the red light emitting region PXA-R, the green light emitting region PXA-G, and the blue light emitting region PXA-B that are separated from each other.

In the display device DD according to an embodiment, the light emitting elements ED-1, ED-2 and ED-3 may emit light having wavelengths different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, embodiments are not limited thereto, and the first to third light emitting elements ED-1, ED-2, and ED-3 may emit light in a same wavelength range or at least one light emitting element may emit a light in a wavelength range different from the others. For example, the first to third light emitting elements ED-1, ED-2, and ED-3 may all emit blue light.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B may each be arranged along a second directional axis DR2. The red light emitting region PXA-R, the green light emitting region PXA-G, and the blue light emitting region PXA-B may be alternately arranged in this order along a first directional axis DR1.

FIGS. 1 and 2 illustrate that the light emitting regions PXA-R, PXA-G, and PXA-B are shown as having a similar area to each other, but embodiments are not limited thereto. Thus, the light emitting regions PXA-R, PXA-G, and PXA-B may have different areas from each other according to a wavelength range of the emitted light. The areas of the light emitting regions PXA-R, PXA-G, and PXA-B may be areas in a plan view that are defined by the first directional axis DR1 and the second directional axis DR2. A third directional axis DR3 may be perpendicular to a plane defined by the first directional axis DR1 and the second directional axis DR2.

An arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations according to the display quality characteristics which are required in the display device DD. For example, the arrangement configuration of the light emitting regions PXA-R, PXA-G, and PXA-B may be a pentile configuration (such as PENTILE®) or a diamond configuration (such as Diamond Pixel®).

In an embodiment, the areas of the light emitting regions PXA-R, PXA-G, and PXA-B may be different in size from each other. For example, in an embodiment, an area of the green light emitting region PXA-G may be smaller than that of the blue light emitting region PXA-B, but embodiments are not limited thereto.

Hereinafter, FIGS. 3 to 6 are schematic cross-sectional views illustrating light emitting elements according to embodiments. Each of the light emitting elements ED according to embodiments may include a first electrode EL1, a hole transport region HTR, an emission layer EML, an electron transport region ETR, and a second electrode EL2 that are stacked.

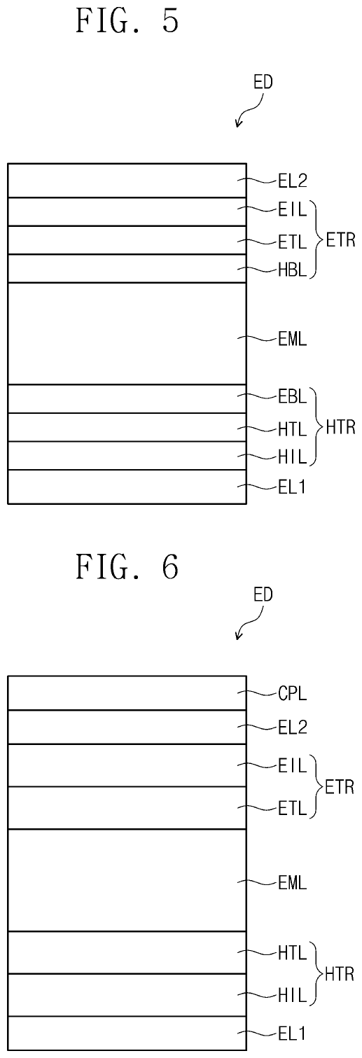

In comparison with FIG. 3, FIG. 4 illustrates a schematic cross-sectional view of a light emitting element ED according to an embodiment, in which a hole transport region HTR includes a hole injection layer HIL and a hole transport layer HTL, and an electron transport region ETR includes an electron injection layer EIL and an electron transport layer ETL. In comparison with FIG. 3, FIG. 5 illustrates a schematic cross-sectional view of a light emitting element ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison with FIG. 4, FIG. 6 illustrates a schematic cross-sectional view of a light emitting element ED according to an embodiment including a capping layer CPL disposed on a second electrode EL2.

The first electrode EL1 has conductivity. The first electrode EL1 may be formed of a metal material, a metal alloy, or a conductive compound. The first electrode EL1 may be an anode or a cathode. However, embodiments are not limited thereto. The first electrode EL1 may be a pixel electrode. The first electrode EL1 may be a transmissive electrode, a transflective electrode, or a reflective electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, and Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). For example, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but embodiments are not limited thereto. In an embodiment, the first electrode EL1 may include the above-described metal materials, combinations of at least two metal materials of the above-described metal materials, oxides of the above-described metal materials, or the like. A thickness of the first electrode EL1 may be in a range of about 700 Å to about 10,000 Å. For example, a thickness of the first electrode EL1 may be in a range of about 1,000 Å to about 3,000 Å.

The hole transport region HTR is provided on the first electrode EL1. The hole transport region HTR may include at least one of a hole injection layer HIL, a hole transport layer HTL, a buffer layer (not shown), an emission-auxiliary layer (not shown), or an electron blocking layer EBL. A thickness of the hole transport region HTR may be, for example, in a range of about 50 Å to about 15,000 Å.

The hole transport region HTR may be a layer consisting of a single material, a layer including different materials, or a structure including multiple layers including different materials.

In an embodiment, the hole transport region HTR may have a single layer structure of the hole injection layer HIL or the hole transport layer HTL, or may have a single layer structure formed of a hole injection material and a hole transport material. In an embodiment, the hole transport region HTR may have a single layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

The hole transport region HTR may include a compound represented by Formula H-1:

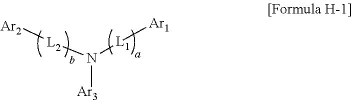

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms; and a and b may each independently be an integer from 0 to 10. When a or b is 2 or greater, multiple L₁ groups and multiple L₂ groups may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In Formula H-1, Ar₃ may be a substituted or unsubstituted aryl group having 6 to 30 ring-forming carbon atoms.

In an embodiment, the compound represented by Formula H-1 may be a monoamine compound. In an embodiment, the compound represented by Formula H-1 may be a diamine compound in which at least one of Ar₁ to Ar₃ includes the amine group as a substituent. In still another embodiment the compound represented by Formula H-1 may be a carbazole-based compound in which at least one of Ar₁ or Ar₂ includes a substituted or unsubstituted carbazole group, or a fluorene-based compound in which at least one of Ar₁ or Ar₂ includes a substituted or unsubstituted fluorene group.

In an embodiment, the compound represented by Formula H-1 may be any compound selected from Compound Group H. However, the compounds listed in Compound Group H are only examples, and the compounds represented by Formula H-1 are not limited to Compound Group H:

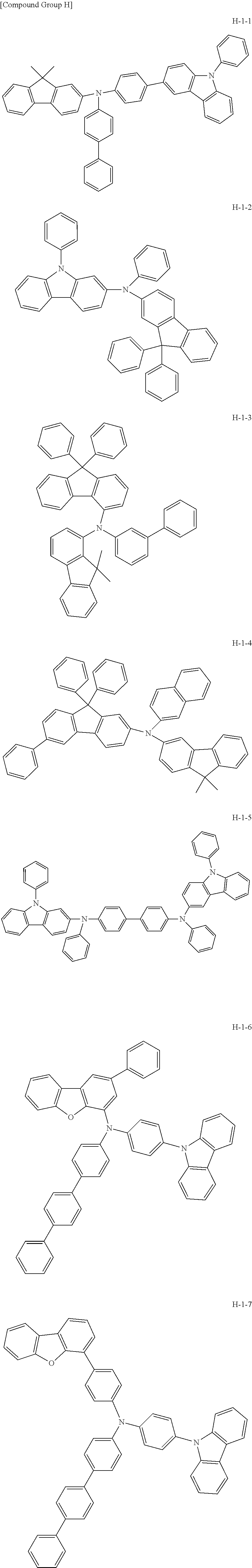

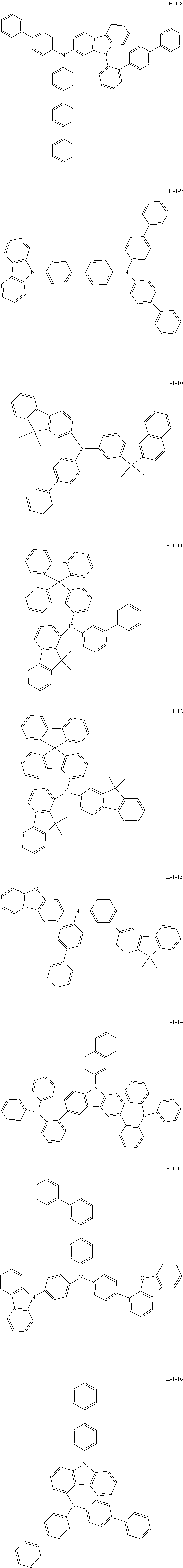

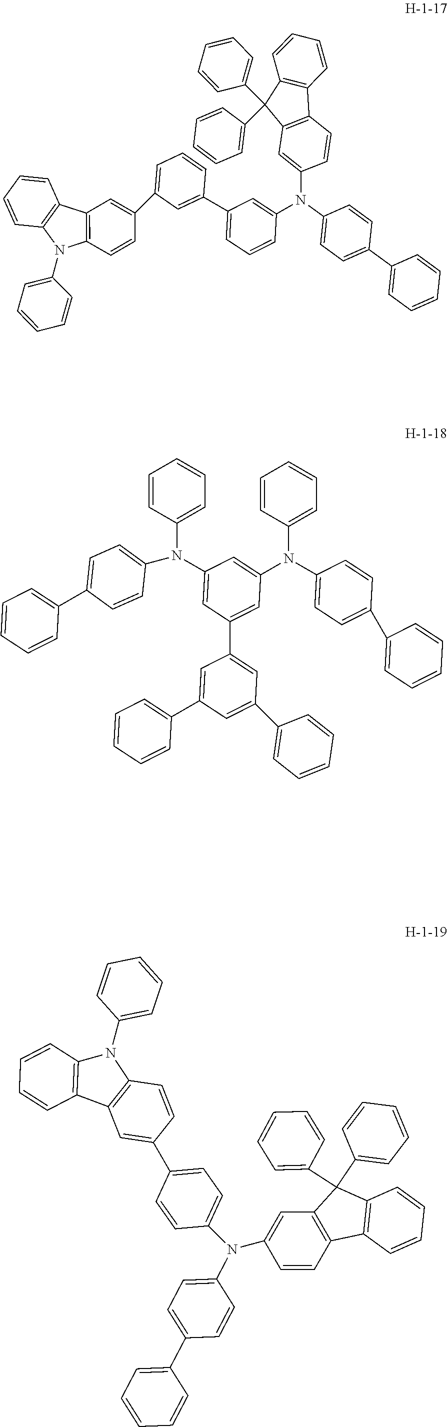 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

The hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region HTR in at least one of a hole injection layer HIL, a hole transport layer HTL, or an electron blocking layer EBL.

A thickness of the hole transport region HTR may be in a range of about 100 Å to about 10,000 Å. For example, a thickness of the hole transport region HTR may be in a range of about 100 Å to about 5,000 Å. When the hole transport region HTR includes the hole injection layer HIL, the hole injection layer HIL may have, for example, a thickness in a range of about 30 Å to about 1,000 Å. When the hole transport region HTR includes the hole transport layer HTL, the hole transport layer HTL may have a thickness in a range of about 250 Å to about 1,000 Å. When the hole transport region HTR includes the electron blocking layer EBL, the electron blocking layer EBL may have a thickness in a range of about 10 Å to about 1,000 Å. If the thicknesses of the hole transport region HTR, the hole injection layer HIL, the hole transport layer HTL and the electron blocking layer EBL satisfy the above-described ranges, satisfactory hole transport properties may be achieved without a substantial increase in driving voltage.

The hole transport region HTR may further include a charge generating material to increase conductivity in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments are not limited thereto. For example, the p-dopant may include a metal halide compound such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h] quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown) or an electron blocking layer EBL, in addition to the hole injection layer HIL and the hole transport layer HTL. The buffer layer (not shown) may compensate for a resonance distance according to a wavelength of light emitted from the emission layer EML and may thus increase light emission efficiency. A material that may be included in the hole transport region HTR may be used as a material to be included in the buffer layer (not shown). The electron blocking layer EBL may prevent electron injection from an electron transport region ETR to the hole transport region HTR.

The emission layer EML may be provided on the hole transport region HTR. The emission layer EML may have a thickness in a range of about 100 Å to about 1,000 Å. For example, the emission layer EML may have a thickness in a range of about 100 Å to about 300 Å. The emission layer EML may be a layer consisting of a single material, a layer including different materials, or a structure including multiple layers including different materials.

In an embodiment, the emission layer EML may include the polycyclic compound. The polycyclic compound according to an embodiment may be a dopant material. In the specification, the polycyclic compound according to an embodiment may be referred to as a first compound.

The polycyclic compound according to an embodiment may include a structure in which aromatic rings are fused via a boron atom and two nitrogen atoms. For example, the polycyclic compound according to an embodiment may include three aromatic rings which are fused via a boron atom and two nitrogen atoms. In the specification, the structure in which three aromatic rings are bonded via a boron atom and two nitrogen atoms may be referred as a “core.” The “core” may be a structure in which three aromatic rings are bonded via a boron atom and two nitrogen atoms and may have a structure of

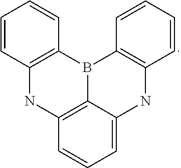 [SMILES: c1ccc2c(c1)Nc1cccc3c1B2c1ccccc1N3]

The polycyclic compound according to another embodiment may be a structure in which aromatic rings are fused via two boron atoms and four nitrogen atoms. For example, the polycyclic compound may include five aromatic rings which are bonded via two boron atoms and four nitrogen atoms. In the specification, the structure in which five aromatic rings are bonded via two boron atoms and four nitrogen atoms may be referred as a “core.” The “core,” the structure in which five aromatic rings are bonded via two boron atoms and four nitrogen atoms may have a structure of

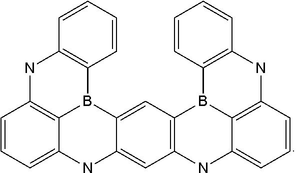 [SMILES: c1ccc2c(c1)Nc1cccc3c1B2c1cc2c(cc1N3)Nc1cccc3c1B2c1ccccc1N3]

The polycyclic compound may have a structure in which at least one carbazole group, to which at least one benzene ring is fused, is substituted in the core. The carbazole group in which at least one benzene ring is fused may improve the stability of the core. The polycyclic compound of an embodiment has a structure with improved stability of the core, and thus may contribute to the improvement in a service life of the light emitting element ED. The light emitting element ED of an embodiment may include the polycyclic compound of an embodiment, which has improved stability, in the emission layer EML, thereby exhibiting long service life characteristics.

The polycyclic compound of an embodiment may be represented by Formula 1:

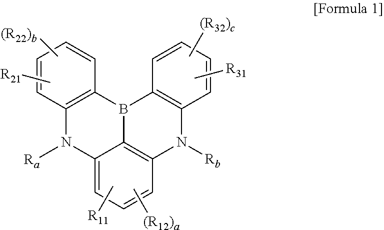

In Formula 1, a may be an integer from 0 to 2. In Formula 1, a may indicate the number of R₁₂ groups. For example, the case where a is 0, no R₁₂ groups are included as a substituent, and the case where a is 1, one R₁₂ is included as a substituent. The case where a is 0 may be the same as the case where a is 2 and all R₁₂ groups are hydrogen atoms. When a is 2, two R₁₂ groups may be the same as or different from each other.

In Formula 1, b and c may each independently be an integer from 0 to 3. In Formula 1, b may indicate the number of R₂₂ groups. For example, the case where b is 0, no R₂₂ groups are included as a substituent, and the case where b is 1, one R₂₂ group is included as a substituent. The case where b is 0 may be the same as the case where b is 3 and all R₂₂ groups are hydrogen atoms. When b is 2 or greater, multiple R₂₂ groups may all be the same or at least one group thereof may be different from the remainder. The description with respect to the relation between b and R₂₂ may be equally applied to the relation between c and R₂₃.

In Formula 1, R₁₂, R₂₂, R₃₂, Rₐ, and R_{b} may each independently be a hydrogen atom, a deuterium atom, a halogen atom, a cyano group, a substituted or unsubstituted amine group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. R₁₂, R₂₂, R₃₂, Rₐ, and R_{b} may all be the same, or at least one thereof may be different from the remainder. In Formula 1, at least one hydrogen atom in Formula 1 may be optionally substituted with a deuterium atom.

In Formula 1, at least one of R₁, R₂₁, and R₃₁ may each independently be a group represented by Formula 2; and the remainder of R₁₁, R₂₁, and R₃₁ may each independently be a hydrogen atom, a deuterium atom, a halogen atom, a cyano group, a substituted or unsubstituted amine group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, only Ru may be a group represented by Formula 2, or only R₂₁ and R₃₁ may each independently be a group represented by Formula 2. However, this is merely an example and embodiments not limited thereto.

When multiple ones of R₁, R₂₁, and R₃₁ are a group represented by Formula 2, substituents in which multiple ones of R₁, R₂₁, and R₃₁ are a group represented by Formula 2 may be the same as or different from each other. When any one of R₁₁, R₂₁, and R₃₁ is a group represented by Formula 2, the remaining two substituents, which are not a group represented by Formula 2, among R₁₁, R₂₁, and R₃₁ may be the same as or different from each other.

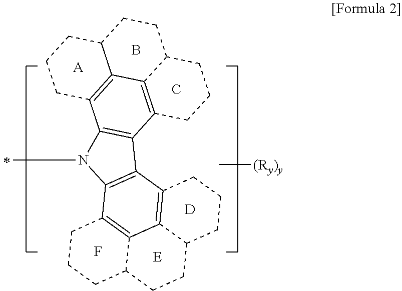

In Formula 2, “ [symbol] ” represents a bond between the nitrogen atom in Formula 2 and Formula 1.

In Formula 2, at least one of A to F may each be a benzene ring; and the remainder of A to F may be absent. For example, the group represented by Formula 2 may have a structure in which at least one benzene ring is fused at a carbazole group. The carbazole group may have improved structural stability when a benzene ring is fused with the carbazole group. The polycyclic compound of an embodiment includes a carbazole group in which a benzene ring is fused, and thus may have improved stability in the whole molecule. Thus, the light emitting element ED of an embodiment may include the polycyclic compound, in which a benzene ring is fused, in the emission layer EML, thereby exhibiting long service life characteristics.

In Formula 2, R_{y} may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R_{y} may be a hydrogen atom, a deuterium atom, a t-butyl group, a substituted or unsubstituted phenyl group, a substituted or unsubstituted naphthyl group, a substituted or unsubstituted phenanthryl group, or a substituted or unsubstituted propylphenyl group.

In Formula 2, y may be an integer from 0 to 16. In Formula 2, y may indicate the number of R_{y} groups which are substituted at the carbazole group in which a benzene ring is fused. For example, when y is 0, R_{y} may not be substituted at the carbazole group in which a benzene ring is fused, and when y is 1, one R_{y} may be substituted at the carbazole group in which a benzene ring is fused. The case where y is 0 may be the same as the case where y is 16 and all R_{y} groups are hydrogen atoms. When y 2 or greater, multiple R_{y} groups may all be the same or at least one may be different from the remainder.

In the carbazole group in which a benzene ring is fused, R_{y} may be substituted at the carbazole group or substituted at the benzene ring fused at the carbazole group. For example, when A is a benzene ring, R_{y} may be substituted at A fused at the carbazole group or substituted at the carbazole group.

In Formula 2, at least one hydrogen atom in Formula 2 may be optionally substituted with a deuterium atom.

In an embodiment, Formula 1 may be represented by Formula 3. Formula 3 represents a case where the positions, at which R₁₁, R₂₁, and R₃₁ in Formula 1 are substituted, are further defined. Each of R₁₁, R₂₁, and R₃₁ may be substituted at the para position with the boron atom in the core. For example, the carbazole group in which a benzene ring is fused may be substituted at the para position with the boron atom in the core.

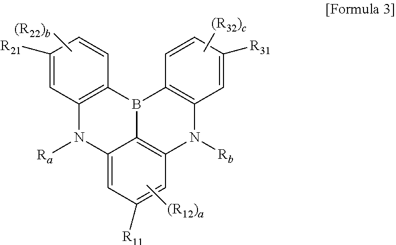

In Formula 3, a, b, c, Rₐ, R_{b}, R₁₁, R₂₁, R₃₁, R₁₂, R₂₂, and R₃₂ are the same as defined in Formula 1; and at least one hydrogen atom in Formula 3 may be optionally substituted with a deuterium atom.

In an embodiment, Formula 3 may be represented by Formula 4-1 or Formula 4-2. Formula 4-1 represents a case where in Formula 3, R₁₁ is a t-butyl group and each of R₂₁ and R₃₁ is represented by Formula 2. Formula 4-2 represents a case where in Formula 3, R₁₁ is represented by Formula 2, and each of R₂₁ and R₃₁ is a hydrogen atom.

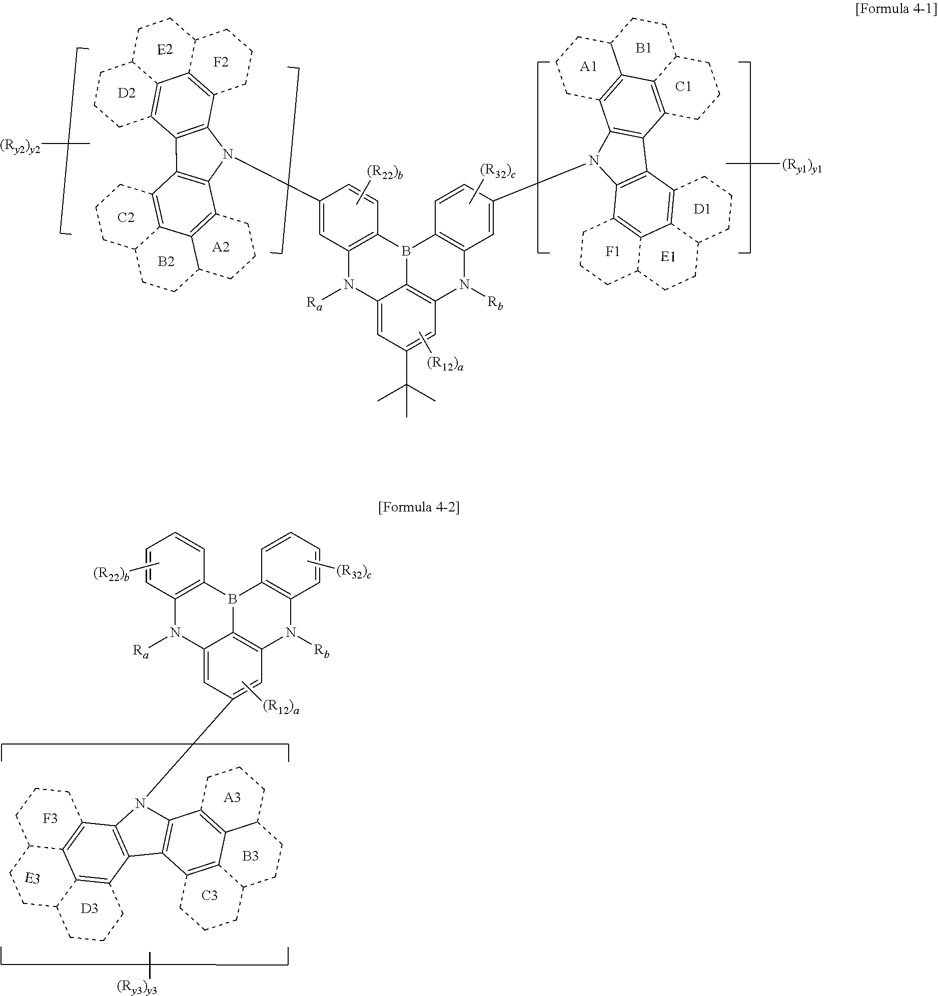

In Formula 4-1, at least one of A1 to F1 may be represented by a benzene ring; and the remainder of A1 to F1 may be absent. In Formula 4-1, at least one of A2 to F2 may be a benzene ring; and the remainder of A2 to F2 may be absent. Accordingly, Formula 4-1 may have a structure in which two carbazole groups in which a benzene ring is fused are substituted in the core.

In Formula 4-1, y₁ and y₂ may each independently be an integer from 0 to 16. In Formula 4-1, R_{y1} and R_{y2} may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula 4-1, y1 may indicate the number of R_{y1} groups which are substituted at the carbazole group in which a benzene ring is fused. For example, when y1 is 0, R_{y1} may not be substituted at the carbazole group in which a benzene ring is fused, and when y1 is 1, one R_{y1} may be substituted at the carbazole group in which a benzene ring is fused. The case where y1 is 0 may be the same as the case where y1 is 16 and R_{y1} groups are all hydrogen atoms. When y1 is 2 or greater, multiple R_{y1} groups may all be the same or at least one may be different from the others.

In Formula 4-1, y2 may indicate the number of R_{y2} groups which are substituted at the carbazole group in which a benzene ring is fused. For example, when y2 is 0, R_{y2} may not be substituted at the carbazole group in which a benzene ring is fused, and when y2 is 1, one R_{y2} may be substituted at the carbazole group in which a benzene ring is fused. The case where y2 is 0 may be the same as the case where y2 is 16 and R_{y2} groups are all hydrogen atoms. When y2 is 2 or greater, multiple R_{y2} groups may all be the same or at least one may be different from the others.

In Formula 4-1, a, b, c, Rₐ, R_{b}, R₁₂, R₂₂, and R₃₂ are the same as defined in Formula 1; and at least one hydrogen atom in Formula 4-1 may be optionally substituted with a deuterium atom.

In Formula 4-2, at least one of A3 to F3 may each be a benzene ring; and the remainder of A3 to F3 may be absent. Accordingly, Formula 4-2 may have a structure in which one carbazole group in which a benzene ring is fused is substituted in the core.

In Formula 4-2, y3 may be an integer from 0 to 16. In Formula 4-2, R_{y3} may be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula 4-2, y3 may indicate the number of R_{y3} groups which are substituted at the carbazole group in which a benzene ring is fused. For example, when y3 is 0, R_{y3} may not be substituted at the carbazole group in which a benzene ring is fused, and when y3 is 1, one R_{y3} may be substituted at the carbazole group in which a benzene ring is fused. The case where y3 is 0 may be the same as the case where y3 is 16 and R_{y3} groups are all hydrogen atoms. When y3 is 2 or greater, multiple R_{y} s groups may all be the same or at least one may be different from the others.

In Formula 4-2, a, b, c, Rₐ, R_{b}, R₁₂, R₂₂, and R₃₂ are the same as defined in Formula 1; and at least one hydrogen atom in Formula 4-2 may be optionally substituted with a deuterium atom.

In an embodiment, a group represented by Formula 2 may be represented by one of Formula 6-1 to Formula 6-14. Formula 6-1 to Formula 6-14 each represent a structure in which at least one of A1 to F1 in Formula 2 is substituted with a benzene ring.

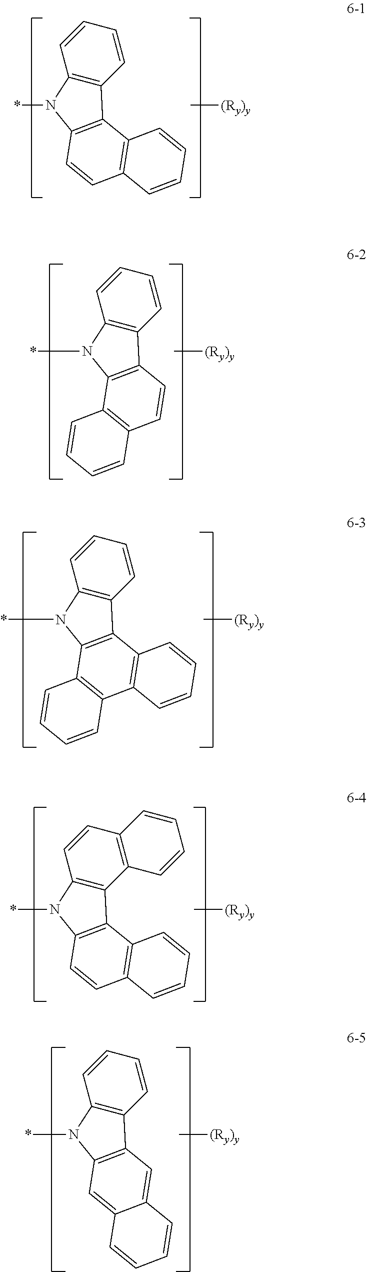

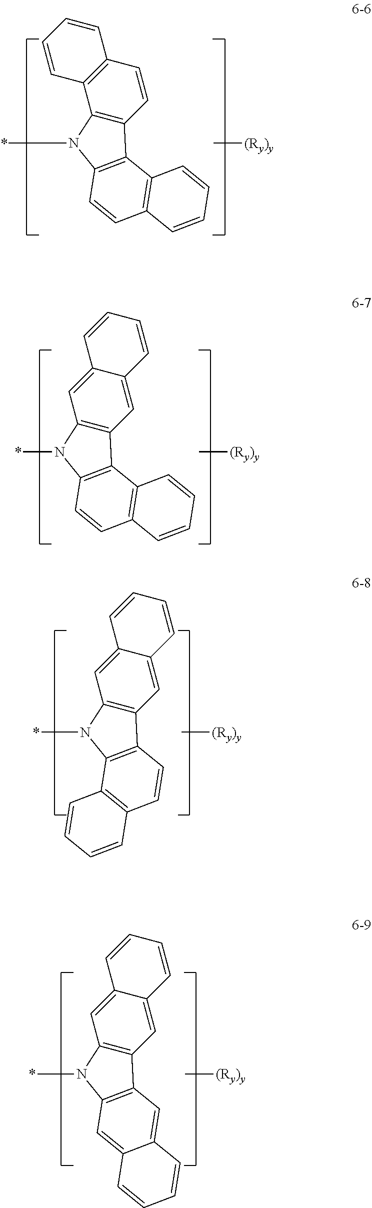

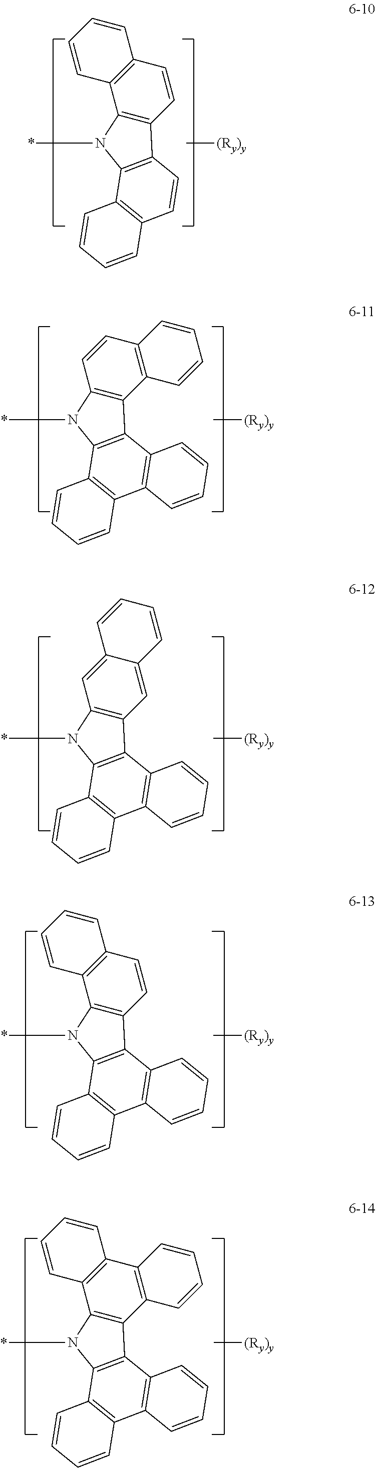

In Formula 6-1 to Formula 6-14, y and R_{y} are the same as defined in Formula 2. In Formula 6-1 to Formula 6-14, at least one hydrogen atom in one of Formula 6-1 to Formula 6-14 may be optionally substituted with a deuterium atom.

In an embodiment, the emission layer EML may include at least one compound selected from Compound Group 1. The polycyclic compound according to an embodiment may be any compound selected from Compound Group 1.

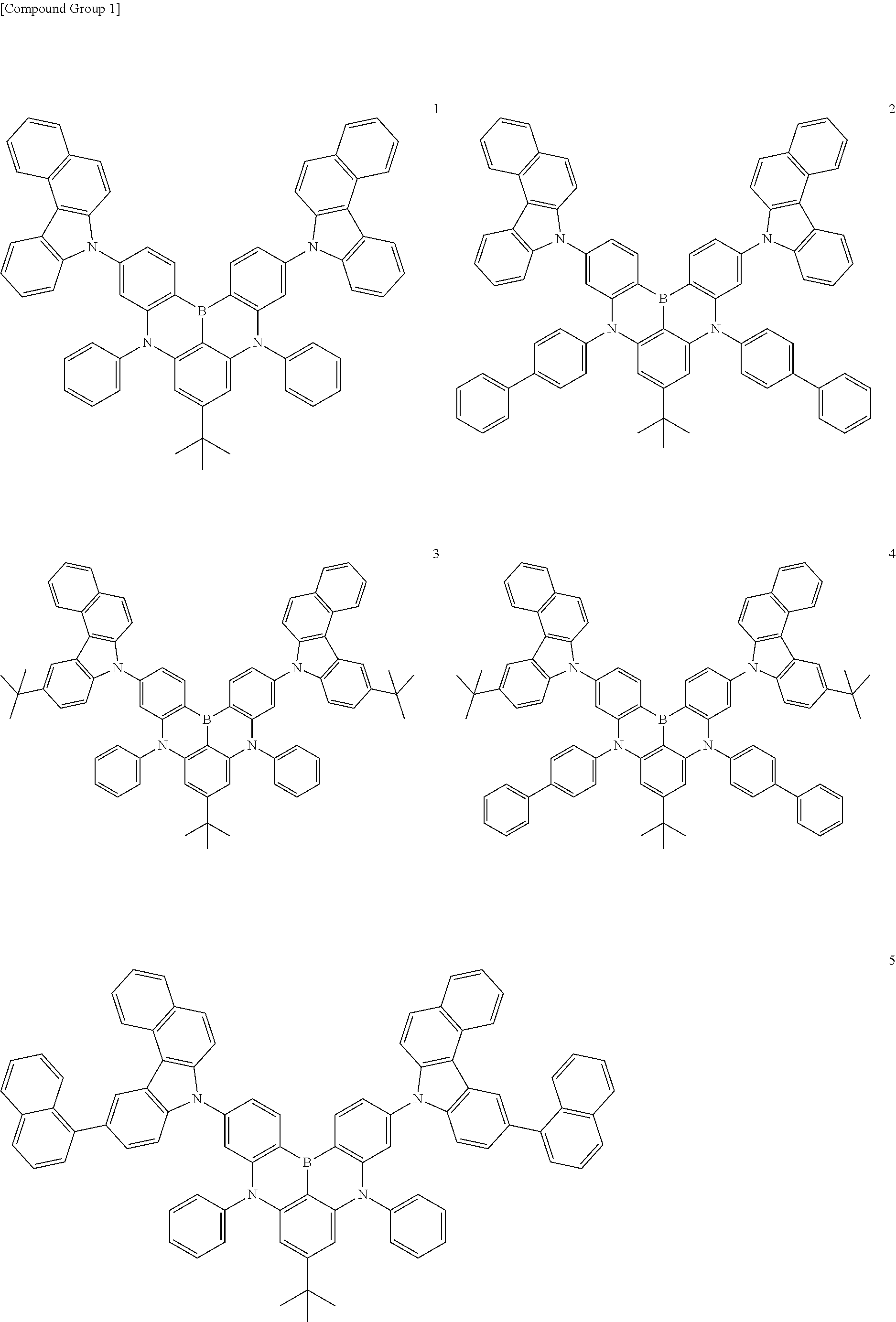

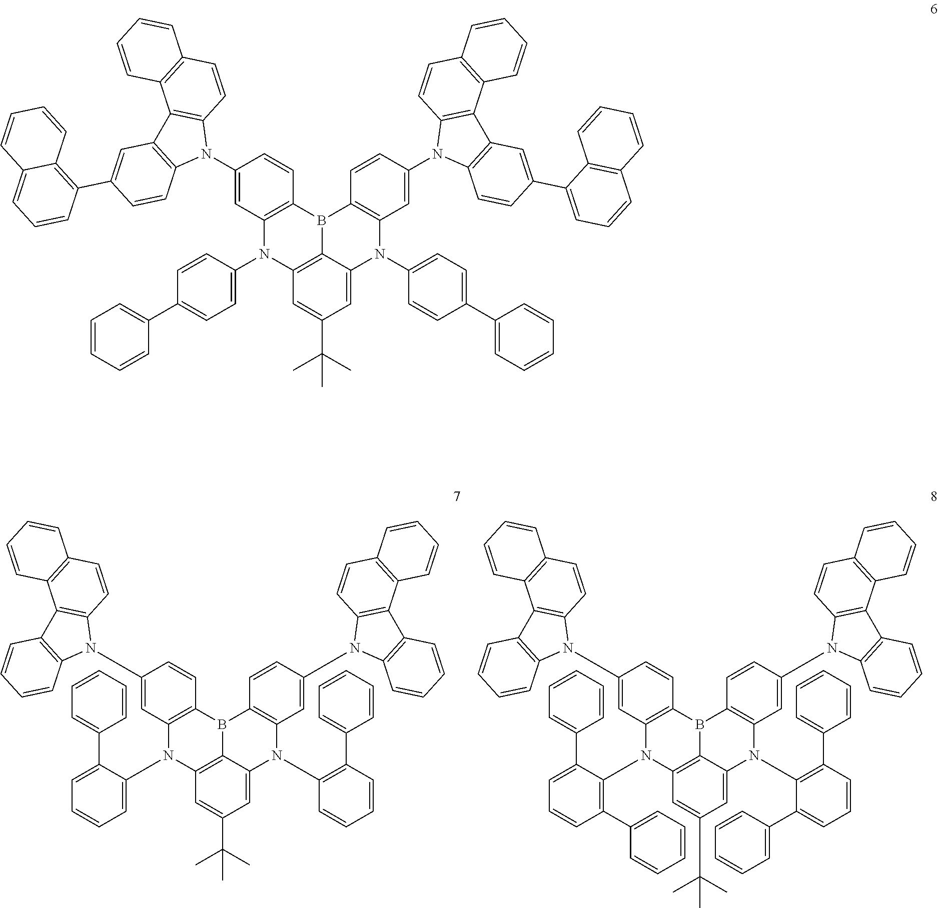

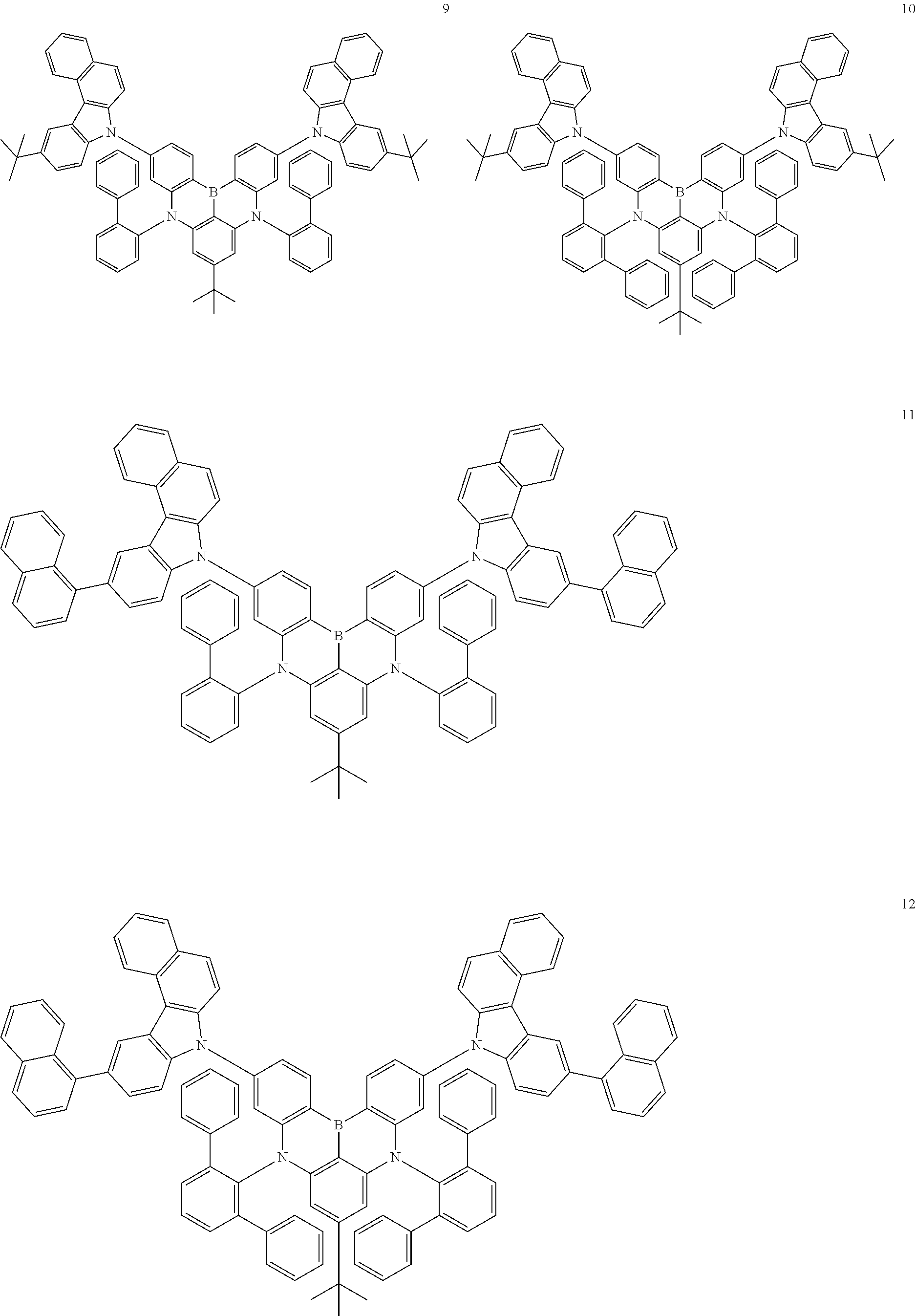

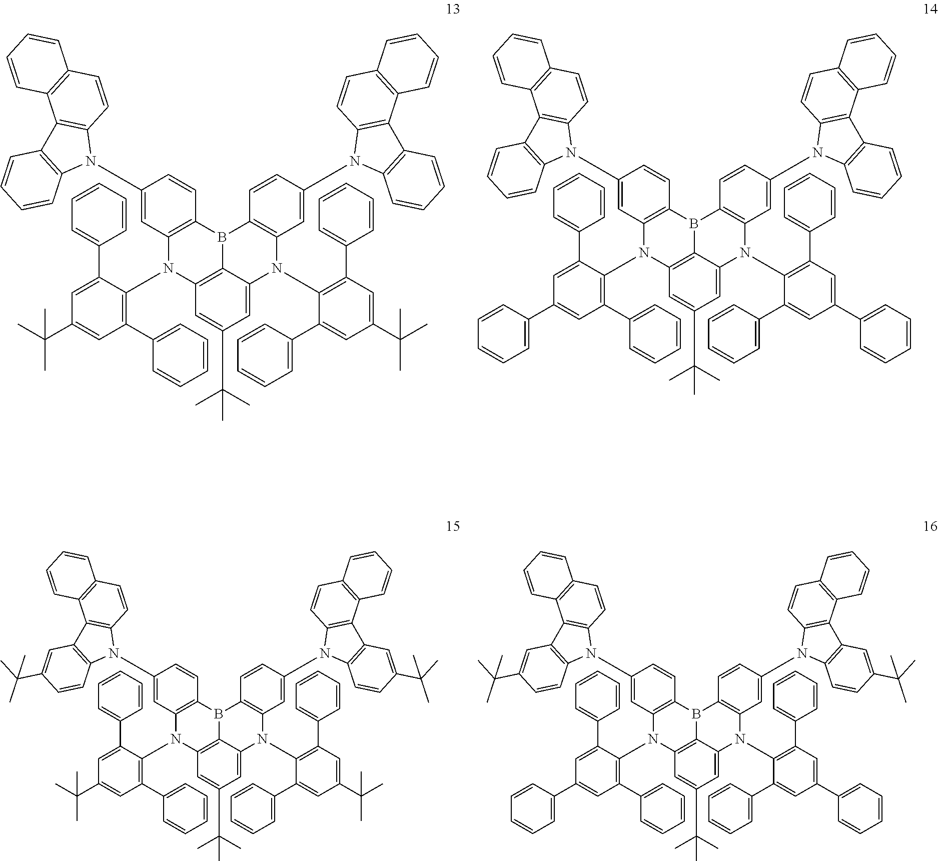

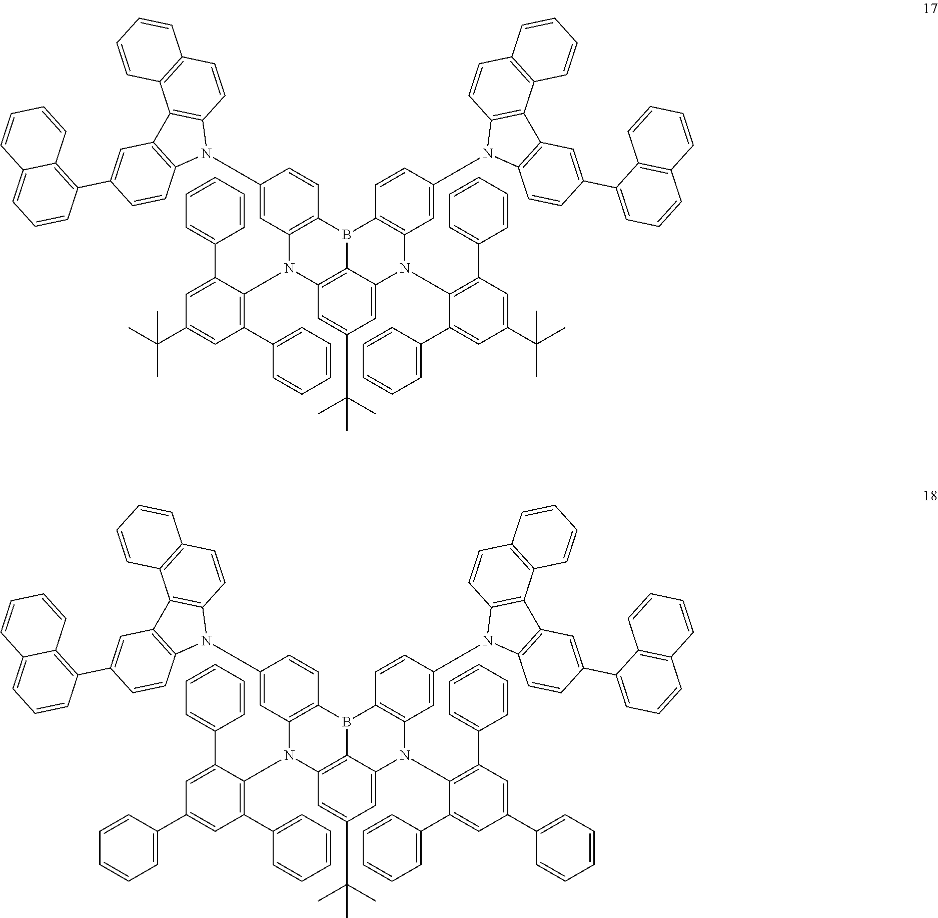 [SMILES: CC(C)(C)c1cc(-c2ccccc2)c(N2c3cc(-n4c5ccc(-c6cccc7ccccc67)cc5c5c6ccccc6ccc54)ccc3B3c4ccc(-n5c6ccc(-c7cccc8ccccc78)cc6c6c7ccccc7ccc65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc2c3c(c1)N(c1c(-c4ccccc4)cc(-c4ccccc4)cc1-c1ccccc1)c1cc(-n4c5ccc(-c6cccc7ccccc67)cc5c5c6ccccc6ccc54)ccc1B3c1ccc(-n3c4ccc(-c5cccc6ccccc56)cc4c4c5ccccc5ccc43)cc1N2c1c(-c2ccccc2)cc(-c2ccccc2)cc1-c1ccccc1]

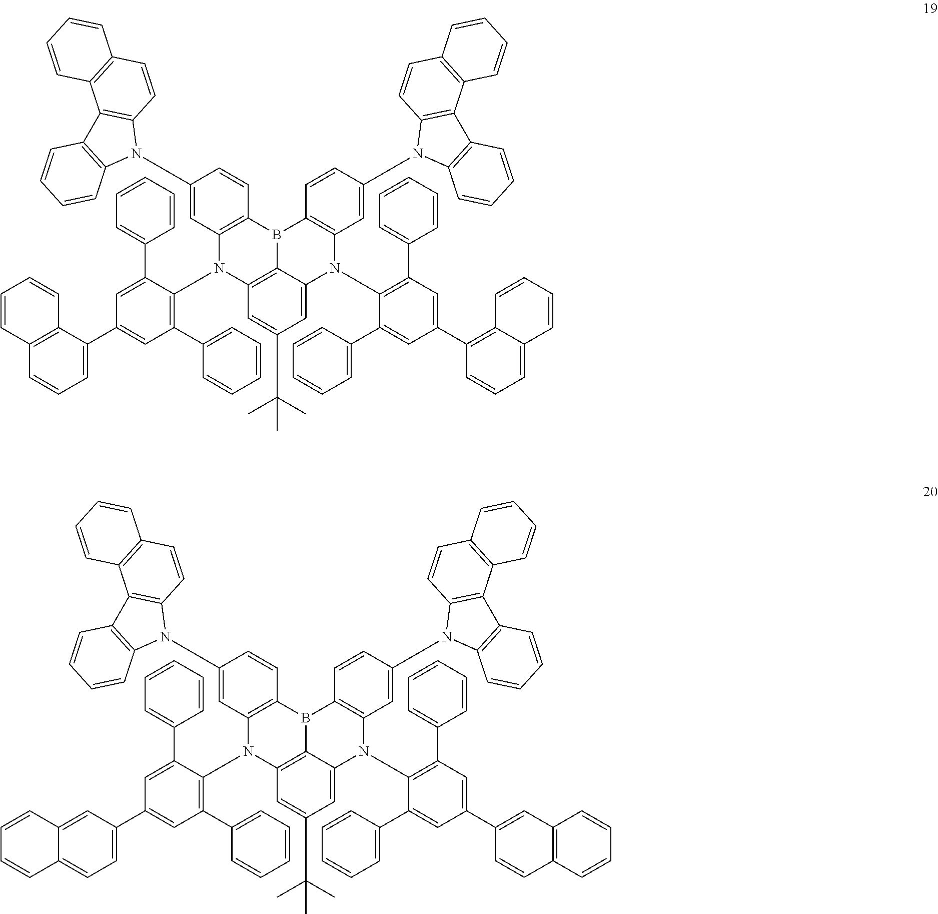 [SMILES: CC(C)(C)c1cc2c3c(c1)N(c1c(-c4ccccc4)cc(-c4cccc5ccccc45)cc1-c1ccccc1)c1cc(-n4c5ccccc5c5c6ccccc6ccc54)ccc1B3c1ccc(-n3c4ccccc4c4c5ccccc5ccc43)cc1N2c1c(-c2ccccc2)cc(-c2cccc3ccccc23)cc1-c1ccccc1 ; CC(C)(C)c1cc2c3c(c1)N(c1c(-c4ccccc4)cc(-c4ccc5ccccc5c4)cc1-c1ccccc1)c1cc(-n4c5ccccc5c5c6ccccc6ccc54)ccc1B3c1ccc(-n3c4ccccc4c4c5ccccc5ccc43)cc1N2c1c(-c2ccccc2)cc(-c2ccc3ccccc3c2)cc1-c1ccccc1]

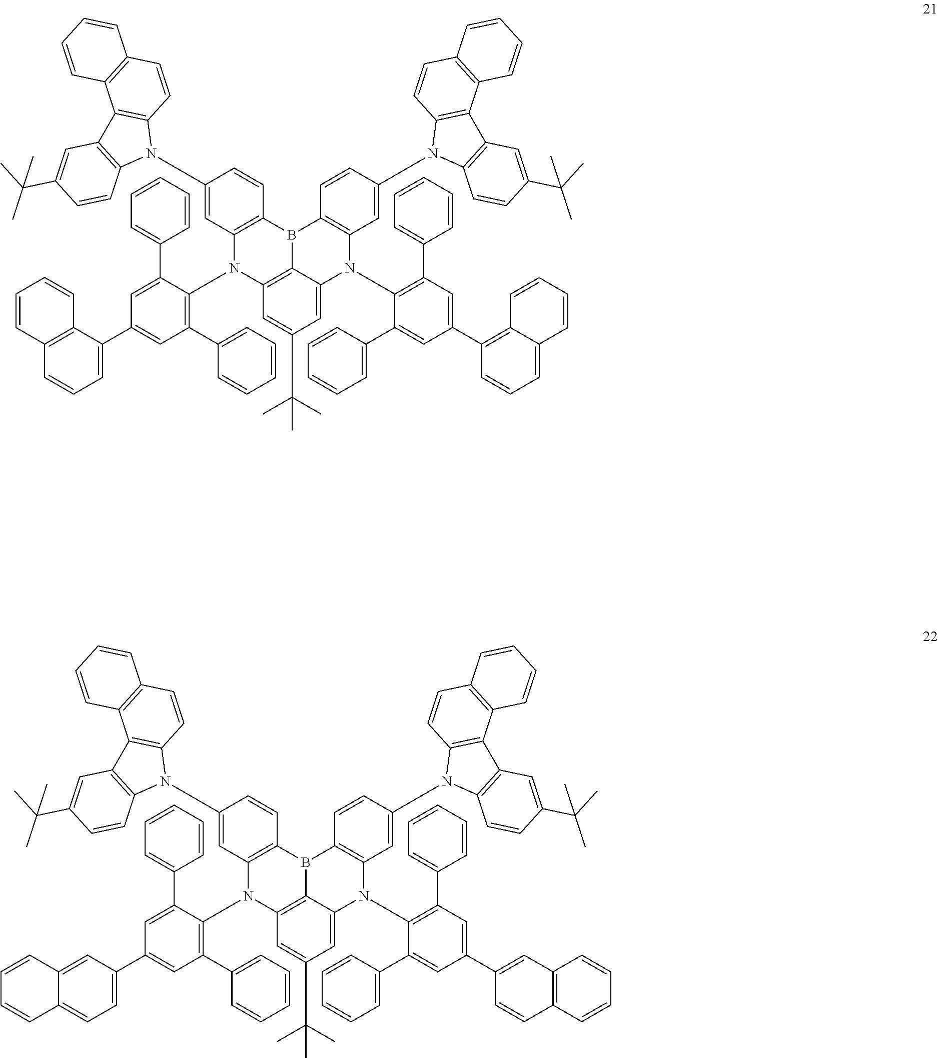 [SMILES: CC(C)(C)c1cc2c3c(c1)N(c1c(-c4ccccc4)cc(-c4cccc5ccccc45)cc1-c1ccccc1)c1cc(-n4c5ccc(C(C)(C)C)cc5c5c6ccccc6ccc54)ccc1B3c1ccc(-n3c4ccc(C(C)(C)C)cc4c4c5ccccc5ccc43)cc1N2c1c(-c2ccccc2)cc(-c2cccc3ccccc23)cc1-c1ccccc1 ; CC(C)(C)c1cc2c3c(c1)N(c1c(-c4ccccc4)cc(-c4ccc5ccccc5c4)cc1-c1ccccc1)c1cc(-n4c5ccc(C(C)(C)C)cc5c5c6ccccc6ccc54)ccc1B3c1ccc(-n3c4ccc(C(C)(C)C)cc4c4c5ccccc5ccc43)cc1N2c1c(-c2ccccc2)cc(-c2ccc3ccccc3c2)cc1-c1ccccc1]

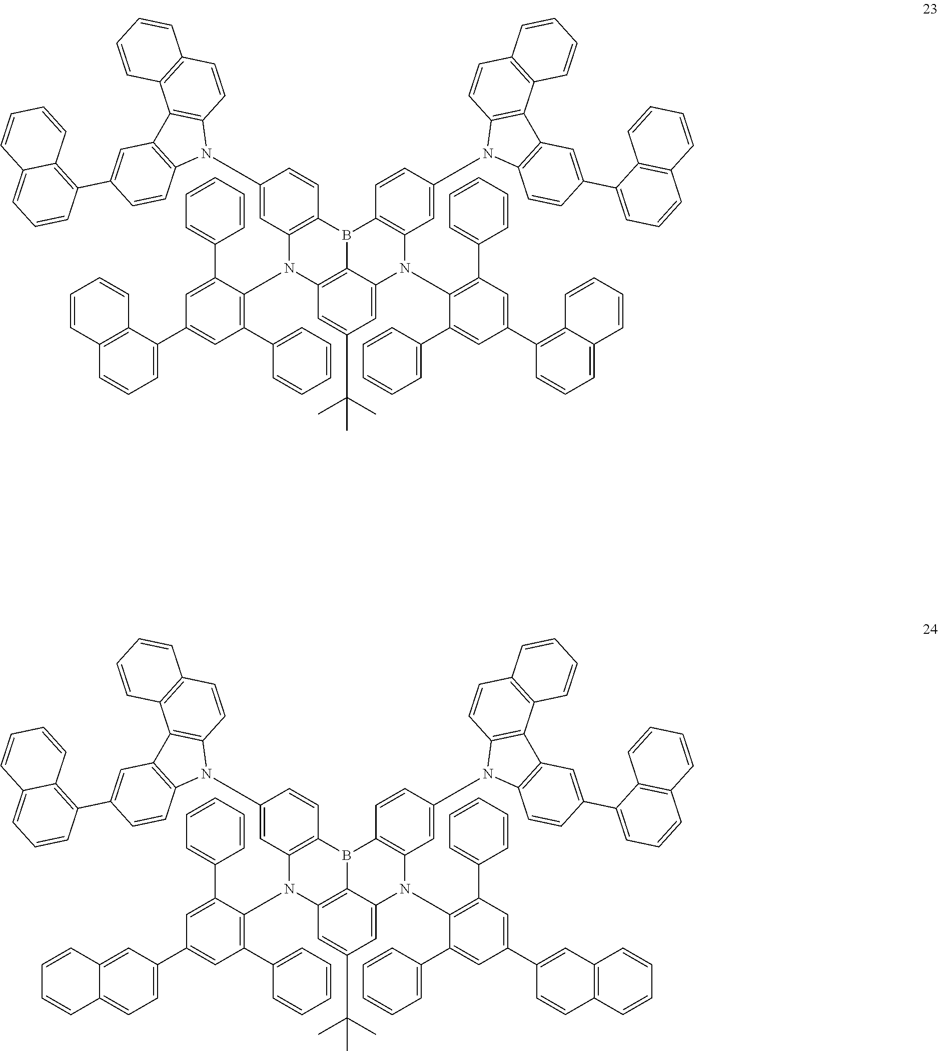 [SMILES: CC(C)(C)c1cc2c3c(c1)N(c1c(-c4ccccc4)cc(-c4cccc5ccccc45)cc1-c1ccccc1)c1cc(-n4c5ccc(-c6cccc7ccccc67)cc5c5c6ccccc6ccc54)ccc1B3c1ccc(-n3c4ccc(-c5cccc6ccccc56)cc4c4c5ccccc5ccc43)cc1N2c1c(-c2ccccc2)cc(-c2cccc3ccccc23)cc1-c1ccccc1 ; CC(C)(C)c1cc2c3c(c1)N(c1c(-c4ccccc4)cc(-c4ccc5ccccc5c4)cc1-c1ccccc1)c1cc(-n4c5ccc(-c6cccc7ccccc67)cc5c5c6ccccc6ccc54)ccc1B3c1ccc(-n3c4ccc(-c5cccc6ccccc56)cc4c4c5ccccc5ccc43)cc1N2c1c(-c2ccccc2)cc(-c2ccc3ccccc3c2)cc1-c1ccccc1]

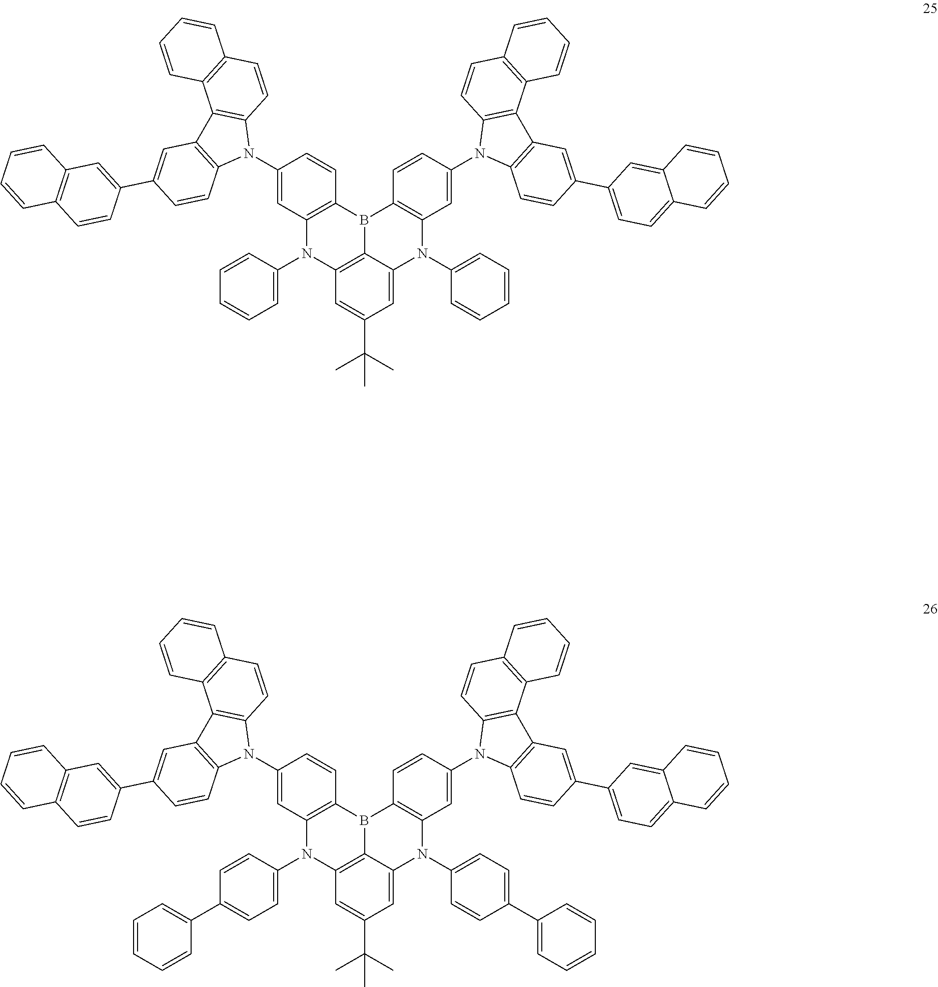 [SMILES: CC(C)(C)c1cc2c3c(c1)N(c1ccccc1)c1cc(-n4c5ccc(-c6ccc7ccccc7c6)cc5c5c6ccccc6ccc54)ccc1B3c1ccc(-n3c4ccc(-c5ccc6ccccc6c5)cc4c4c5ccccc5ccc43)cc1N2c1ccccc1 ; CC(C)(C)c1cc2c3c(c1)N(c1ccc(-c4ccccc4)cc1)c1cc(-n4c5ccc(-c6ccc7ccccc7c6)cc5c5c6ccccc6ccc54)ccc1B3c1ccc(-n3c4ccc(-c5ccc6ccccc6c5)cc4c4c5ccccc5ccc43)cc1N2c1ccc(-c2ccccc2)cc1]

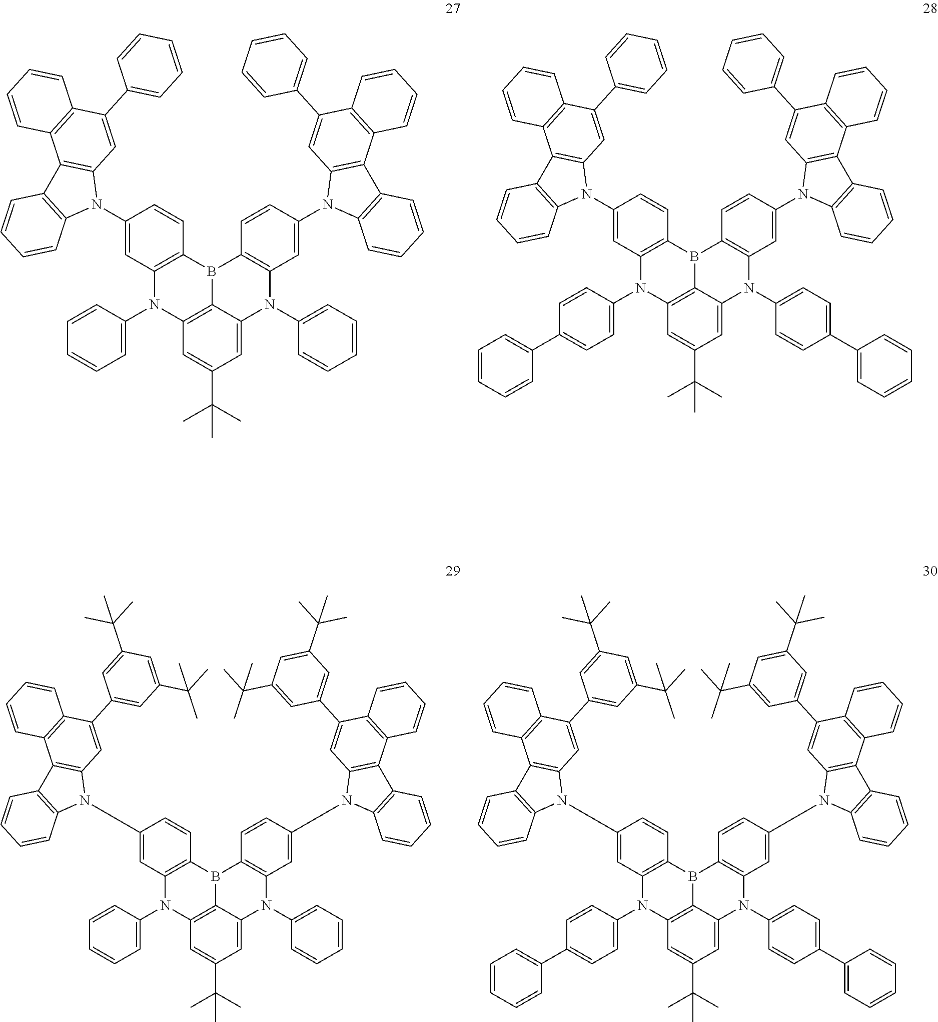

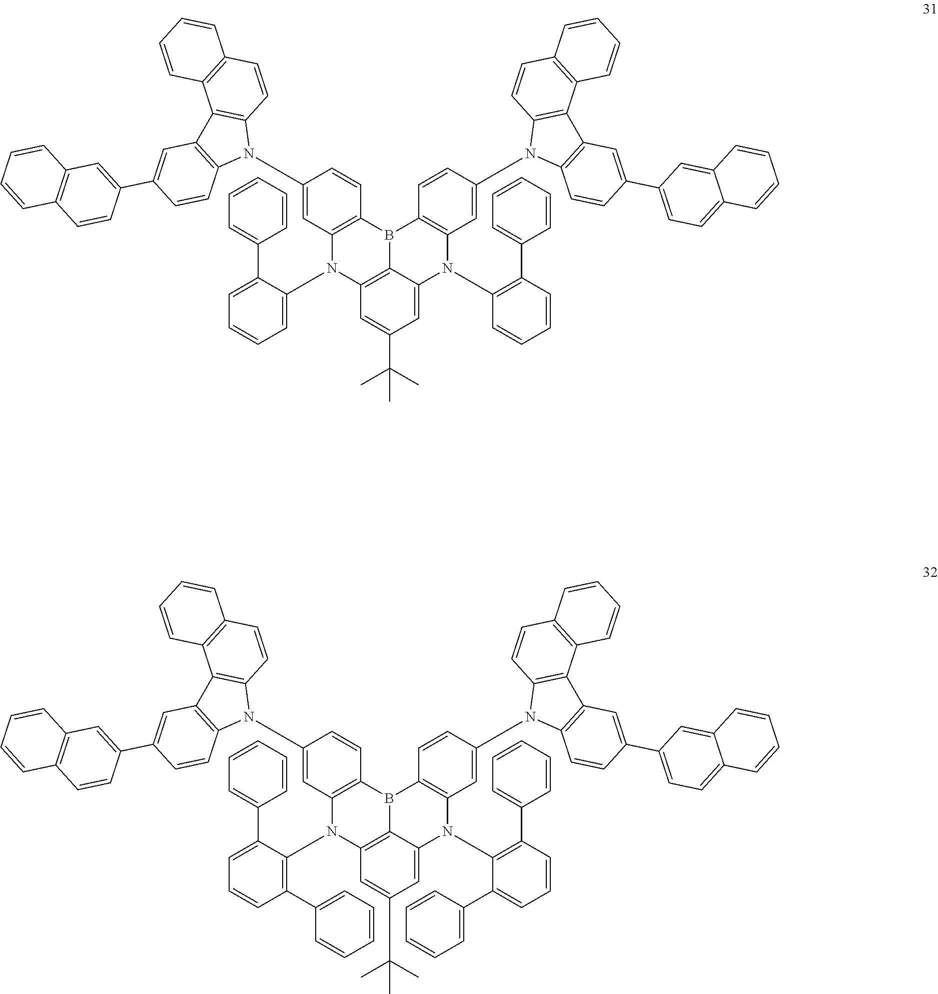 [SMILES: CC(C)(C)c1cc2c3c(c1)N(c1ccccc1-c1ccccc1)c1cc(-n4c5ccc(-c6ccc7ccccc7c6)cc5c5c6ccccc6ccc54)ccc1B3c1ccc(-n3c4ccc(-c5ccc6ccccc6c5)cc4c4c5ccccc5ccc43)cc1N2c1ccccc1-c1ccccc1 ; CC(C)(C)c1cc2c3c(c1)N(c1c(-c4ccccc4)cccc1-c1ccccc1)c1cc(-n4c5ccc(-c6ccc7ccccc7c6)cc5c5c6ccccc6ccc54)ccc1B3c1ccc(-n3c4ccc(-c5ccc6ccccc6c5)cc4c4c5ccccc5ccc43)cc1N2c1c(-c2ccccc2)cccc1-c1ccccc1]

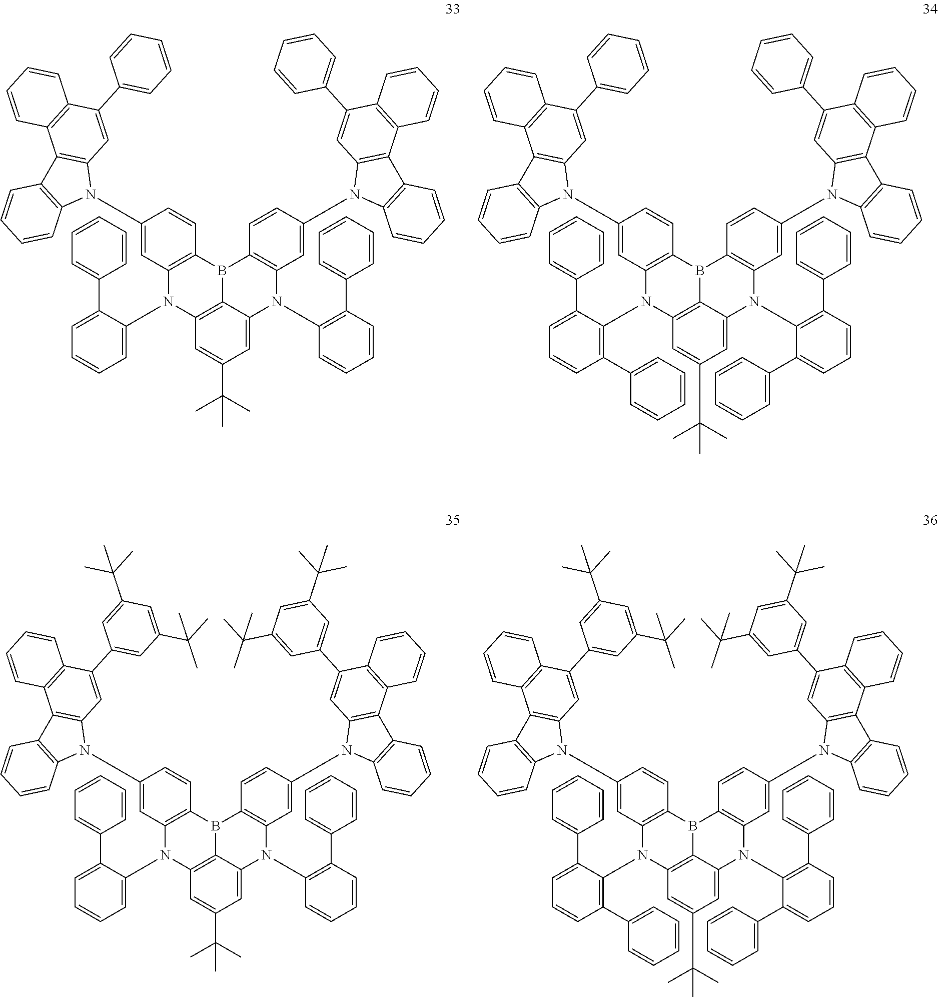

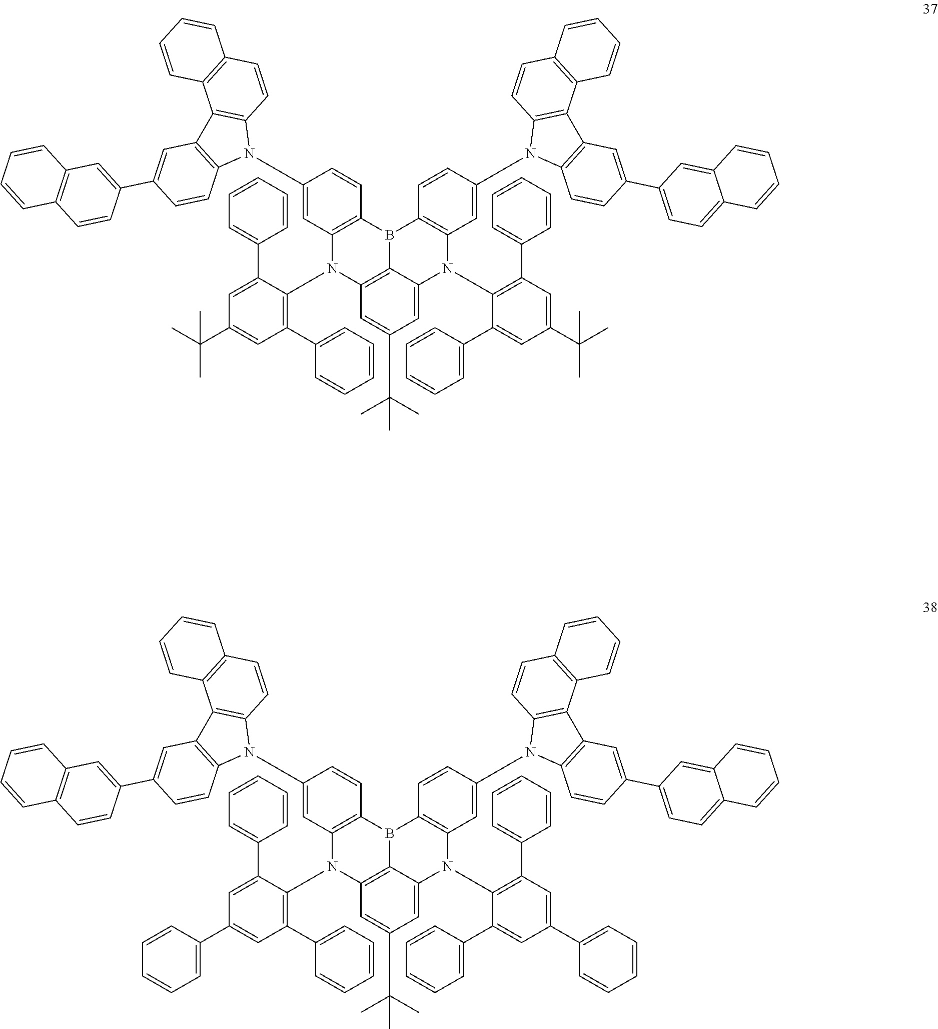 [SMILES: CC(C)(C)c1cc(-c2ccccc2)c(N2c3cc(-n4c5ccc(-c6ccc7ccccc7c6)cc5c5c6ccccc6ccc54)ccc3B3c4ccc(-n5c6ccc(-c7ccc8ccccc8c7)cc6c6c7ccccc7ccc65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc2c3c(c1)N(c1c(-c4ccccc4)cc(-c4ccccc4)cc1-c1ccccc1)c1cc(-n4c5ccc(-c6ccc7ccccc7c6)cc5c5c6ccccc6ccc54)ccc1B3c1ccc(-n3c4ccc(-c5ccc6ccccc6c5)cc4c4c5ccccc5ccc43)cc1N2c1c(-c2ccccc2)cc(-c2ccccc2)cc1-c1ccccc1]

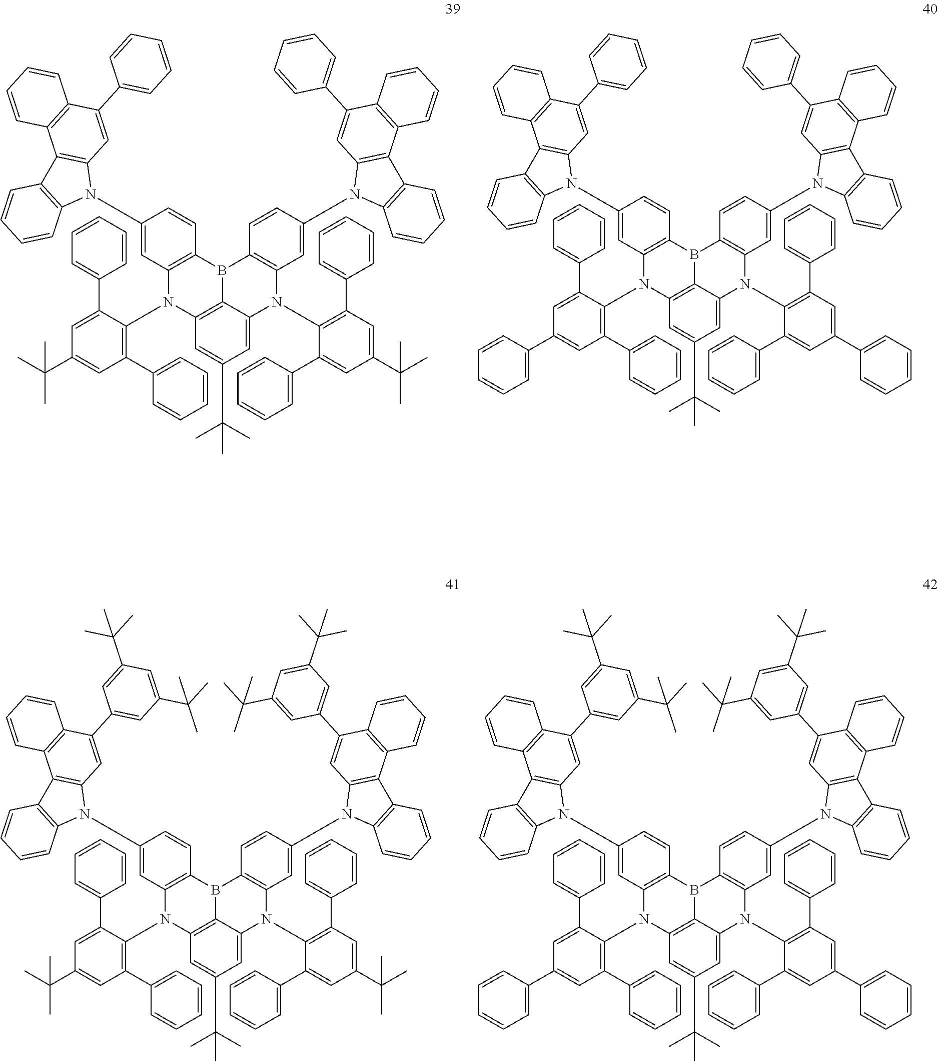

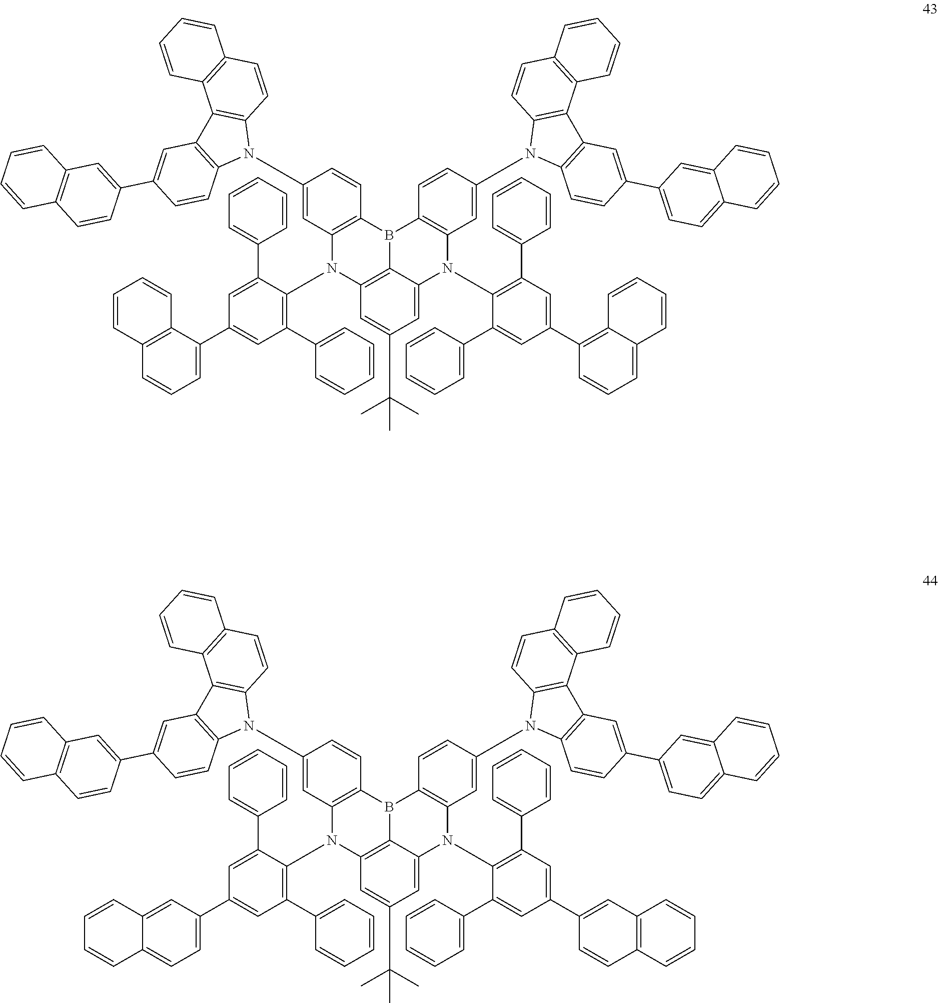 [SMILES: CC(C)(C)c1cc2c3c(c1)N(c1c(-c4ccccc4)cc(-c4cccc5ccccc45)cc1-c1ccccc1)c1cc(-n4c5ccc(-c6ccc7ccccc7c6)cc5c5c6ccccc6ccc54)ccc1B3c1ccc(-n3c4ccc(-c5ccc6ccccc6c5)cc4c4c5ccccc5ccc43)cc1N2c1c(-c2ccccc2)cc(-c2cccc3ccccc23)cc1-c1ccccc1 ; CC(C)(C)c1cc2c3c(c1)N(c1c(-c4ccccc4)cc(-c4ccc5ccccc5c4)cc1-c1ccccc1)c1cc(-n4c5ccc(-c6ccc7ccccc7c6)cc5c5c6ccccc6ccc54)ccc1B3c1ccc(-n3c4ccc(-c5ccc6ccccc6c5)cc4c4c5ccccc5ccc43)cc1N2c1c(-c2ccccc2)cc(-c2ccc3ccccc3c2)cc1-c1ccccc1]

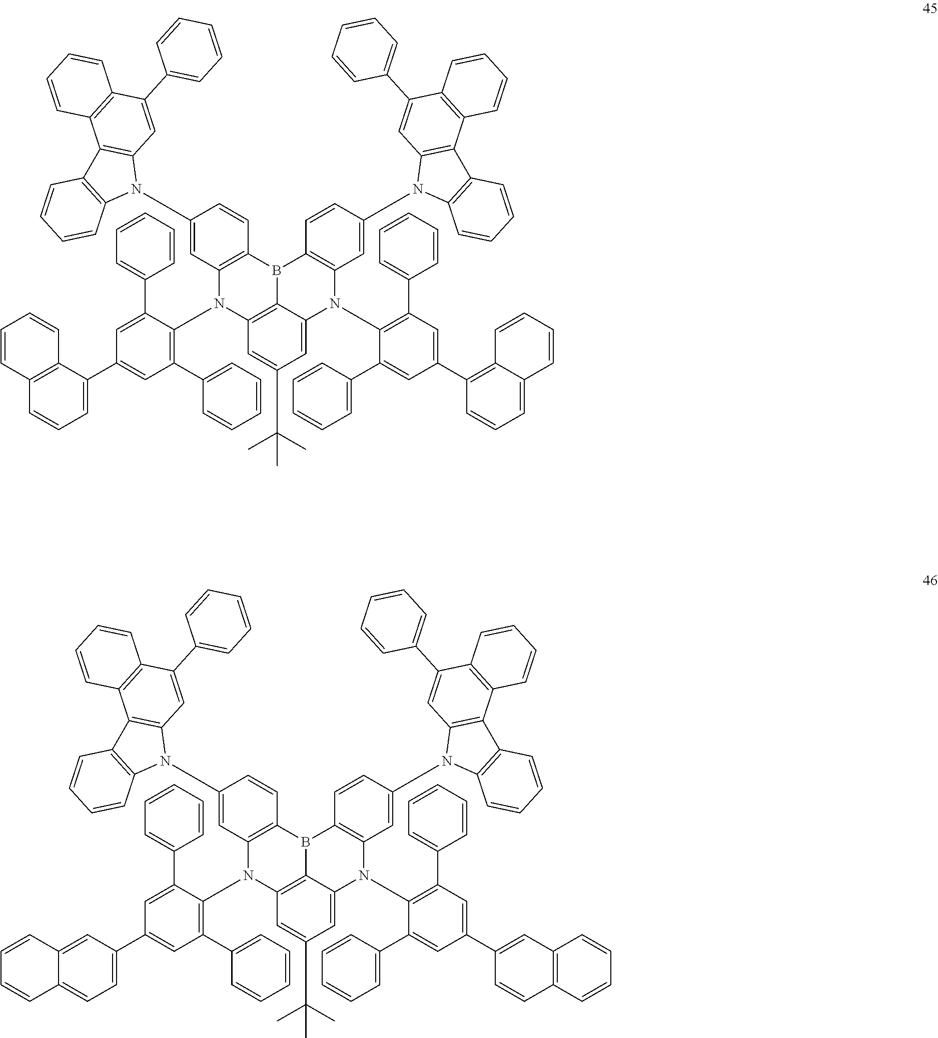 [SMILES: CC(C)(C)c1cc2c3c(c1)N(c1c(-c4ccccc4)cc(-c4cccc5ccccc45)cc1-c1ccccc1)c1cc(-n4c5ccccc5c5c6ccccc6c(-c6ccccc6)cc54)ccc1B3c1ccc(-n3c4ccccc4c4c5ccccc5c(-c5ccccc5)cc43)cc1N2c1c(-c2ccccc2)cc(-c2cccc3ccccc23)cc1-c1ccccc1 ; CC(C)(C)c1cc2c3c(c1)N(c1c(-c4ccccc4)cc(-c4ccc5ccccc5c4)cc1-c1ccccc1)c1cc(-n4c5ccccc5c5c6ccccc6c(-c6ccccc6)cc54)ccc1B3c1ccc(-n3c4ccccc4c4c5ccccc5c(-c5ccccc5)cc43)cc1N2c1c(-c2ccccc2)cc(-c2ccc3ccccc3c2)cc1-c1ccccc1]

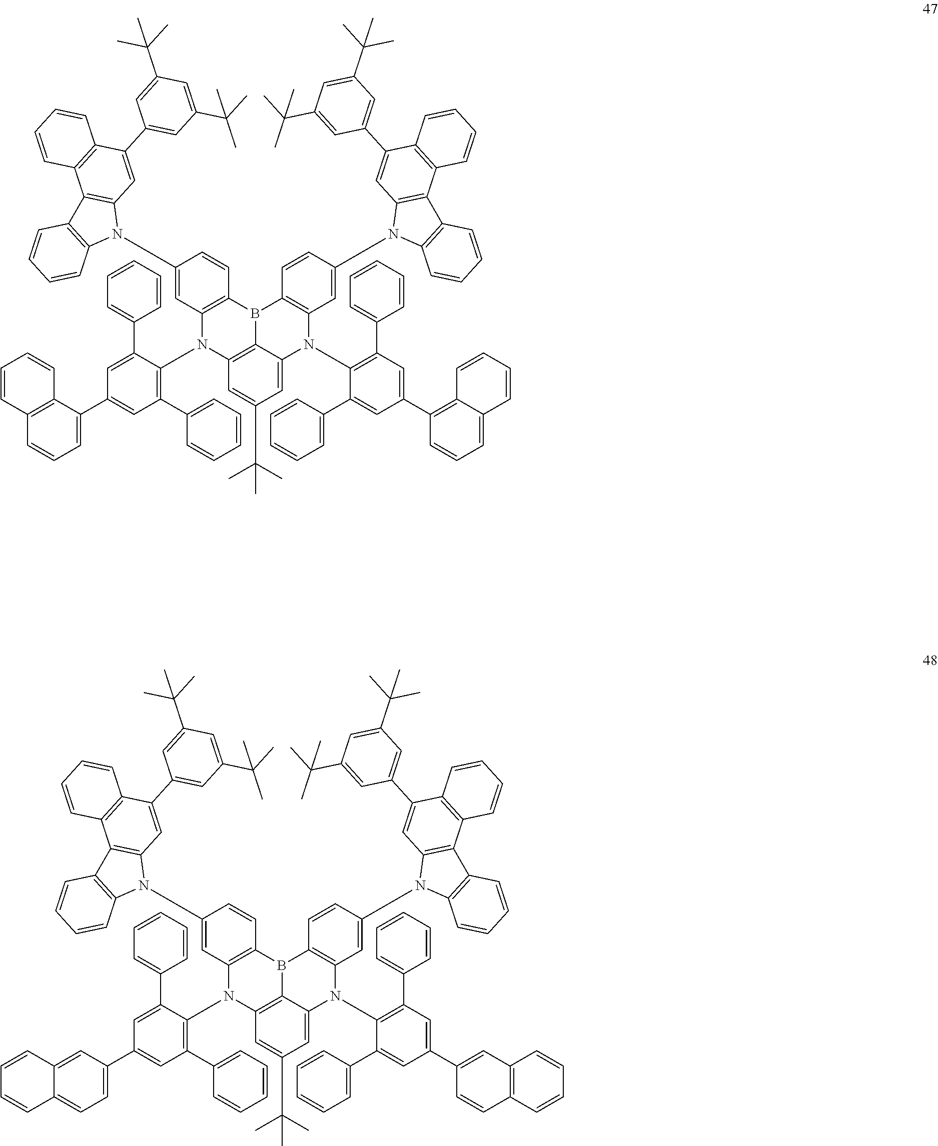

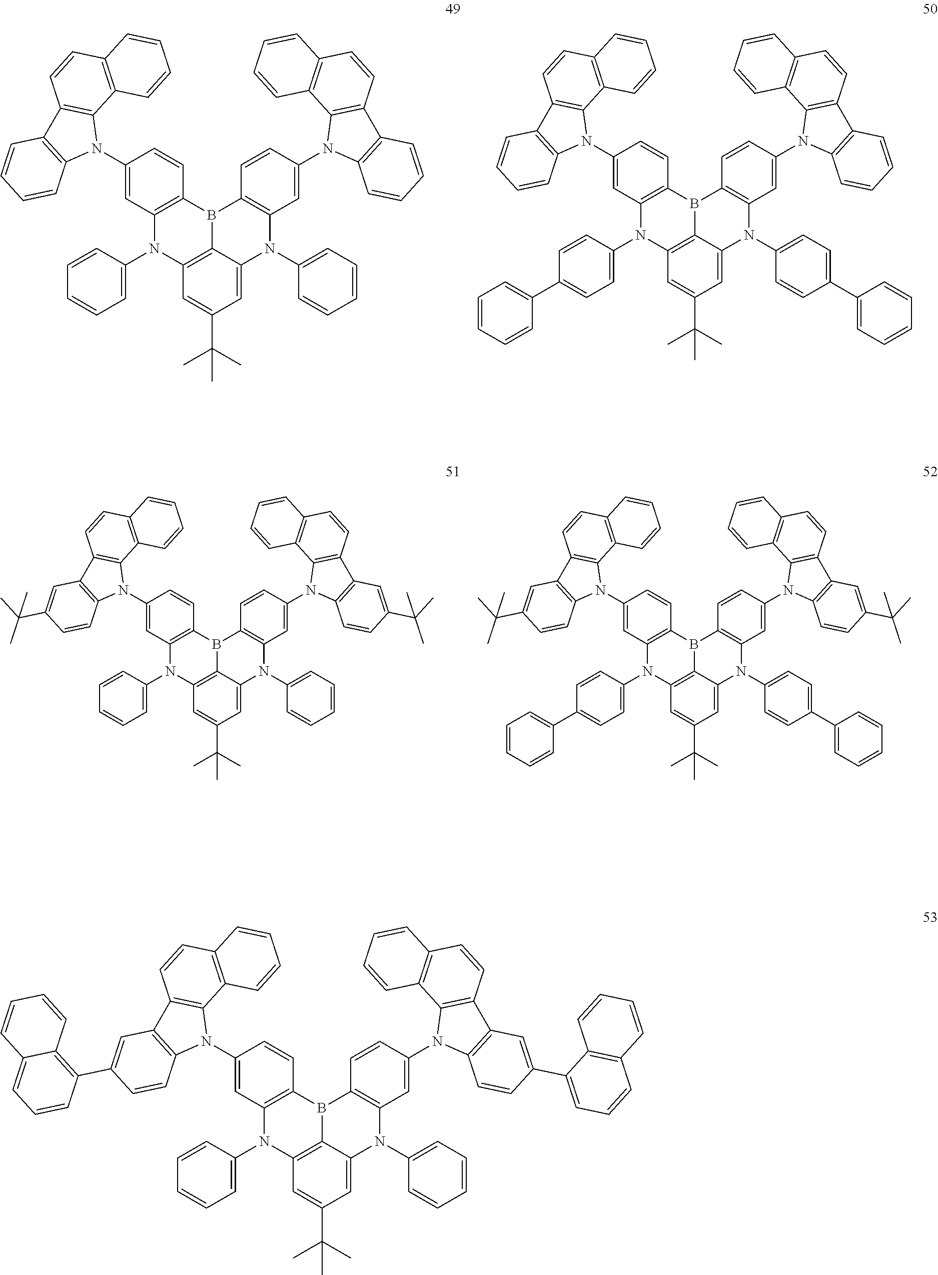

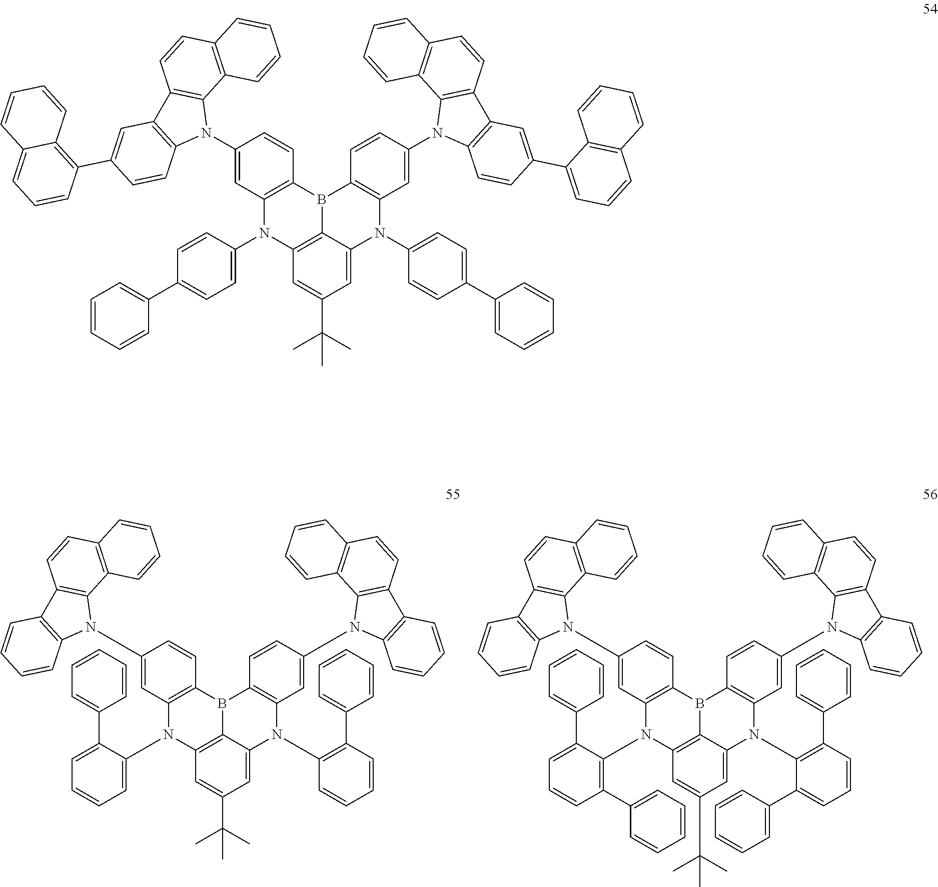

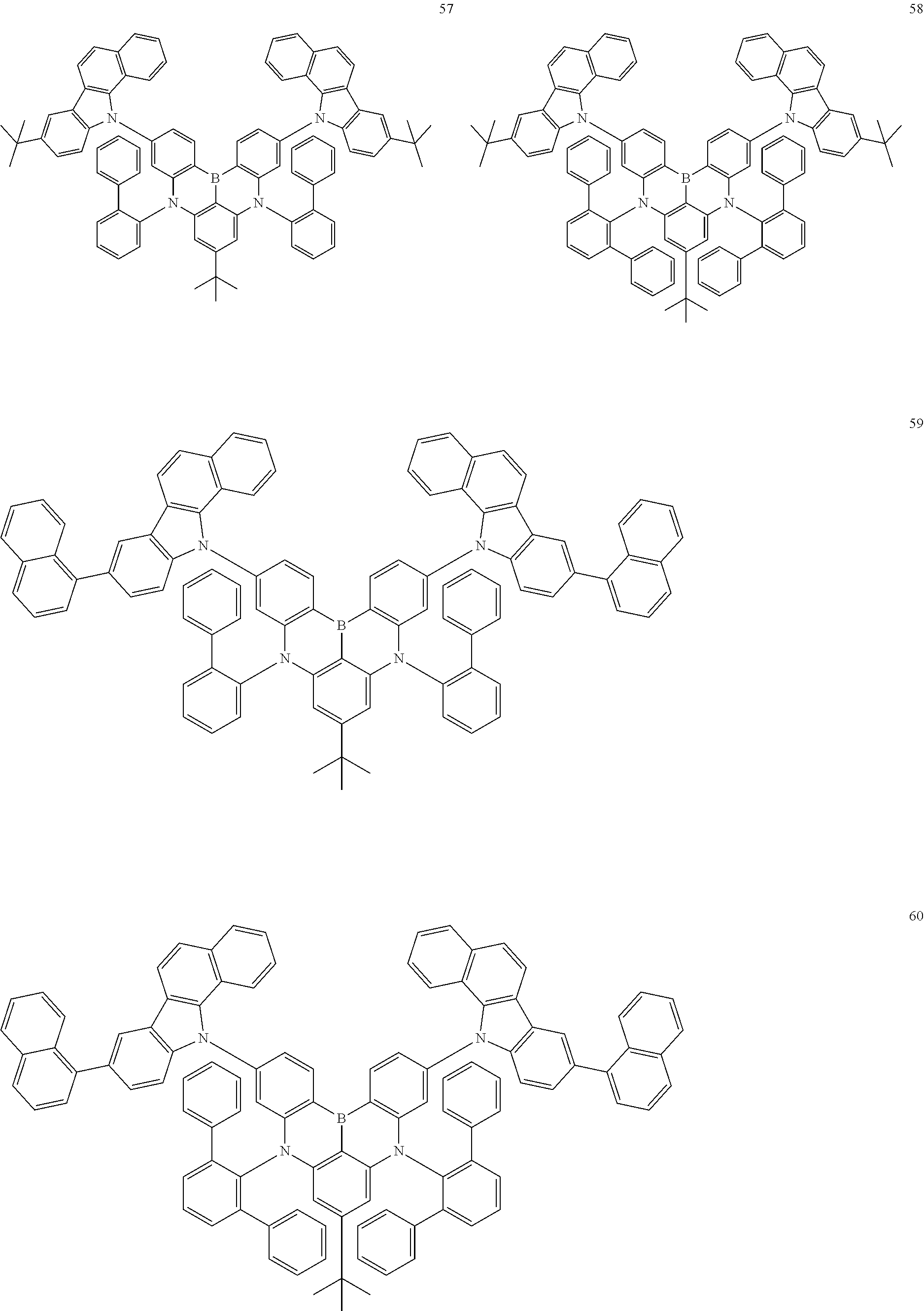

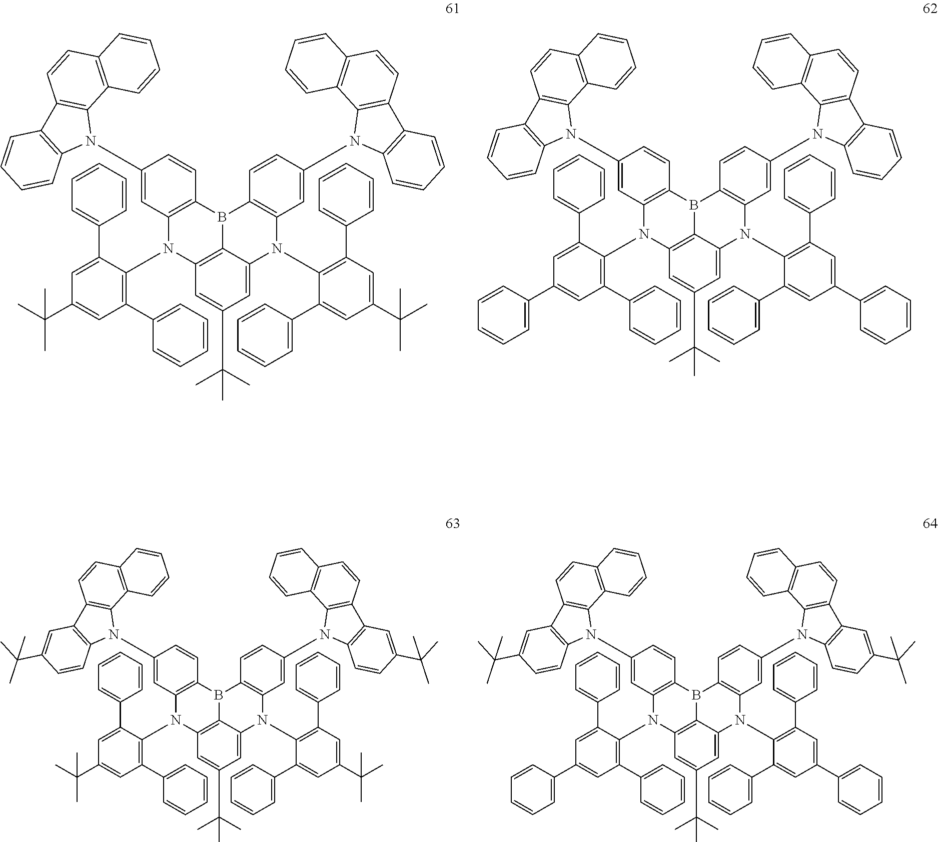

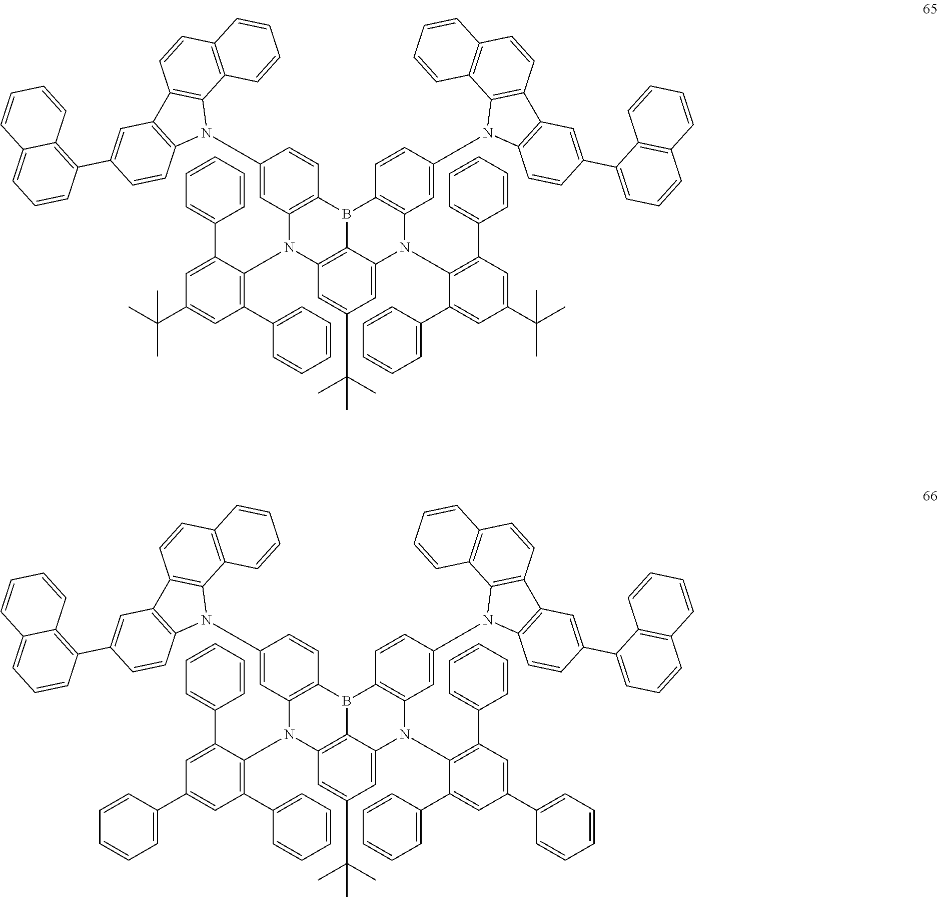 [SMILES: CC(C)(C)c1cc(-c2ccccc2)c(N2c3cc(-n4c5ccc(-c6cccc7ccccc67)cc5c5ccc6ccccc6c54)ccc3B3c4ccc(-n5c6ccc(-c7cccc8ccccc78)cc6c6ccc7ccccc7c65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc2c3c(c1)N(c1c(-c4ccccc4)cc(-c4ccccc4)cc1-c1ccccc1)c1cc(-n4c5ccc(-c6cccc7ccccc67)cc5c5ccc6ccccc6c54)ccc1B3c1ccc(-n3c4ccc(-c5cccc6ccccc56)cc4c4ccc5ccccc5c43)cc1N2c1c(-c2ccccc2)cc(-c2ccccc2)cc1-c1ccccc1]

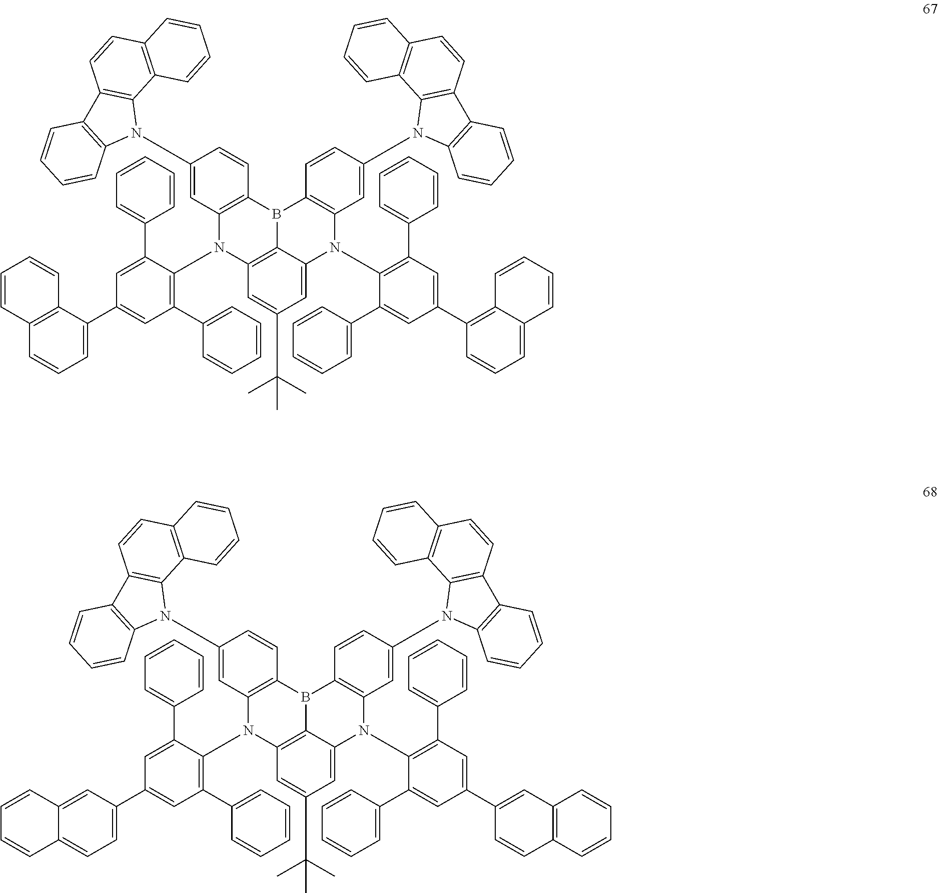 [SMILES: CC(C)(C)c1cc2c3c(c1)N(c1c(-c4ccccc4)cc(-c4cccc5ccccc45)cc1-c1ccccc1)c1cc(-n4c5ccccc5c5ccc6ccccc6c54)ccc1B3c1ccc(-n3c4ccccc4c4ccc5ccccc5c43)cc1N2c1c(-c2ccccc2)cc(-c2cccc3ccccc23)cc1-c1ccccc1 ; CC(C)(C)c1cc2c3c(c1)N(c1c(-c4ccccc4)cc(-c4ccc5ccccc5c4)cc1-c1ccccc1)c1cc(-n4c5ccccc5c5ccc6ccccc6c54)ccc1B3c1ccc(-n3c4ccccc4c4ccc5ccccc5c43)cc1N2c1c(-c2ccccc2)cc(-c2ccc3ccccc3c2)cc1-c1ccccc1]

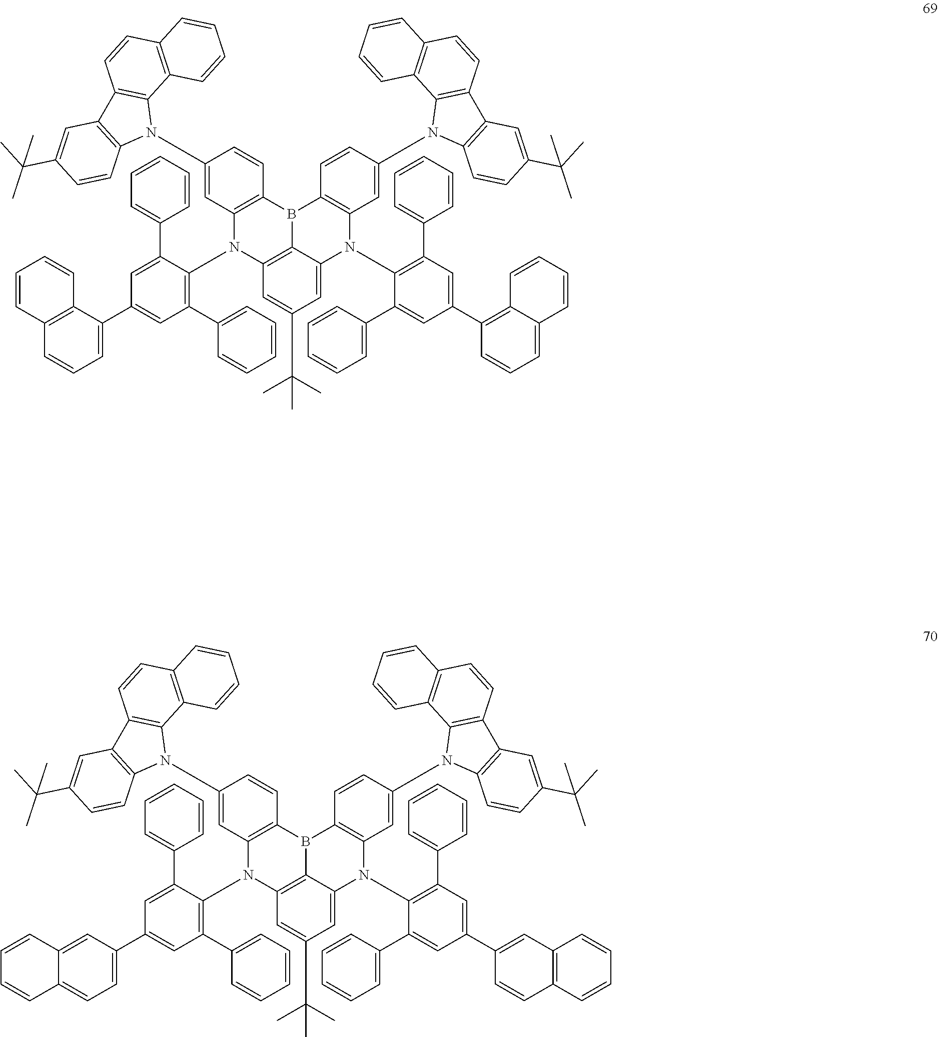 [SMILES: CC(C)(C)c1cc2c3c(c1)N(c1c(-c4ccccc4)cc(-c4cccc5ccccc45)cc1-c1ccccc1)c1cc(-n4c5ccc(C(C)(C)C)cc5c5ccc6ccccc6c54)ccc1B3c1ccc(-n3c4ccc(C(C)(C)C)cc4c4ccc5ccccc5c43)cc1N2c1c(-c2ccccc2)cc(-c2cccc3ccccc23)cc1-c1ccccc1 ; CC(C)(C)c1cc2c3c(c1)N(c1c(-c4ccccc4)cc(-c4ccc5ccccc5c4)cc1-c1ccccc1)c1cc(-n4c5ccc(C(C)(C)C)cc5c5ccc6ccccc6c54)ccc1B3c1ccc(-n3c4ccc(C(C)(C)C)cc4c4ccc5ccccc5c43)cc1N2c1c(-c2ccccc2)cc(-c2ccc3ccccc3c2)cc1-c1ccccc1]

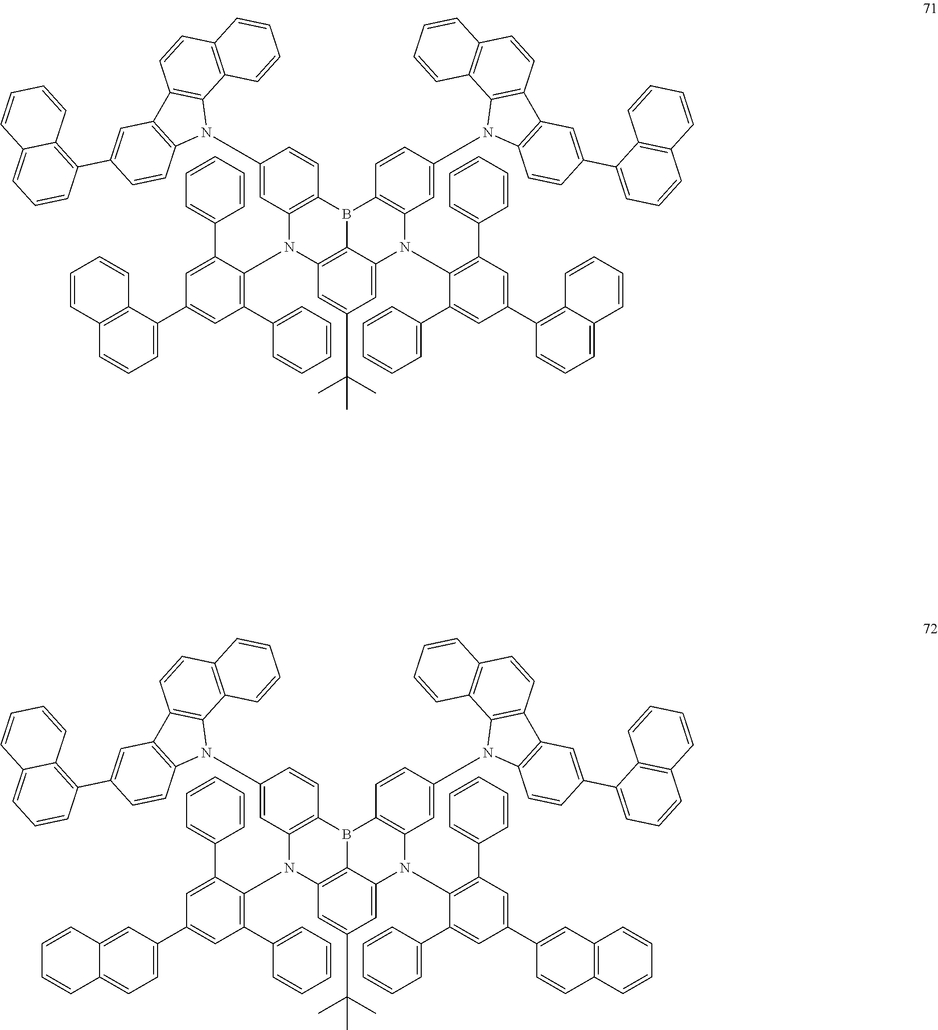 [SMILES: CC(C)(C)c1cc2c3c(c1)N(c1c(-c4ccccc4)cc(-c4cccc5ccccc45)cc1-c1ccccc1)c1cc(-n4c5ccc(-c6cccc7ccccc67)cc5c5ccc6ccccc6c54)ccc1B3c1ccc(-n3c4ccc(-c5cccc6ccccc56)cc4c4ccc5ccccc5c43)cc1N2c1c(-c2ccccc2)cc(-c2cccc3ccccc23)cc1-c1ccccc1 ; CC(C)(C)c1cc2c3c(c1)N(c1c(-c4ccccc4)cc(-c4ccc5ccccc5c4)cc1-c1ccccc1)c1cc(-n4c5ccc(-c6cccc7ccccc67)cc5c5ccc6ccccc6c54)ccc1B3c1ccc(-n3c4ccc(-c5cccc6ccccc56)cc4c4ccc5ccccc5c43)cc1N2c1c(-c2ccccc2)cc(-c2ccc3ccccc3c2)cc1-c1ccccc1]

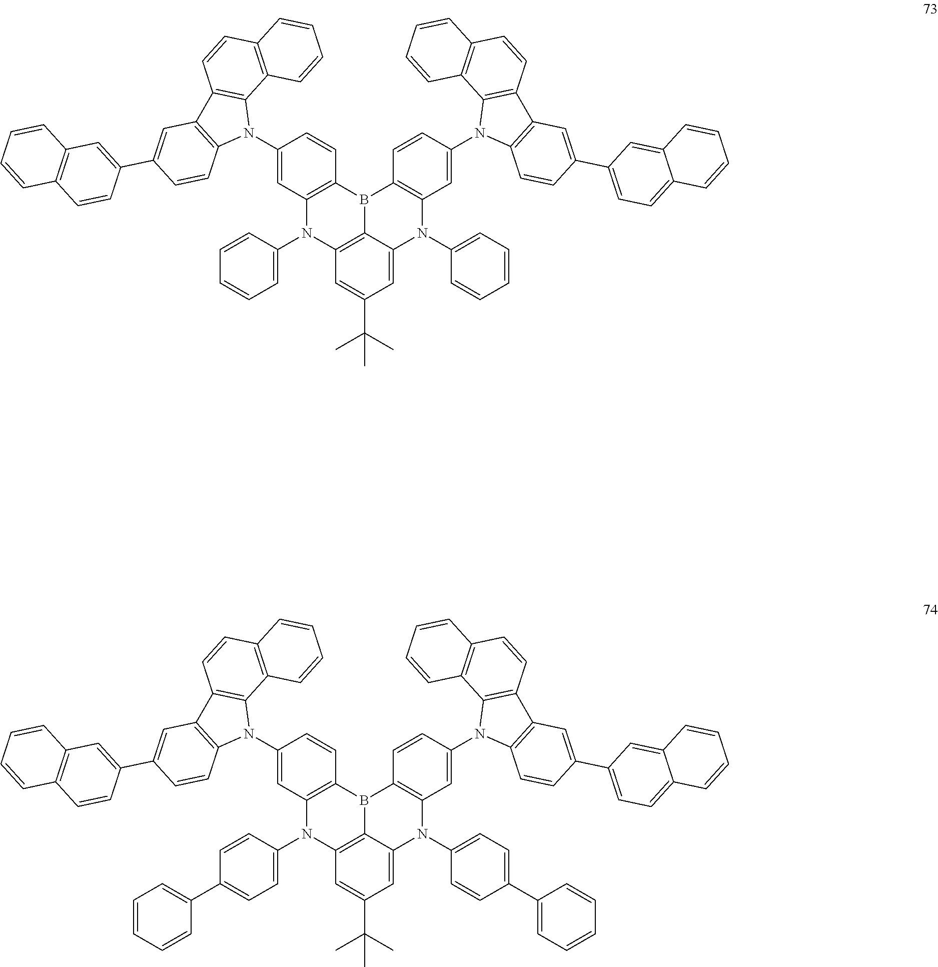 [SMILES: CC(C)(C)c1cc2c3c(c1)N(c1ccccc1)c1cc(-n4c5ccc(-c6ccc7ccccc7c6)cc5c5ccc6ccccc6c54)ccc1B3c1ccc(-n3c4ccc(-c5ccc6ccccc6c5)cc4c4ccc5ccccc5c43)cc1N2c1ccccc1 ; CC(C)(C)c1cc2c3c(c1)N(c1ccc(-c4ccccc4)cc1)c1cc(-n4c5ccc(-c6ccc7ccccc7c6)cc5c5ccc6ccccc6c54)ccc1B3c1ccc(-n3c4ccc(-c5ccc6ccccc6c5)cc4c4ccc5ccccc5c43)cc1N2c1ccc(-c2ccccc2)cc1]

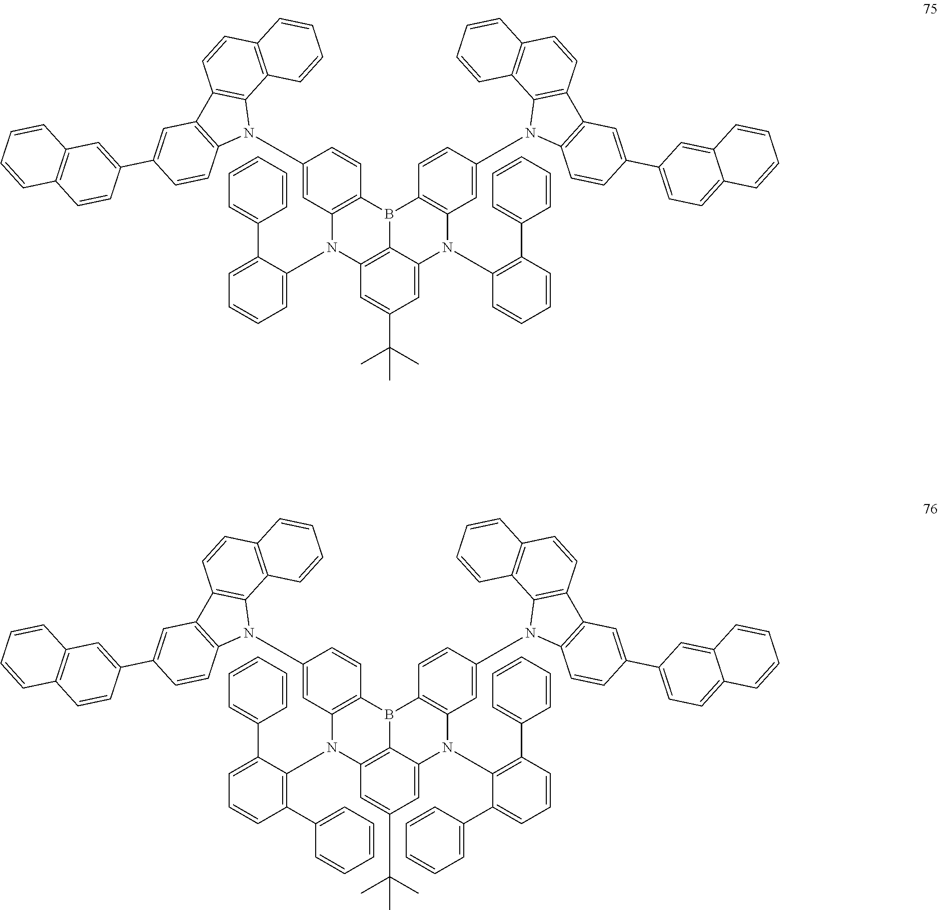 [SMILES: CC(C)(C)c1cc2c3c(c1)N(c1ccccc1-c1ccccc1)c1cc(-n4c5ccc(-c6ccc7ccccc7c6)cc5c5ccc6ccccc6c54)ccc1B3c1ccc(-n3c4ccc(-c5ccc6ccccc6c5)cc4c4ccc5ccccc5c43)cc1N2c1ccccc1-c1ccccc1 ; CC(C)(C)c1cc2c3c(c1)N(c1c(-c4ccccc4)cccc1-c1ccccc1)c1cc(-n4c5ccc(-c6ccc7ccccc7c6)cc5c5ccc6ccccc6c54)ccc1B3c1ccc(-n3c4ccc(-c5ccc6ccccc6c5)cc4c4ccc5ccccc5c43)cc1N2c1c(-c2ccccc2)cccc1-c1ccccc1]

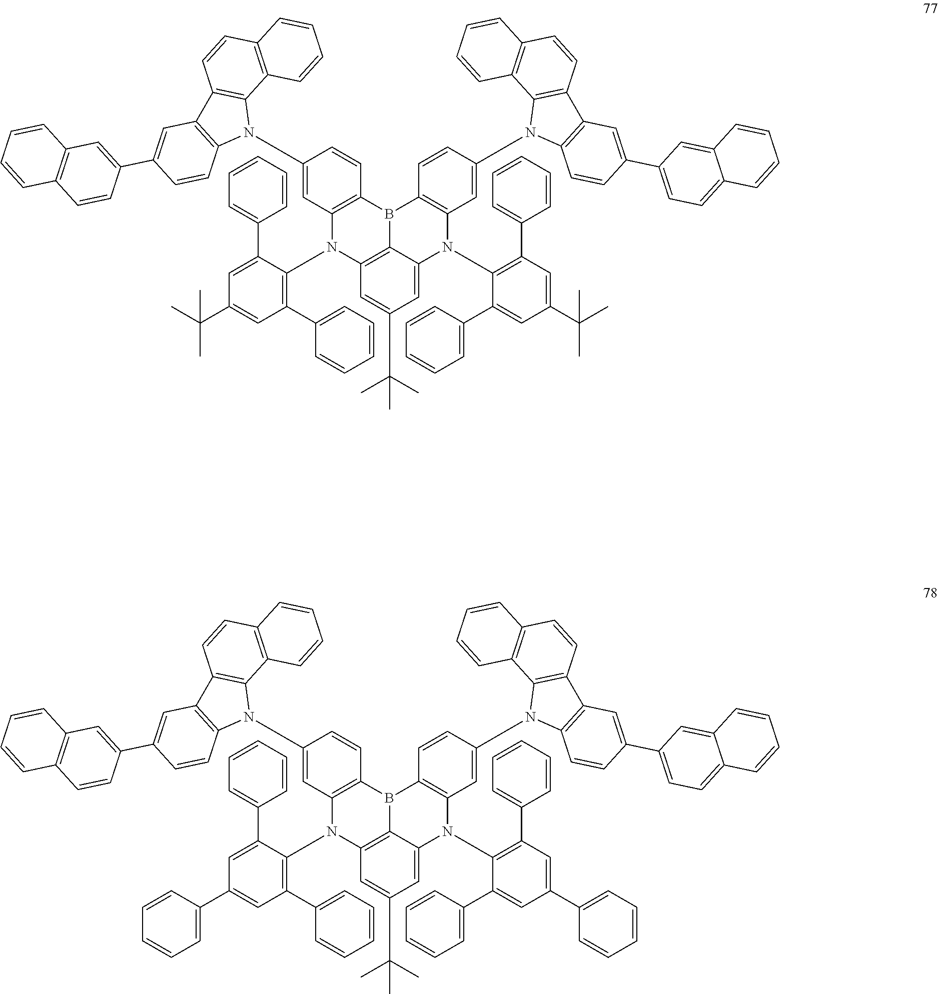 [SMILES: CC(C)(C)c1cc(-c2ccccc2)c(N2c3cc(-n4c5ccc(-c6ccc7ccccc7c6)cc5c5ccc6ccccc6c54)ccc3B3c4ccc(-n5c6ccc(-c7ccc8ccccc8c7)cc6c6ccc7ccccc7c65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc2c3c(c1)N(c1c(-c4ccccc4)cc(-c4ccccc4)cc1-c1ccccc1)c1cc(-n4c5ccc(-c6ccc7ccccc7c6)cc5c5ccc6ccccc6c54)ccc1B3c1ccc(-n3c4ccc(-c5ccc6ccccc6c5)cc4c4ccc5ccccc5c43)cc1N2c1c(-c2ccccc2)cc(-c2ccccc2)cc1-c1ccccc1]

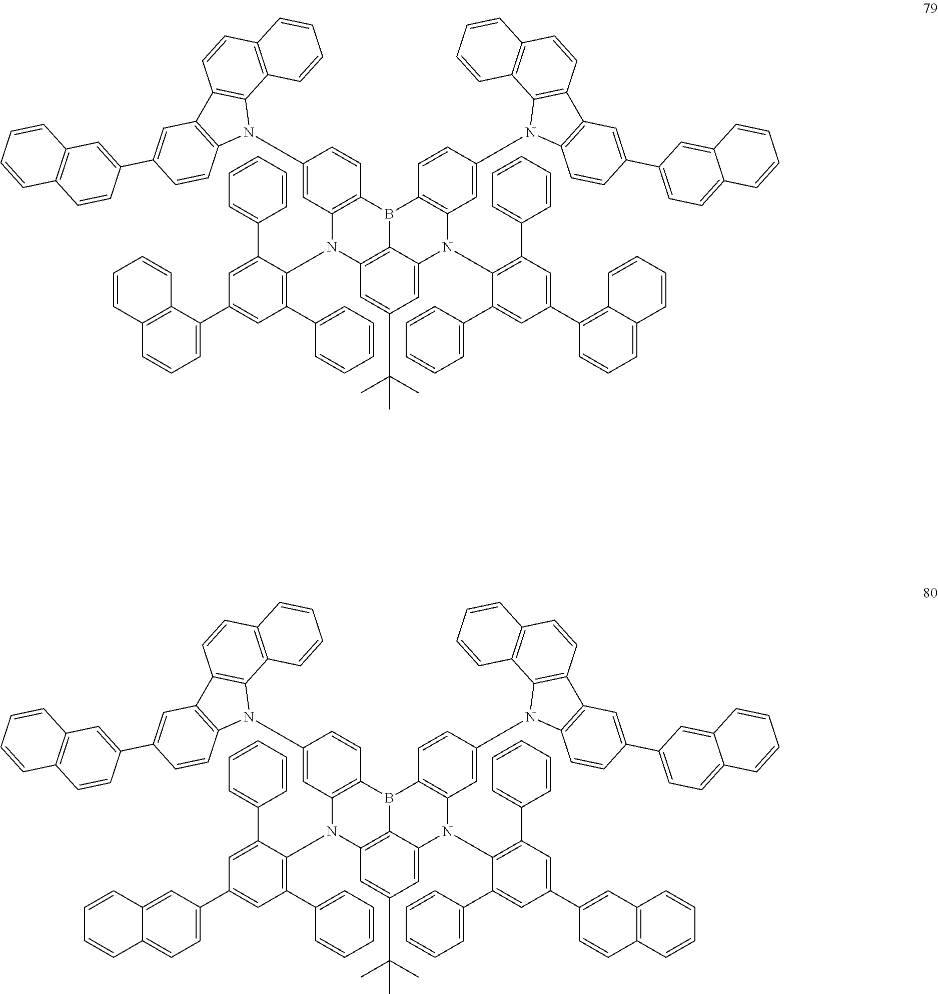 [SMILES: CC(C)(C)c1cc2c3c(c1)N(c1c(-c4ccccc4)cc(-c4cccc5ccccc45)cc1-c1ccccc1)c1cc(-n4c5ccc(-c6ccc7ccccc7c6)cc5c5ccc6ccccc6c54)ccc1B3c1ccc(-n3c4ccc(-c5ccc6ccccc6c5)cc4c4ccc5ccccc5c43)cc1N2c1c(-c2ccccc2)cc(-c2cccc3ccccc23)cc1-c1ccccc1 ; CC(C)(C)c1cc2c3c(c1)N(c1c(-c4ccccc4)cc(-c4ccc5ccccc5c4)cc1-c1ccccc1)c1cc(-n4c5ccc(-c6ccc7ccccc7c6)cc5c5ccc6ccccc6c54)ccc1B3c1ccc(-n3c4ccc(-c5ccc6ccccc6c5)cc4c4ccc5ccccc5c43)cc1N2c1c(-c2ccccc2)cc(-c2ccc3ccccc3c2)cc1-c1ccccc1]

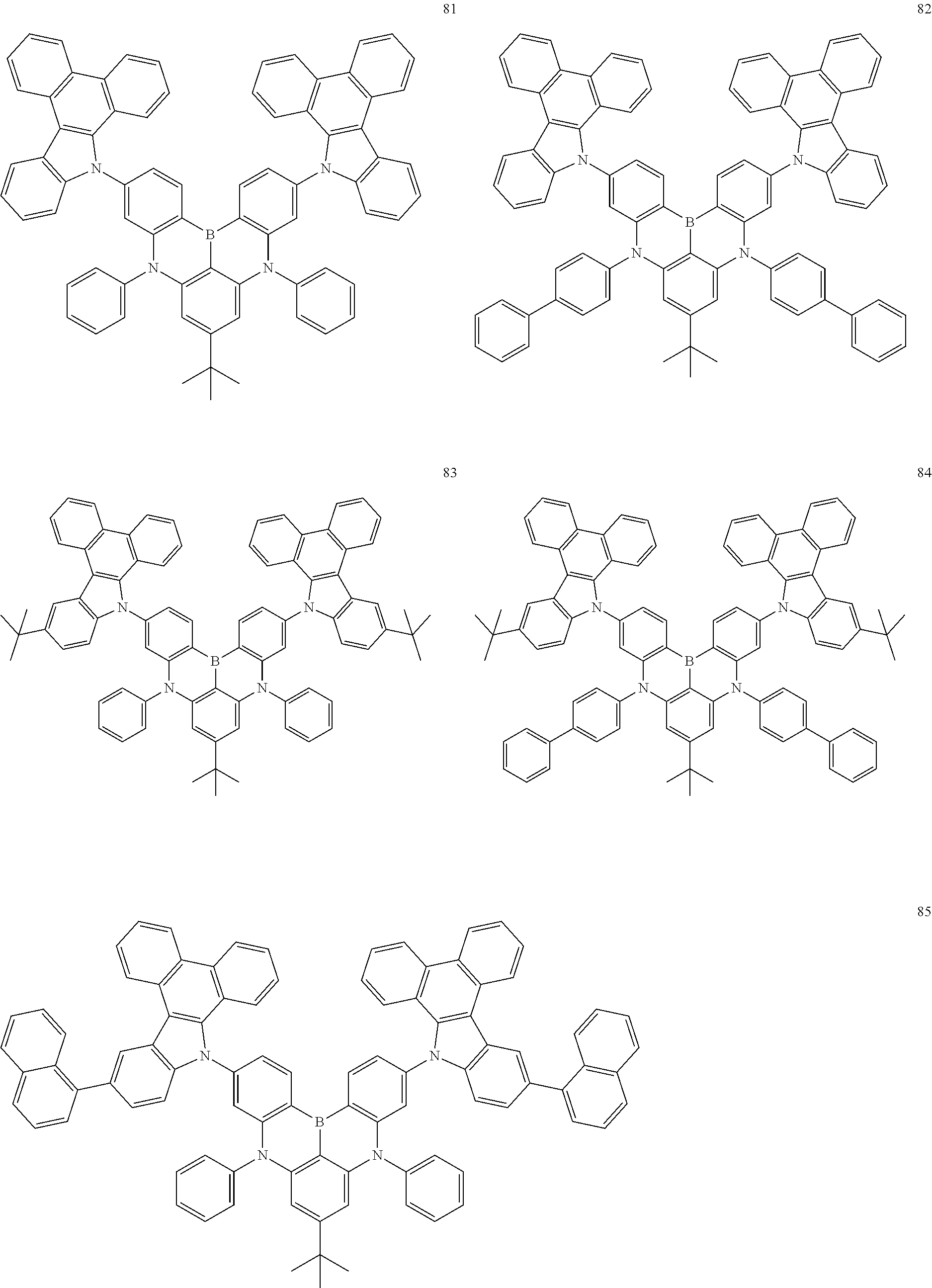

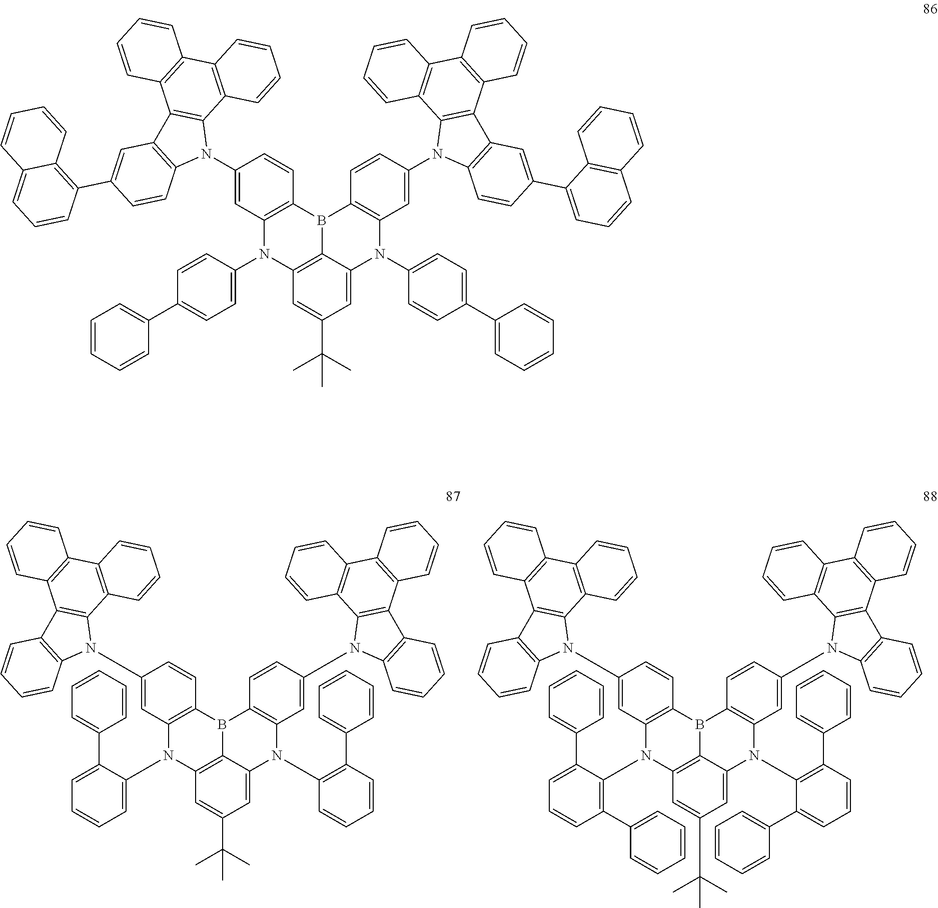

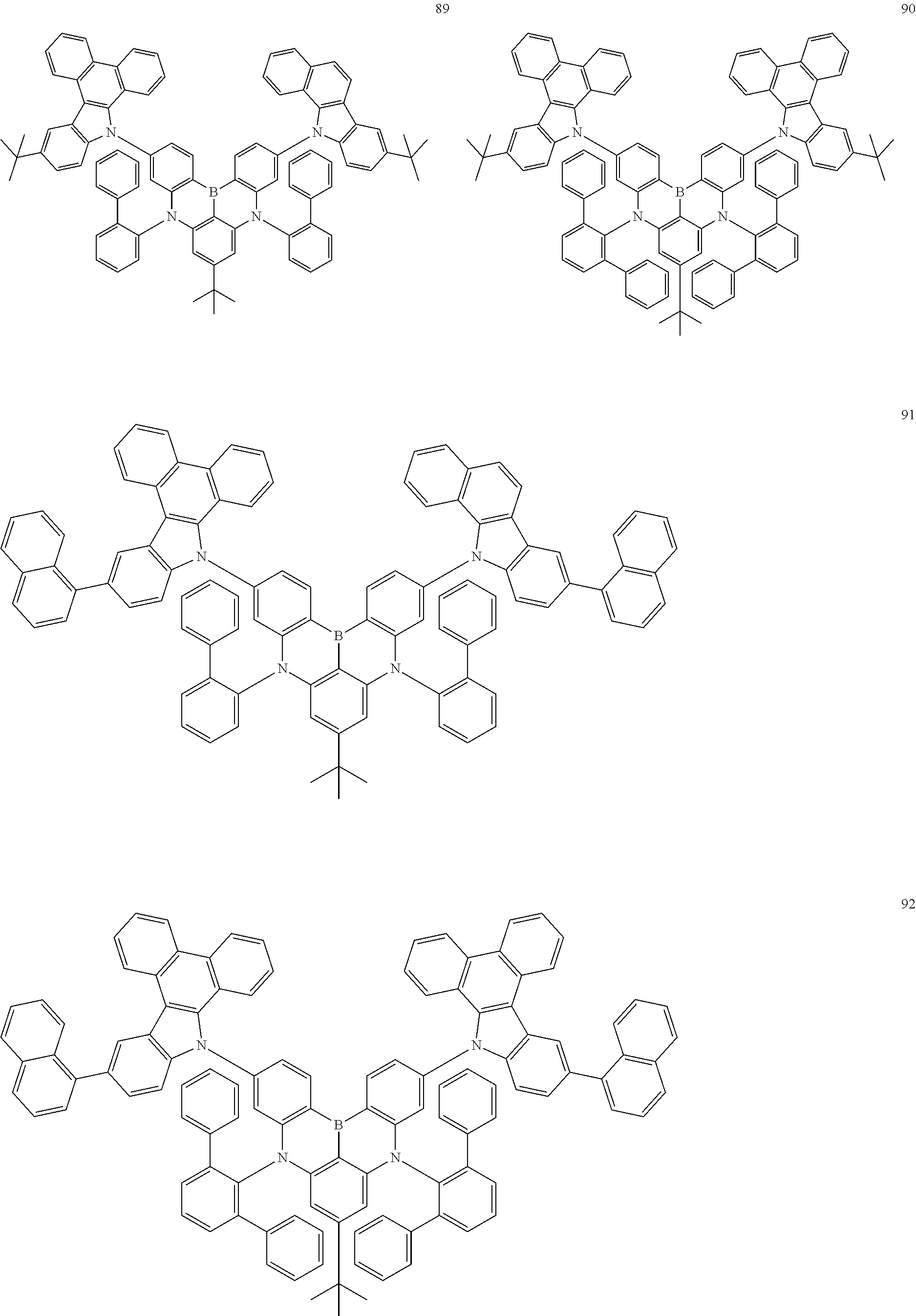

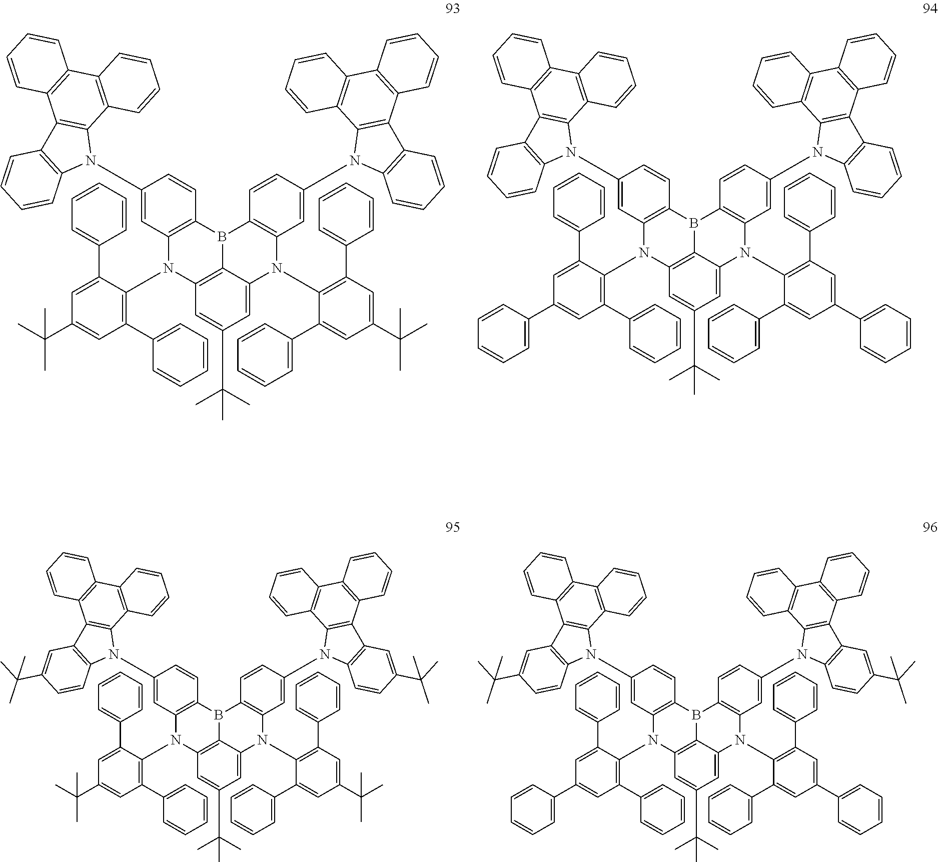

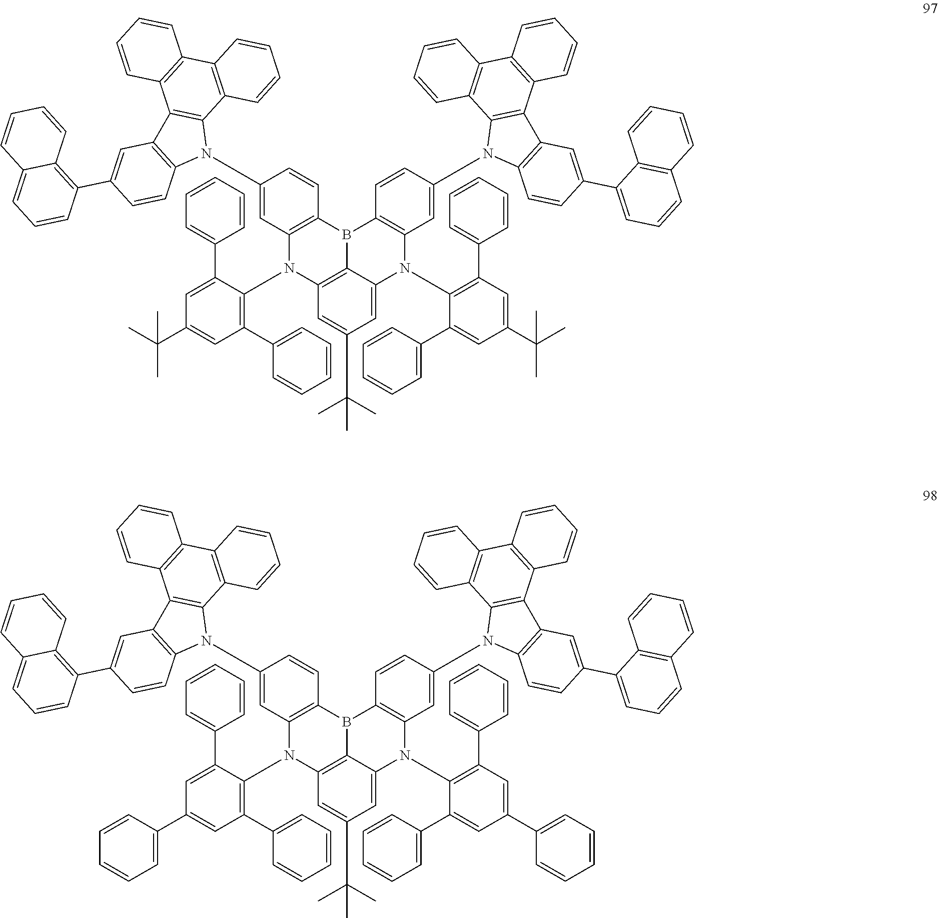 [SMILES: CC(C)(C)c1cc(-c2ccccc2)c(N2c3cc(-n4c5ccc(-c6cccc7ccccc67)cc5c5c6ccccc6c6ccccc6c54)ccc3B3c4ccc(-n5c6ccc(-c7cccc8ccccc78)cc6c6c7ccccc7c7ccccc7c65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc2c3c(c1)N(c1c(-c4ccccc4)cc(-c4ccccc4)cc1-c1ccccc1)c1cc(-n4c5ccc(-c6cccc7ccccc67)cc5c5c6ccccc6c6ccccc6c54)ccc1B3c1ccc(-n3c4ccc(-c5cccc6ccccc56)cc4c4c5ccccc5c5ccccc5c43)cc1N2c1c(-c2ccccc2)cc(-c2ccccc2)cc1-c1ccccc1]

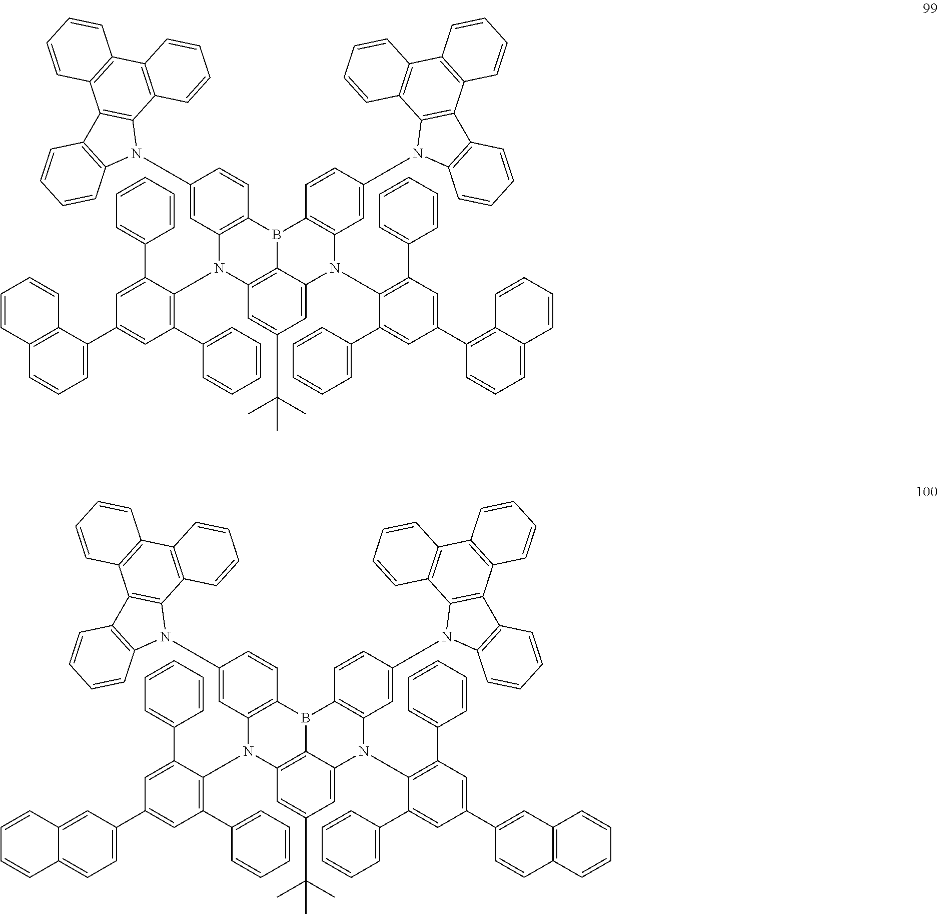 [SMILES: CC(C)(C)c1cc2c3c(c1)N(c1c(-c4ccccc4)cc(-c4cccc5ccccc45)cc1-c1ccccc1)c1cc(-n4c5ccccc5c5c6ccccc6c6ccccc6c54)ccc1B3c1ccc(-n3c4ccccc4c4c5ccccc5c5ccccc5c43)cc1N2c1c(-c2ccccc2)cc(-c2cccc3ccccc23)cc1-c1ccccc1 ; CC(C)(C)c1cc2c3c(c1)N(c1c(-c4ccccc4)cc(-c4ccc5ccccc5c4)cc1-c1ccccc1)c1cc(-n4c5ccccc5c5c6ccccc6c6ccccc6c54)ccc1B3c1ccc(-n3c4ccccc4c4c5ccccc5c5ccccc5c43)cc1N2c1c(-c2ccccc2)cc(-c2ccc3ccccc3c2)cc1-c1ccccc1]

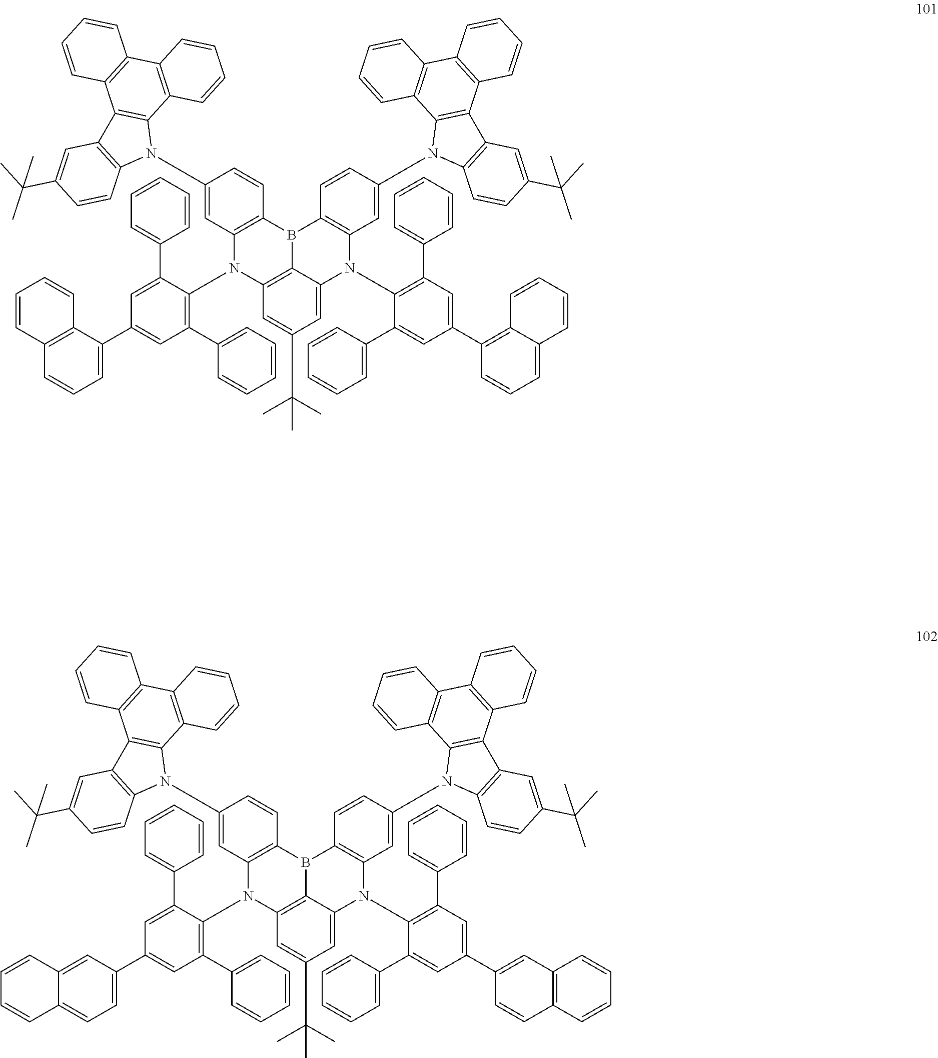 [SMILES: CC(C)(C)c1cc2c3c(c1)N(c1c(-c4ccccc4)cc(-c4cccc5ccccc45)cc1-c1ccccc1)c1cc(-n4c5ccc(C(C)(C)C)cc5c5c6ccccc6c6ccccc6c54)ccc1B3c1ccc(-n3c4ccc(C(C)(C)C)cc4c4c5ccccc5c5ccccc5c43)cc1N2c1c(-c2ccccc2)cc(-c2cccc3ccccc23)cc1-c1ccccc1 ; CC(C)(C)c1cc2c3c(c1)N(c1c(-c4ccccc4)cc(-c4ccc5ccccc5c4)cc1-c1ccccc1)c1cc(-n4c5ccc(C(C)(C)C)cc5c5c6ccccc6c6ccccc6c54)ccc1B3c1ccc(-n3c4ccc(C(C)(C)C)cc4c4c5ccccc5c5ccccc5c43)cc1N2c1c(-c2ccccc2)cc(-c2ccc3ccccc3c2)cc1-c1ccccc1]

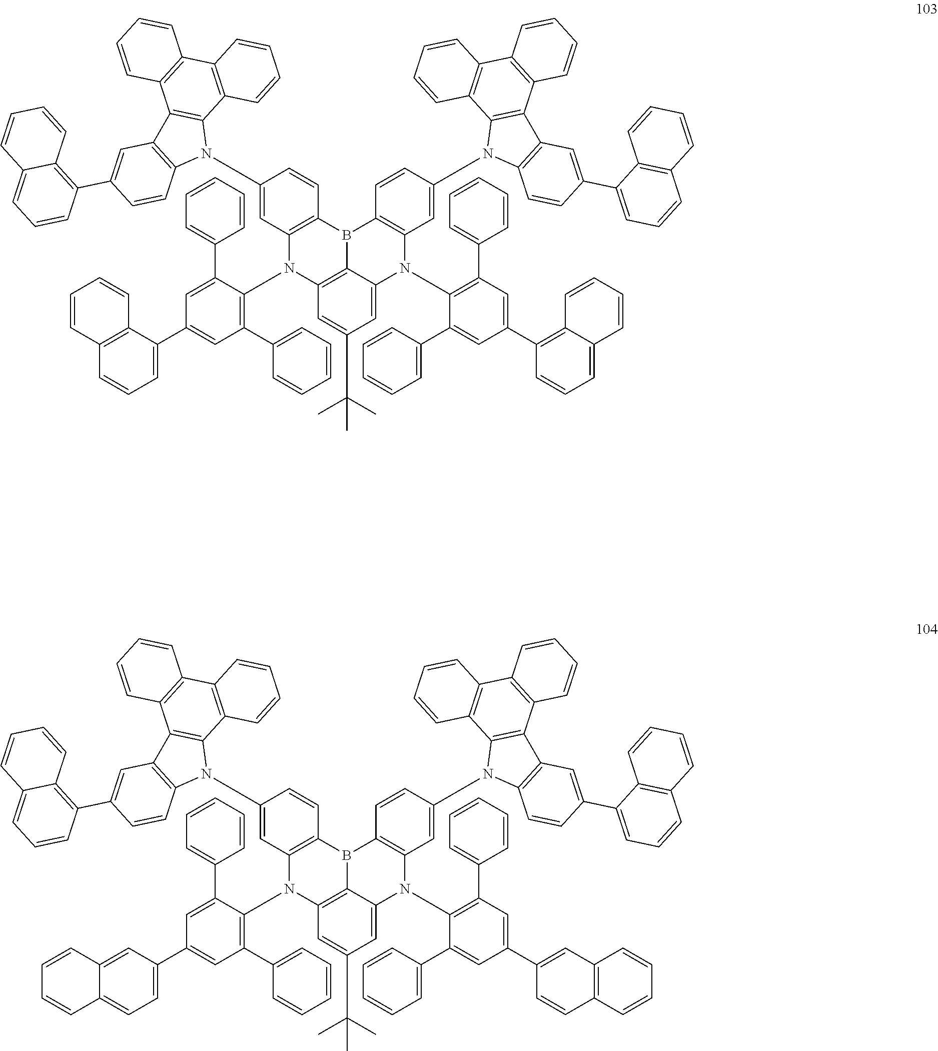 [SMILES: CC(C)(C)c1cc2c3c(c1)N(c1c(-c4ccccc4)cc(-c4cccc5ccccc45)cc1-c1ccccc1)c1cc(-n4c5ccc(-c6cccc7ccccc67)cc5c5c6ccccc6c6ccccc6c54)ccc1B3c1ccc(-n3c4ccc(-c5cccc6ccccc56)cc4c4c5ccccc5c5ccccc5c43)cc1N2c1c(-c2ccccc2)cc(-c2cccc3ccccc23)cc1-c1ccccc1 ; CC(C)(C)c1cc2c3c(c1)N(c1c(-c4ccccc4)cc(-c4ccc5ccccc5c4)cc1-c1ccccc1)c1cc(-n4c5ccc(-c6cccc7ccccc67)cc5c5c6ccccc6c6ccccc6c54)ccc1B3c1ccc(-n3c4ccc(-c5cccc6ccccc56)cc4c4c5ccccc5c5ccccc5c43)cc1N2c1c(-c2ccccc2)cc(-c2ccc3ccccc3c2)cc1-c1ccccc1]

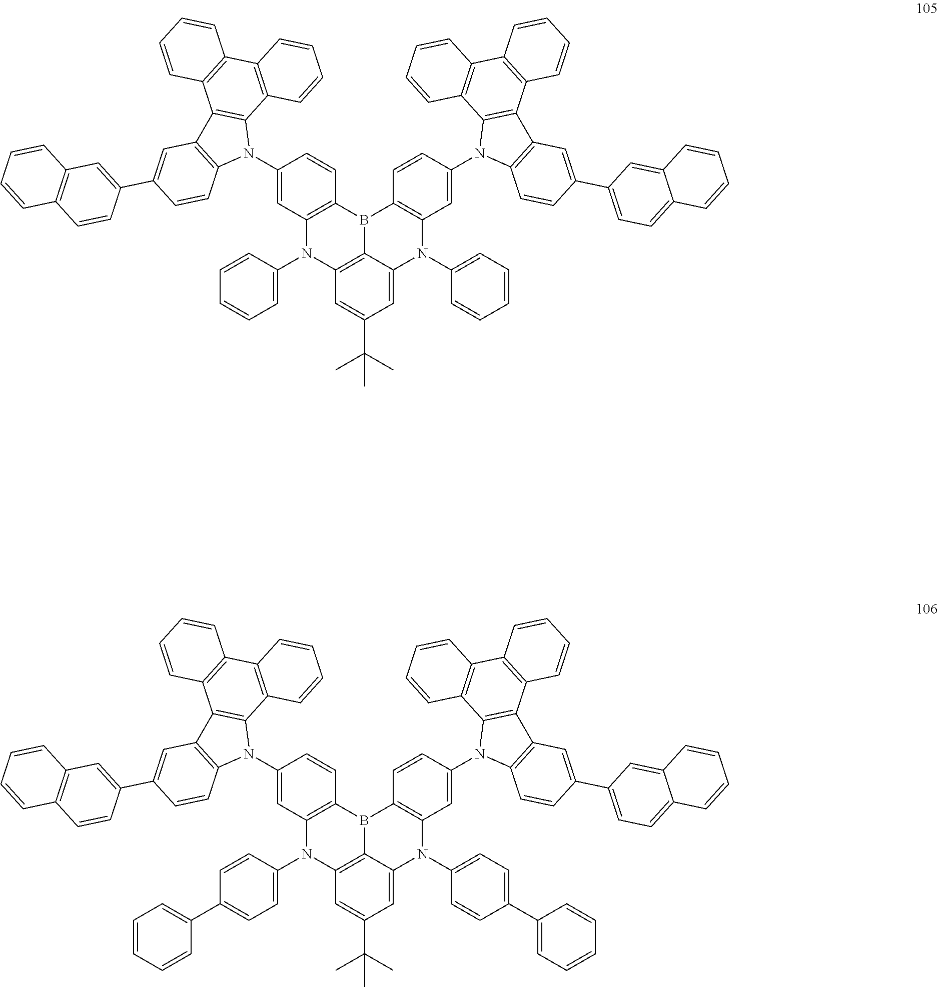 [SMILES: CC(C)(C)c1cc2c3c(c1)N(c1ccccc1)c1cc(-n4c5ccc(-c6ccc7ccccc7c6)cc5c5c6ccccc6c6ccccc6c54)ccc1B3c1ccc(-n3c4ccc(-c5ccc6ccccc6c5)cc4c4c5ccccc5c5ccccc5c43)cc1N2c1ccccc1 ; CC(C)(C)c1cc2c3c(c1)N(c1ccc(-c4ccccc4)cc1)c1cc(-n4c5ccc(-c6ccc7ccccc7c6)cc5c5c6ccccc6c6ccccc6c54)ccc1B3c1ccc(-n3c4ccc(-c5ccc6ccccc6c5)cc4c4c5ccccc5c5ccccc5c43)cc1N2c1ccc(-c2ccccc2)cc1]

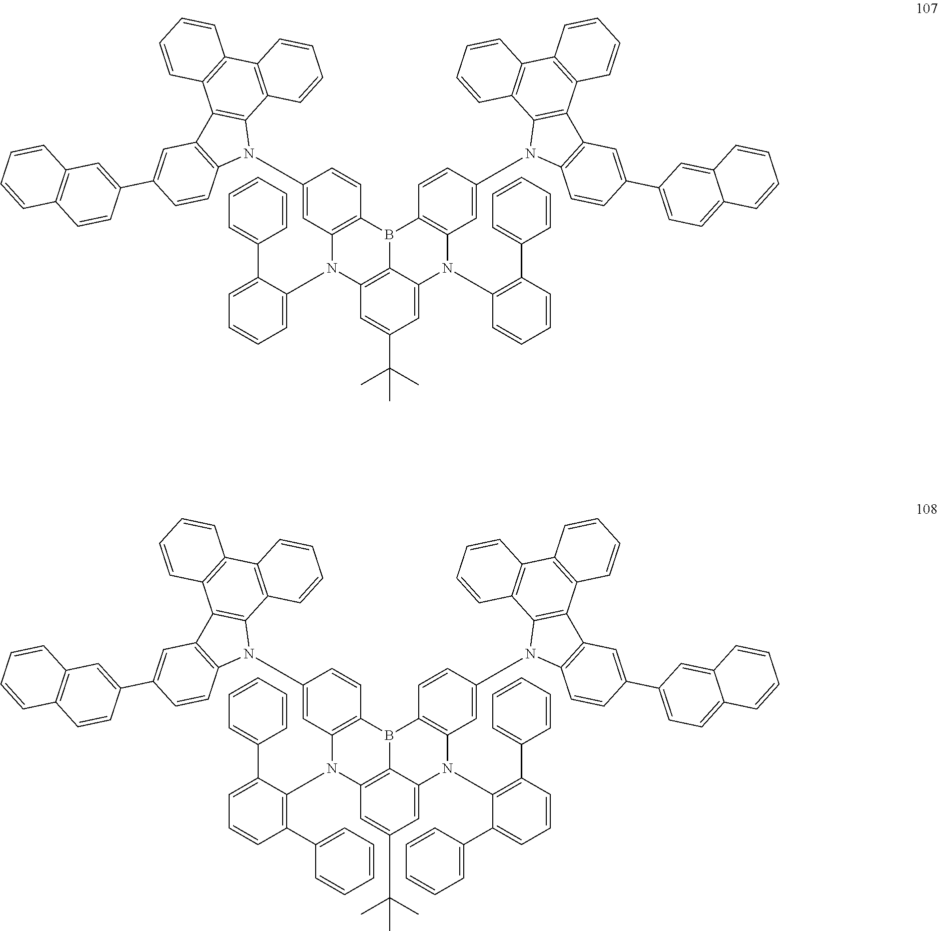 [SMILES: CC(C)(C)c1cc2c3c(c1)N(c1ccccc1-c1ccccc1)c1cc(-n4c5ccc(-c6ccc7ccccc7c6)cc5c5c6ccccc6c6ccccc6c54)ccc1B3c1ccc(-n3c4ccc(-c5ccc6ccccc6c5)cc4c4c5ccccc5c5ccccc5c43)cc1N2c1ccccc1-c1ccccc1 ; CC(C)(C)c1cc2c3c(c1)N(c1c(-c4ccccc4)cccc1-c1ccccc1)c1cc(-n4c5ccc(-c6ccc7ccccc7c6)cc5c5c6ccccc6c6ccccc6c54)ccc1B3c1ccc(-n3c4ccc(-c5ccc6ccccc6c5)cc4c4c5ccccc5c5ccccc5c43)cc1N2c1c(-c2ccccc2)cccc1-c1ccccc1]

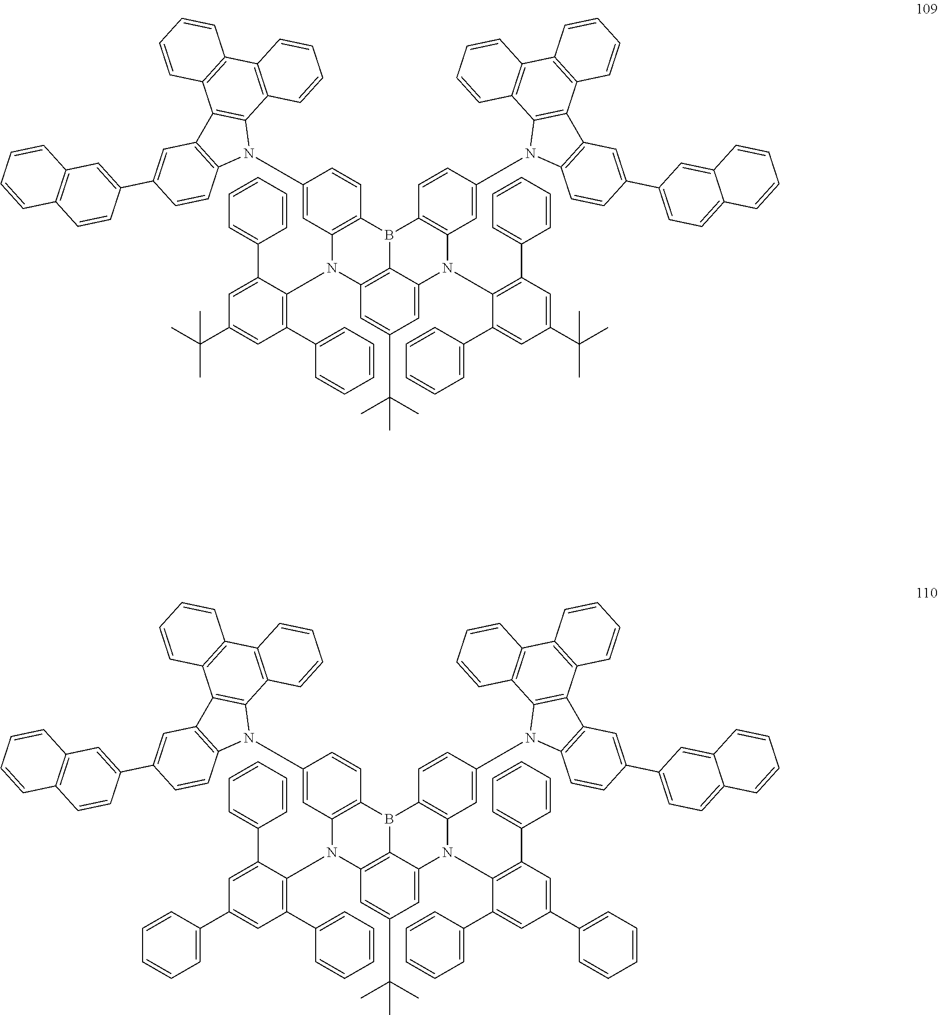 [SMILES: CC(C)(C)c1cc(-c2ccccc2)c(N2c3cc(-n4c5ccc(-c6ccc7ccccc7c6)cc5c5c6ccccc6c6ccccc6c54)ccc3B3c4ccc(-n5c6ccc(-c7ccc8ccccc8c7)cc6c6c7ccccc7c7ccccc7c65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc2c3c(c1)N(c1c(-c4ccccc4)cc(-c4ccccc4)cc1-c1ccccc1)c1cc(-n4c5ccc(-c6ccc7ccccc7c6)cc5c5c6ccccc6c6ccccc6c54)ccc1B3c1ccc(-n3c4ccc(-c5ccc6ccccc6c5)cc4c4c5ccccc5c5ccccc5c43)cc1N2c1c(-c2ccccc2)cc(-c2ccccc2)cc1-c1ccccc1]

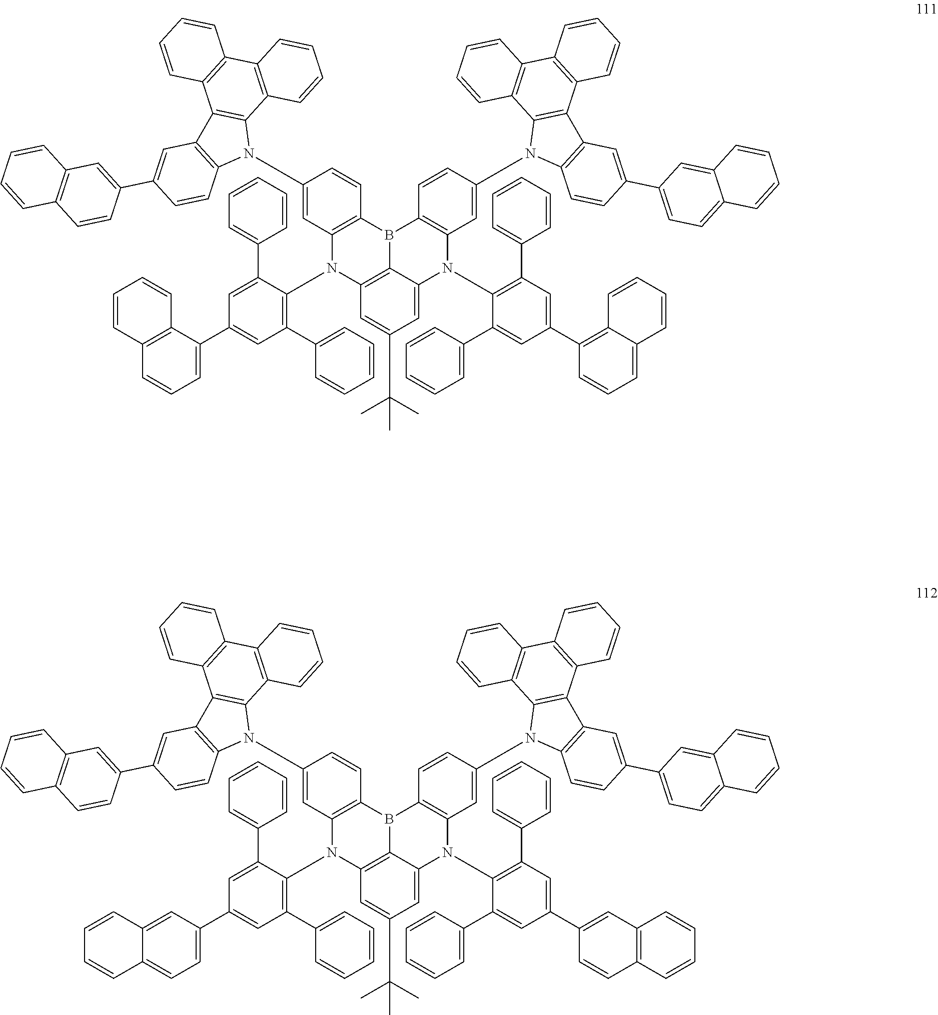 [SMILES: CC(C)(C)c1cc2c3c(c1)N(c1c(-c4ccccc4)cc(-c4cccc5ccccc45)cc1-c1ccccc1)c1cc(-n4c5ccc(-c6ccc7ccccc7c6)cc5c5c6ccccc6c6ccccc6c54)ccc1B3c1ccc(-n3c4ccc(-c5ccc6ccccc6c5)cc4c4c5ccccc5c5ccccc5c43)cc1N2c1c(-c2ccccc2)cc(-c2cccc3ccccc23)cc1-c1ccccc1 ; CC(C)(C)c1cc2c3c(c1)N(c1c(-c4ccccc4)cc(-c4ccc5ccccc5c4)cc1-c1ccccc1)c1cc(-n4c5ccc(-c6ccc7ccccc7c6)cc5c5c6ccccc6c6ccccc6c54)ccc1B3c1ccc(-n3c4ccc(-c5ccc6ccccc6c5)cc4c4c5ccccc5c5ccccc5c43)cc1N2c1c(-c2ccccc2)cc(-c2ccc3ccccc3c2)cc1-c1ccccc1]

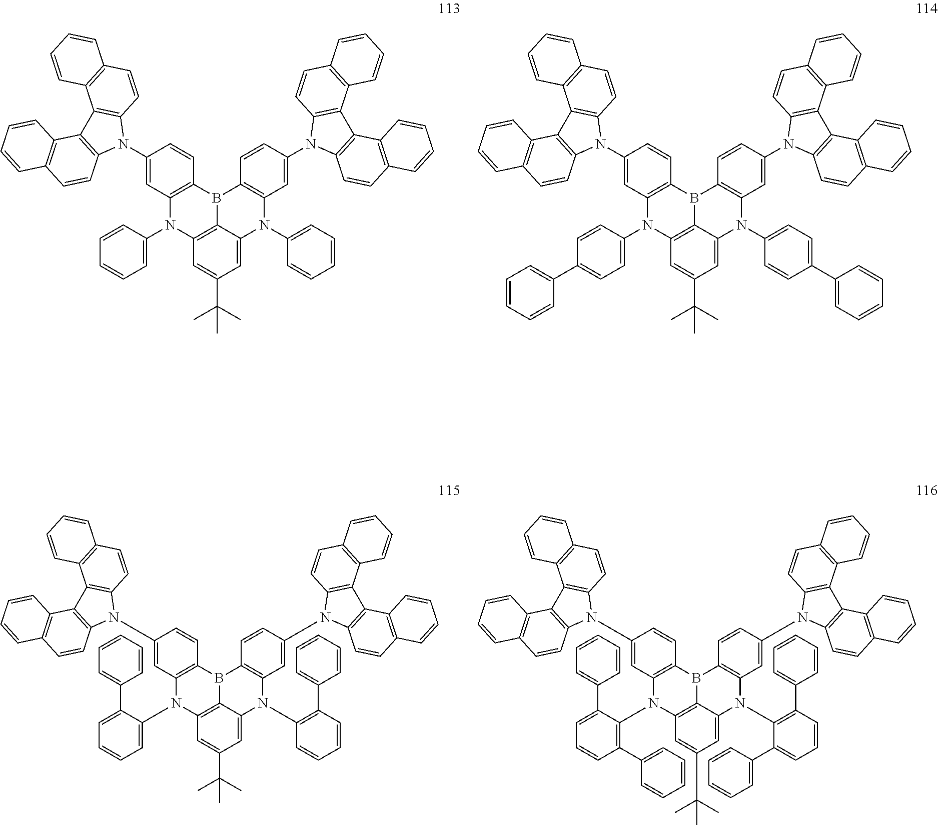

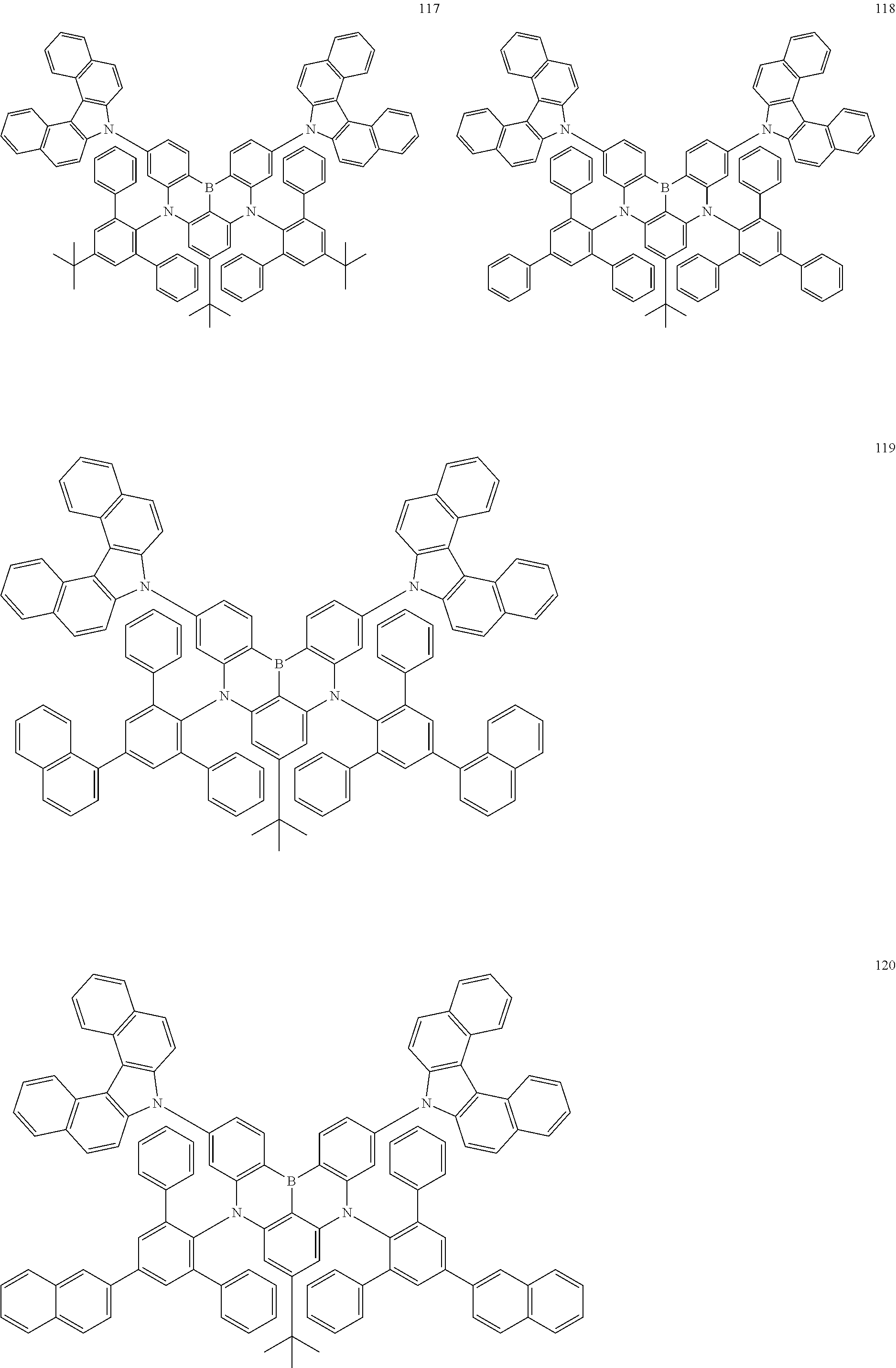

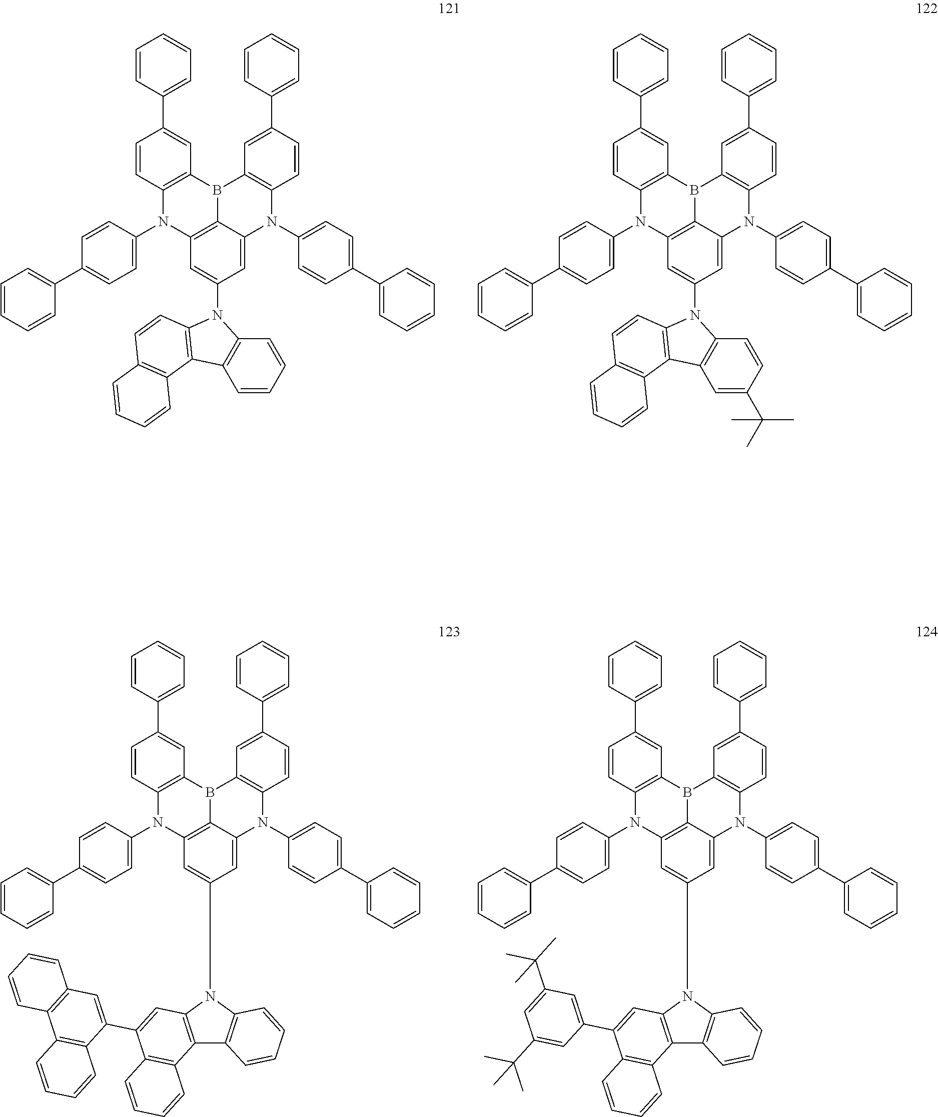

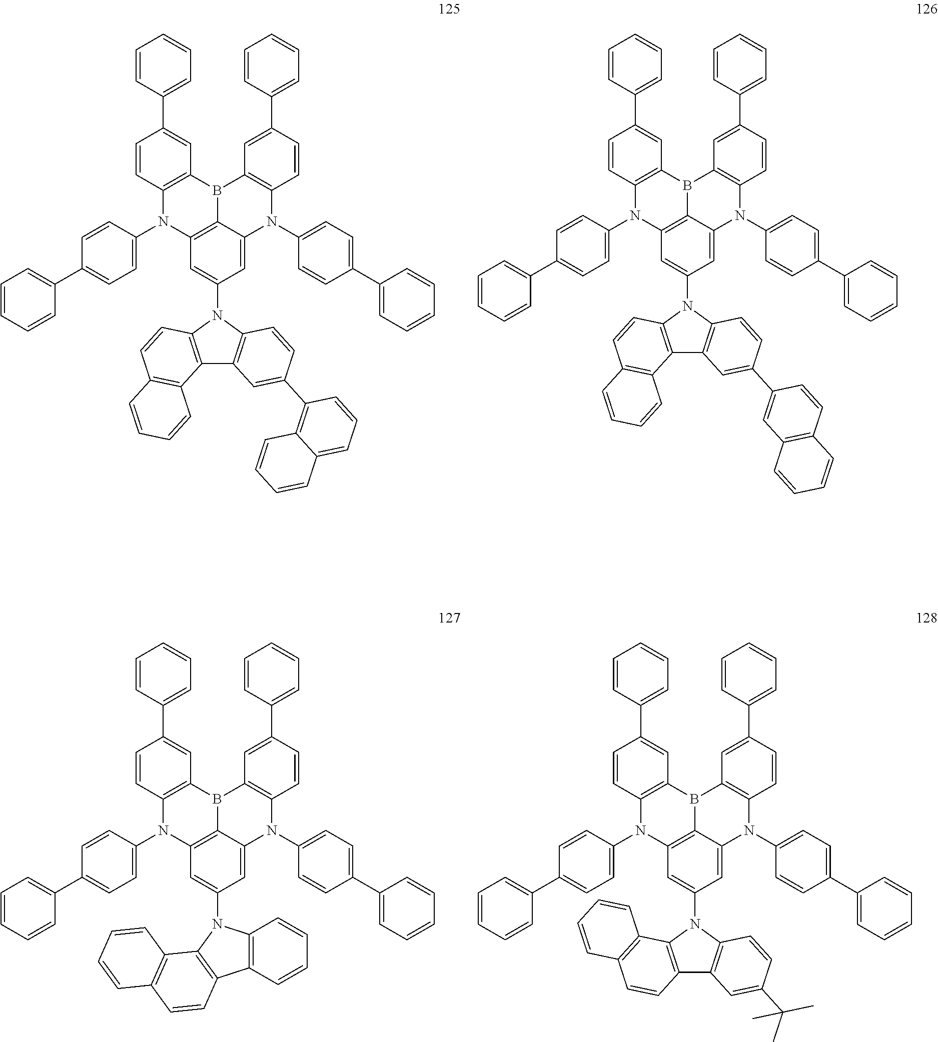

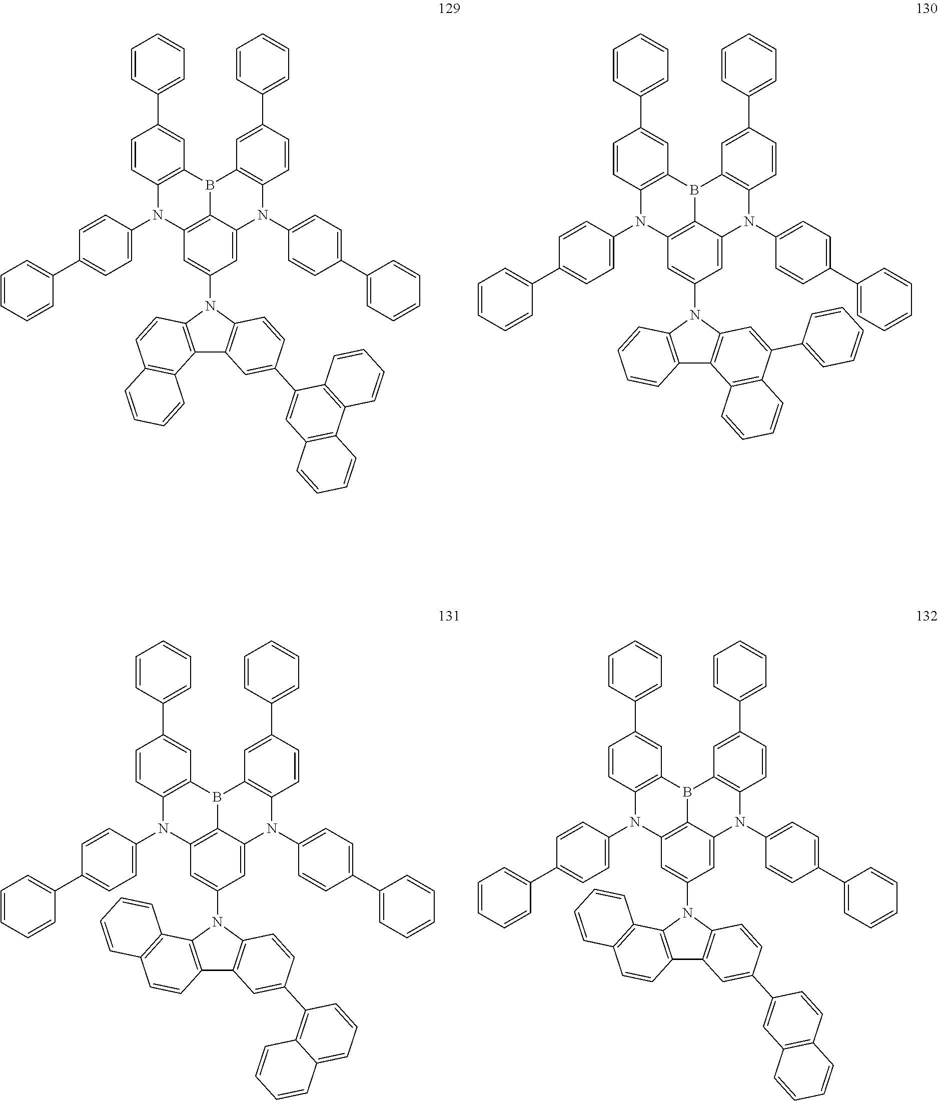

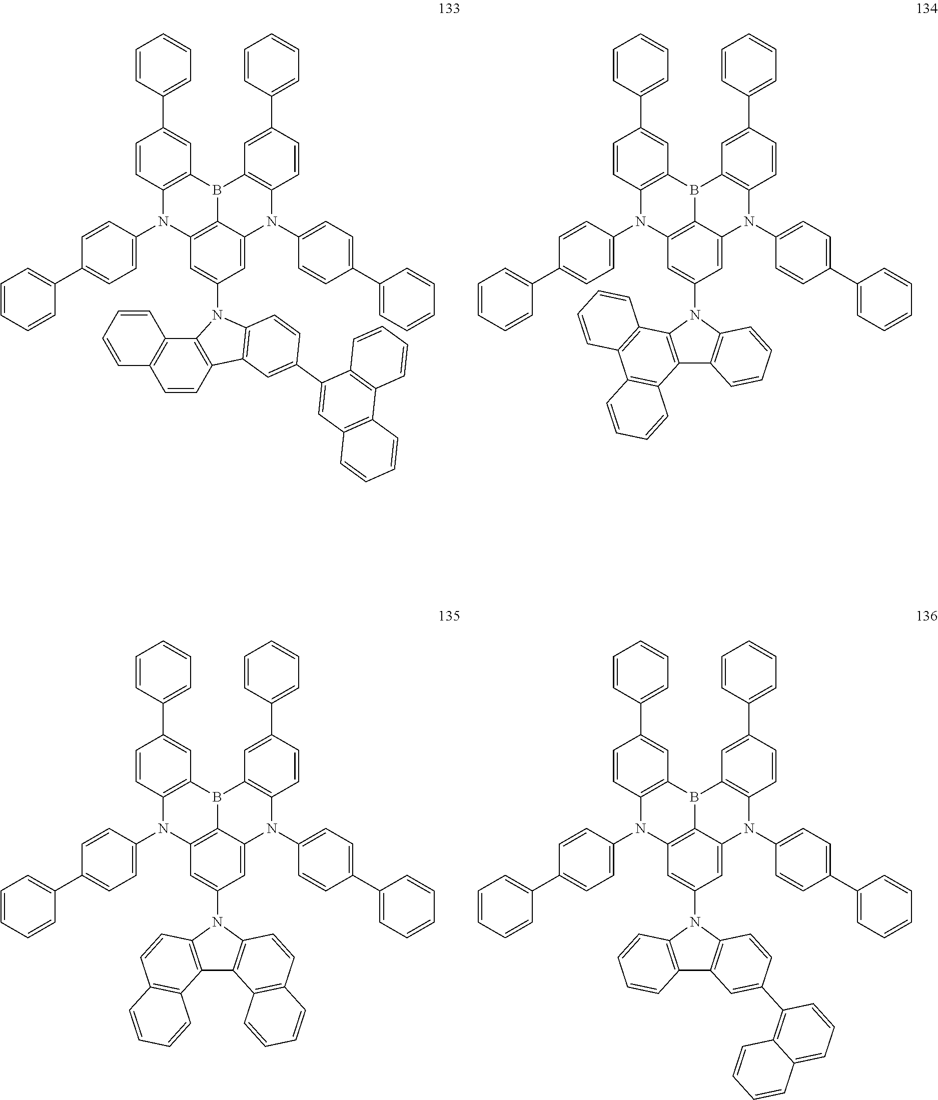

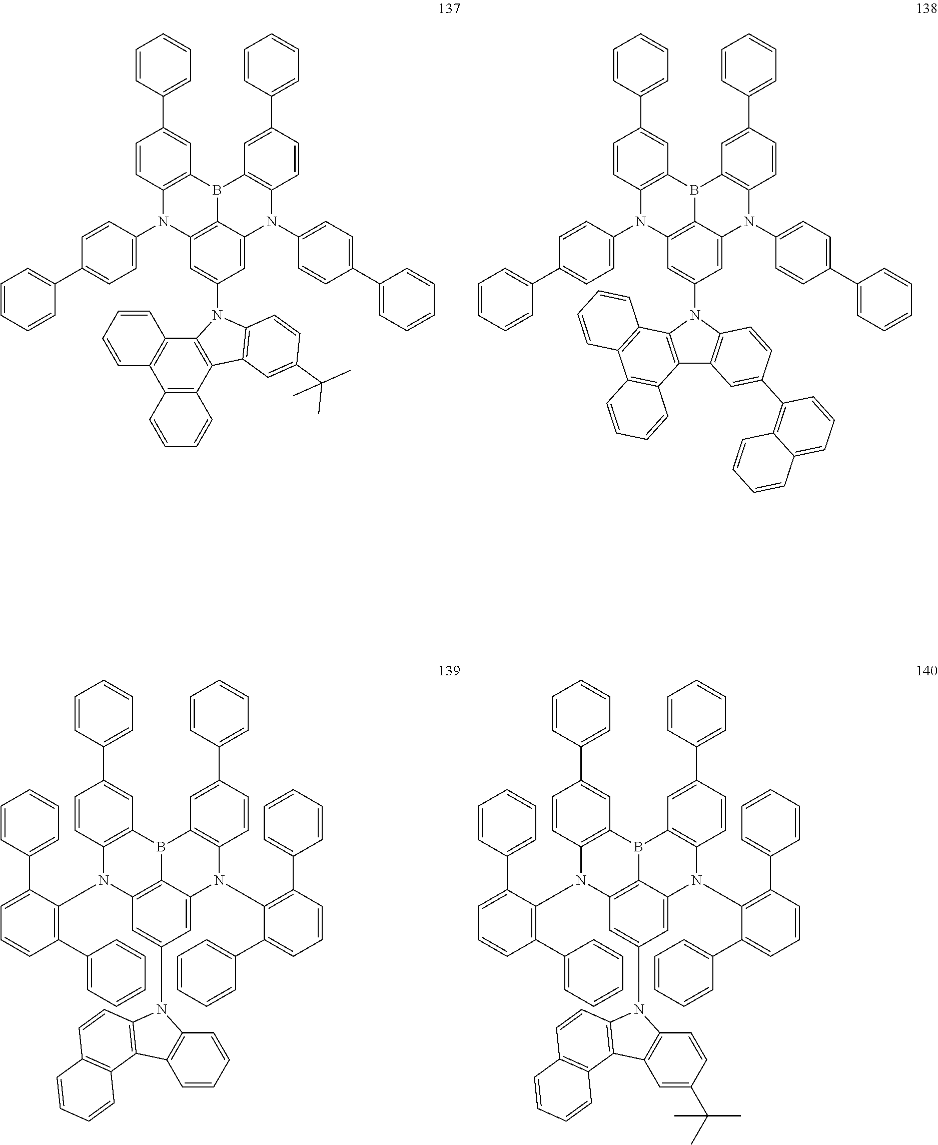

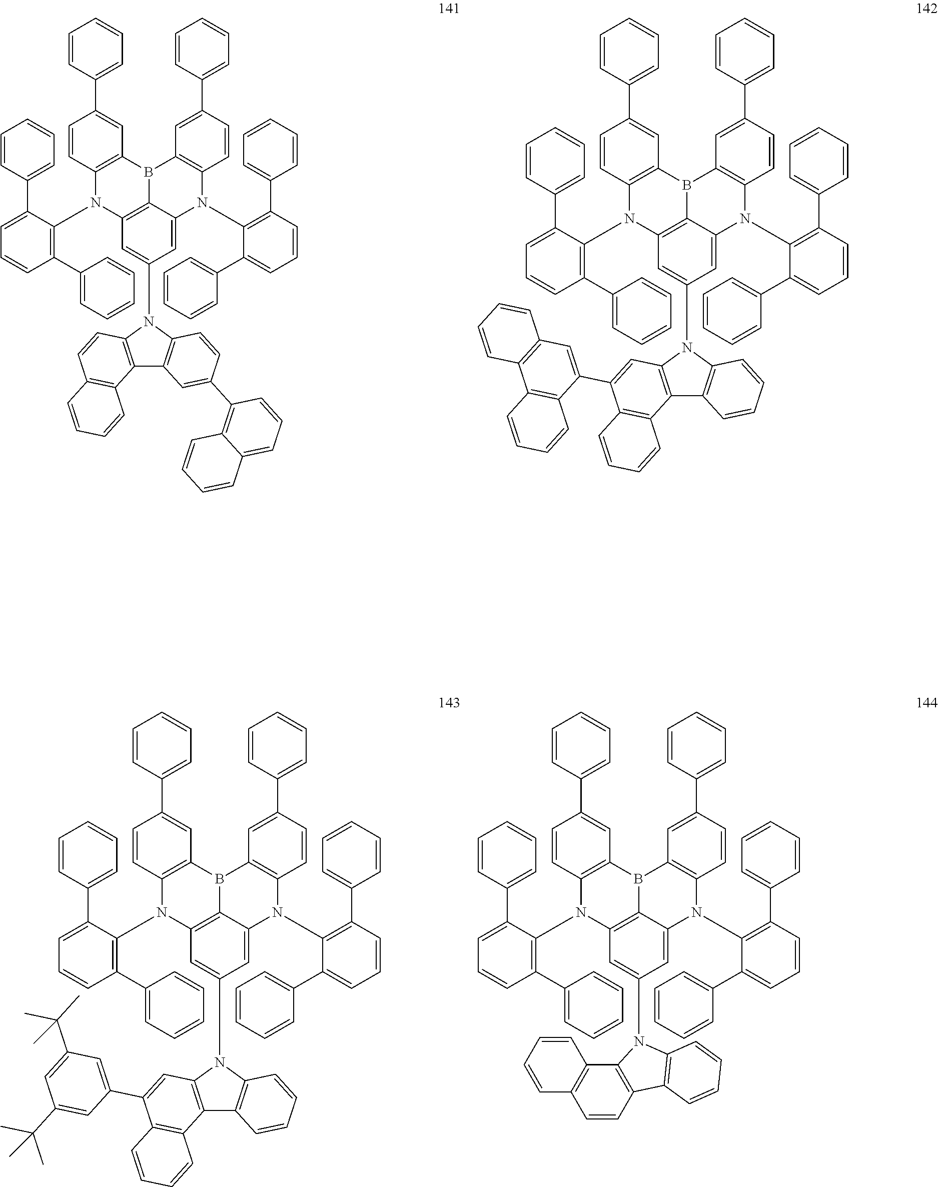

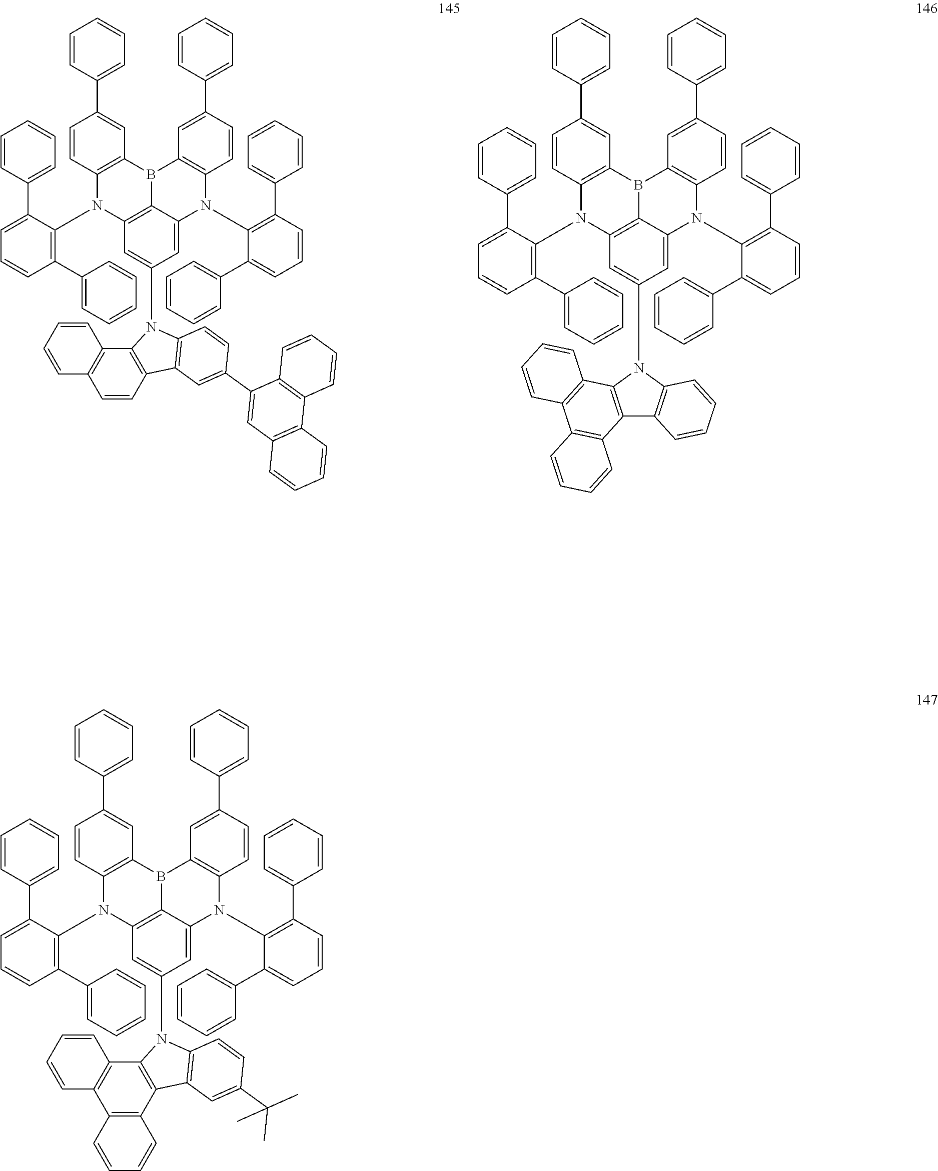 [SMILES: c1ccc(-c2ccc3c(c2)B2c4cc(-c5ccccc5)ccc4N(c4c(-c5ccccc5)cccc4-c4ccccc4)c4cc(-n5c6ccc(-c7cc8ccccc8c8ccccc78)cc6c6ccc7ccccc7c65)cc(c42)N3c2c(-c3ccccc3)cccc2-c2ccccc2)cc1 ; c1ccc(-c2ccc3c(c2)B2c4cc(-c5ccccc5)ccc4N(c4c(-c5ccccc5)cccc4-c4ccccc4)c4cc(-n5c6ccccc6c6c7ccccc7c7ccccc7c65)cc(c42)N3c2c(-c3ccccc3)cccc2-c2ccccc2)cc1 ; CC(C)(C)c1ccc2c(c1)c1c3ccccc3c3ccccc3c1n2-c1cc2c3c(c1)N(c1c(-c4ccccc4)cccc1-c1ccccc1)c1ccc(-c4ccccc4)cc1B3c1cc(-c3ccccc3)ccc1N2c1c(-c2ccccc2)cccc1-c1ccccc1]

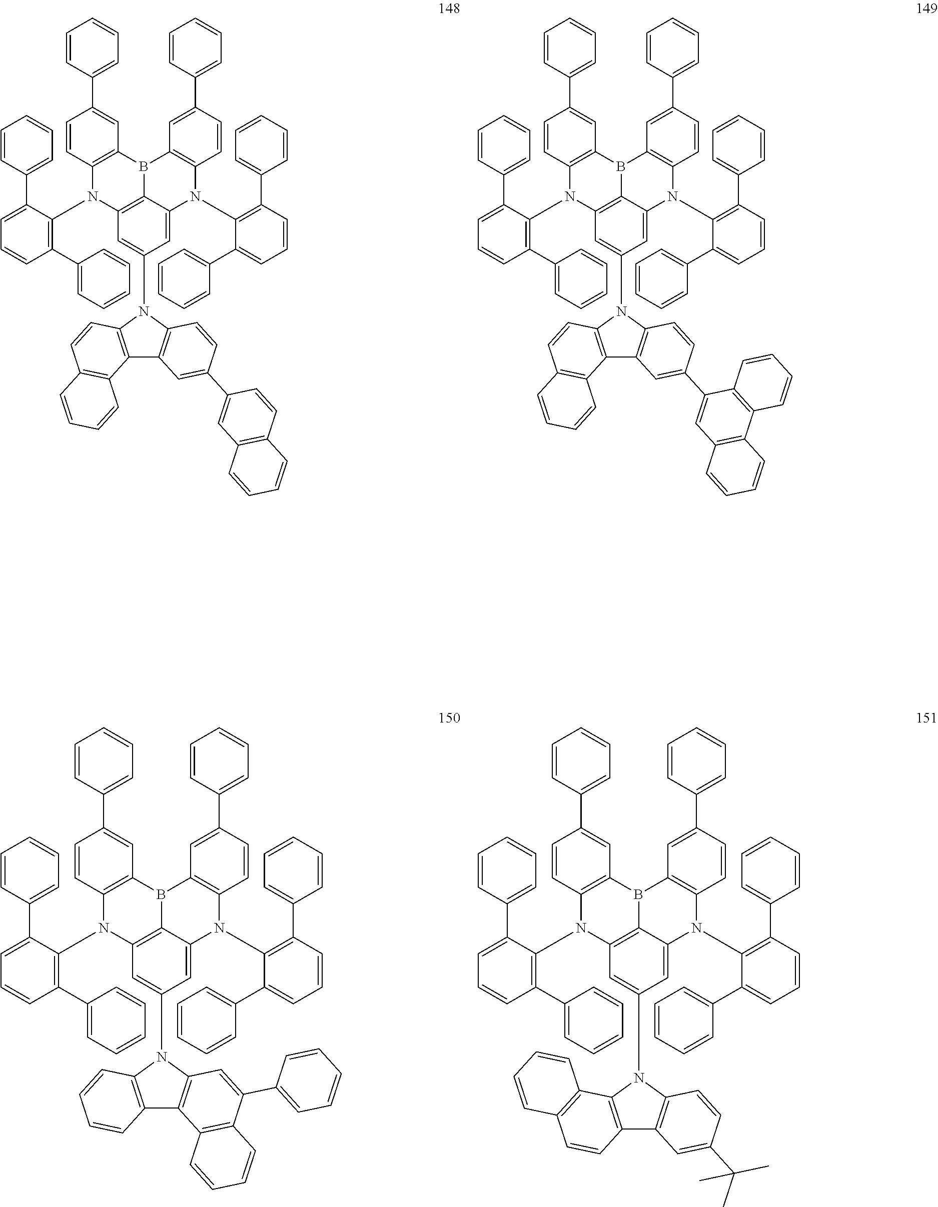

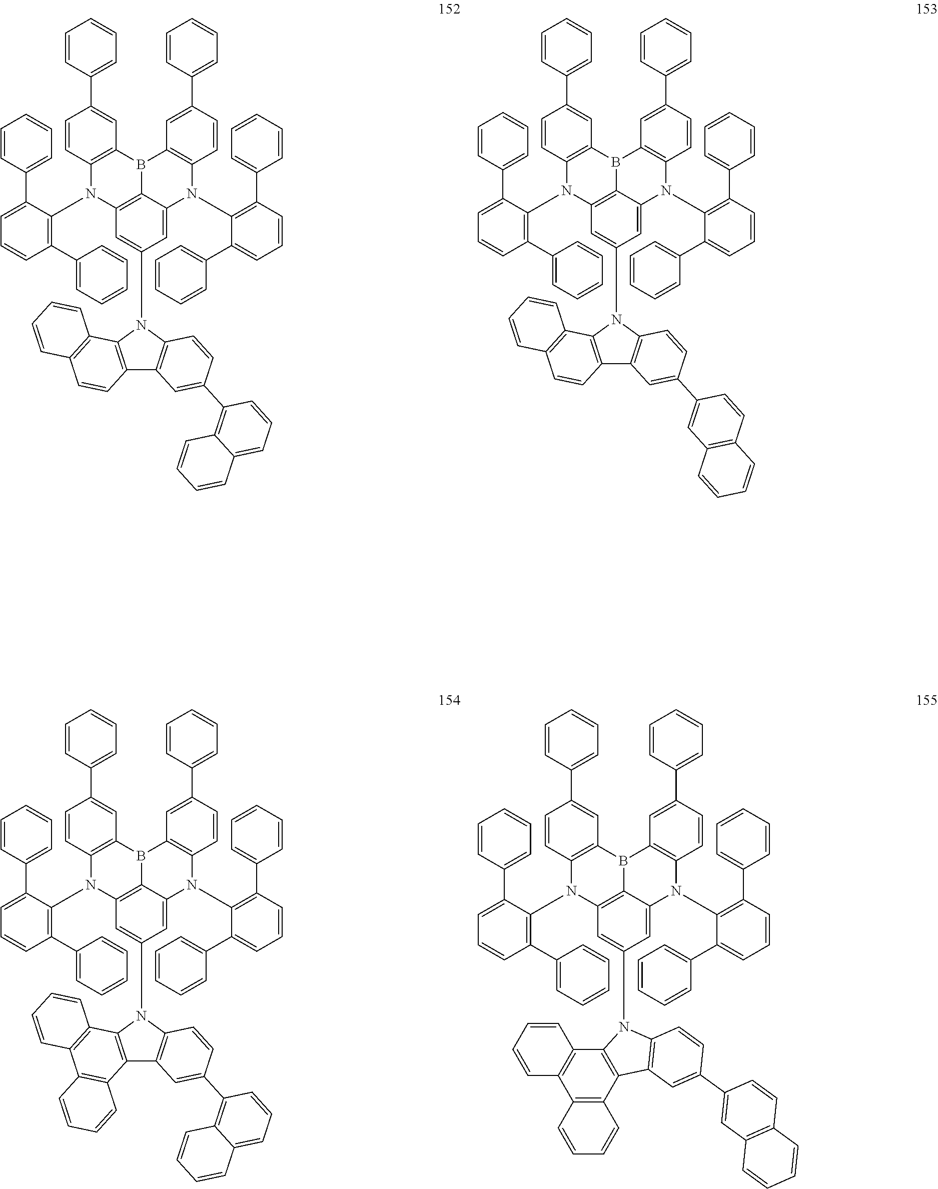

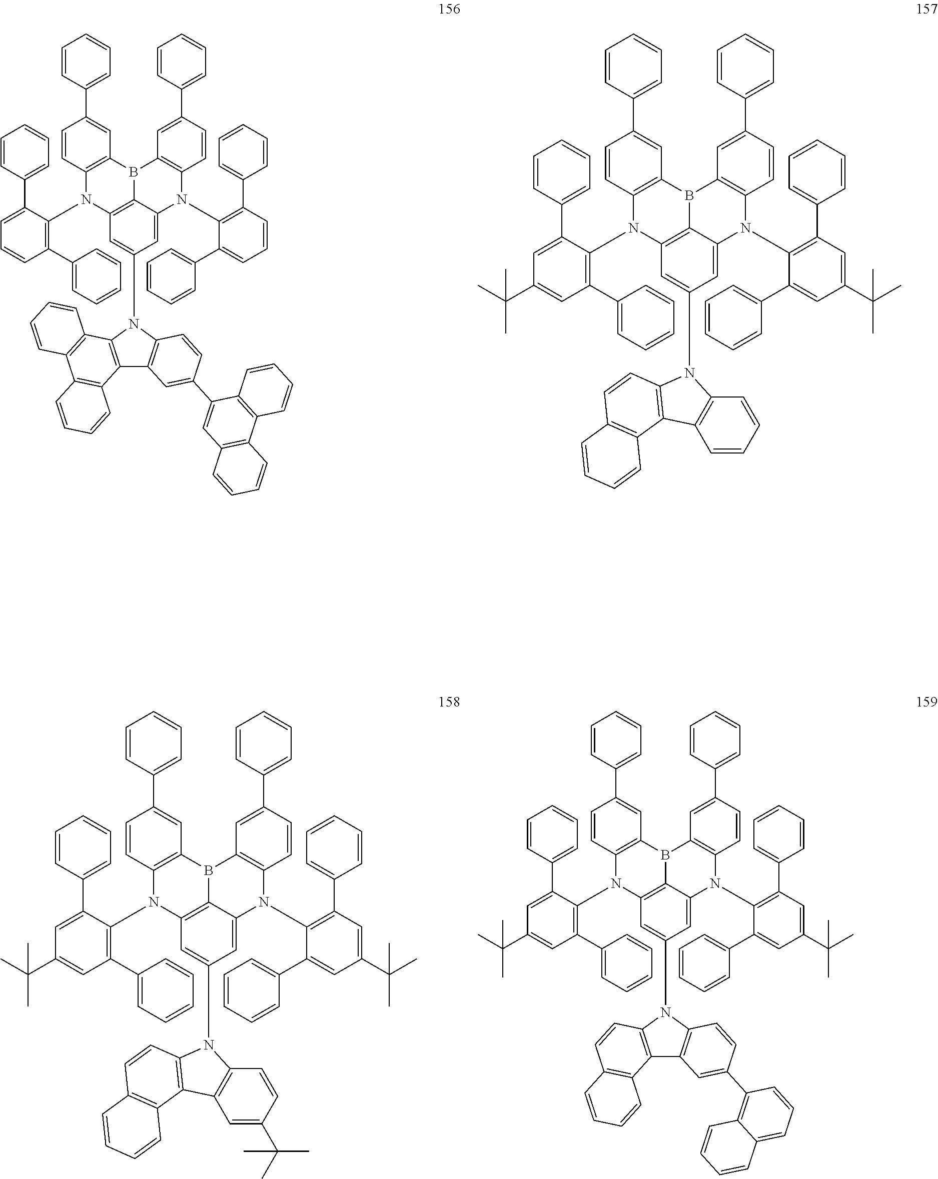

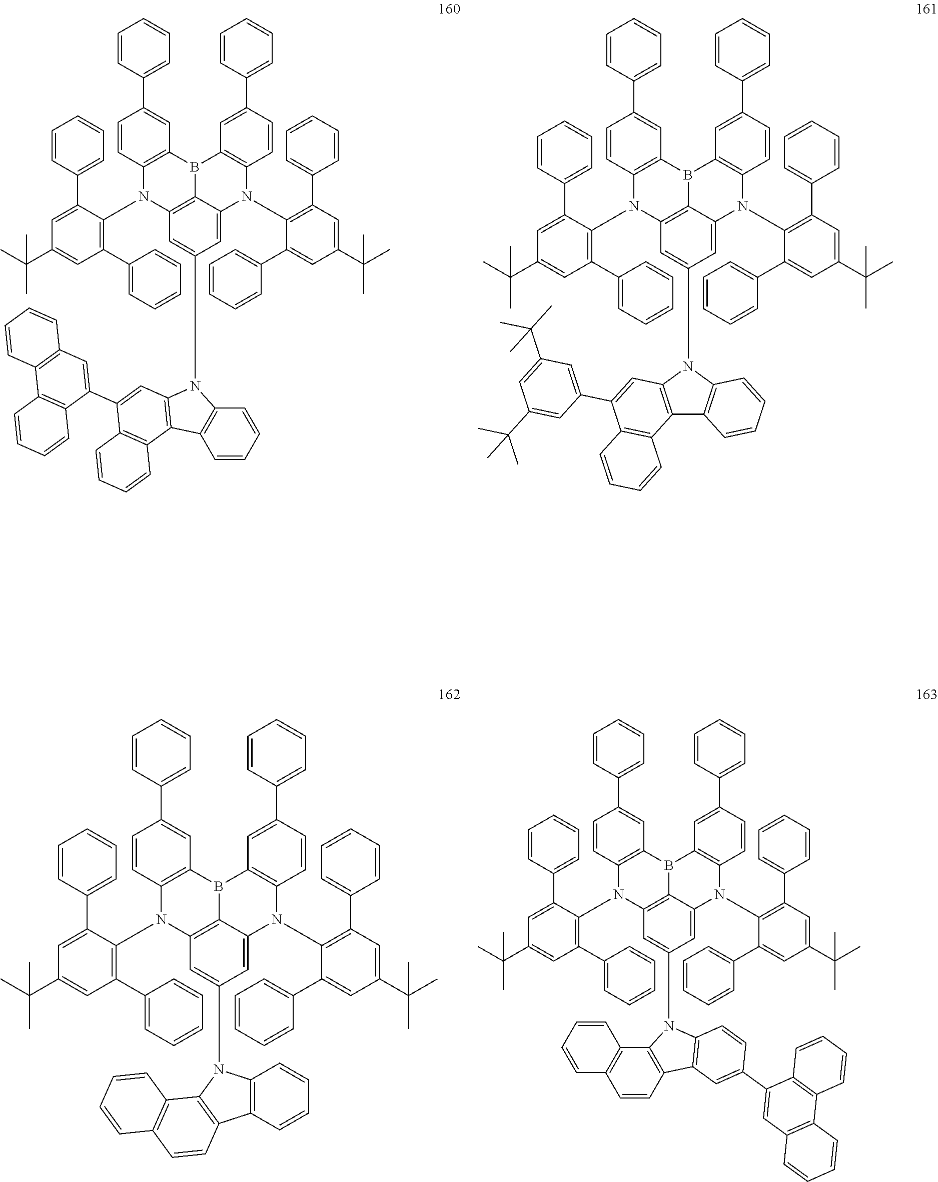

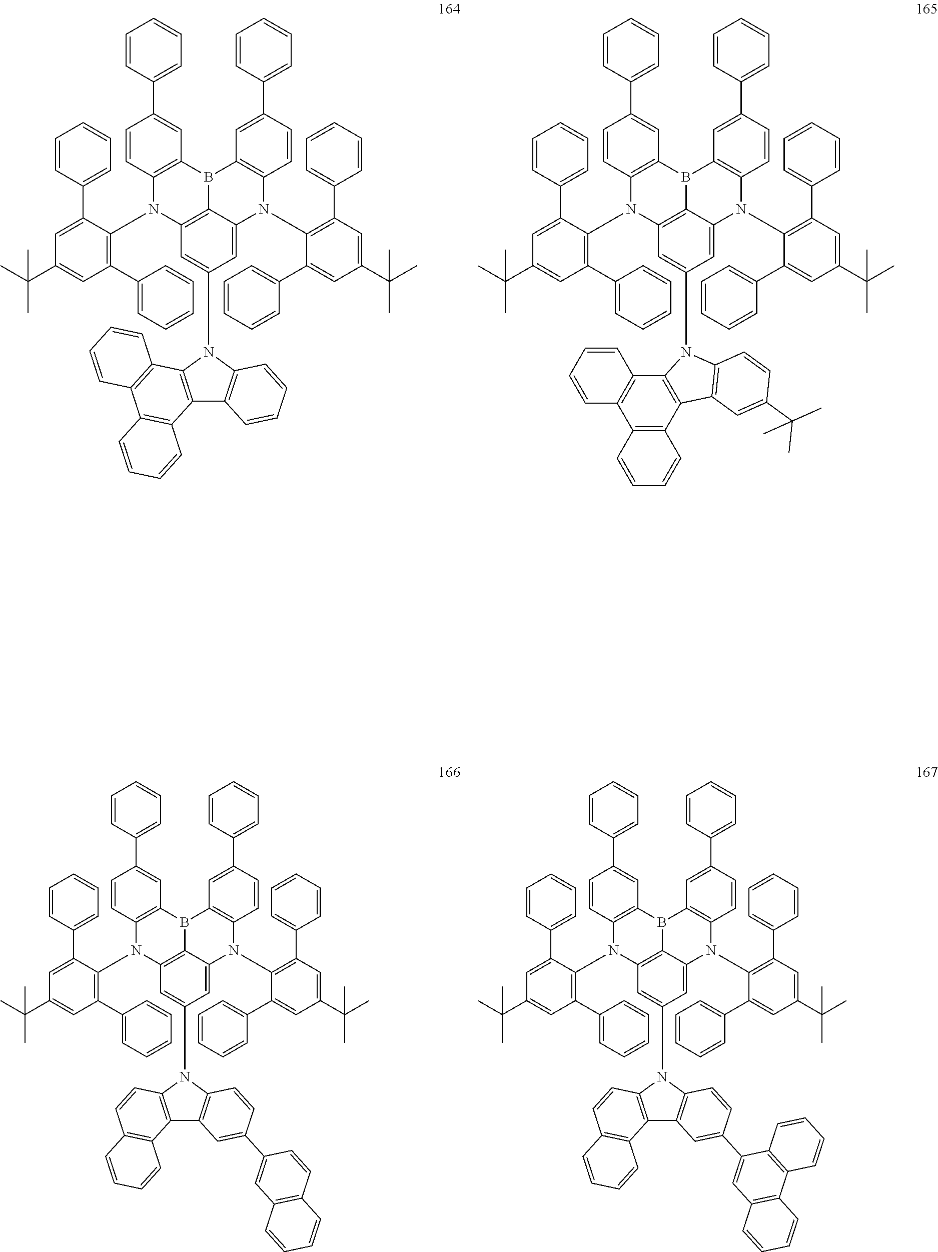

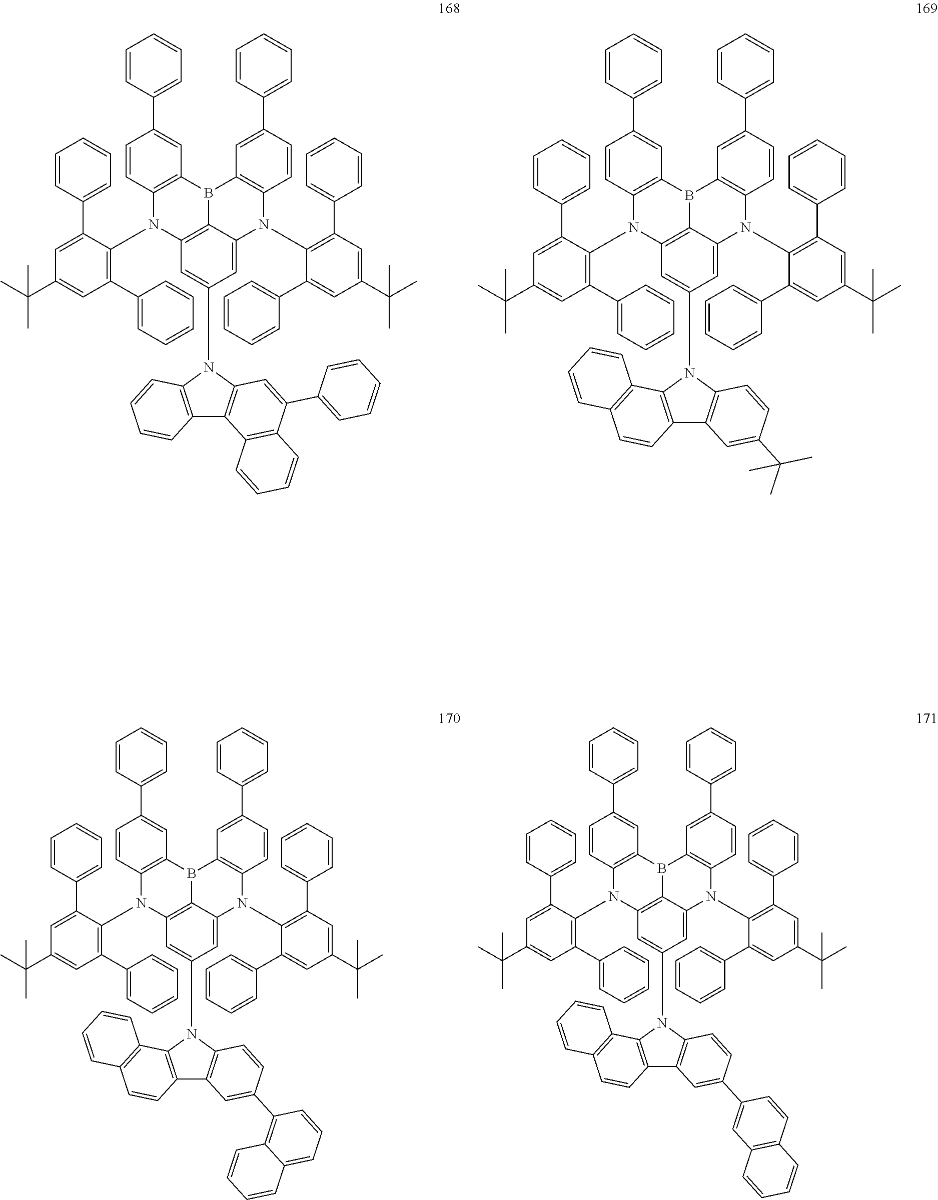

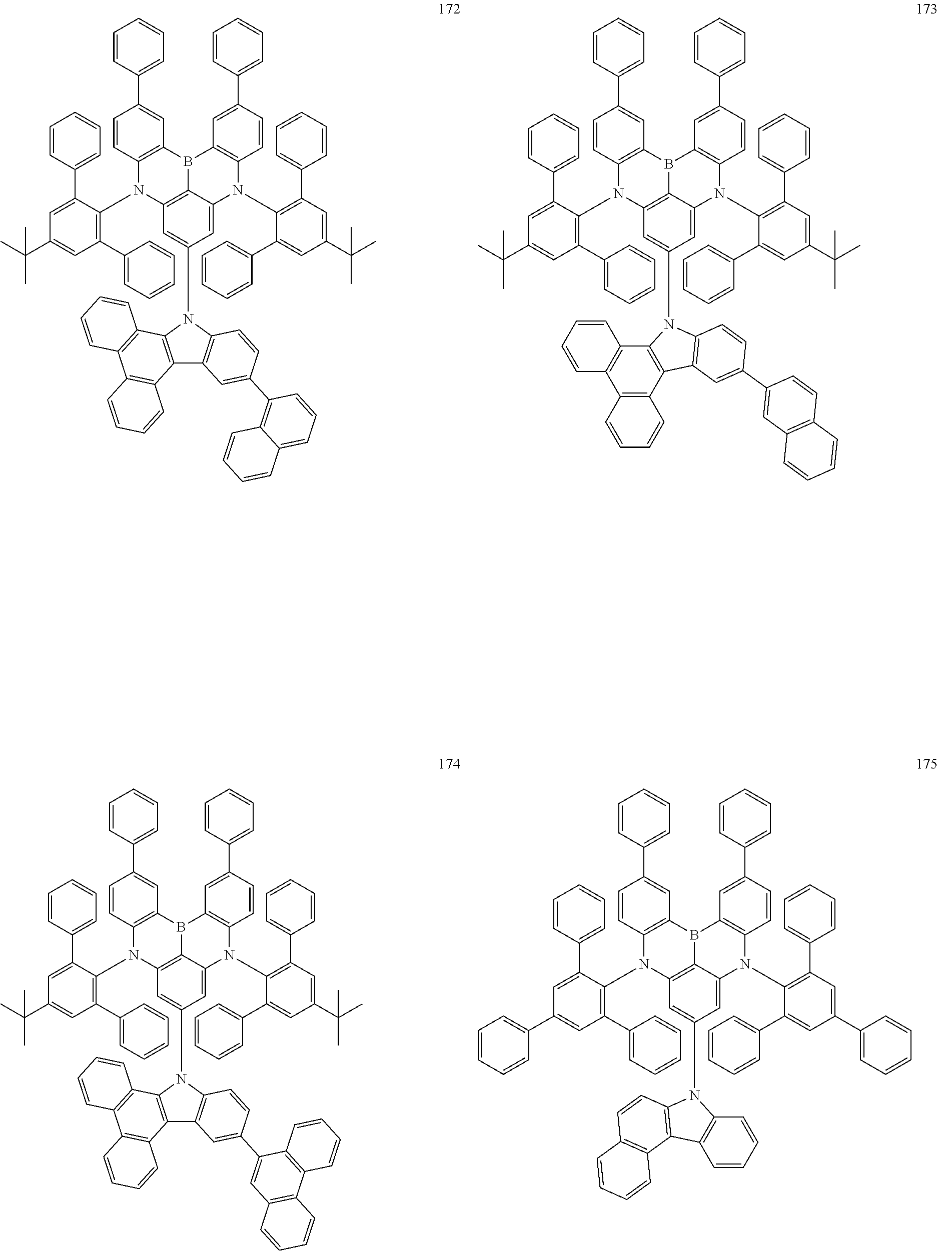

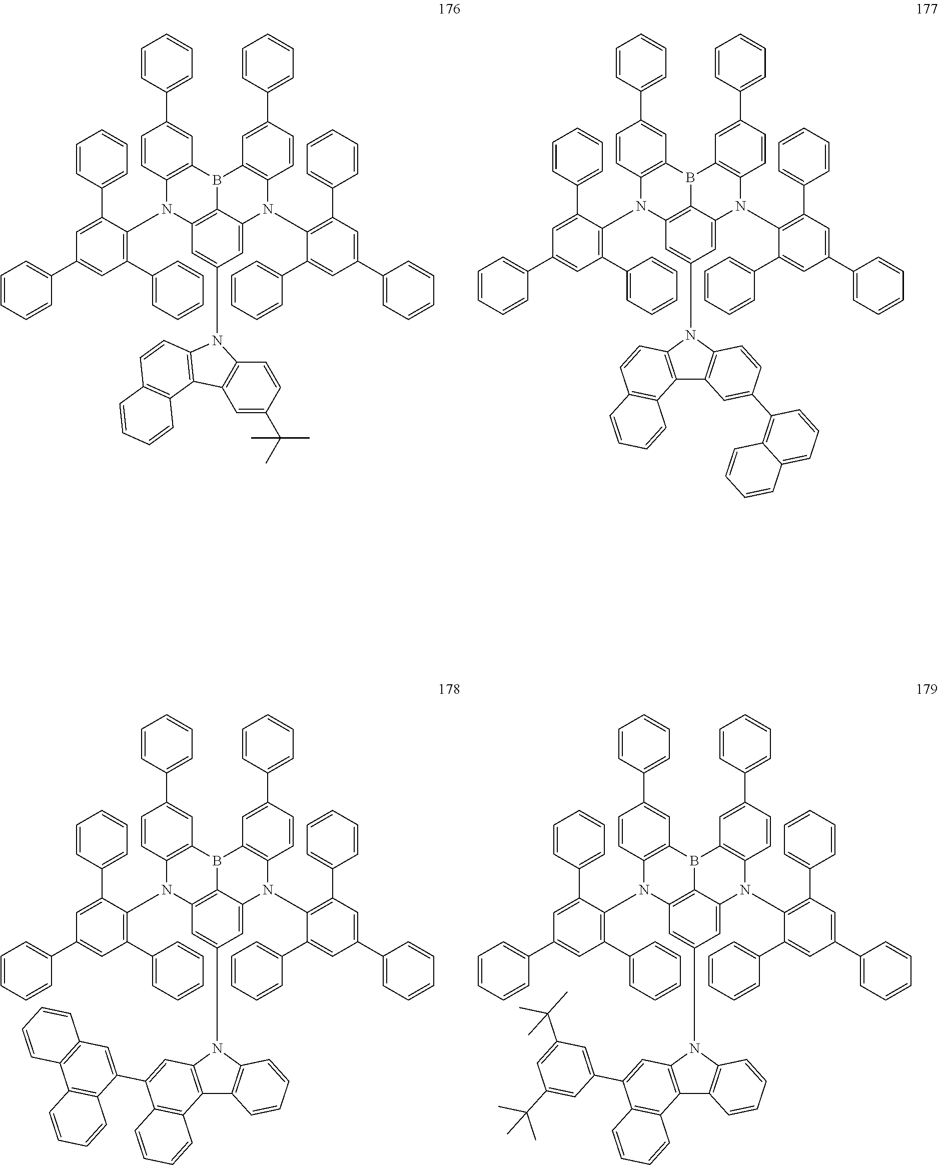

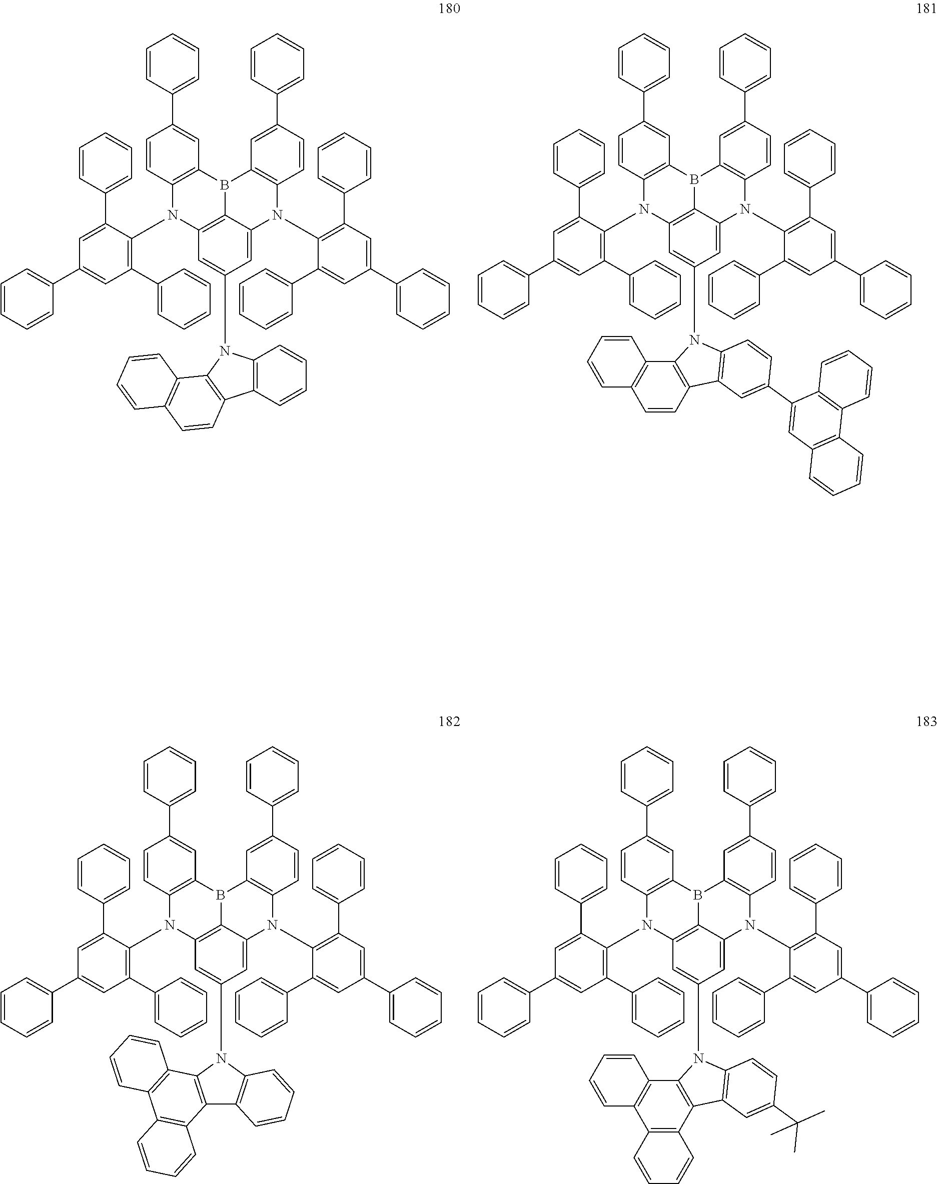

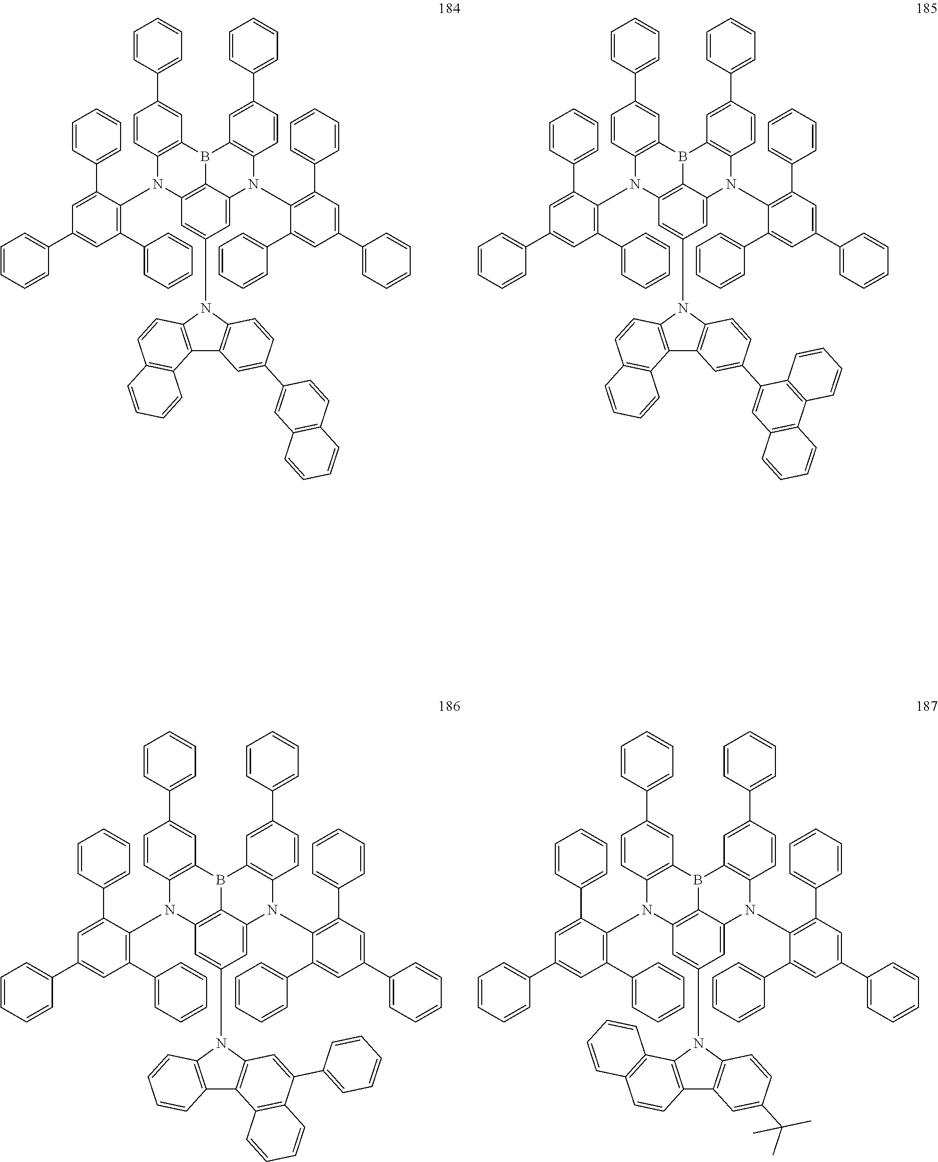

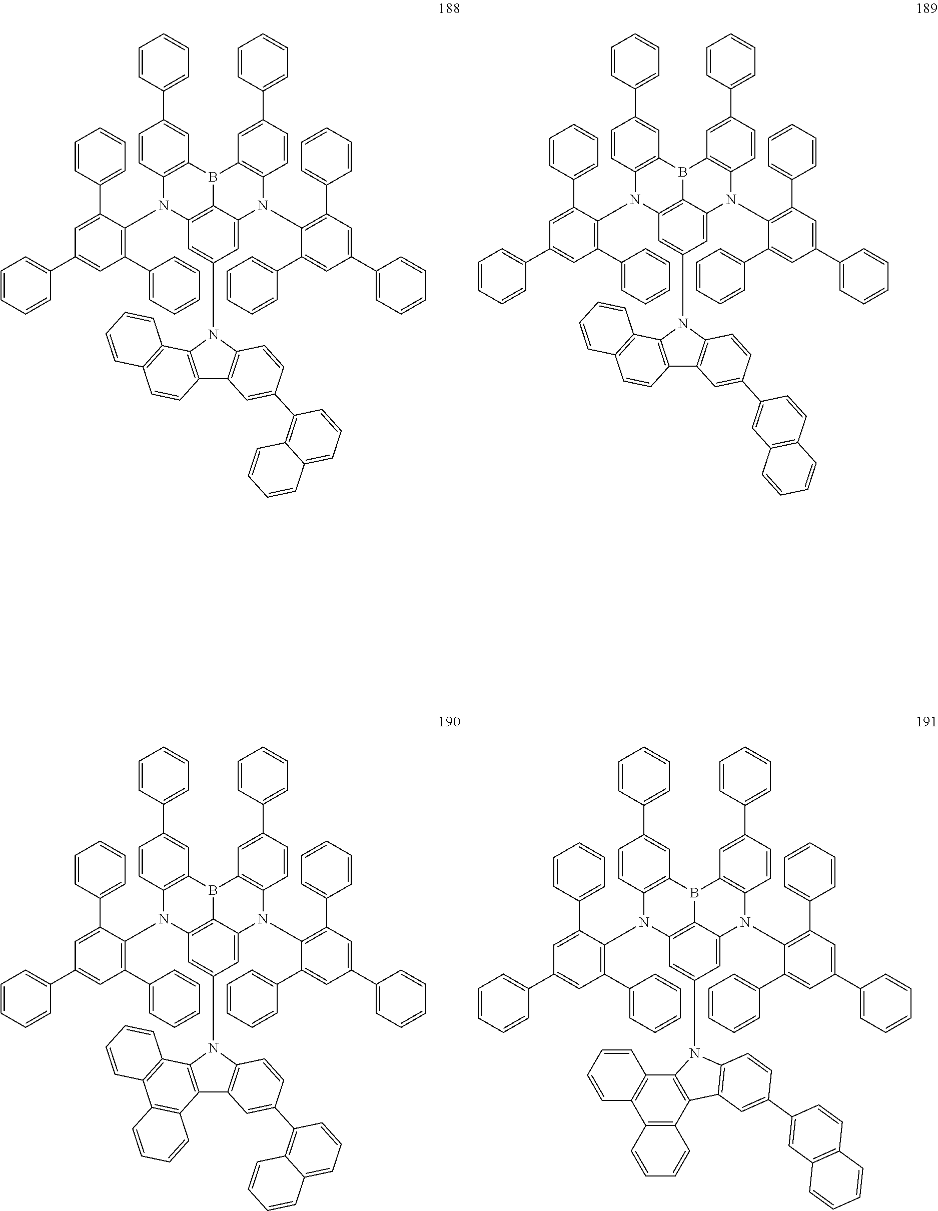

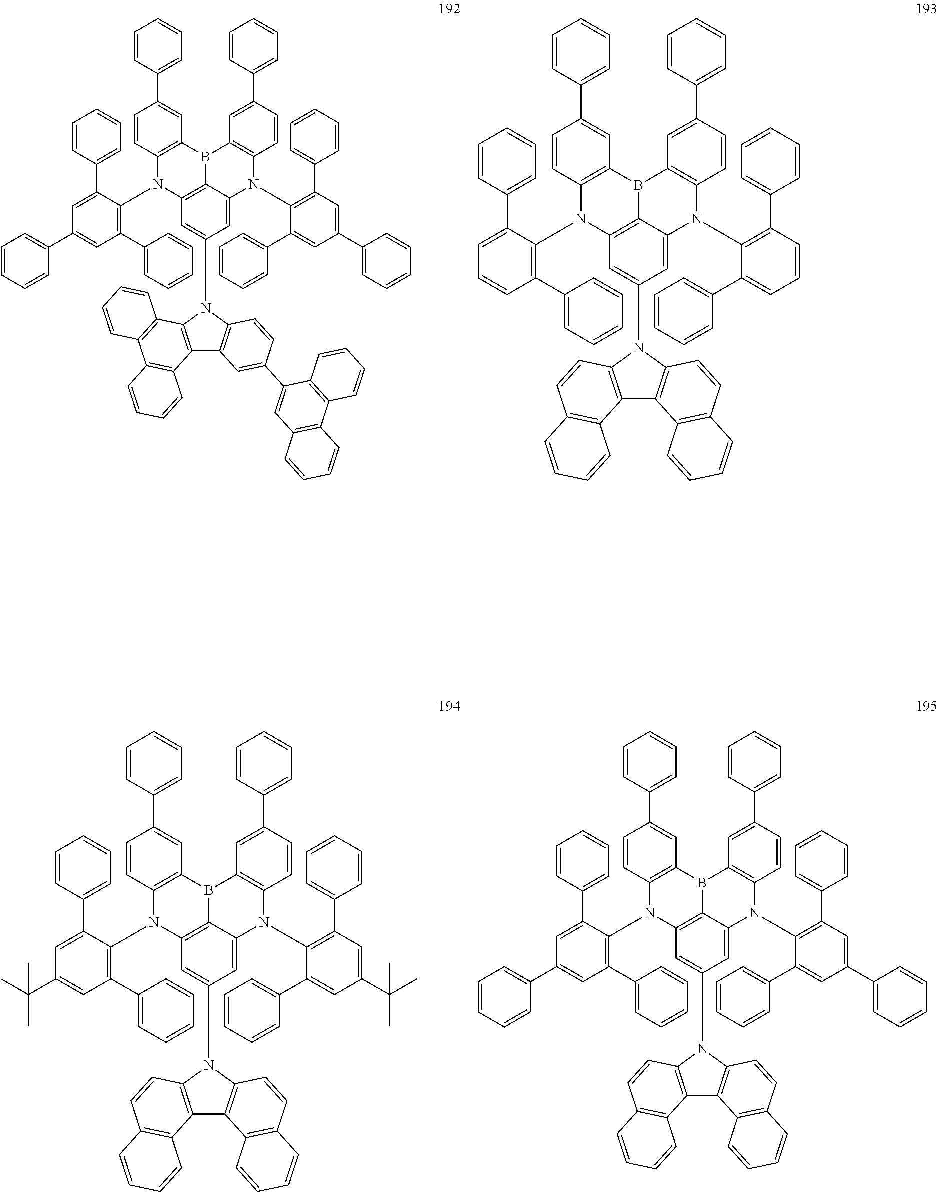

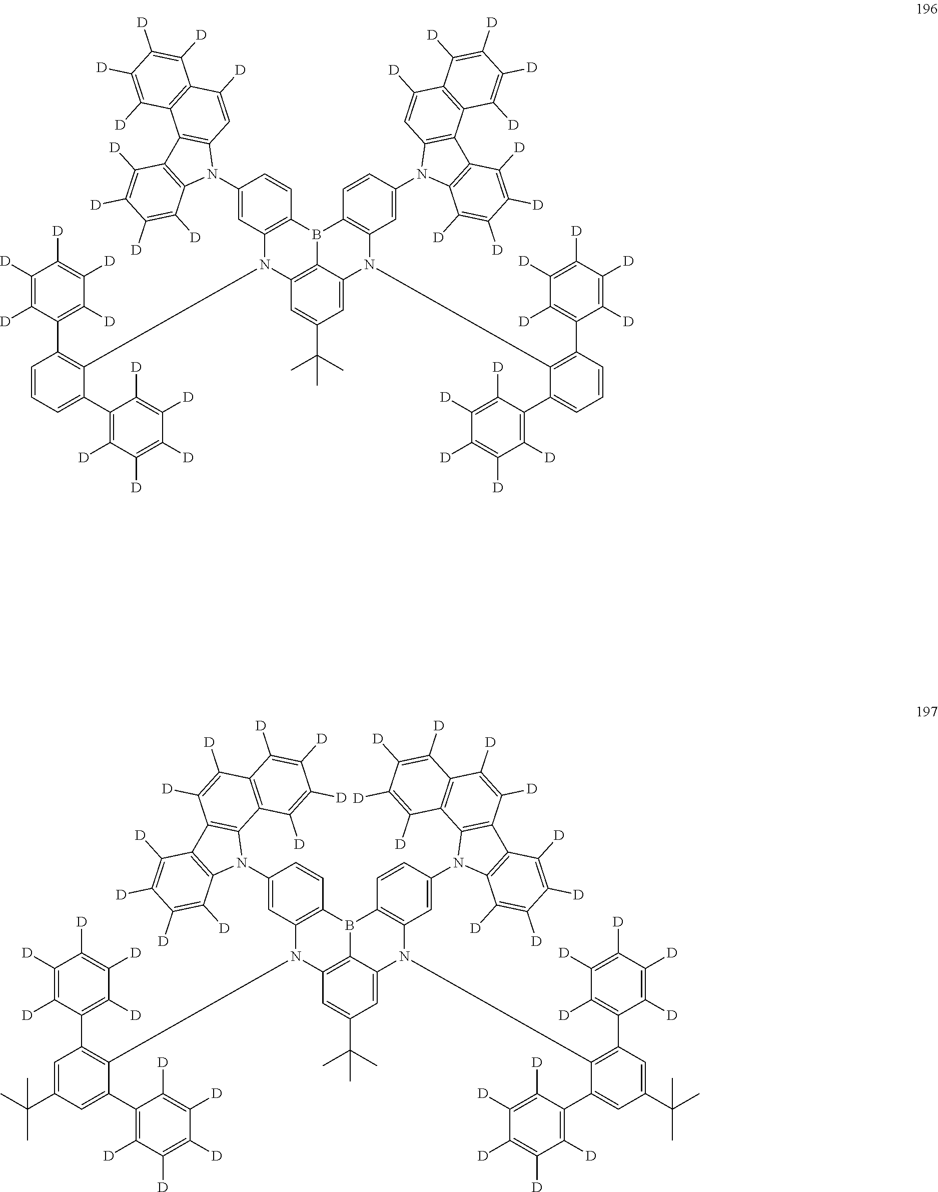

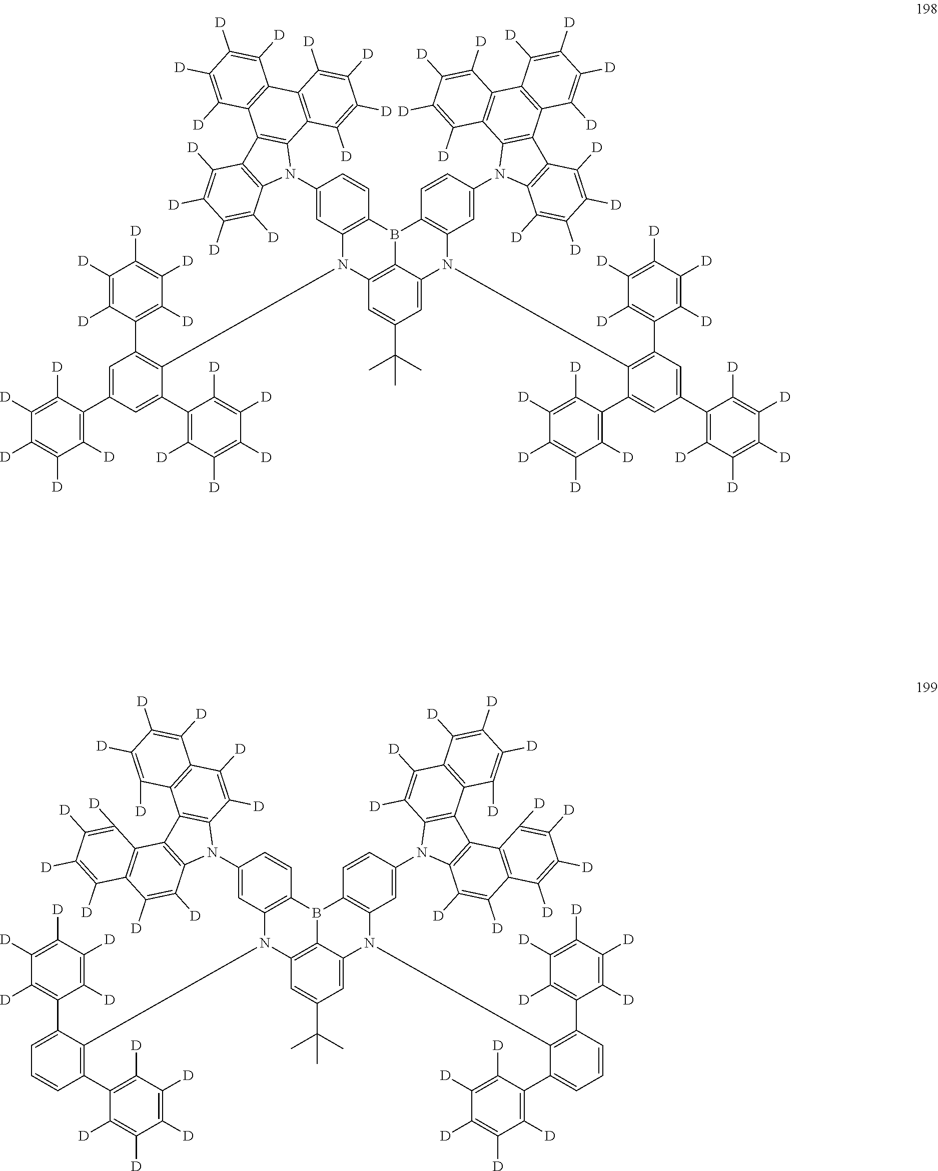

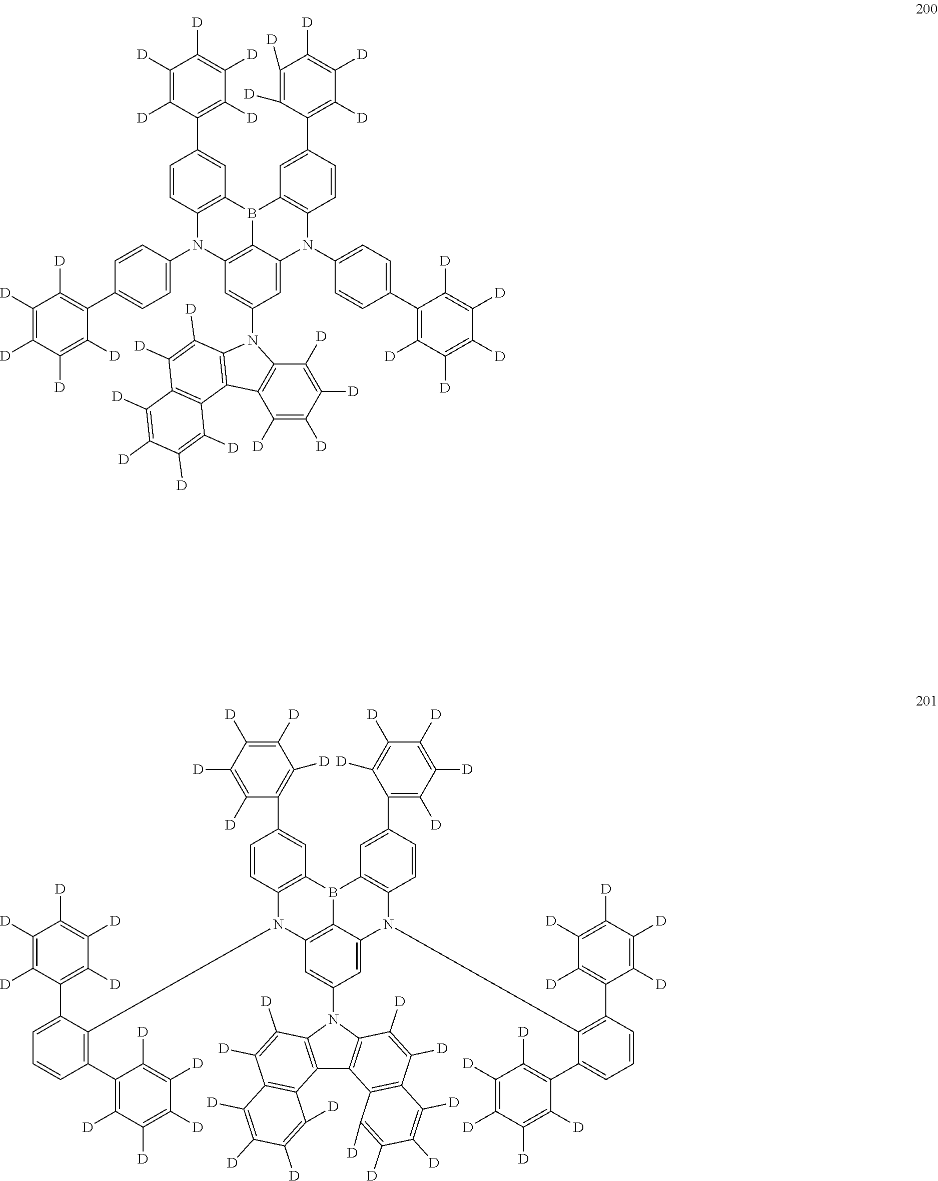

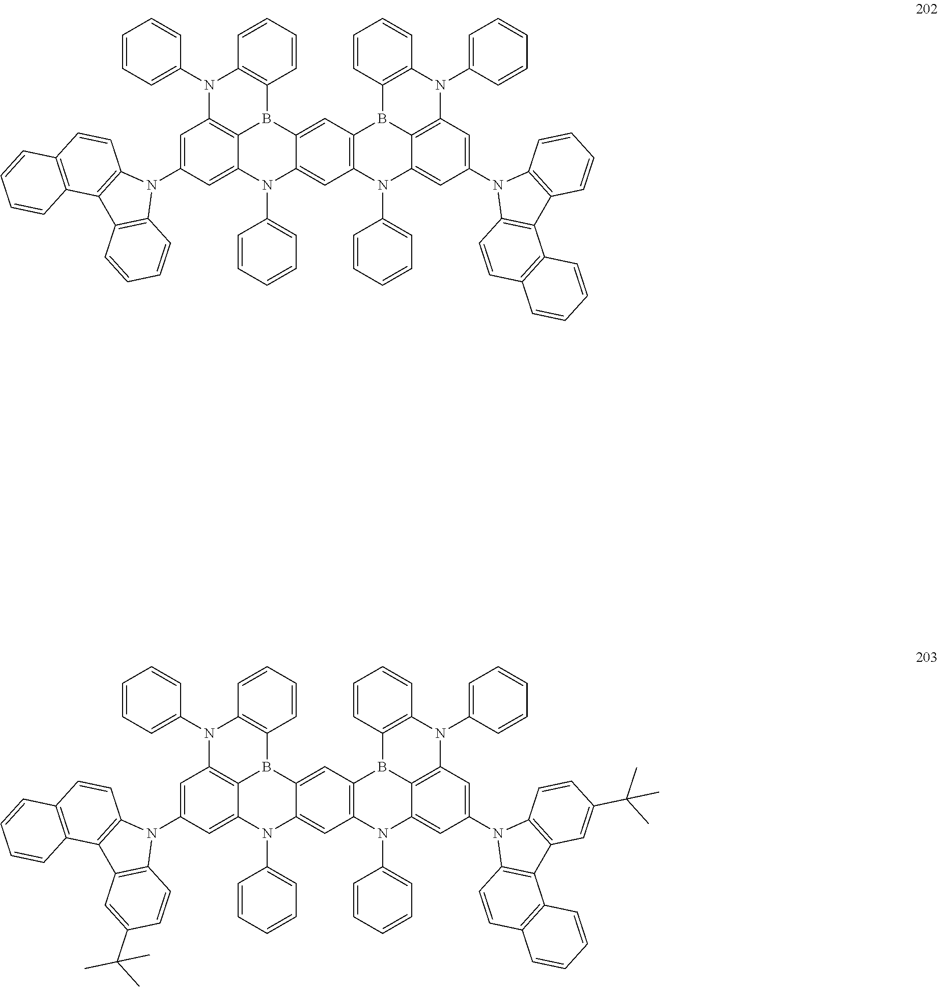 [SMILES: c1ccc(N2c3ccccc3B3c4cc5c(cc4N(c4ccccc4)c4cc(-n6c7ccccc7c7c8ccccc8ccc76)cc2c43)N(c2ccccc2)c2cc(-n3c4ccccc4c4c6ccccc6ccc43)cc3c2B5c2ccccc2N3c2ccccc2)cc1 ; CC(C)(C)c1ccc2c(c1)c1c3ccccc3ccc1n2-c1cc2c3c(c1)N(c1ccccc1)c1cc4c(cc1B3c1ccccc1N2c1ccccc1)B1c2ccccc2N(c2ccccc2)c2cc(-n3c5ccc(C(C)(C)C)cc5c5c6ccccc6ccc53)cc(c21)N4c1ccccc1]

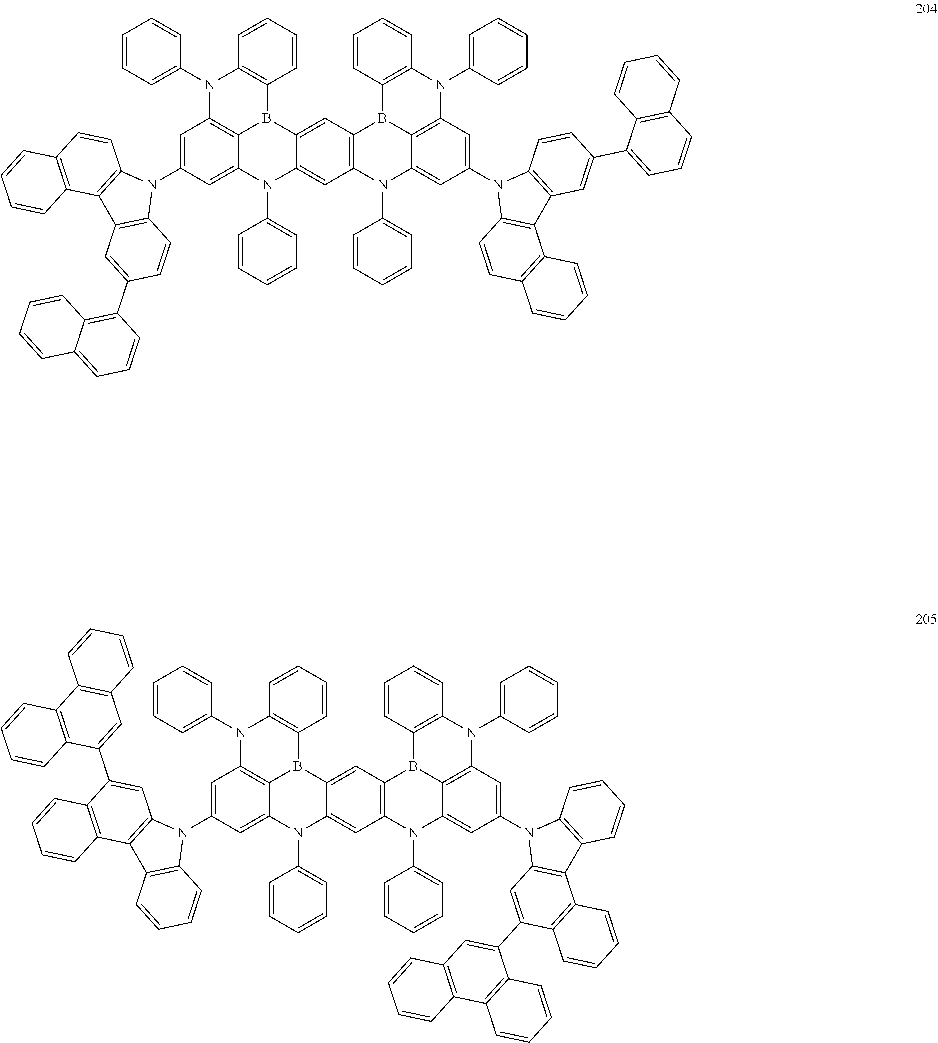 [SMILES: c1ccc(N2c3ccccc3B3c4cc5c(cc4N(c4ccccc4)c4cc(-n6c7ccc(-c8cccc9ccccc89)cc7c7c8ccccc8ccc76)cc2c43)N(c2ccccc2)c2cc(-n3c4ccc(-c6cccc7ccccc67)cc4c4c6ccccc6ccc43)cc3c2B5c2ccccc2N3c2ccccc2)cc1 ; c1ccc(N2c3ccccc3B3c4cc5c(cc4N(c4ccccc4)c4cc(-n6c7ccccc7c7c8ccccc8c(-c8cc9ccccc9c9ccccc89)cc76)cc2c43)N(c2ccccc2)c2cc(-n3c4ccccc4c4c6ccccc6c(-c6cc7ccccc7c7ccccc67)cc43)cc3c2B5c2ccccc2N3c2ccccc2)cc1]

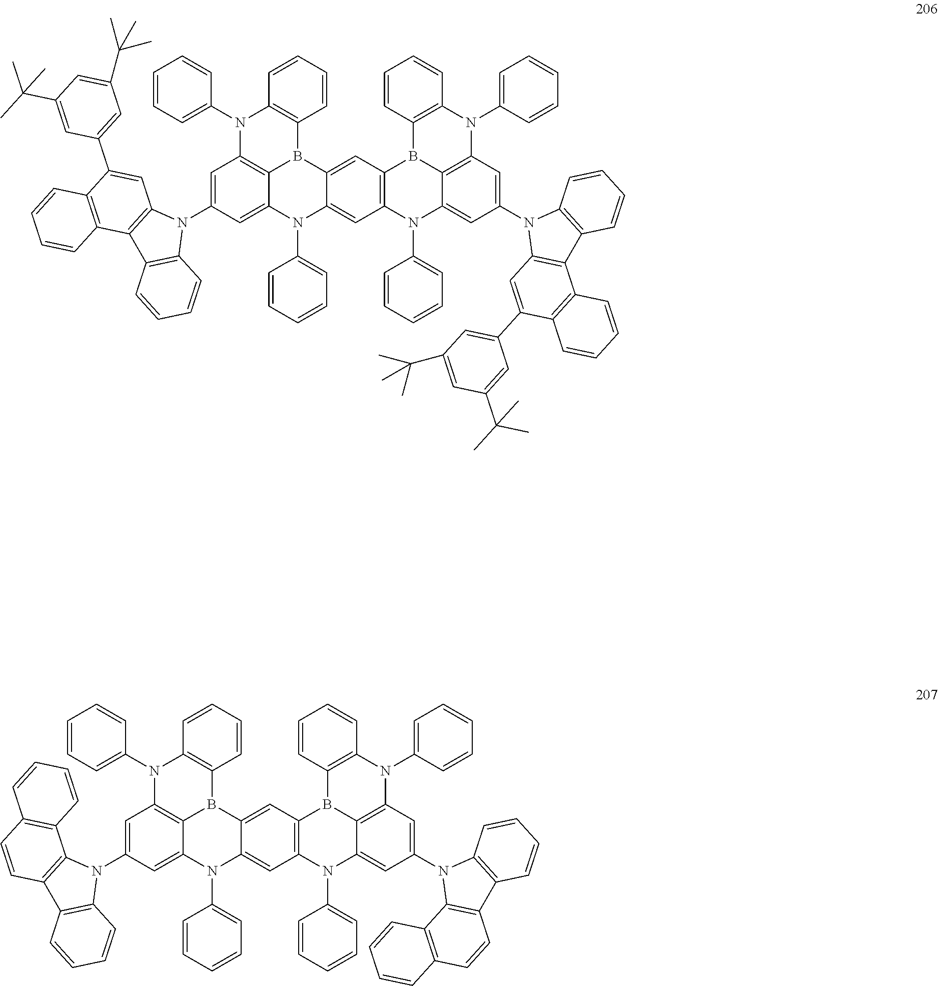 [SMILES: CC(C)(C)c1cc(-c2cc3c(c4ccccc24)c2ccccc2n3-c2cc3c4c(c2)N(c2ccccc2)c2cc5c(cc2B4c2ccccc2N3c2ccccc2)B2c3ccccc3N(c3ccccc3)c3cc(-n4c6ccccc6c6c7ccccc7c(-c7cc(C(C)(C)C)cc(C(C)(C)C)c7)cc64)cc(c32)N5c2ccccc2)cc(C(C)(C)C)c1 ; c1ccc(N2c3ccccc3B3c4cc5c(cc4N(c4ccccc4)c4cc(-n6c7ccccc7c7ccc8ccccc8c76)cc2c43)N(c2ccccc2)c2cc(-n3c4ccccc4c4ccc6ccccc6c43)cc3c2B5c2ccccc2N3c2ccccc2)cc1]

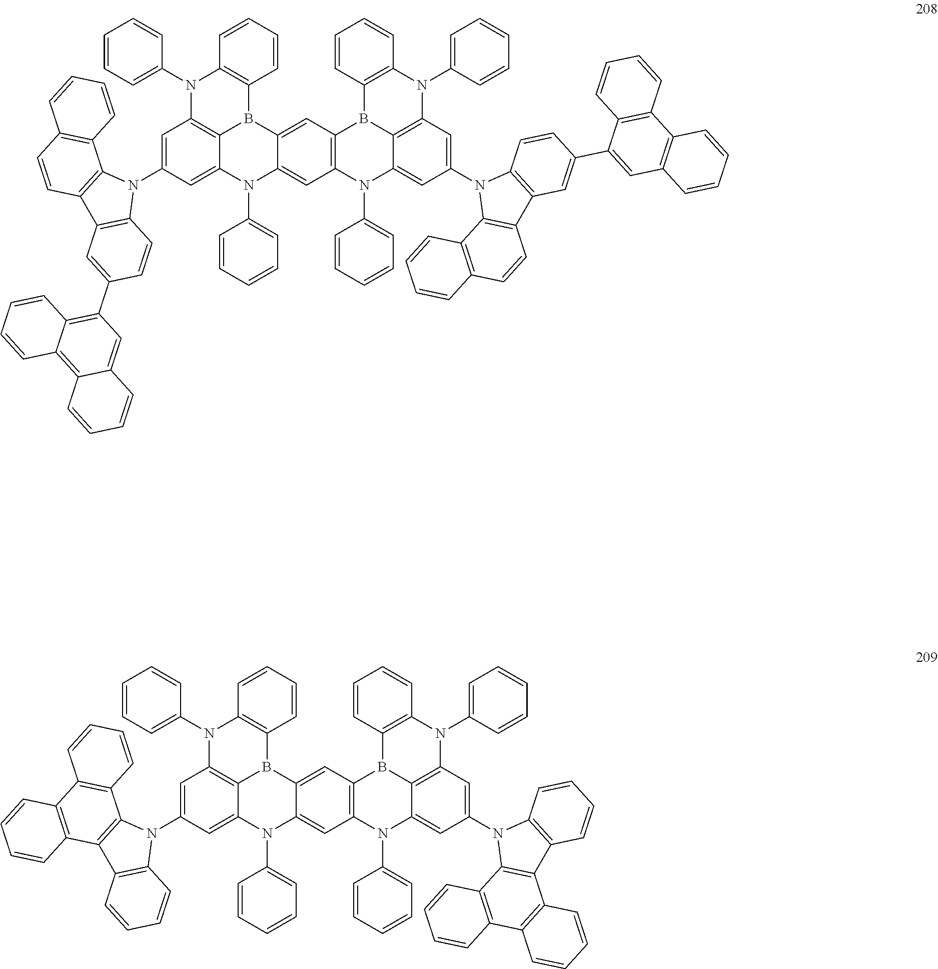 [SMILES: c1ccc(N2c3ccccc3B3c4cc5c(cc4N(c4ccccc4)c4cc(-n6c7ccc(-c8cc9ccccc9c9ccccc89)cc7c7ccc8ccccc8c76)cc2c43)N(c2ccccc2)c2cc(-n3c4ccc(-c6cc7ccccc7c7ccccc67)cc4c4ccc6ccccc6c43)cc3c2B5c2ccccc2N3c2ccccc2)cc1 ; c1ccc(N2c3ccccc3B3c4cc5c(cc4N(c4ccccc4)c4cc(-n6c7ccccc7c7c8ccccc8c8ccccc8c76)cc2c43)N(c2ccccc2)c2cc(-n3c4ccccc4c4c6ccccc6c6ccccc6c43)cc3c2B5c2ccccc2N3c2ccccc2)cc1]

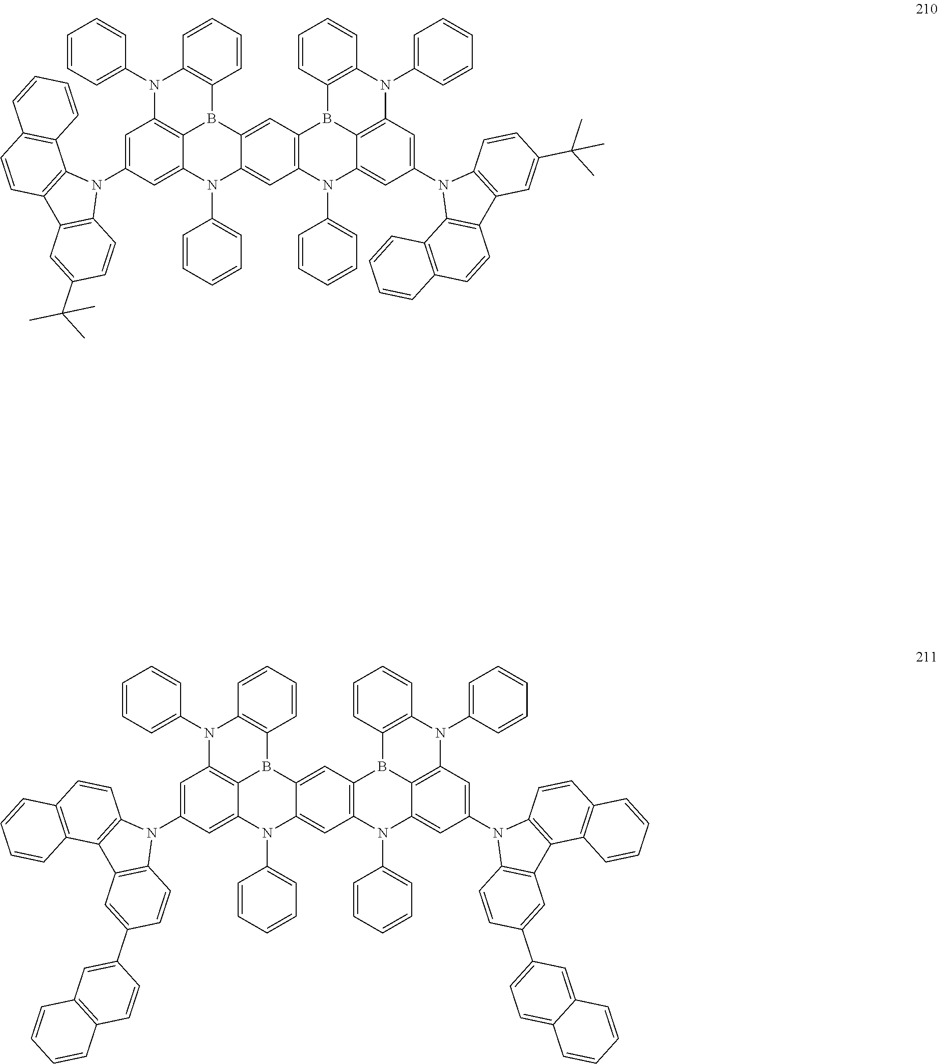 [SMILES: CC(C)(C)c1ccc2c(c1)c1ccc3ccccc3c1n2-c1cc2c3c(c1)N(c1ccccc1)c1cc4c(cc1B3c1ccccc1N2c1ccccc1)B1c2ccccc2N(c2ccccc2)c2cc(-n3c5ccc(C(C)(C)C)cc5c5ccc6ccccc6c53)cc(c21)N4c1ccccc1 ; c1ccc(N2c3ccccc3B3c4cc5c(cc4N(c4ccccc4)c4cc(-n6c7ccc(-c8ccc9ccccc9c8)cc7c7c8ccccc8ccc76)cc2c43)N(c2ccccc2)c2cc(-n3c4ccc(-c6ccc7ccccc7c6)cc4c4c6ccccc6ccc43)cc3c2B5c2ccccc2N3c2ccccc2)cc1]

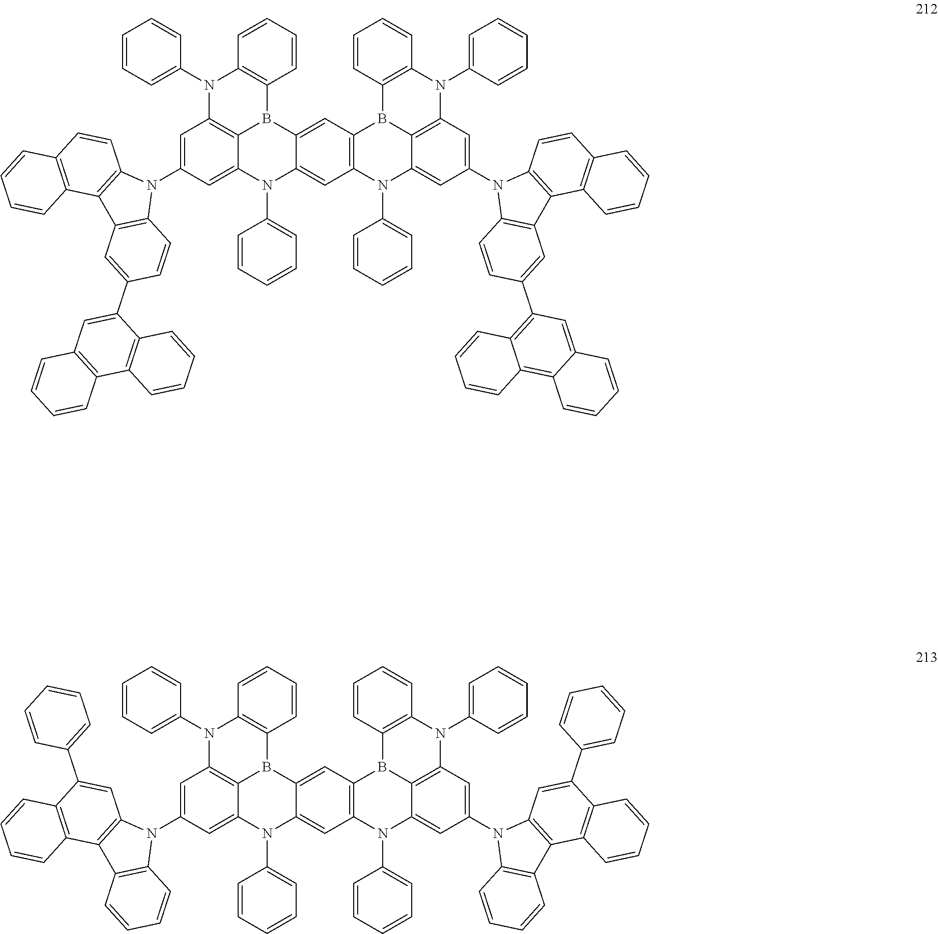 [SMILES: c1ccc(N2c3ccccc3B3c4cc5c(cc4N(c4ccccc4)c4cc(-n6c7ccc(-c8cc9ccccc9c9ccccc89)cc7c7c8ccccc8ccc76)cc2c43)N(c2ccccc2)c2cc(-n3c4ccc(-c6cc7ccccc7c7ccccc67)cc4c4c6ccccc6ccc43)cc3c2B5c2ccccc2N3c2ccccc2)cc1 ; c1ccc(-c2cc3c(c4ccccc24)c2ccccc2n3-c2cc3c4c(c2)N(c2ccccc2)c2cc5c(cc2B4c2ccccc2N3c2ccccc2)B2c3ccccc3N(c3ccccc3)c3cc(-n4c6ccccc6c6c7ccccc7c(-c7ccccc7)cc64)cc(c32)N5c2ccccc2)cc1]

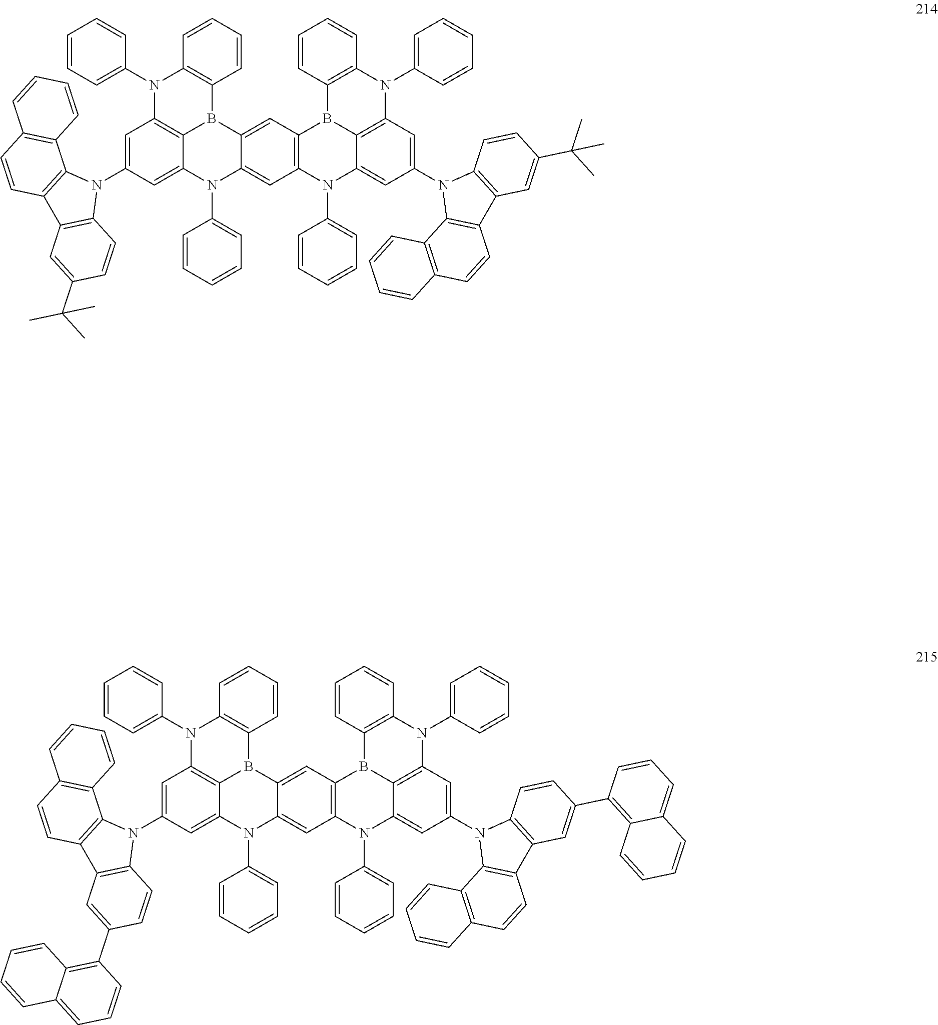 [SMILES: CC(C)(C)c1ccc2c(c1)c1ccc3ccccc3c1n2-c1cc2c3c(c1)N(c1ccccc1)c1cc4c(cc1B3c1ccccc1N2c1ccccc1)B1c2ccccc2N(c2ccccc2)c2cc(-n3c5ccc(C(C)(C)C)cc5c5ccc6ccccc6c53)cc(c21)N4c1ccccc1 ; c1ccc(N2c3ccccc3B3c4cc5c(cc4N(c4ccccc4)c4cc(-n6c7ccc(-c8cccc9ccccc89)cc7c7ccc8ccccc8c76)cc2c43)N(c2ccccc2)c2cc(-n3c4ccc(-c6cccc7ccccc67)cc4c4ccc6ccccc6c43)cc3c2B5c2ccccc2N3c2ccccc2)cc1]

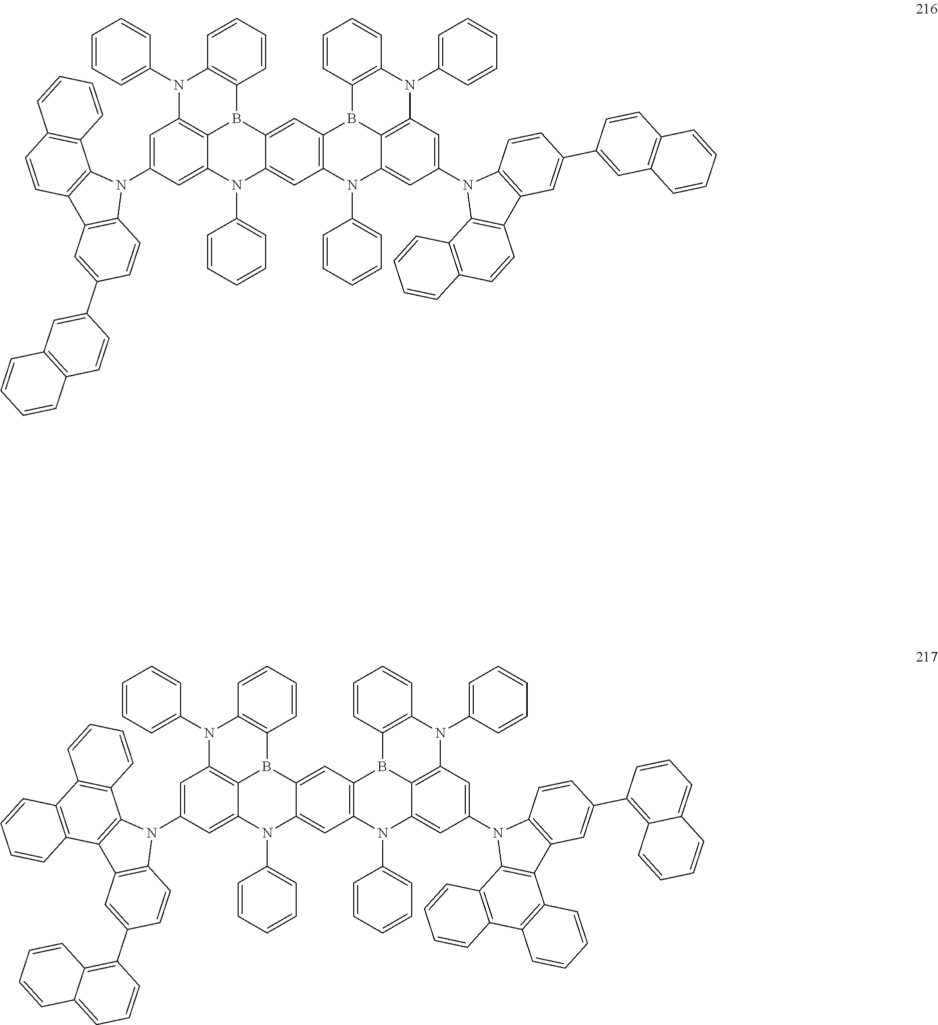 [SMILES: c1ccc(N2c3ccccc3B3c4cc5c(cc4N(c4ccccc4)c4cc(-n6c7ccc(-c8ccc9ccccc9c8)cc7c7ccc8ccccc8c76)cc2c43)N(c2ccccc2)c2cc(-n3c4ccc(-c6ccc7ccccc7c6)cc4c4ccc6ccccc6c43)cc3c2B5c2ccccc2N3c2ccccc2)cc1 ; c1ccc(N2c3ccccc3B3c4cc5c(cc4N(c4ccccc4)c4cc(-n6c7ccc(-c8cccc9ccccc89)cc7c7c8ccccc8c8ccccc8c76)cc2c43)N(c2ccccc2)c2cc(-n3c4ccc(-c6cccc7ccccc67)cc4c4c6ccccc6c6ccccc6c43)cc3c2B5c2ccccc2N3c2ccccc2)cc1]

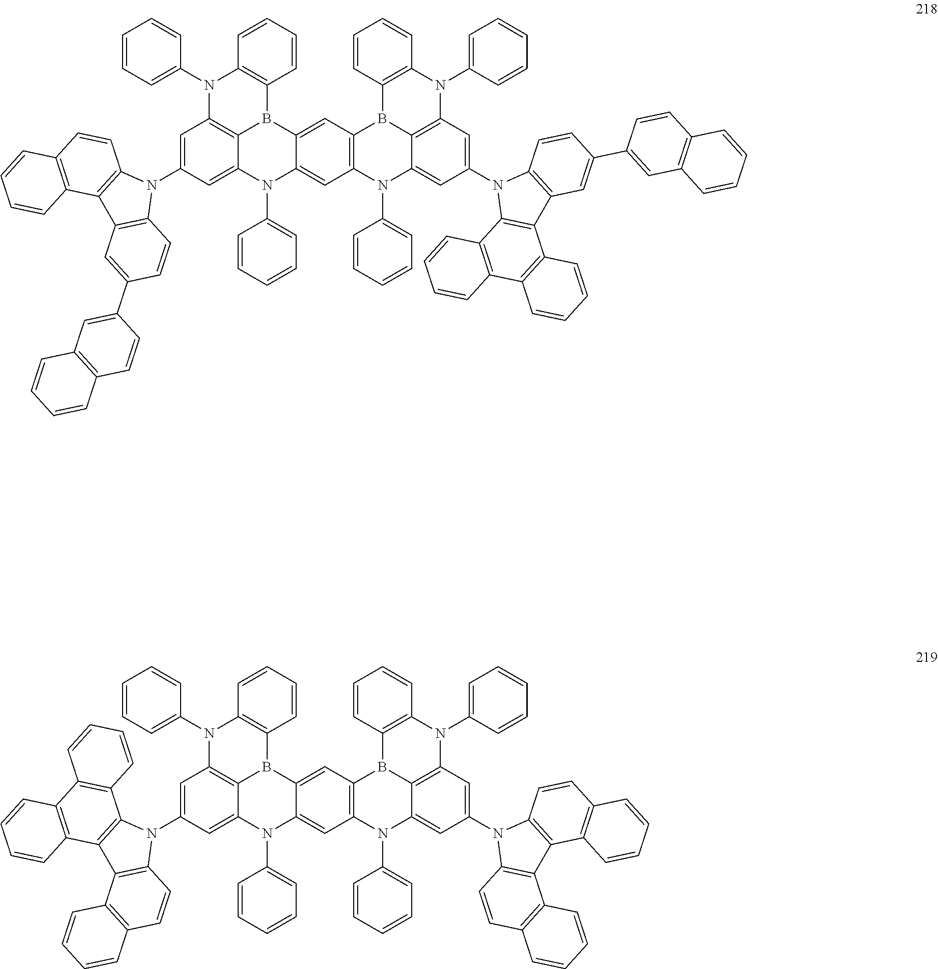 [SMILES: c1ccc(N2c3ccccc3B3c4cc5c(cc4N(c4ccccc4)c4cc(-n6c7ccc(-c8ccc9ccccc9c8)cc7c7c8ccccc8ccc76)cc2c43)N(c2ccccc2)c2cc(-n3c4ccc(-c6ccc7ccccc7c6)cc4c4c6ccccc6c6ccccc6c43)cc3c2B5c2ccccc2N3c2ccccc2)cc1 ; c1ccc(N2c3ccccc3B3c4cc5c(cc4N(c4ccccc4)c4cc(-n6c7ccc8ccccc8c7c7c8ccccc8ccc76)cc2c43)N(c2ccccc2)c2cc(-n3c4ccc6ccccc6c4c4c6ccccc6c6ccccc6c43)cc3c2B5c2ccccc2N3c2ccccc2)cc1]

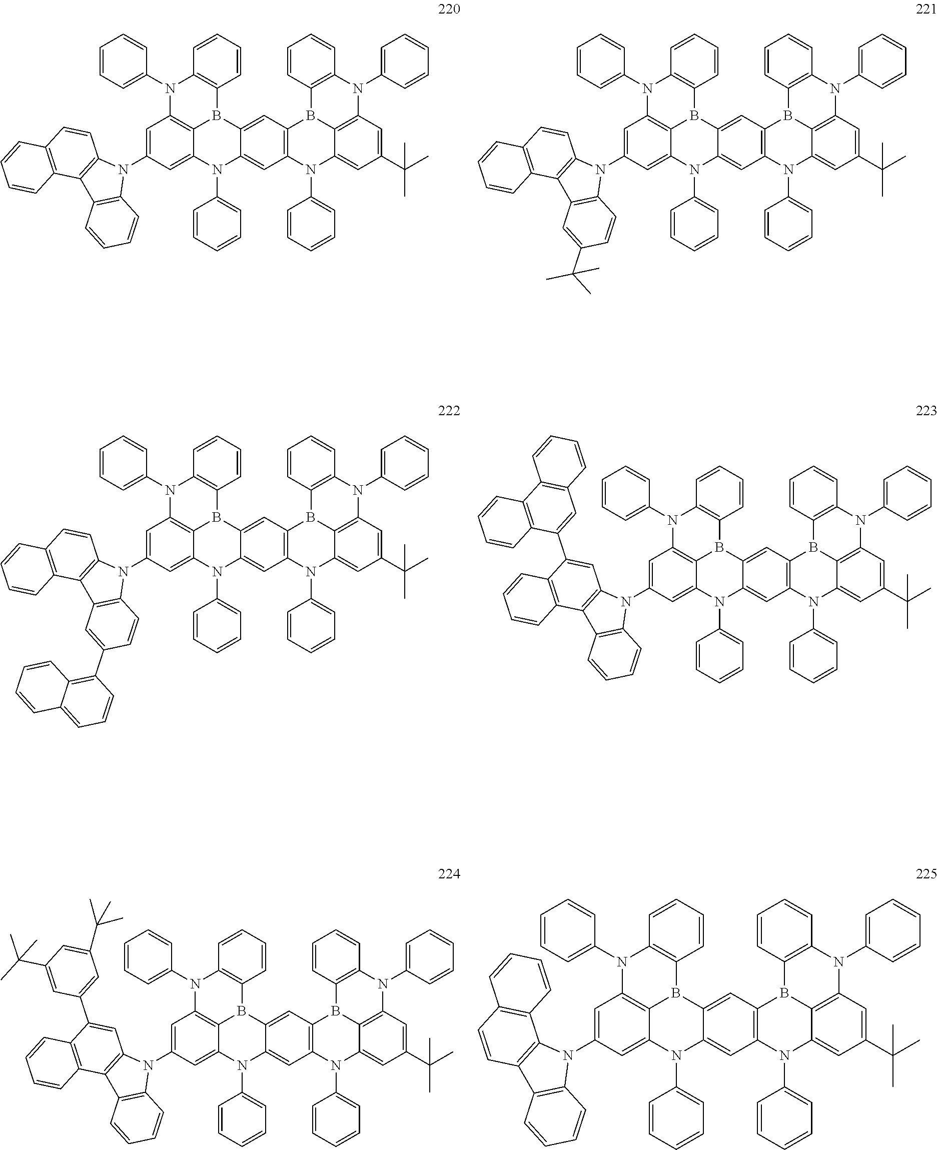

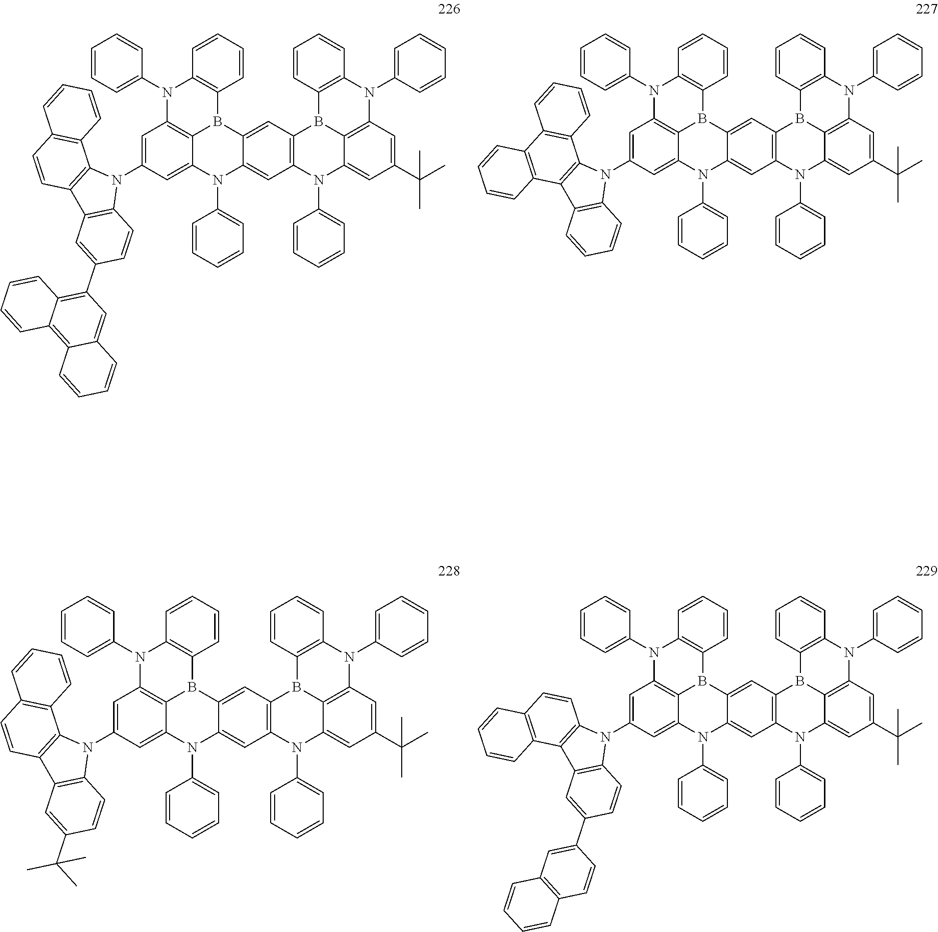

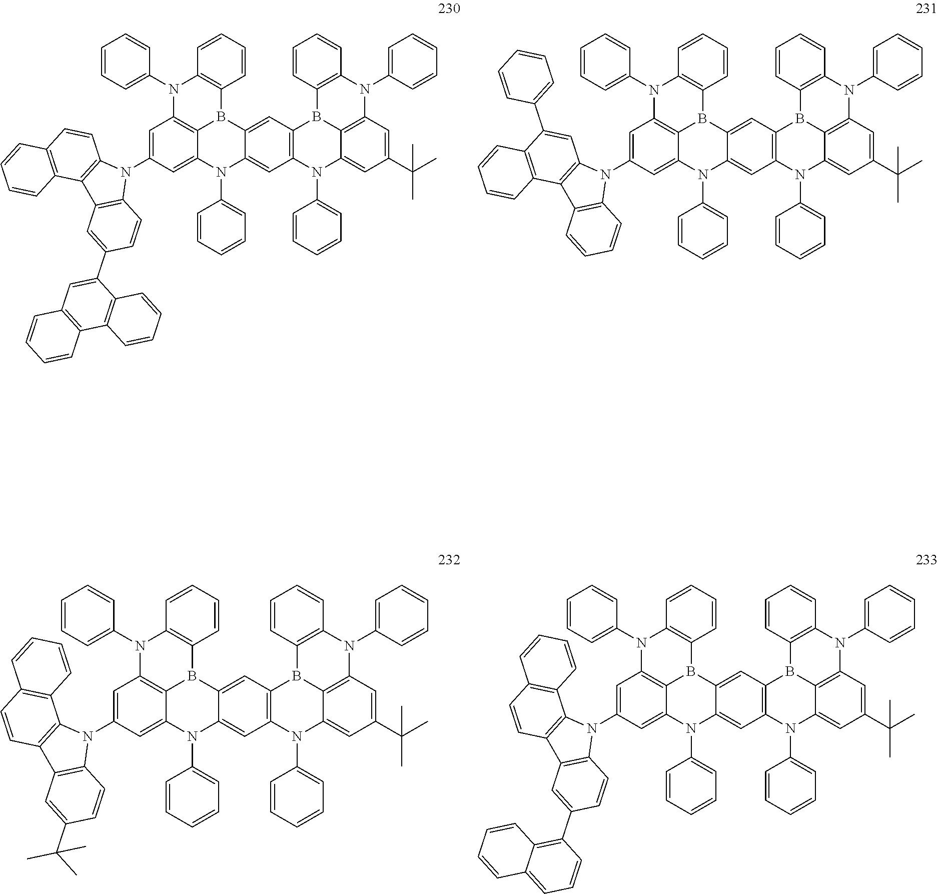

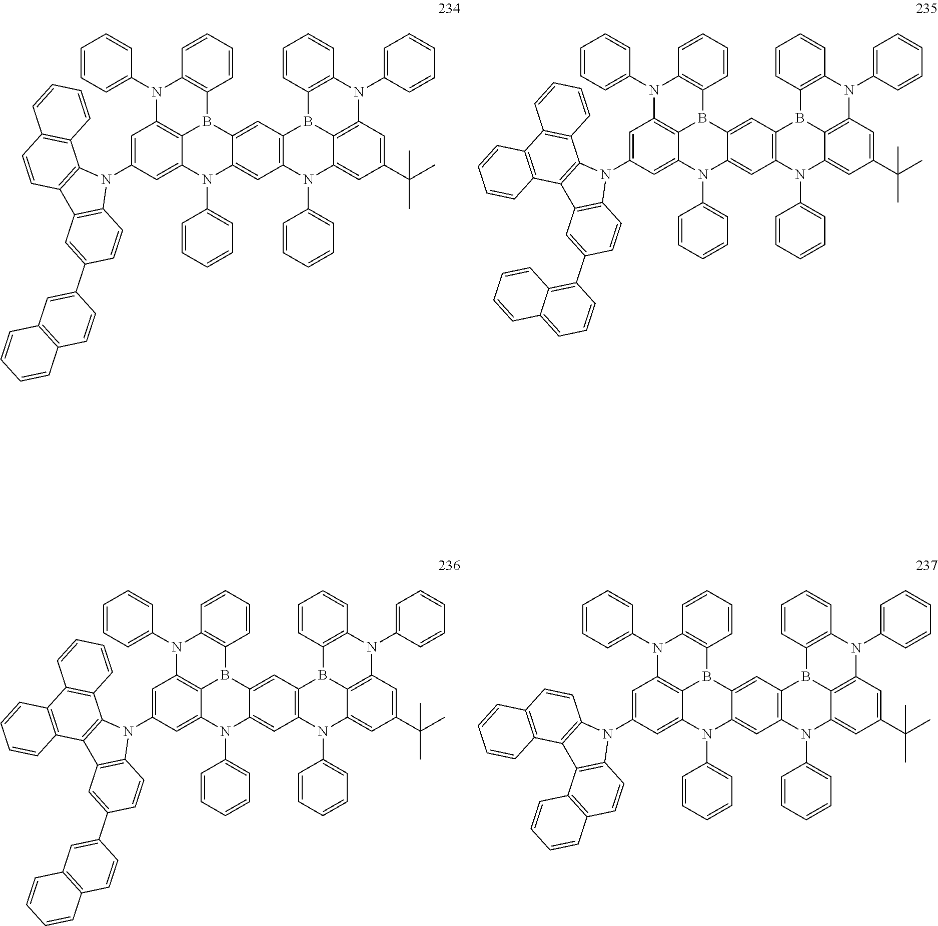

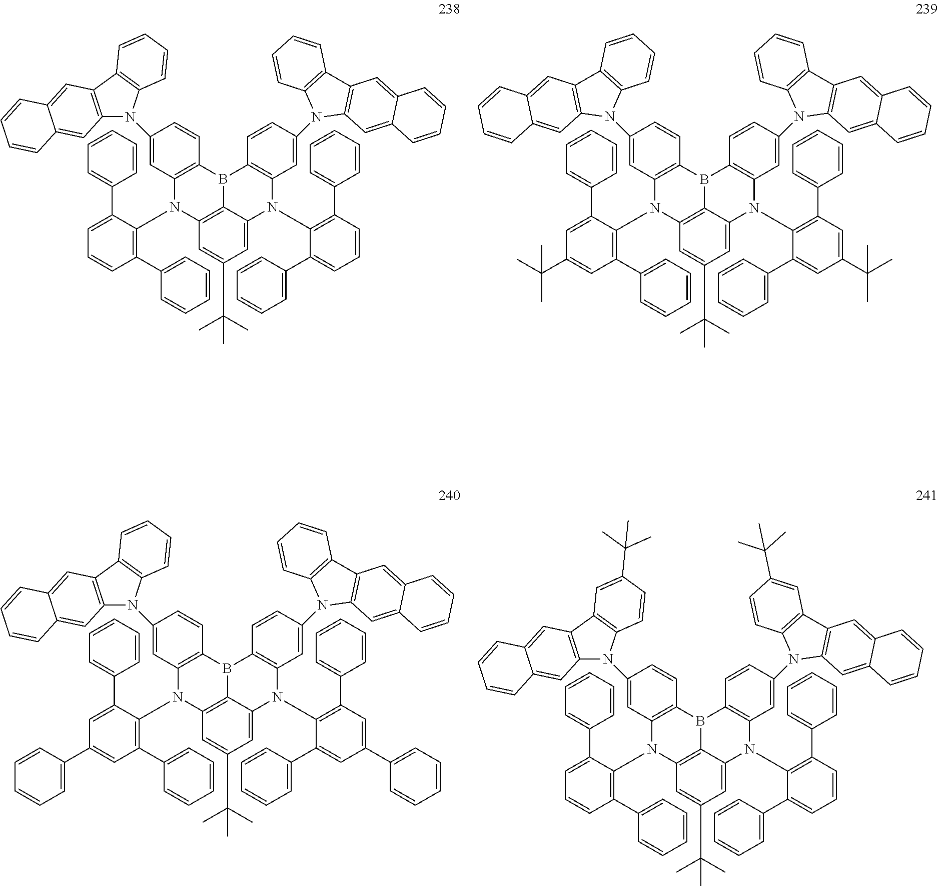

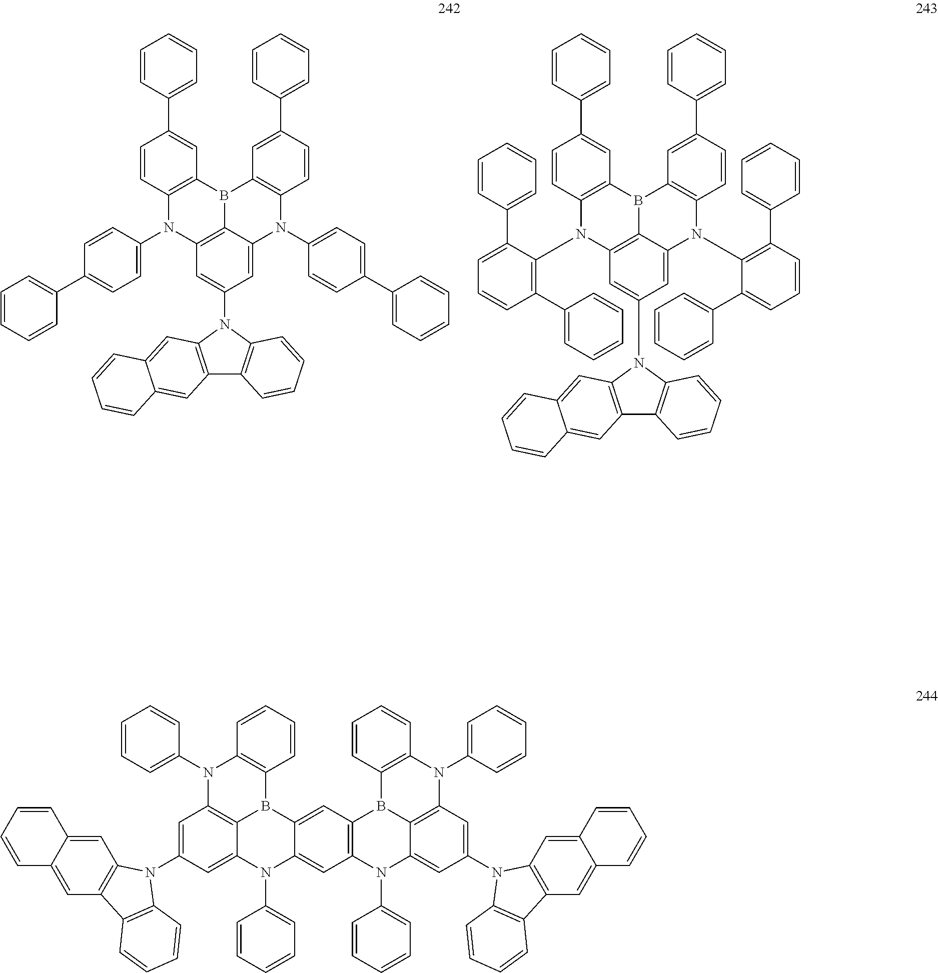

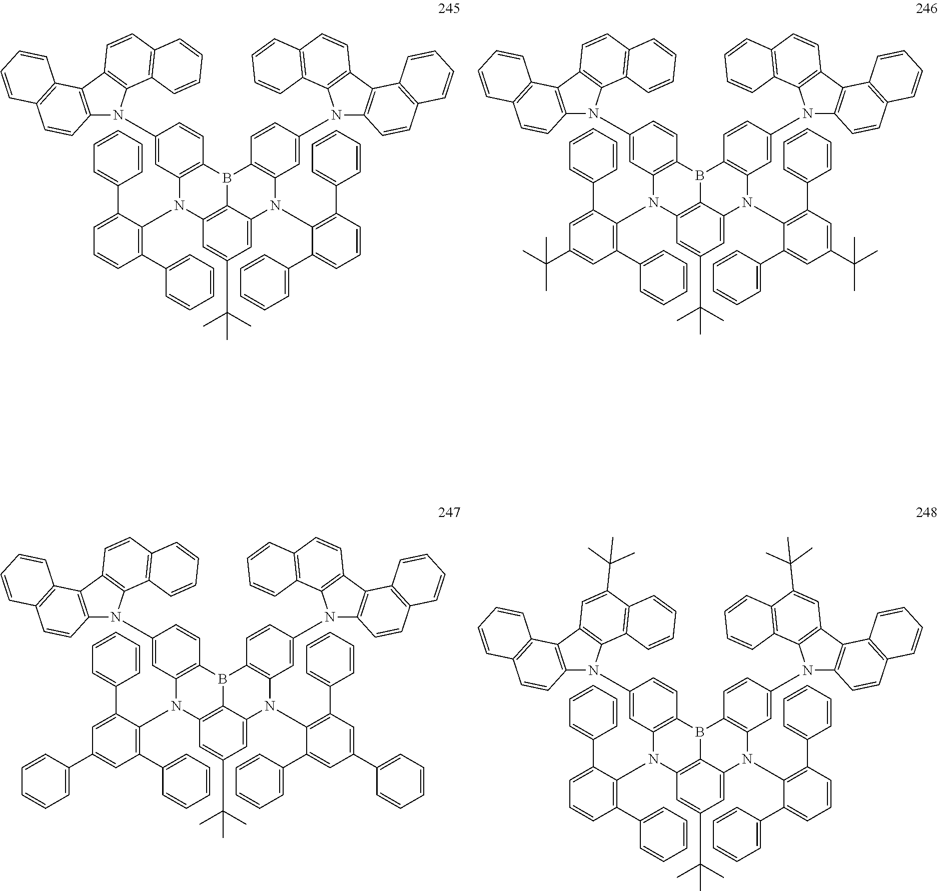

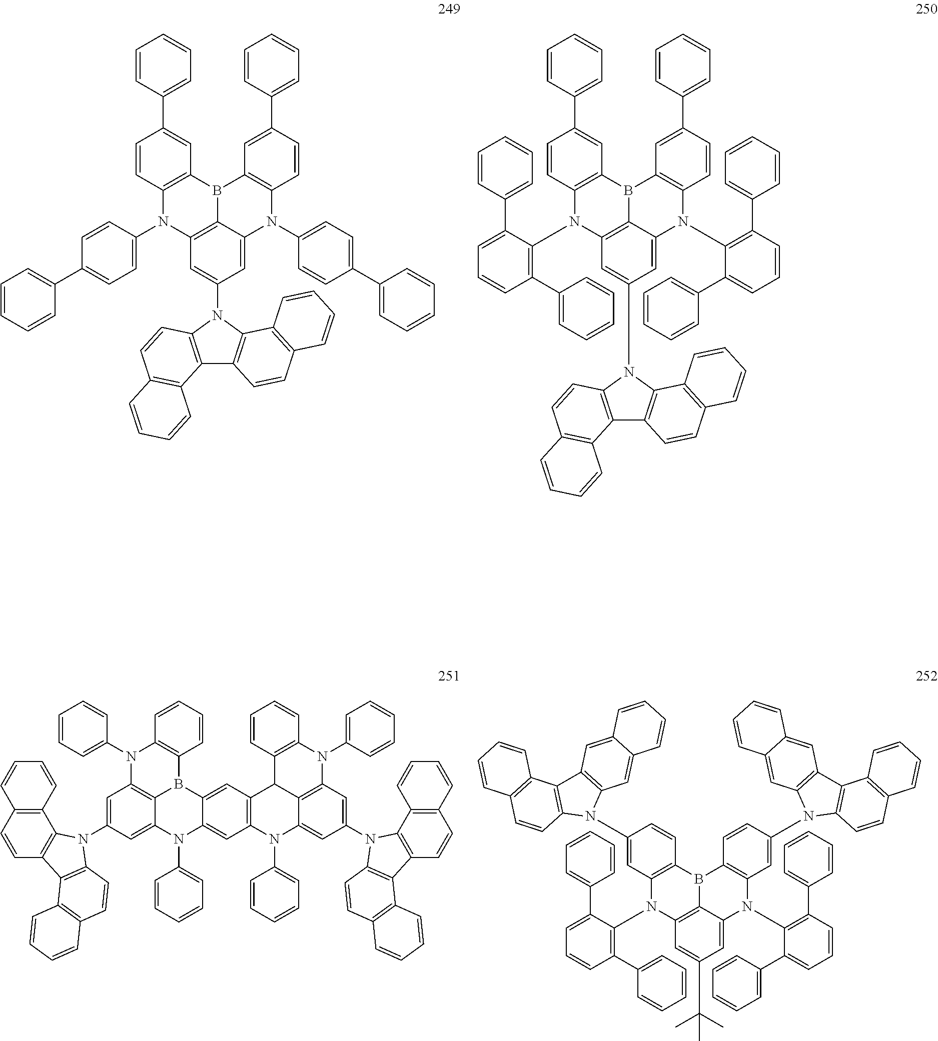

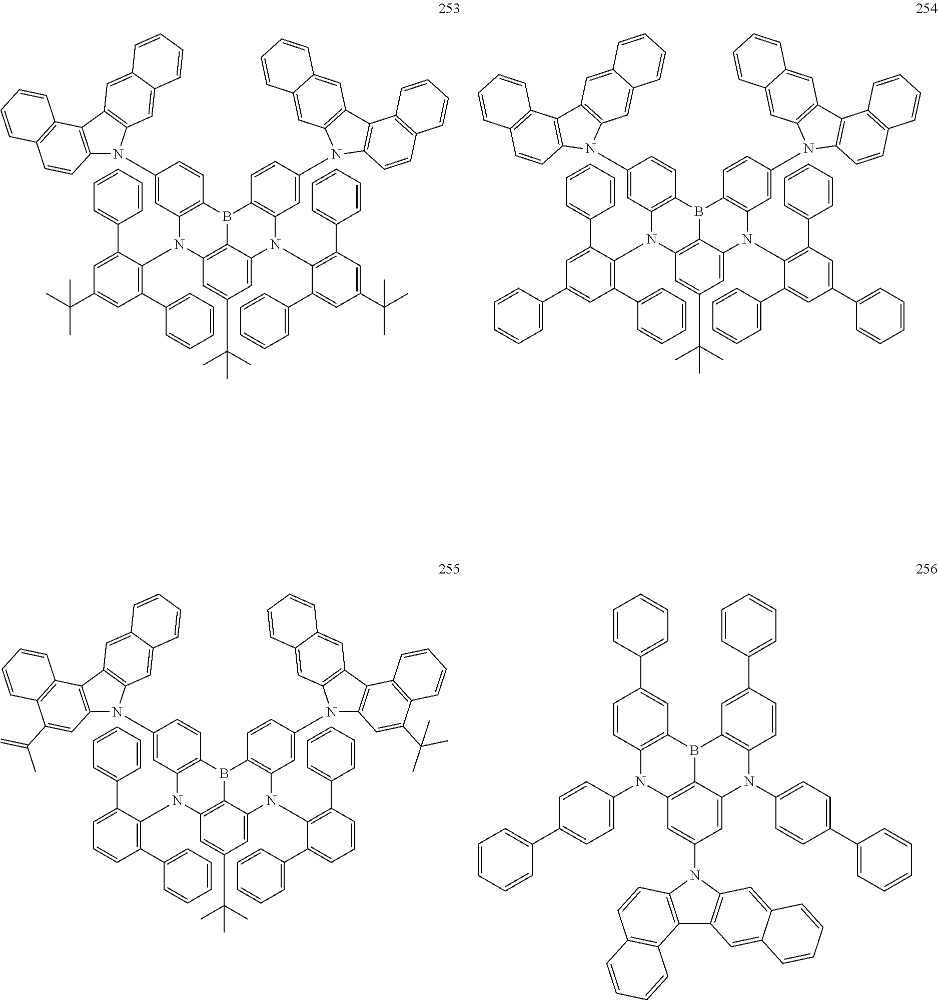

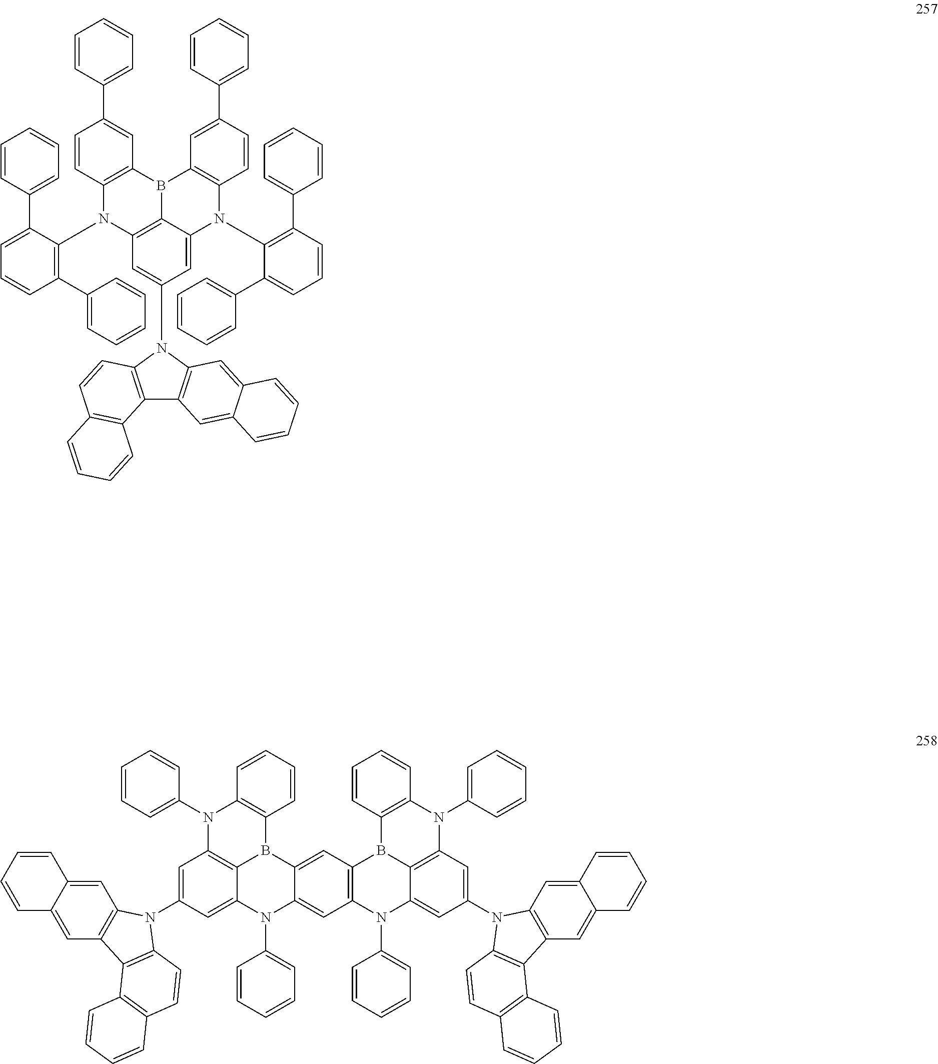 [SMILES: c1ccc(-c2ccc3c(c2)B2c4cc(-c5ccccc5)ccc4N(c4c(-c5ccccc5)cccc4-c4ccccc4)c4cc(-n5c6cc7ccccc7cc6c6c7ccccc7ccc65)cc(c42)N3c2c(-c3ccccc3)cccc2-c2ccccc2)cc1 ; c1ccc(N2c3ccccc3B3c4cc5c(cc4N(c4ccccc4)c4cc(-n6c7cc8ccccc8cc7c7c8ccccc8ccc76)cc2c43)N(c2ccccc2)c2cc(-n3c4cc6ccccc6cc4c4c6ccccc6ccc43)cc3c2B5c2ccccc2N3c2ccccc2)cc1]

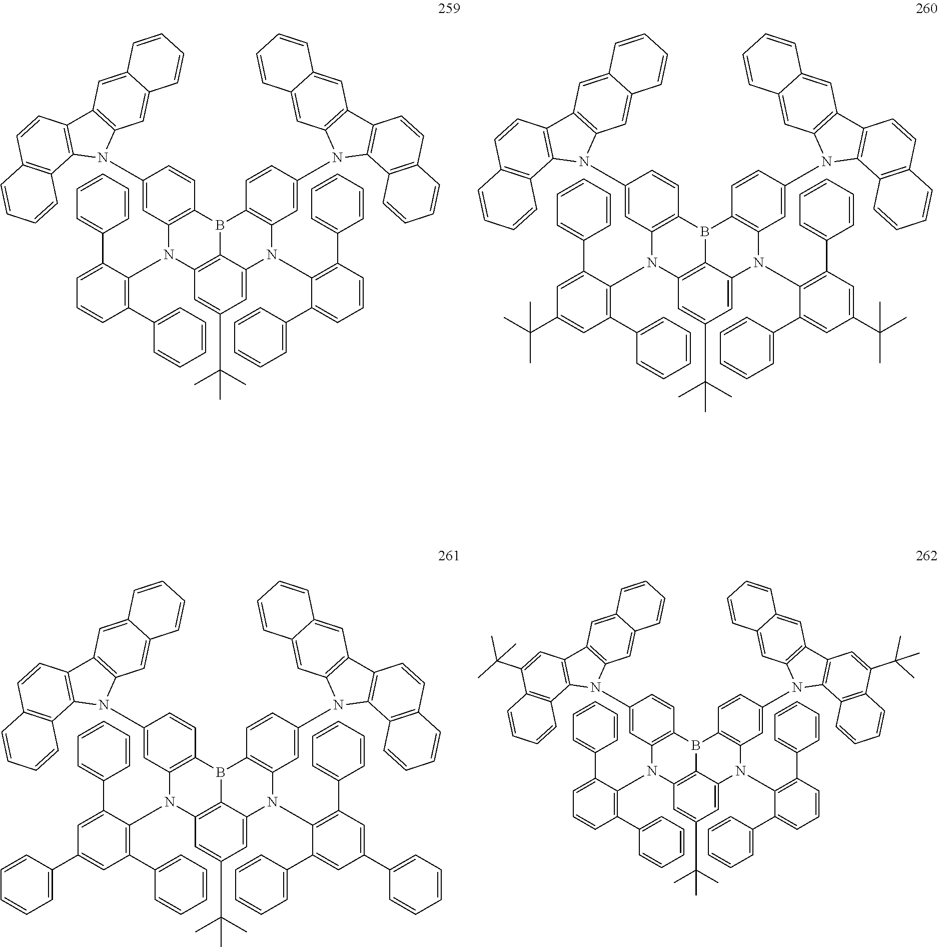

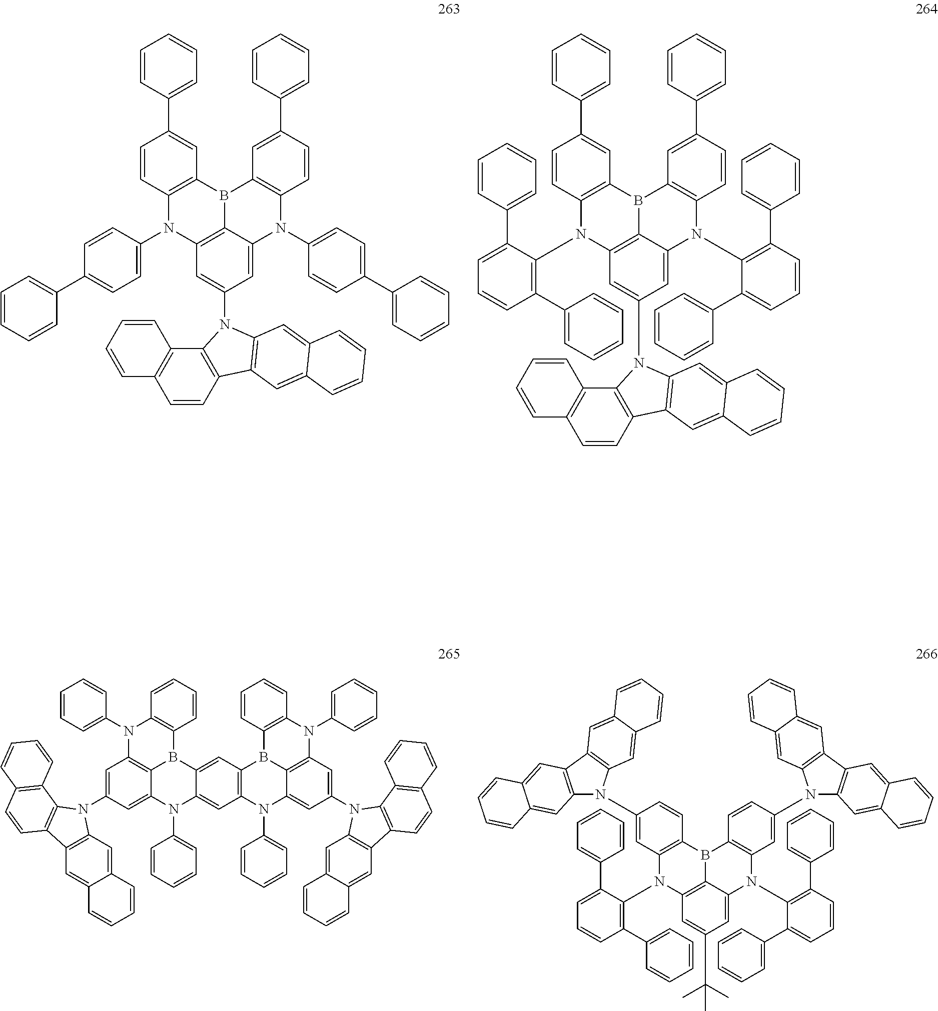

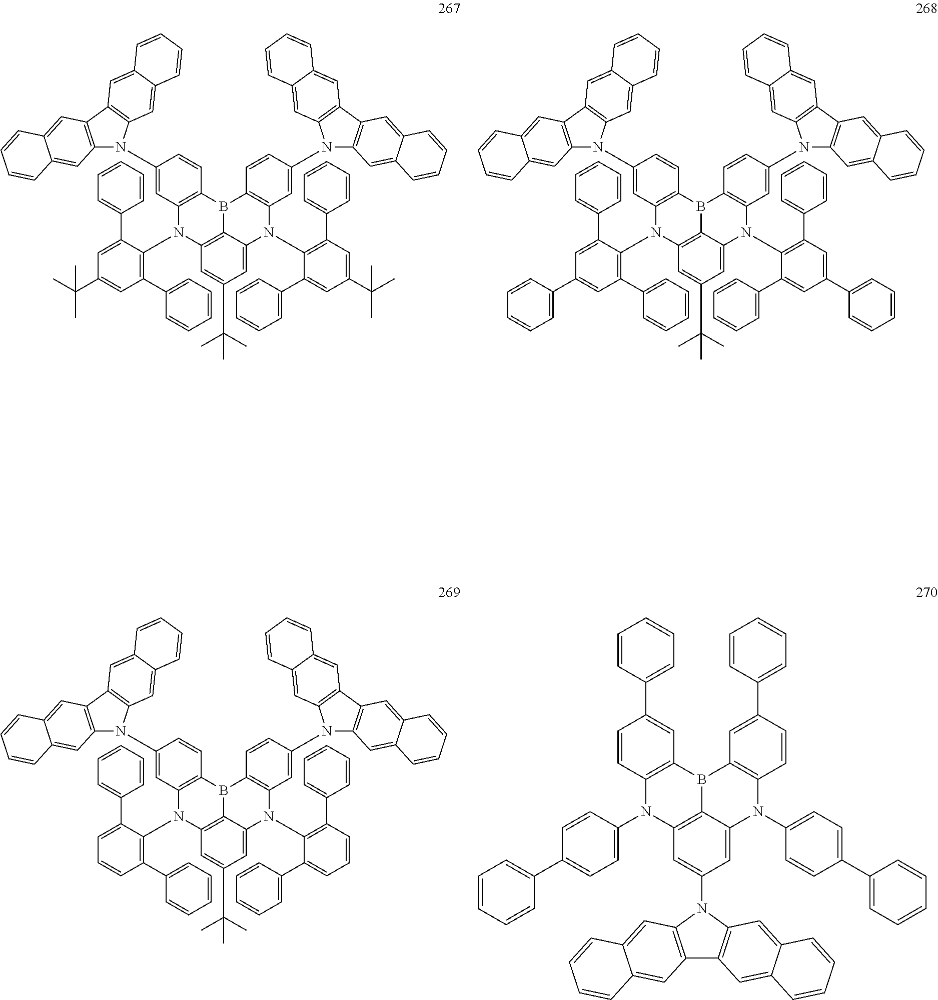

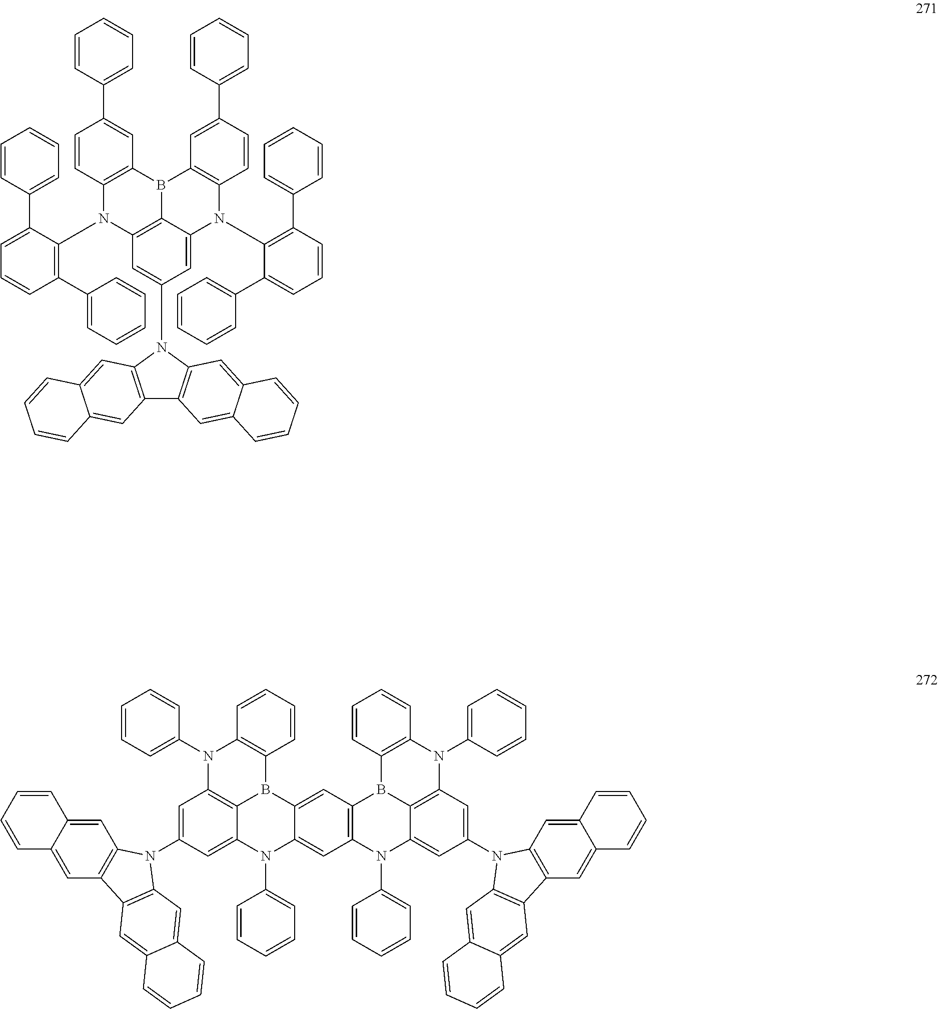 [SMILES: c1ccc(-c2ccc3c(c2)B2c4cc(-c5ccccc5)ccc4N(c4c(-c5ccccc5)cccc4-c4ccccc4)c4cc(-n5c6cc7ccccc7cc6c6cc7ccccc7cc65)cc(c42)N3c2c(-c3ccccc3)cccc2-c2ccccc2)cc1 ; c1ccc(N2c3ccccc3B3c4cc5c(cc4N(c4ccccc4)c4cc(-n6c7cc8ccccc8cc7c7cc8ccccc8cc76)cc2c43)N(c2ccccc2)c2cc(-n3c4cc6ccccc6cc4c4cc6ccccc6cc43)cc3c2B5c2ccccc2N3c2ccccc2)cc1]

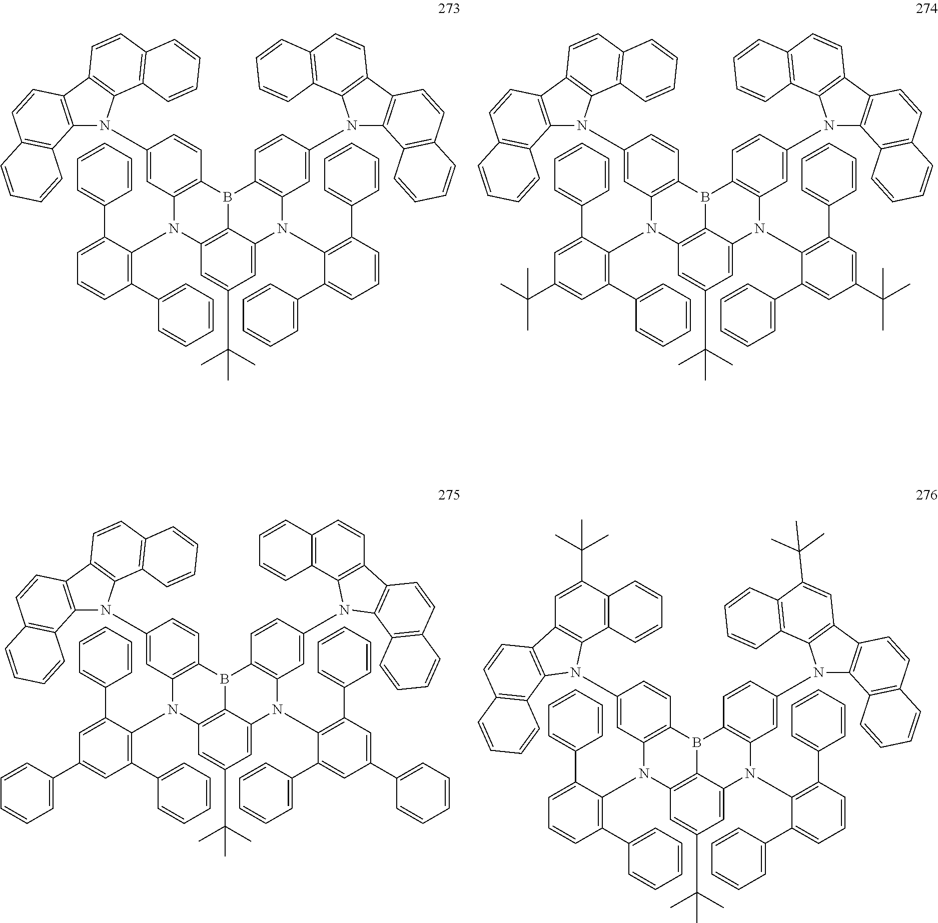

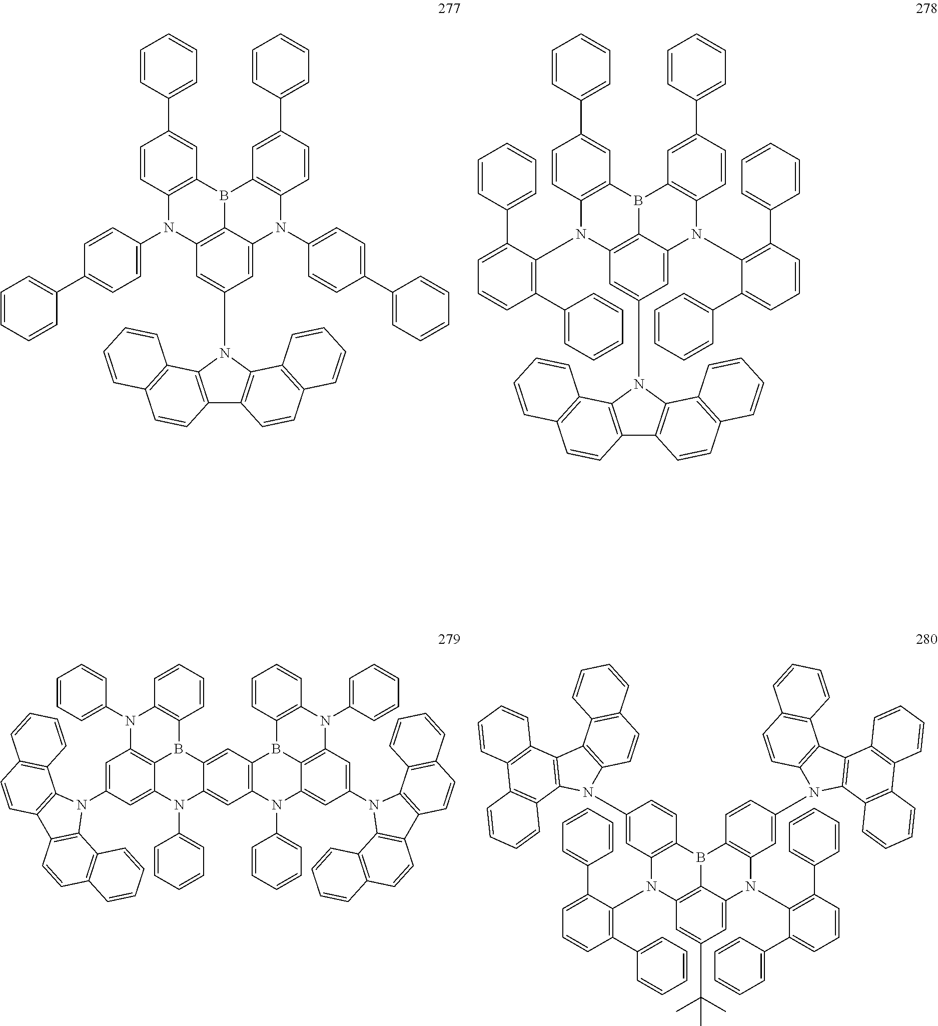

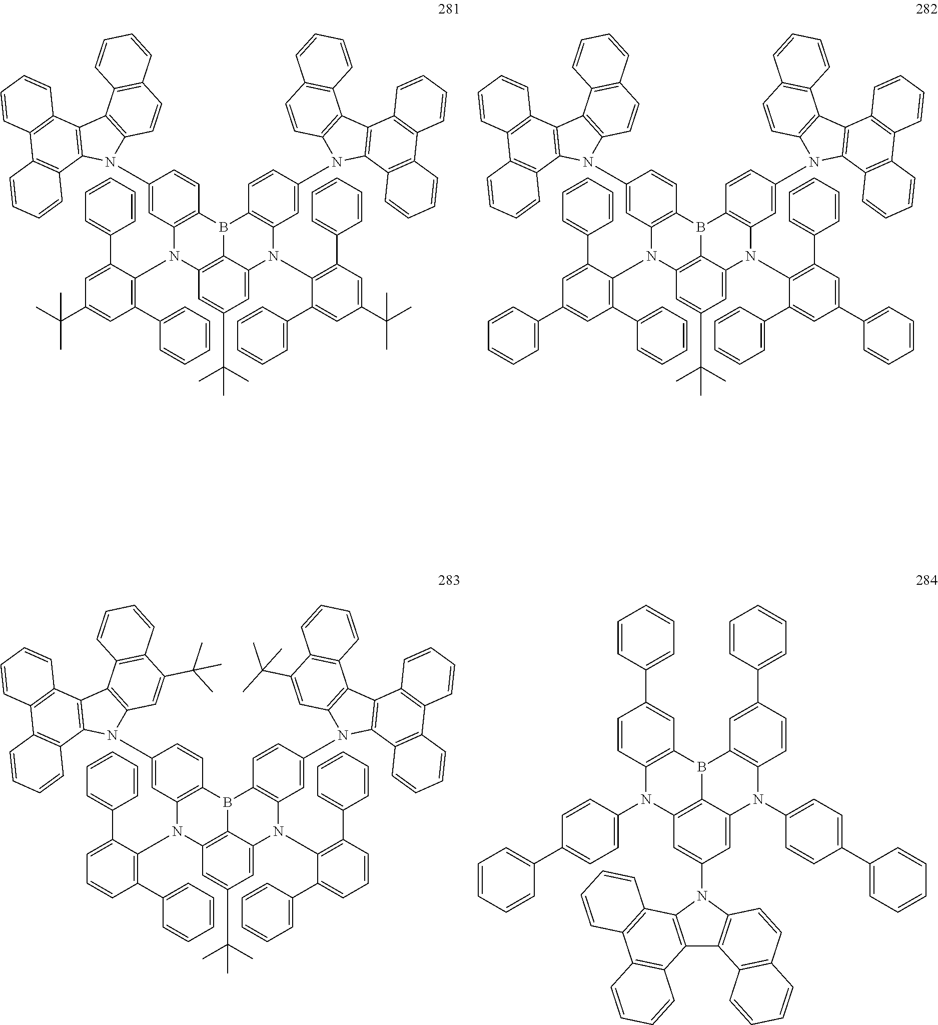

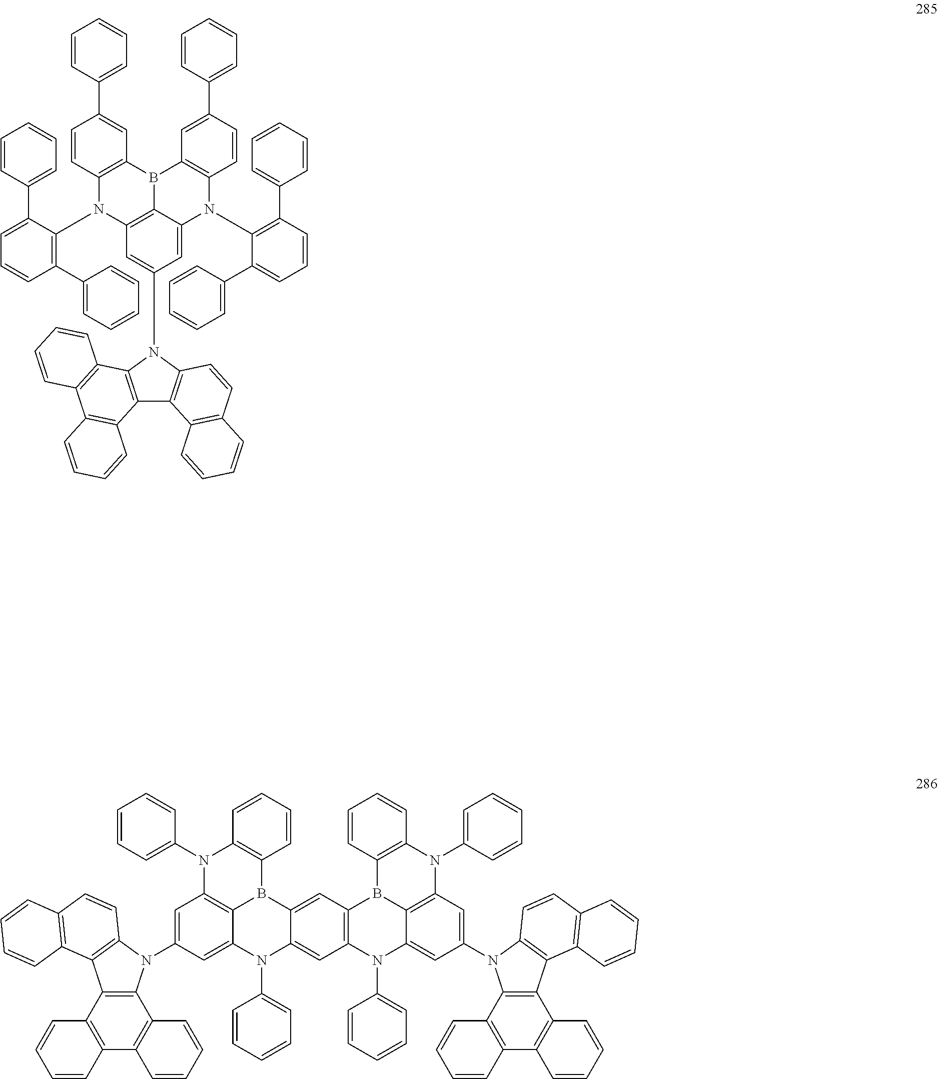 [SMILES: c1ccc(-c2ccc3c(c2)B2c4cc(-c5ccccc5)ccc4N(c4c(-c5ccccc5)cccc4-c4ccccc4)c4cc(-n5c6ccc7ccccc7c6c6c7ccccc7c7ccccc7c65)cc(c42)N3c2c(-c3ccccc3)cccc2-c2ccccc2)cc1 ; c1ccc(N2c3ccccc3B3c4cc5c(cc4N(c4ccccc4)c4cc(-n6c7ccc8ccccc8c7c7c8ccccc8c8ccccc8c76)cc2c43)N(c2ccccc2)c2cc(-n3c4ccc6ccccc6c4c4c6ccccc6c6ccccc6c43)cc3c2B5c2ccccc2N3c2ccccc2)cc1]

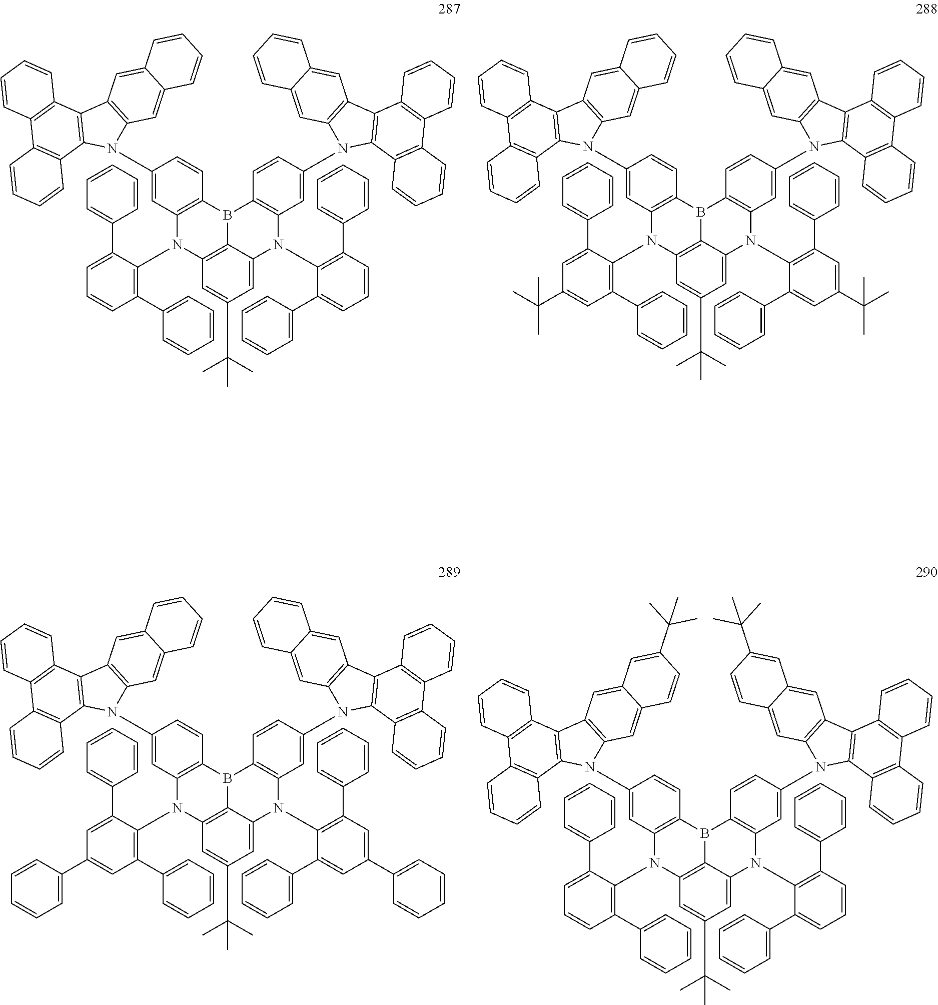

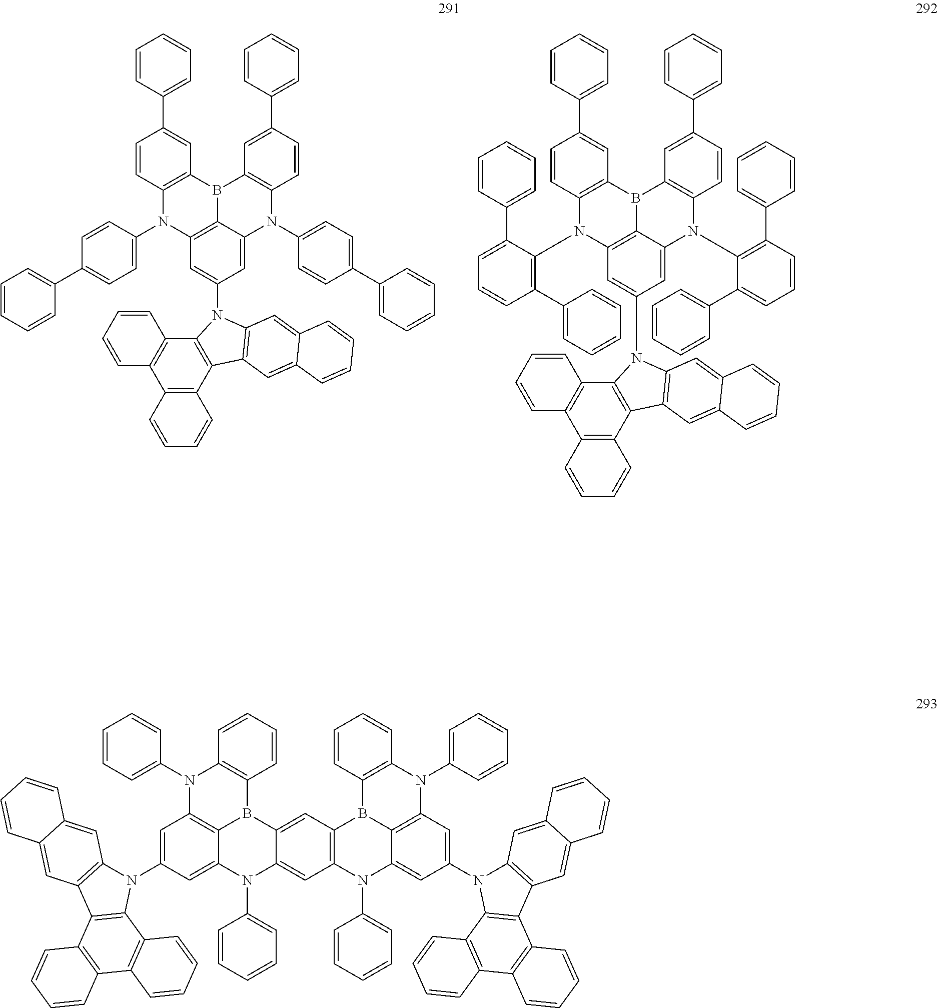

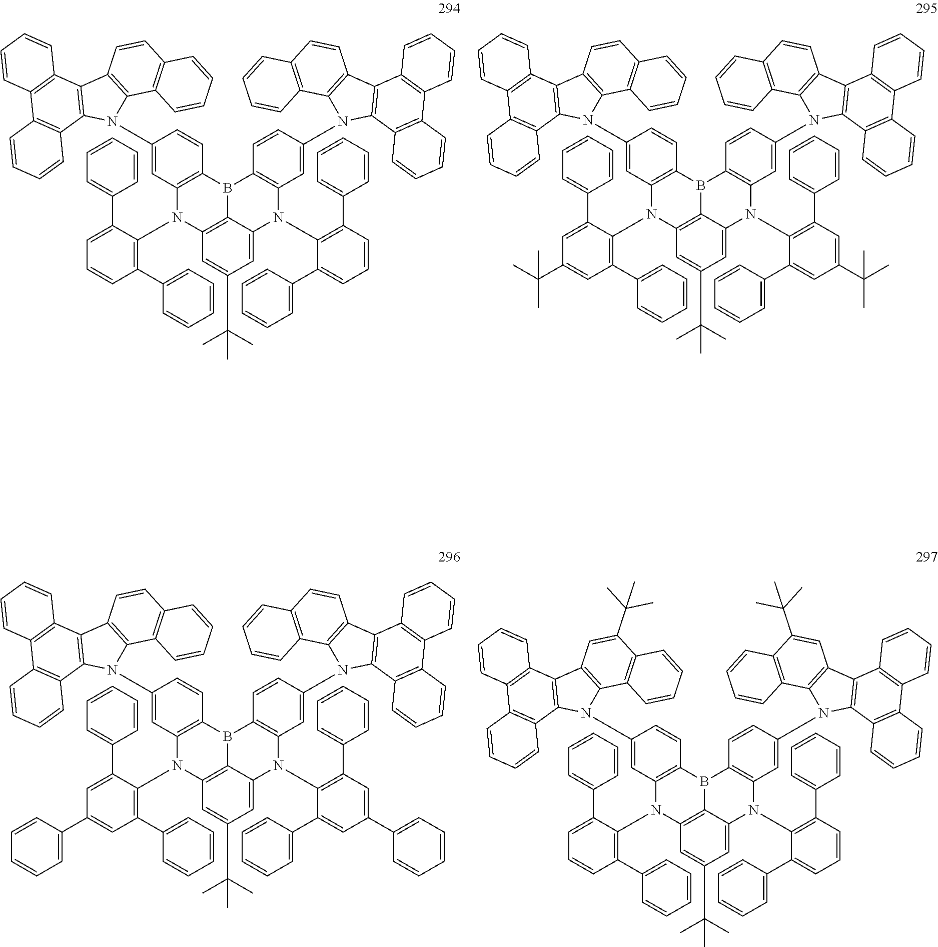

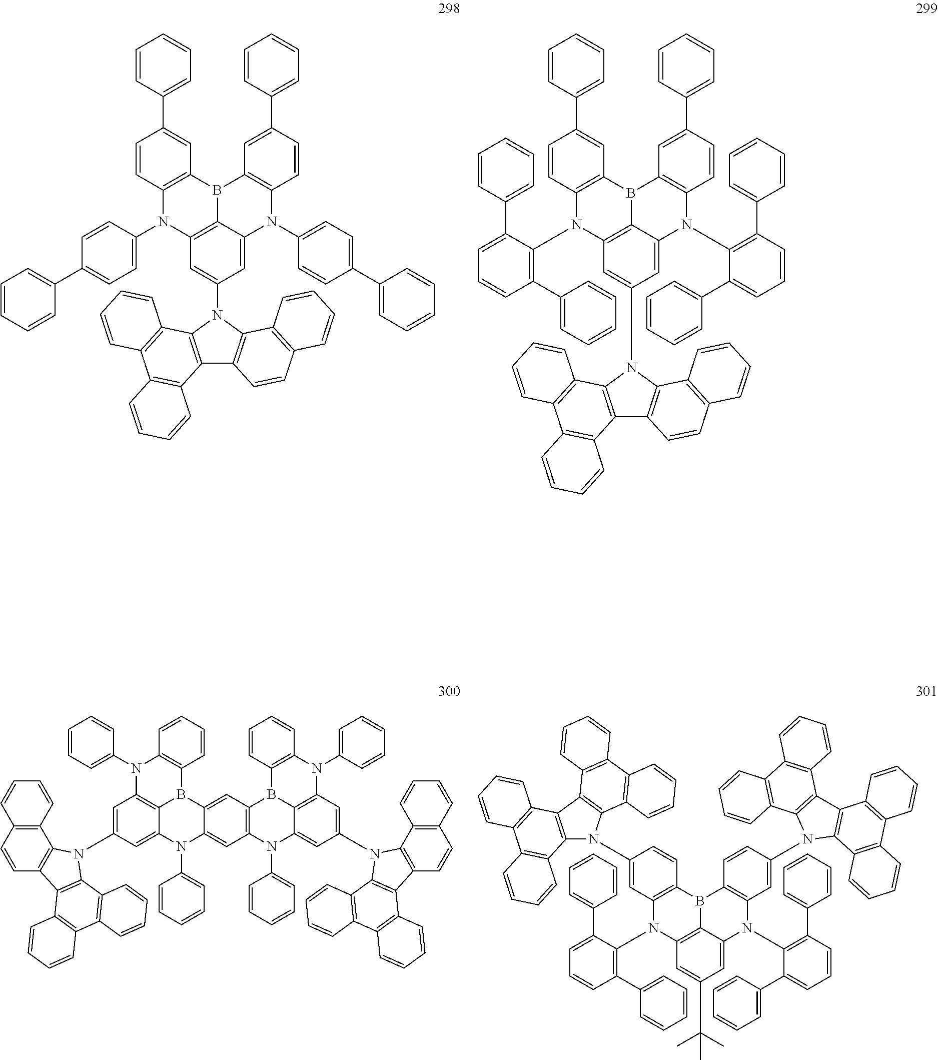

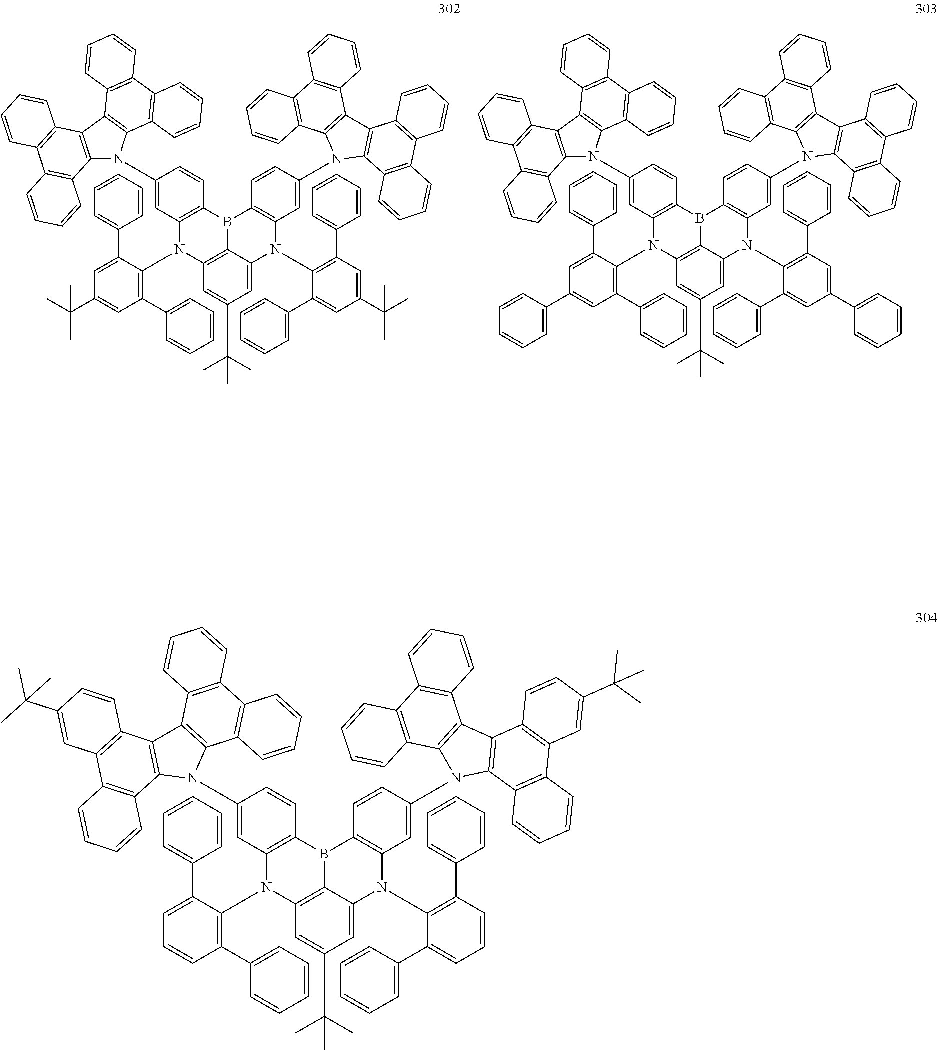

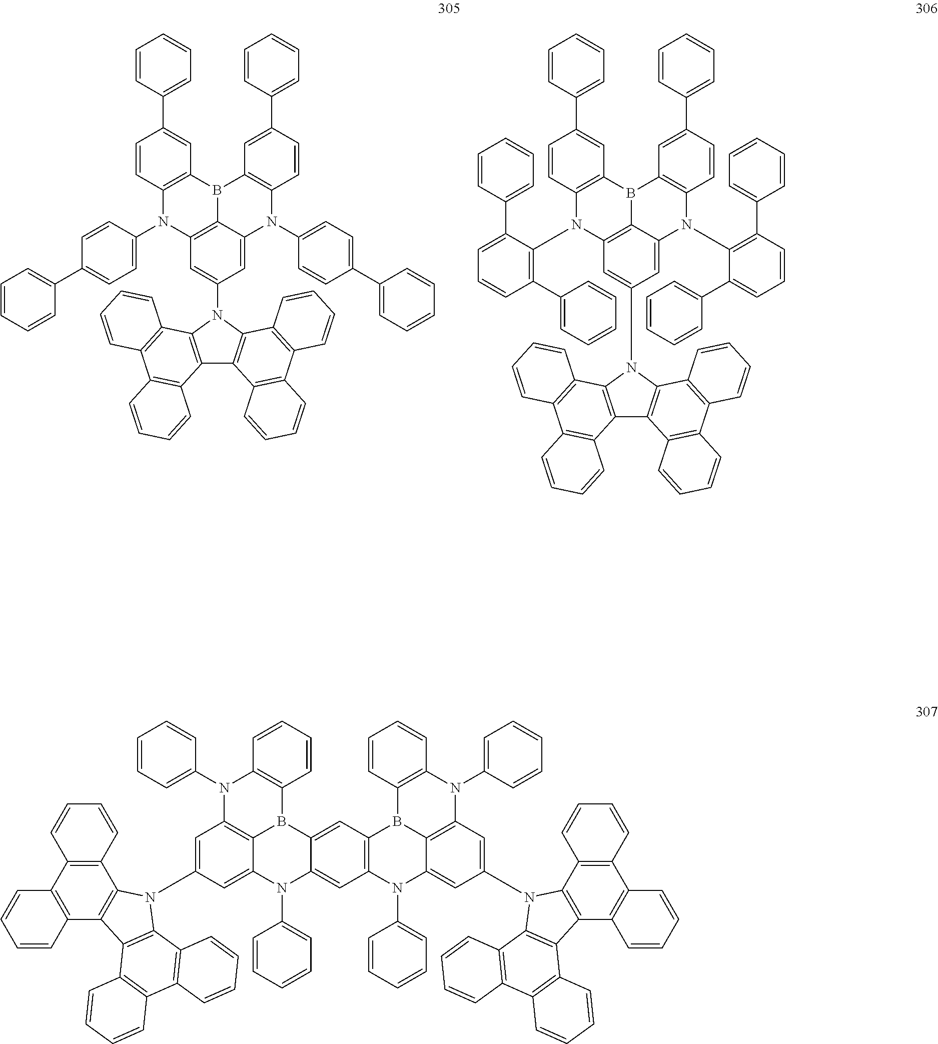

In Compound Group 1, D represents a deuterium atom.

The polycyclic compound according to an embodiment may be included in the emission layer EML. The polycyclic compound according to an embodiment may be included as a dopant material in the emission layer EML. The polycyclic compound according to an embodiment may be a thermally activated delayed fluorescence material. The polycyclic compound according to an embodiment may be used as a thermally activated delayed fluorescence dopant. For example, in the light emitting element ED according to an embodiment, the emission layer EML may include, as a thermally activated delayed fluorescence dopant, at least one of the polycyclic compounds represented by Compound Group 1 as described above. However, use of the polycyclic compound is not limited thereto.

In an embodiment, the emission layer EML may include multiple compounds. The emission layer EML according to an embodiment may include the polycyclic compound represented by Formula 1, i.e., the first compound, and at least one of a second compound represented by Formula HT-1, a third compound represented by Formula ET-1, and a fourth compound represented by Formula D-1.

In an embodiment, the emission layer EML may include the second compound represented by Formula HT-1. In an embodiment, the second compound may be used as a hole transporting host material of the emission layer EML.

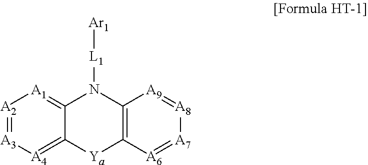

In Formula HT-1, A₁ to A₄ and A₆ to A₉ may each independently be N or C(R₄₁). For example, all of A₁ to A₄ and A₆ to A₉ may each be C(R₄₁). In an embodiment, any one of A₁ to A₄ and A₆ to A₉ may be N, and the remainder of A₁ to A₄ and A₆ to A₉ may each independently be C(R₄₁).

In Formula HT-1, L₁ may be a direct linkage, a substituted or unsubstituted arylene group having 6 to 30 ring-forming carbon atoms or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, etc., but the embodiments are not limited thereto.

In Formula HT-1, Yₐ may be a direct linkage, C(R₄₂)(R₄₃), or Si(R₄₄)(R₄₅). For example, it may mean that the two benzene rings linked to the nitrogen atom in Formula HT-1 are linked to each other via a direct linkage,

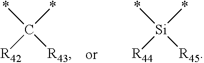

In Formula HT-1, when Yₐ is a direct linkage, the substituent represented by Formula HT-1 may include a carbazole moiety.

In Formula HT-1, Ar₁ may be a substituted or unsubstituted aryl group having 6 to 30 ring-forming carbon atoms or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, etc., but embodiments are not limited thereto.

In Formula HT-1, R₄₁ to R₄₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In an embodiment, each of R₄₁ to R₄₅ may be bonded to an adjacent group to form a ring. For example, R₄₁ to R₄₅ may each independently be a hydrogen atom or a deuterium atom. For example, R₄₁ to R₄₅ may each independently be an unsubstituted methyl group or an unsubstituted phenyl group.

In an embodiment, the second compound represented by Formula HT-1 may be selected from Compound Group 2. The emission layer EML may include at least one compound selected from Compound Group 2 as a hole transporting host material.

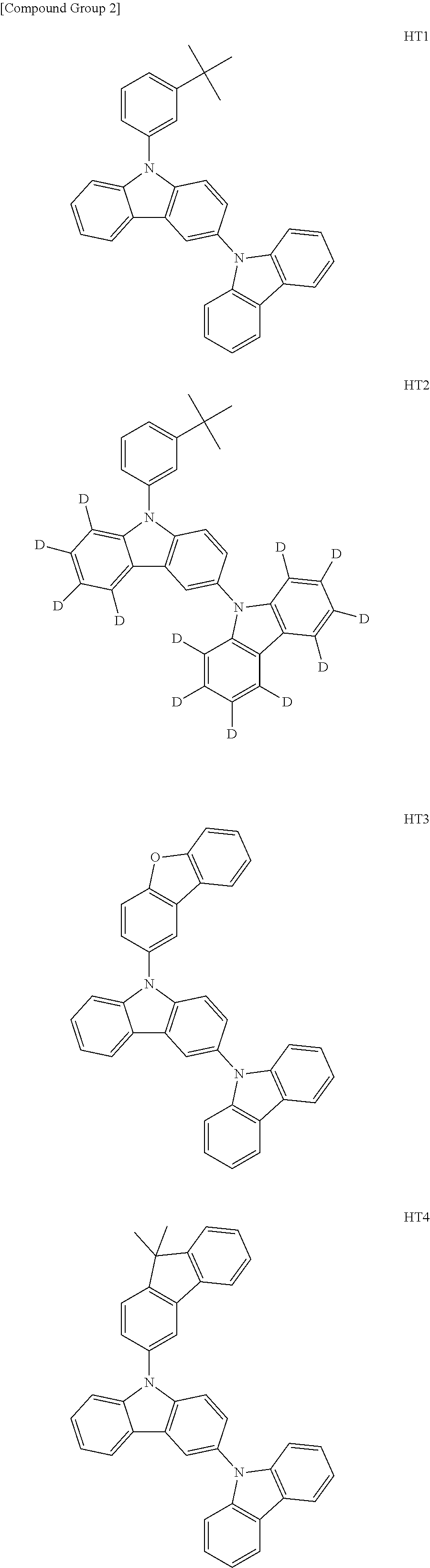 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12 ; CC1(C)c2ccccc2-c2cc(-n3c4ccccc4c4cc(-n5c6ccccc6c6ccccc65)ccc43)ccc21]

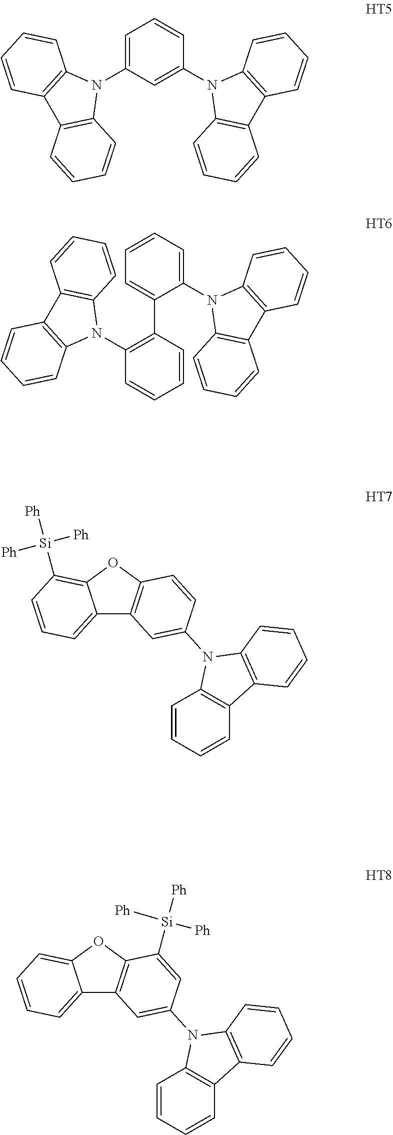 [SMILES: c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

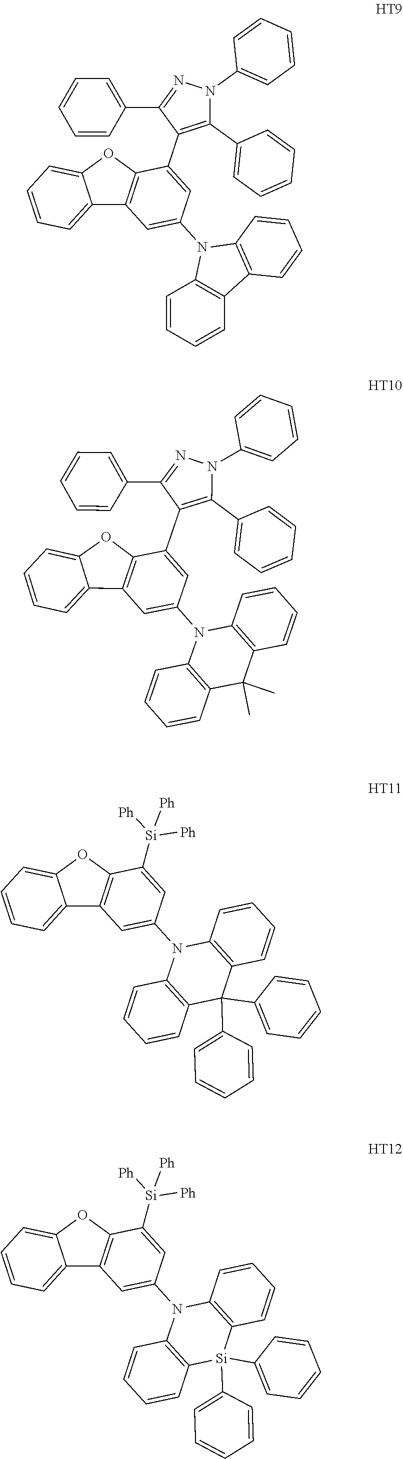 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

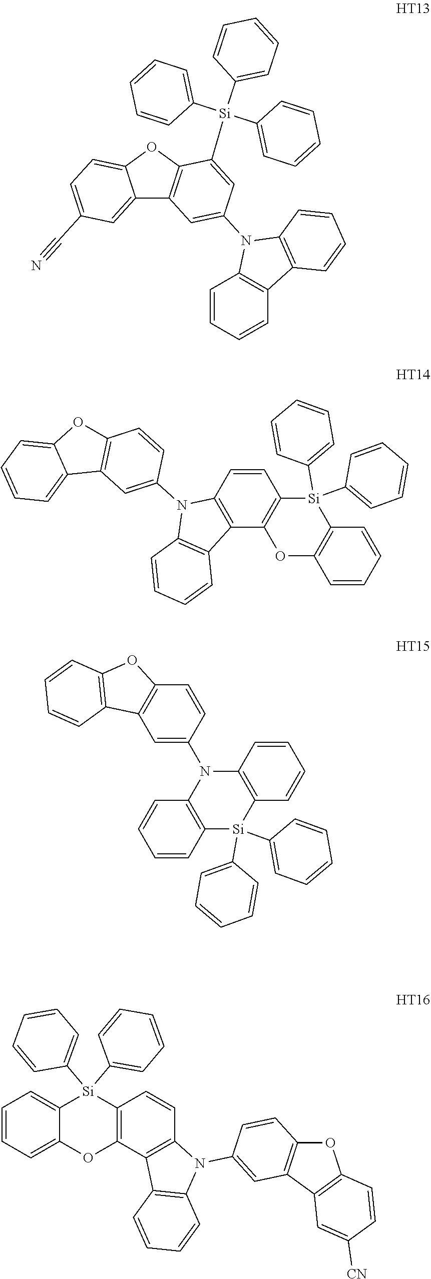 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

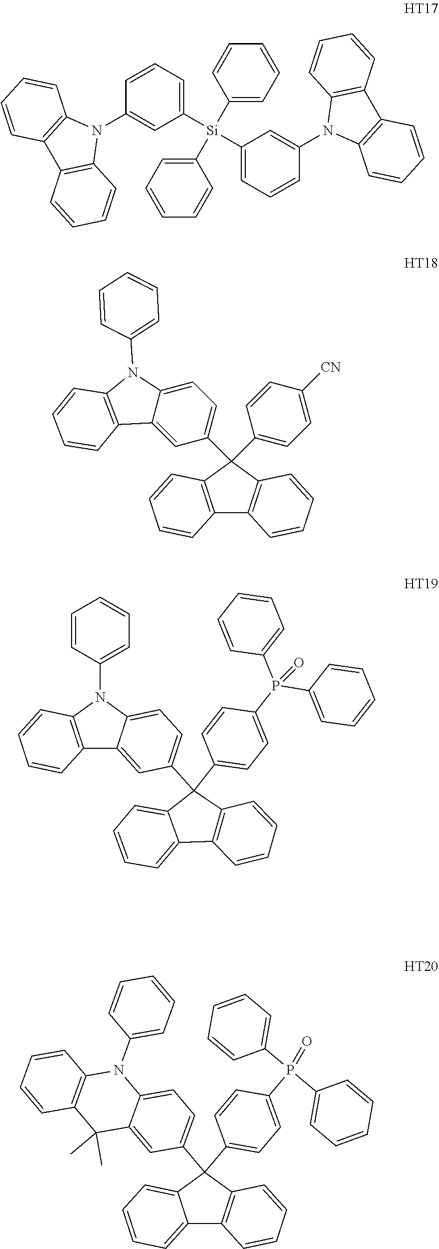 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

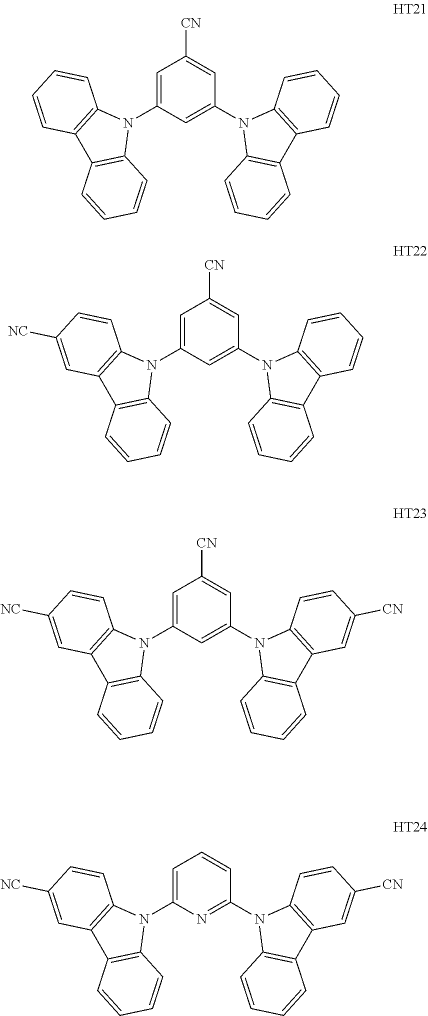 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

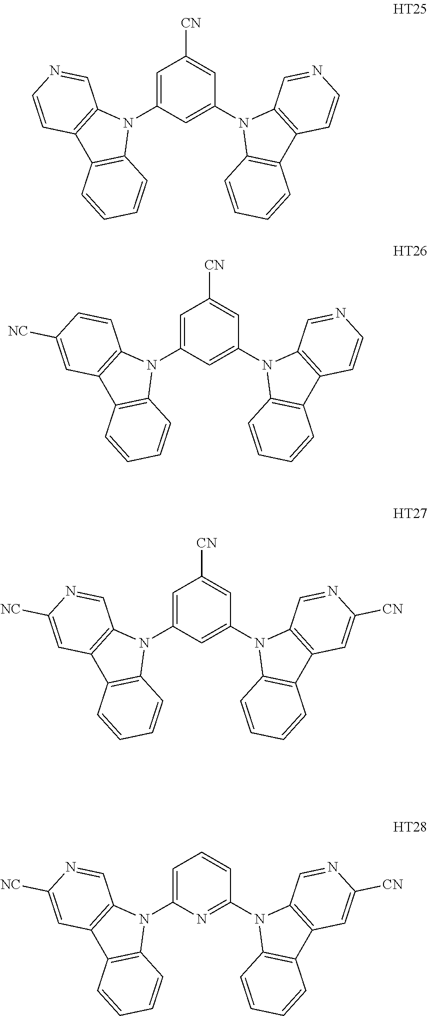 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

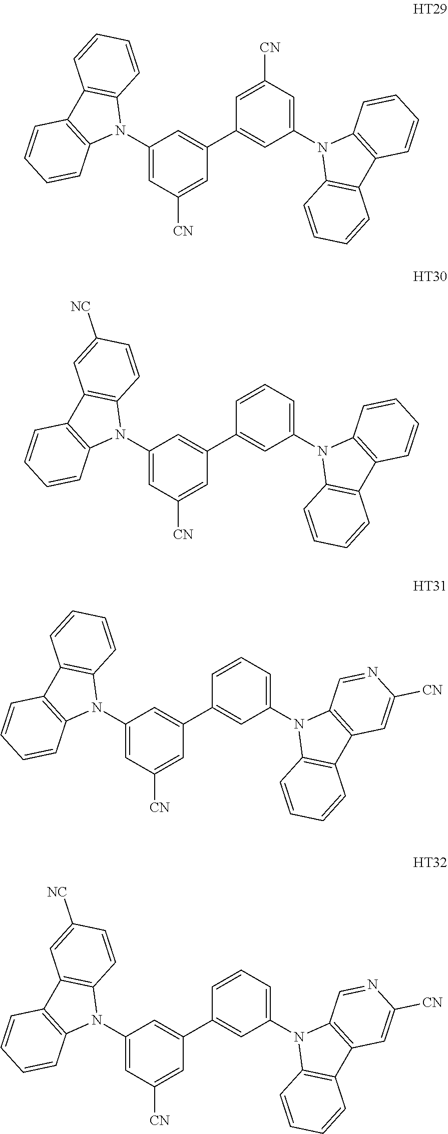 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ncc43)c2)cc(-n2c3ccccc3c3ccccc32)c1 ; N#Cc1cc(-c2cccc(-n3c4ccccc4c4cc(C#N)ncc43)c2)cc(-n2c3ccccc3c3cc(C#N)ccc32)c1]

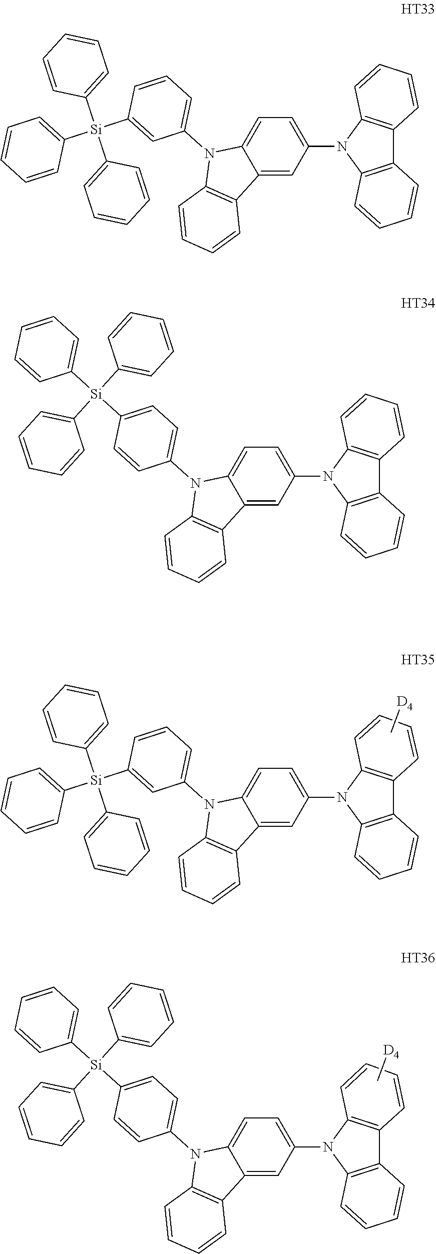

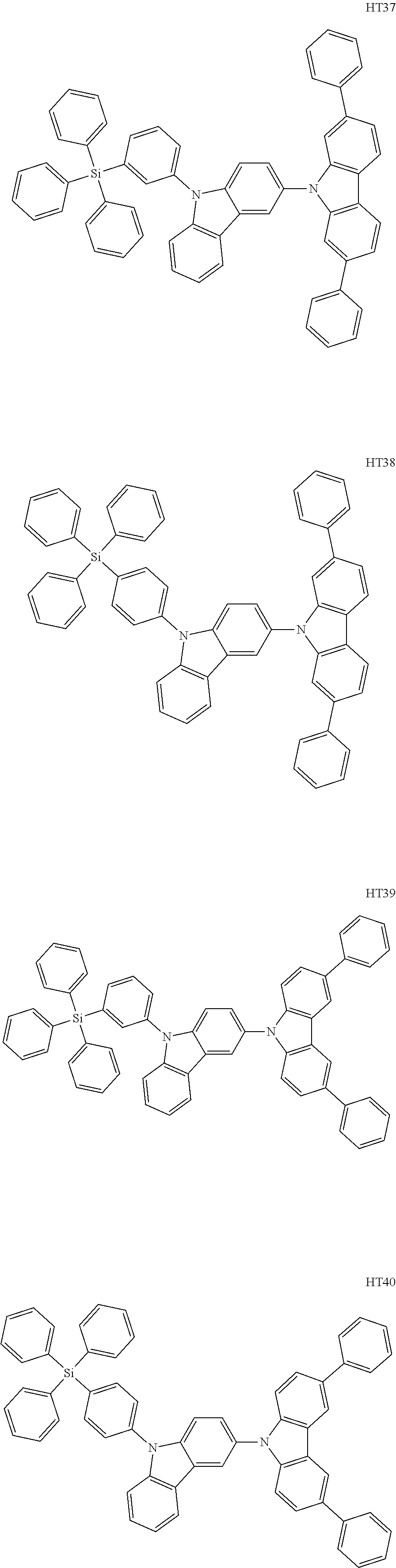 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

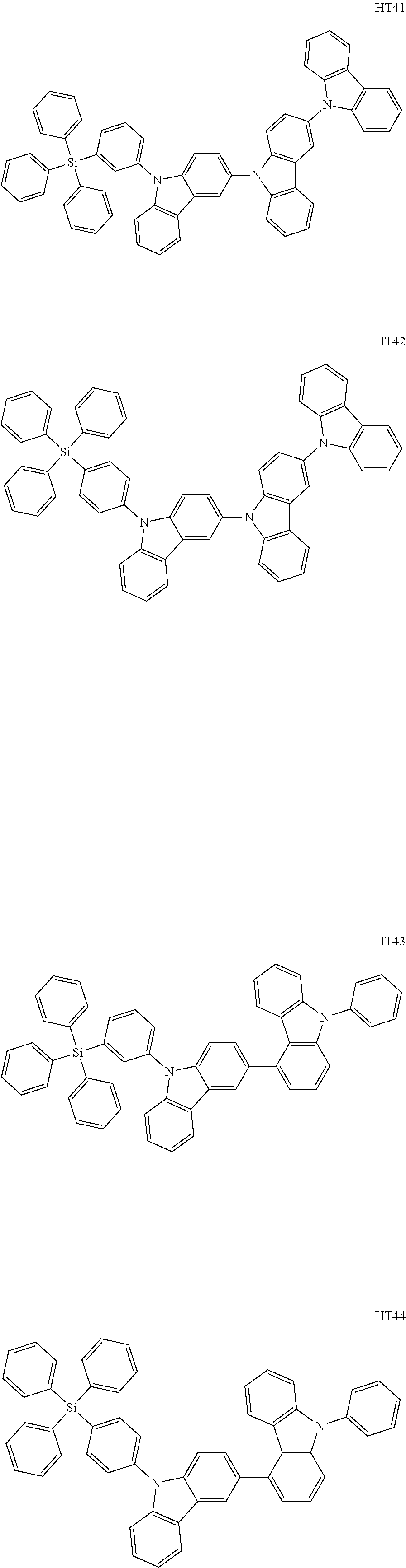 [SMILES: c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1 ; c1ccc(-n2c3ccccc3c3c(-c4ccc5c(c4)c4ccccc4n5-c4ccc([Si](c5ccccc5)(c5ccccc5)c5ccccc5)cc4)cccc32)cc1]

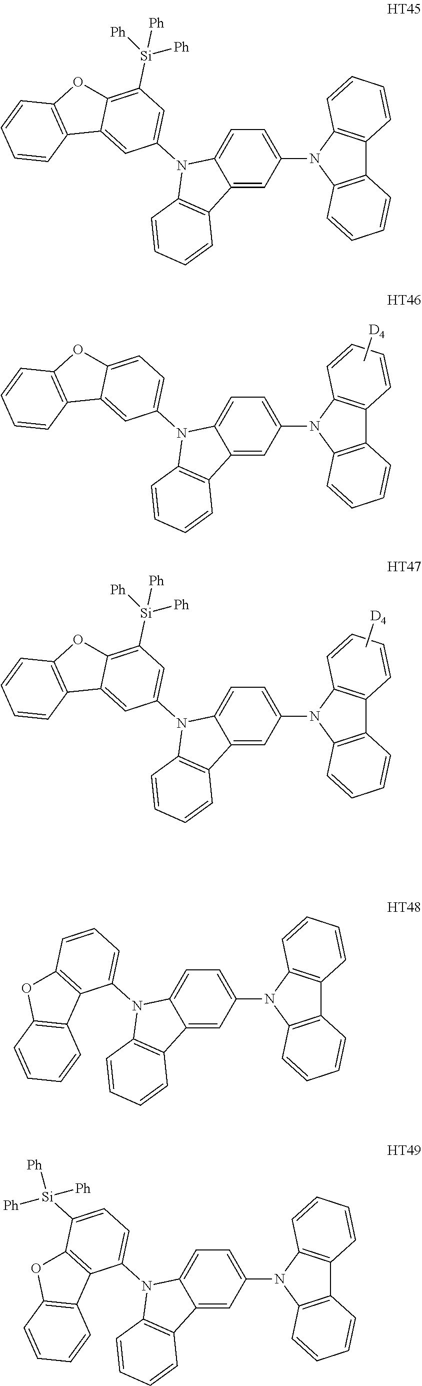

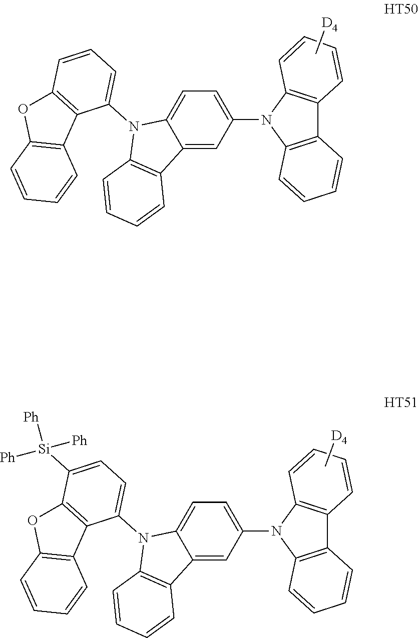

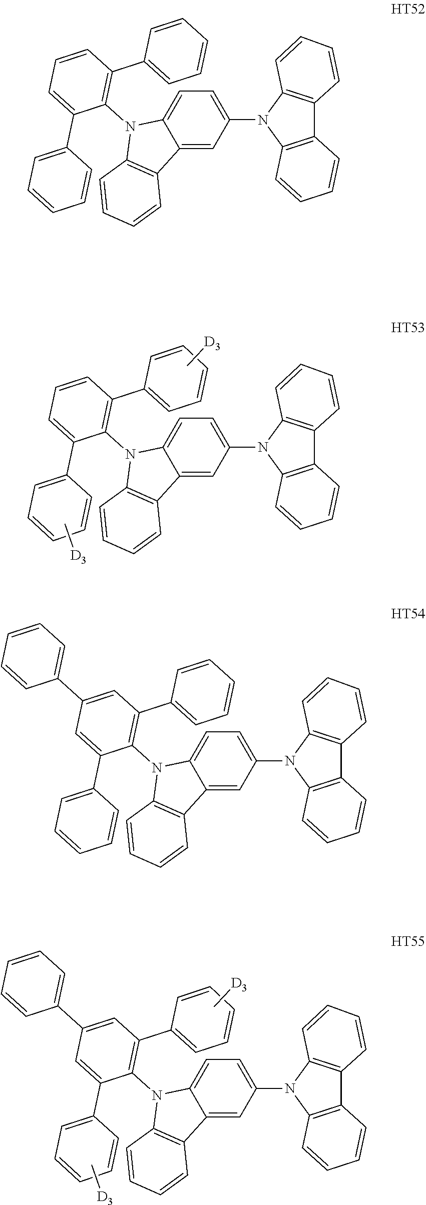

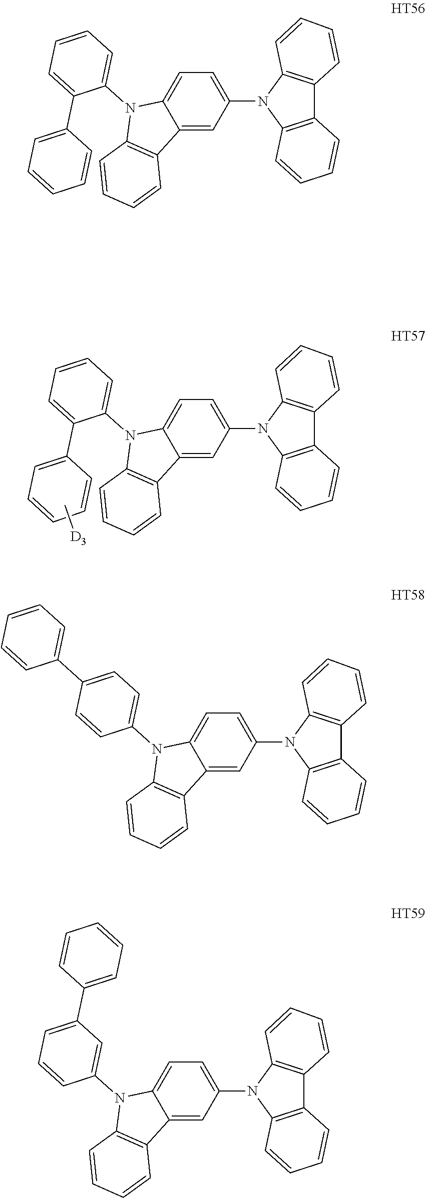

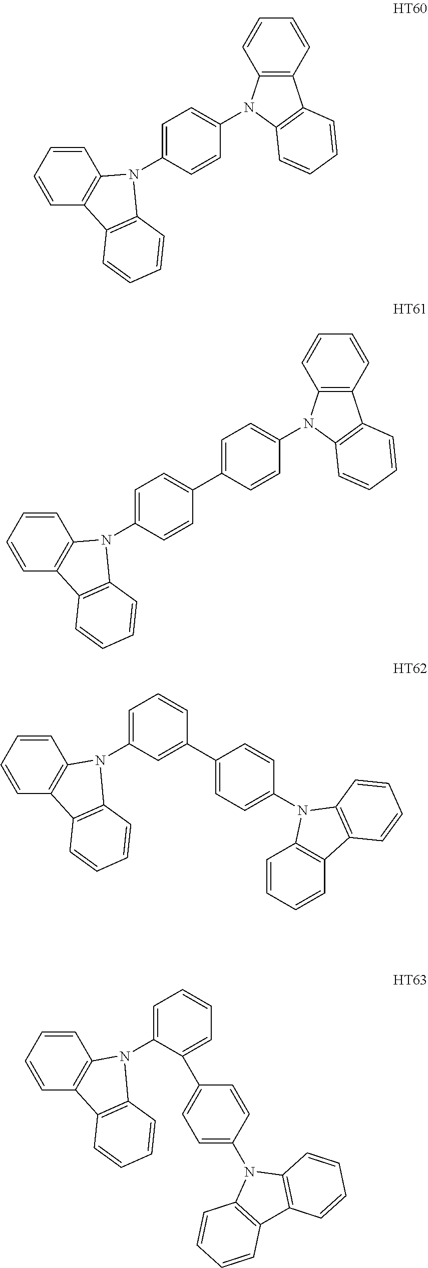 [SMILES: c1ccc2c(c1)c1ccccc1n2-c1ccc(-n2c3ccccc3c3ccccc32)cc1 ; c1ccc2c(c1)c1ccccc1n2-c1ccc(-c2ccc(-n3c4ccccc4c4ccccc43)cc2)cc1 ; c1cc(-c2ccc(-n3c4ccccc4c4ccccc43)cc2)cc(-n2c3ccccc3c3ccccc32)c1 ; c1ccc(-n2c3ccccc3c3ccccc32)c(-c2ccc(-n3c4ccccc4c4ccccc43)cc2)c1]

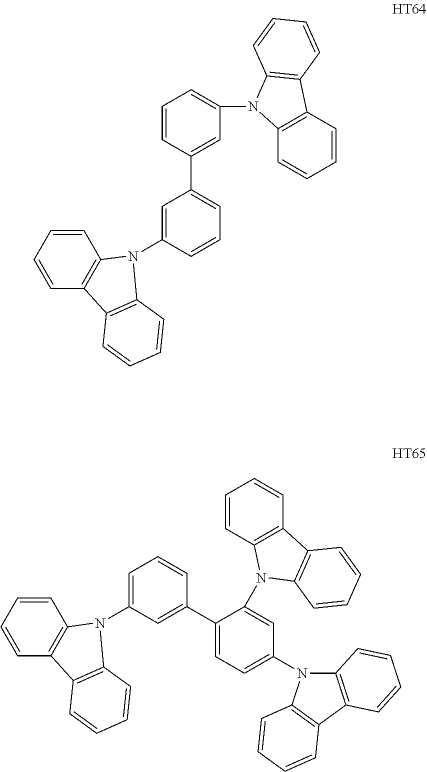 [SMILES: c1cc(-c2cccc(-n3c4ccccc4c4ccccc43)c2)cc(-n2c3ccccc3c3ccccc32)c1 ; c1cc(-c2ccc(-n3c4ccccc4c4ccccc43)cc2-n2c3ccccc3c3ccccc32)cc(-n2c3ccccc3c3ccccc32)c1]

In Compound Group 2, D represents a deuterium atom, and Ph represents an unsubstituted phenyl group. For example, in Compound Group 2, Ph may represent an unsubstituted phenyl group.

In an embodiment, the emission layer EML may further include the third compound represented by Formula ET-1. In an embodiment, the third compound may be used as an electron transport host material in the emission layer EML.

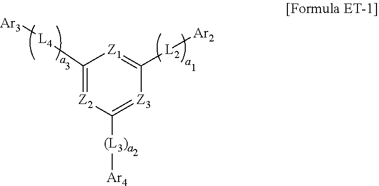

In Formula ET-1, at least one of Z₁ to Z₃ may each be N; the remainder of Z₁ to Z₃ may each independently be C(Rₐ₃); and Rₐ₃ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, a₁ to a₃ may each independently be an integer from 0 to 10.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. When each of a₁ to a₃ is 2 or greater, L₂ to L₄ may each independently be a substituted or unsubstituted arylene group having 6 to 30 ring-forming carbon atoms, or a substituted or unsubstituted heteroarylene group having 2 to 30 ring-forming carbon atoms.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group, or a substituted or unsubstituted carbazole group.

In an embodiment, the third compound may be selected from Compound Group 3. In an embodiment, the emission layer EML may include at least one compound selected from Compound Group 3:

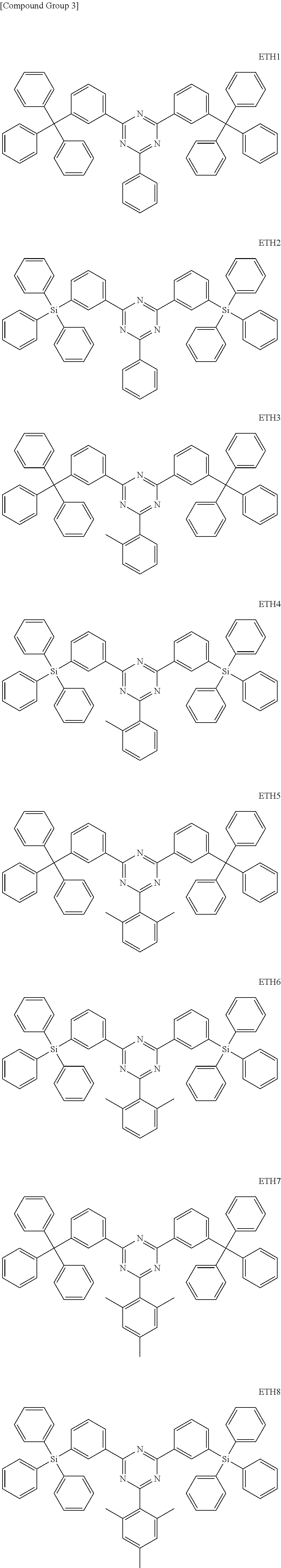

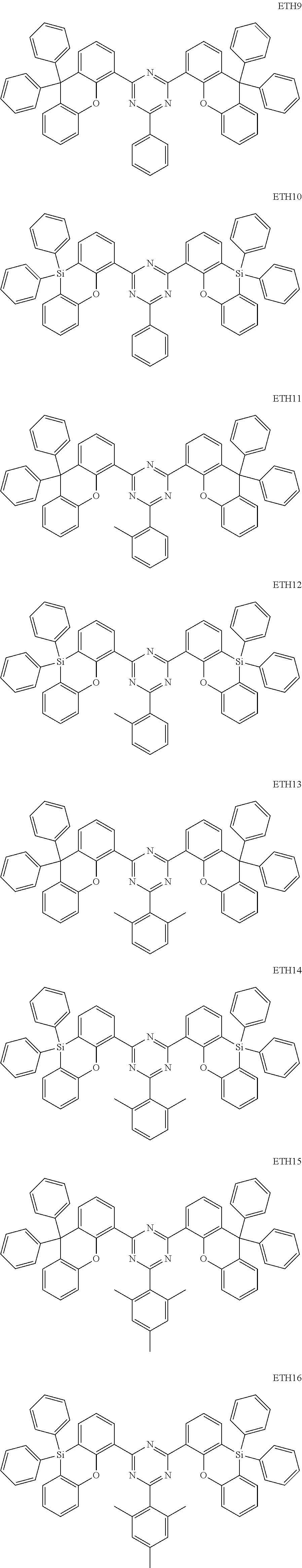

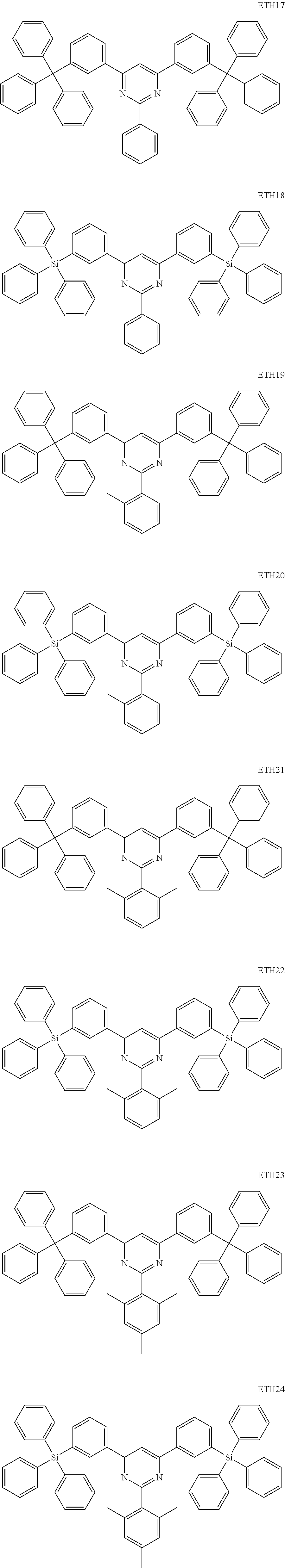

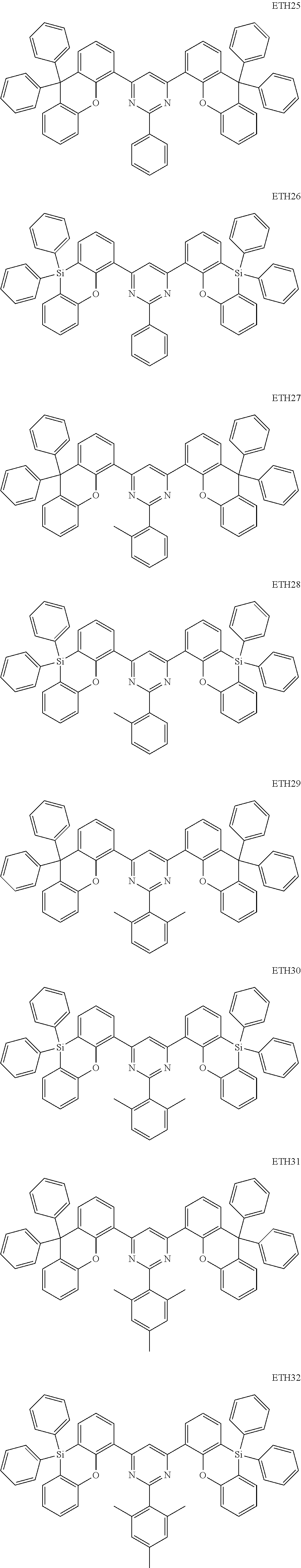

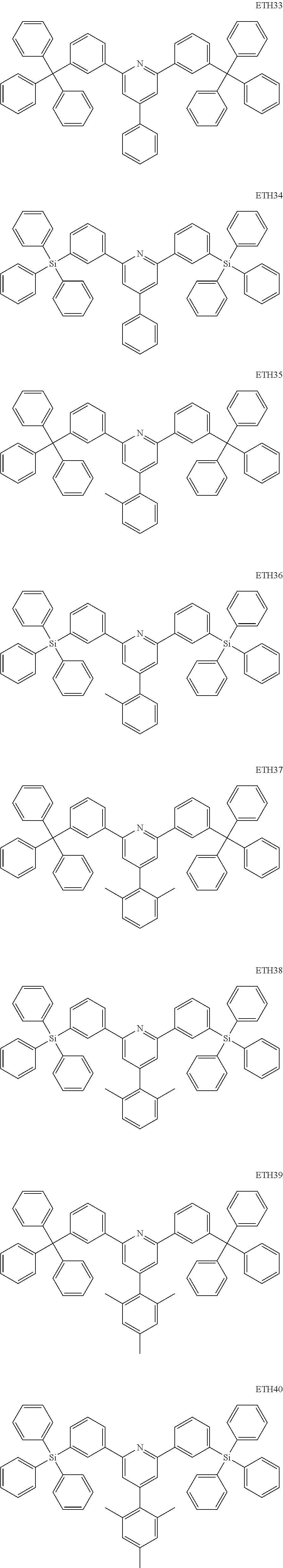

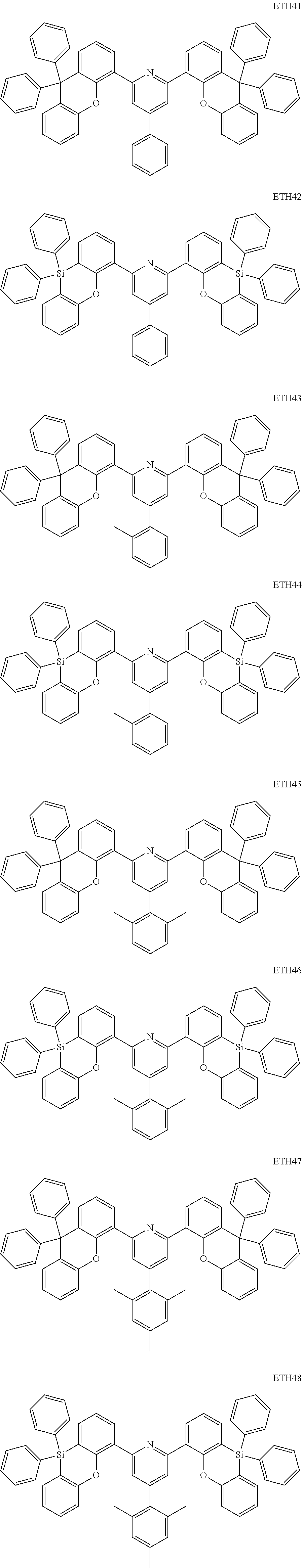

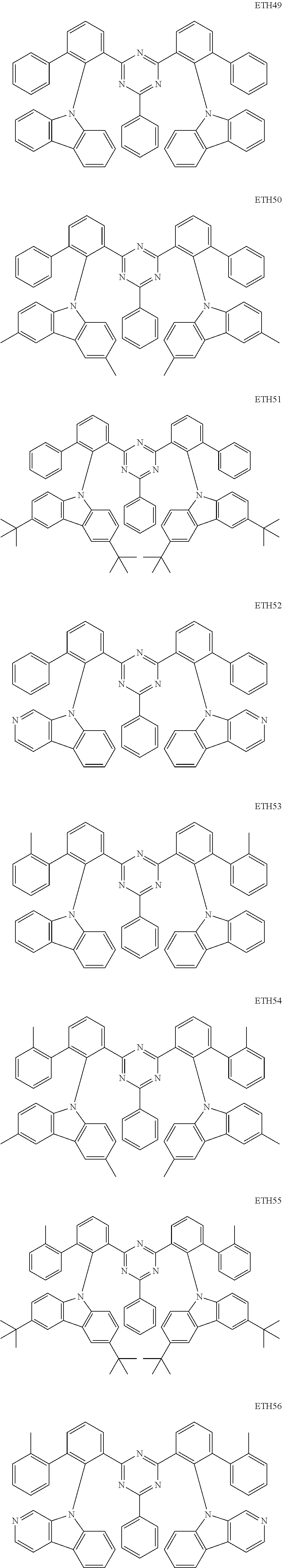

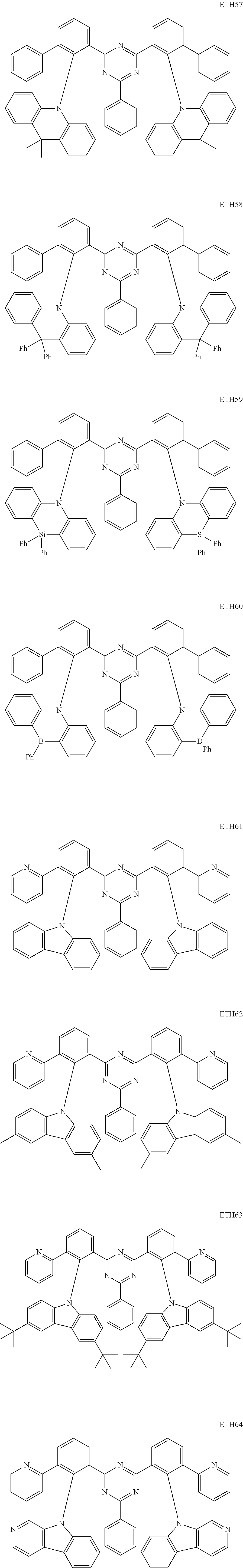

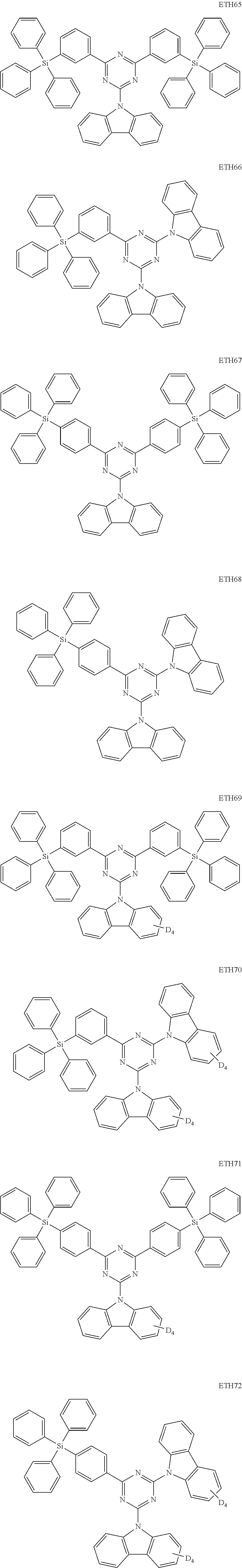

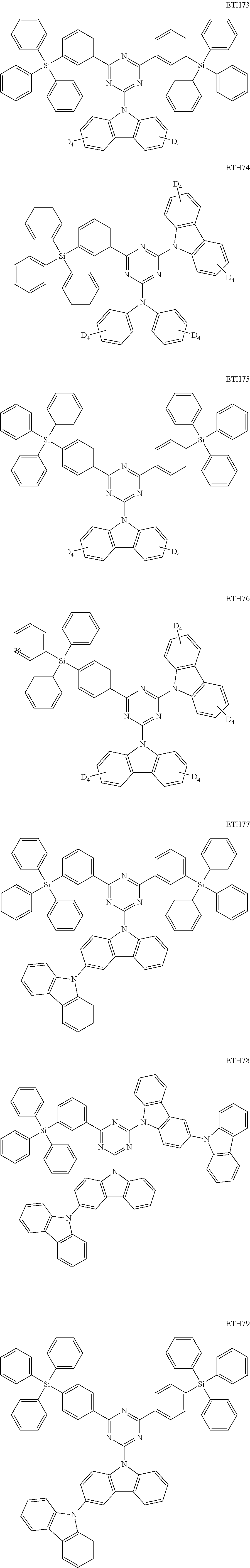

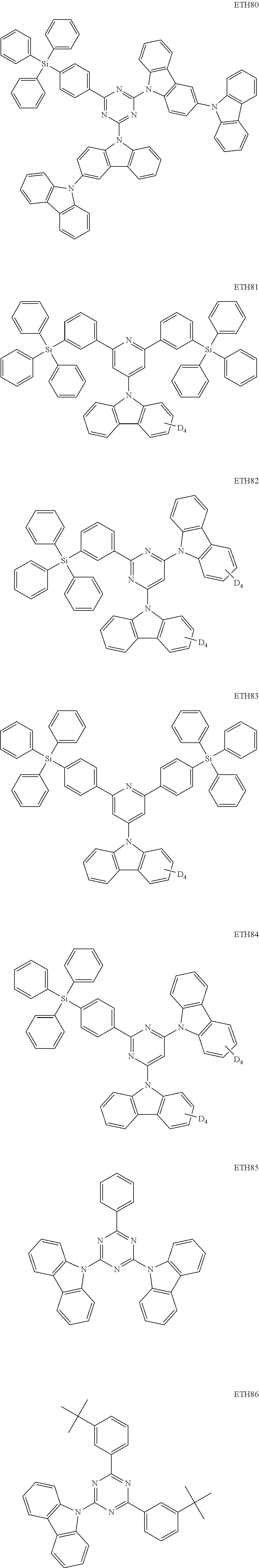

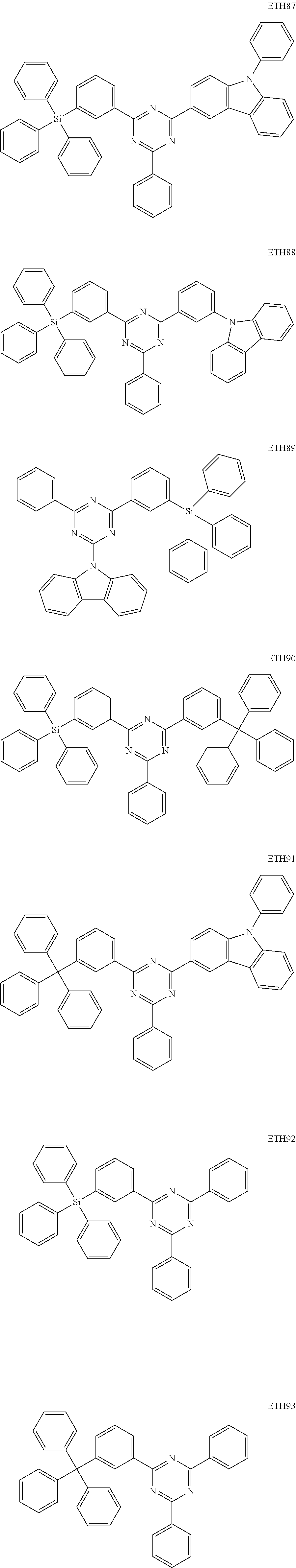

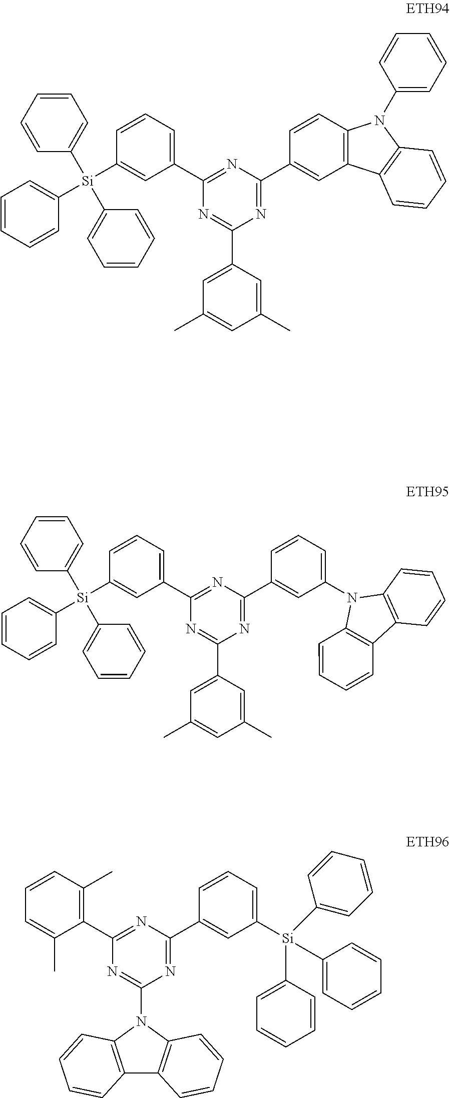 [SMILES: Cc1cc(C)cc(-c2nc(-c3cccc([Si](c4ccccc4)(c4ccccc4)c4ccccc4)c3)nc(-c3ccc4c(c3)c3ccccc3n4-c3ccccc3)n2)c1 ; Cc1cc(C)cc(-c2nc(-c3cccc(-n4c5ccccc5c5ccccc54)c3)nc(-c3cccc([Si](c4ccccc4)(c4ccccc4)c4ccccc4)c3)n2)c1 ; Cc1cccc(C)c1-c1nc(-c2cccc([Si](c3ccccc3)(c3ccccc3)c3ccccc3)c2)nc(-n2c3ccccc3c3ccccc32)n1]

In Compound Group 3, D represents a deuterium atom, and Ph represents an unsubstituted phenyl group.

In an embodiment, the emission layer EML may include the second compound and the third compound, and the second compound and the third compound may form an exciplex. In the emission layer EML, an exciplex may be formed by the hole transport host and the electron transport host. A triplet energy of the exciplex formed by a hole transporting host and an electron transporting host may correspond to a difference between a lowest unoccupied molecular orbital (LUMO) energy level of the electron transporting host and a highest occupied molecular orbital (HOMO) energy level of the hole transporting host.

For example, an absolute value of the triplet energy level (T1) of the exciplex formed by the hole transporting host and the electron transporting host may be in a range of about 2.4 eV to about 3.0 eV. The triplet energy level of the exciplex may be a value that is smaller than an energy gap of each host material. The exciplex may have a triplet energy level equal to or less than about 3.0 eV, which is an energy gap between the hole transporting host and the electron transporting host.

In an embodiment, the emission layer EML may further include a fourth compound in addition to the first compound, the second compound, and the third compound. The fourth compound may be used as a sensitizer in the emission layer EML. Energy may be transferred from the fourth compound to the first compound, thereby emitting light.

The emission layer EML may include, as the fourth compound, an organometallic complex containing platinum (Pt) as a central metal atom and ligands linked to the central metal atom. The emission layer EML in the light emitting element ED according to an embodiment may include, as the fourth compound, a compound represented by Formula D-1:

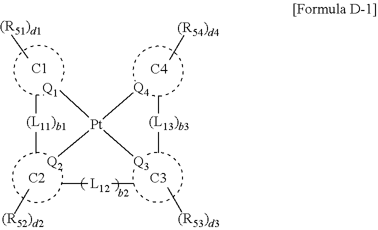

In Formula D-1, Q₁ to Q₄ may each independently be C or N.

In Formula D-1, C1 to C4 may each independently be a substituted or unsubstituted hydrocarbon ring group having 5 to 30 ring-forming carbon atoms or a substituted or unsubstituted heterocyclic group having 2 to 30 ring-forming carbon atoms.

In Formula D-1, L₁₁ to L₁₃ may each independently be a direct linkage,

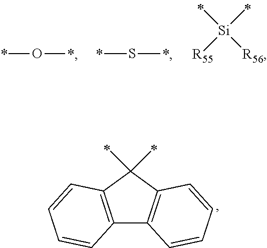

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, wherein in L₁₁ to L₁₃, —* represents a bond linked to one of C1 to C4.

In Formula D-1, b1 to b3 may each independently be 0 or 1. If b1 is 0, C1 and C2 may not be directly linked to each other. If b2 is 0, C2 and C3 may not be directly linked to each other. If b3 is 0, C3 and C4 may not be directly linked to each other.

In Formula D-1, R₅₁ to R₅₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring. For example, R₅₁ to R₅₆ may each independently be a substituted or unsubstituted methyl group, or a substituted or unsubstituted t-butyl group.

In Formula D-1, d1 to d4 may each independently be an integer from 0 to 4. In Formula D-1, if each of d1 to d4 is 0, the fourth compound may not be substituted with each of R₅₁ to R₅₄. The case where each of d1 to d4 is 4 and groups of R₅₁ to R₅₄ are each hydrogen atoms may be the same as the case where each of d1 to d4 is 0. When each of d1 to d4 is 2 or more, multiple groups of each of R₅₁ to R₅₄ may each be the same or at least one group thereof may be different from the remainder.

In an embodiment, in Formula D-1, C1 to C4 may each independently be a substituted or unsubstituted hydrocarbon ring or a substituted or unsubstituted heterocycle represented by any one of Formula C-1 to Formula C-4:

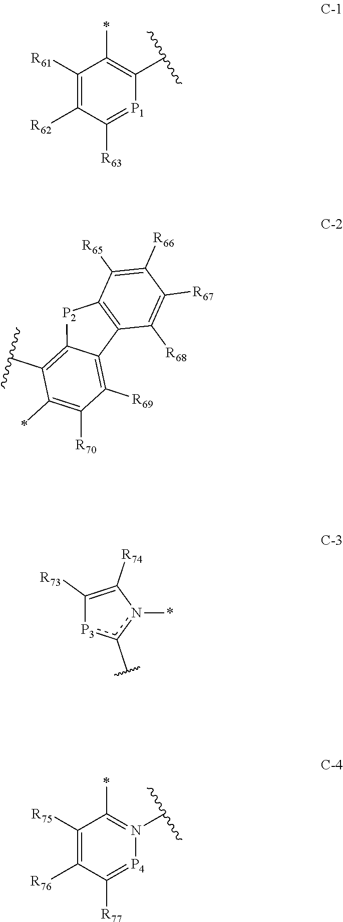

In Formula C-1 to Formula C-4, P₁ may be C—* or C(R₆₄), P₂ may be N—* or N(R₇₁), P₃ may be N—* or N(R₇₂), and P₄ may be C—* or C(R₇₈). In Formula C-1 to Formula C-4, R₆₁ to R₇₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In Formula C-1 to Formula C-4,

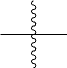

represents a bond linked to Pt that is a central metal atom, and —* represents a bond linked to a neighboring cyclic group (C1 to C4) or to a linker (L₁₁ to L₁₃).

In an embodiment, the fourth compound represented by Formula D-1 may be selected from Compound Group 4. The emission layer EML may include at least one compound selected from Compound Group 4 as a sensitizer material.

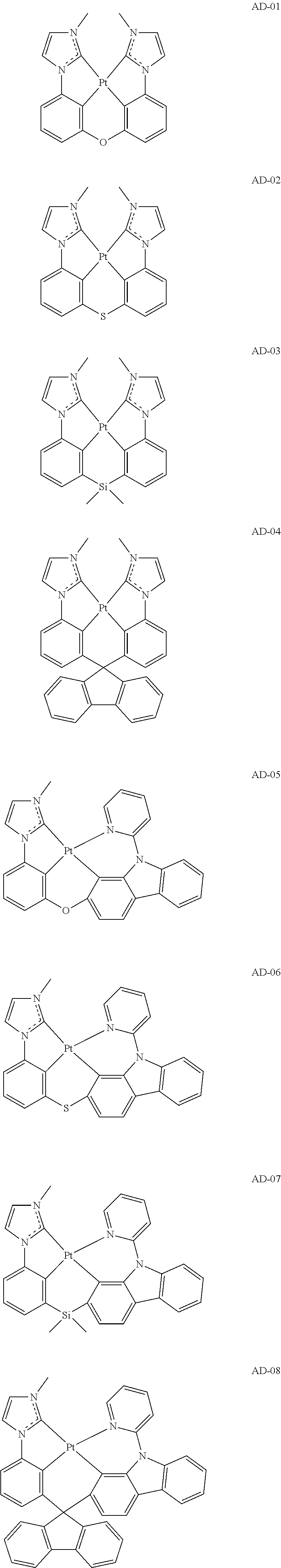

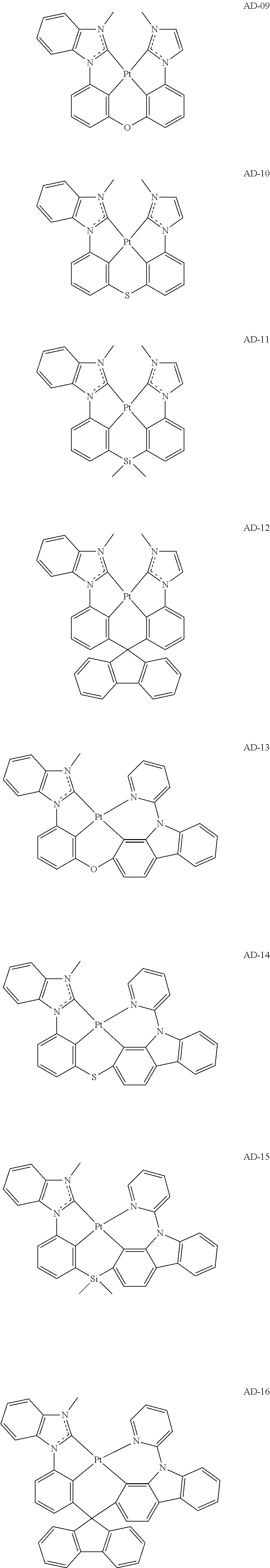

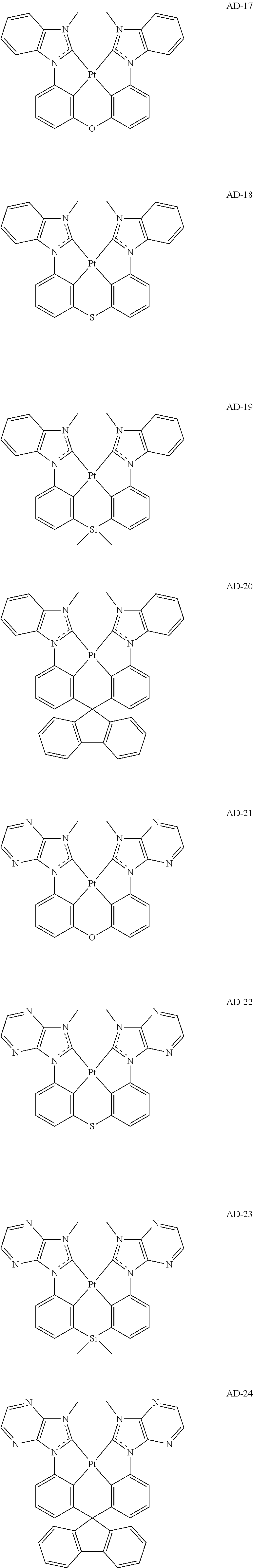

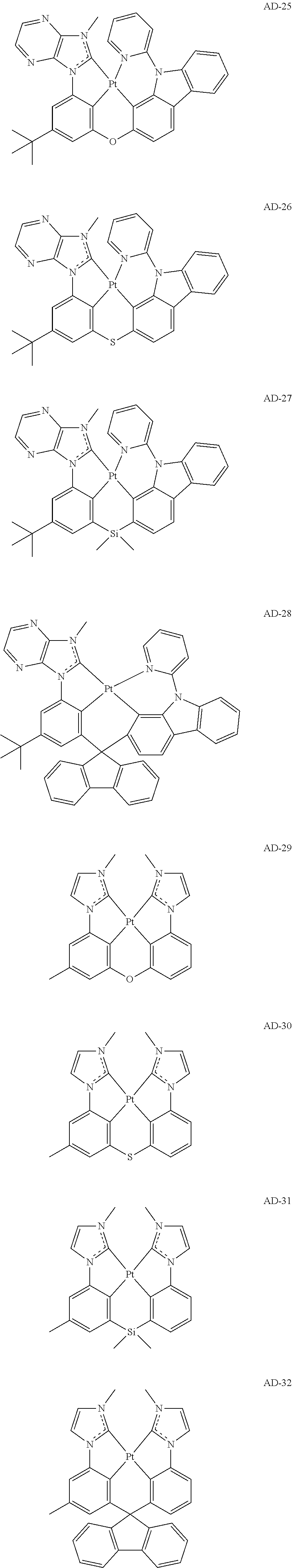

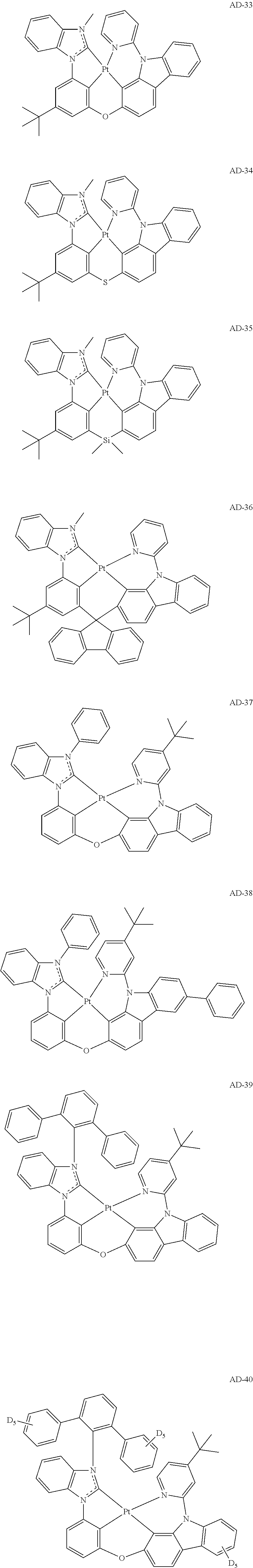

In Compound Group 4. D represents a deuterium atom.

In an embodiment, the emission layer EML may include the first compound, and at least one of the second compound, the third compound, and the fourth compound. For example, the emission layer EML may include the first compound, the second compound, and the third compound. In the emission layer EML, the second compound and the third compound may form an exciplex, and energy may be transferred from the exciplex to the first compound, thereby emitting light.

In another embodiment, the emission layer EML may include the first compound, the second compound, the third compound, and the fourth compound. In the emission layer EML, the second compound and the third compound may form an exciplex, and energy may be transferred from the exciplex to the fourth compound and the first compound, thereby emitting light. In an embodiment, the fourth compound may be a sensitizer. The fourth compound included in the emission layer EML in the light emitting element ED according to an embodiment may serve as a sensitizer to transfer energy from the host to the first compound that is a light emitting dopant. For example, the fourth compound which serves as an auxiliary dopant accelerates energy transfer to the first compound that is a light emitting dopant, thereby increasing an emission ratio of the first compound. Therefore, the emission layer EML according to an embodiment may improve luminous efficiency. When energy transfer to the first compound is increased, an exciton formed in the emission layer EML may not accumulate inside the emission layer EML and may emit light rapidly, so that deterioration of the device may be reduced. Therefore, the service life of the light emitting element ED may increase.

The light emitting element ED according to an embodiment may include all of the first compound, the second compound, the third compound, and the fourth compound, and the emission layer EML may include a combination of two host materials and two dopant materials. In the light emitting element ED according to an embodiment, the emission layer EML may include the second compound and the third compound, which are two different hosts, the first compound that emits delayed fluorescence, and the fourth compound which includes an organometallic complex, thereby exhibiting excellent luminous efficiency characteristics.

The light emitting element ED according to an embodiment may include emission layers. The emission layers may be provided as a stack of emission layers, so that the light emitting element ED including the emission layers may emit white light. The light emitting element including the emission layers may be a light emitting element having a tandem structure. When the light emitting element ED includes the emission layers, at least one emission layer EML may include the first compound represented by Formula 1. In an embodiment, when the light emitting element ED includes multiple emission layers, at least one emission layer EML may include the first compound, the second compound, the third compound, and the fourth compound as described above.

The emission layer EML may have a thickness in a range of about 100 Å to about 1,000 Å. For example, the emission layer EML may have a thickness in a range of about 100 Å to about 300 Å. The emission layer EML may be a layer consisting of a single material, a layer including different materials, or a structure including multiple layers including different materials.

The emission layer EML may further include a host and a dopant of the related art in addition to the polycyclic compound and the second to fourth compounds as described above. In an embodiment, the emission layer EML may include anthracene derivatives, pyrene derivatives, fluoranthene derivatives, chrysene derivatives, dihydrobenzanthracene derivatives, or triphenylene derivatives. For example, the emission layer EML may include the anthracene derivative or the pyrene derivative.

In an embodiment, the emission layer EML may include a compound represented by Formula E-1. The compound represented by Formula E-1 may be used as a fluorescent host material.

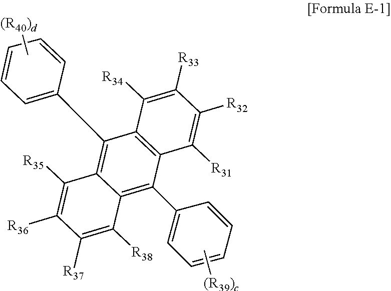

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, in Formula E-1, R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may each independently be an integer from 0 to 5.

The compound represented by Formula E-1 may be any compound selected from Compound E1 to Compound E19:

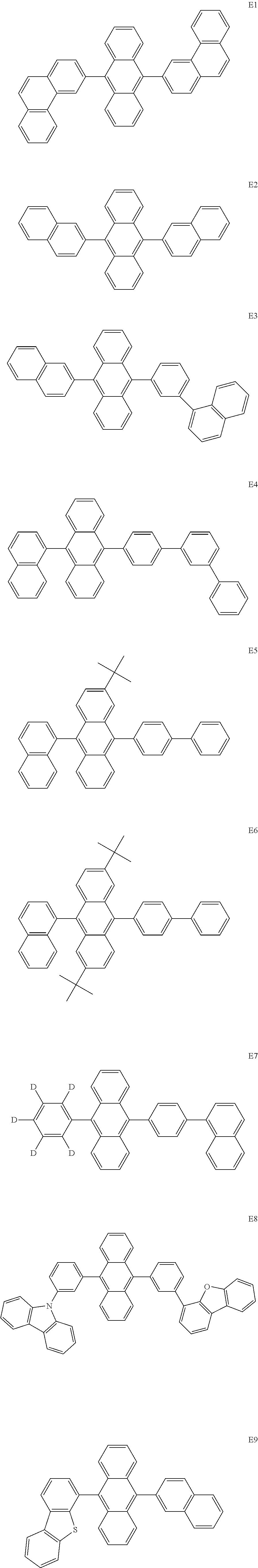

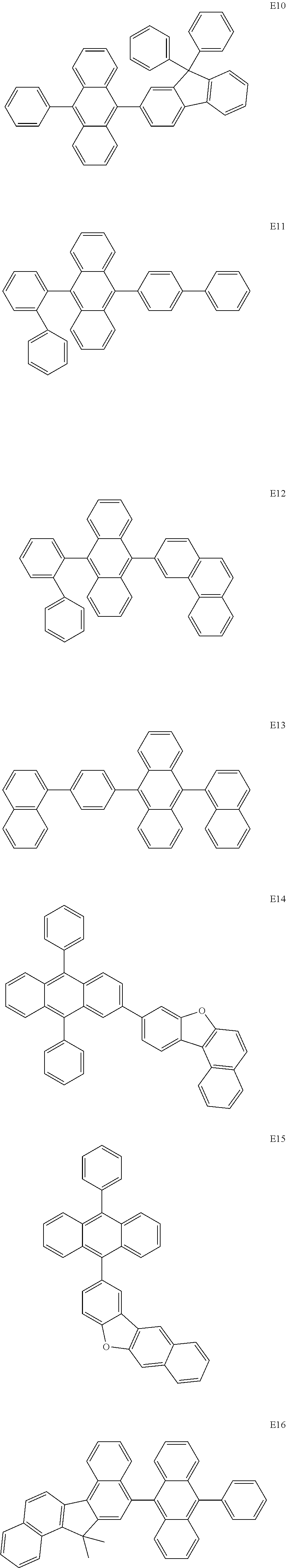

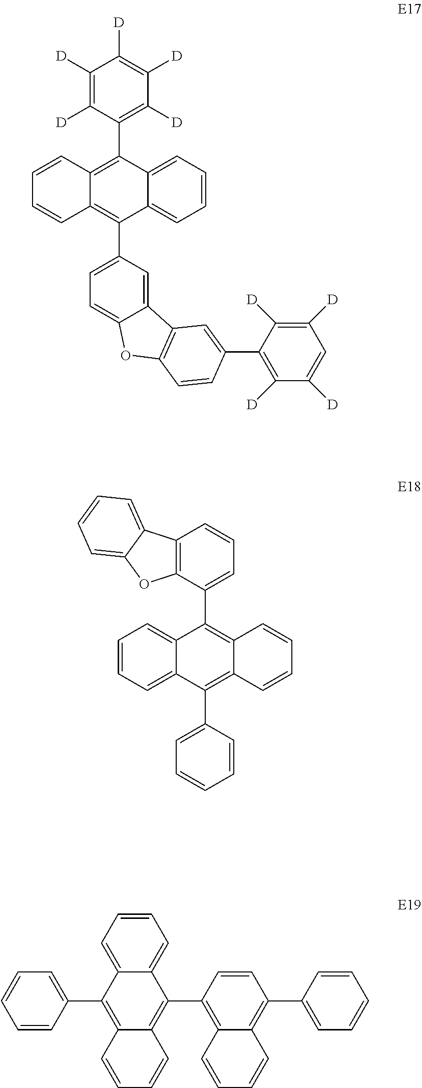

In an embodiment, the emission layer EML may include the first compound represented by Formula 1, and at least one of the second compound represented by Formula HT-1, the third compound represented by Formula ET-1, and the fourth compound represented by Formula M-b, which will be explained below.

In an embodiment, the emission layer EML may include a compound represented by Formula E-2a or Formula E-2b. The compound represented by Formula E-2a or Formula E-2b may be used as a phosphorescent host material.

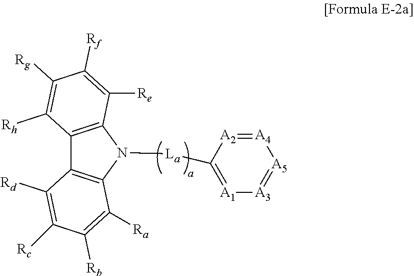

In Formula E-2a, a may be an integer from 0 to 10; and La may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or greater, multiple La groups may each independently be a substituted or unsubstituted arylene group having 6 to 30 ring-forming carbon atoms or a substituted or unsubstituted heteroarylene group having 2 to 30 ring-forming carbon atoms.

In Formula E-2a, A1 to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, Rₐ to Rᵢ may be bonded to an adjacent group to form a hydrocarbon ring or a heterocycle containing N, O, S, etc., as a ring-forming atom.

In Formula E-2a, two or three of A₁ to A₅ may each be N, and the remainder of A₁ to A₅ may each independently be C(Rᵢ).

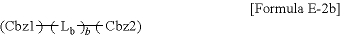

In Formula E-2b, Cbz1 and Cbz2 may each independently be an unsubstituted carbazole group, or a carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10, and when b is 2 or more, multiple L_{b} groups may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2.

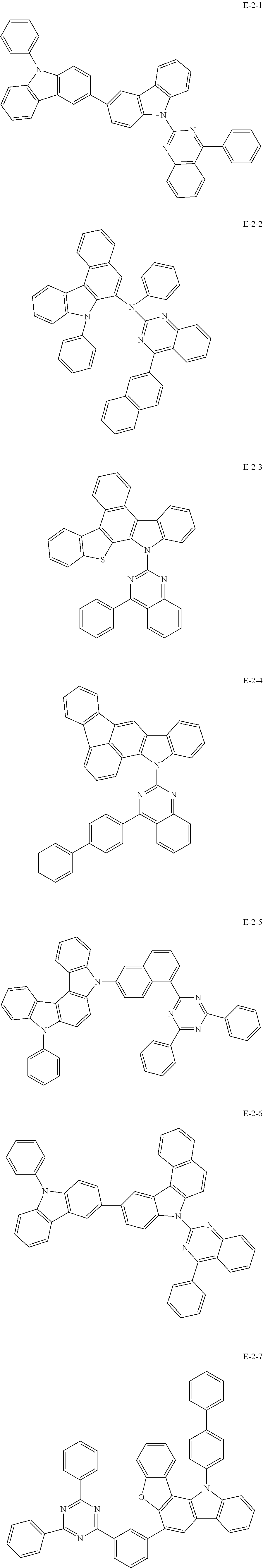

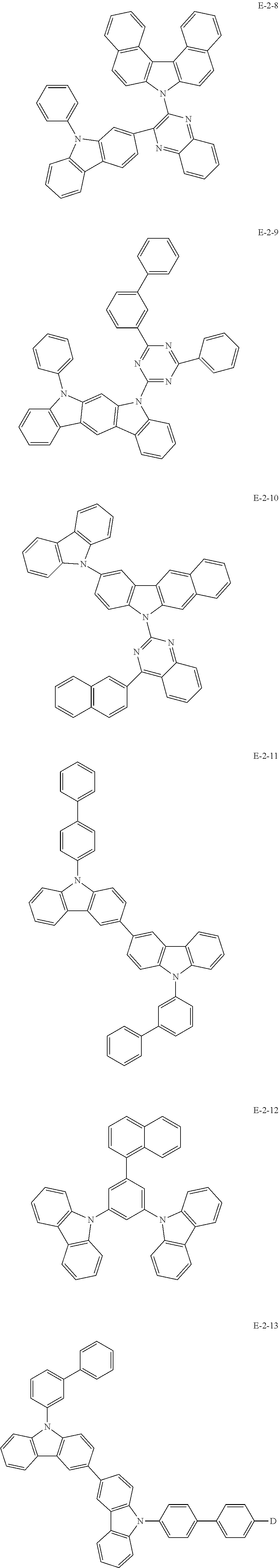

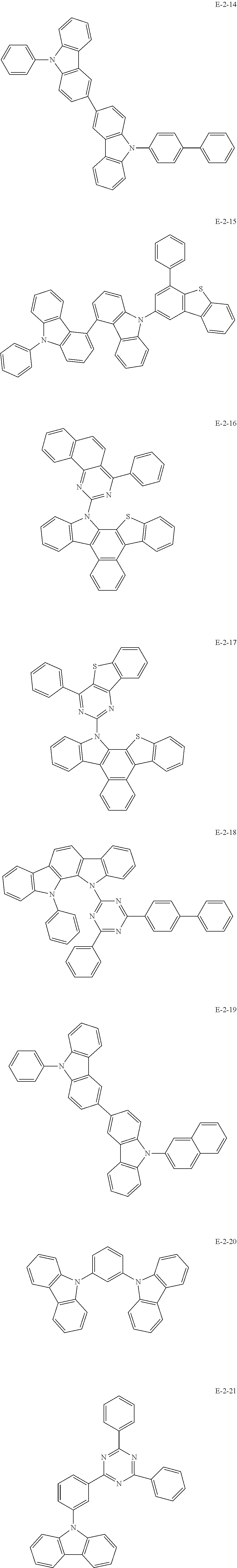

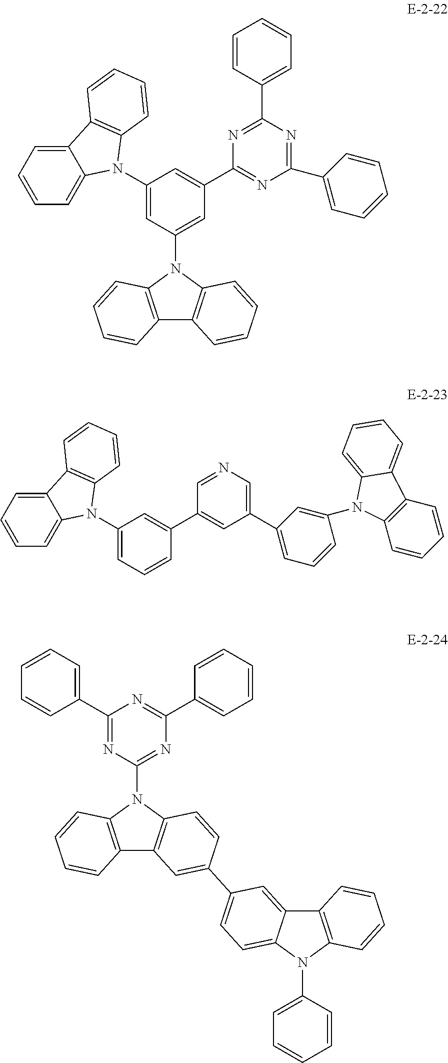 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, the embodiment of the inventive concept is not limited thereto, for example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be used as a host material.

The emission layer EML may include a compound represented by Formula M-a or Formula M-b. The compound represented by Formula M-a or Formula M-b may be used as a phosphorescent dopant material.

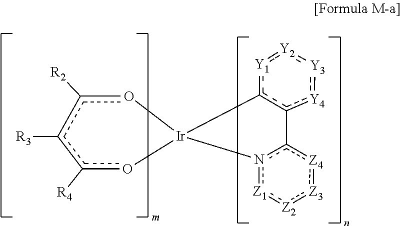

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula M-a, m may be 0 or 1, and n may be 2 or 3. In Formula M-a, when m is 0, n may be 3, and when m is 1, n may be 2.

The compound represented by Formula M-a may be used as a phosphorescent dopant.

The compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25.

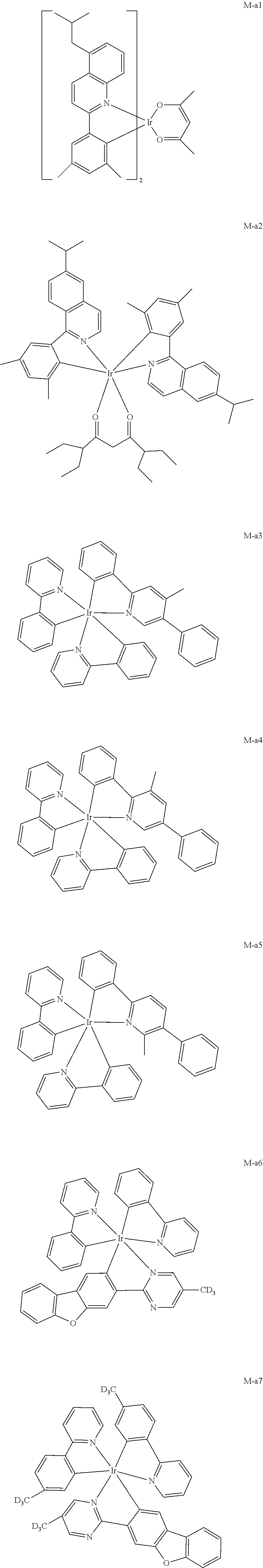

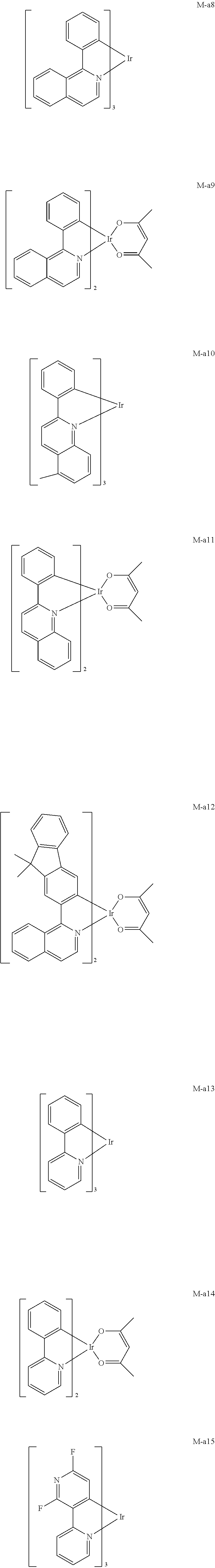

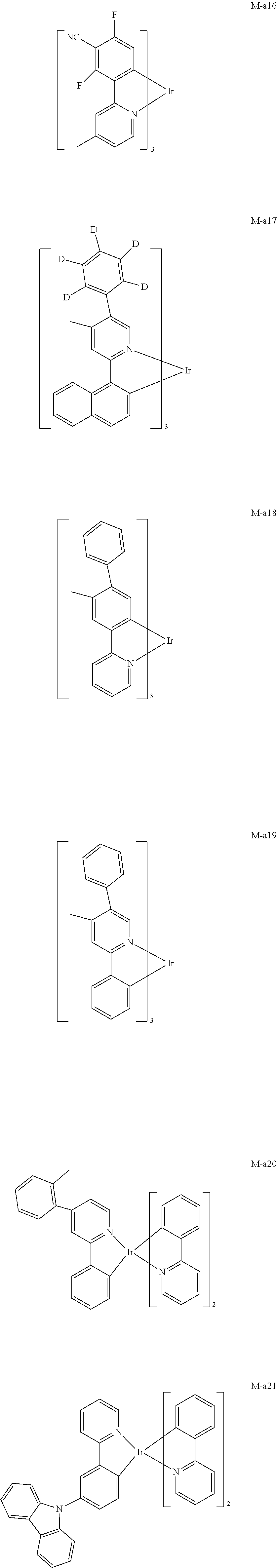

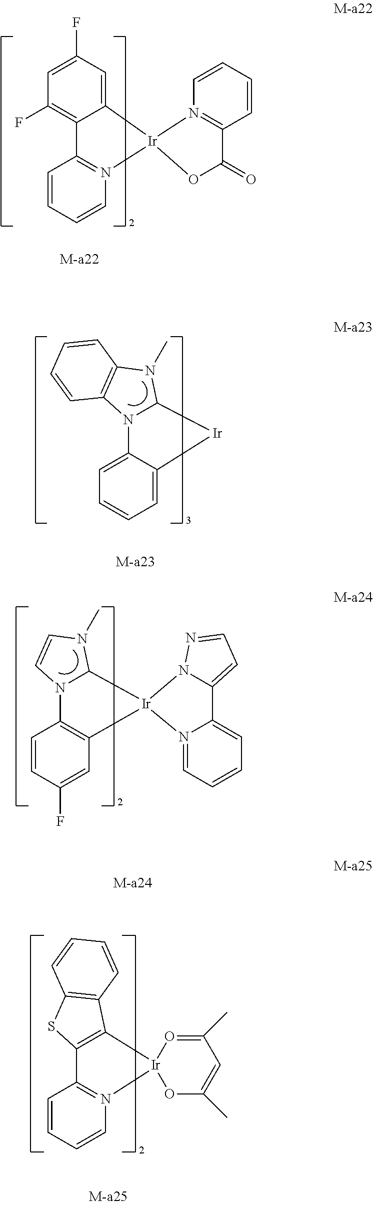

Compound M-a1 and Compound M-a2 may be used as a red dopant material, and Compound M-a3 to Compound M-a7 may be used as a green dopant material.

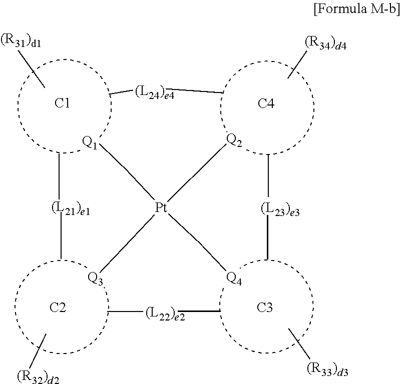

In Formula M-b, Q₁ to Q₄ may each independently be C or N; and C1 to C4 may each independently be a substituted or unsubstituted hydrocarbon ring group having 5 to 30 ring-forming carbon atoms, or a substituted or unsubstituted heterocyclic group having 2 to 30 ring-forming carbon atoms. In Formula M-b, L₂₁ to L₂₄ may each independently be a direct linkage,

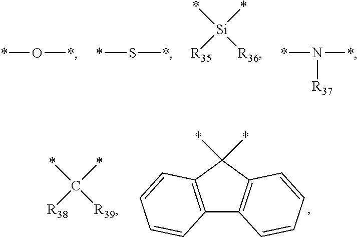

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms; and e1 to e4 may each independently be 0 or 1. In Formula M-b, R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring; and d1 to d4 may each independently be an integer from 0 to 4.

The compound represented by Formula M-b may be used as a blue phosphorescent dopant or as a green phosphorescent dopant.

The compound represented by Formula M-b may be any compound selected from Compound M-b-1 to Compound M-b-11. However, Compound M-b-1 to Compound M-b-11 are only examples, and the compound represented by Formula M-b is not limited to Compound M-b-1 to Compound M-b-11.

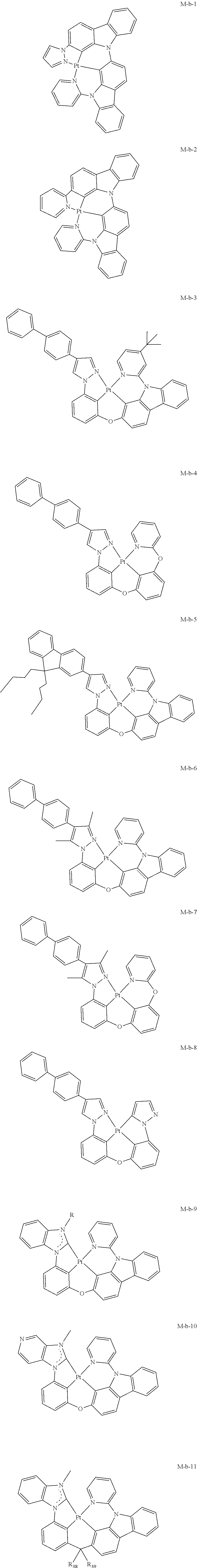

In Compound M-b-1 to Compound M-b-11, R, R₃₈, and R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

The emission layer EML may include a compound represented by any one of Formula F-a to Formula F-c. The compound represented by one of Formula F-a to Formula F-c may be used as a fluorescence dopant material.

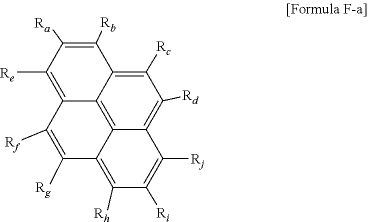

In Formula F-a, two of Rₐ to Rⱼ may each independently be substituted with a group represented by [symbol] NAr₁Ar₂. The remainder of Rₐ to Rⱼ which are not substituted with the group represented by [symbol] NAr₁Ar₂, may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In the group represented by [symbol] NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may each independently be a heteroaryl group containing O or S as a ring-forming atom.

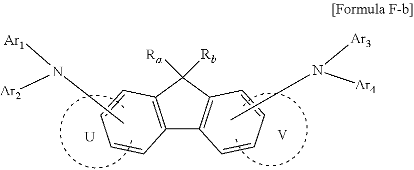

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula F-b, Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms.

In Formula F-b, the number of rings represented by U and V may each independently be 0 or 1. When the number of U or V is 1, a fused ring may be present at a portion indicated by U or V, and when the number of U or V is 0, a fused ring may not be present at the portion indicated by U or V. When the number of U is 0 and the number of V is 1, or when the number of U is 1 and the number of V is 0, a fused ring having a fluorene core of Formula F-b may be a cyclic compound having four rings. When U and V are each 0, a fused ring having a fluorene core of Formula F-b may be a cyclic compound having three rings. When U and V are each 1, a fused ring having a fluorene core of Formula F-b may be a cyclic compound having five rings.

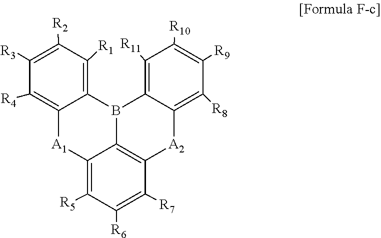

In Formula F-c, A₁ and A₂ may be each independently O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In Formula F-c, A₁ and A₂ may each independently be bonded to substituents of an adjacent ring to form a fused ring. For example, when A₁ and A₂ are each independently N(Rₘ), A₁ may be bonded to R₄ or R₅ to form a ring. For example, A₂ may be bonded to R₇ or R₈ to form a ring.

In an embodiment, the emission layer EML may include, as a dopant material of the related art, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and a derivative thereof (e.g., 2,5,8,11-tetra-t-butylperylene (TBP)), pyrene and a derivative thereof (e.g., 1,1′-dipyrene, 1,4-dipyrenylbenzene, 1,4-bis(N,N-diphenylamino)pyrene), etc.

The emission layer EML may include a phosphorescent dopant material of the related art. For example, a metal complex containing iridium (Ir), platinum (Pt), osmium (Os), gold (Au), titanium (Ti), zirconium (Zr), hafnium (Hf), curopium (Eu), terbium (Tb), or thulium (Tm) may be used as a phosphorescent dopant. For example, iridium(III) bis(4,6-difluorophenylpyridinato-N,C2′)picolinate (FIrpic), bis(2,4-difluorophenylpyridinato)-tetrakis(1-pyrazolyl)borate iridium(III) (FIr6), or platinum octaethyl porphyrin (PtOEP) may be used as a phosphorescent dopant. However, embodiments are not limited thereto.

The emission layer EML may include a quantum dot. In the specification, the quantum dot may be a crystal of a semiconductor compound. The quantum dot may emit light having various emission wavelengths depending on a size of crystal. The quantum dot may emit light having various emission wavelengths as an elemental ratio in the quantum dot compound is adjusted.

The quantum dot may have a diameter in a range of, for example, about 1 nm to about 10 nm.

The quantum dot may be synthesized by a wet chemical process, a metal organic chemical vapor deposition process, a molecular beam epitaxy process, a similar process thereto, or the like.

The wet chemical process is a method in which a precursor material may be mixed with an organic solvent to grow quantum dot particle crystals. When the crystals grow, the organic solvent naturally may serve as a dispersant coordinated on the surface of the quantum dot crystals and control the growth of the crystals. Thus, the wet chemical process may control the growth of quantum dot particles through a process which may be more readily performed than vapor deposition methods, such as metal organic chemical vapor deposition (MOCVD) or molecular beam epitaxy (MBE), and which is performed at low costs.

The quantum dot may be a Group II-VI compound, a Group III-VI compound, a Group I-III-VI compound, a Group III-V compound, a Group III-II-V compound, a Group I-IV-VI compound, a Group IV element, a Group IV compound, or any combination thereof.

Examples of a Group II-VI compound may include: a binary compound selected from the group consisting of CdSe, CdTe, CdS, ZnS, ZnSe, ZnTe, ZnO, HgS, HgSe, HgTe, MgSc, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof; or any combination thereof.

Examples of a Group III-VI compound may include: a binary compound such as In₂S₃ or In₂Se₃; a ternary compound such as InGaS₃ or InGaSe₃; or any combination thereof.

Examples of a Group I-III-VI compound may include: a ternary compound selected from the group consisting of AgInS, AgInS₂, CuInS, CuInS₂, AgGaS₂, CuGaS₂ CuGaO₂, AgGaO₂, AgAlO₂, and a mixture thereof; a quaternary compound such as AgInGaS₂ or CuInGaS₂; or any combination thereof.

Examples of a Group III-V compound may include: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; or any combination thereof. In an embodiment, a Group III-V compound may further include a Group II metal. For example, InZnP, etc., may be selected as a Group III-II-V compound.

Examples of a Group IV-VI compound may include: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; a quaternary compound selected from the group consisting of SnPbSSe, SnPbSeTe, SnPbSTe, and a mixture thereof; or any combination thereof. Examples of a Group IV element may include Si, Ge, or any mixture thereof. Examples of a Group IV compound may include a binary compound selected from the group consisting of SiC, SiGe, and any mixture thereof.

A binary compound, a ternary compound, or a quaternary compound may be present in a particle at a uniform concentration distribution, or may be present in a particle at a partially different concentration distribution. In an embodiment, a quantum dot may have a core/shell structure in which a quantum dot surrounds another quantum dot. A quantum dot having a core/shell structure may have a concentration gradient in which the concentration of a material that is present in the shell decreases toward the core.

In embodiments, the quantum dot may have the above-described core/shell structure including a core containing nanocrystals and a shell surrounding the core. The shell of the quantum dot may serve as a protection layer to prevent the chemical deformation of the core to maintain semiconductor properties, and/or may serve as a charging layer to impart electrophoresis properties to the quantum dot. The shell may be a single layer or multiple layers. Examples of a shell of a quantum dot may include a metal oxide, a non-metal oxide, a semiconductor compound, or any combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; a ternary compound such as MgAl₂O₄, CoFc₂O₄, NiFc₂O₄, or CoMn₂O₄; or any combination thereof, but embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of a light emitting wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. Color purity or color reproducibility may be improved in any of the above ranges. Light emitted through a quantum dot may be emitted in all directions so that a wide viewing angle may be improved.

The form of the quantum dot is not particularly limited as long as it is a form that is used in the related art. For example, a quantum dot may have a spherical shape, a pyramidal shape, a multi-arm shape, or a cubic shape, or a quantum dot may be in the form of nanoparticles, nanotubes, nanowires, nanofibers, nanoplate particles, etc.

As the size of the quantum dot is adjusted or the elemental ratio in the quantum dot compound is adjusted, it may be possible to control the energy band gap, and thus light in various wavelength ranges may be obtained from a quantum dot emission layer. Therefore, as the quantum dot described herein (using different sizes of quantum dots or different elemental ratios in the quantum dot compound) is used, a light emitting element which emits light in various wavelengths may be implemented. For example, the adjustment of the size of the quantum dot or the elemental ratio in the quantum dot compound may be selected to emit red light, green light, and/or blue light. The quantum dots may be configured to emit white light by combining various colors of light.

In the light emitting element ED according to an embodiment as illustrated in each of FIGS. 3 to 6, the electron transport region ETR is provided on the emission layer EML. The electron transport region ETR may include at least one of a hole blocking layer HBL, an electron transport layer ETL, or an electron injection layer EIL, but embodiments are not limited thereto.

The electron transport region ETR may be a layer consisting of a single material, a layer including different materials, or a structure including multiple layers including different materials.

For example, the electron transport region ETR may have a single layer structure of an electron injection layer EIL or an electron transport layer ETL, or may have a single layer structure formed of an electron injection material and an electron transport material. The electron transport region ETR may have a single layer structure formed of different materials, or may have a structure in which an electron transport layer ETL/electron injection layer EIL, or a hole blocking layer HBL/electron transport layer ETL/electron injection layer EIL are stacked in its respective stated order from the emission layer EML, but embodiments are not limited thereto. The electron transport region ETR may have a thickness, for example, in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the electron transport region ETR may include a compound represented by Formula ET-1:

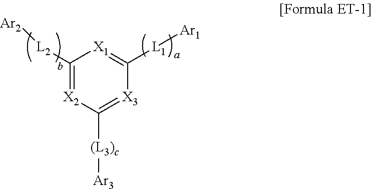

In Formula ET-1, at least one of X₁ to X₃ may each be N; and the remainder of X₁ to X₃ may each independently be C(Rₐ). In Formula ET-1, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-1, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer from 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each 2 or more, multiple groups of each of L₁ to L₃ may each independently be a substituted or unsubstituted arylene group having 6 to 30 ring-forming carbon atoms or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), or a mixture thereof.

In an embodiment, the electron transport region ETR may include at least one compound selected from Compound ET1 to Compound ET36:

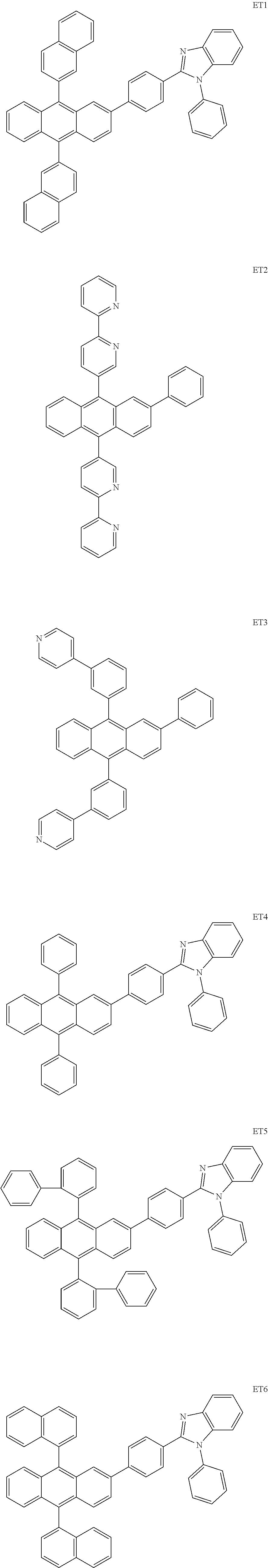

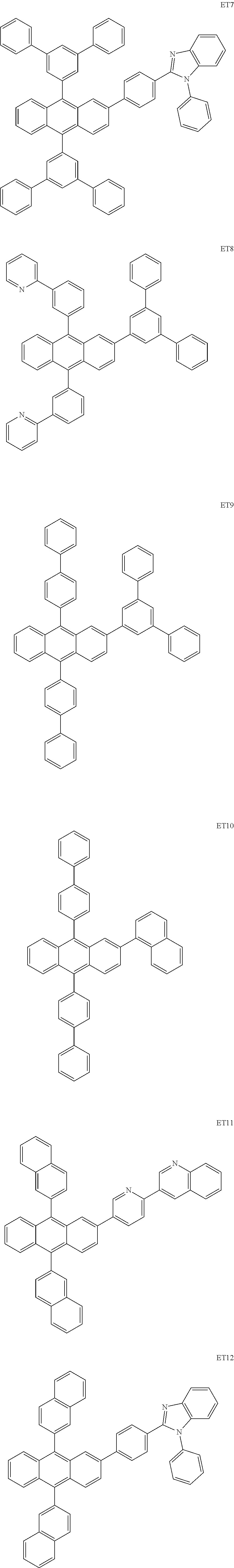

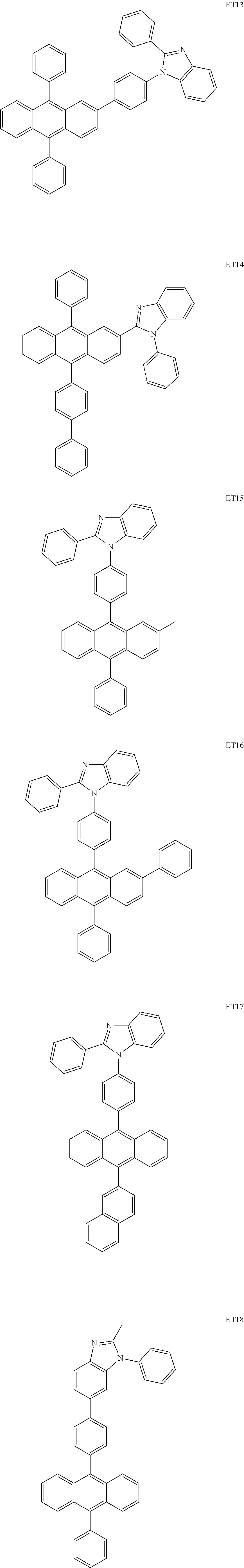 [SMILES: c1ccc(-c2c3ccccc3c(-c3ccccc3)c3cc(-c4ccc(-n5c(-c6ccccc6)nc6ccccc65)cc4)ccc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

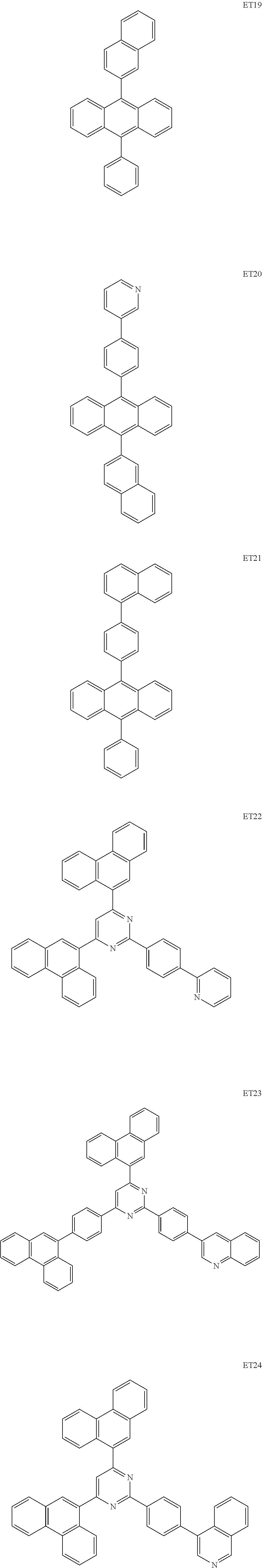

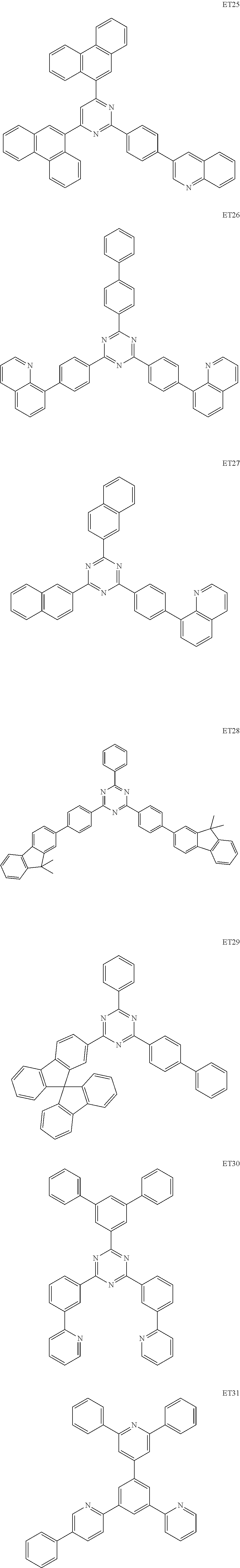

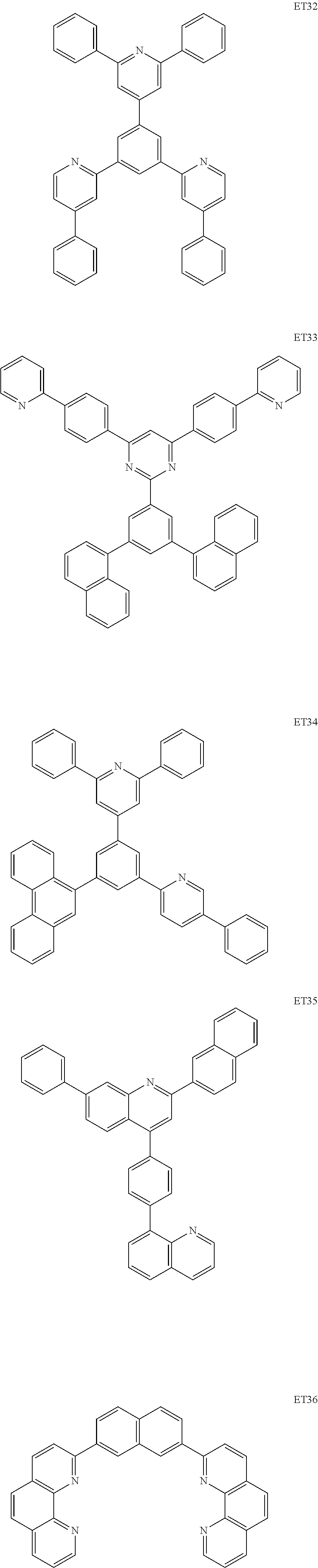 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In an embodiment, the electron transport region ETR may include a metal halide such as LiF, NaCl, CsF, RbCl, RbI, CuI, and KI; a lanthanide metal such as Yb; or a co-deposited material of a metal halide and a lanthanide metal. For example, the electron transport region ETR may include KI:Yb, RbI:Yb, LiF:Yb, etc., as a co-deposited material. The electron transport region ETR may include a metal oxide such as Li₂O or BaO, or 8-hydroxyl-lithium quinolate (Liq), etc., but embodiments are not limited thereto. The electron transport region ETR may also be formed of a mixture material of an electron transport material and an insulating organometallic salt. The organometallic salt may be a material having an energy band gap equal to or greater than about 4 eV. For example, the organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but embodiments are not limited thereto.

The electron transport region ETR may include the above-described compounds of the electron transport region ETR in at least one of an electron injection layer EIL, an electron transport layer ETL, or a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. If the thickness of the electron transport layer ETL satisfies any of the aforementioned ranges, satisfactory electron transport characteristics may be obtained without a substantial increase in a driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. If the thickness of the electron injection layer EIL satisfies any of the above-described ranges, satisfactory electron injection characteristics may be obtained without a substantial increase in driving voltage.

The second electrode EL2 may be provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode. The second electrode may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

The second electrode EL2 may be a transmissive electrode, a transflective electrode, or a reflective electrode. When the second electrode EL2 is a transmissive electrode, the second electrode EL2 may include a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgAg). In an embodiment, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown in the drawings, the second electrode EL2 may be electrically connected to an auxiliary electrode. If the second electrode EL2 is electrically connected to an auxiliary electrode, the resistance of the second electrode EL2 may decrease.

In an embodiment, the light emitting element ED may include a capping layer CPL disposed on the second electrode EL2. The capping layer CPL may be a multilayer or a single layer.

In an embodiment, the capping layer CPL may include an organic layer or an inorganic layer. For example, when the capping layer CPL contains an inorganic material, the inorganic material may include an alkaline metal compound (e.g., LiF), an alkaline earth metal compound (e.g., MgF₂), SiON, SiNₓ, SiOy, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., or an epoxy resin, or acrylate such as methacrylate. However, embodiments are not limited thereto, and the capping layer CPL may include at least one of Compounds P1 to P5:

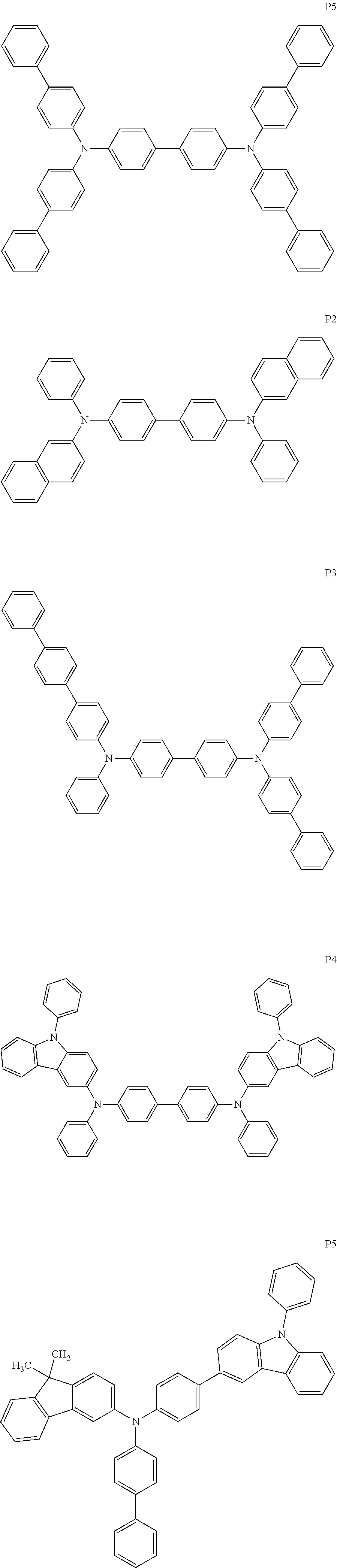 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, a refractive index of the capping layer CPL may be equal to or greater than about 1.6, with respect to light in a wavelength range of about 550 nm to about 660 nm.

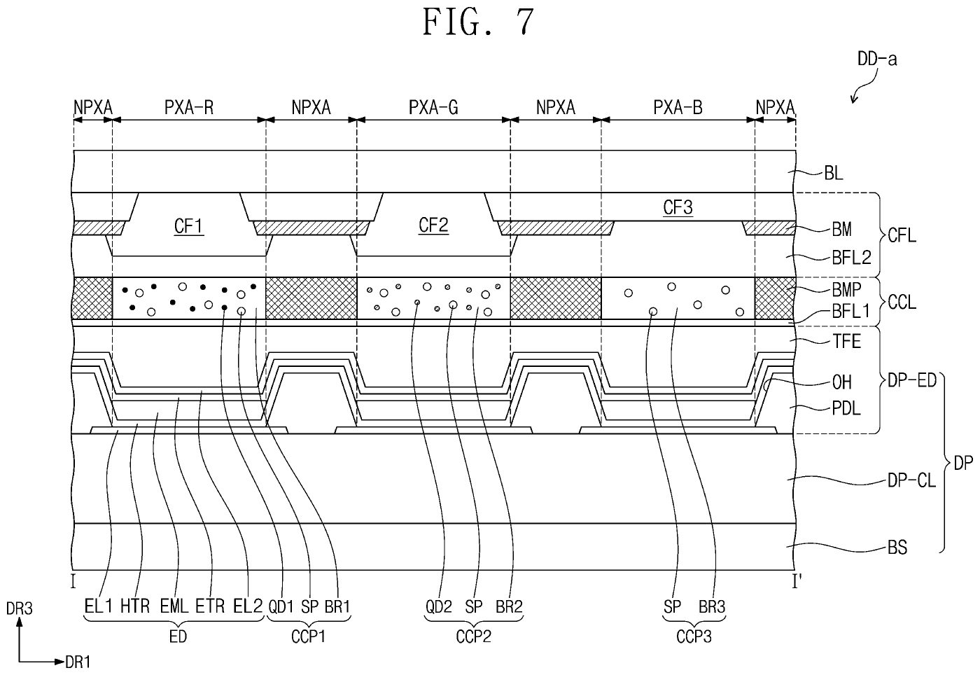

FIGS. 7 to 10 are each a schematic cross-sectional view of a display device according to an embodiment. Hereinafter, in describing the display devices according to embodiments with reference to FIGS. 7 to 10, the features which have been described above with respect to FIGS. 1 to 6 will not be described again, and the different features will be described.

Referring to FIG. 7, the display device DD-a according to an embodiment may include a display panel DP including a display element layer DP-ED, a light control layer CCL disposed on the display panel DP, and a color filter layer CFL.

In an embodiment illustrated in FIG. 7, the display panel DP may include a base layer BS, a circuit layer DP-CL provided on the base layer BS, and a display element layer DP-ED, and the display element layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In an embodiment, a structure of the light emitting element ED illustrated in FIG. 7 may be the same as a structure of a light emitting element ED according to one of FIGS. 3 to 6 as described herein.

Referring to FIG. 7, the emission layer EML may be disposed in an opening OH defined in a pixel defining film PDL. For example, the emission layer EML which is divided by the pixel defining film PDL and correspondingly provided to each of the light emitting regions PXA-R, PXA-G, and PXA-B may each emit light in a same wavelength range. In the display device DD-a, the emission layer EML may emit blue light. Although not shown in the drawings, in an embodiment, the emission layer EML may be provided as a common layer for each of the light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may convert the wavelength of a provided light and may emit the resulting light. For example, the light control layer CCL may be a layer including a quantum dot or a layer including a phosphor.

The light control layer CCL may include light control parts CCP1, CCP2 and CCP3. The light control parts CCP1, CCP2, and CCP3 may be spaced apart from each other.

Referring to FIG. 7, divided patterns BMP may be disposed between the light control parts CCP1, CCP2, and CCP3 which are spaced apart from each other, but embodiments are not limited thereto. In FIG. 7 it is illustrated that the divided patterns BMP do not overlap the light control parts CCP1, CCP2 and CCP3, but at least a portion of the edges of the light control parts CCP1, CCP2 and CCP3 may overlap the divided patterns BMP.

The light control layer CCL may include a first light control part CCP1 including a first quantum dot QD1 that converts first color light provided from the light emitting element ED into second color light, a second light control part CCP2 including a second quantum dot QD2 that converts the first color light into third color light, and a third light control part CCP3 that transmits the first color light.

In an embodiment, the first light control part CCP1 may provide red light, which may be the second color light, and the second light control part CCP2 may provide green light, which may be the third color light. The third light control part CCP3 may provide blue light by transmitting the blue light that is the first color light provided from the light emitting element ED. For example, the first quantum dot QD1 may be a red quantum dot, and the second quantum dot QD2 may be a green quantum dot. The quantum dots QD1 and QD2 may each be a quantum dot as described herein.

The light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include a quantum dot but include the scatterer SP.

The scatterer SP may be inorganic particles. For example, the scatterer SP may include at least one of TiO₂, ZnO, Al₂O₃, SiO₂, or hollow silica. The scatterer SP may include any one of TiO₂, ZnO, Al₂O₃, SiO₂, or hollow silica, or the scatterer SP may be a mixture of at least two materials selected from TiO₂, ZnO, Al₂O₃, SiO₂, and hollow silica.

The first light control part CCP1, the second light control part CCP2, and the third light control part CCP3 may each include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3. The base resins BR1, BR2, and BR3 are media in which the quantum dots QD1 and QD2 and the scatterer SP are dispersed, and may be formed of various resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may be disposed on the light control parts CCP1, CCP2, and CCP3 to block the light control parts CCP1, CCP2 and CCP3 from exposure to moisture/oxygen. The barrier layer BFL1 may cover the light control parts CCP1, CCP2, and CCP3. A barrier layer BFL2 may be provided between the light control parts CCP1, CCP2, and CCP3 and the filters CF1, CF2, and CF3.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. The barrier layers BFL1 and BFL2 may each independently further include an organic layer. The barrier layers BFL1 and BFL2 may be formed of a single layer or formed of multiple layers.

In the display device DD-a, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include a light shielding part BM and filters CF1, CF2, and CF3. The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye. However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be separated but may be provided as one filter.

The light shielding part BM may be a black matrix. The light shielding part BM may include an organic light shielding material or an inorganic light shielding material containing a black pigment or dye. The light shielding part BM may prevent light leakage, and may separate boundaries between the adjacent filters CF1, CF2, and CF3. In an embodiment, the light shielding part BM may be formed of a blue filter.

The first to third filters CF1, CF2, and CF3 may be disposed corresponding to the red light emitting region PXA-R, the green light emitting region PXA-G, and the blue light emitting region PXA-B, respectively.

A base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

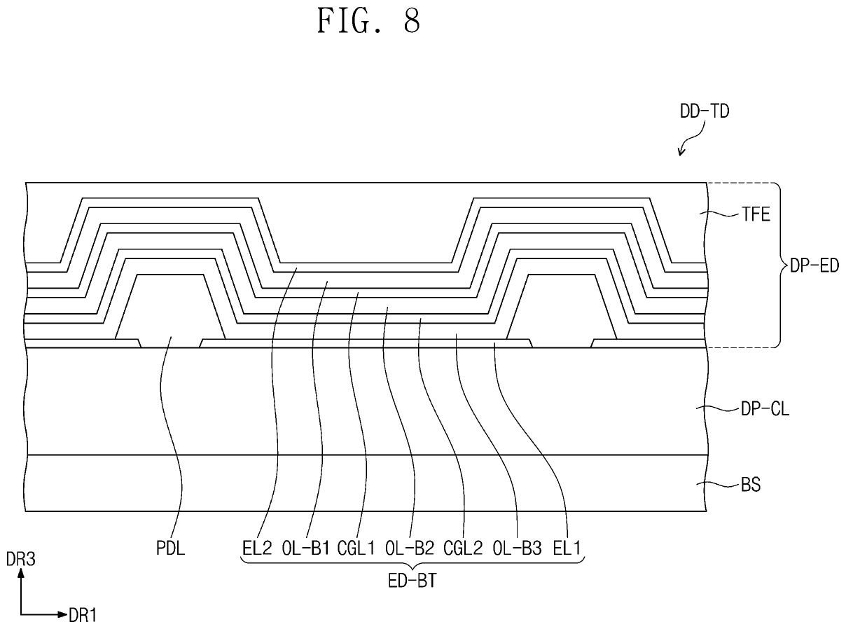

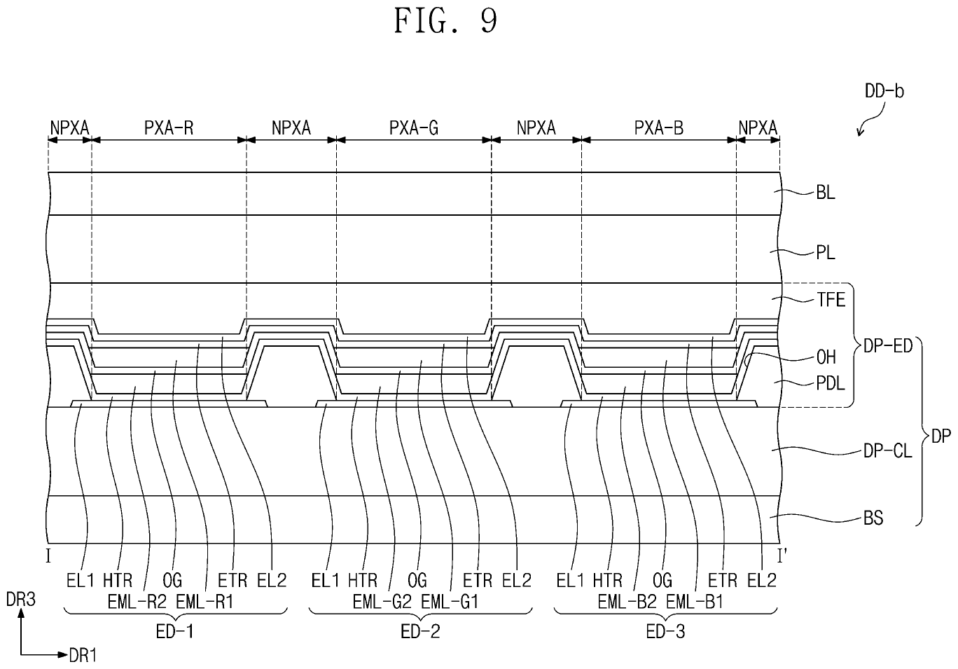

FIG. 8 is a schematic cross-sectional view of a portion of a display device according to an embodiment. In the display device DD-TD according to an embodiment, the light emitting element ED-BT may include light emitting structures OL-B1, OL-B2, and OL-B3. The light emitting element ED-BT may include a first electrode EL1 and a second electrode EL2 which face each other, and light emitting structures OL-B1, OL-B2, and OL-B3 may be stacked in a thickness direction between the first electrode EL1 and the second electrode EL2. The light emitting structures OL-B1, OL-B2, and OL-B3 may each include an emission layer EML (FIG. 7) and a hole transport region HTR and an electron transport region ETR disposed with the emission layer EML (FIG. 7) therebetween.

For example, the light emitting element ED-BT included in the display device DD-TD may be a light emitting element having a tandem structure and including multiple emission layers EML.

In an embodiment illustrated in FIG. 8, light emitted from the light emitting structures OL-B1, OL-B2, and OL-B3 may each be blue light. However, embodiments are not limited thereto, and the light respectively emitted from the light emitting structures OL-B1, OL-B2, and OL-B3 may have wavelength ranges that are different from each other. For example, the light emitting element ED-BT that includes the light emitting structures OL-B1, OL-B2, and OL-B3 which emit light having wavelength ranges that are different from each other may emit white light.

Charge generation layers CGL1 and CGL2 may each be disposed between the neighboring light emitting structures OL-B1, OL-B2, and OL-B3. Charge generation layers CGL1 and CGL2 may each independently include a p-type charge generation layer and/or an n-type charge generation layer.

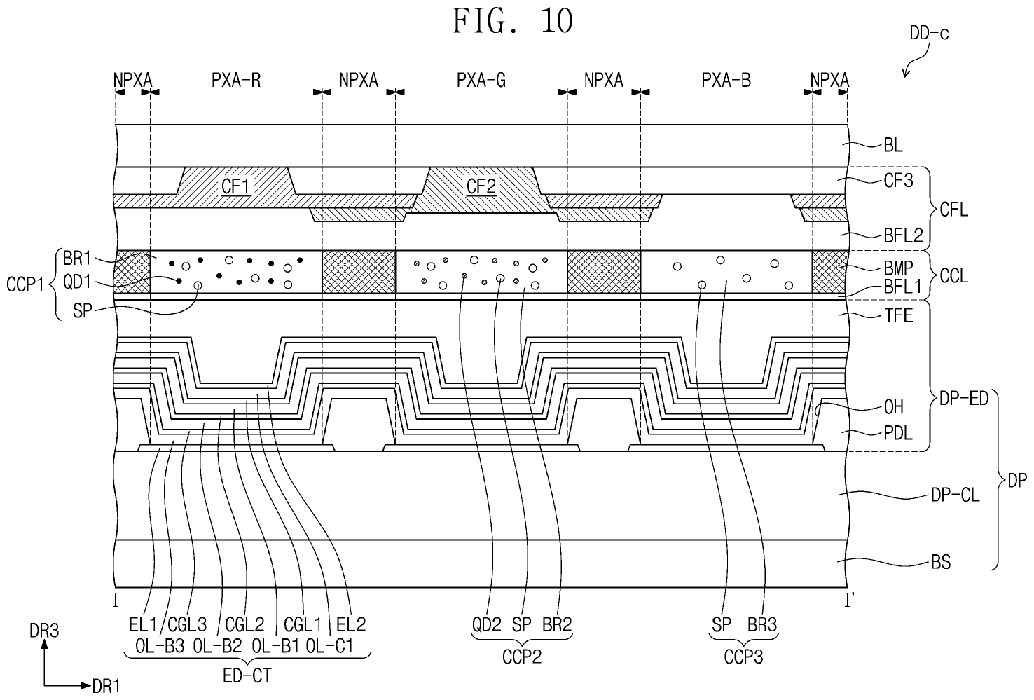

FIG. 9 is a schematic cross-sectional view of a display device DD-b according to an embodiment. The display apparatus DD-b may include light emitting elements ED-1, ED-2, and ED-3 in which two emission layers are stacked. In comparison to the display device DD illustrated in FIG. 2, the embodiment illustrated in FIG. 9 is different at least in that the first to third light emitting elements ED-1, ED-2, and ED-3 each include two emission layers that are stacked in a thickness direction. In each of the first to third light emitting elements ED-1, ED-2, and ED-3, the two emission layers may emit light in a same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. The third light emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may be a single layer or a multilayer. The emission auxiliary part OG may include a charge generation layer. For example, the emission auxiliary part OG may include an electron transport region, a charge generation layer, and a hole transport region which may be stacked in that stated order. The emission auxiliary part OG may be provided as a common layer for all of the first to third light emitting elements ED-1, ED-2, and ED-3. However, embodiments are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may each be disposed between the electron transport region ETR and the emission auxiliary part OG. The second red emission layer EML-R2, the second green emission layer EML-G2, and the second blue emission layer EML-B2 may each be disposed between the emission auxiliary part OG and the hole transport region HTR.

For example, the first light emitting element ED-1 may include the first electrode EL1, the hole transport region HTR, the second red emission layer EML-R2, the emission auxiliary part OG, the first red emission layer EML-R1, the electron transport region ETR, and the second electrode EL2 which are stacked in that order. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2 which are stacked in that order. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2 which are stacked in that order.

An optical auxiliary layer PL may be disposed on the display element layer DP-ED. The optical auxiliary layer PL may include a polarizing layer. The optical auxiliary layer PL may be disposed on the display panel DP and may control light reflected at the display panel DP from an external light. Although not shown in the drawings, in an embodiment, the optical auxiliary layer PL may be omitted from the display device DD-b.

In contrast to FIGS. 8 and 9, FIG. 10 illustrates a display device DD-c that is different at least in that it includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2.

Light emitting structures OL-C1, OL-B1, OL-B2, and OL-B3 may be stacked in this stated order, charge generation layer CGL1 may be disposed between light emitting structures OL-B1 and OL-C1, charge generation layer CGL2 may be disposed between light emitting structures OL-B1 and OL-B2, and charge generation layer CGL3 may be disposed between light emitting structures OL-B2 and OL-B3. Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having different wavelength regions from each other.

Charge generation layers CGL1, CGL2, and CGL3 that are disposed between adjacent light emitting structures OL-C1, OL-B1, OL-B2, and OL-B3 may each independently include a p-type charge generation layer and/or an n-type charge generation layer.

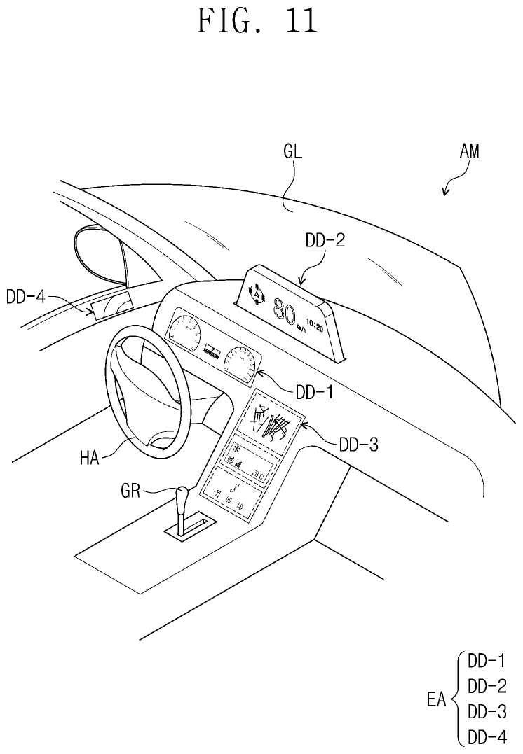

FIG. 11 is a schematic perspective view of an electronic device including display devices according to embodiments. FIG. 11 illustrates a vehicle as an example of an electronic device including display devices.

Referring to FIG. 11, the electronic device EA according to an embodiment may include display devices DD-1, DD-2, DD-3, and DD-4 for a vehicle AM. FIG. 11 illustrates the first to fourth display devices DD-1, DD-2, DD-3, and DD-4 as display devices for a vehicle AM disposed inside the vehicle AM. FIG. 11 illustrates a vehicle, but this is only an example, and the first to fourth display devices DD-1, DD-2, DD-3, and DD-4 may be disposed in various transportation means such as bicycles, motorcycles, trains, ships, and airplanes. At least one of the first to fourth display devices DD-1, DD-2, DD-3, and DD-4 may have a structure according to one of the display devices DD, DD-a, DD-TD, DD-b, and DD-c as described in reference to FIG. 1, FIG. 2, and FIGS. 7 to 10.

In an embodiment, at least one of the first to fourth display devices DD-1, DD-2, DD-3, and DD-4 may include a light emitting element ED according to an embodiment as described with reference to FIGS. 3 to 6. The first to fourth display devices DD-1, DD-2, DD-3, and DD-4 may each independently include multiple light emitting elements ED, and each of the light emitting elements ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. The emission layer EML may include a polycyclic compound represented by Formula 1 according to an embodiment. Accordingly, the electronic device EA according to an embodiment may exhibit improved image quality.

Referring to FIG. 11, the vehicle AM may include a steering wheel HA and a gearshift GR for operating the vehicle AM, and a front window GL may be disposed so as to face the driver.

The first display device DD-1 may be disposed in a first region overlapping the steering wheel HA. For example, the first display device DD-1 may be a digital cluster which displays first information of the vehicle AM. The first information may include a first scale for indicating a driving speed of the vehicle AM, a second scale for indicating an engine speed (that is, revolutions per minute (RPM)), an image for indicating a fuel state, etc. A first scale and a second scale may each be represented as a digital image.

The second display device DD-2 may be disposed in a second region facing the driver's seat and overlapping the front window GL. The driver's seat may be a seat where the steering wheel HA is disposed. For example, the second display device DD-2 may be a head up display (HUD) which displays second information of the vehicle AM. The second display device DD-2 may be optically transparent. The second information may include digital numbers DN for indicating a driving speed, and may further include information such as the current time.

The third display device DD-3 may be disposed in a third region adjacent to the gearshift GR. For example, the third display device DD-3 may be disposed between the driver's seat and the passenger seat and may be a center information display (CID) for displaying third information. The passenger seat may be a seat spaced apart from the driver's seat with the gearshift GR disposed therebetween. The third information may include information about traffic (e.g., navigation information), playing music or radio, playing video, temperatures inside the vehicle AM, etc.

The fourth display device DD-4 may be spaced apart from the steering wheel HA and the gearshift GR, and may be disposed in a fourth region adjacent to the side of the vehicle AM. For example, the fourth display device DD-4 may be a digital side-view mirror which displays fourth information. The fourth display device DD-4 may display an image outside the vehicle AM taken by a camera module CM disposed outside the vehicle AM. The fourth information may include an image outside the vehicle AM.

The first to fourth information as described herein are only examples, and the first to fourth display devices DD-1, DD-2, DD-3, and DD-4 may further display information about the interior and exterior of the vehicle AM. The first to fourth information may include information which is different from each other. However, the embodiments are not limited thereto, and a part of the first to fourth information may include the same information as one another.

Hereinafter, a polycyclic compound according to an embodiment and a light emitting element according to an embodiment will be described in detail with reference to the Examples and Comparative Examples. The Examples described below are only provided as illustrations to assist in understanding of the embodiments, and the scope thereof is not limited thereto.

### Examples and Comparative Examples

### 1. Synthesis of Polycyclic Compound of Example

A synthesis method of a polycyclic compound will be explained in detail by illustrating synthesis methods for Compounds 8, 61, 94, 116, 121, 193, and 202. In the following descriptions, a synthesis method of the polycyclic compound is only provided as an example, but the synthesis method of the polycyclic compound is not limited to the Examples below.

### (1) Synthesis of Compound 8

Compound 8 according to an example may be synthesized by, for example, the steps shown in Reaction Scheme 1:

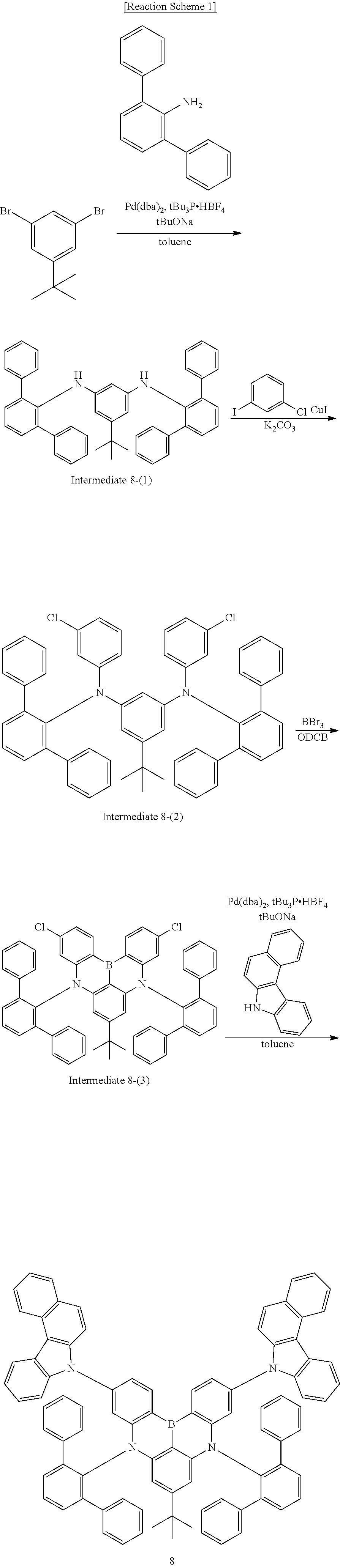

### 1) Synthesis of Intermediate 8-(1)

In an Ar atmosphere, 1,3-dibromo-5-(tert-butyl)benzene (15.0 g, 51.4 mmol), [1,1′:3′,1″-terphenyl]-2′-amine (25.2 g, 102.7 mmol), Pd(dba)₂ (2.95 g, 5.14 mmol), P(t-Bu)₃HBF₄ (2.98 g, 10.3 mmol), and tBuONa (11.4 g, 118 mmol) were added to 250 mL of toluene, and the resultant mixture was heated and stirred at about 100° C. for about 8 hours. Water was added thereto, and the resultant mixture was subjected to Celite filtering and liquid separation to concentrate an organic layer. The organic layer was purified by silica gel column chromatography to obtain Intermediate 8-(1) (28.1 g, yield: 88%). The molecular weight of Intermediate 8-(1) was about 620 as measured by FAB MS.

### 2) Synthesis of Intermediate 8-(2)

A small amount of toluene (about 10 mL) was added to Intermediate 8-(1) (28.0 g, 45.1 mmol), 3-chloro-1-iodobenzene (161 g, 0.677 mol), CuI (18.0 g, 94.7 mmol), and K₂CO₃ (49.9 g, 0.360 mol), and the resultant mixture was heated for about 24 hours while maintaining the outside temperature at about 215° C. The resultant mixture was diluted with CH₂Cl₂, water was added thereto, and the mixture was subjected to Celite filtering and liquid separation to concentrate an organic layer. The organic layer was purified by silica gel column chromatography to obtain Intermediate 8-(2) (26.6 g, yield: 70%). The molecular weight of Intermediate 8-(2) was about 842 as measured by FAB MS.

### 3) Synthesis of Intermediate 8-(3)

In an Ar atmosphere, Intermediate 8-(2) (26.0 g, 30.9 mmol) was dissolved in 1,2-dichlorobenzene (ODCB, 300 mL), BBr₃ (19.3 g, 77.2 mmol) was added thereto, and the resultant mixture was heated and stirred at about 170° C. for about 10 hours. The resultant mixture was cooled to room temperature, N,N-diisopropylethylamine (47.8 g, 371 mmol) was added thereto, water was added thereto, and the resultant mixture was subjected to Celite filtering and liquid separation to concentrate an organic layer. The organic layer was purified by silica gel column chromatography to obtain Intermediate 8-(3) (9.18 g, yield: 35%). The molecular weight of Intermediate 8-(3) was about 849 as measured by FAB MS.

### 4) Synthesis of Compound 8

In an Ar atmosphere, Intermediate 8-(3) (3.00 g, 3.53 mmol), 7H-benzo[c]carbazole (1.53 g, 7.06 mmol), Pd(dba)₂ (203 mg, 0.35 mmol), P(t-Bu)₃HBF₄ (205 mg, 0.71 mmol), and tBuONa (780 mg, 8.12 mmol) were added to 25 mL of toluene, and the resultant mixture was heated and stirred at about 100° C. for about 10 hours. Water was added thereto, and the resultant mixture was subjected to Celite filtering and liquid separation to concentrate an organic layer. The organic layer was purified by silica gel column chromatography to obtain Compound 8 (3.21 g, yield: 75%). The molecular weight of Compound 8 was about 1211 as measured by FAB MS. The purification by sublimation was performed (350° C., 2.1×10−3 Pa) to perform device evaluation.

### (2) Synthesis of Compound 61

Compound 61 according to an example may be synthesized by, for example, the steps shown in Reaction Scheme 2 below:

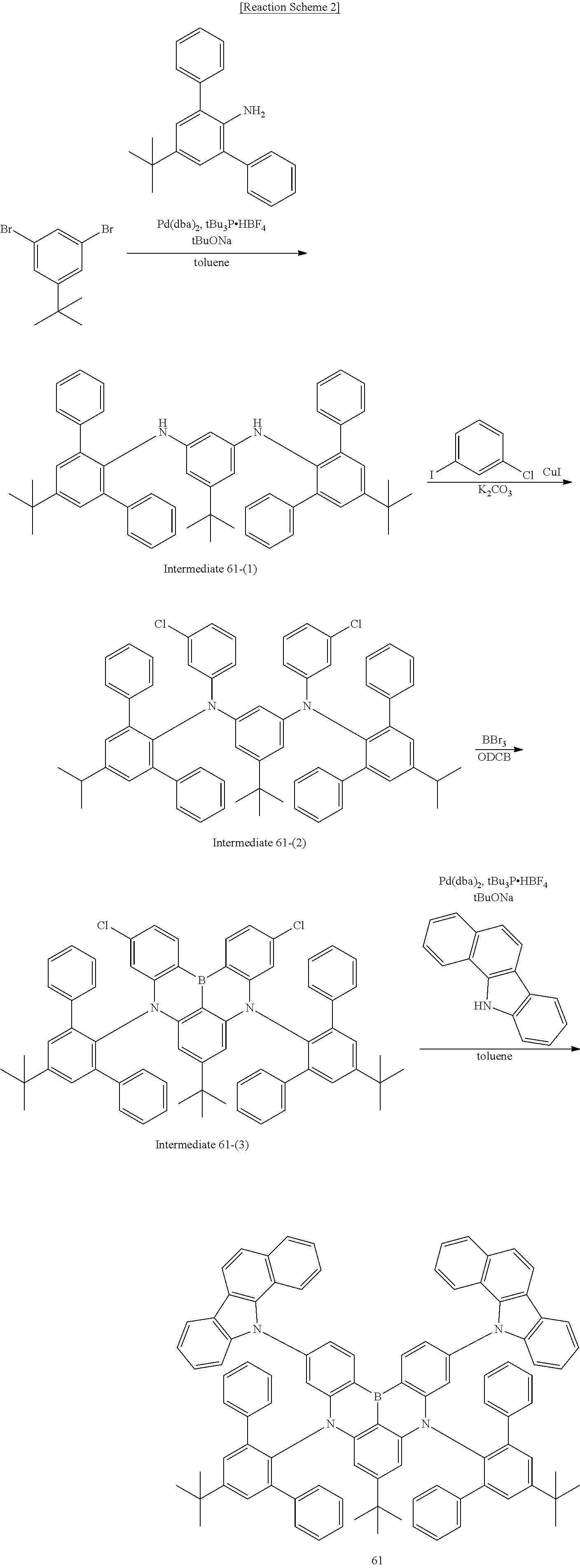

### 1) Synthesis of Intermediate 61-(1)

In an Ar atmosphere, 1,3-dibromo-5-(tert-butyl)benzene (10.03 g, 34.25 mmol), 5′-(tert-butyl)-[1,1′:3′,1″-terphenyl]-2′-amine (20.65 g, 68.49 mmol), Pd(dba)₂ (1.97 g, 3.42 mmol), (tBu)₃PHBF₄ (1.99 g, 6.85 mmol), and tBuONa (7.57 g, 78.76 mmol) were added to 171 mL of toluene, and the resultant mixture was heated and stirred at about 100° C. for about 8 hours. Water was added thereto, and the resultant mixture was subjected to Celite filtering and liquid separation to concentrate an organic layer. The organic layer was purified by silica gel column chromatography to obtain Intermediate 61-(1) (17.82 g, yield: 71%). The molecular weight of Intermediate 61-(1) was about 733 as measured by FAB MS.

### 2) Synthesis of Intermediate 61-(2)

A small amount of toluene (about 10 mL) was added to Intermediate 61-(1) (28.02 g, 38.2 mmol), 3-chloro-1-iodobenzene (136.62 g, 572.94 mmol), CuI (15.28 g, 80.21 mmol), and K₂CO₃ (42.23 g, 305.57 mmol), and the resultant mixture was heated for about 24 hours while maintaining the outside temperature at about 215° C. The resultant mixture was diluted with CH₂Cl₂, water was added thereto, and the mixture was subjected to Celite filtering and liquid separation to concentrate an organic layer. The organic layer was purified by silica gel column chromatography to obtain Intermediate 61-(2) (24.78 g, yield: 68%). The molecular weight of Intermediate 61-(2) was about 954 as measured by FAB MS.

### 3) Synthesis of Intermediate 61-(3)

In an Ar atmosphere, Intermediate 61-(2) (12.00 g, 14.25 mmol) was dissolved in ODCB (143 mL), BBr₃ (8.93 g, 35.63 mmol) was added thereto, and the resultant mixture was heated and stirred at about 170° C. for about 10 hours. The resultant mixture was cooled to room temperature, DIPEA (22.06 g, 171.04 mmol) was added thereto, water was added thereto, and the resultant mixture was subjected to Celite filtering and liquid separation to concentrate an organic layer. The organic layer was purified by silica gel column chromatography to obtain Intermediate 61-(3) (4.24 g, yield: 35%). The molecular weight of Intermediate 61-(3) was about 962 as measured by FAB MS.

### 4) Synthesis of Compound 61

In an Ar atmosphere, Intermediate 61-(3) (4.01 g, 4.16 mmol), 7H-benzo[c]carbazole (1.81 g, 8.32 mmol), Pd(dba)₂ (0.24 g, 0.42 mmol), (tBu)₃PHBF₄ (0.24 g, 0.83 mmol), and tBuONa (0.92 g, 9.56 mmol) were added to 20 mL of toluene, and the resultant mixture was heated and stirred at about 100° ° C. for about 8 hours. Water was added thereto, and the resultant mixture was subjected to Celite filtering and liquid separation to concentrate an organic layer. The organic layer was purified by silica gel column chromatography to obtain Compound 61 (4.68 g, yield: 85%). The molecular weight of Compound 61 was about 1324 as measured by FAB MS. The purification by sublimation was performed (350° C., 2.1×10⁻³ Pa) to perform device evaluation.

### (3) Synthesis of Compound 94

Compound 94 according to an example may be synthesized by, for example, the steps shown in Reaction Scheme 3 below:

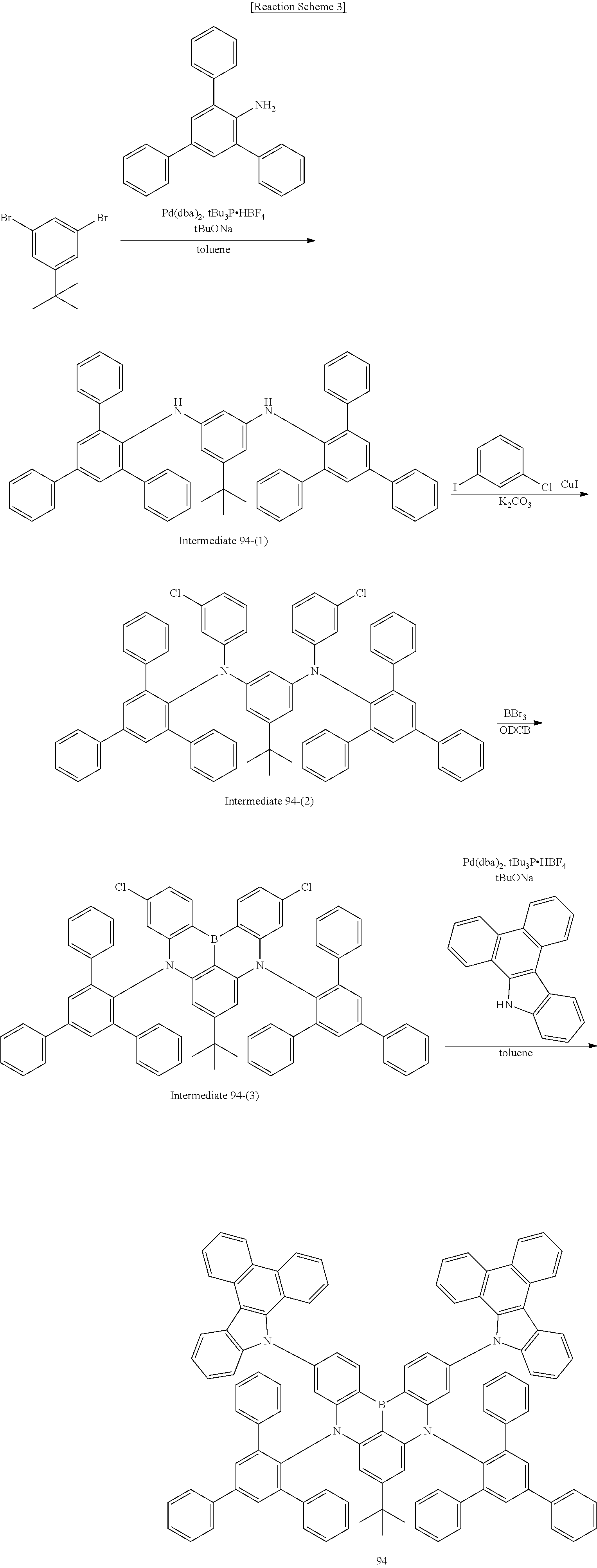

### 1) Synthesis of Intermediate 94-(1)

In an Ar atmosphere, 1,3-dibromo-5-(tert-butyl)benzene (12.02 g, 41.09 mmol), 5′-phenyl-[1,1′:3′,1″-terphenyl]-2′-amine (26.42 g, 82.19 mmol), Pd(dba)₂ (2.36 g, 4.11 mmol), (tBu)₃PHBF₄ (2.38 g, 8.22 mmol), and tBuONa (9.08 g, 94.52 mmol) were added to 205 mL of toluene, and the resultant mixture was heated and stirred at about 100° C. for about 8 hours. Water was added thereto, and the resultant mixture was subjected to Celite filtering and liquid separation to concentrate an organic layer. The organic layer was purified by silica gel column chromatography to obtain Intermediate 94-(1) (23.51 g, yield: 74%). The molecular weight of Intermediate 94-(1) was about 773 as measured by FAB MS.

### 2) Synthesis of Intermediate 94-(2)

A small amount of toluene (about 10 mL) was added to Intermediate 94-(1) (12.01 g, 16.37 mmol), 3-chloro-1-iodobenzene (58.55 g, 245.55 mmol), CuI (6.55 g, 34.38 mmol), and K₂CO₃ (18.1 g, 130.96 mmol), and the resultant mixture was heated for about 24 hours while maintaining the outside temperature at about 215° C. The resultant mixture was diluted with CH₂Cl₂, water was added thereto, and the mixture was subjected to Celite filtering and liquid separation to concentrate an organic layer. The organic layer was purified by silica gel column chromatography to obtain Intermediate 94-(2) (10.62 g, yield: 68%). The molecular weight of Intermediate 94-(2) was about 994 as measured by FAB MS.

### 3) Synthesis of Intermediate 94-(3)

In an Ar atmosphere, Intermediate 94-(2) (10.00 g, 10.06 mmol) was dissolved in ODCB (101 mL), BBr₃ (6.3 g, 25.15 mmol) was added thereto, and the resultant mixture was heated and stirred at about 170° C. for about 10 hours. The resultant mixture was cooled to room temperature, DIPEA (15.57 g, 120.71 mmol) was added thereto, water was added thereto, and the resultant mixture was subjected to Celite filtering and liquid separation to concentrate an organic layer. The organic layer was purified by silica gel column chromatography to obtain Intermediate 94-(3) (3.53 g, yield: 35%). The molecular weight of Intermediate 94-(3) was about 1002 as measured by FAB MS.

### 3) Synthesis of Compound 94

In an Ar atmosphere, Intermediate 94-(3) (3.02 g, 3.01 mmol), 9H-dibenzo[a,c]carbazole (1.61 g, 6.03 mmol), Pd(dba)₂ (0.17 g, 0.3 mmol), (tBu)₃PHBF₄ (0.17 g, 0.6 mmol), and tBuONa (0.67 g, 6.93 mmol) were added to 15 mL of toluene, and the resultant mixture was heated and stirred at about 100° C. for about 8 hours. Water was added thereto, and the resultant mixture was subjected to Celite filtering and liquid separation to concentrate an organic layer. The organic layer was purified by silica gel column chromatography to obtain Compound 94 (3.88 g, yield: 88%). The molecular weight of Compound 94 was about 1464 as measured by FAB MS. The purification by sublimation was performed (390° C., 3.1×10⁻³ Pa) to perform device evaluation.

### (4) Synthesis of Compound 116

Compound 116 according to an example may be synthesized by, for example, the steps shown in Reaction Scheme 4 below:

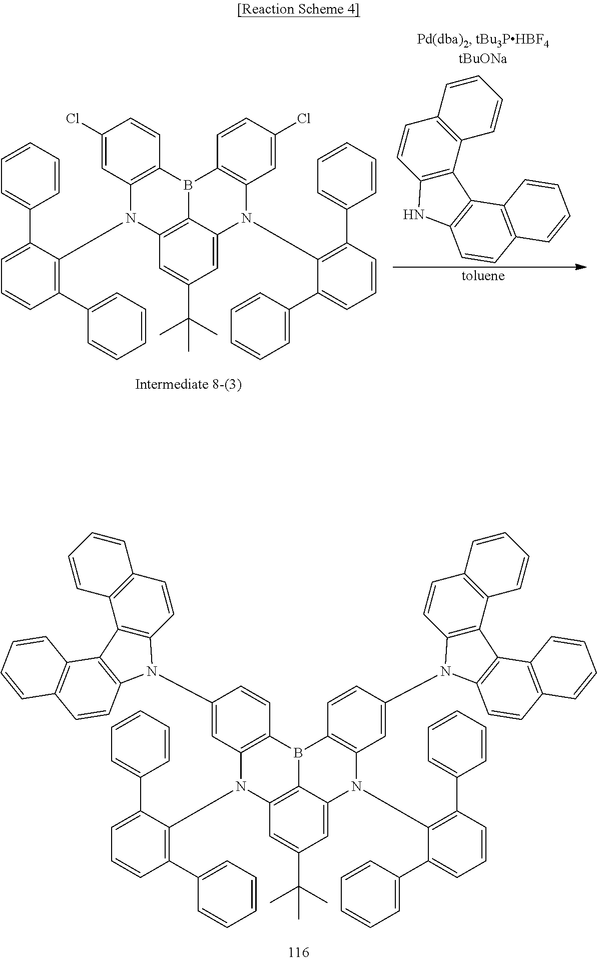

### 1) Synthesis of Compound 116

In an Ar atmosphere, Intermediate 8-(3) (3.02 g, 3.55 mmol), 7H-dibenzo[c]carbazole (1.9 g, 7.11 mmol), Pd(dba)₂ (0.24 g, 0.36 mmol), (tBu)₃PHBF₄ (0.24 g, 0.71 mmol), and tBuONa (0.79 g, 8.17 mmol) were added to 17 ml in the of toluene, and the resultant mixture was heated and stirred at about 100° C. for about 8 hours. Water was added thereto, and the resultant mixture was subjected to Celite filtering and liquid separation to concentrate an organic layer. The organic layer was purified by silica gel column chromatography to obtain Compound 116 (4.1 g, yield: 88%). The molecular weight of Compound 116 was about 1311 as measured by FAB MS.

The purification by sublimation was performed (420° C., 2.9×10⁻³ Pa) to perform device evaluation.

### (5) Synthesis of Compound 121

Compound 121 according to an example may be synthesized by, for example, the steps shown in Reaction Scheme 5 below:

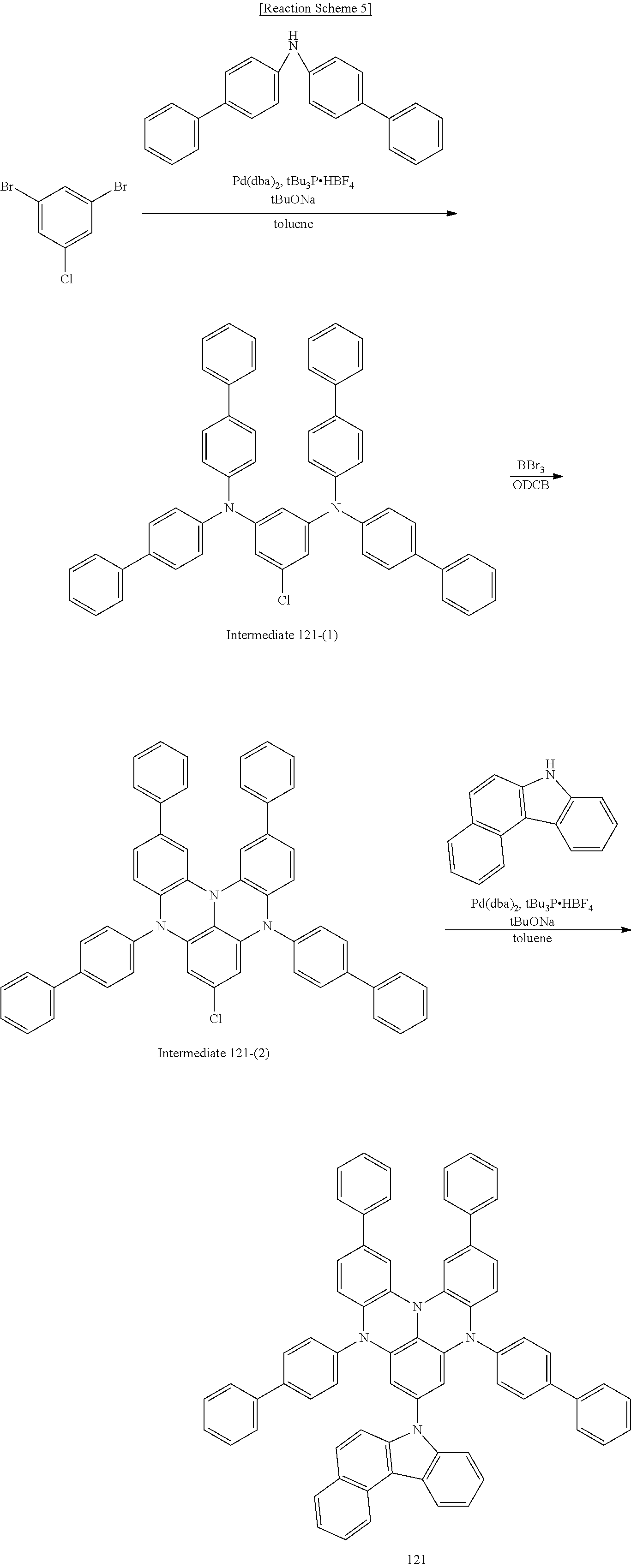

### 1) Synthesis of Intermediate 121-(1)

In an Ar atmosphere, 1,3-dibromo-5-chlorobenzene (24 g, 88.77 mmol), di([1,1′-biphenyl]-4-yl)amine (57.07 g, 177.55 mmol), Pd(dba)₂ (5.1 g, 8.88 mmol), (tBu)₃PHBF₄ (5.15 g, 17.75 mmol), and tBuONa (19.62 g, 204.18 mmol) were added to 443 mL of toluene, and the resultant mixture was heated and stirred at about 100° C. for about 8 hours. Water was added thereto, and the resultant mixture was subjected to Celite filtering and liquid separation to concentrate an organic layer. The organic layer was purified by silica gel column chromatography to obtain Intermediate 121-(1) (43.36 g, yield: 65%). The molecular weight of Intermediate 121-(1) was about 751 as measured by FAB MS.

### 2) Synthesis of Intermediate 121-(2)

In an Ar atmosphere, Intermediate 121-(1) (10 g, 13.31 mmol) was dissolved in ODCB (133 mL), BBr₃ (8.34 g, 33.27 mmol) was added thereto, and the resultant mixture was heated and stirred at about 170° C. for about 10 hours. The resultant mixture was cooled to room temperature, DIPEA (20.6 g, 159.71 mmol) was added thereto, water was added thereto, and the resultant mixture was subjected to Celite filtering and liquid separation to concentrate an organic layer. The organic layer was purified by silica gel column chromatography to obtain Intermediate 121-(2) (3.23 g, yield: 32%). The molecular weight of Intermediate 121-(2) was about 759 as measured by FAB MS.

### 3) Synthesis of Compound 121

In an Ar atmosphere, Intermediate 121-(2) (2.32 g, 3.06 mmol), 7H-benzo[c]carbazole (1.79 g, 6.11 mmol), Pd(dba)₂ (0.18 g, 0.31 mmol), (tBu)₃PHBF₄ (0.18 g, 0.61 mmol), and tBuONa (0.68 g, 7.03 mmol) were added to 15 mL of toluene, and the resultant mixture was heated and stirred at about 100° C. for about 8 hours. Water was added thereto, and the resultant mixture was subjected to Celite filtering and liquid separation to concentrate an organic layer. The organic layer was purified by silica gel column chromatography to obtain Compound 121 (2.13 g, yield: 74%). The molecular weight of Compound 121 was about 940 as measured by FAB MS.

The purification by sublimation was performed (350° C., 3.3×10⁻³ Pa) to perform device evaluation.

### (6) Synthesis of Compound 193

Compound 193 according to an example may be synthesized by, for example, the steps shown in Reaction Scheme 6 below:

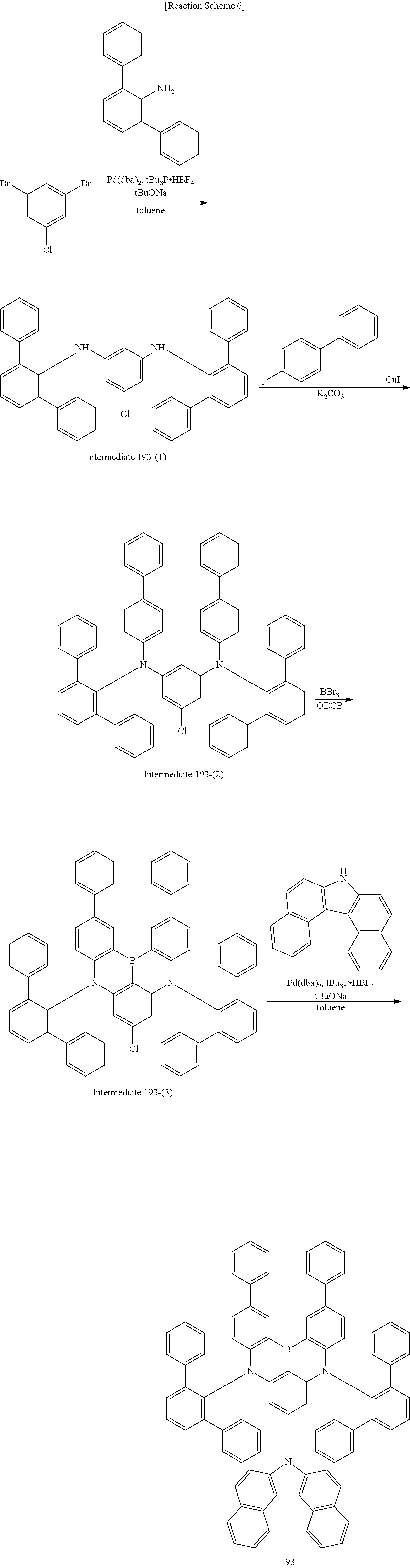

### 1) Synthesis of Intermediate 193-(1)

In an Ar atmosphere, 1,3-dibromo-5-chlorobenzene (25.00 g, 92.47 mmol), [1,1′:3′,1″-terphenyl]-2′-amine (45.37 g, 184.95 mmol), Pd(dba)₂ (5.32 g, 9.25 mmol), (tBu)₃PHBF₄ (5.37 g, 18.49 mmol), and tBuONa (20.44 g, 212.69 mmol) were added to 462 mL of toluene, and the resultant mixture was heated and stirred at about 100° C. for about 8 hours. Water was added thereto, and the resultant mixture was subjected to Celite filtering and liquid separation to concentrate an organic layer. The organic layer was purified by silica gel column chromatography to obtain Intermediate 193-(1) (37.12 g, yield: 67%). The molecular weight of Intermediate 193-(1) was about 599 as measured by FAB MS.

### 2) Synthesis of Intermediate 193-(2)

A small amount of toluene (about 10 mL) was added to Intermediate 193-(1) (10.08 g, 16.82 mmol), 4-iodo-1,1′-biphenyl (70.69 g, 252.35 mmol), CuI (6.73 g, 35.33 mmol), and K₂CO₃ (18.6 g, 134.59 mmol), and the resultant mixture was heated for about 24 hours while maintaining the outside temperature at about 215° C. The resultant mixture was diluted with CH₂Cl₂, water was added thereto, and the mixture was subjected to Celite filtering and liquid separation to concentrate an organic layer. The organic layer was purified by silica gel column chromatography to obtain Intermediate 193-(2) (8.82 g, yield: 58%). The molecular weight of Intermediate 193-(2) was about 904 as measured by FAB MS.

### 3) Synthesis of Intermediate 193-(3)

In an Ar atmosphere, Intermediate 193-(2) (8.00 g, 8.85 mmol) was dissolved in ODCB (89 mL), BBr₃ (5.55 g, 22.13 mmol) was added thereto, and the resultant mixture was heated and stirred at about 170° C. for about 10 hours. The resultant mixture was cooled to room temperature, DIPEA (13.71 g, 106.25 mmol) was added thereto, water was added thereto, and the resultant mixture was subjected to Celite filtering and liquid separation to concentrate an organic layer. The organic layer was purified by silica gel column chromatography to obtain Intermediate 193-(3) (3.03 g, yield: 30%). The molecular weight of Intermediate 193-(3) was about 991 as measured by FAB MS.

### 4) Synthesis of Compound 193

In an Ar atmosphere, Intermediate 193-(3) (2.01 g, 2.21 mmol), 7H-dibenzo[c,g]carbazole (0.96 g, 4.41 mmol), Pd(dba)₂ (0.13 g, 0.22 mmol), (tBu)₃PHBF₄ (0.13 g, 0.44 mmol), and tBuONa (0.49 g, 5.07 mmol) were added to 11 mL of toluene, and the resultant mixture was heated and stirred at about 100° C. for about 8 hours. Water was added thereto, and the resultant mixture was subjected to Celite filtering and liquid separation to concentrate an organic layer. The organic layer was purified by silica gel column chromatography to obtain Compound 193 (2.24 g, yield: 89%). The molecular weight of Compound 193 was about 1142 as measured by FAB MS.

The purification by sublimation was performed (360° ° C., 3.8×10⁻³ Pa) to perform device evaluation.

### (7) Synthesis of Compound 202

Compound 202 according to an example may be synthesized by, for example, the steps shown in Reaction Scheme 7 below:

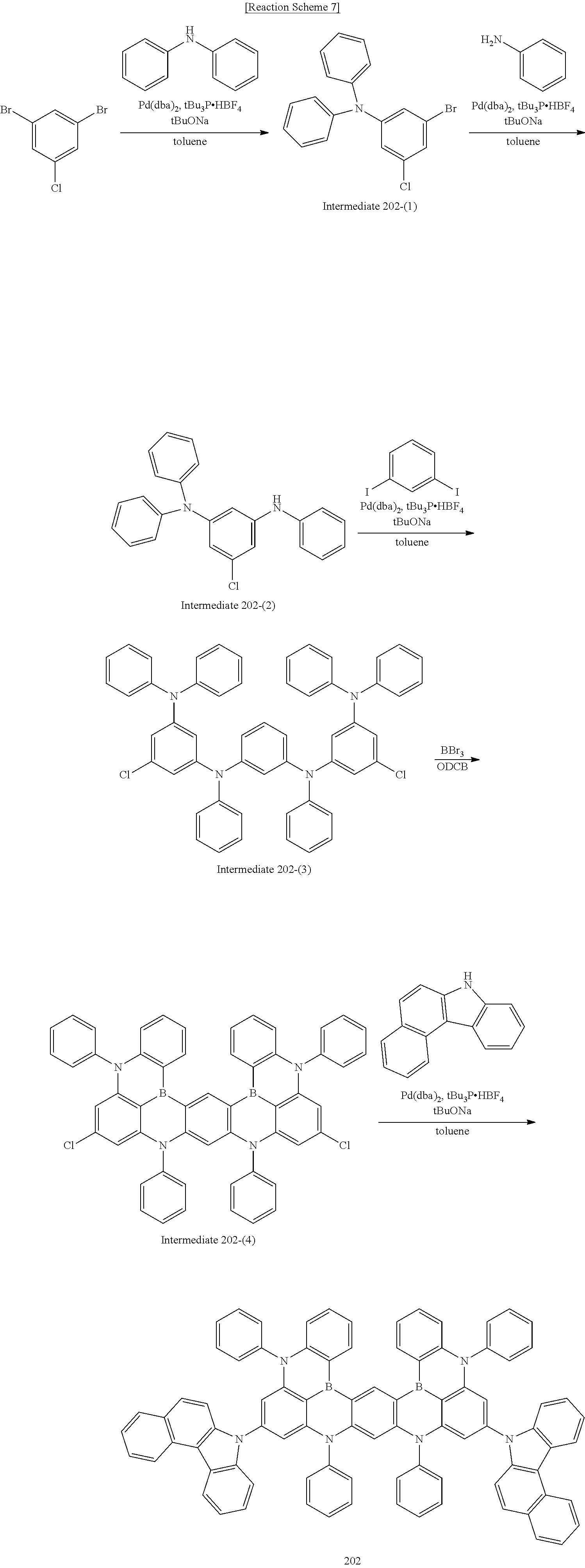

### 1) Synthesis of Intermediate 202-(1)

In an Ar atmosphere, 1,3-dibromo-5-chlorobenzene (25.0 g, 92.47 mmol), diphenylamine (15.65 g, 92.47 mmol), Pd(dba)₂ (5.32 g, 9.25 mmol), (tBu)₃PHBF₄ (5.37 g, 18.49 mmol), and tBuONa (20.44 g, 212.69 mmol) were added to 462 mL of toluene, and the resultant mixture was heated and stirred at about 100° C. for about 8 hours. Water was added thereto, and the resultant mixture was subjected to Celite filtering and liquid separation to concentrate an organic layer. The organic layer was purified by silica gel column chromatography to obtain Intermediate 202-(1) (17.25 g, yield: 52%). The molecular weight of Intermediate 202-(1) was about 359 as measured by FAB MS.

### 2) Synthesis of Intermediate 202-(2)

In an Ar atmosphere, Intermediate 202-(1) (16.0 g, 44.61 mmol), aniline (4.57 g, 49.07 mmol), Pd(dba)₂ (2.57 g, 4.46 mmol), (tBu)₃PHBF₄ (2.59 g, 8.92 mmol), and tBuONa (9.86 g, 102.6 mmol) were added to 223 mL of toluene, and the resultant mixture was heated and stirred at about 100° C. for about 8 hours. Water was added thereto, and the resultant mixture was subjected to Celite filtering and liquid separation to concentrate an organic layer. The organic layer was purified by silica gel column chromatography to obtain Intermediate 202-(2) (14.06 g, yield: 85%). The molecular weight of Intermediate 202-(2) was about 371 as measured by FAB MS.

### 3) Synthesis of Intermediate 202-(3)

In an Ar atmosphere, Intermediate 202-(2) (12.01 g, 32.38 mmol), 1,3-diiodobenzene (5.34 g, 16.19 mmol), Pd(dba)₂ (1.86 g, 3.24 mmol), (tBu)₃PHBF₄ (1.88 g, 6.48 mmol), and tBuONa (7.16 g, 74.48 mmol) were added to 161 mL of toluene, and the resultant mixture was heated and stirred at about 100° C. for about 8 hours. Water was added thereto, and the resultant mixture was subjected to Celite filtering and liquid separation to concentrate an organic layer. The organic layer was purified by silica gel column chromatography to obtain Intermediate 202-(3) (9.51 g, yield: 72%). The molecular weight of Intermediate 202-(3) was about 816 as measured by FAB MS.

### 4) Synthesis of Intermediate 202-(4)

In an Ar atmosphere, Intermediate 202-(3) (8.00 g, 9.81 mmol) was dissolved in ODCB (98 mL), BBr₃ (6.14 g, 24.51 mmol) was added thereto, and the resultant mixture was heated and stirred at about 170° C. for about 10 hours. The resultant mixture was cooled to room temperature, DIPEA (15.18 g, 117.67 mmol) was added thereto, water was added thereto, and the resultant mixture was subjected to Celite filtering and liquid separation to concentrate an organic layer. The organic layer was purified by silica gel column chromatography to obtain Intermediate 202-(4) (3.51 g, yield: 43%). The molecular weight of Intermediate 202-(4) was about 831 as measured by FAB MS.

### 5) Synthesis of Compound 202

In an Ar atmosphere, Intermediate 202-(4) (2.1 g, 2.53 mmol), 7H-benzo[c]carbazole (1.37 g, 6.31 mmol), Pd(dba)₂ (0.15 g, 0.25 mmol), (tBu)₃PHBF₄ (0.15 g, 0.51 mmol), and tBuONa (0.56 g, 5.81 mmol) were added to 12 mL of toluene, and the resultant mixture was heated and stirred at about 100° C. for about 8 hours. Water was added thereto, and the resultant mixture was subjected to Celite filtering and liquid separation to concentrate an organic layer. The organic layer was purified by silica gel column chromatography to obtain Compound 202 (1.33 g, yield: 88%). The molecular weight of Compound 202 was about 1193 as measured by FAB MS.

The purification by sublimation was performed (390° C., 2.8×10⁻³ Pa) to perform device evaluation.

### 2. Manufacture and Evaluation of Light Emitting Elements

### (1) Manufacture of Light Emitting Elements

Light emitting elements including the polycyclic compound of an Example Compound or a Comparative Example Compound in the emission layer were manufactured as follows. Compounds 8, 61, 94, 116, 121, 193, and 202, which are Example Compounds, were used as a dopant material for the emission layer to manufacture the light emitting elements of Examples 1 to 7. Comparative Example Compounds X1 to X9 were used as a dopant material for the emission layer to manufacture the light emitting elements of Comparative Examples 1 to 9.

A glass substrate on which a 150 nm-thick ITO had been patterned was ultrasonically washed by using isopropyl alcohol and pure water for about 5 minutes each. After ultrasonically washed, the glass substrate was irradiated with UV rays for about 30 minutes and treated with ozone. HAT-CN was deposited to have a thickness of about 10 nm, a-NPD was deposited to have a thickness of about 80 nm, and mCP was deposited to have a thickness of about 5 nm in this order to form a hole transport region.

An Example Compound or a Comparative Example Compound and mCBP were co-deposited to form a 20 nm-thick emission layer. An Example Compound or a Comparative Example Compound and mCBP were co-deposited at a weight ratio of about 1:99. In the manufacture of the light emitting element, an Example Compound or a Comparative Example Compound was used as a dopant material.

On the emission layer, TBPi was deposited to have a thickness of about 30 nm and LiF was deposited to have a thickness of about 0.5 nm to form an electron transport region.

Al was deposited on the electron transport region to form a 100 nm-thick second electrode, thereby manufacturing a light emitting element.

In the Examples, the hole transport region, the emission layer, the electron transport region, and the second electrode were formed using a vacuum deposition apparatus.

Example Compounds and Comparative Example Compounds used to manufacture the light emitting elements are as follows:

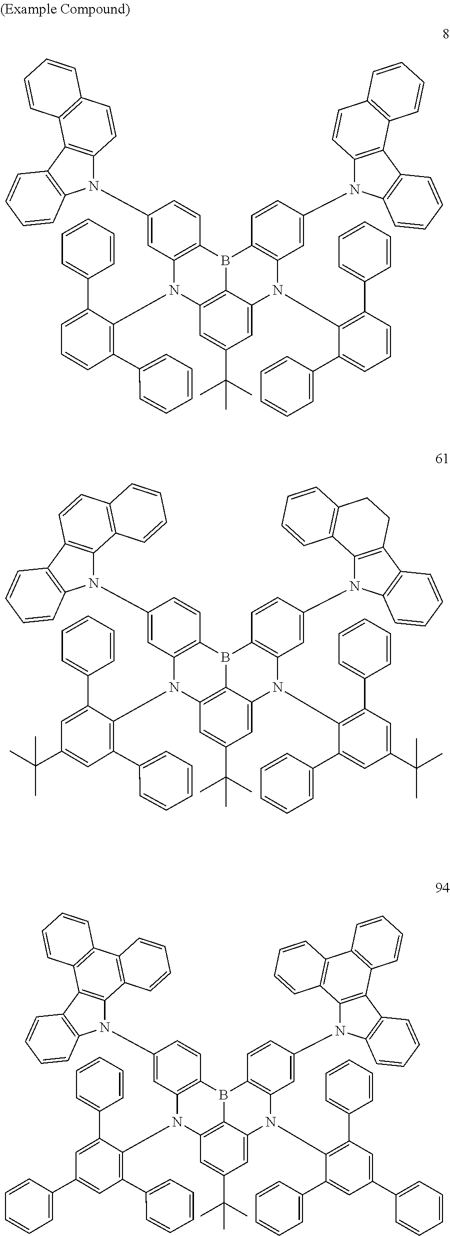

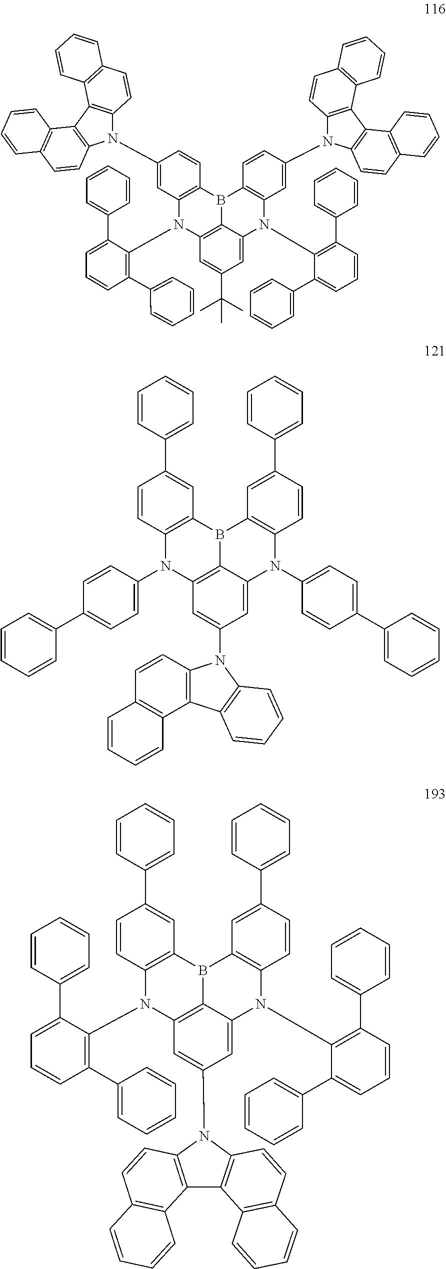

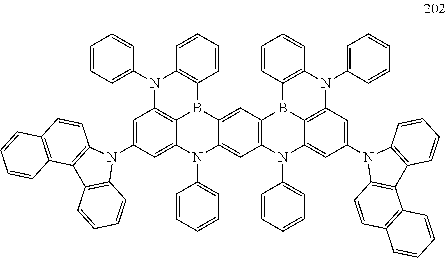 [SMILES: c1ccc(N2c3ccccc3B3c4cc5c(cc4N(c4ccccc4)c4cc(-n6c7ccccc7c7c8ccccc8ccc76)cc2c43)N(c2ccccc2)c2cc(-n3c4ccccc4c4c6ccccc6ccc43)cc3c2B5c2ccccc2N3c2ccccc2)cc1]

### Comparative Example Compound

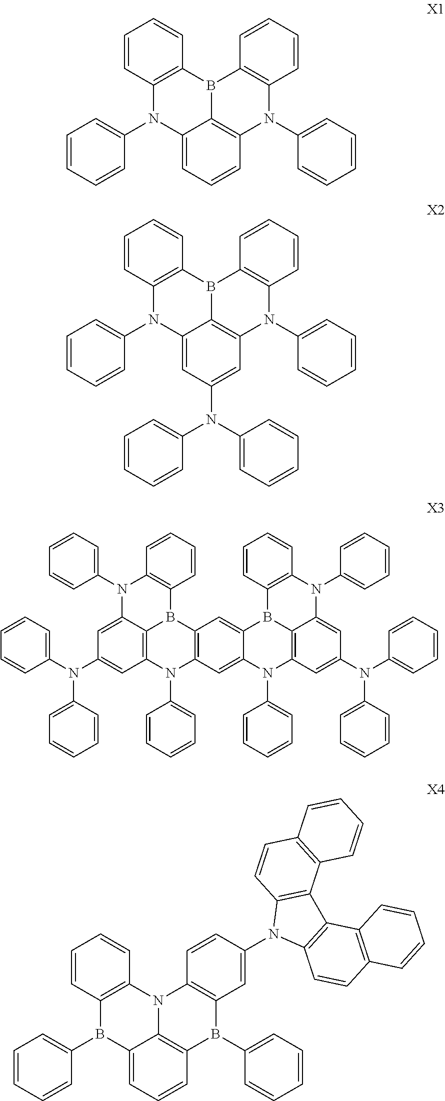 [SMILES: c1ccc(N2c3ccccc3B3c4ccccc4N(c4ccccc4)c4cccc2c43)cc1 ; c1ccc(N(c2ccccc2)c2cc3c4c(c2)N(c2ccccc2)c2ccccc2B4c2ccccc2N3c2ccccc2)cc1 ; c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)cc(c32)N5c2ccccc2)cc1 ; c1ccc(B2c3ccccc3N3c4ccc(-n5c6ccc7ccccc7c6c6c7ccccc7ccc65)cc4B(c4ccccc4)c4cccc2c43)cc1]

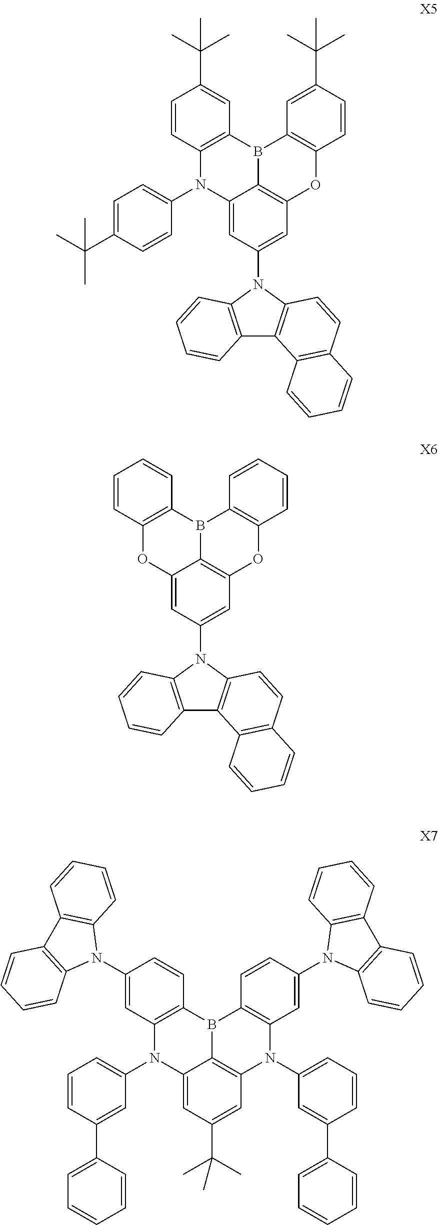 [SMILES: CC(C)(C)c1ccc(N2c3ccc(C(C)(C)C)cc3B3c4cc(C(C)(C)C)ccc4Oc4cc(-n5c6ccccc6c6c7ccccc7ccc65)cc2c43)cc1 ; c1ccc2c(c1)Oc1cc(-n3c4ccccc4c4c5ccccc5ccc43)cc3c1B2c1ccccc1O3 ; CC(C)(C)c1cc2c3c(c1)N(c1cccc(-c4ccccc4)c1)c1cc(-n4c5ccccc5c5ccccc54)ccc1B3c1ccc(-n3c4ccccc4c4ccccc43)cc1N2c1cccc(-c2ccccc2)c1]

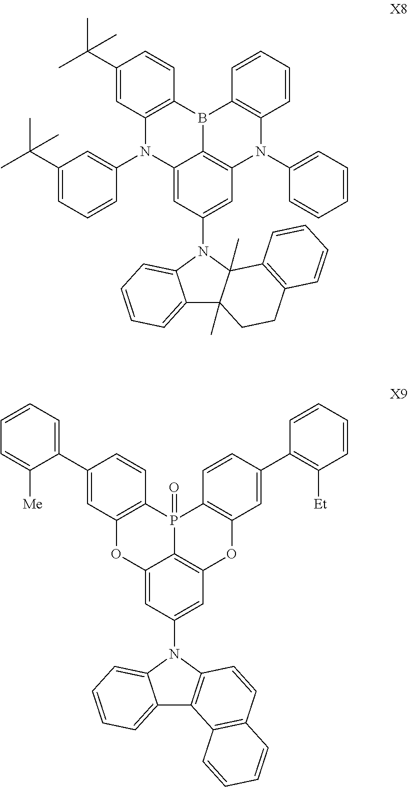 [SMILES: CC(C)(C)c1cccc(N2c3cc(C(C)(C)C)ccc3B3c4ccccc4N(c4ccccc4)c4cc(N5c6ccccc6C6(C)CCc7ccccc7C56C)cc2c43)c1 ; CCc1ccccc1-c1ccc2c(c1)Oc1cc(-n3c4ccccc4c4c5ccccc5ccc43)cc3c1P2(=O)c1ccc(-c2ccccc2C)cc1O3]

### (Other Materials Used to Manufacture Light Emitting Elements)

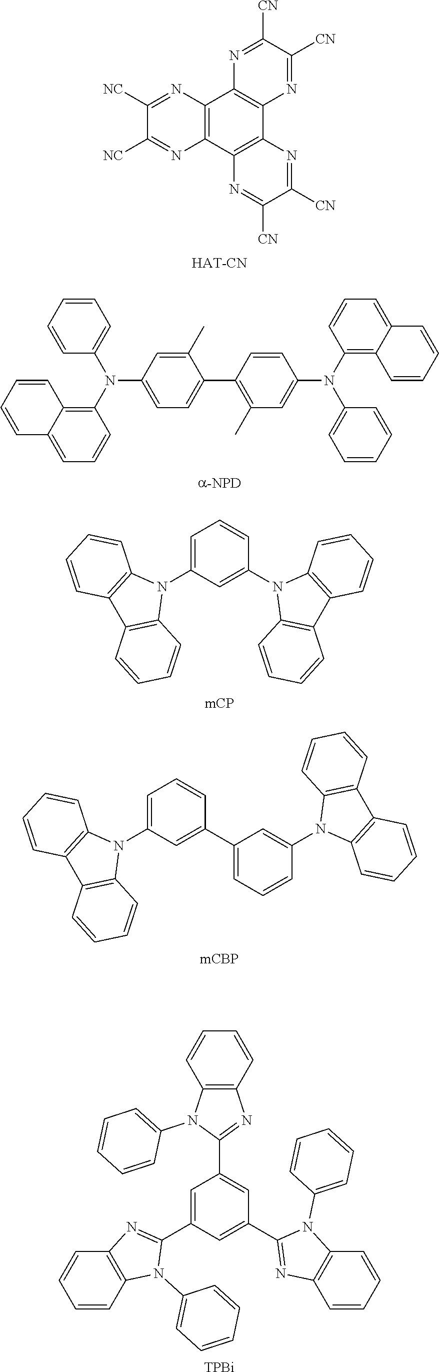

### (2) Evaluation of Light Emitting Elements

Evaluation results of the light emitting elements in Examples 1 to 7 and Comparative Examples 1 to 9 are listed in Table 1. A maximum emission wavelength (λₘₐₓ), a delayed fluorescence service life, roll-off, and a relative service life (LT50) in the manufactured light emitting elements are listed in comparison in Table 1. In the evaluation of the element, the maximum emission wavelength (λₘₐₓ) represents the maximum emission wavelength value in an emission spectrum of the light emitting element, and the emission decay time (μS) is represented by a value calculated from the time-resolved photoluminescence (TRPL) spectrum at room temperature with respect to a 20-nm thin film composed of a dopant (1.0 wt %) of Example or Comparative Example Compounds and a host (mCBP, 99 wt %).

In the characteristic evaluation results of Examples and Comparative Examples listed in Table 1, the roll-off is represented by [[(external quantum efficiency at 1 cd/m³)−(1,000 cd/m³)]/(external quantum efficiency at 1 cd/m³)]×100. The relative service life is shown by evaluating a brightness half-life from an initial brightness of 100 cd/m². The relative service life is shown relative to the basis of the result of Comparative Example 3.

TABLE 1

| Element | | | Emission | | LT50 |
|---|---|---|---|---|---|
| Manufacture | | λₘₐₓ | decay time | Roll-off | Relative |
| Examples | Dopant | (nm) | (μS) | (%) | service life |
| Example 1 | 8 | 460 | 100 | 10.6 | 6.3 |
| Example 2 | 61 | 459 | 110 | 11.0 | 5.8 |
| Example 3 | 94 | 459 | 120 | 12.0 | 5.2 |
| Example 4 | 116 | 462 | 150 | 13.1 | 4.3 |
| Example 5 | 121 | 458 | 52 | 8.1 | 5.8 |
| Example 6 | 193 | 460 | 62 | 8.4 | 7.5 |
| Example 7 | 202 | 467 | 15 | 5.3 | 8.2 |
| Comparative | X1 | 457 | 130 | 33.2 | 0.3 |
| Example 1 | | | | | |
| Comparative | X2 | 446 | 11.2 | 30.5 | 0.2 |
| Example 2 | | | | | |
| Comparative | X3 | 467 | 5.5 | 13.5 | 1.0 |
| Example 3 | | | | | |
| Comparative | X4 | 472 | 226 | 82.5 | 0.20 |
| Example 4 | | | | | |
| Comparative | X5 | 452 | 65 | 62.1 | 0.38 |
| Example 5 | | | | | |
| Comparative | X6 | 450 | non | 72.1 | 0.32 |
| Example 6 | | | | | |
| Comparative | X7 | 458 | 88 | 18.2 | 0.95 |
| Example 7 | | | | | |
| Comparative | X8 | 455 | 125 | 23.2 | 0.10 |
| Example 8 | | | | | |
| Comparative | X9 | 452 | non | 35.5 | 0.05 |
| Example 9 | | | | | |

Referring to Table 1, the light emitting elements of Examples 1 to 7 exhibit long service life characteristics as compared with those of Comparative Examples 1 to 9. It may be confirmed that the light emitting elements of Examples including, as a material for the emission layer, the polycyclic compound containing a carbazole group in which at least one benzene group is fused exhibit long service life characteristics as compared with those of Comparative Examples without containing the carbazole group in which at least one benzene group is fused.

In Table 1, the emission decay time indicated as “non” represents that the emission decay time has a specific value of 1 μS or less and thus is not determined by the time measurement in μS unit.

Referring to Table 1, the maximum emission wavelength (λₘₐₓ) in Examples 1 to 7 is about 460 nm, which exhibits color purity close to pure blue compared to Comparative Examples 1 to 9. Each of Examples 1 to 7 exhibit improved characteristics in the service life, as compared with Comparative Examples 1 to 9.

Examples 1 to 7 exhibit low roll-off characteristics as compared with Comparative Examples 1 to 9. Thus, it is thought that Examples 1 to 7 exhibit the results of a significantly improved service life as compared with Comparative Examples 1 to 9.

Comparative Example Compounds X1, X2, X3, X7, and X8 are different from Example Compounds in that Comparative Example Compounds X1, X2, X3, X7, and X8 do not include the carbazole group in which a benzene ring is fused. Comparative Example Compounds X4, X5, X6, and X9 have a different combination of heteroatoms contained in the core than Example Compounds. For example, it is thought that Example Compounds have a structure in which a carbazole group in which a benzene ring is fused is substituted at the core structures below, thereby having structural stability. It is thought that the light emitting elements of the Examples include, as a material for the emission layer, the Example Compounds having structural stability, thereby exhibiting long service life characteristics.

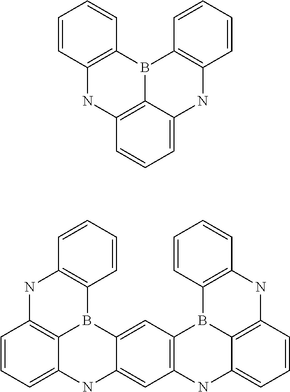 [SMILES: c1ccc2c(c1)Nc1cccc3c1B2c1ccccc1N3 ; c1ccc2c(c1)Nc1cccc3c1B2c1cc2c(cc1N3)Nc1cccc3c1B2c1ccccc1N3]

The polycyclic compound according to an embodiment may have the core part of the fused ring containing nitrogen, boron, and nitrogen as ring-forming atoms, and a structure in which a carbazole group in which at least one benzene group is fused is substituted, and thus the polycyclic compound may exhibit excellent stability. The light emitting element including this polycyclic compound according to an example may exhibit long service life characteristics.

The light emitting element according to an embodiment may include the polycyclic compound, thereby exhibiting long service life characteristics.

The polycyclic compound according to an embodiment may contribute to the improvement in the light efficiency and a long service life of the light emitting element.

Embodiments have been disclosed herein, and although terms are employed, they are used and are to be interpreted in a generic and descriptive sense only and not for the purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a second electrode disposed on the first electrode; and
an emission layer disposed between the first electrode and the second electrode, wherein
the emission layer comprises:
a first compound represented by Formula 1; and
at least one of a second compound and a third compound: 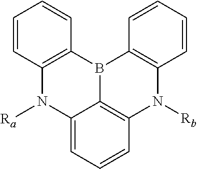
wherein in Formula 1,
a is an integer from 0 to 2,
b and c are each independently an integer from 0 to 3,
at least one of R₁₁, R₂₁, and R₃₁ is a group represented by Formula 2,
the remainder of R₁₁, R₂₁, and R₃₁ are each independently a hydrogen atom, a deuterium atom, a halogen atom, a cyano group, a substituted or unsubstituted amine group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
R₁₂, R₂₂, R₃₂, Rₐ, and R_{b} are each independently a hydrogen atom, a deuterium atom, a halogen atom, a cyano group, a substituted or unsubstituted amine group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring, and
at least one hydrogen atom in Formula 1 is optionally substituted with a deuterium atom; 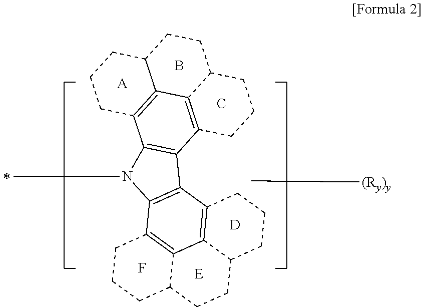
wherein in Formula 2,
at least one of A to F is each a benzene ring,
the remainder of A to F are absent,
y is an integer from 0 to 16,
R_{y} is a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
at least one hydrogen atom in Formula 2 is optionally substituted with a deuterium atom.

2. The light emitting element of claim 1, wherein the first compound is represented by Formula 3: 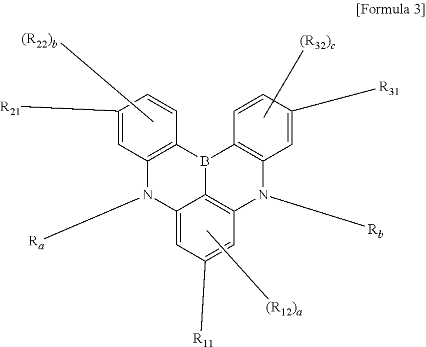
wherein in Formula 3,
a, b, c, Rₐ, R_{b}, R₁₁, R₂₁, R₃₁, R₁₂, R₂₂, and R₃₂ are the same as defined in Formula 1, and
at least one hydrogen atom in Formula 3 is optionally substituted with a deuterium atom.

3. The light emitting element of claim 2, wherein the first compound is represented by Formula 4-1 or Formula 4-2: 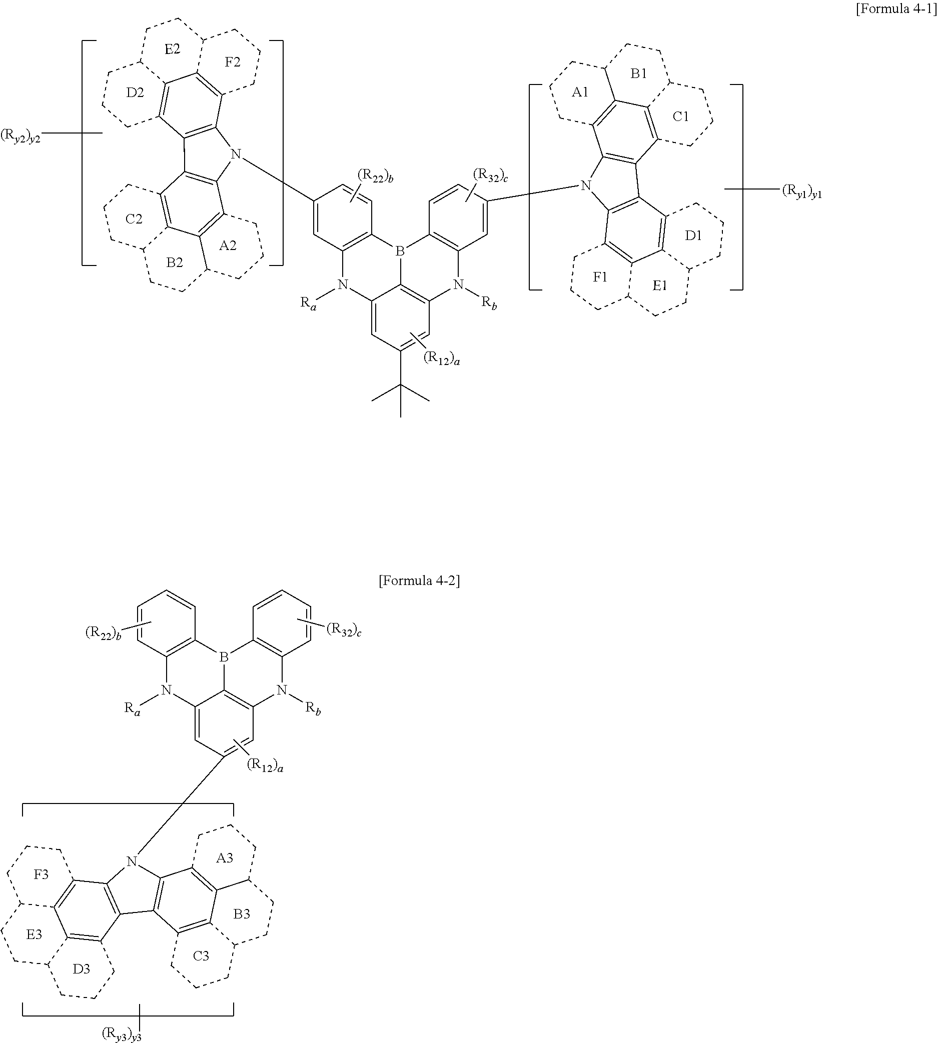
wherein in Formula 4-1,
at least one of A1 to F1 is each a benzene ring,
the remainder of A1 to F1 are absent,
at least one of A2 to F2 is each a benzene ring,
the remainder of A2 to F2 are absent,
y₁ and y₂ are each independently an integer from 0 to 16,
R_{y1} and R_{y2} are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
a, b, c, Rₐ, R_{b}, R₁₂, R₂₂, and R₃₂ are the same as defined in Formula 1, and
at least one hydrogen atom in Formula 4-1 is optionally substituted with a deuterium atom, and
in Formula 4-2,
at least one of A3 to F3 is each a benzene ring,
the remainder of A3 to F3 are absent,
y₃ is an integer from 0 to 16,
R_{y3} is a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
a, b, c, Rₐ, R_{b}, R₁₂, R₂₂, and R₃₂ are the same as defined in Formula 1, and
at least one hydrogen atom in Formula 4-2 is optionally substituted with a deuterium atom.

4. The light emitting element of claim 1, wherein the first compound is represented by Formula 5: 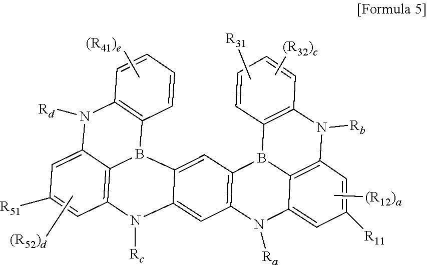
wherein in Formula 5,
R₁₁ is a group represented by Formula 2,
R₅₁ is a group represented by Formula 2, a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
d is an integer from 0 to 2,
e is an integer from 0 to 4,
R₃₁, R₄₁, R₅₂, R_{c}, and R_{d} are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
a, c, Rₐ, R_{b}, R₁₂, and R₃₂ are the same as defined in Formula 1, and
at least one hydrogen atom in Formula 5 is optionally substituted with a deuterium atom.

5. The light emitting element of claim 1, wherein a group represented by Formula 2 is represented by one of Formula 6-1 to Formula 6-14: 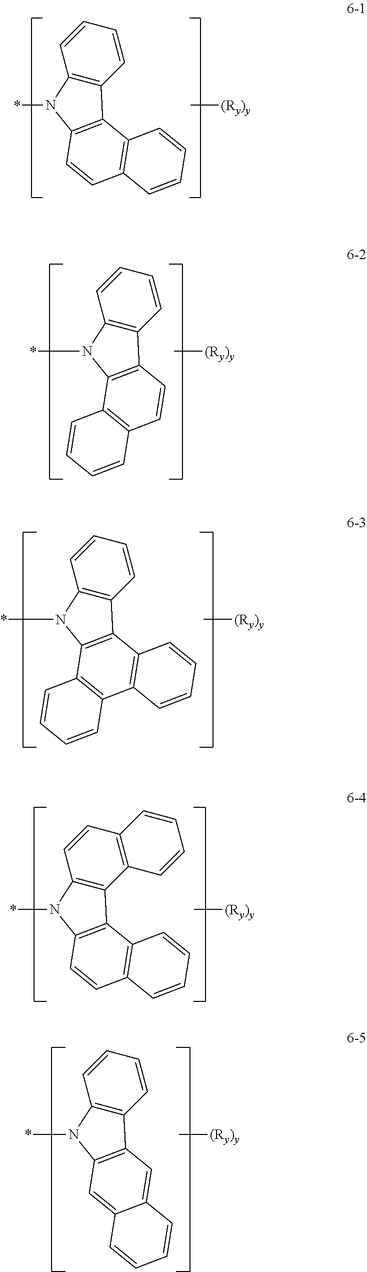 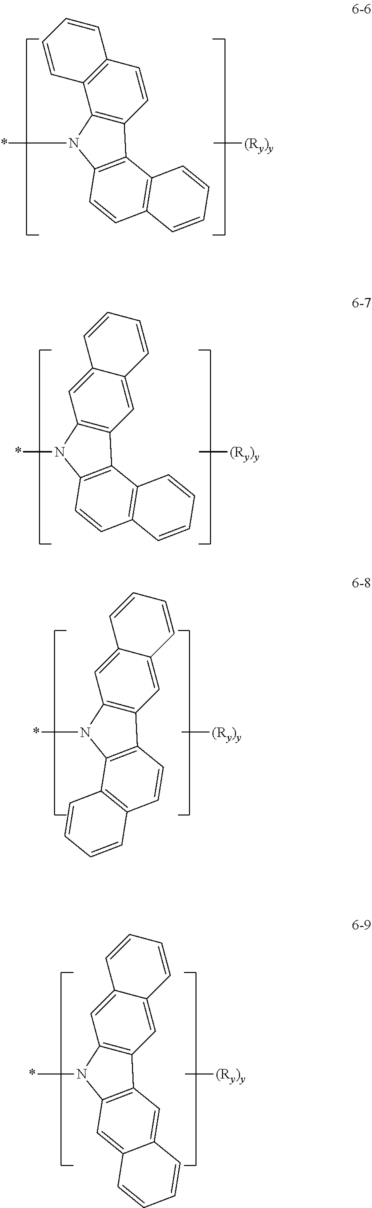 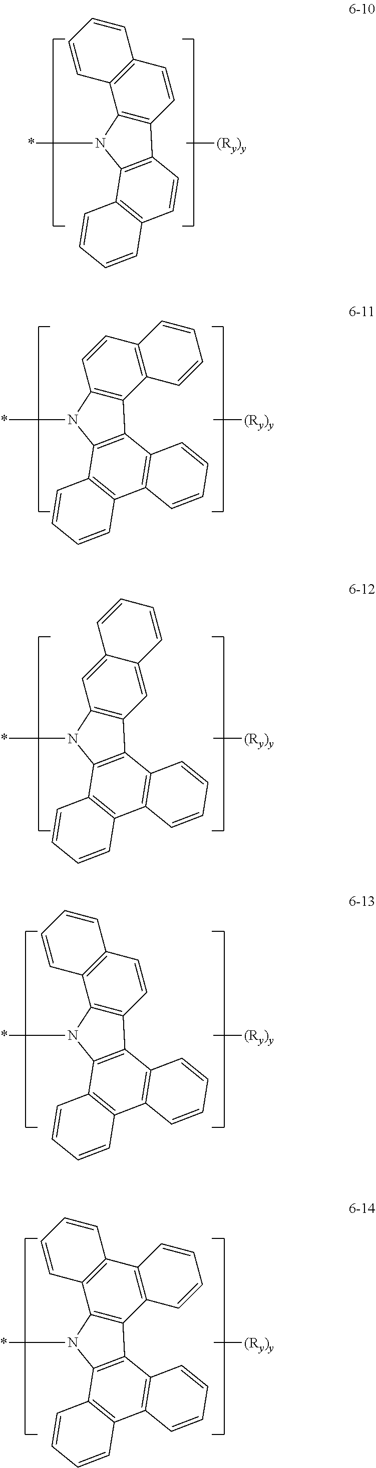
wherein in Formula 6-1 to Formula 6-14,
y and R_{y} are the same as defined in Formula 2, and
at least one hydrogen atom in one of Formula 6-1 to Formula 6-14 is optionally substituted with a deuterium atom.

6. The light emitting element of claim 1, wherein in Formula 2,
R_{y} is a hydrogen atom, a deuterium atom, a t-butyl group, a substituted or unsubstituted phenyl group, a substituted or unsubstituted naphthyl group, a substituted or unsubstituted phenanthryl group, or a substituted or unsubstituted propylphenyl group.

7. The light emitting element of claim 1, wherein the second compound is represented by HT-1: 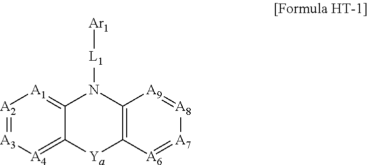
wherein in Formula HT-1,
A₁ to A₄ and A₆ to A₉ are each independently N or C(R₄₁),
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, C(R₄₂)(R₄₃), or Si(R₄₄)(R₄₅),
Ar₁ is a substituted or unsubstituted aryl group having 6 to 30 ring-forming carbon atoms or a substituted or unsubstituted heteroaryl group having 2 to 30 ring-forming carbon atoms, and
R₄₁ to R₄₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms.

8. The light emitting element of claim 1, wherein the third compound is represented by Formula ET-1: 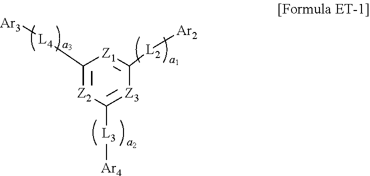
wherein in Formula ET-1,
at least one of Z₁ to Z₃ is each N,
the remainder of Z₁ to Z₃ are each independently C(Rₐ₃),
Rₐ₃ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
a₁ to a₃ are each independently an integer from 0 to 10,
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms, and
Ar₂ to Ar₄ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

9. The light emitting element of claim 1, wherein
the emission layer further comprises a fourth compound, and
the fourth compound is represented by Formula D-1: 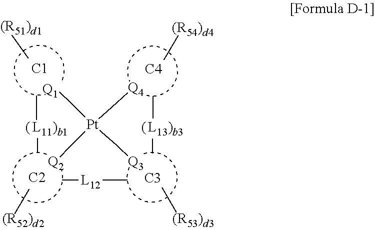
wherein in Formula D-1,
Q₁ to Q₄ are each independently C or N,
C1 to C4 are each independently a substituted or unsubstituted hydrocarbon ring group having 5 to 30 ring-forming carbon atoms or a substituted or unsubstituted heterocyclic group having 2 to 30 ring-forming carbon atoms,
L₁₁ to L₁₃ are each independently a direct linkage, 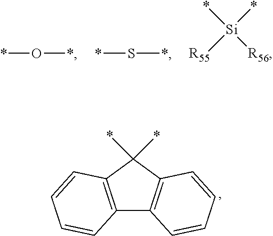
a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
in L₁₁ to L₁₃, —* represents a bond linked to one of C1 to C4,
b1 to b3 are each independently 0 or 1,
R₅₁ to R₅₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring, and
d1 to d4 are each independently an integer from 0 to 4.

10. The light emitting element of claim 9, wherein the emission layer comprises the first compound, the second compound, the third compound, and the fourth compound.

11. The light emitting element of claim 1, wherein the emission layer emits blue light.

12. The light emitting element of claim 1, wherein the emission layer emits thermally activated delayed fluorescence.

13. The light emitting element of claim 1, wherein the emission layer comprises at least one compound selected from Compound Group 1: 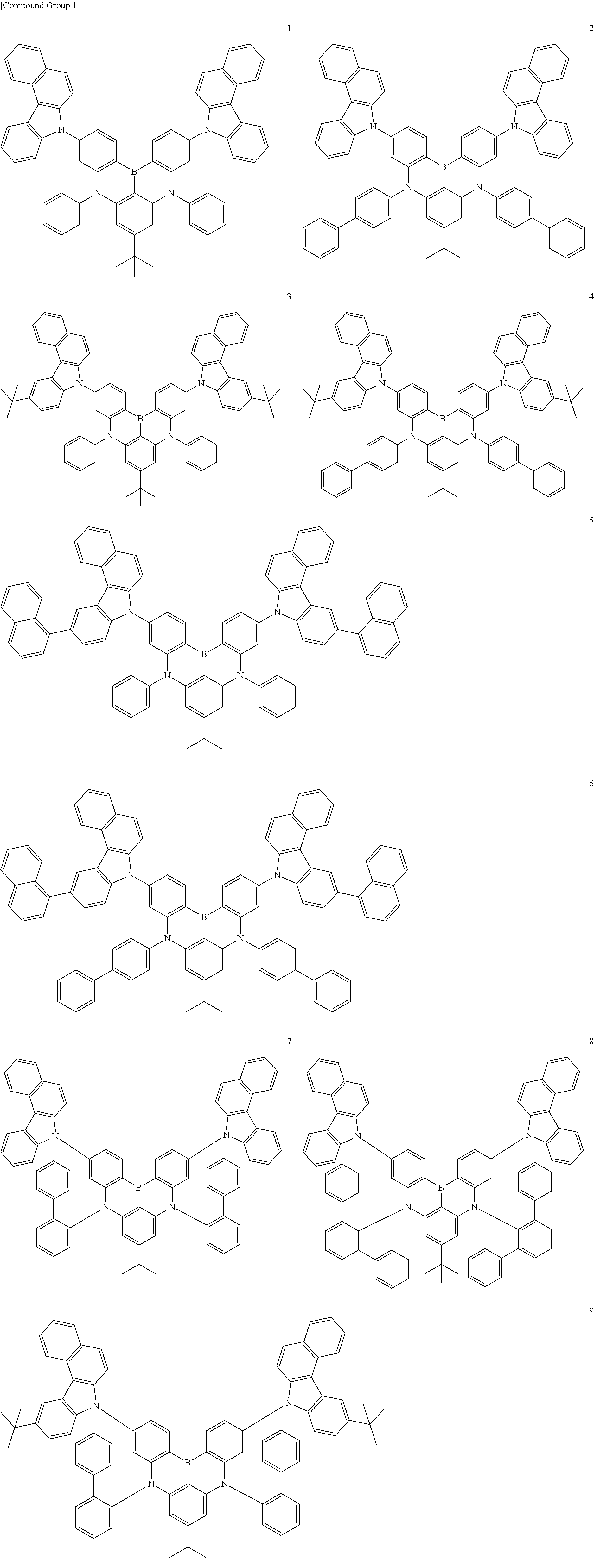 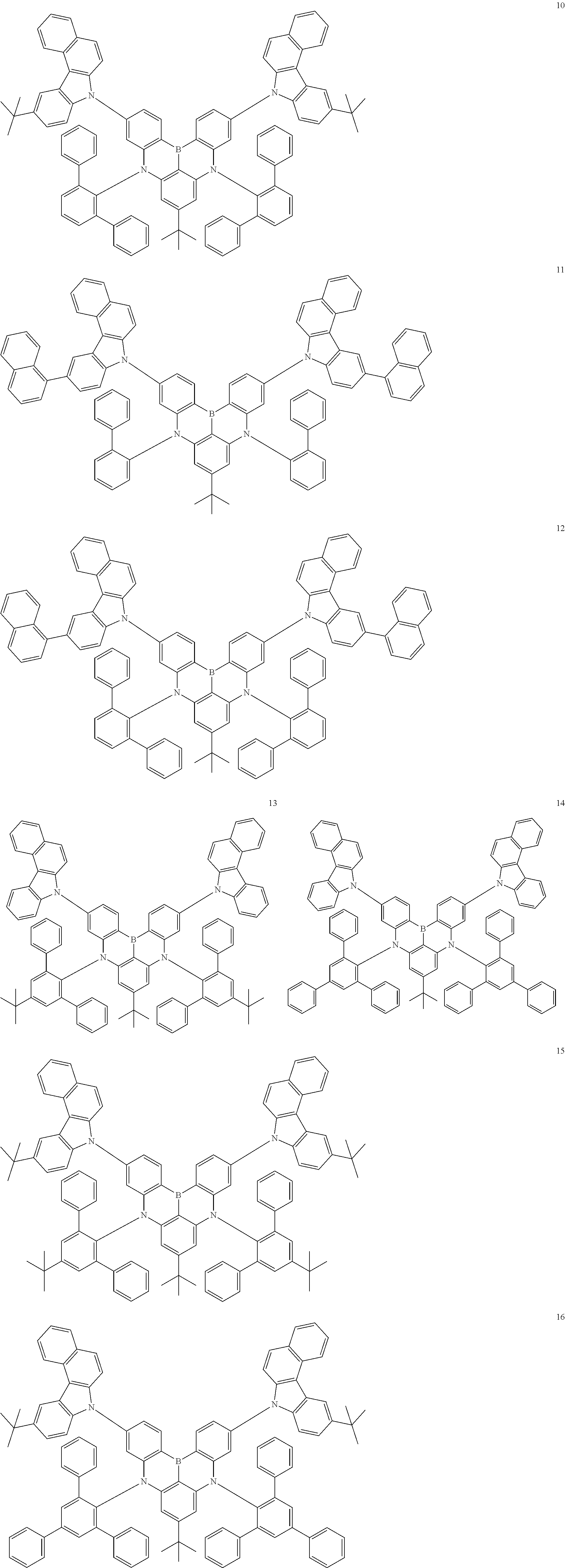 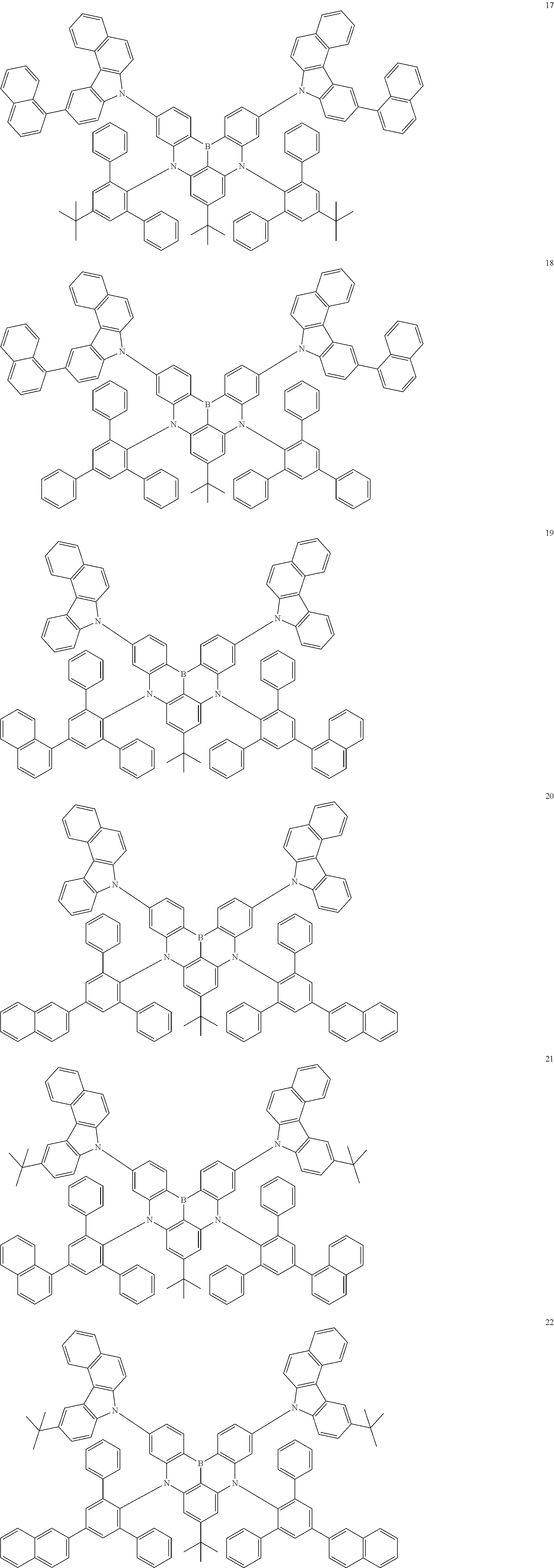 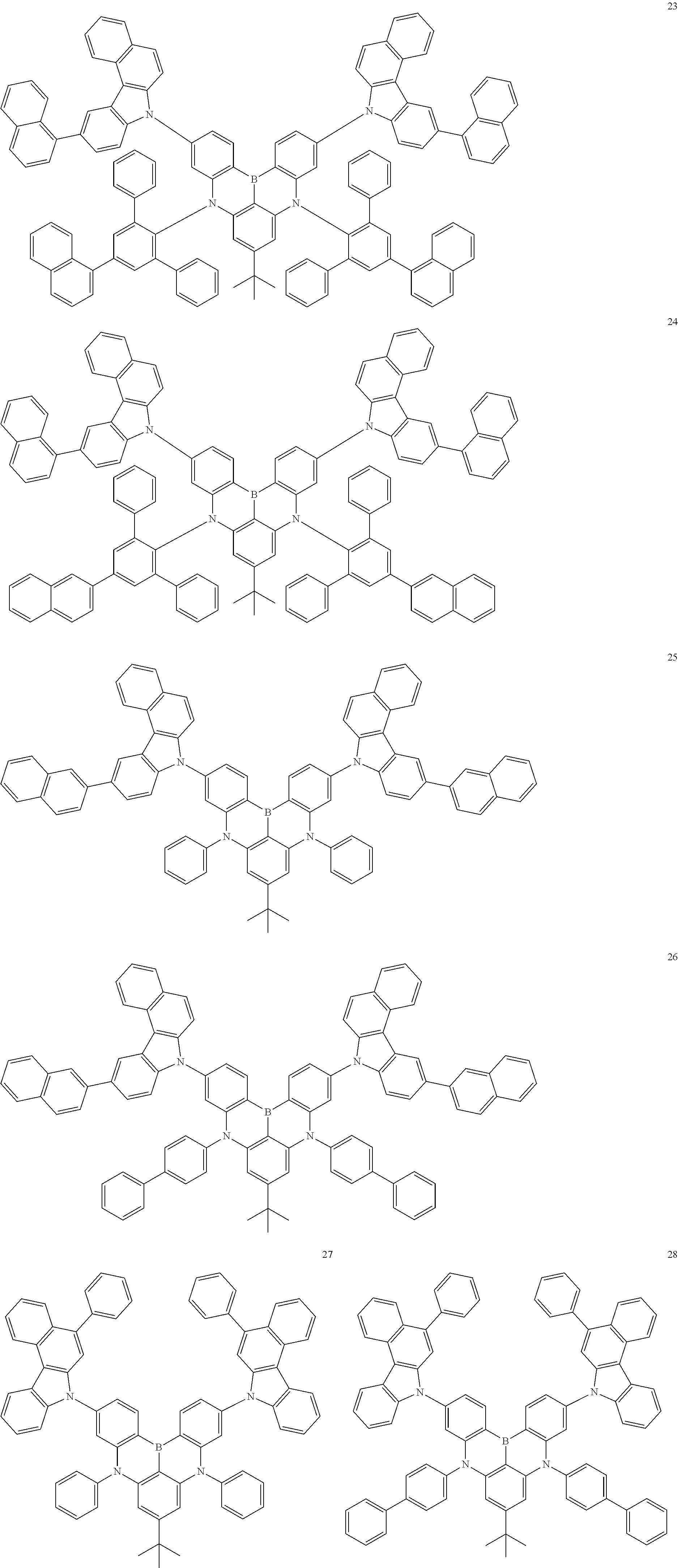 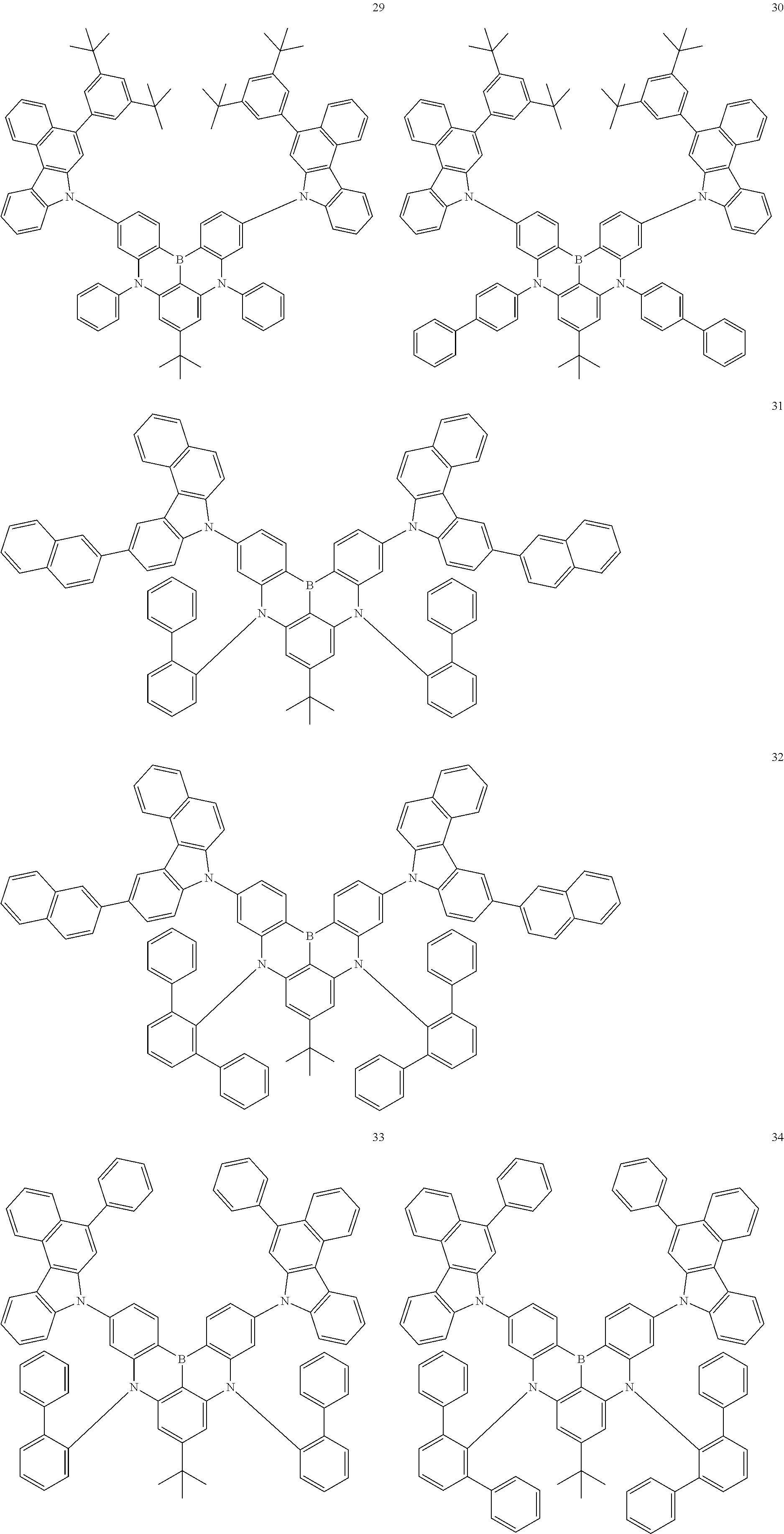 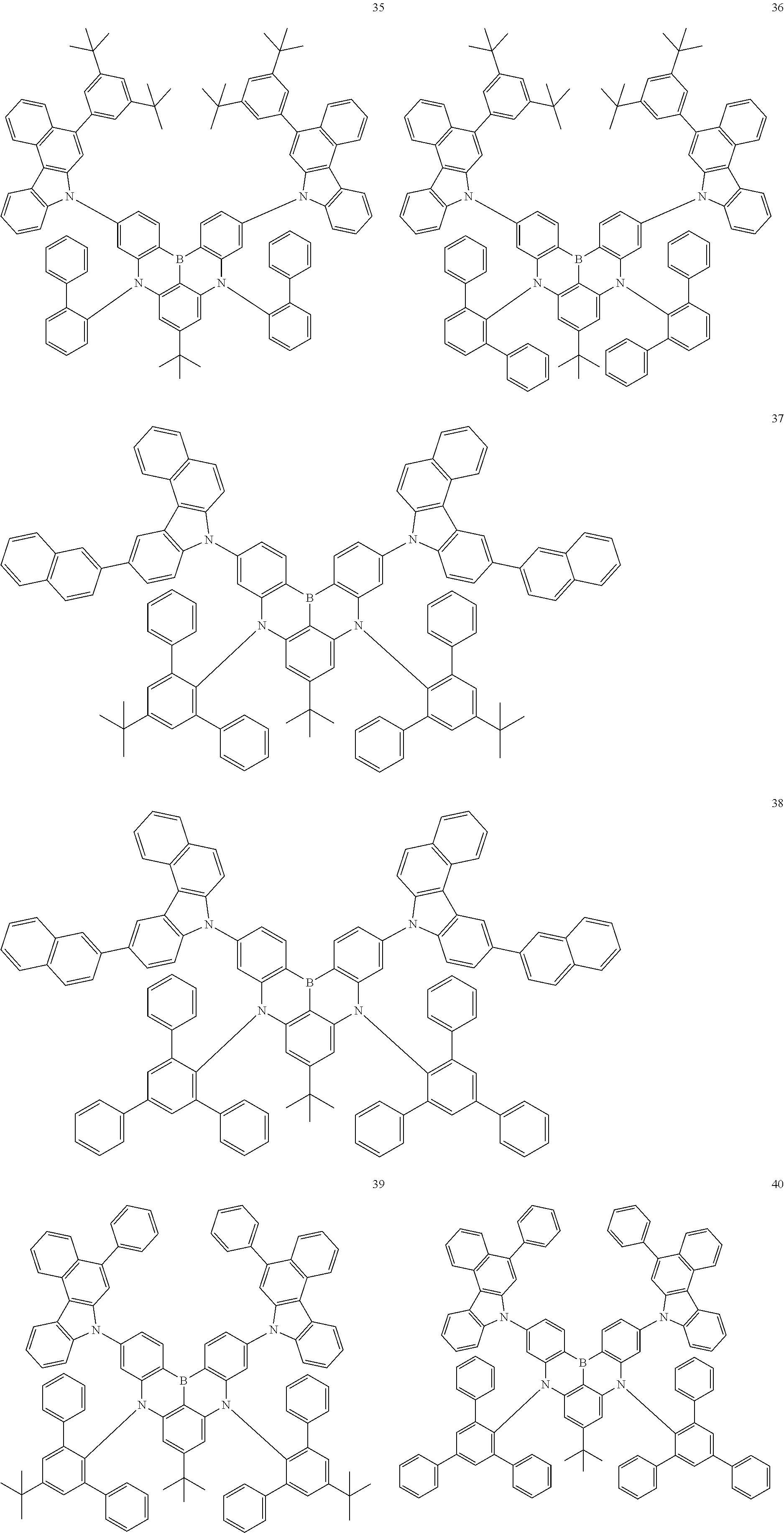 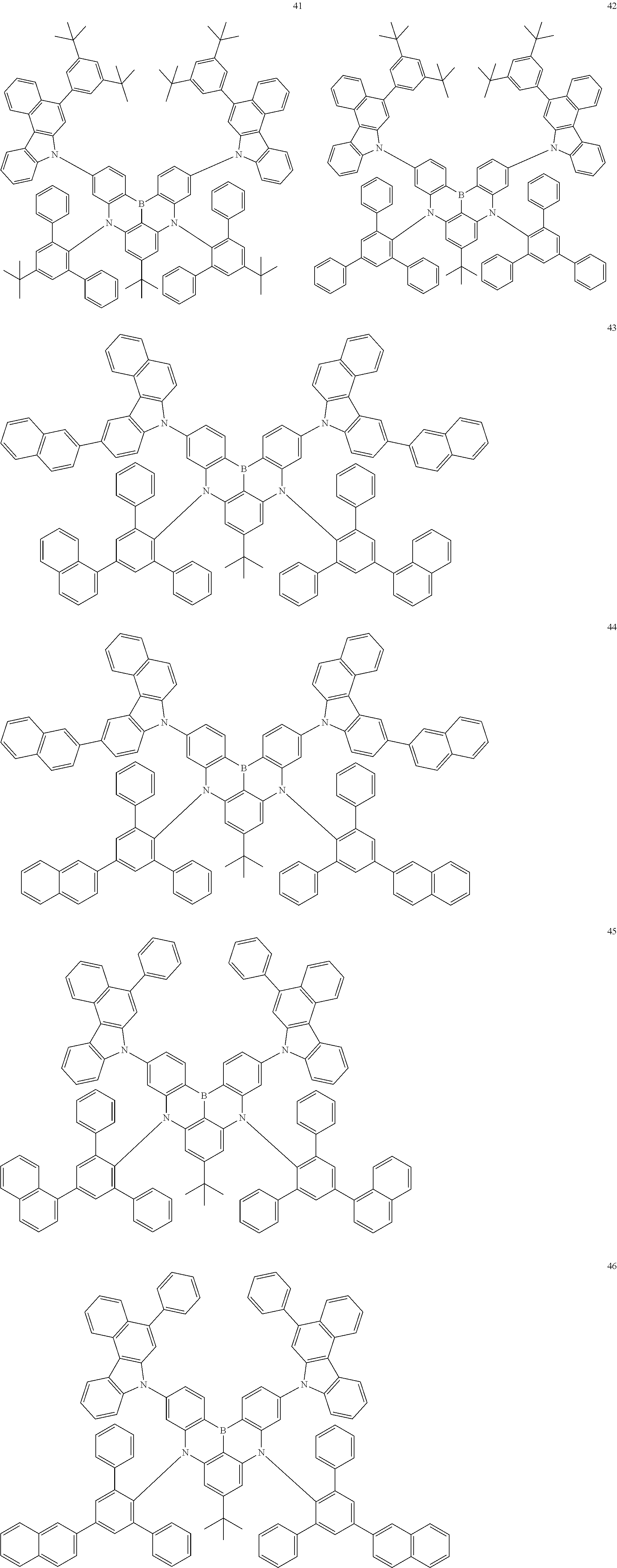 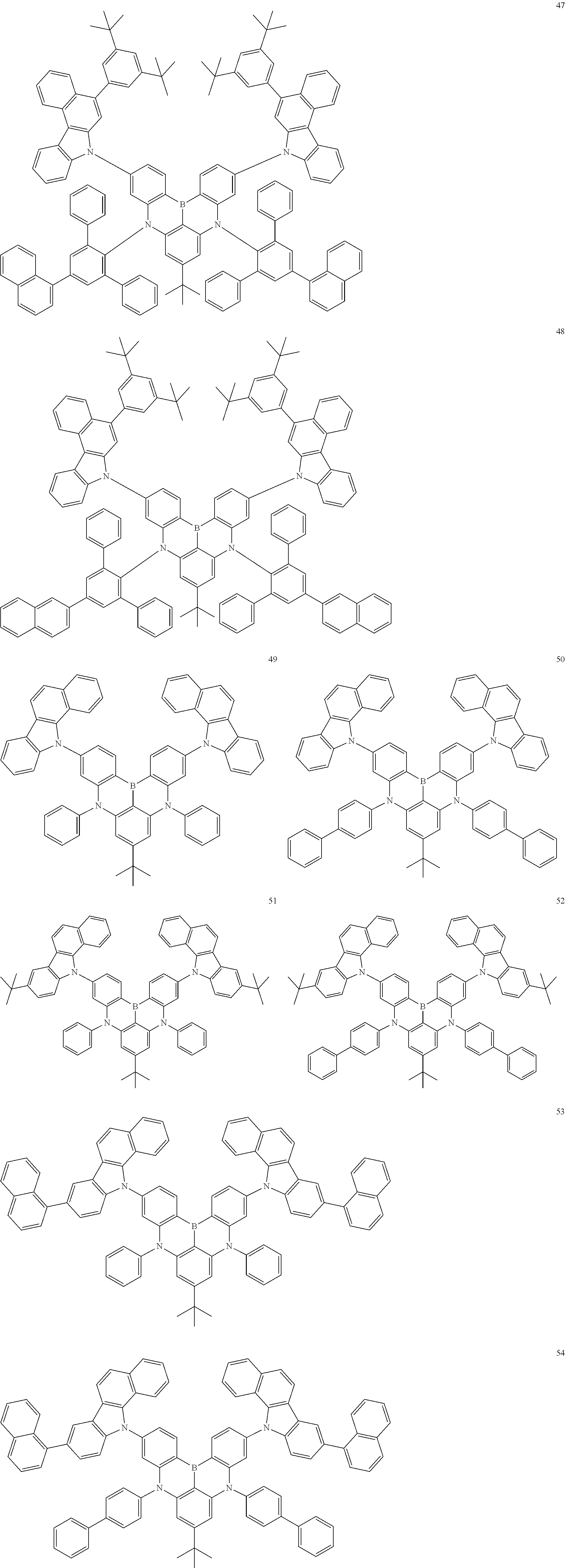 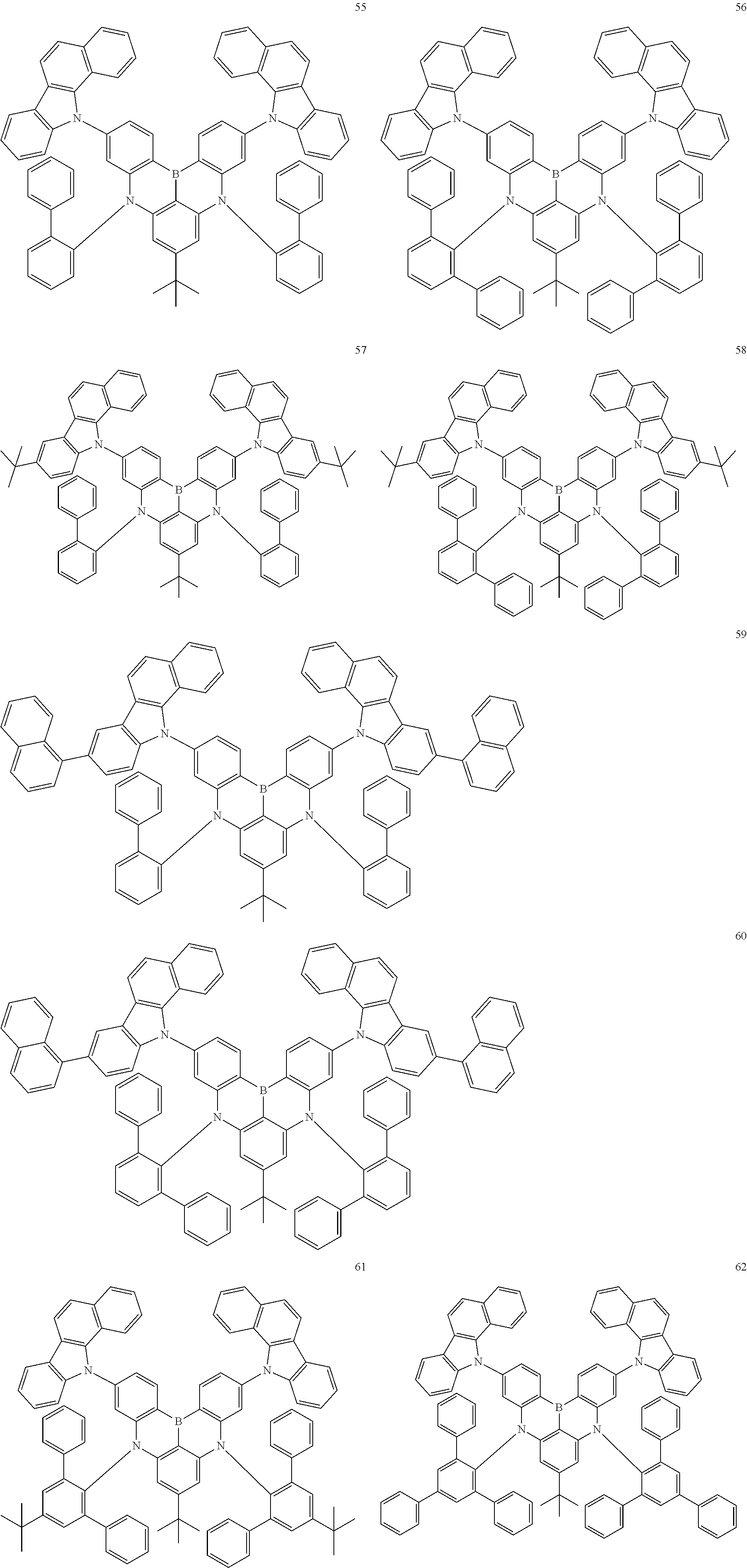 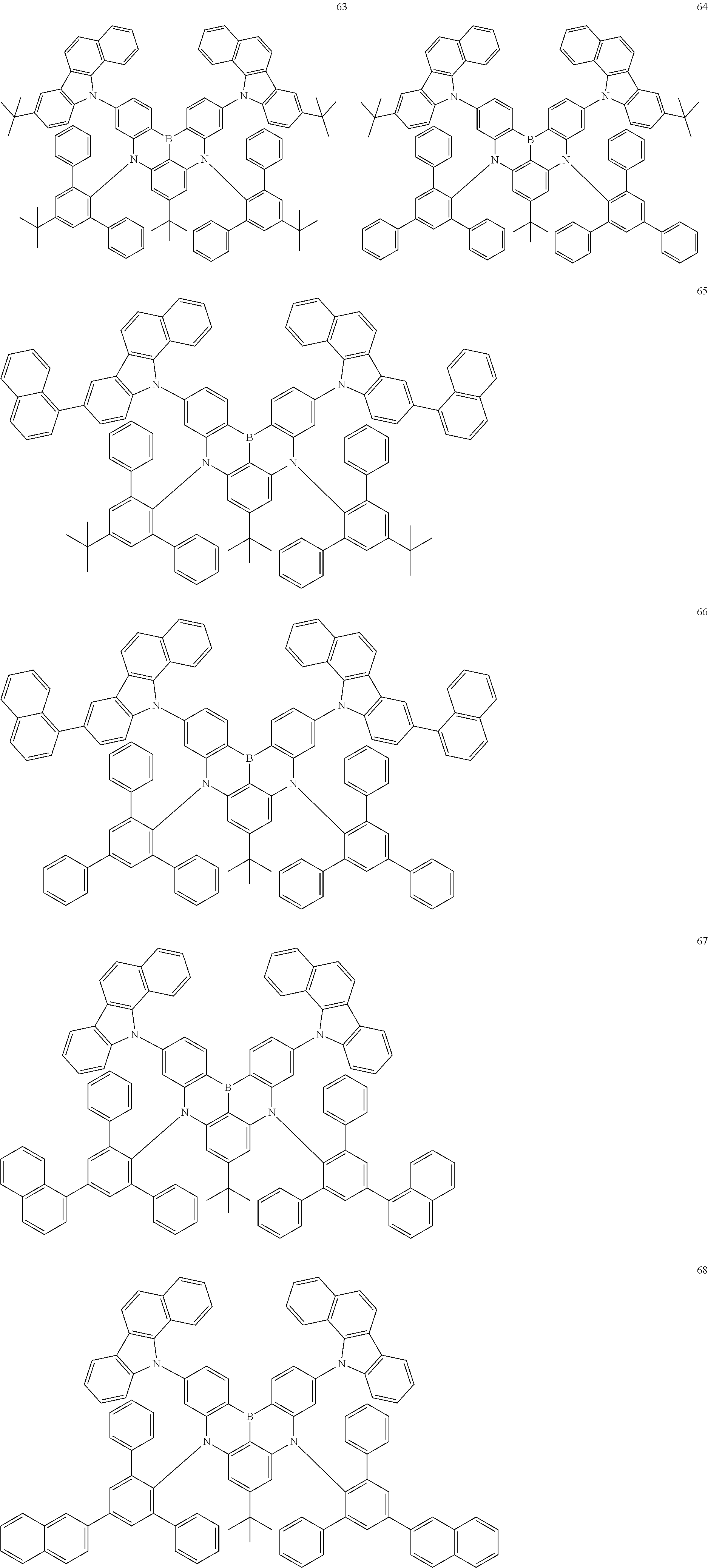 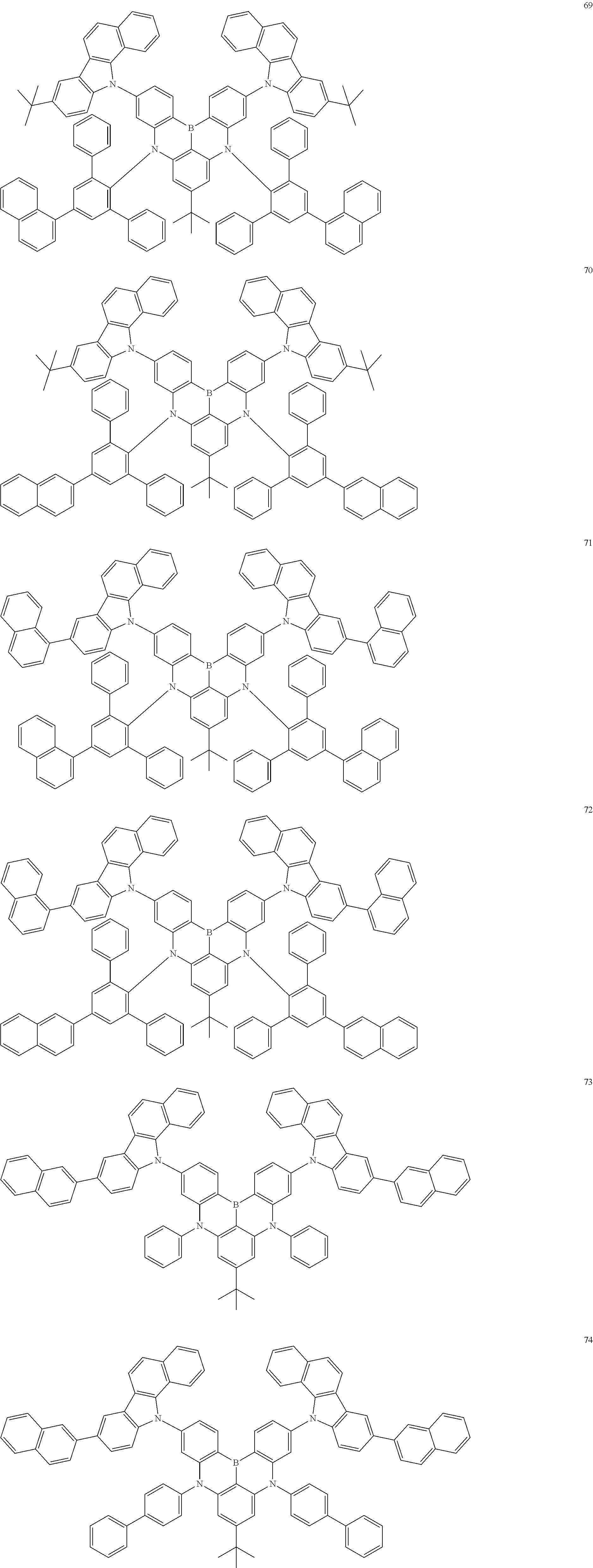 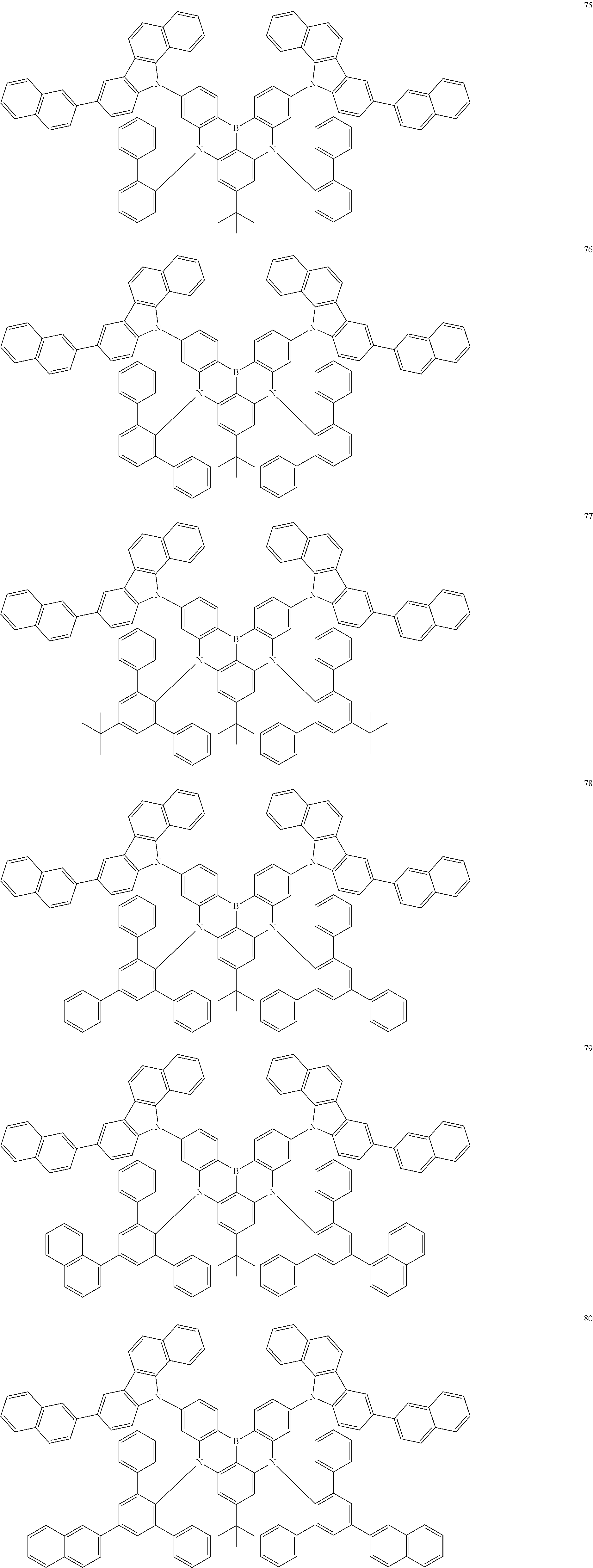 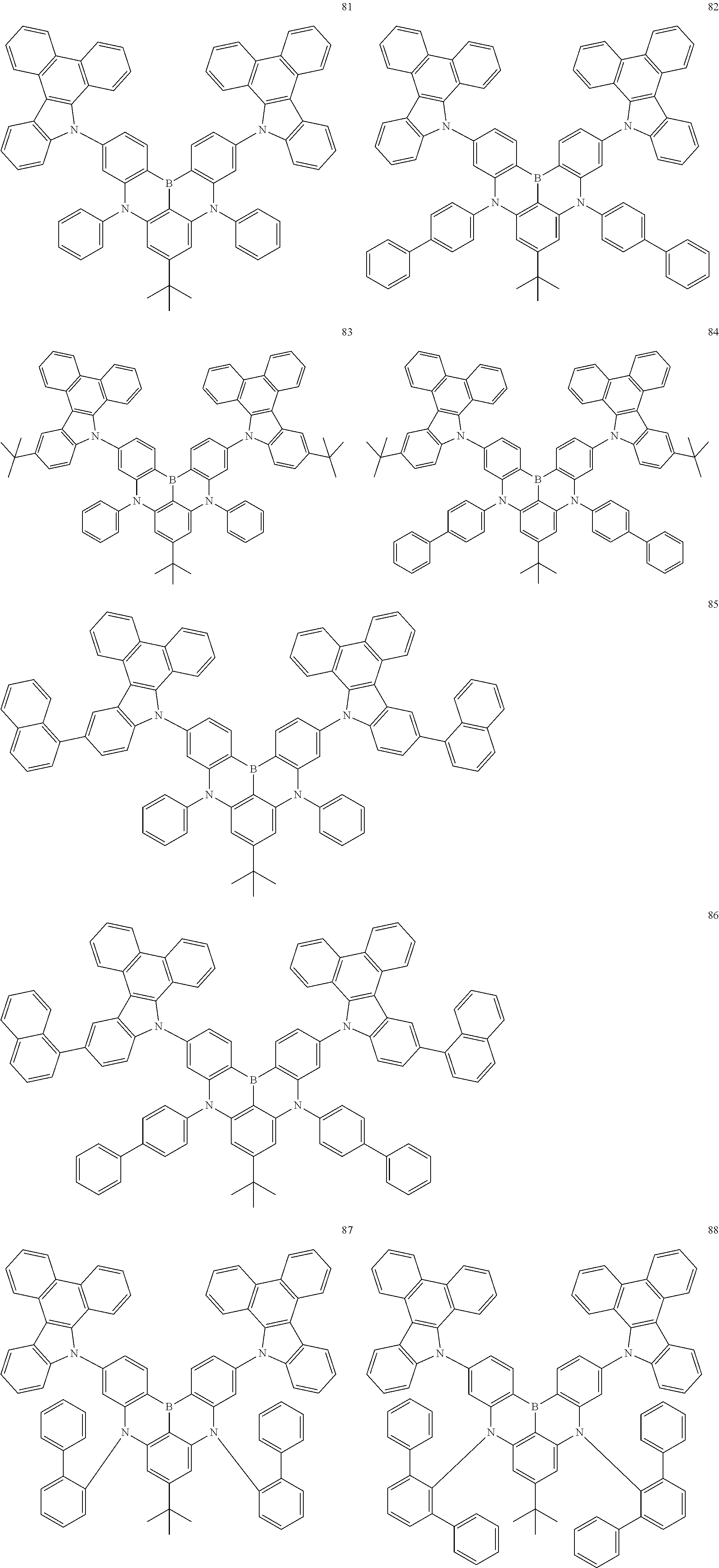 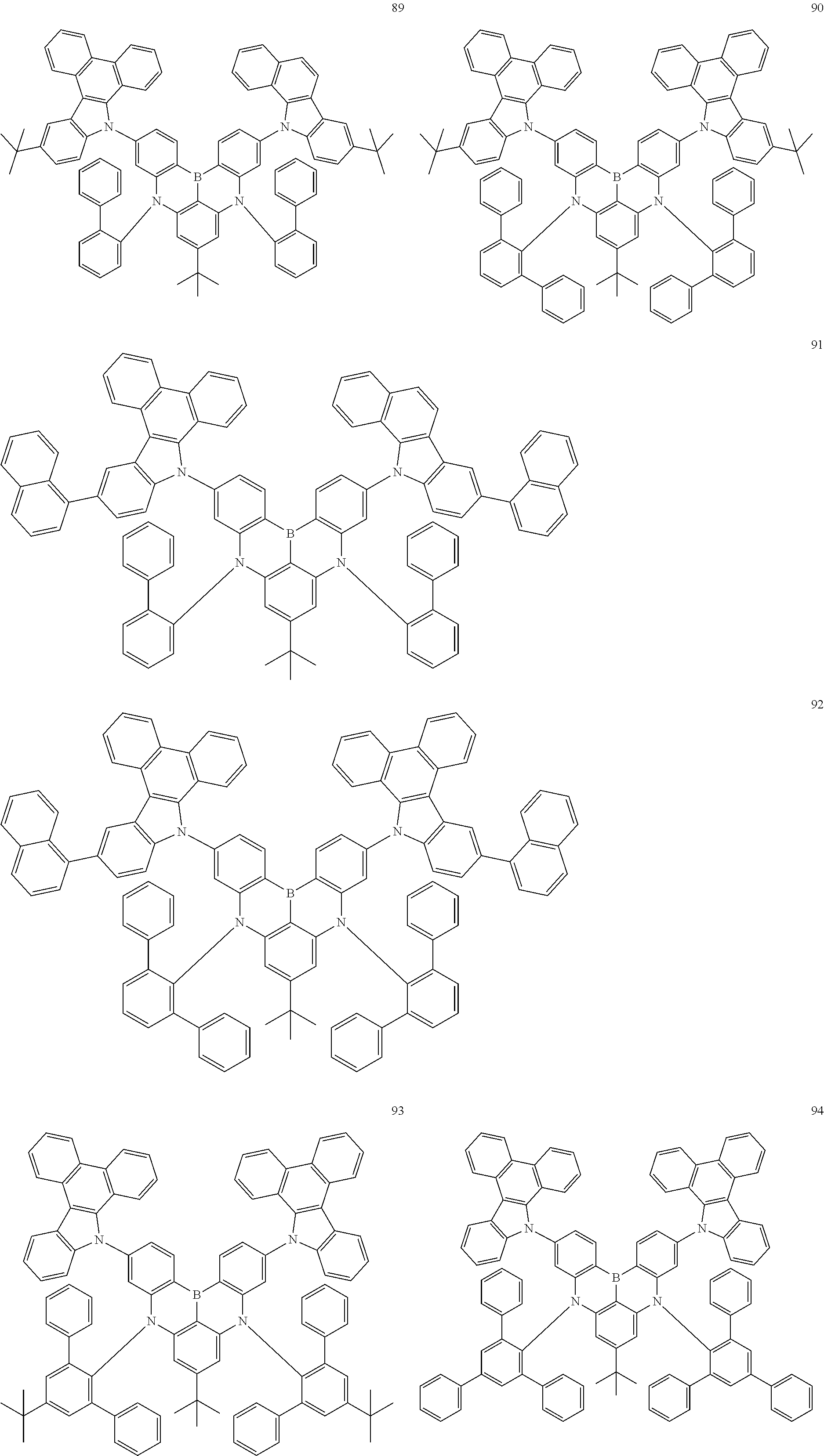 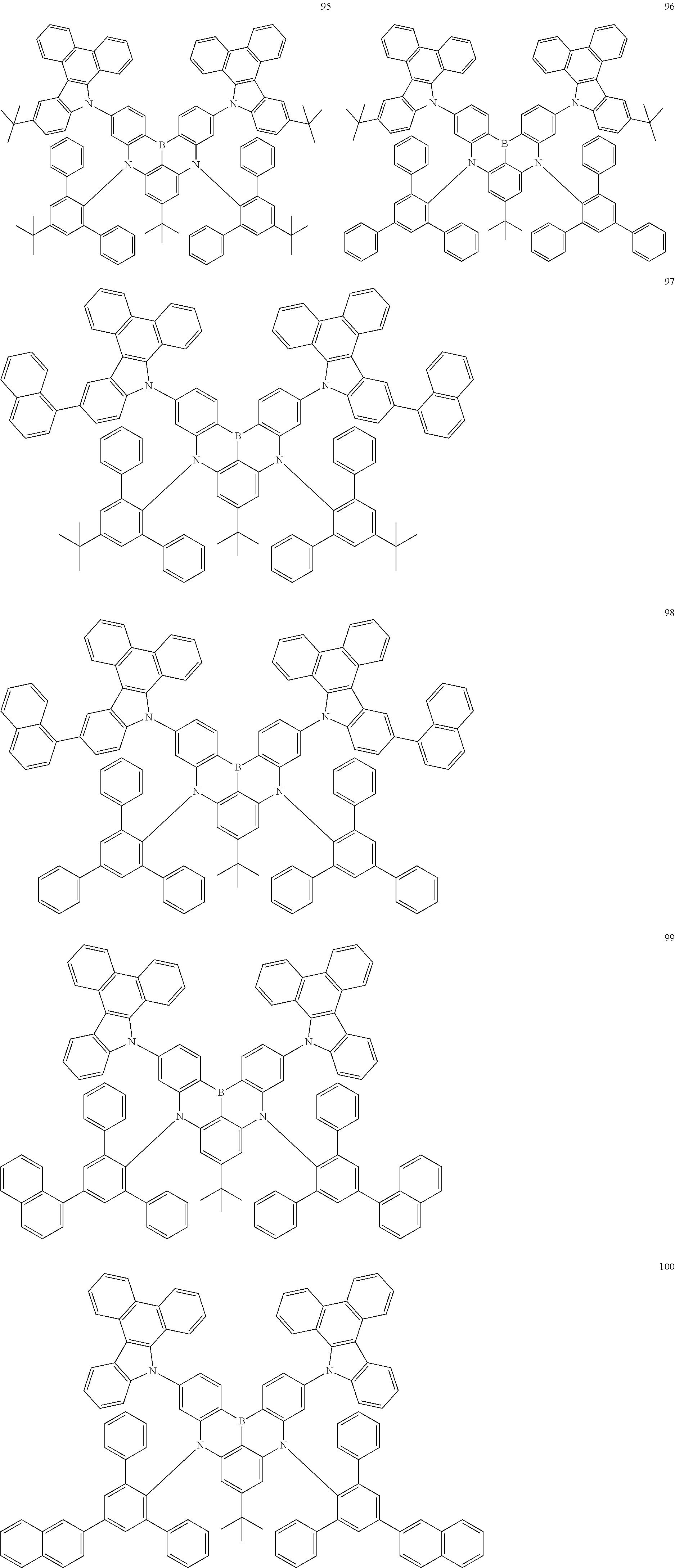 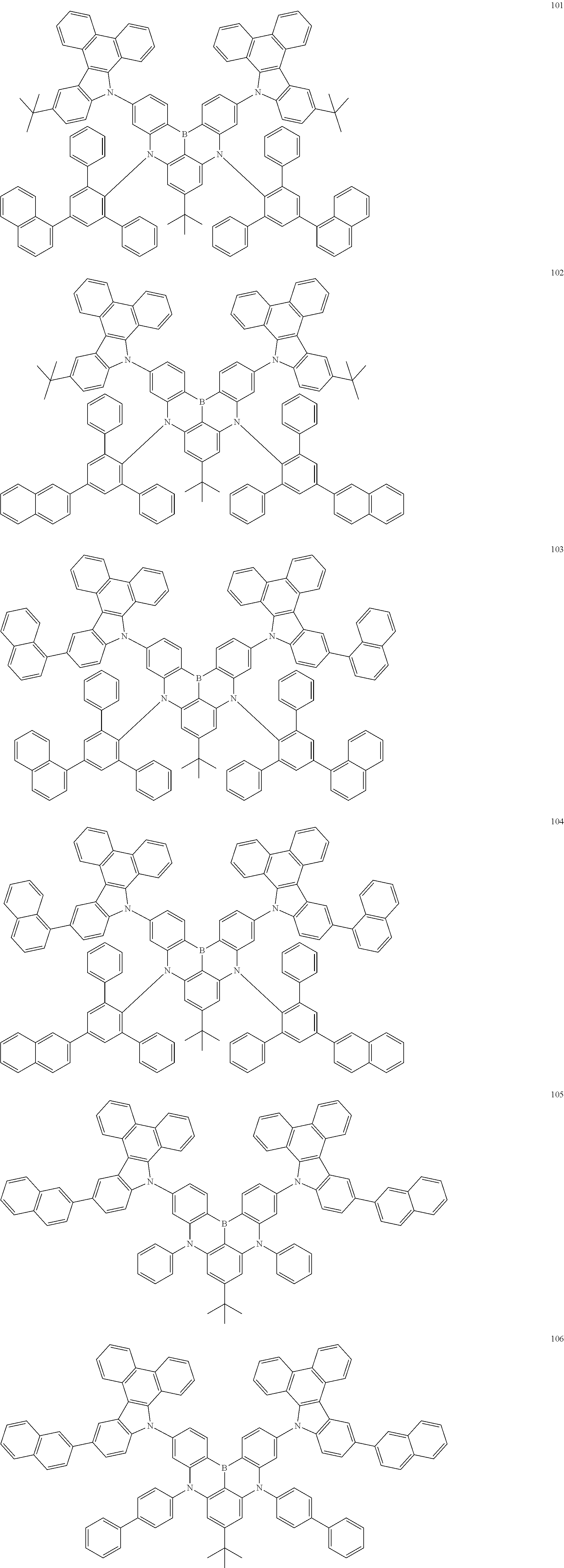 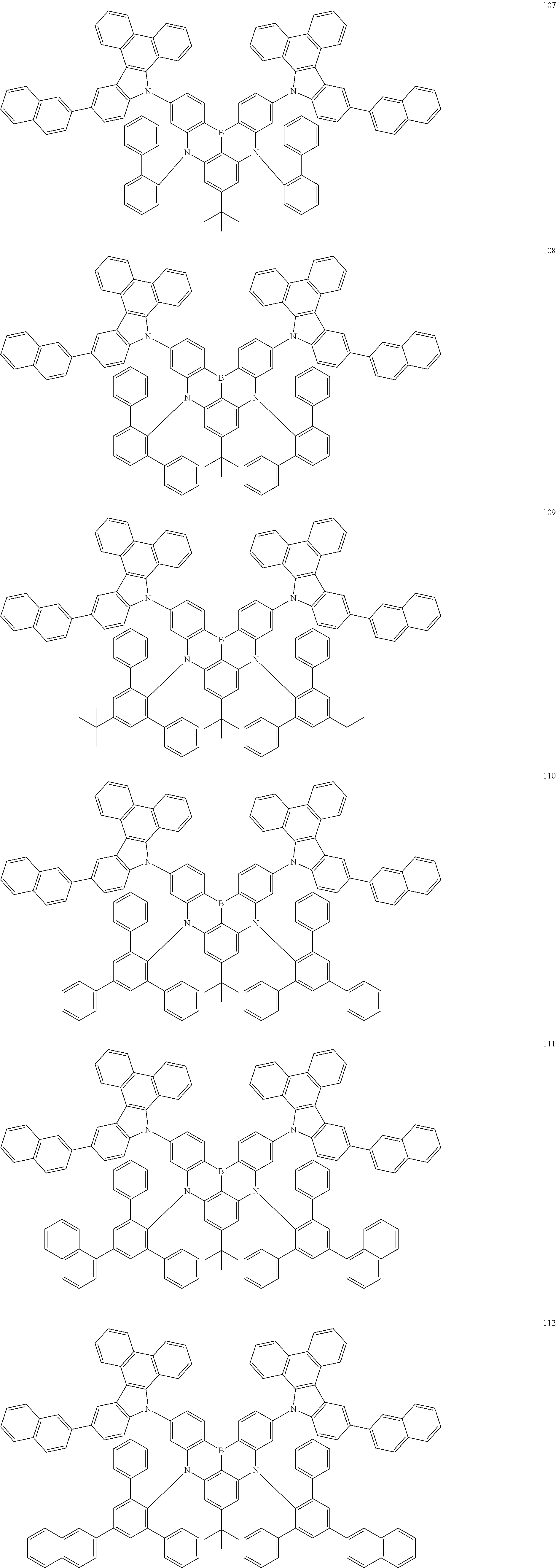 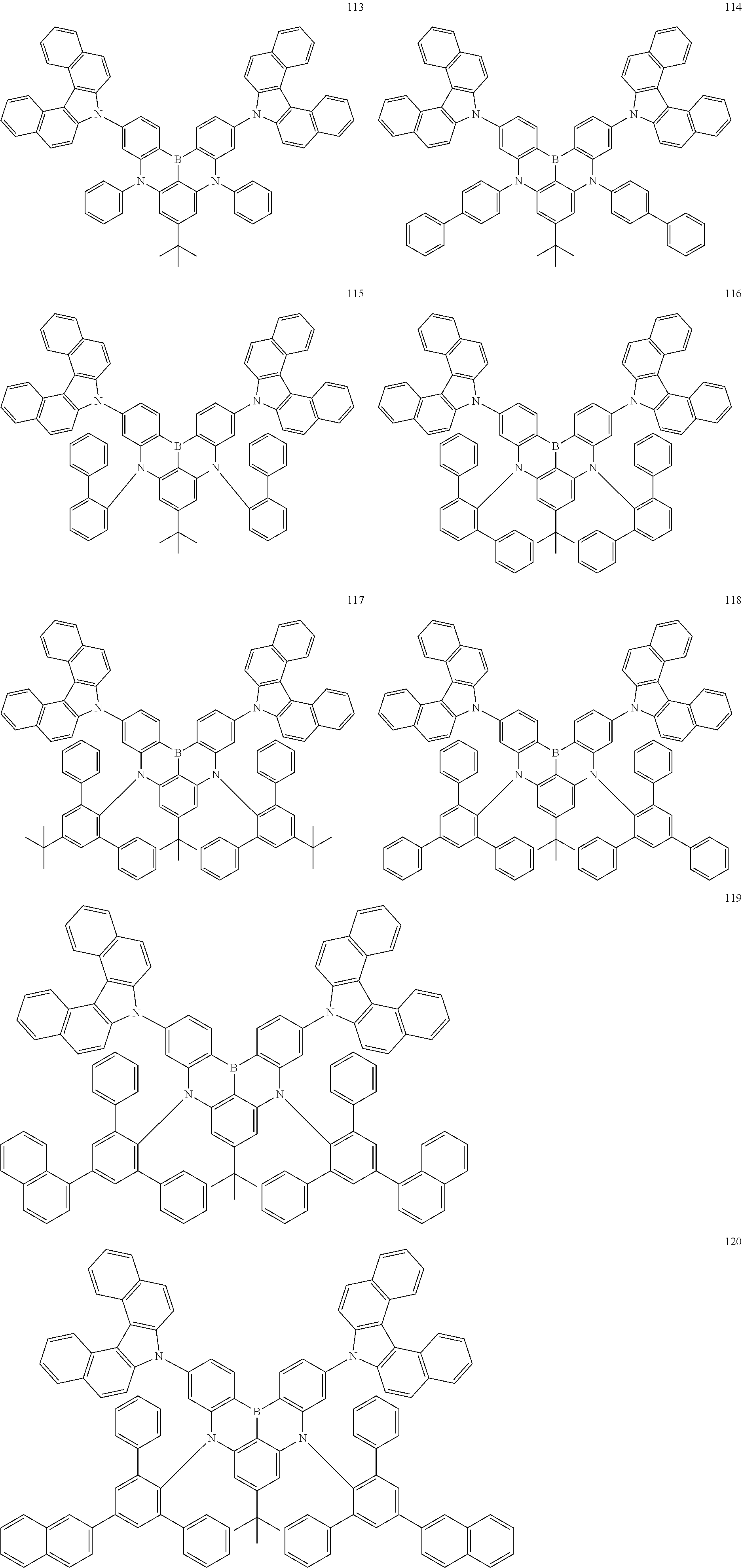 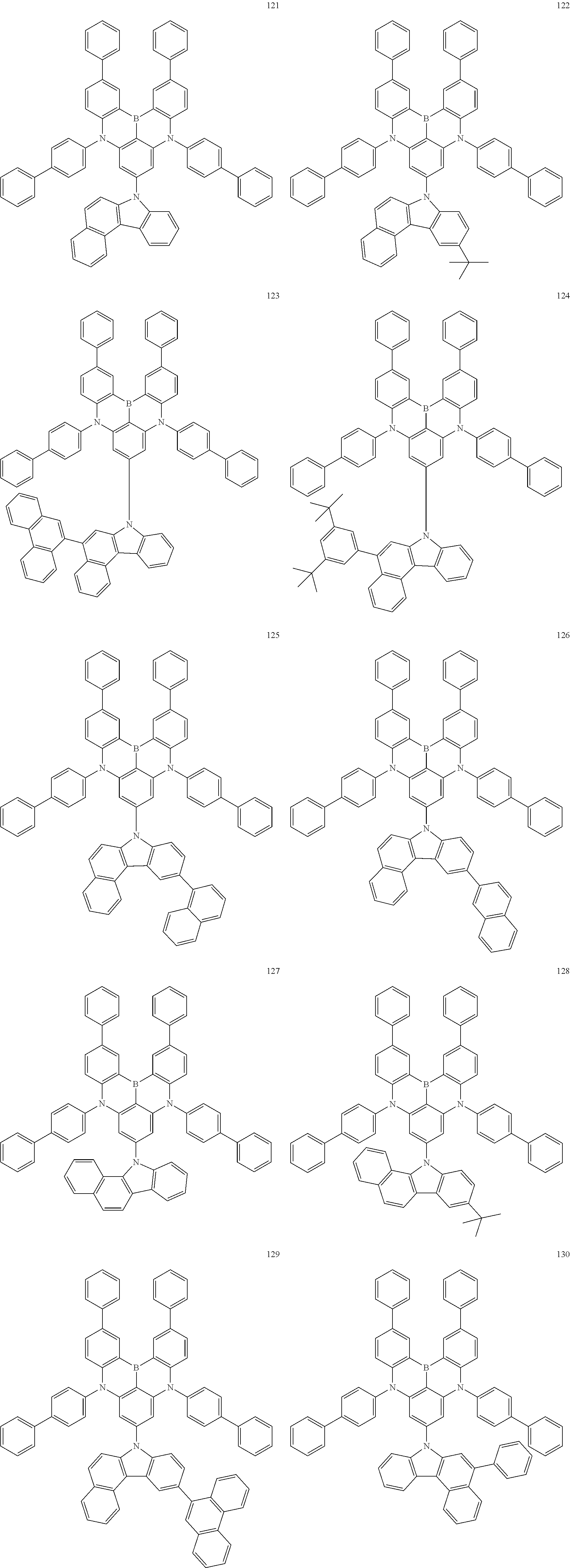 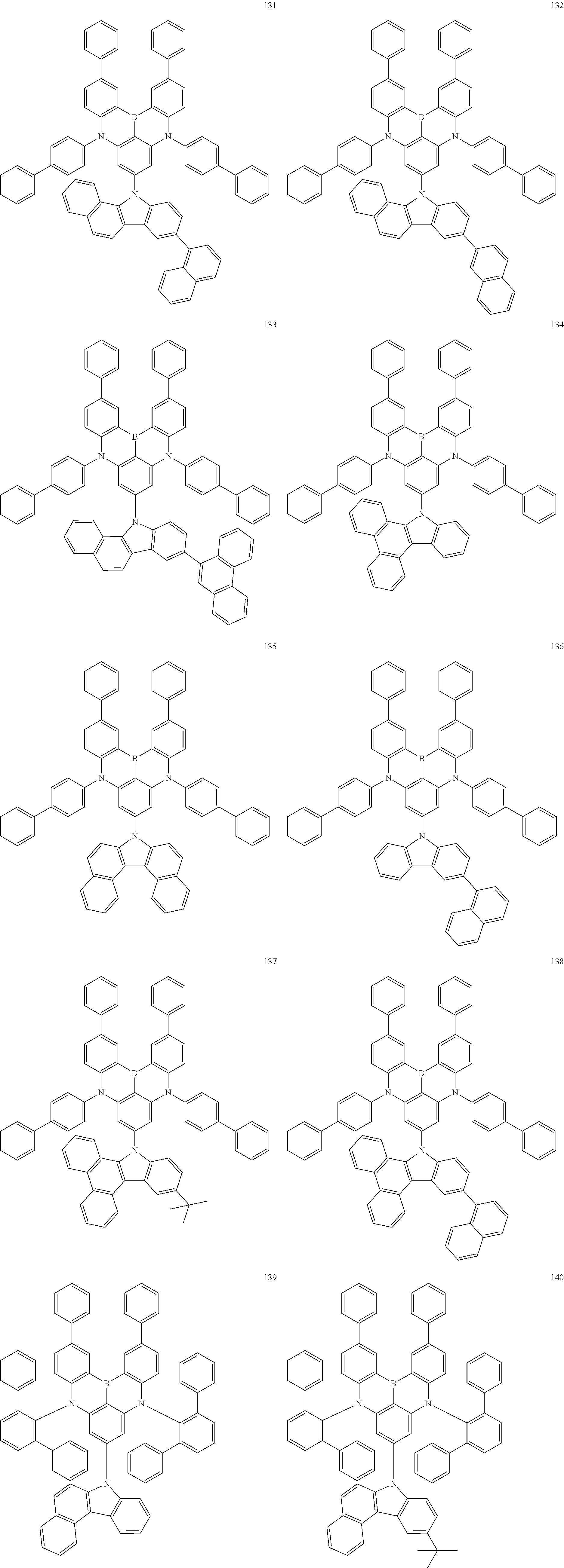 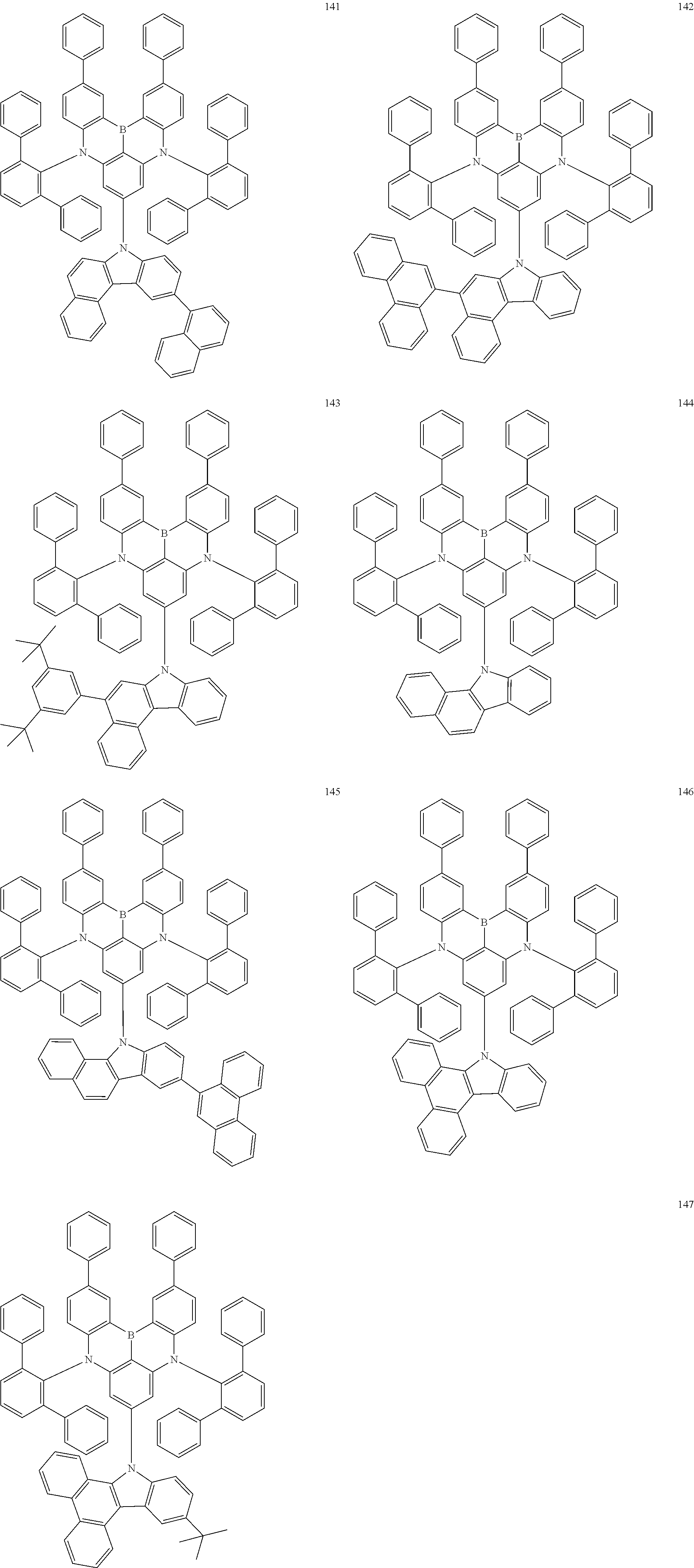 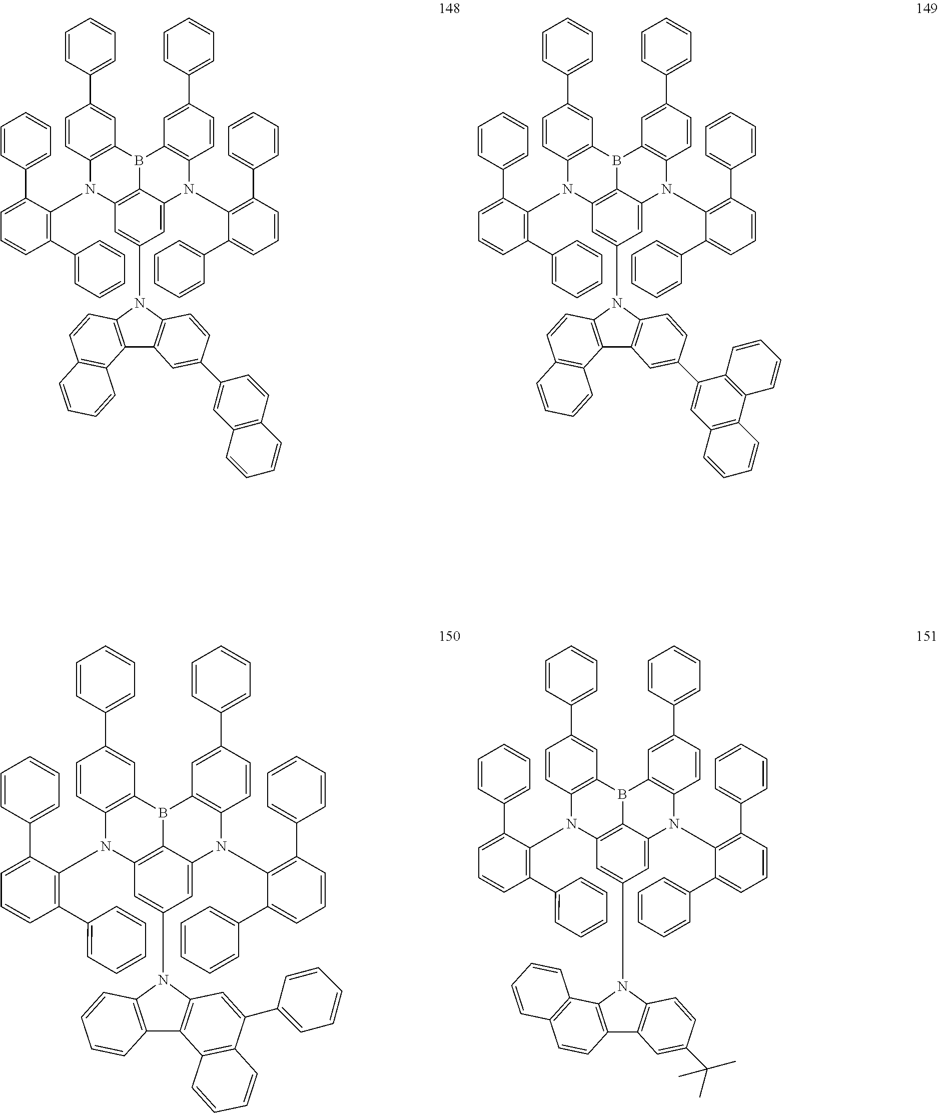 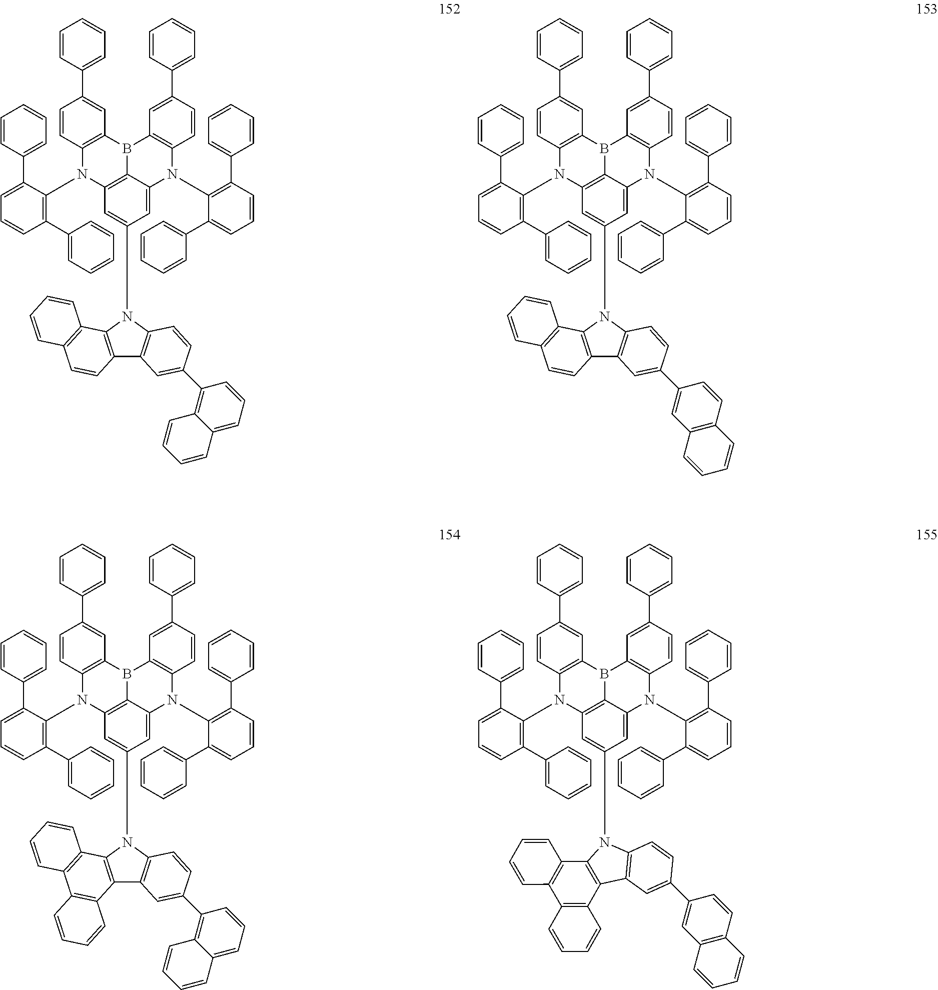 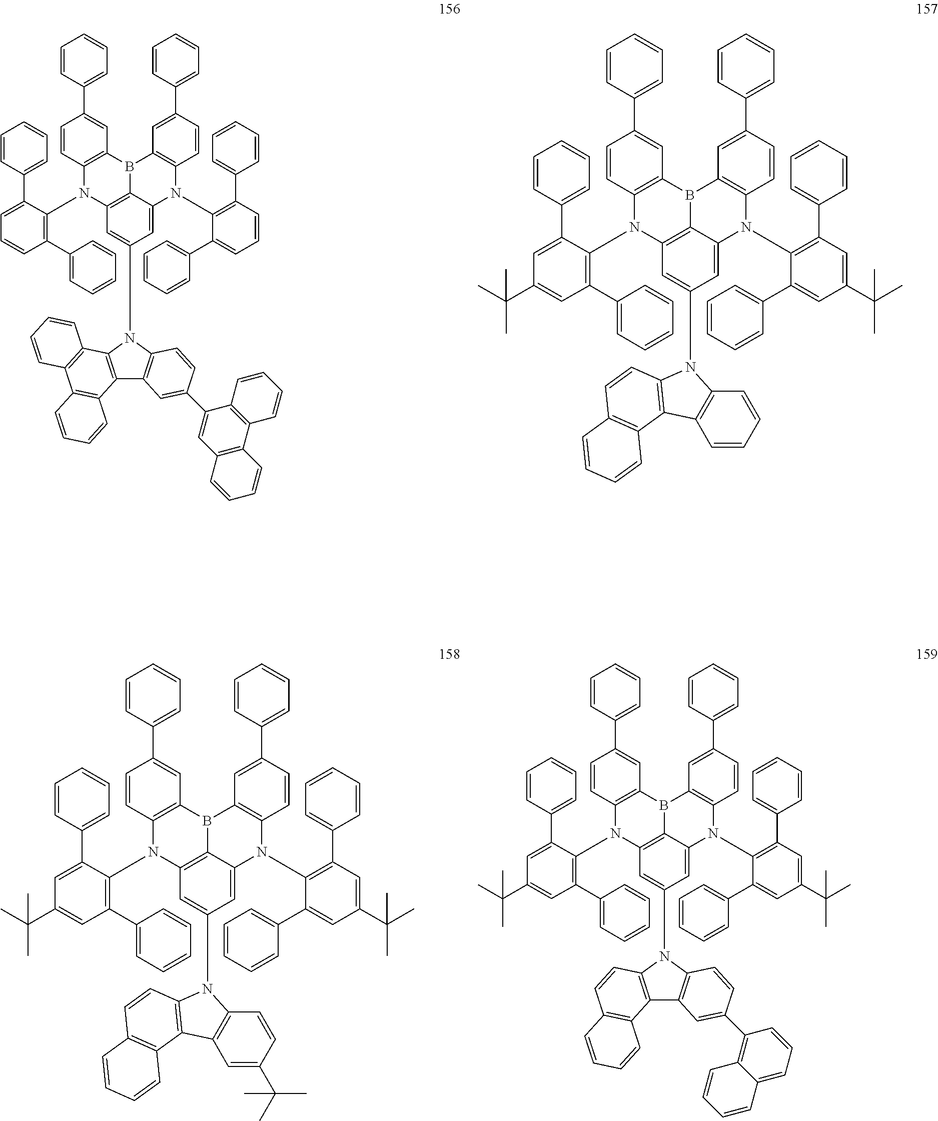 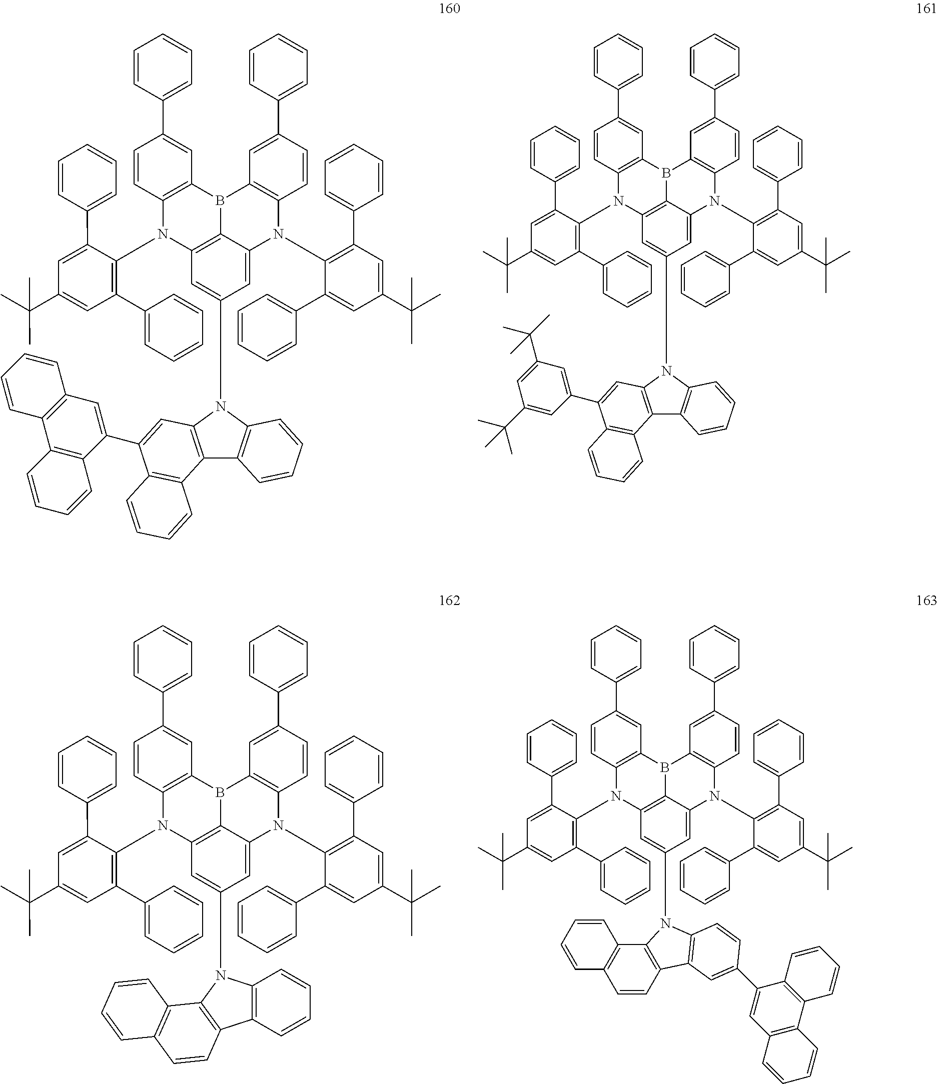 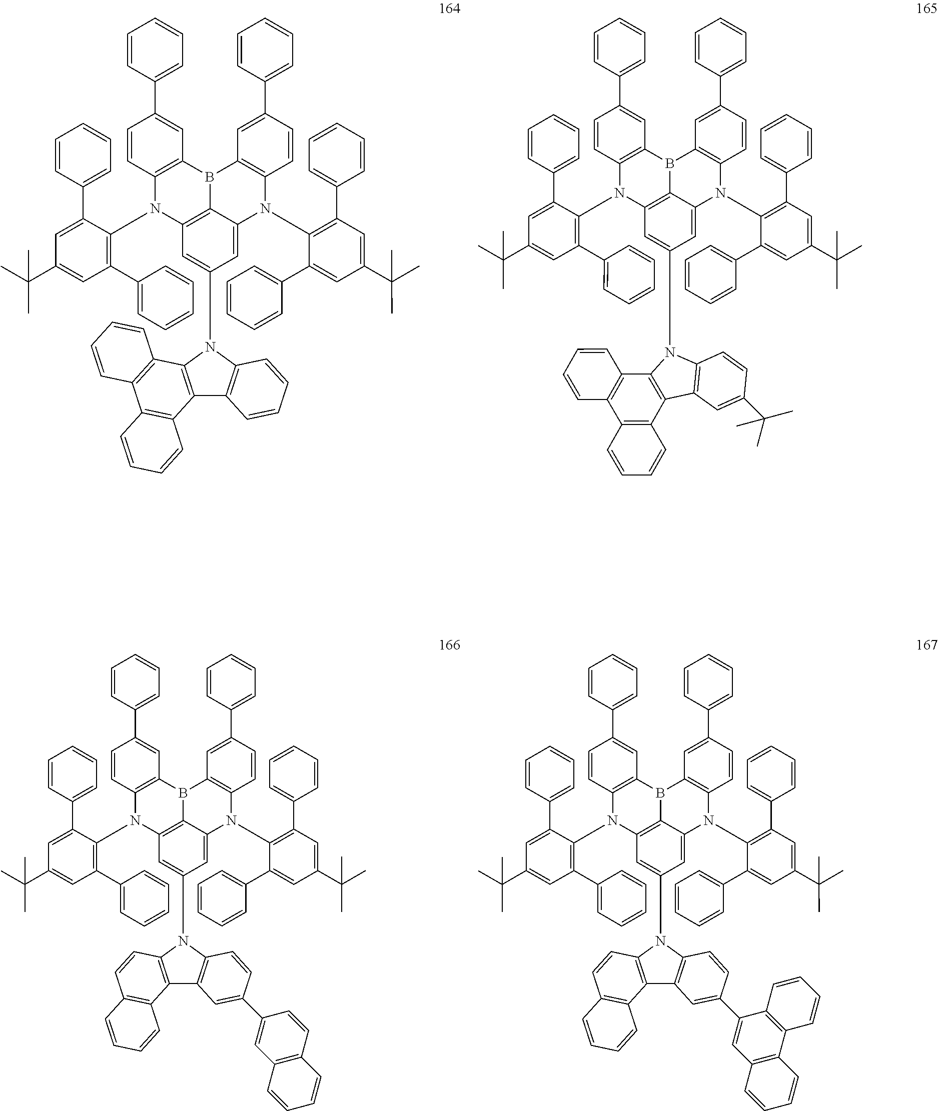 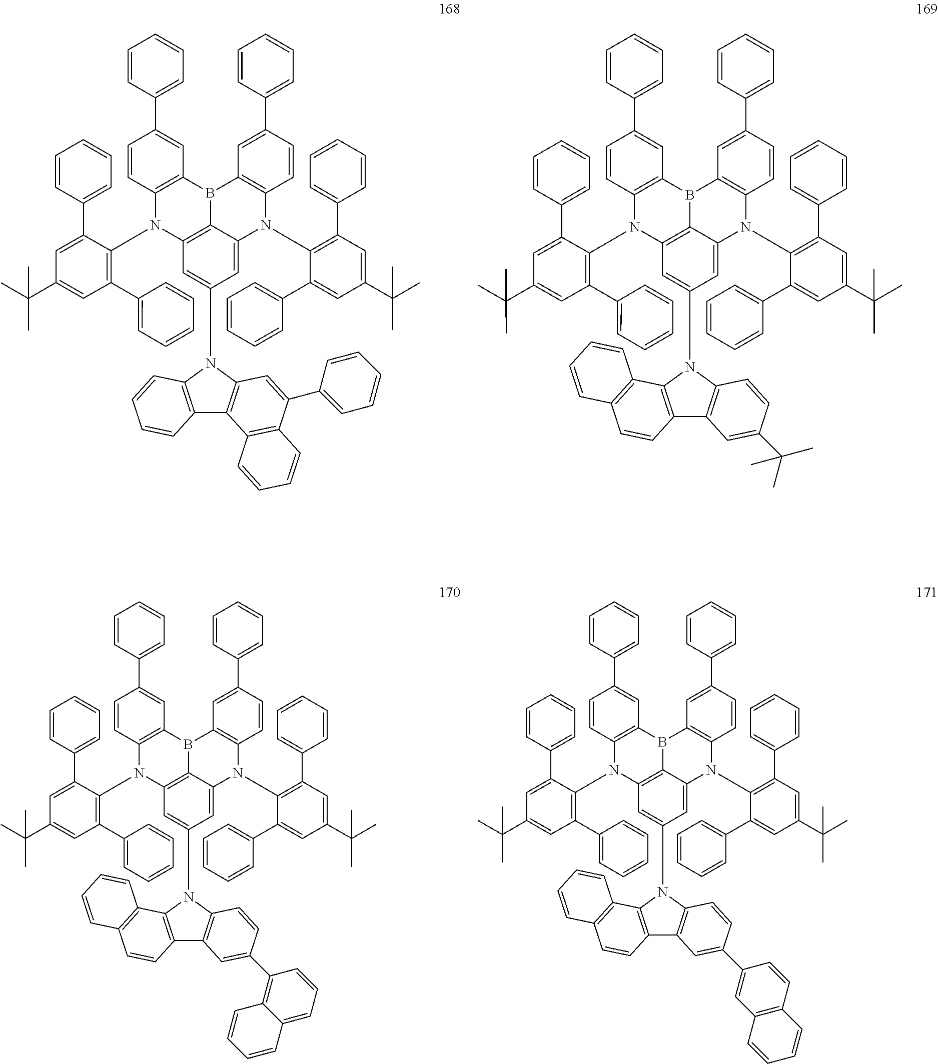 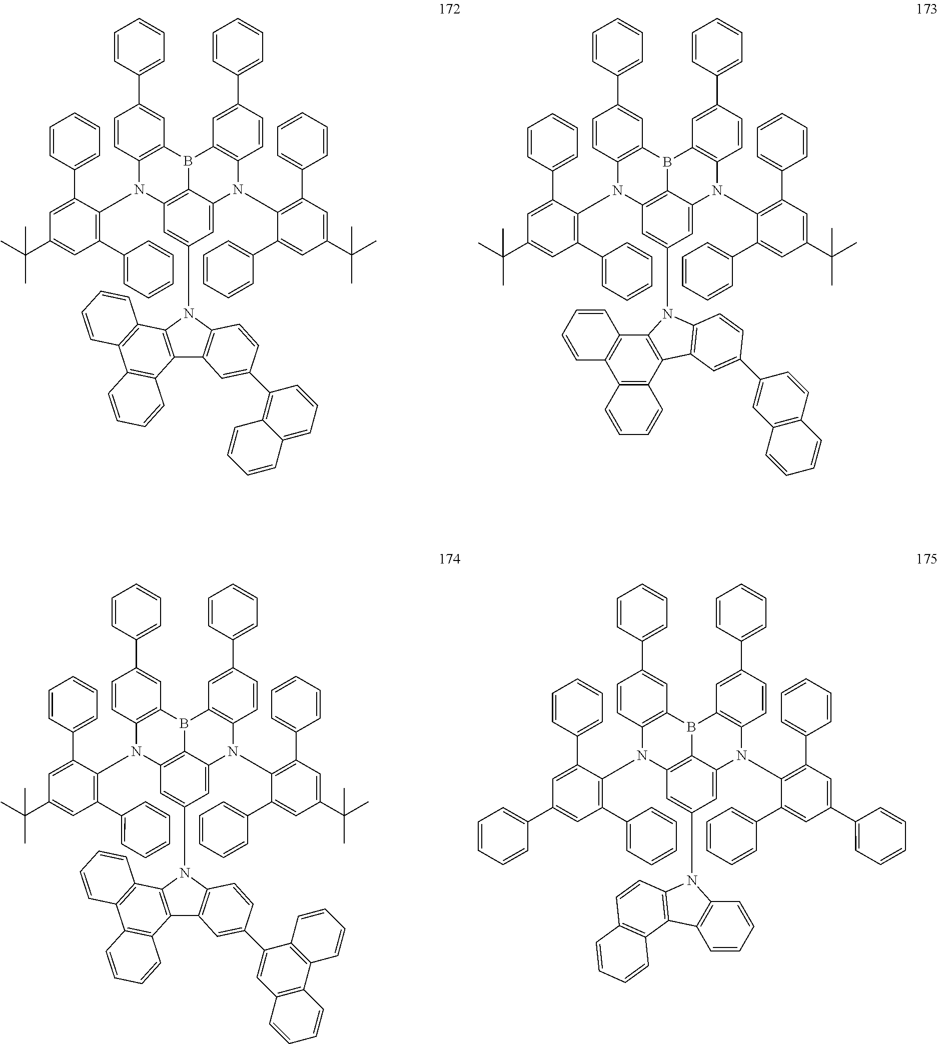 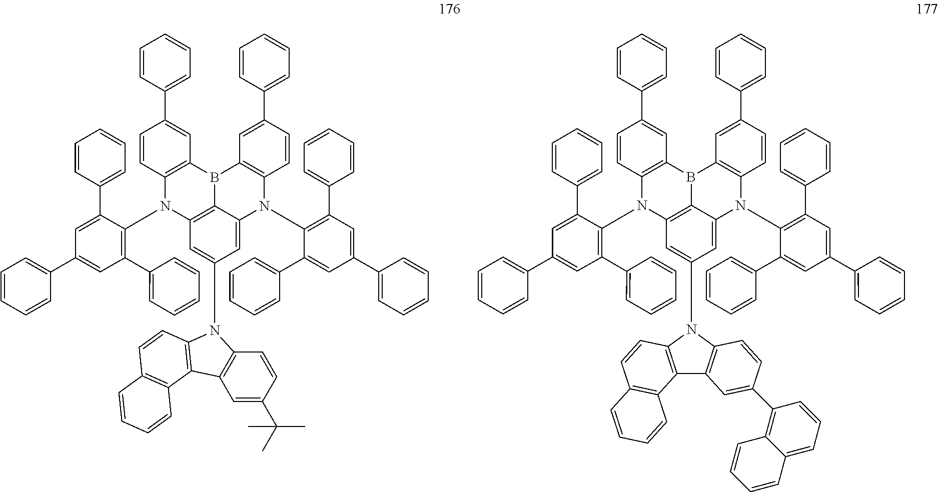 [SMILES: CC(C)(C)c1ccc2c(c1)c1c3ccccc3ccc1n2-c1cc2c3c(c1)N(c1c(-c4ccccc4)cc(-c4ccccc4)cc1-c1ccccc1)c1ccc(-c4ccccc4)cc1B3c1cc(-c3ccccc3)ccc1N2c1c(-c2ccccc2)cc(-c2ccccc2)cc1-c1ccccc1 ; c1ccc(-c2ccc3c(c2)B2c4cc(-c5ccccc5)ccc4N(c4c(-c5ccccc5)cc(-c5ccccc5)cc4-c4ccccc4)c4cc(-n5c6ccc(-c7cccc8ccccc78)cc6c6c7ccccc7ccc65)cc(c42)N3c2c(-c3ccccc3)cc(-c3ccccc3)cc2-c2ccccc2)cc1] 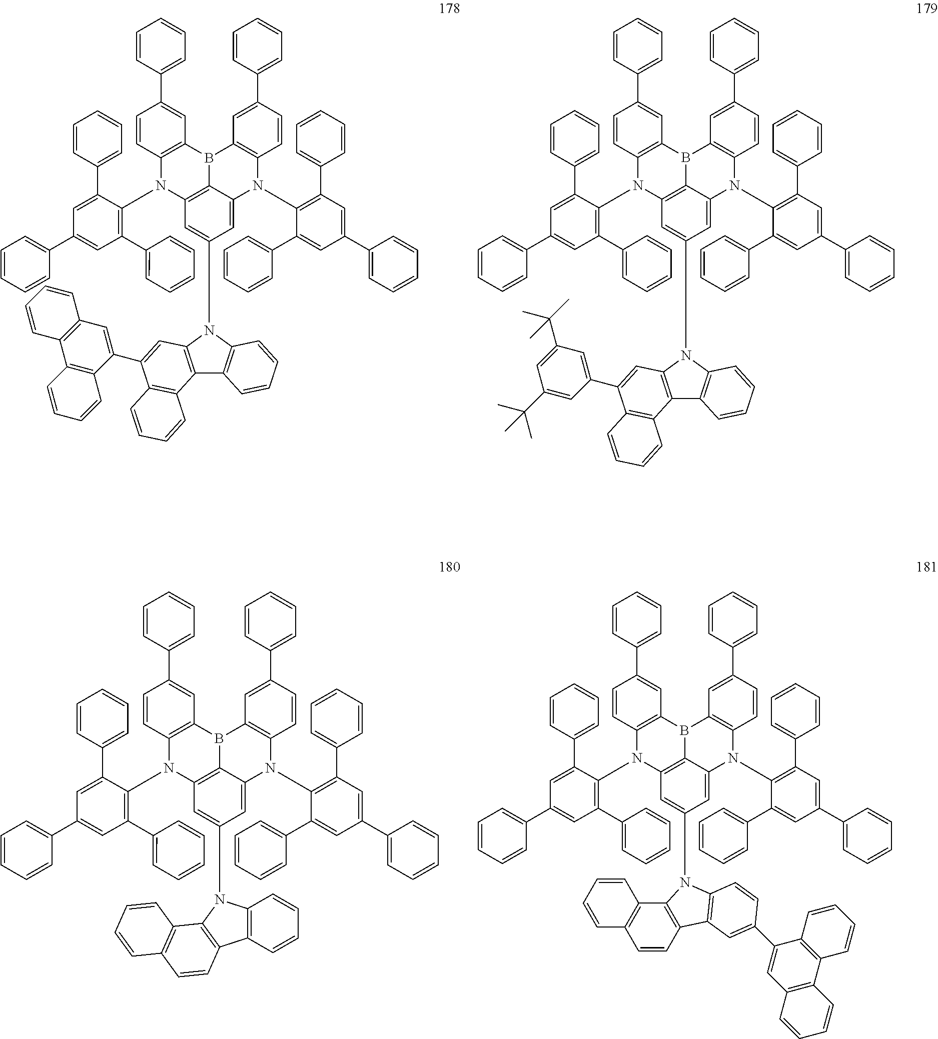 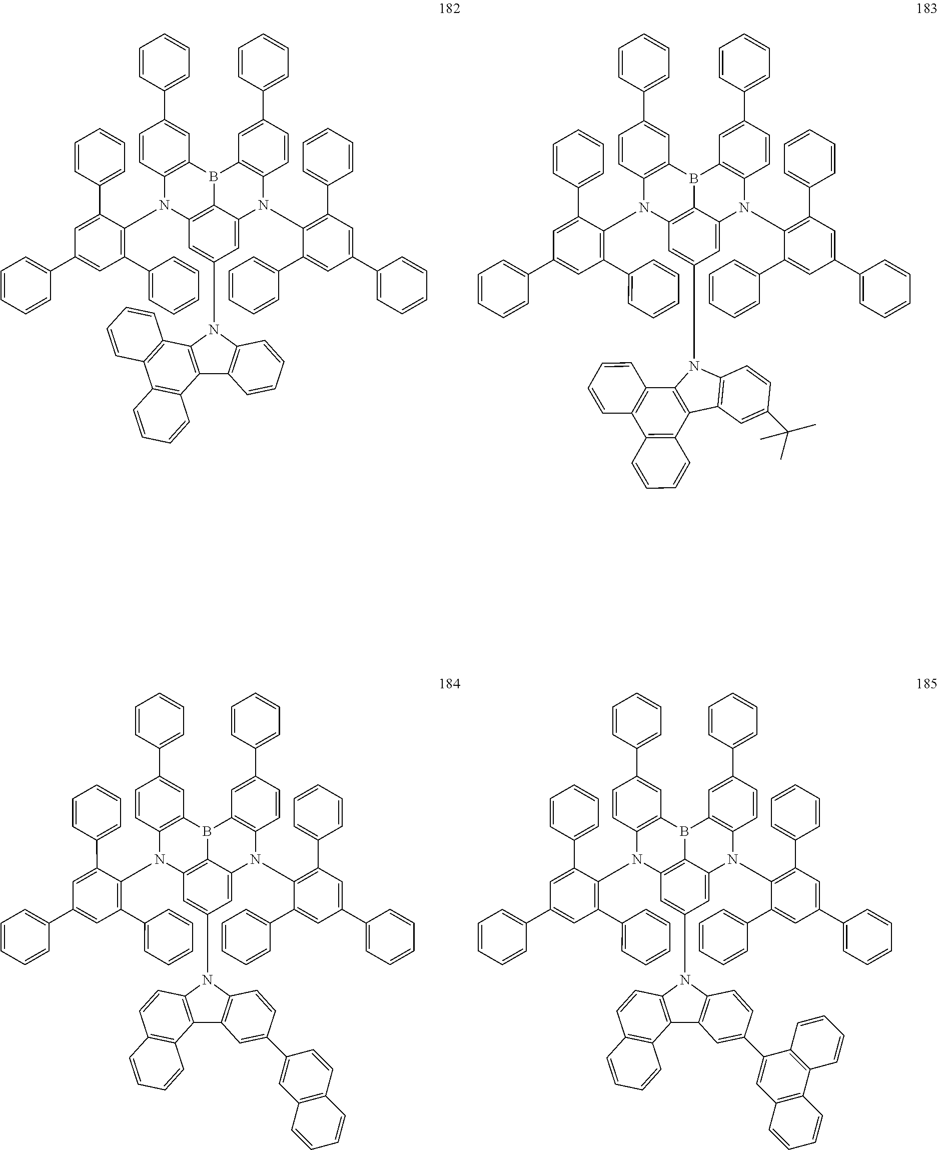 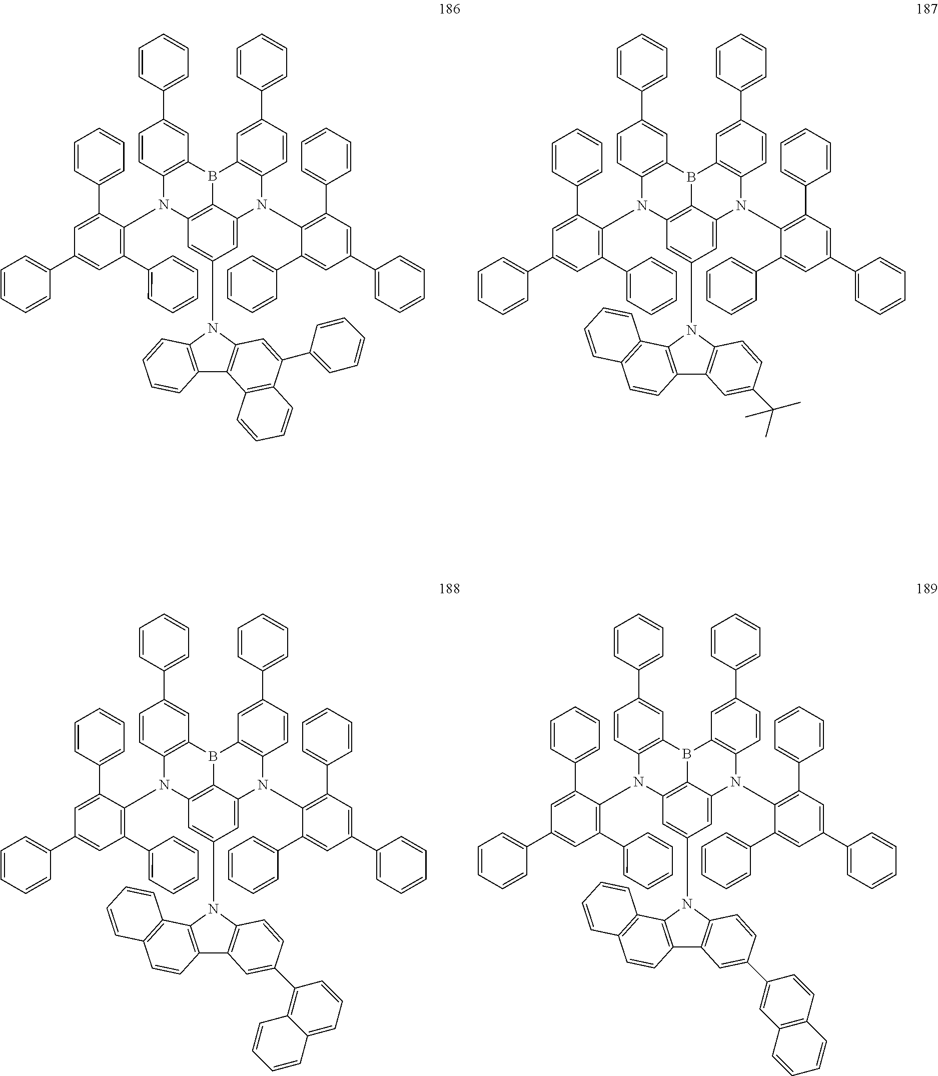 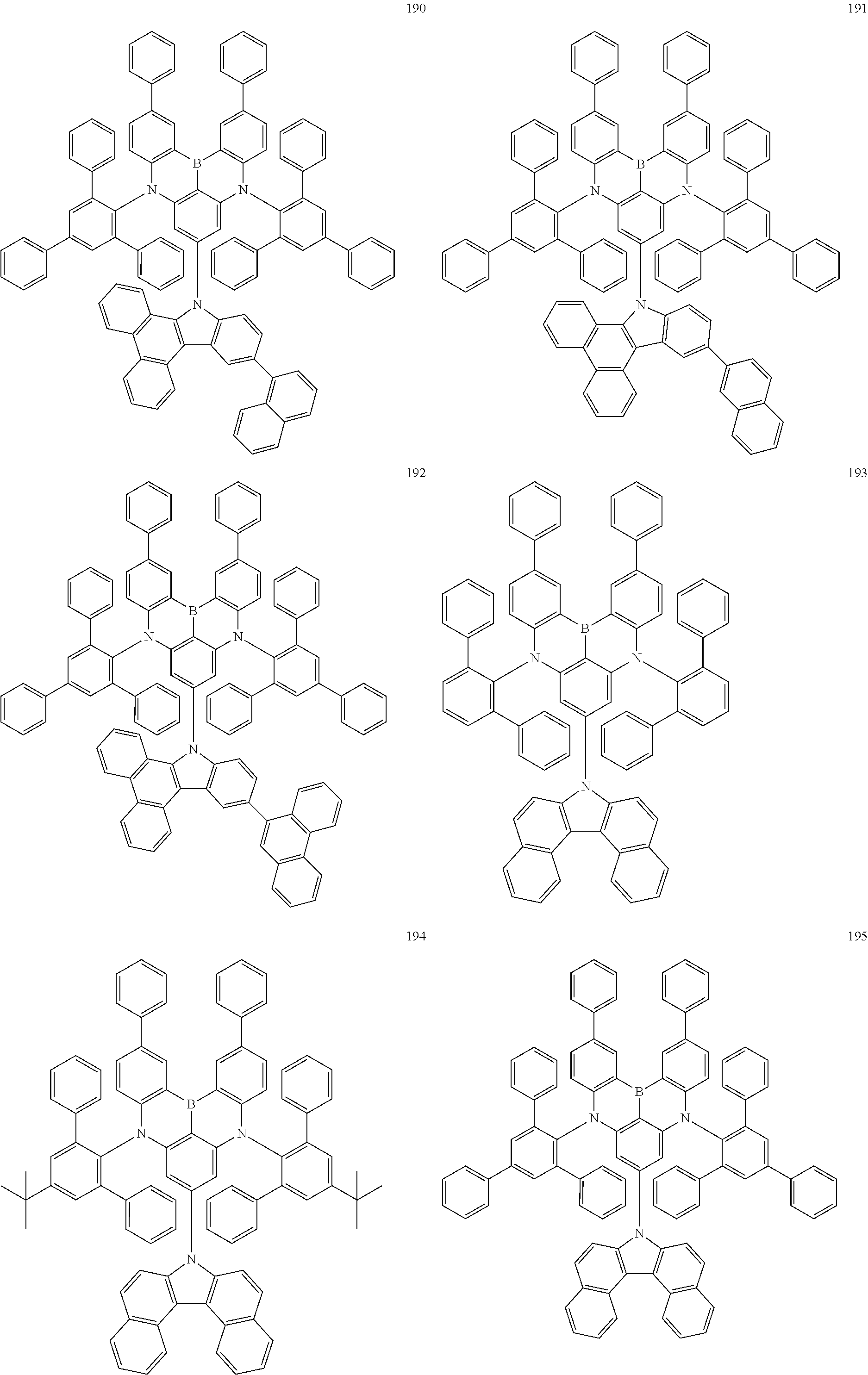 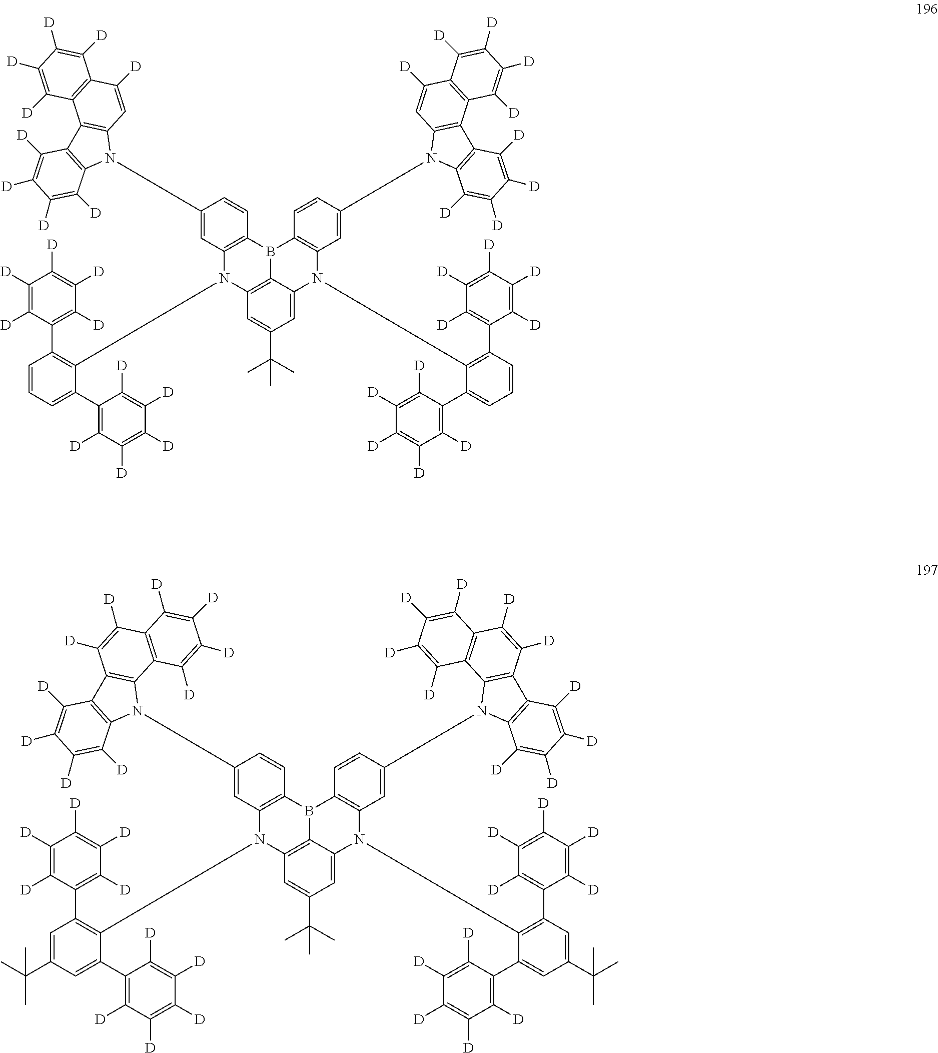 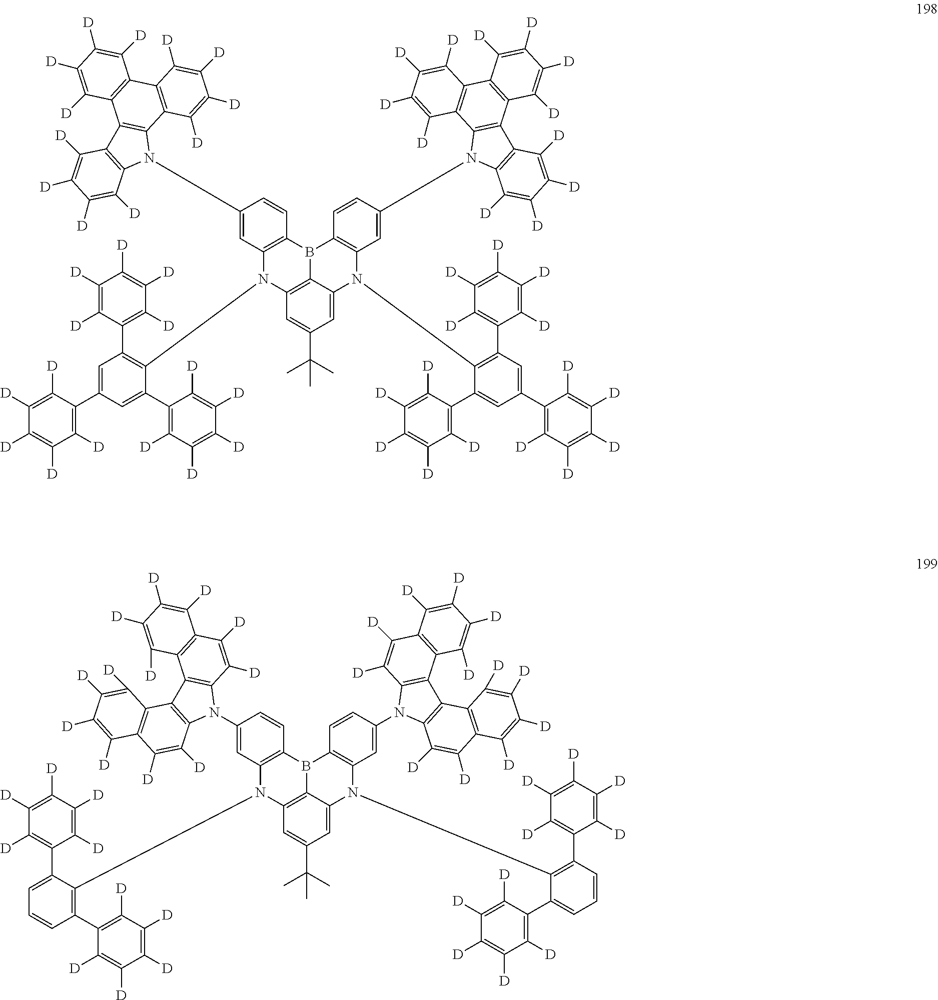 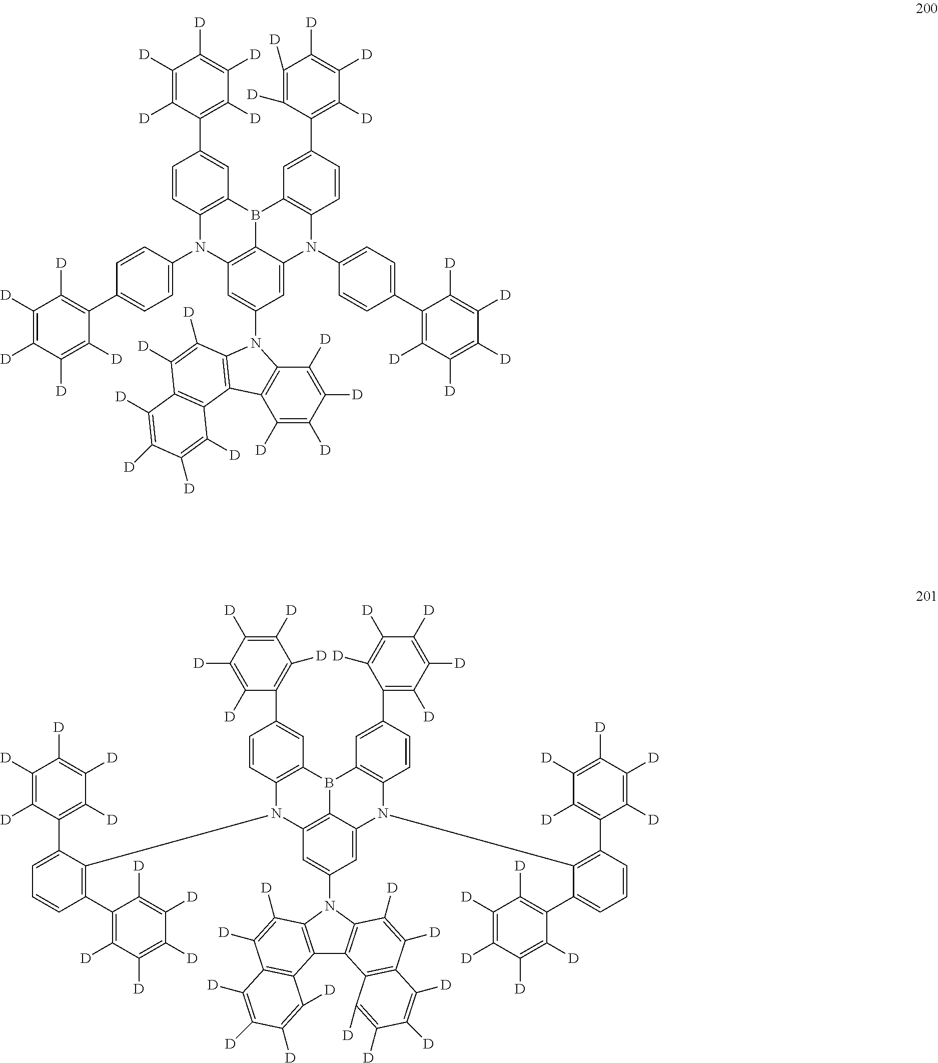 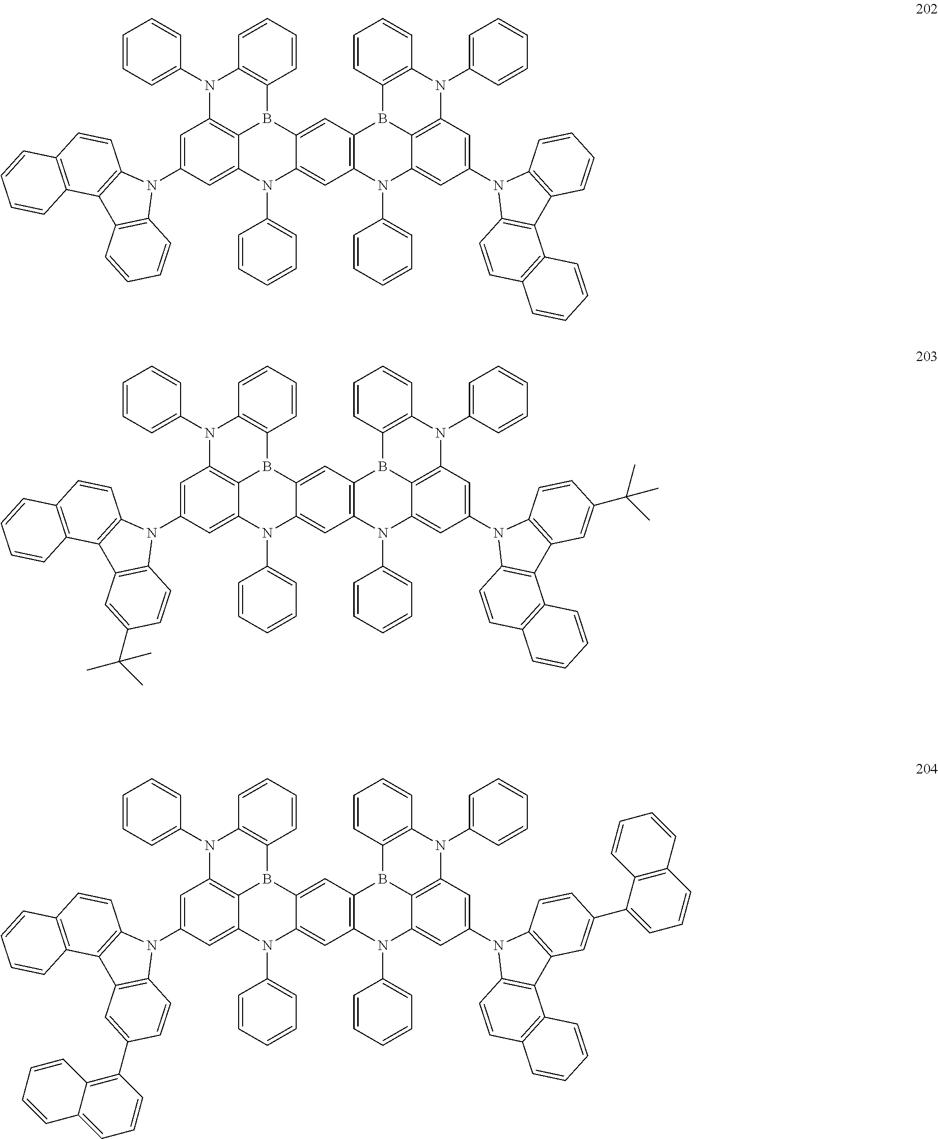 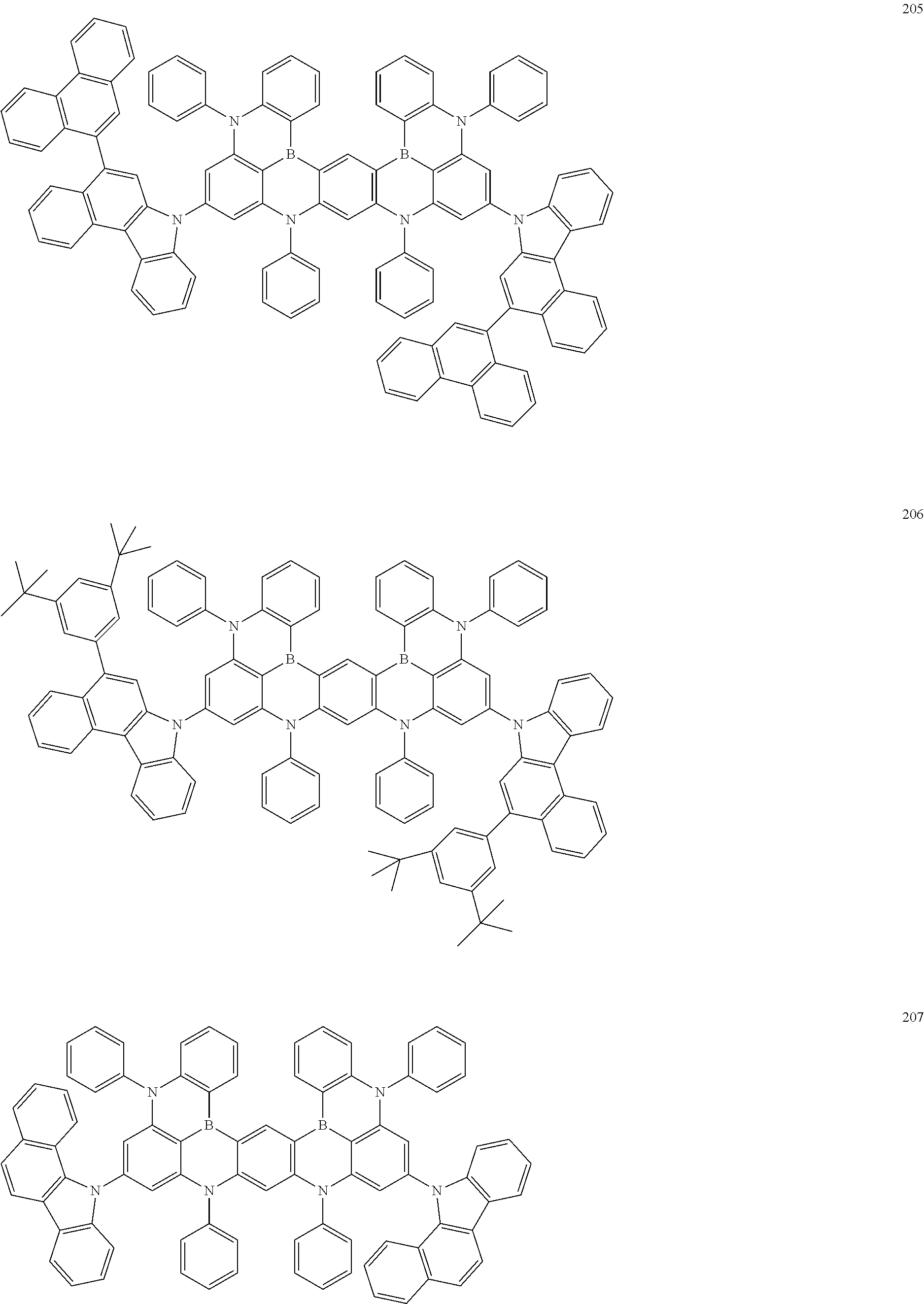 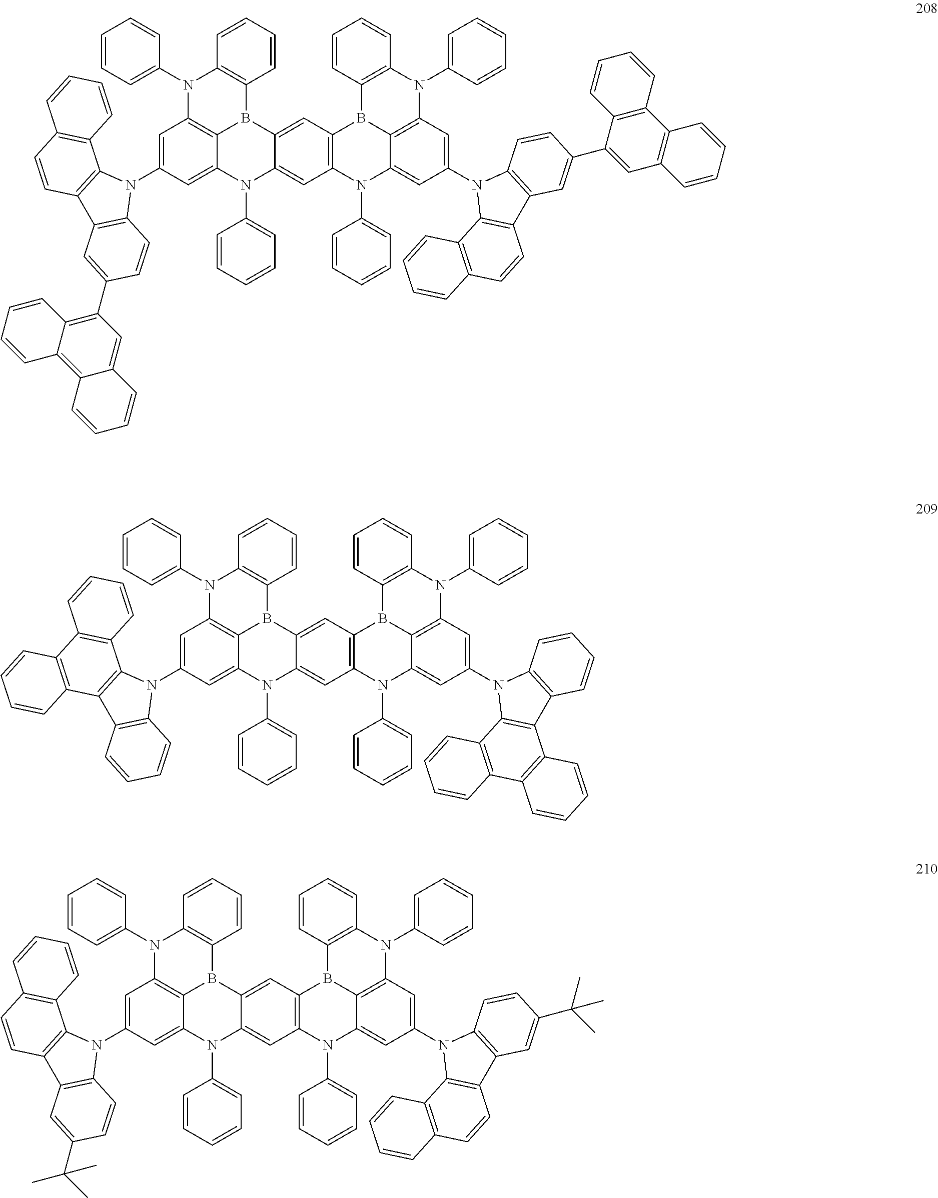 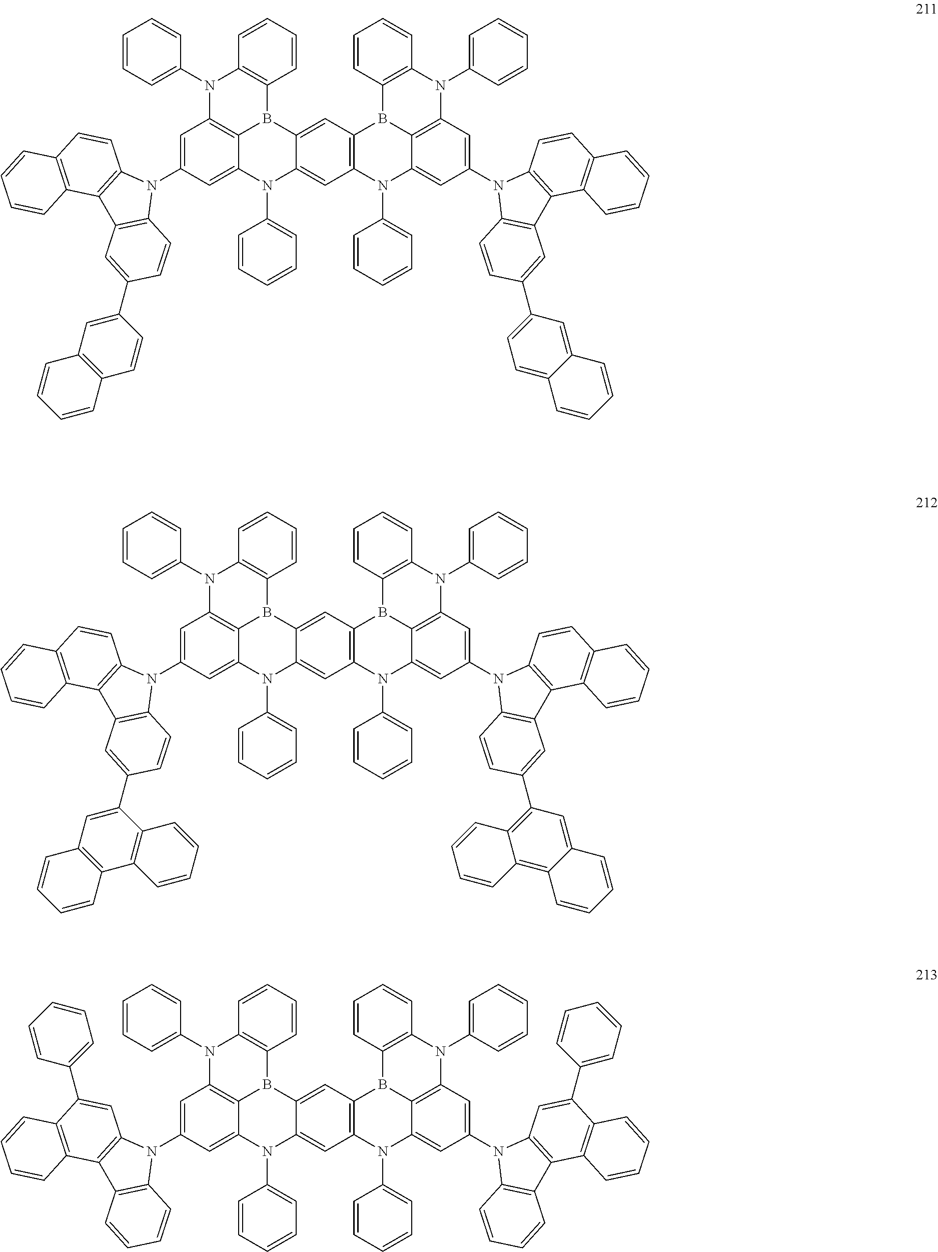 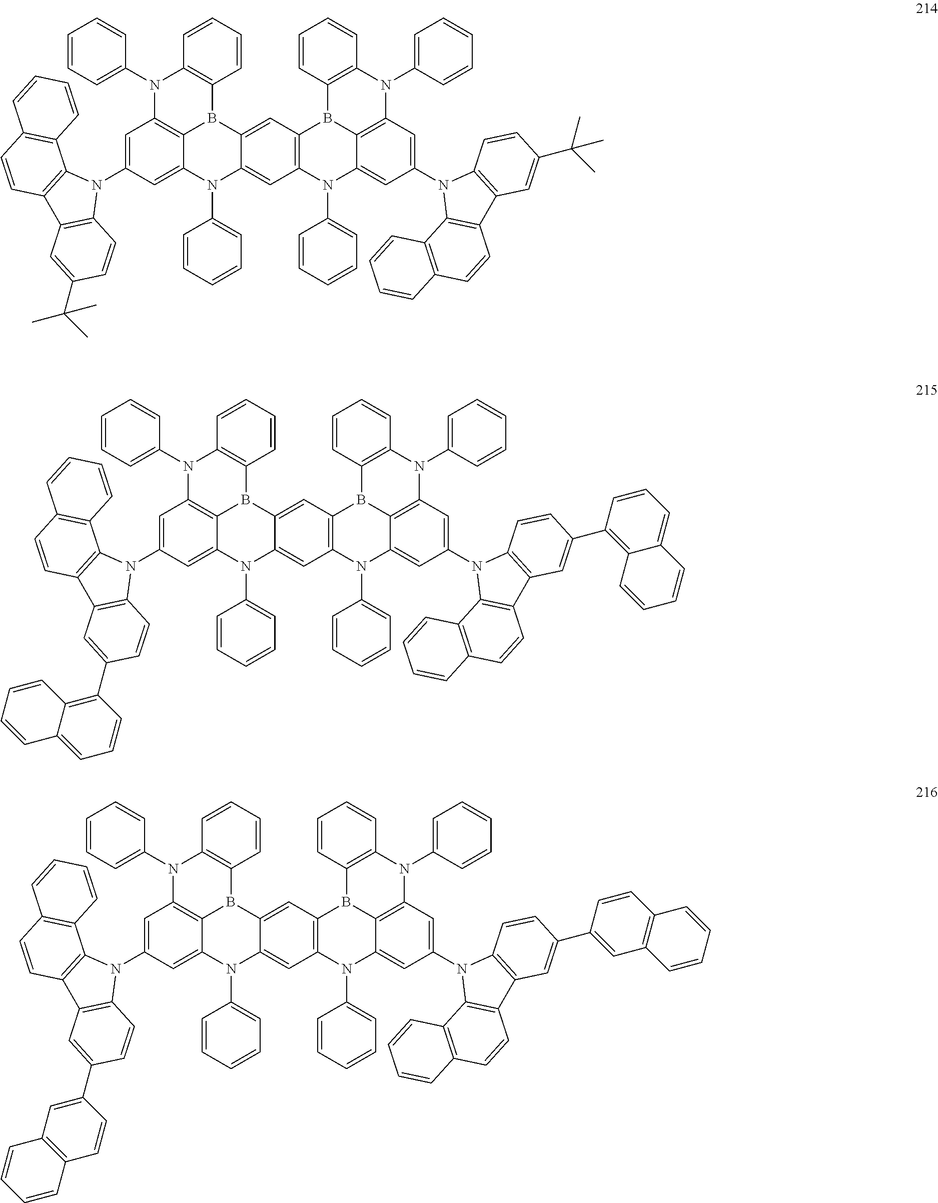 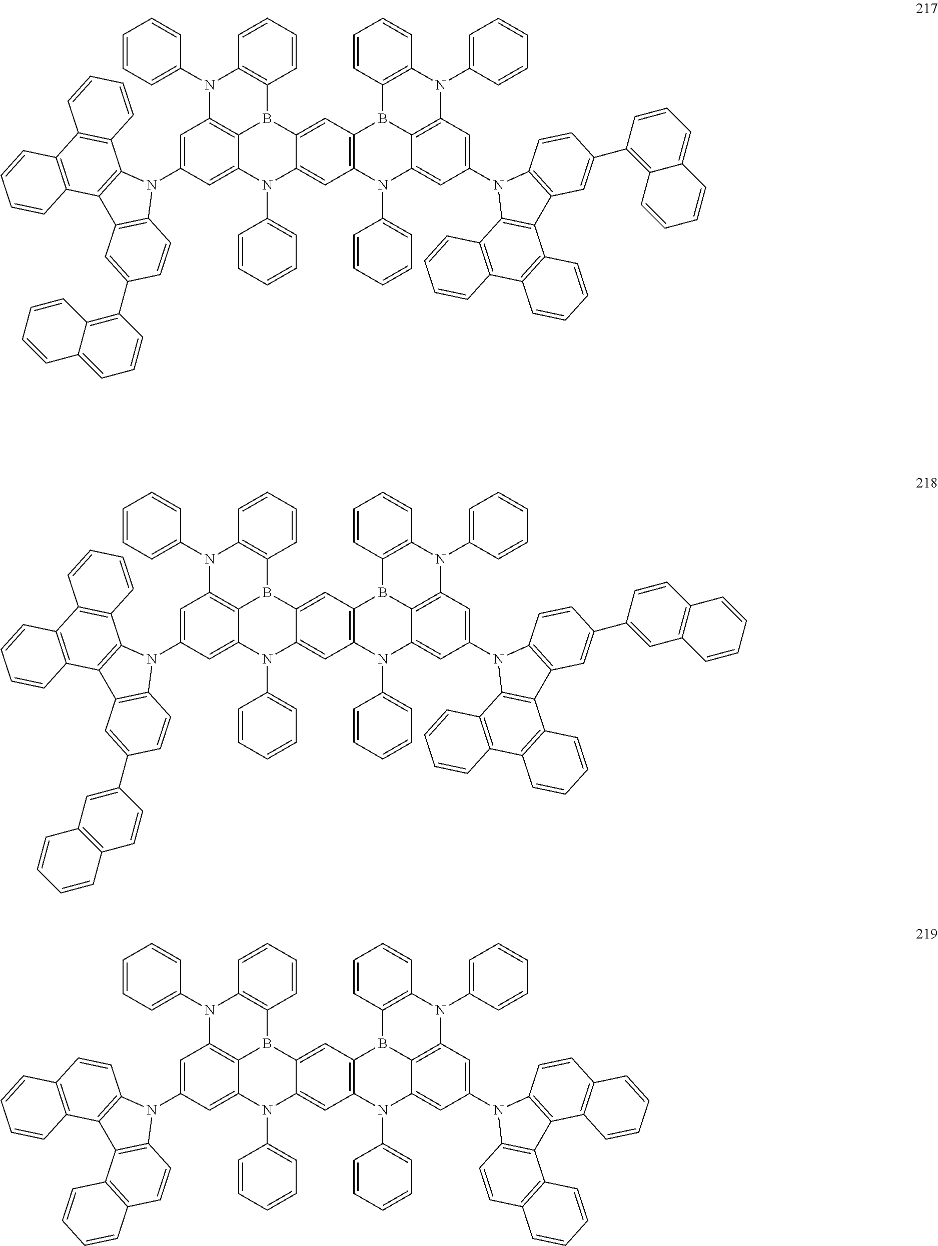 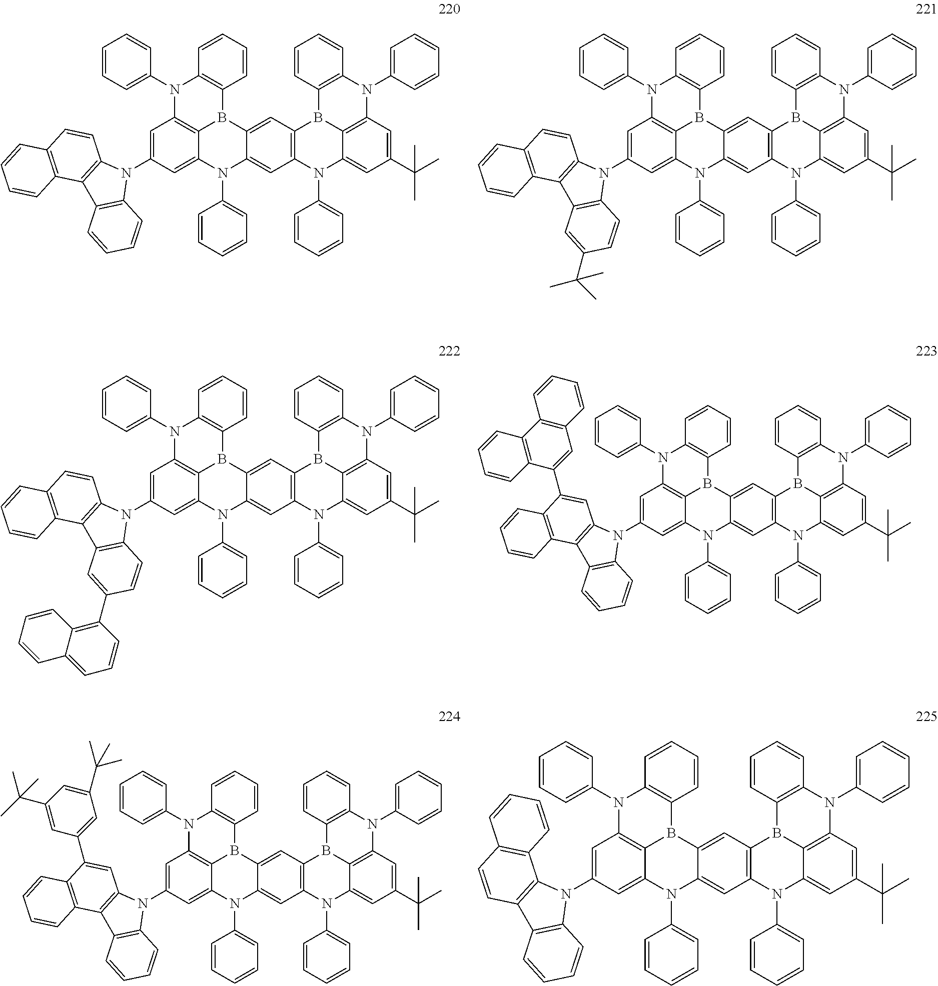 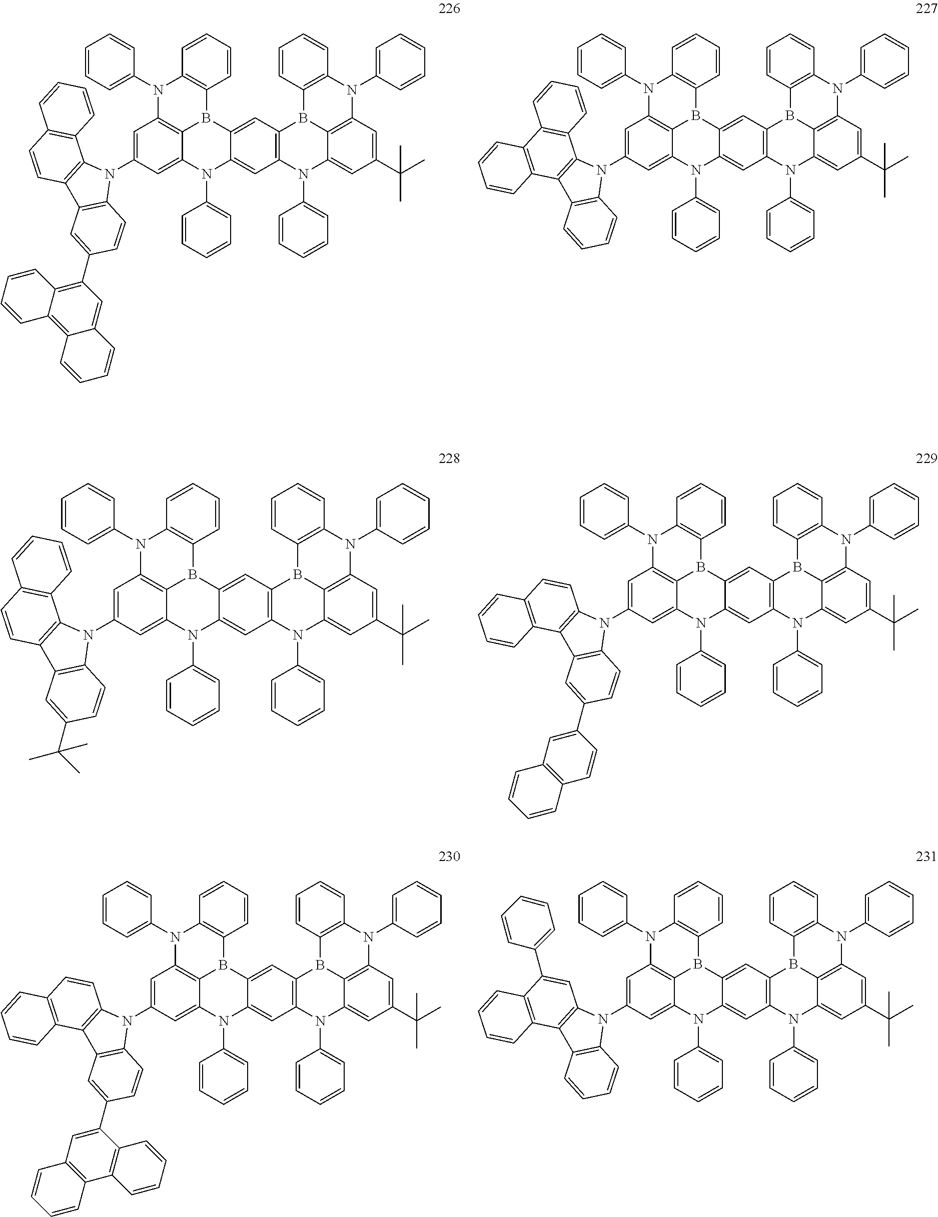 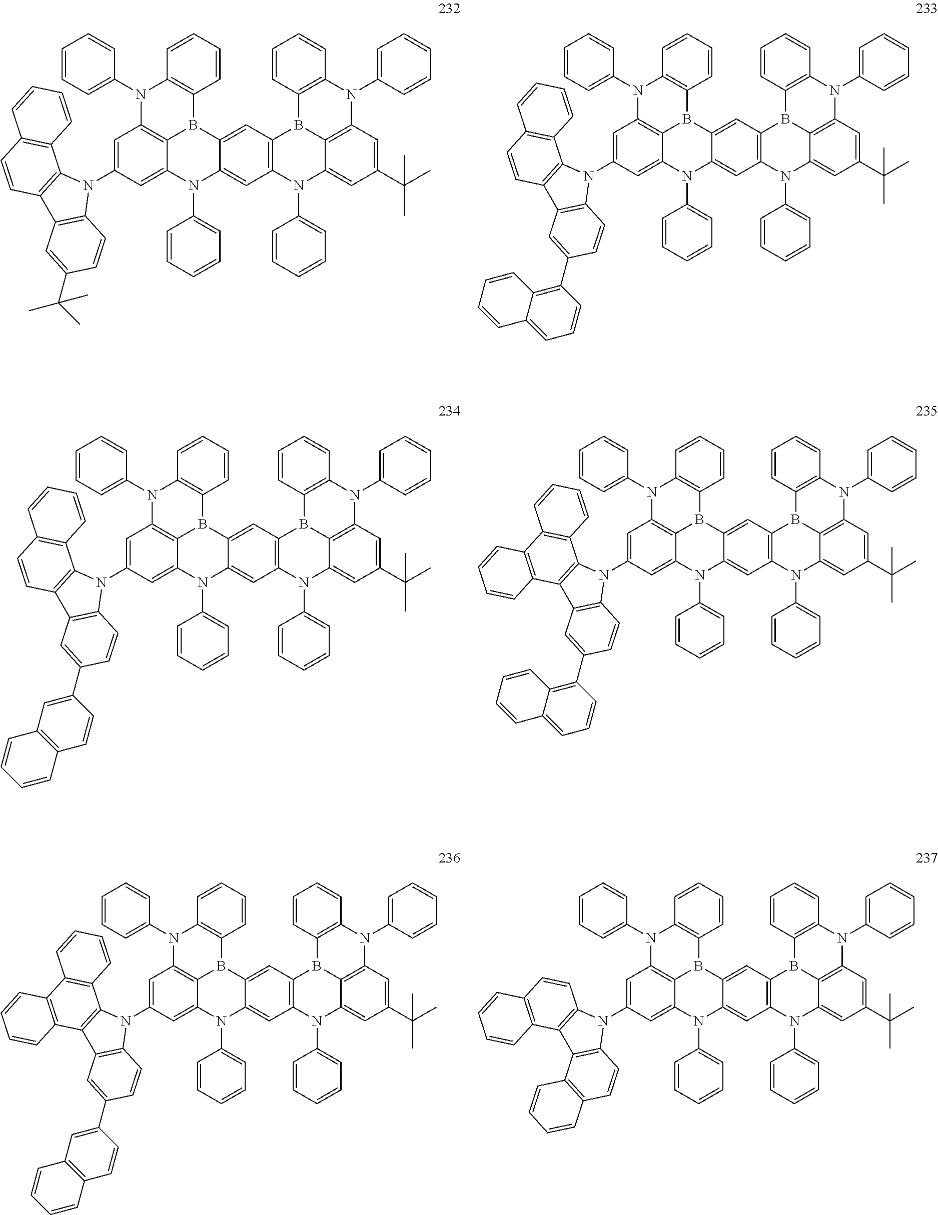 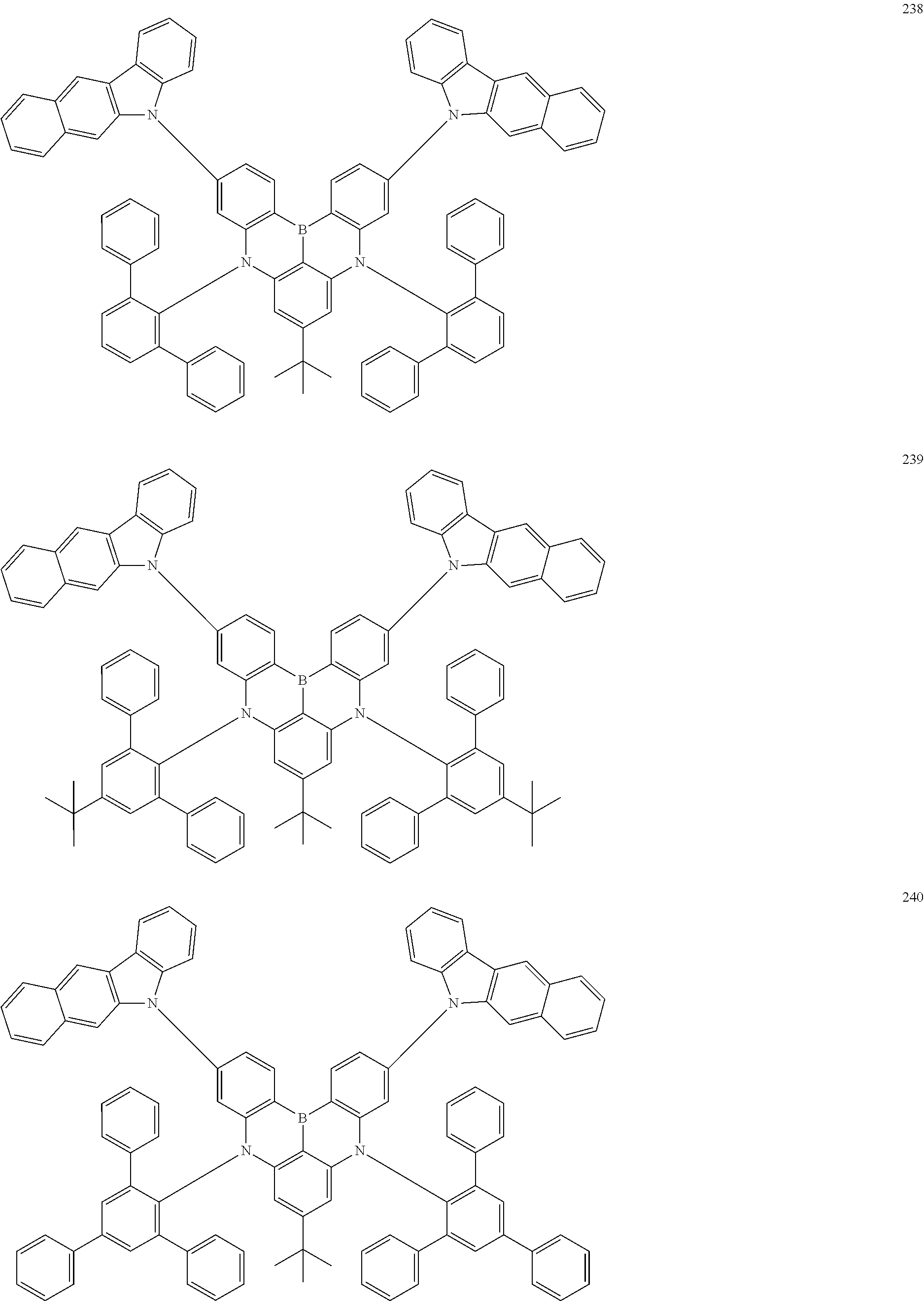 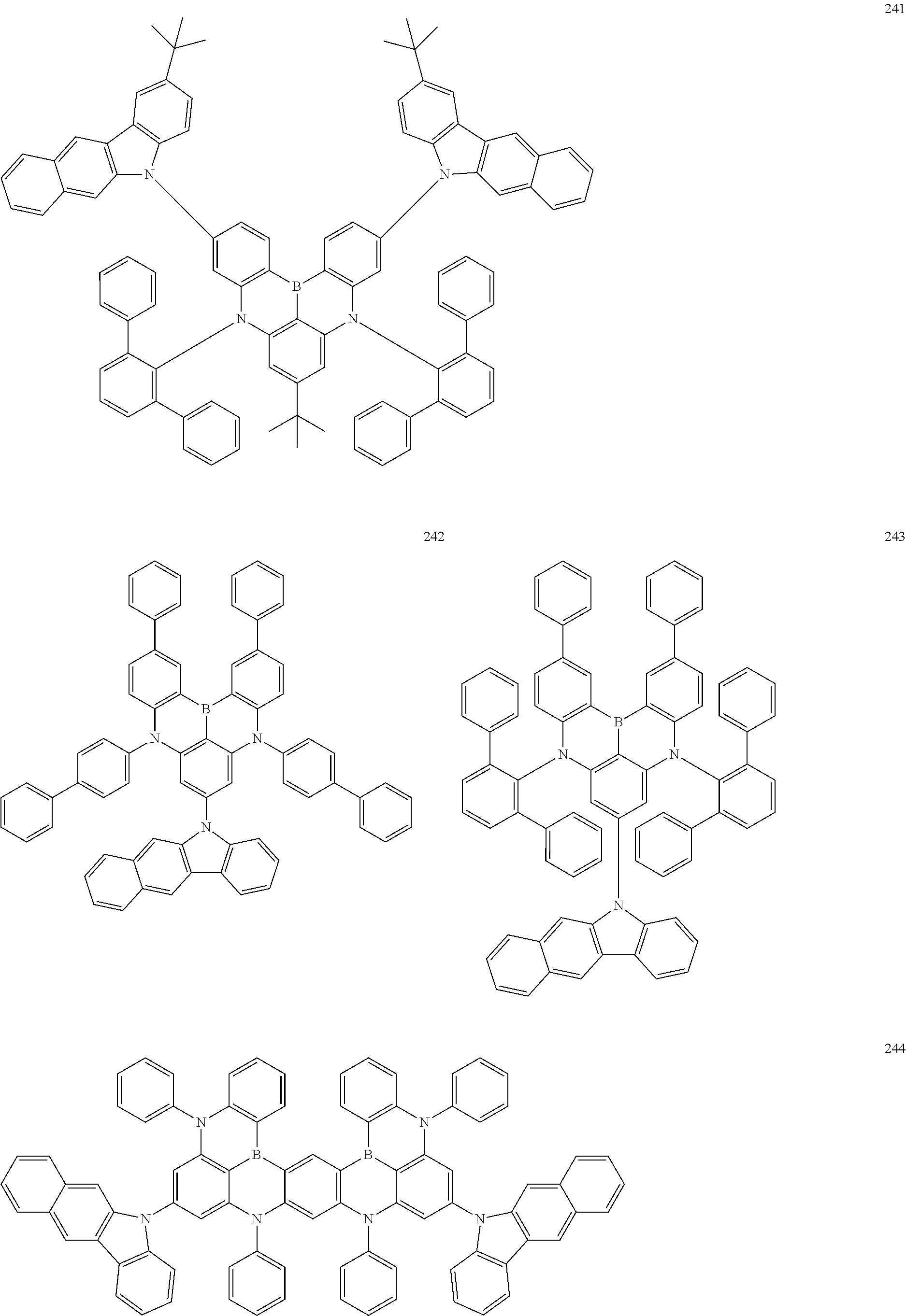 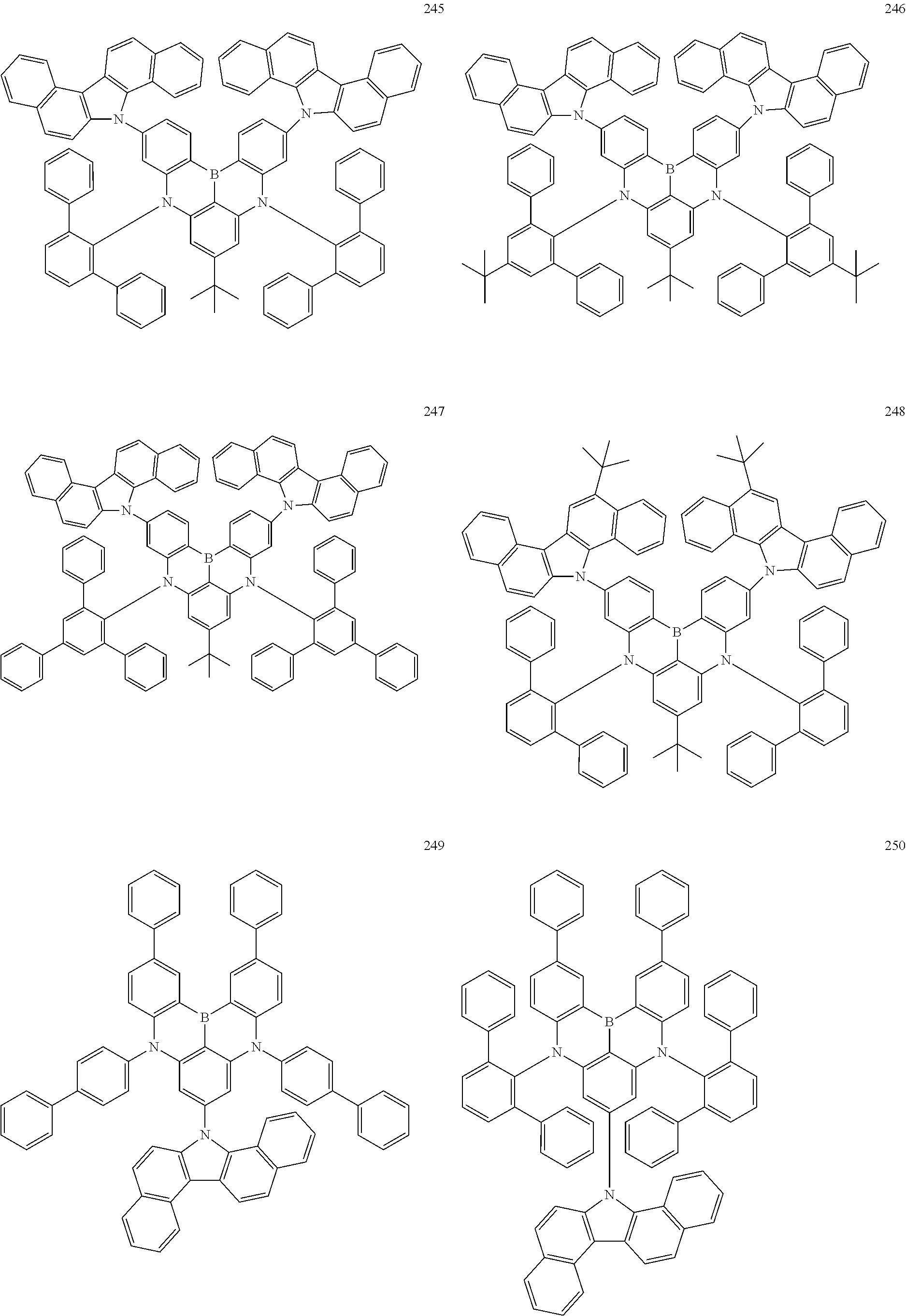 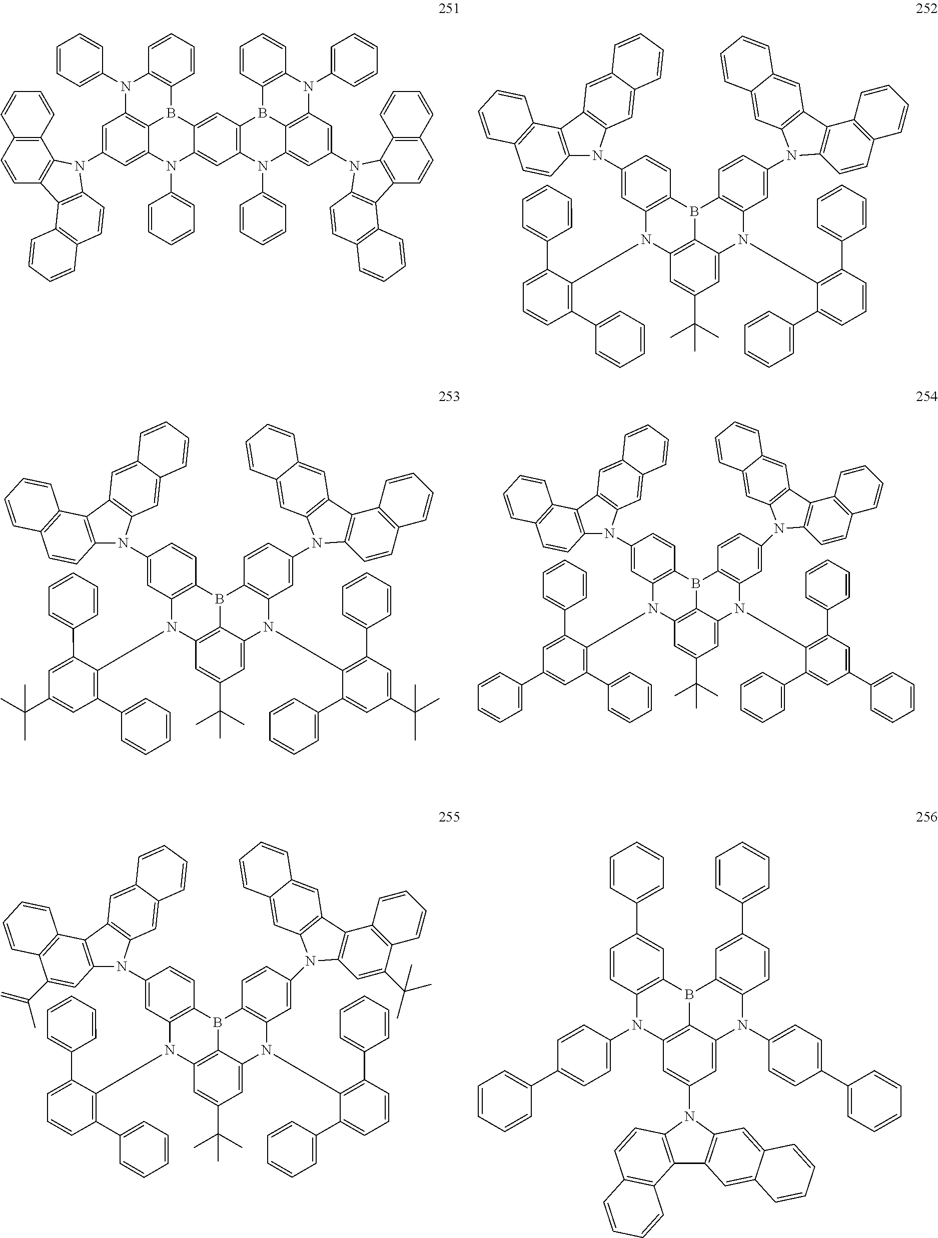 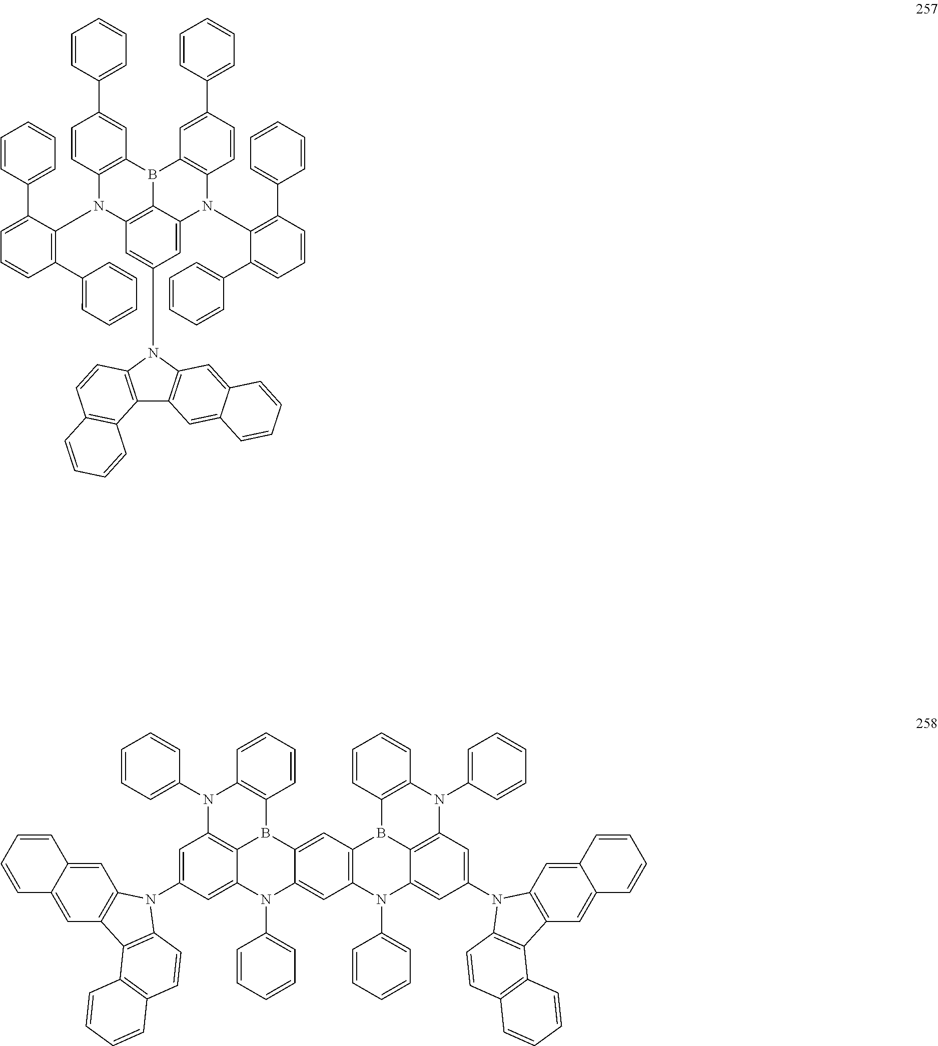 [SMILES: c1ccc(-c2ccc3c(c2)B2c4cc(-c5ccccc5)ccc4N(c4c(-c5ccccc5)cccc4-c4ccccc4)c4cc(-n5c6cc7ccccc7cc6c6c7ccccc7ccc65)cc(c42)N3c2c(-c3ccccc3)cccc2-c2ccccc2)cc1 ; c1ccc(N2c3ccccc3B3c4cc5c(cc4N(c4ccccc4)c4cc(-n6c7cc8ccccc8cc7c7c8ccccc8ccc76)cc2c43)N(c2ccccc2)c2cc(-n3c4cc6ccccc6cc4c4c6ccccc6ccc43)cc3c2B5c2ccccc2N3c2ccccc2)cc1] 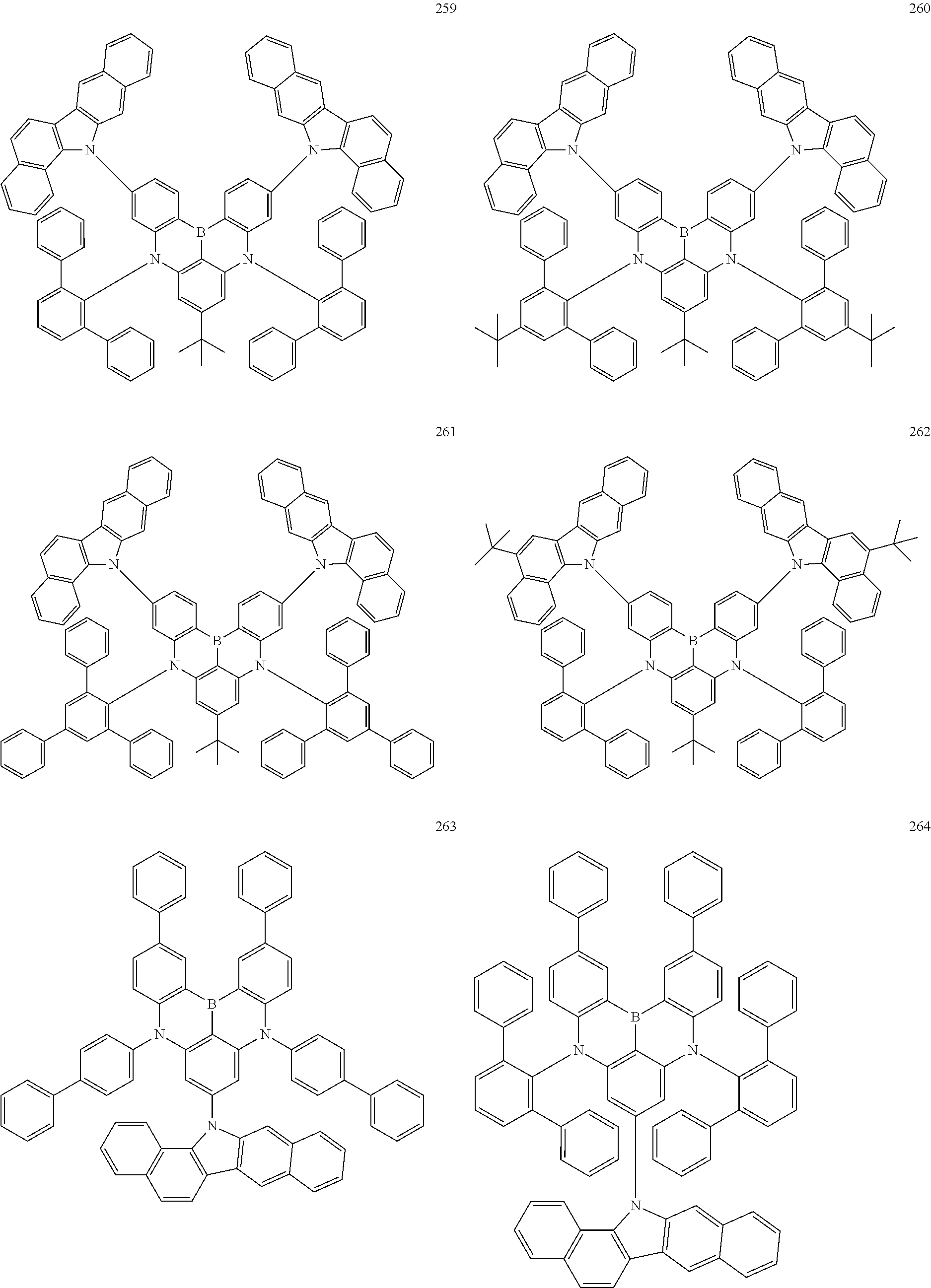 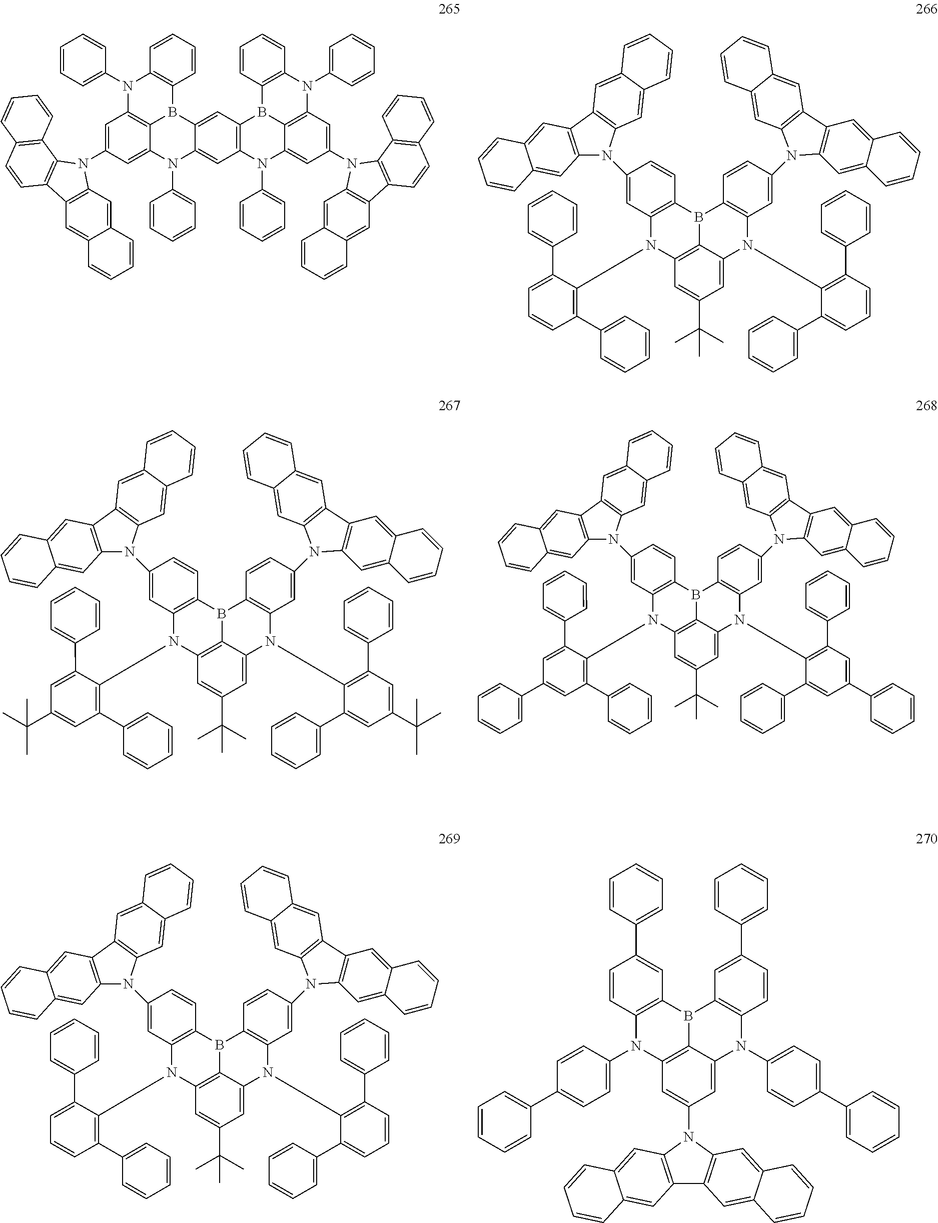 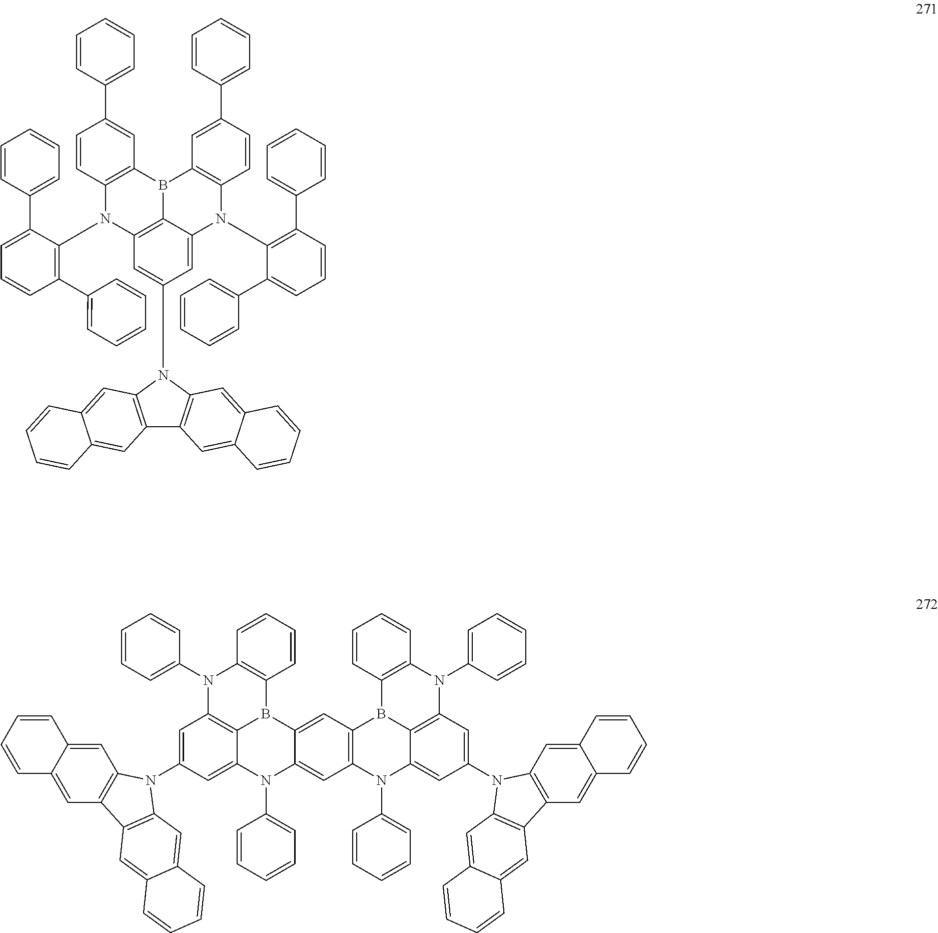 [SMILES: c1ccc(-c2ccc3c(c2)B2c4cc(-c5ccccc5)ccc4N(c4c(-c5ccccc5)cccc4-c4ccccc4)c4cc(-n5c6cc7ccccc7cc6c6cc7ccccc7cc65)cc(c42)N3c2c(-c3ccccc3)cccc2-c2ccccc2)cc1 ; c1ccc(N2c3ccccc3B3c4cc5c(cc4N(c4ccccc4)c4cc(-n6c7cc8ccccc8cc7c7cc8ccccc8cc76)cc2c43)N(c2ccccc2)c2cc(-n3c4cc6ccccc6cc4c4cc6ccccc6cc43)cc3c2B5c2ccccc2N3c2ccccc2)cc1] 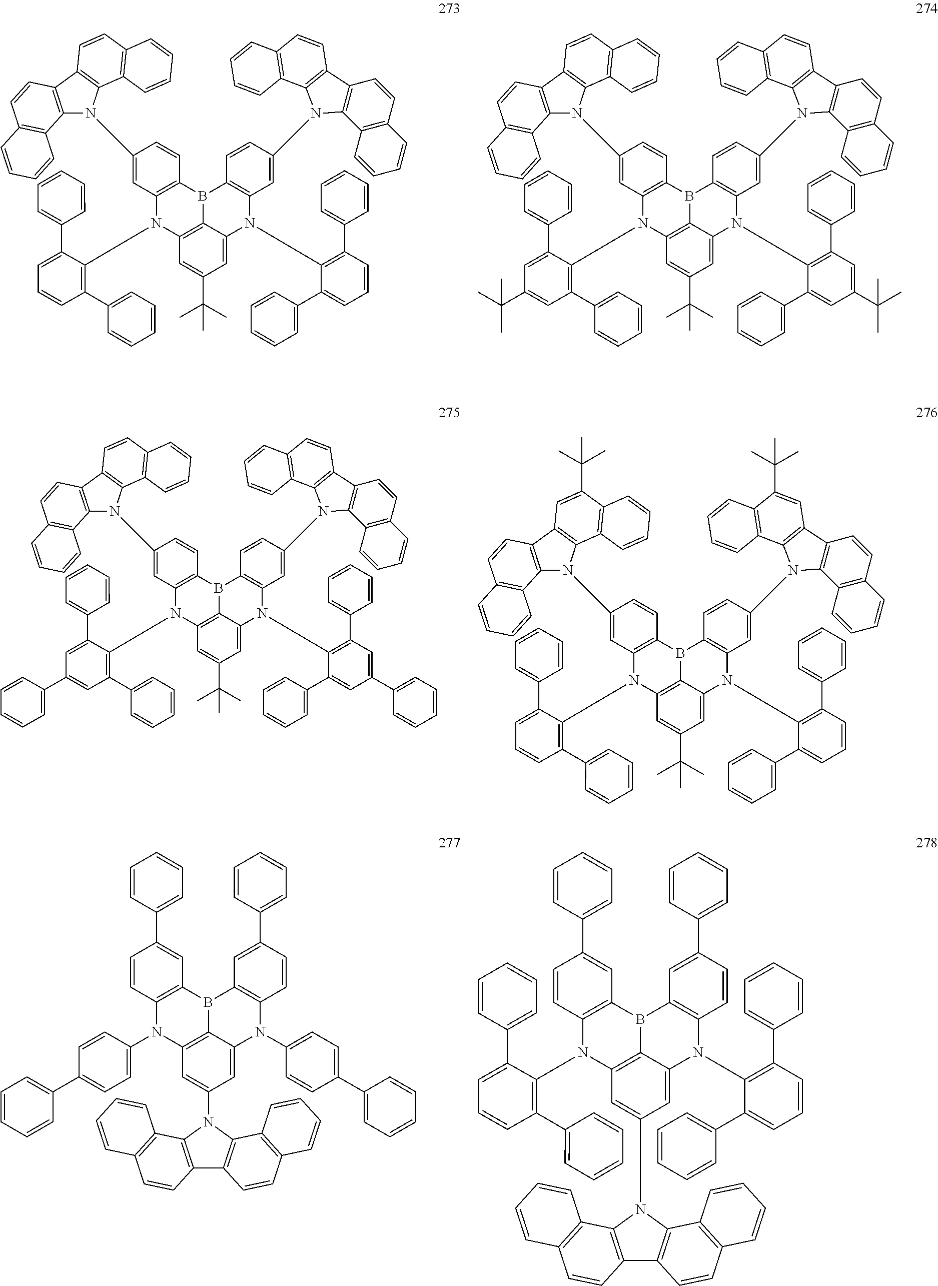 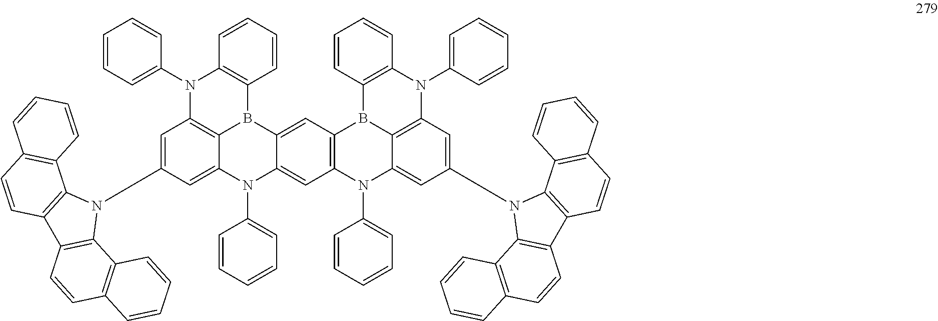 [SMILES: c1ccc(N2c3ccccc3B3c4cc5c(cc4N(c4ccccc4)c4cc(-n6c7c8ccccc8ccc7c7ccc8ccccc8c76)cc2c43)N(c2ccccc2)c2cc(-n3c4c6ccccc6ccc4c4ccc6ccccc6c43)cc3c2B5c2ccccc2N3c2ccccc2)cc1] 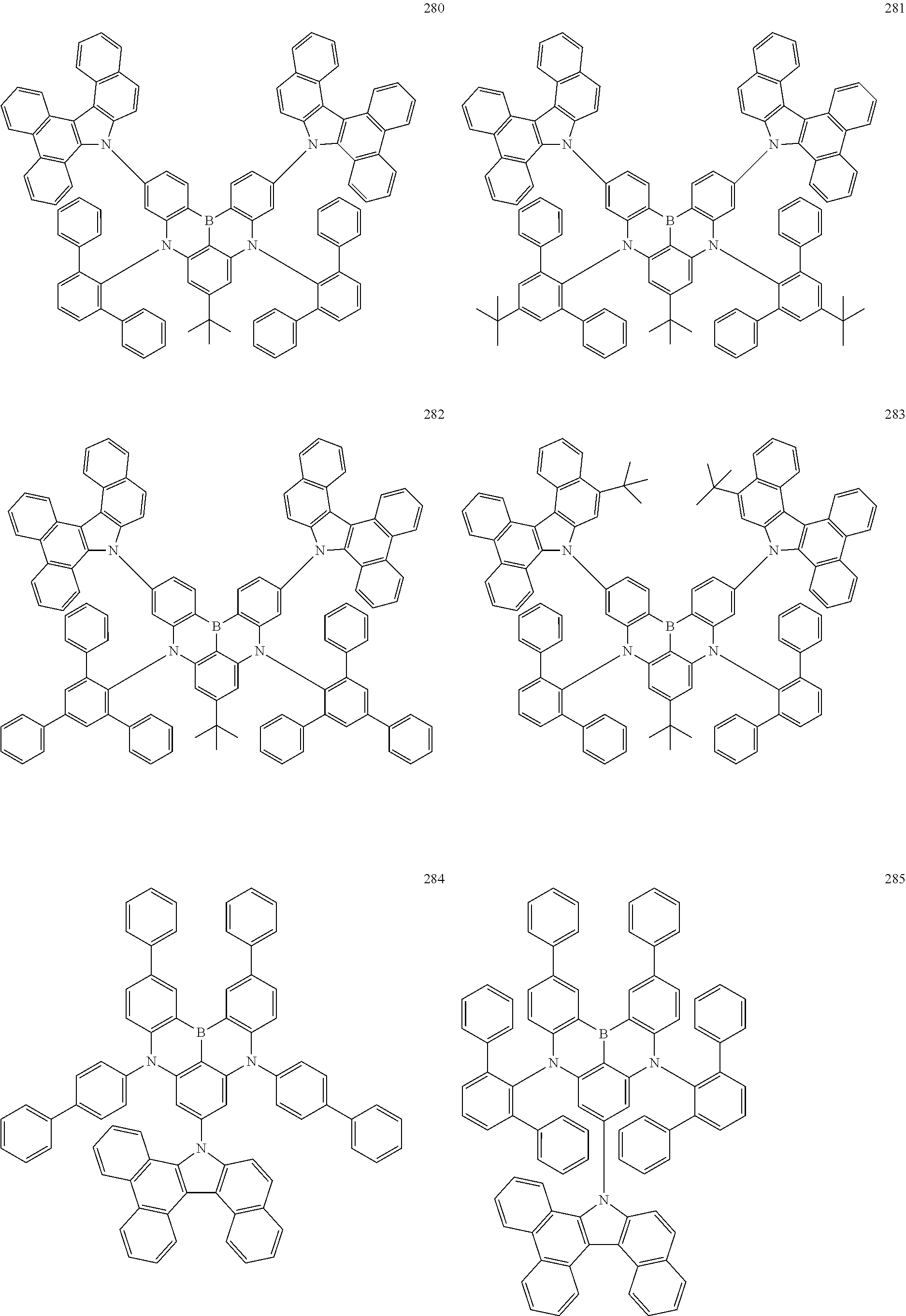 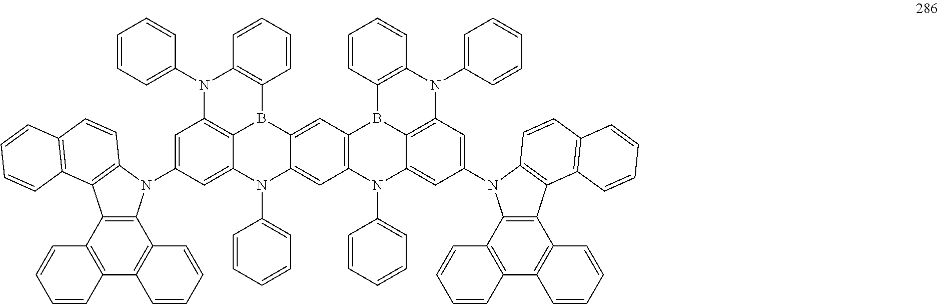 [SMILES: c1ccc(N2c3ccccc3B3c4cc5c(cc4N(c4ccccc4)c4cc(-n6c7ccc8ccccc8c7c7c8ccccc8c8ccccc8c76)cc2c43)N(c2ccccc2)c2cc(-n3c4ccc6ccccc6c4c4c6ccccc6c6ccccc6c43)cc3c2B5c2ccccc2N3c2ccccc2)cc1] 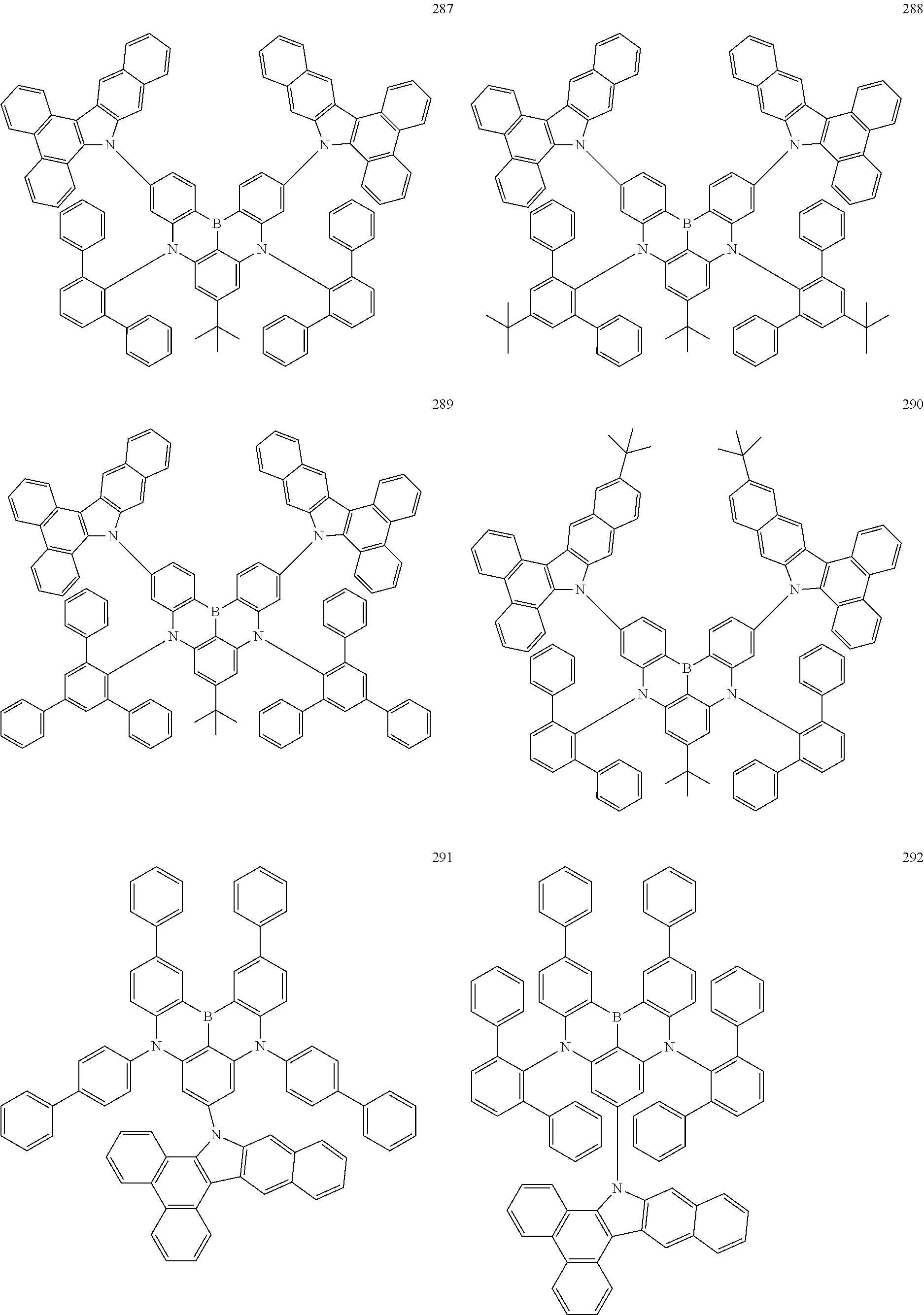 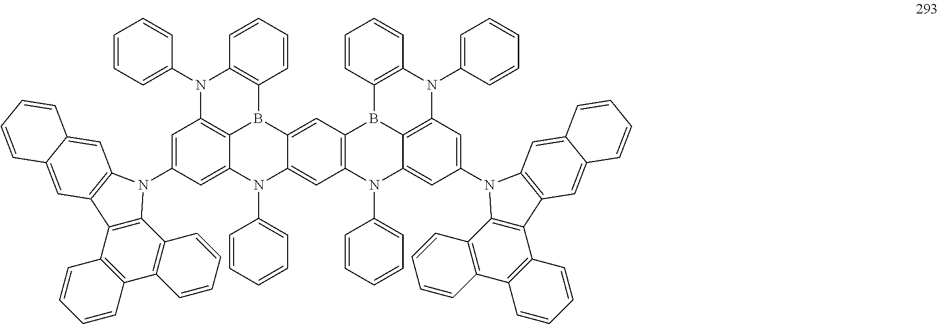 [SMILES: c1ccc(N2c3ccccc3B3c4cc5c(cc4N(c4ccccc4)c4cc(-n6c7cc8ccccc8cc7c7c8ccccc8c8ccccc8c76)cc2c43)N(c2ccccc2)c2cc(-n3c4cc6ccccc6cc4c4c6ccccc6c6ccccc6c43)cc3c2B5c2ccccc2N3c2ccccc2)cc1] 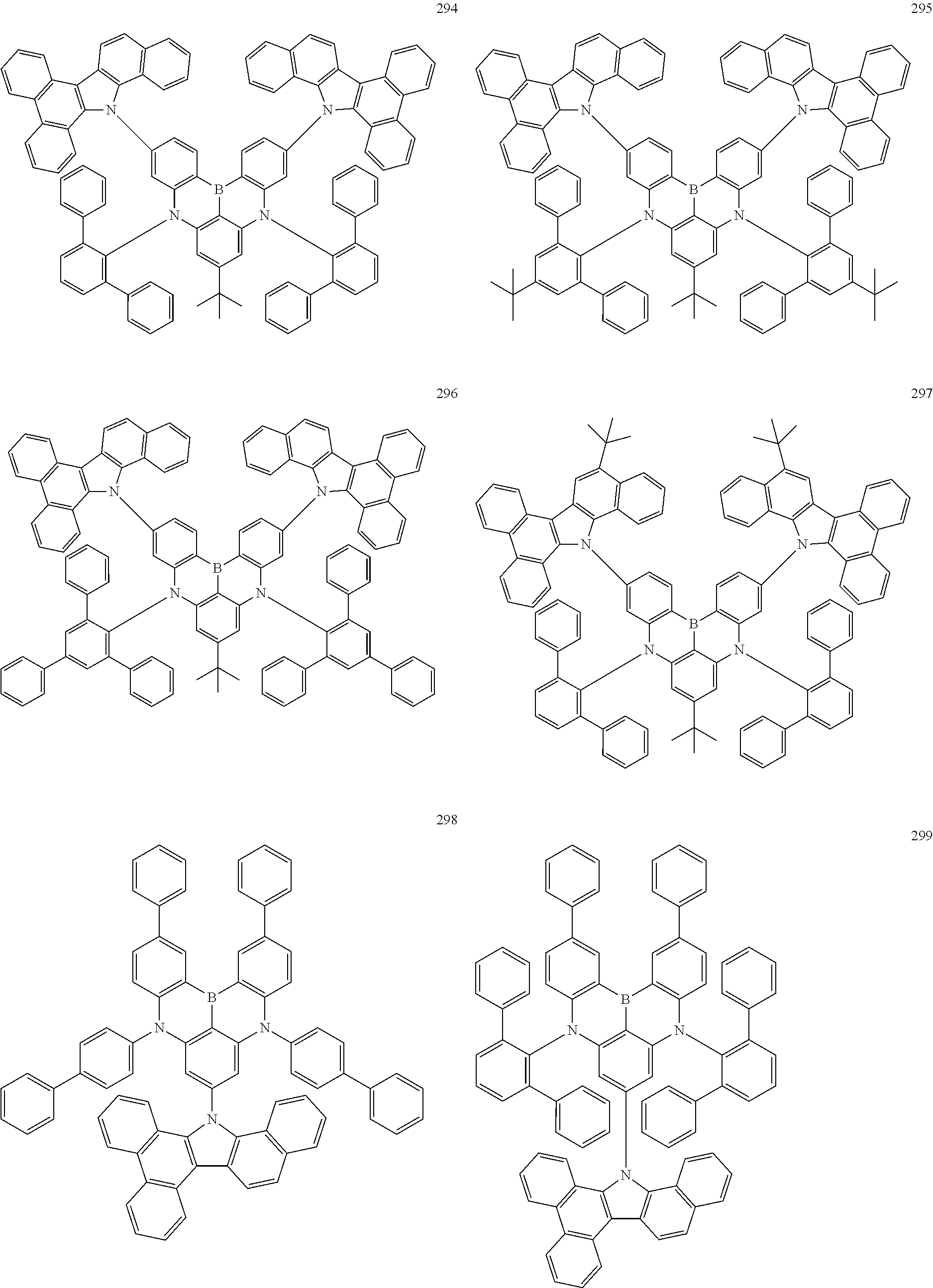 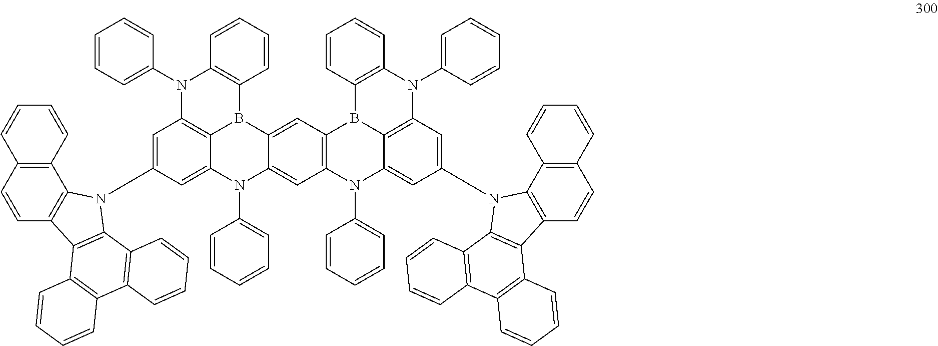 [SMILES: c1ccc(N2c3ccccc3B3c4cc5c(cc4N(c4ccccc4)c4cc(-n6c7c8ccccc8ccc7c7c8ccccc8c8ccccc8c76)cc2c43)N(c2ccccc2)c2cc(-n3c4c6ccccc6ccc4c4c6ccccc6c6ccccc6c43)cc3c2B5c2ccccc2N3c2ccccc2)cc1] 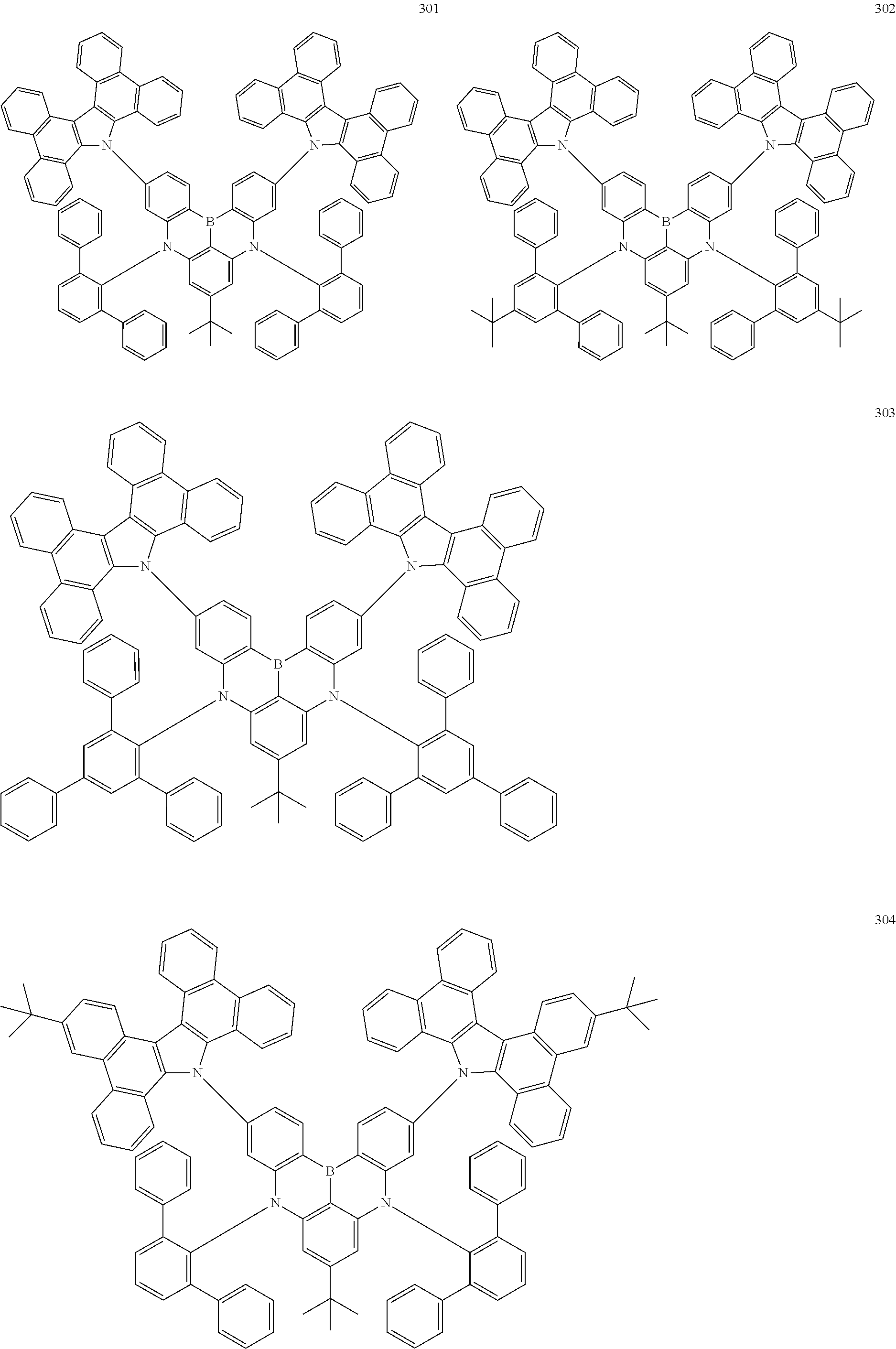 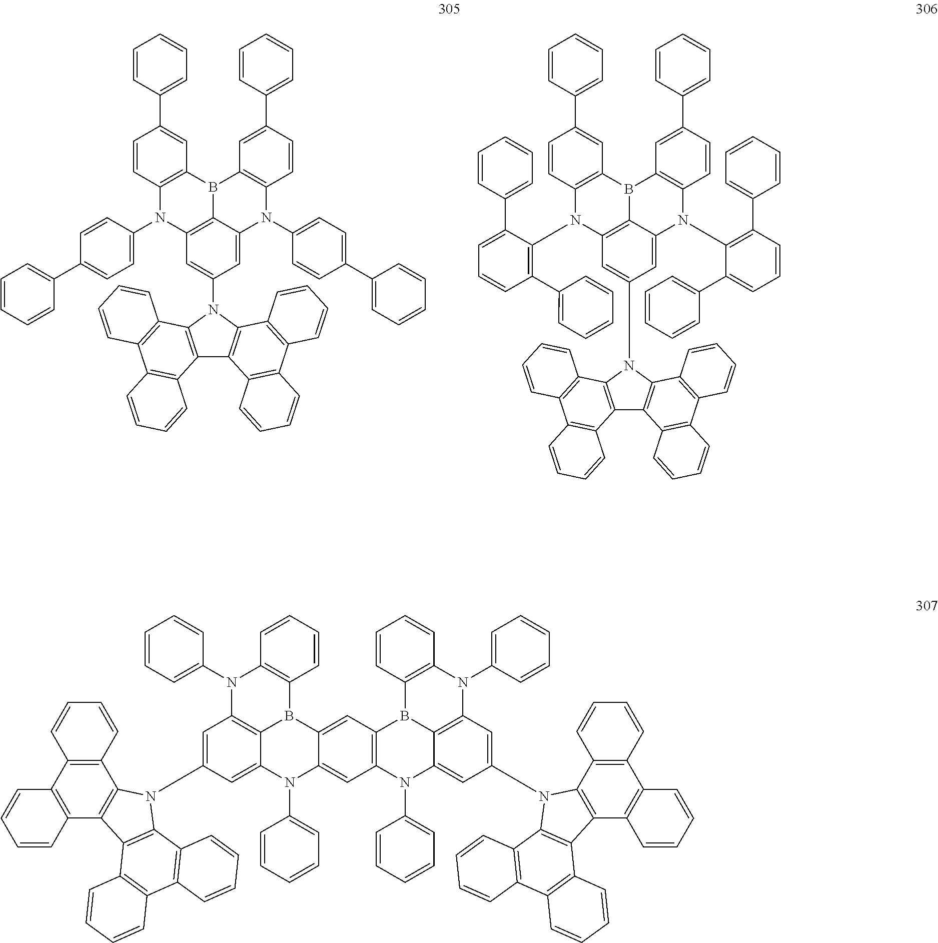 [SMILES: c1ccc(-c2ccc(N3c4ccc(-c5ccccc5)cc4B4c5cc(-c6ccccc6)ccc5N(c5ccc(-c6ccccc6)cc5)c5cc(-n6c7c8ccccc8c8ccccc8c7c7c8ccccc8c8ccccc8c76)cc3c54)cc2)cc1 ; c1ccc(-c2ccc3c(c2)B2c4cc(-c5ccccc5)ccc4N(c4c(-c5ccccc5)cccc4-c4ccccc4)c4cc(-n5c6c7ccccc7c7ccccc7c6c6c7ccccc7c7ccccc7c65)cc(c42)N3c2c(-c3ccccc3)cccc2-c2ccccc2)cc1 ; c1ccc(N2c3ccccc3B3c4cc5c(cc4N(c4ccccc4)c4cc(-n6c7c8ccccc8c8ccccc8c7c7c8ccccc8c8ccccc8c76)cc2c43)N(c2ccccc2)c2cc(-n3c4c6ccccc6c6ccccc6c4c4c6ccccc6c6ccccc6c43)cc3c2B5c2ccccc2N3c2ccccc2)cc1]
wherein in Compound Group 1,
D represents a deuterium atom.

14. A polycyclic compound represented by Formula 1: 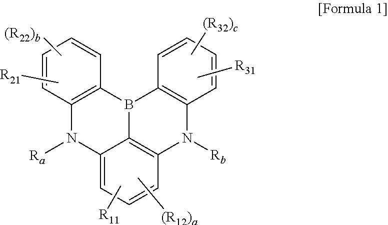
wherein in Formula 1,
a is an integer from 0 to 2,
b and c are each independently an integer from 0 to 3,
at least one of R₁₁, R₂₁, and R₃₁ is a group represented by Formula 2,
the remainder of R₁₁, R₂₁, and R₃₁ are each independently a hydrogen atom, a deuterium atom, a halogen atom, a cyano group, a substituted or unsubstituted amine group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
R₁₂, R₂₂, R₃₂, Rₐ, and R_{b} are each independently a hydrogen atom, a deuterium atom, a halogen atom, a cyano group, a substituted or unsubstituted amine group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring, and
at least one hydrogen atom in Formula 1 is optionally substituted with a deuterium atom; 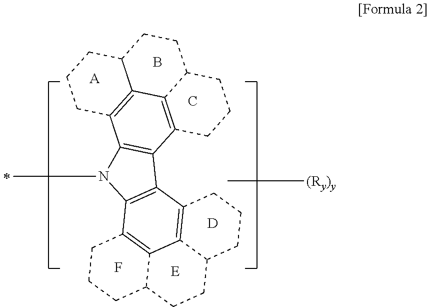
wherein in Formula 2,
at least one of A to F is each a benzene ring,
the remainder of A to F are absent,
y is an integer from 0 to 16,
R_{y} is a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
at least one hydrogen atom in Formula 2 is optionally substituted with a deuterium atom.

15. The polycyclic compound of claim 14, wherein Formula 1 is represented by Formula 3: 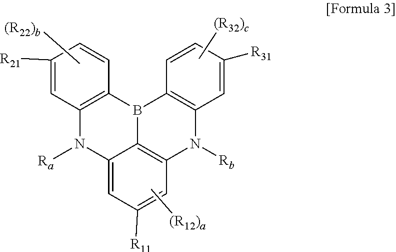
wherein in Formula 3,
a, b, c, Rₐ, R_{b}, R₁₁, R₁₂, R₂₁, R₂₂, R₃₁, and R₃₂ are the same as defined in Formula 1, and
at least one hydrogen atom in Formula 3 is optionally substituted with a deuterium atom.

16. The polycyclic compound of claim 15, wherein Formula 3 is represented by Formula 4-1 or Formula 4-2: 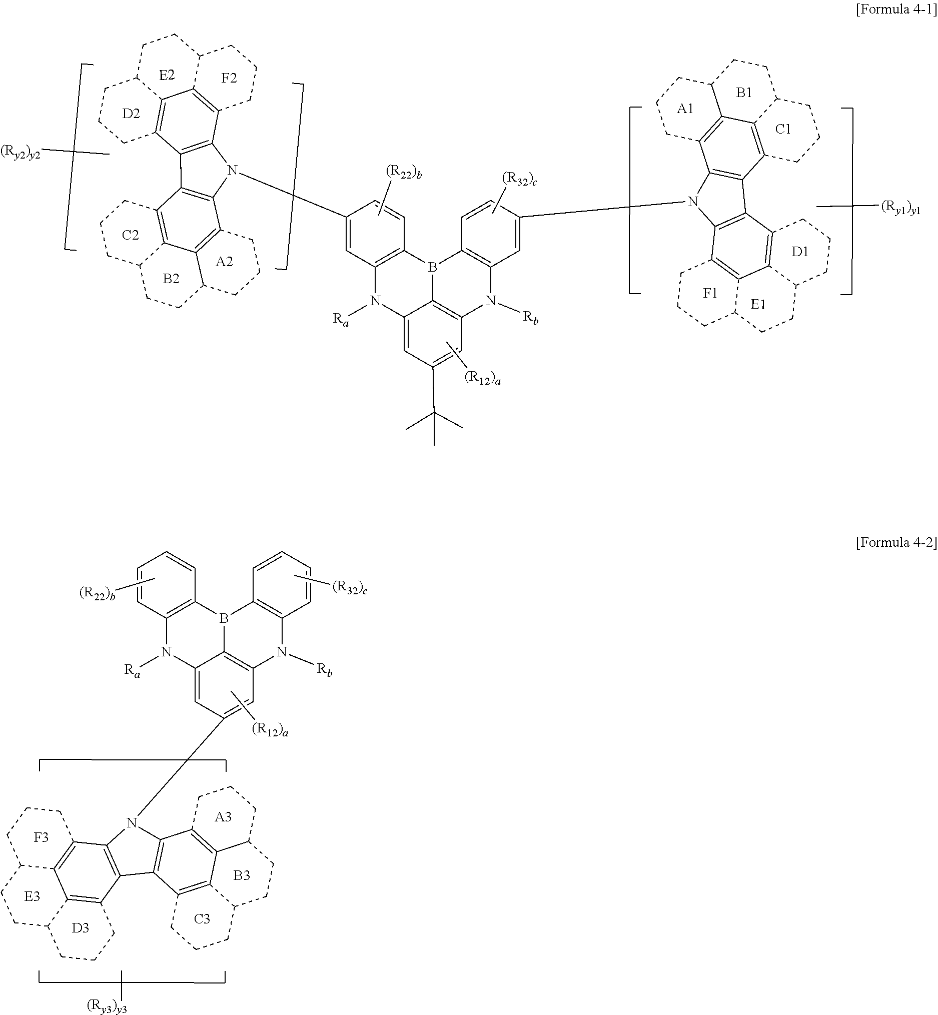
wherein in Formula 4-1,
at least one of A1 to F1 is each a benzene ring,
the remainder of A1 to F1 are absent,
at least one of A2 to F2 is each a benzene ring,
the remainder of A2 to F2 are absent,
y₁ and y₂ are each independently an integer from 0 to 16,
R_{y1} and R_{y2} are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
a, b, c, Rₐ, R_{b}, R₁₂, R₂₂, and R₃₂ are the same as defined in Formula 1, and
at least one hydrogen atom in Formula 4-1 is optionally substituted with a deuterium atom, and
in Formula 4-2,
at least one of A3 to F3 is each a benzene ring,
the remainder of A3 to F3 are absent,
y₃ is an integer from 0 to 16,
R_{y3} is a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
a, b, c, Rₐ, R_{b}, R₁₂, R₂₂, and R₃₂ are the same as defined in Formula 1, and
at least one hydrogen atom in Formula 4-2 is optionally substituted with a deuterium atom.

17. The polycyclic compound of claim 14, wherein Formula 1 is represented by Formula 5: 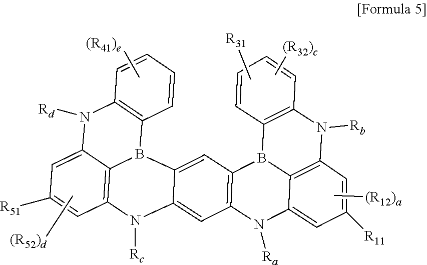
wherein in Formula 5,
R₁₁ is a group represented by Formula 2,
R₅₁ is a group represented by Formula 2 or a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
d is an integer from 0 to 2,
e is an integer from 0 to 4,
R₃₁, R₄₁, R₅₂, R_{c}, and R_{d} are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
a, c, Rₐ, R_{b}, R₁₂, and R₃₂ are the same as defined in Formula 1, and
at least one hydrogen atom in Formula 5 is optionally substituted with a deuterium atom.

18. The polycyclic compound of claim 14, wherein a group represented by Formula 2 is represented by one of Formula 6-1 to Formula 6-14: 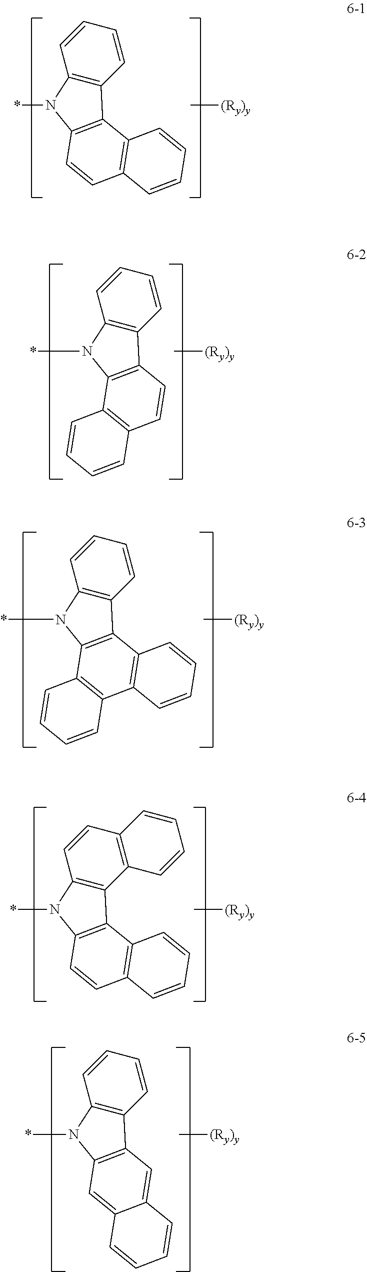 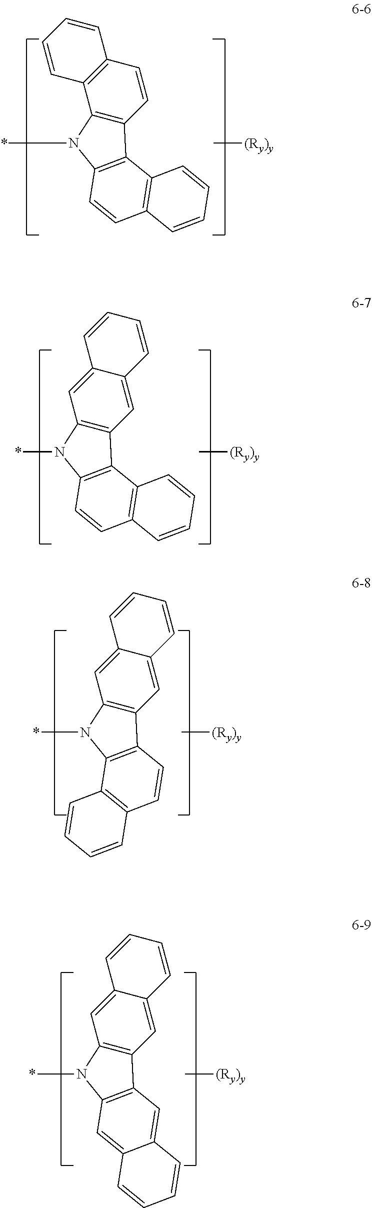 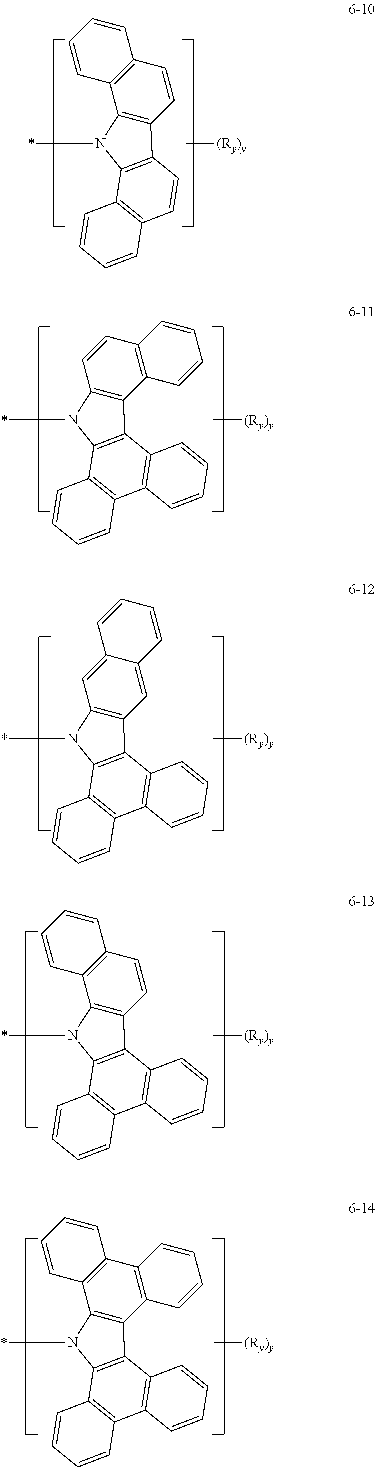
wherein, in Formula 6-1 to Formula 6-14,
y and R_{y} are the same as defined in Formula 2, and
at least one hydrogen atom in one of Formula 6-1 to Formula 6-14 is optionally substituted with a deuterium atom.

19. The polycyclic compound of claim 14, wherein in Formula 2,
R_{y} is a hydrogen atom, a deuterium atom, a t-butyl group, a substituted or unsubstituted phenyl group, a substituted or unsubstituted naphthyl group, a substituted or unsubstituted phenanthryl group, or a substituted or unsubstituted propylphenyl group.

20. The polycyclic compound of claim 14, wherein the polycyclic compound represented by Formula 1 is selected from Compound Group 1: 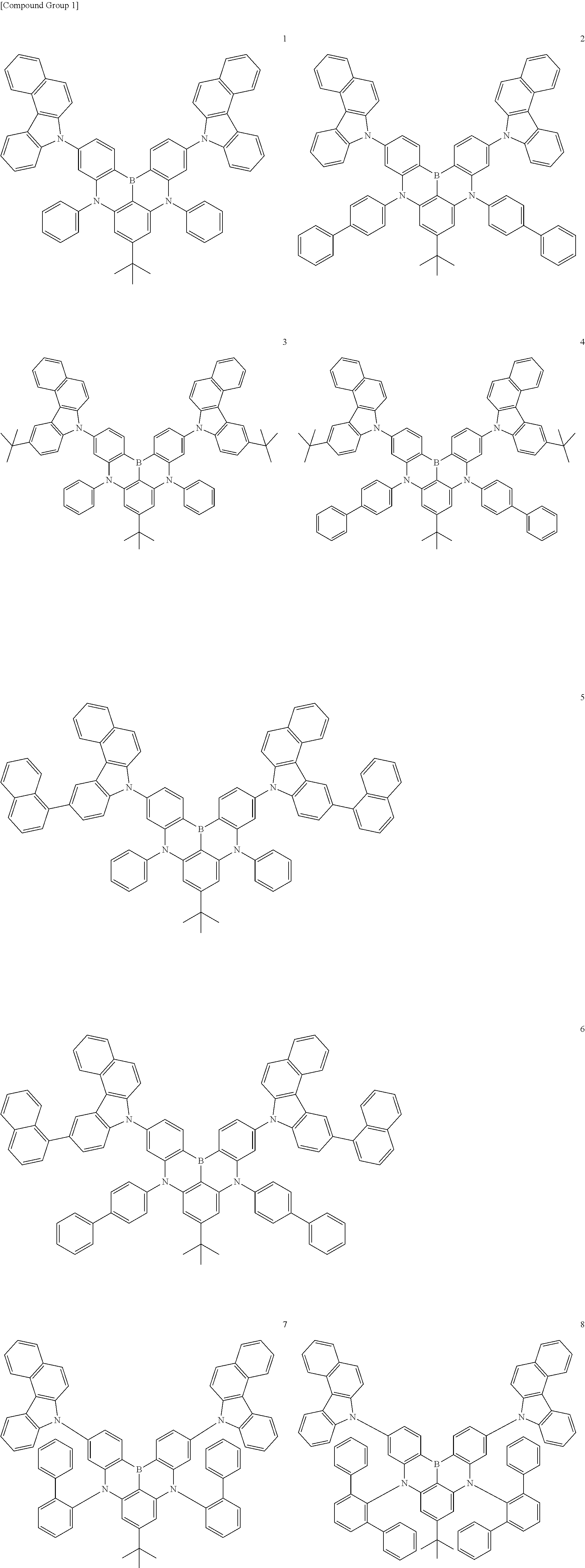 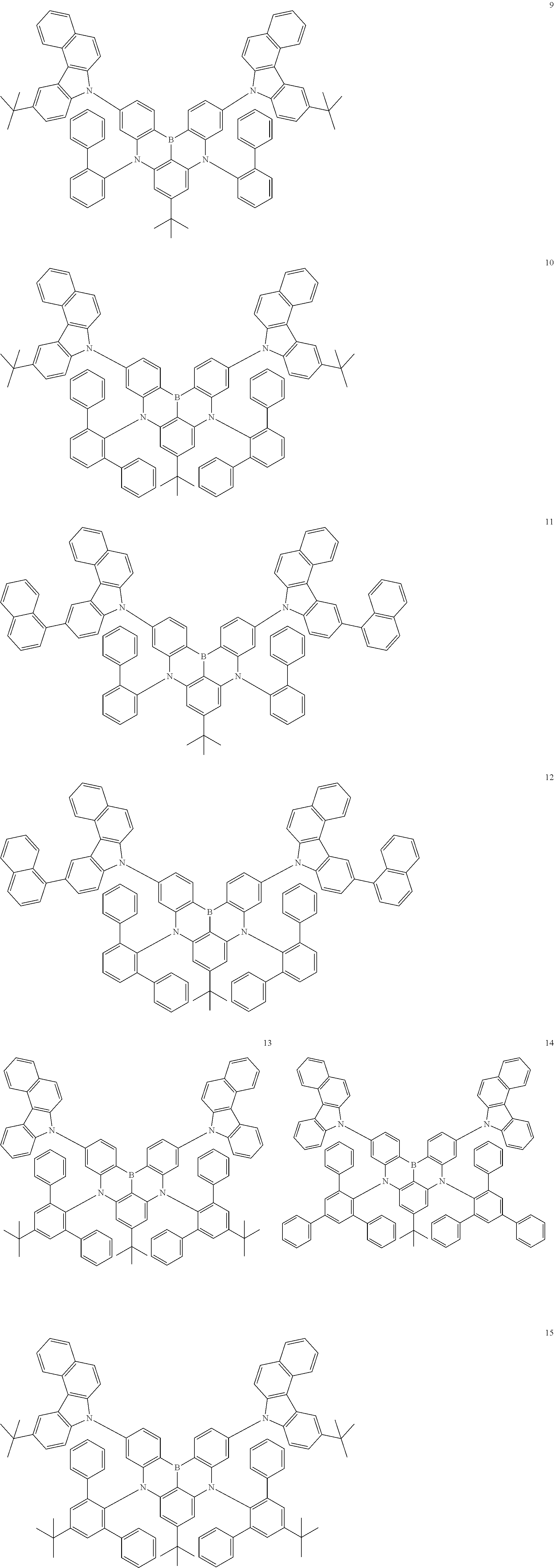 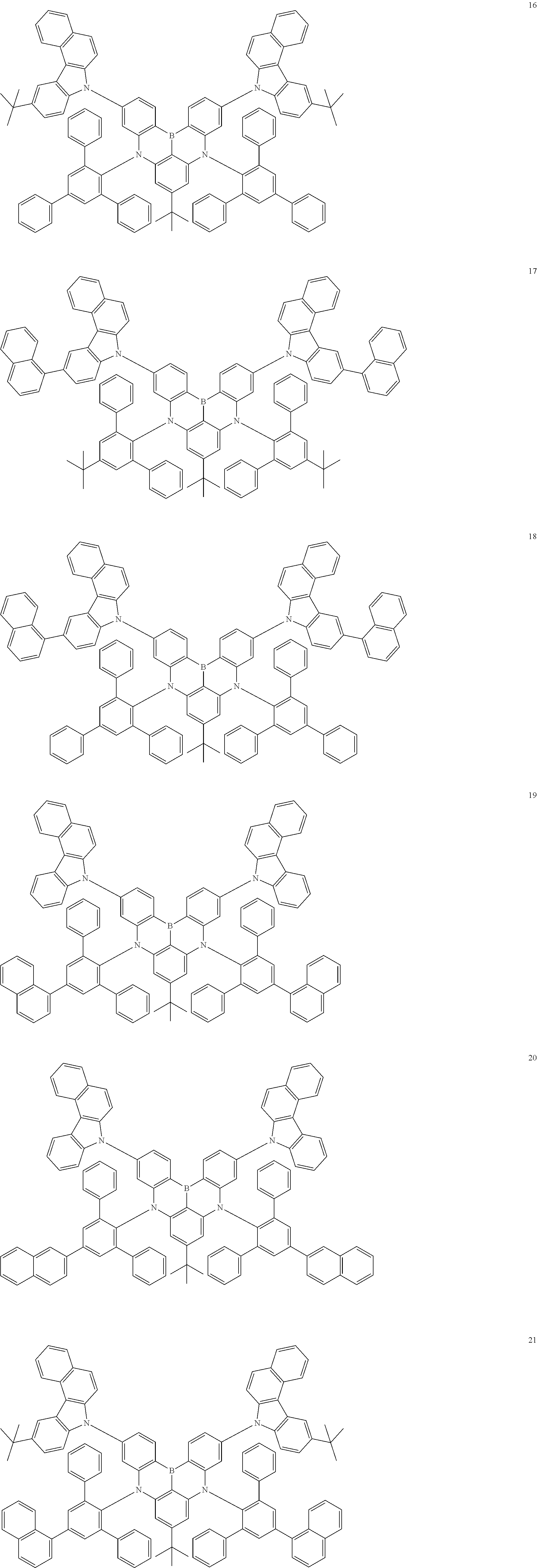 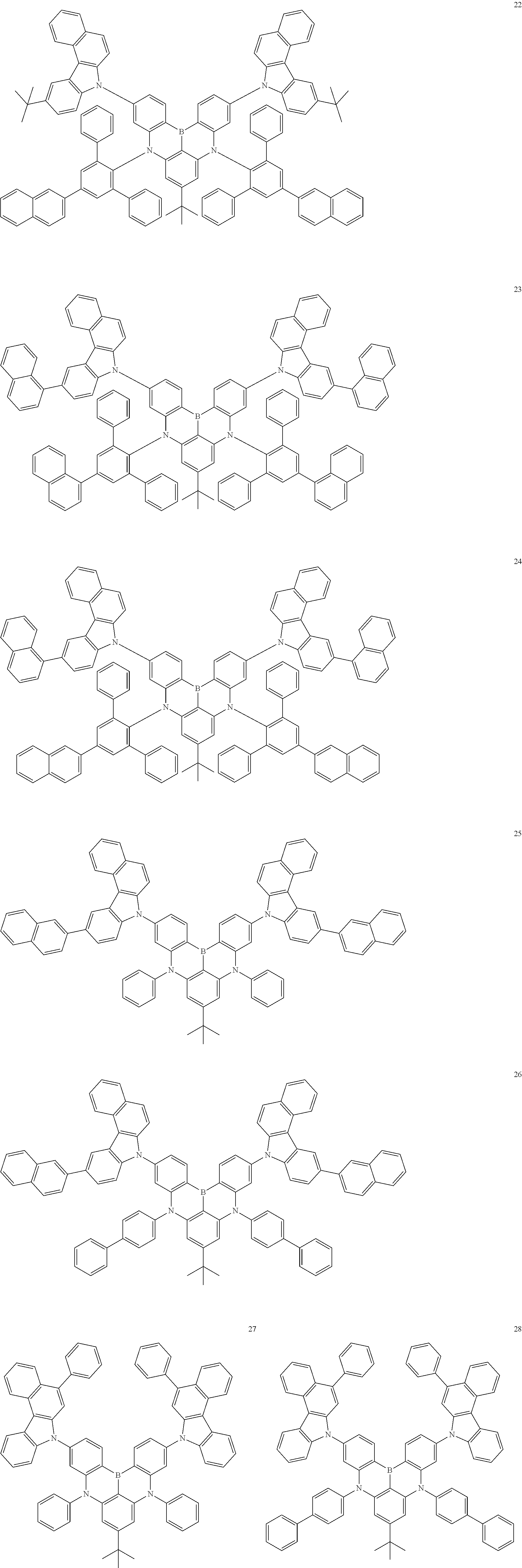 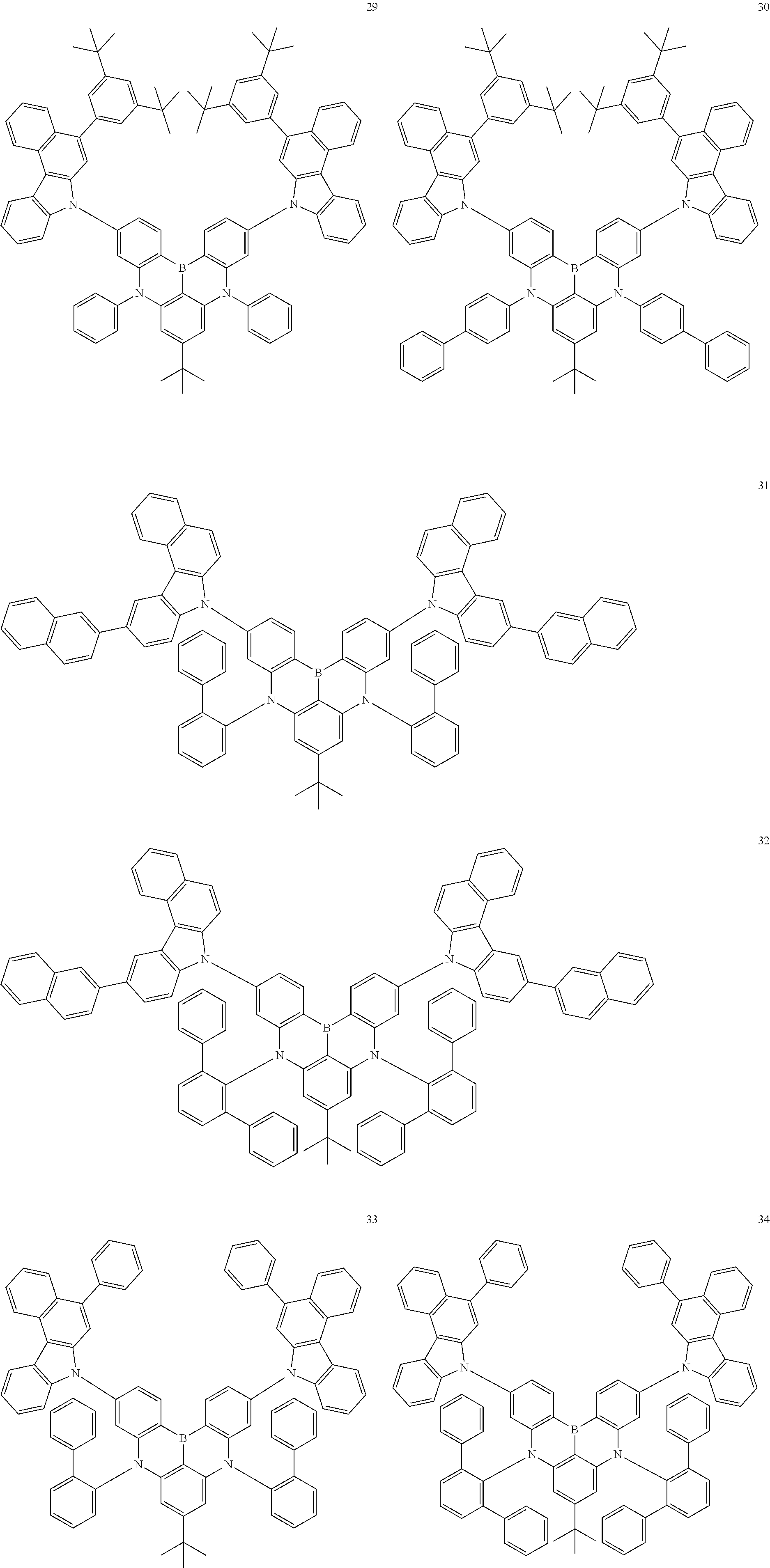 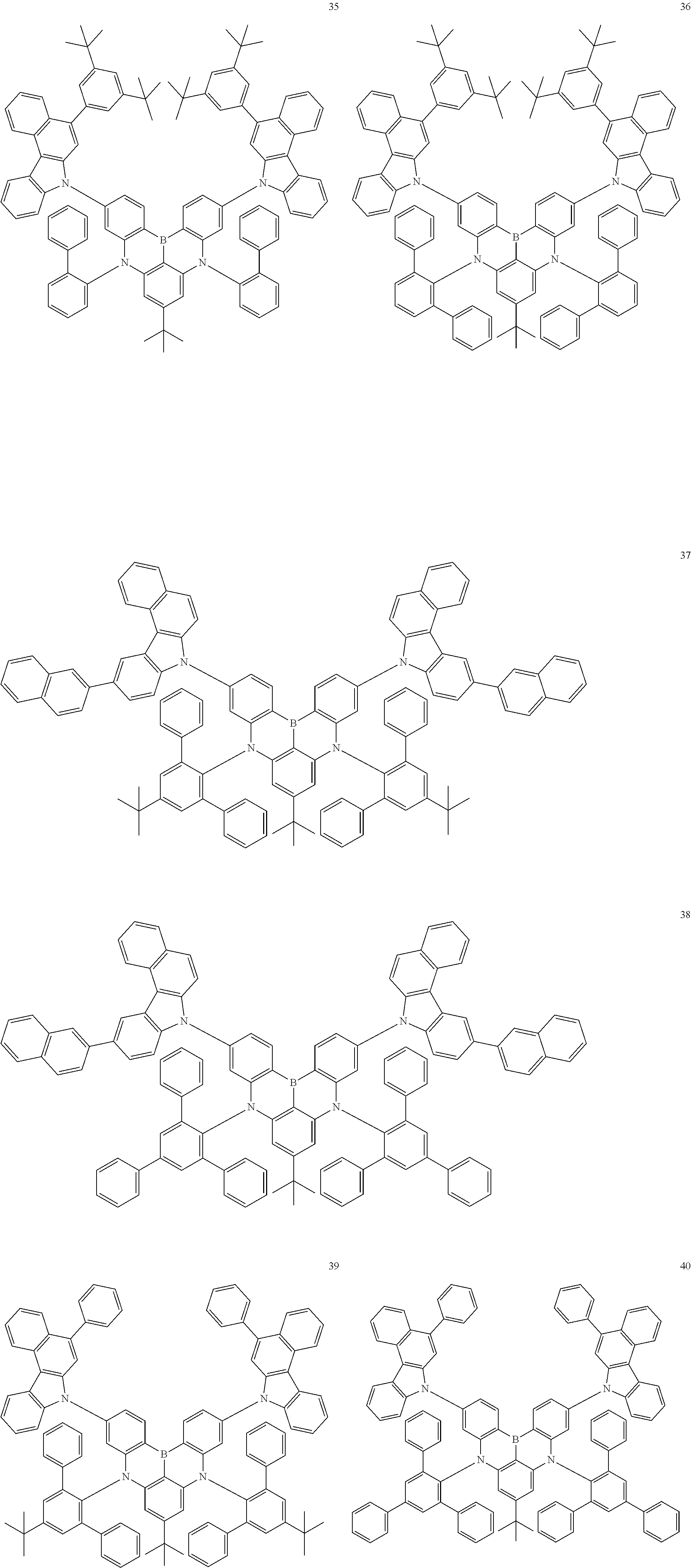 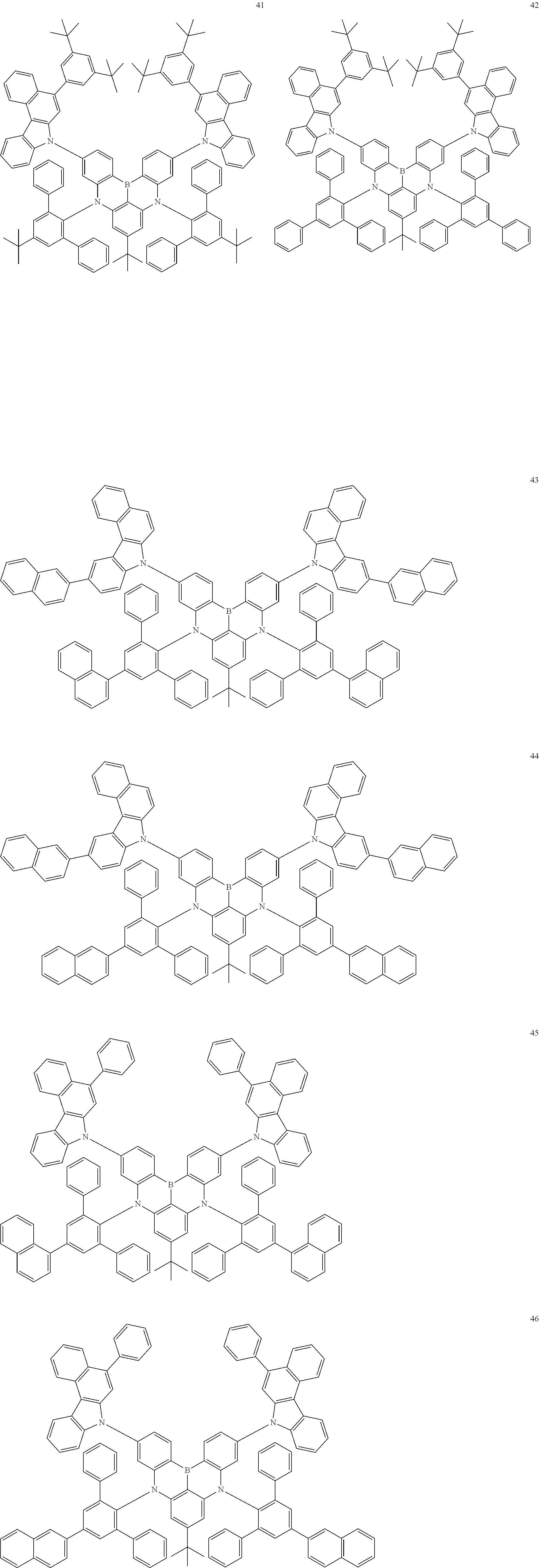 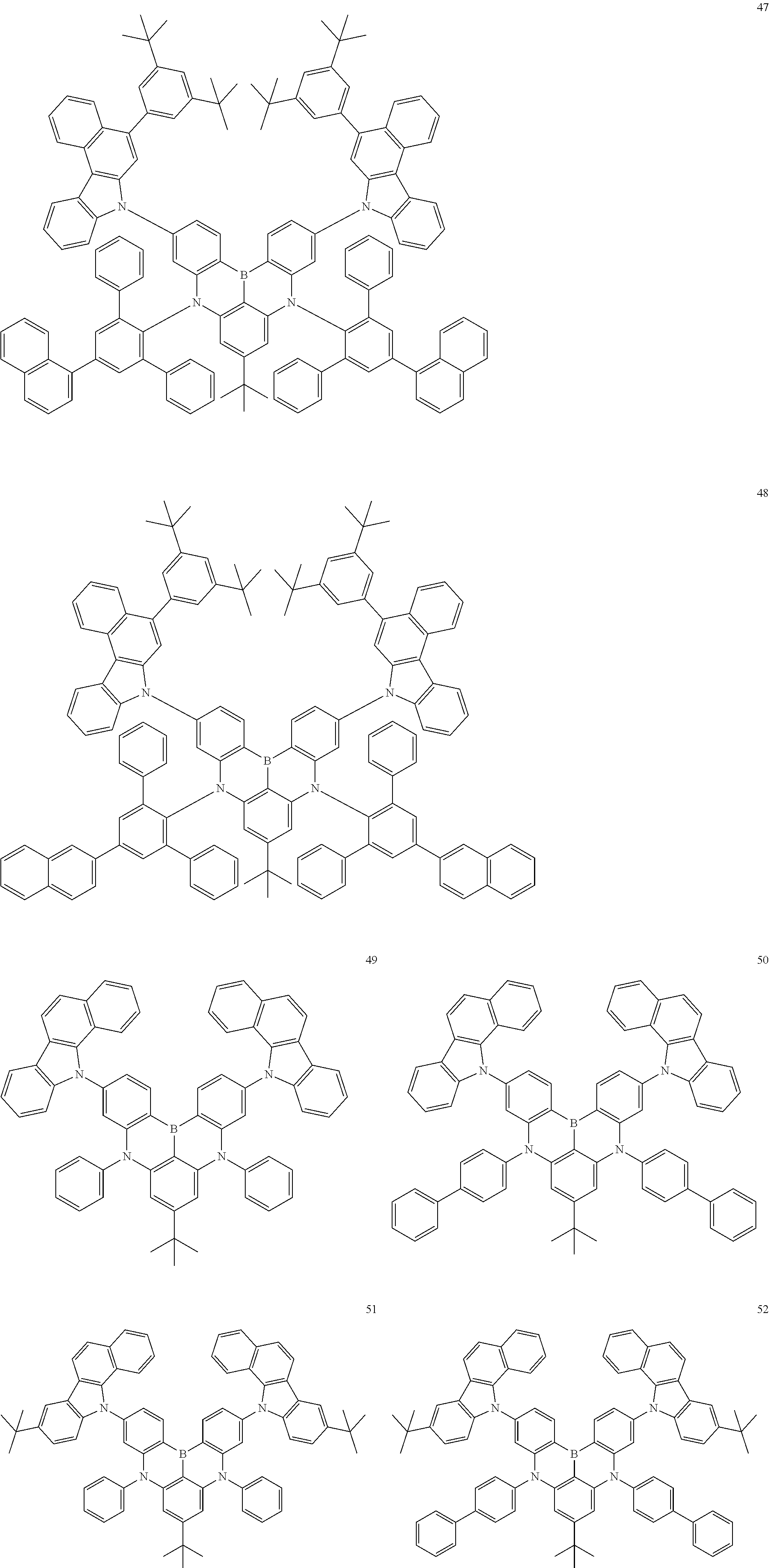 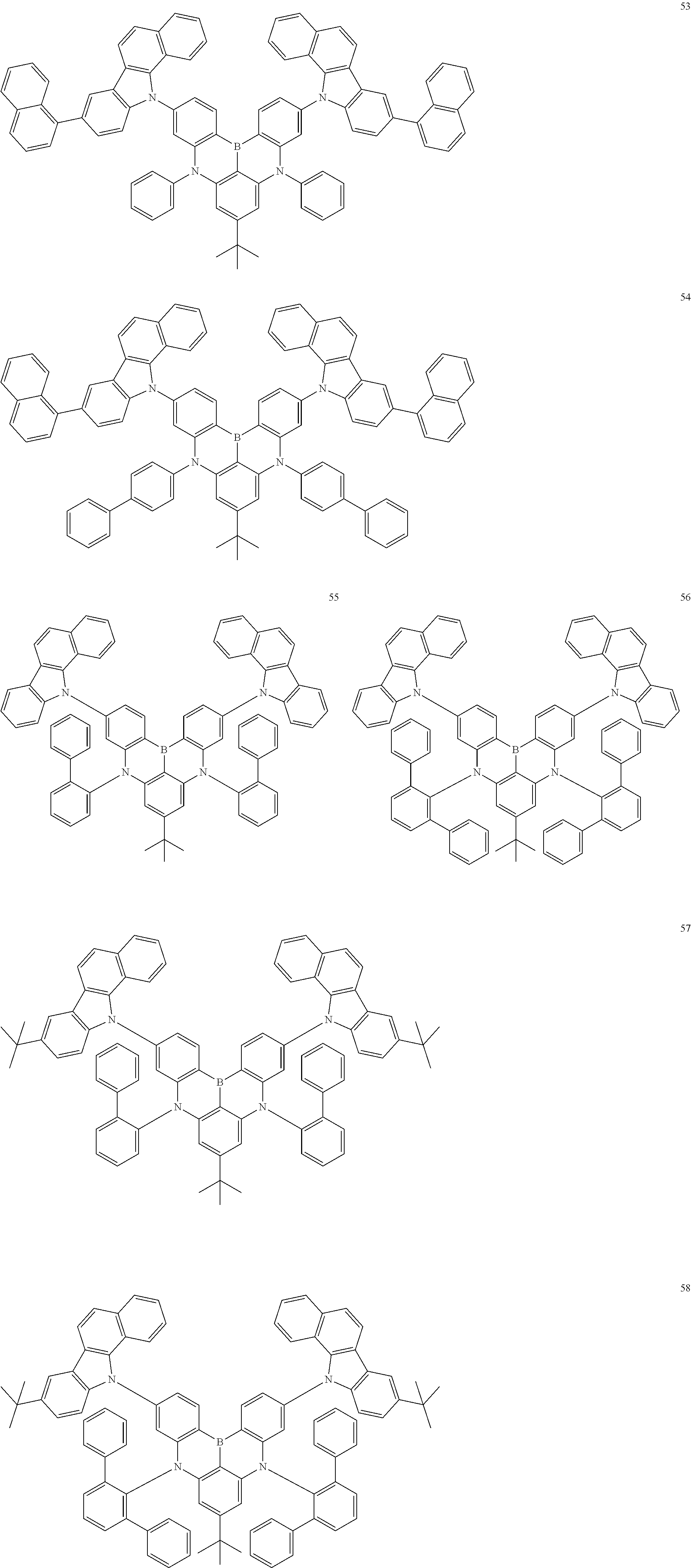 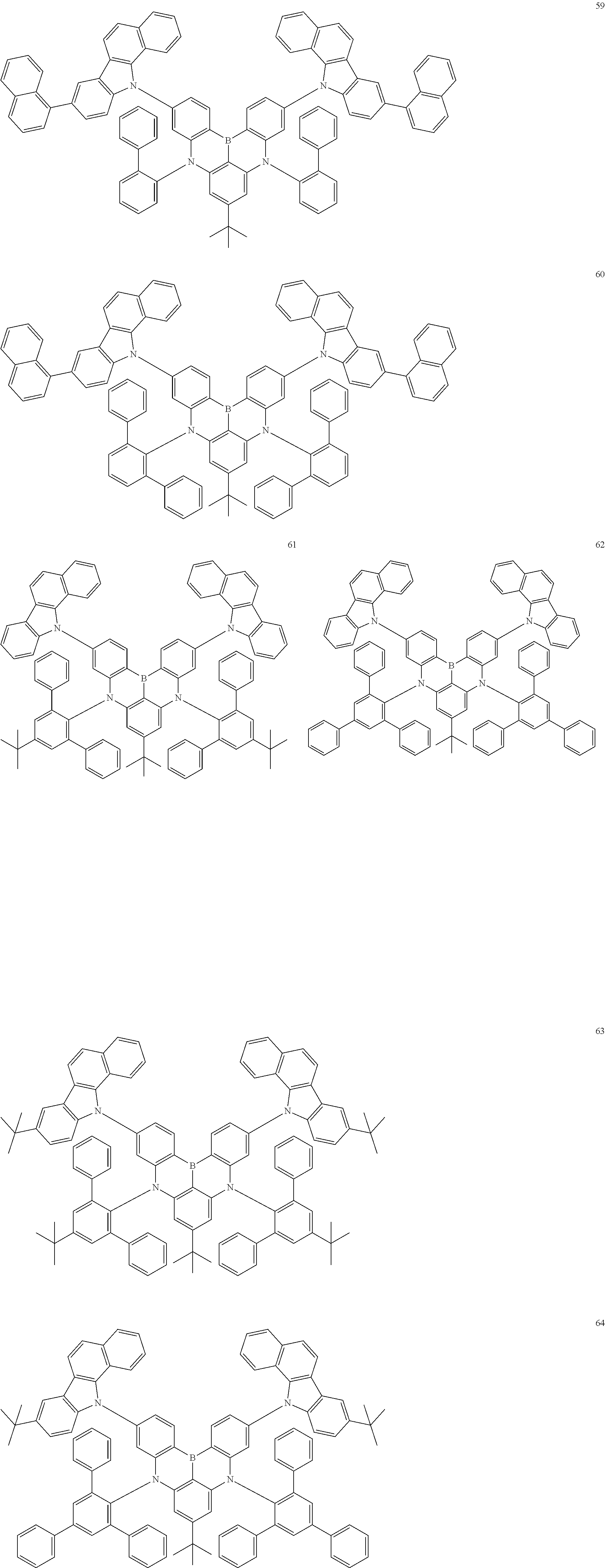 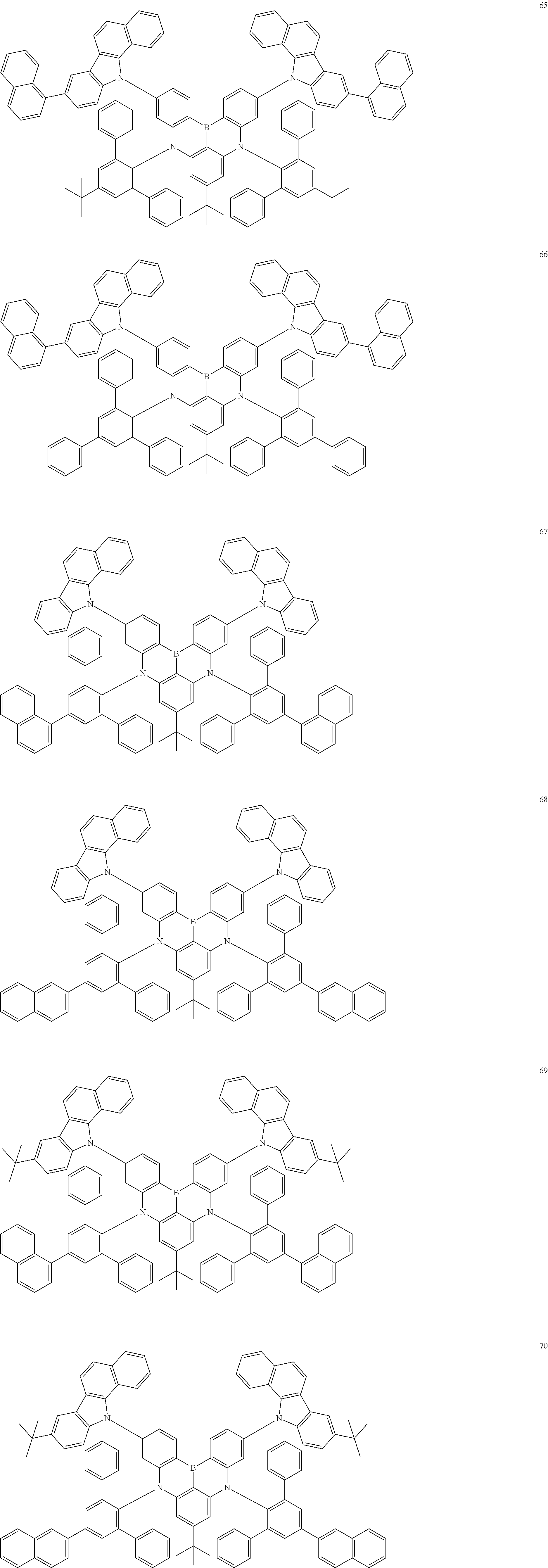 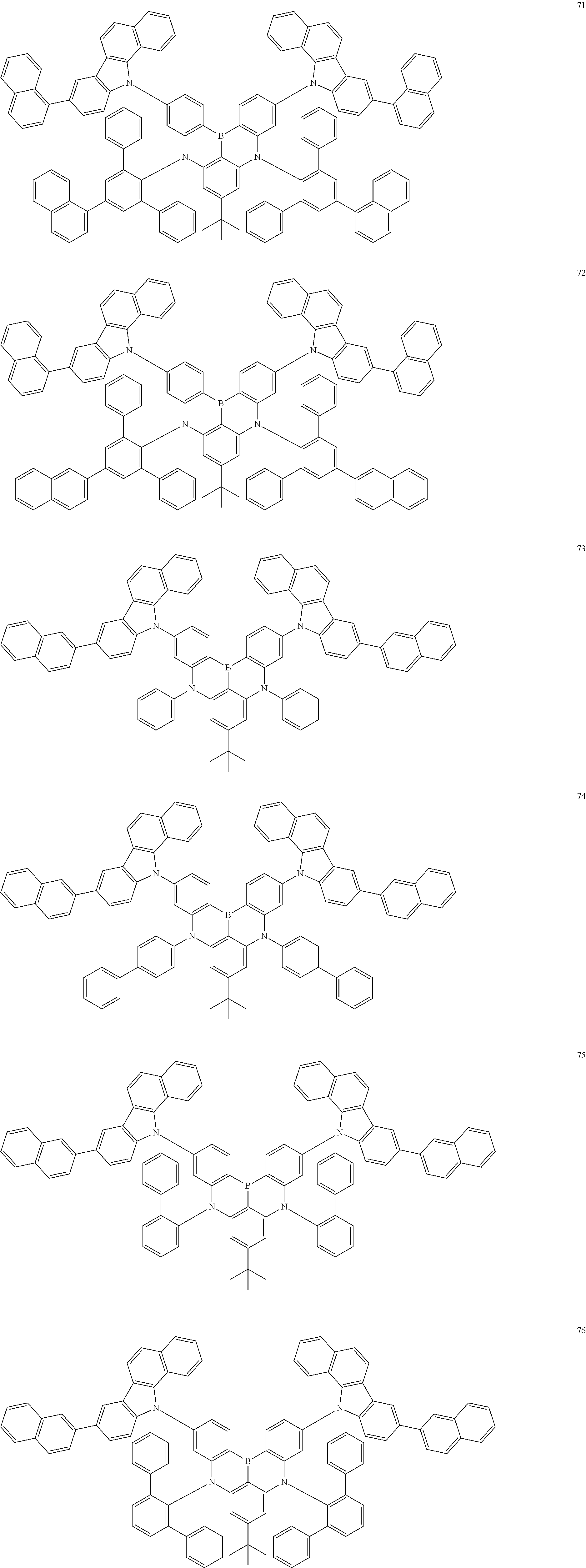 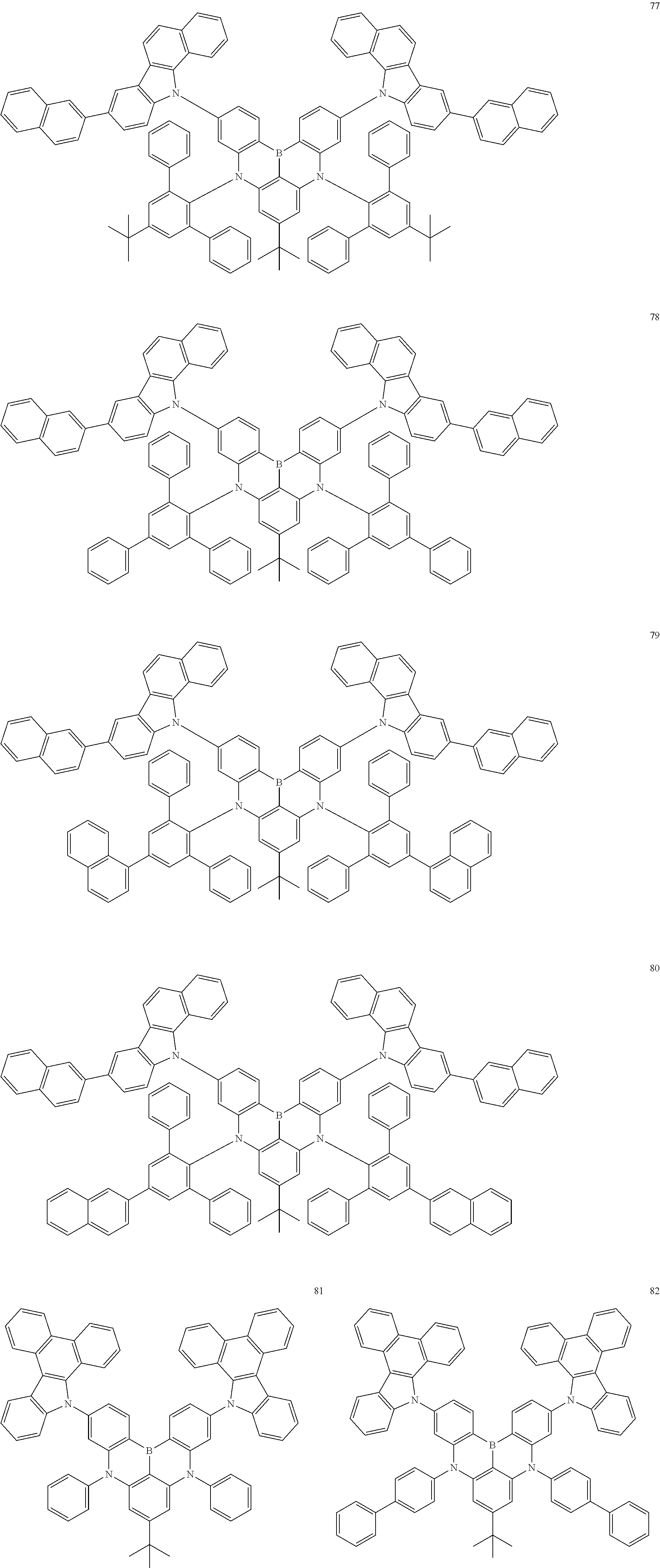 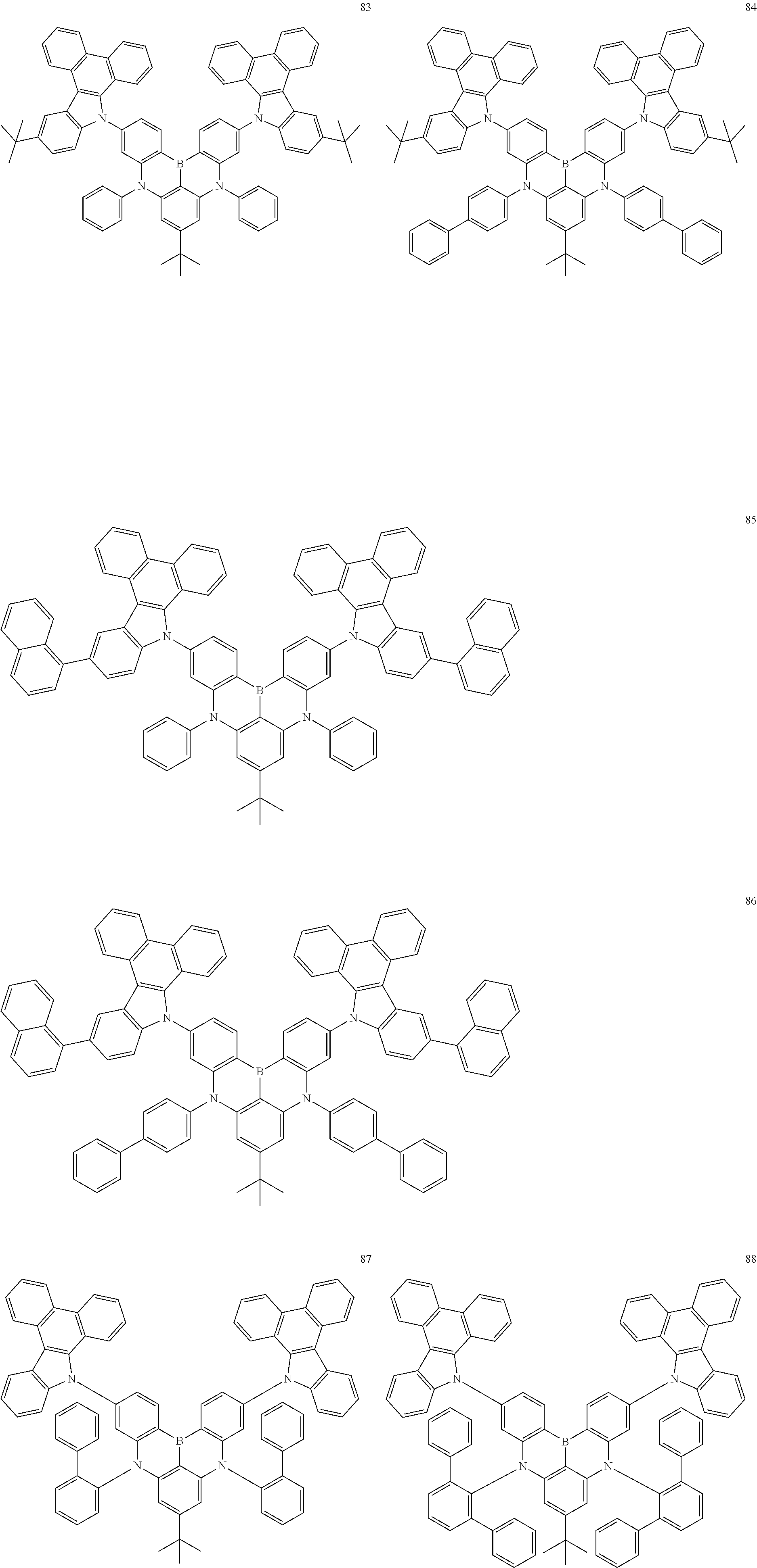 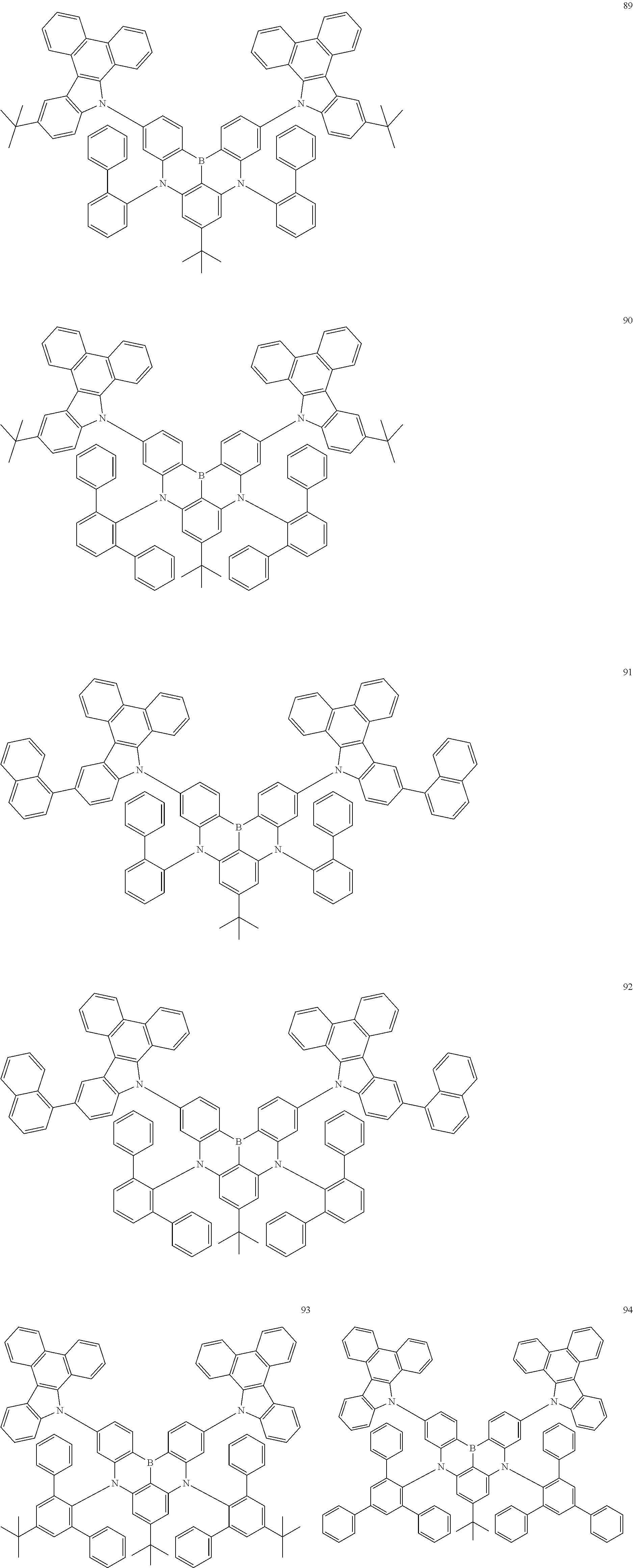 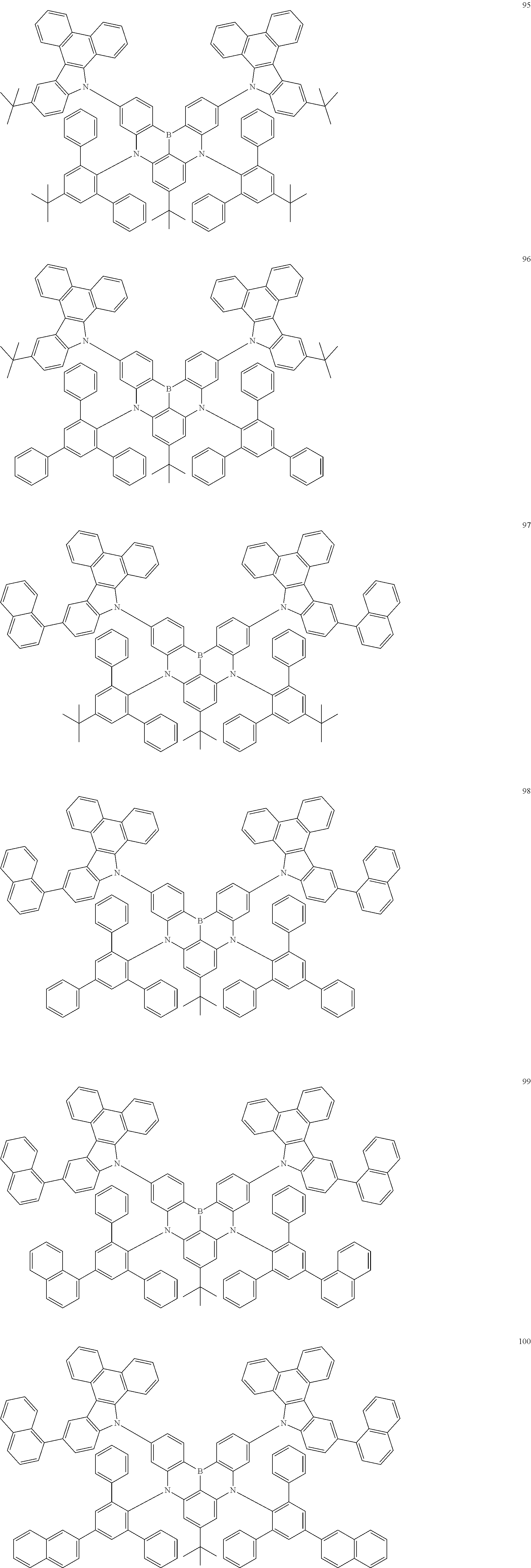 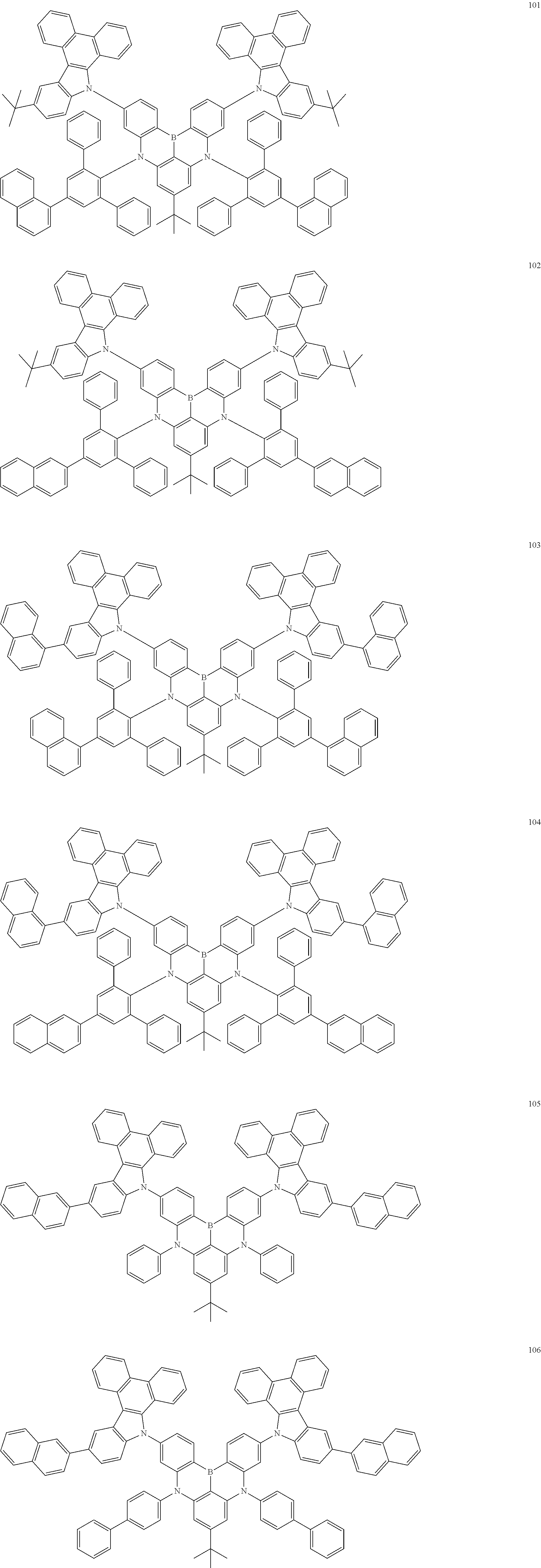 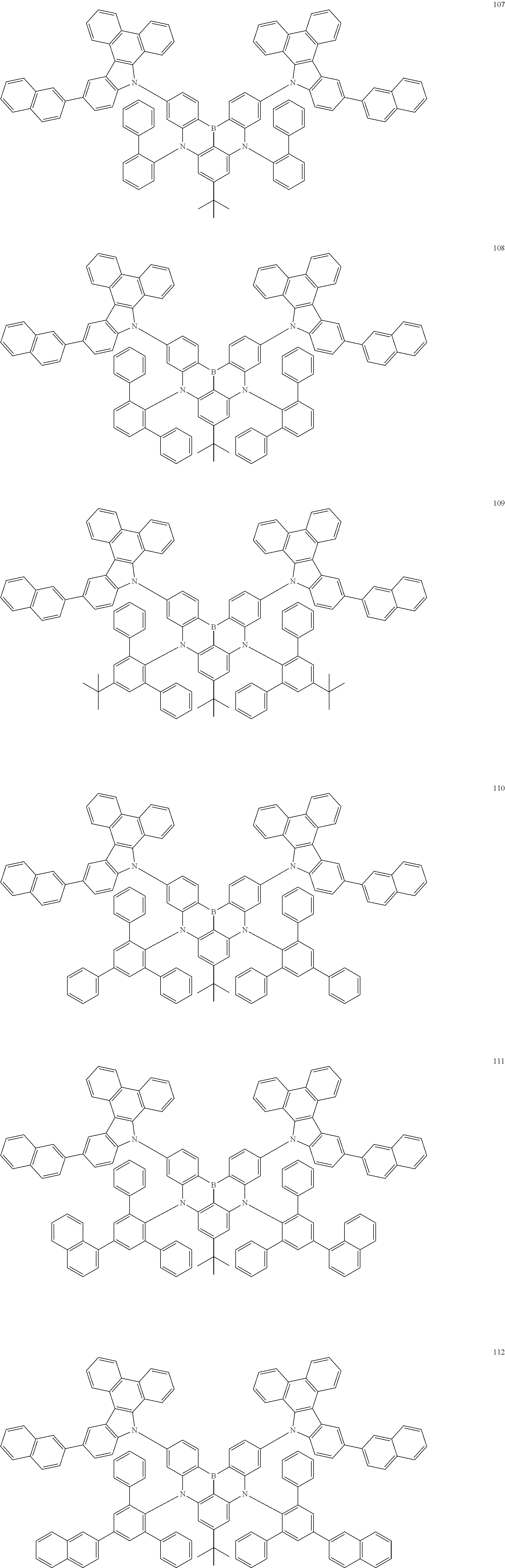 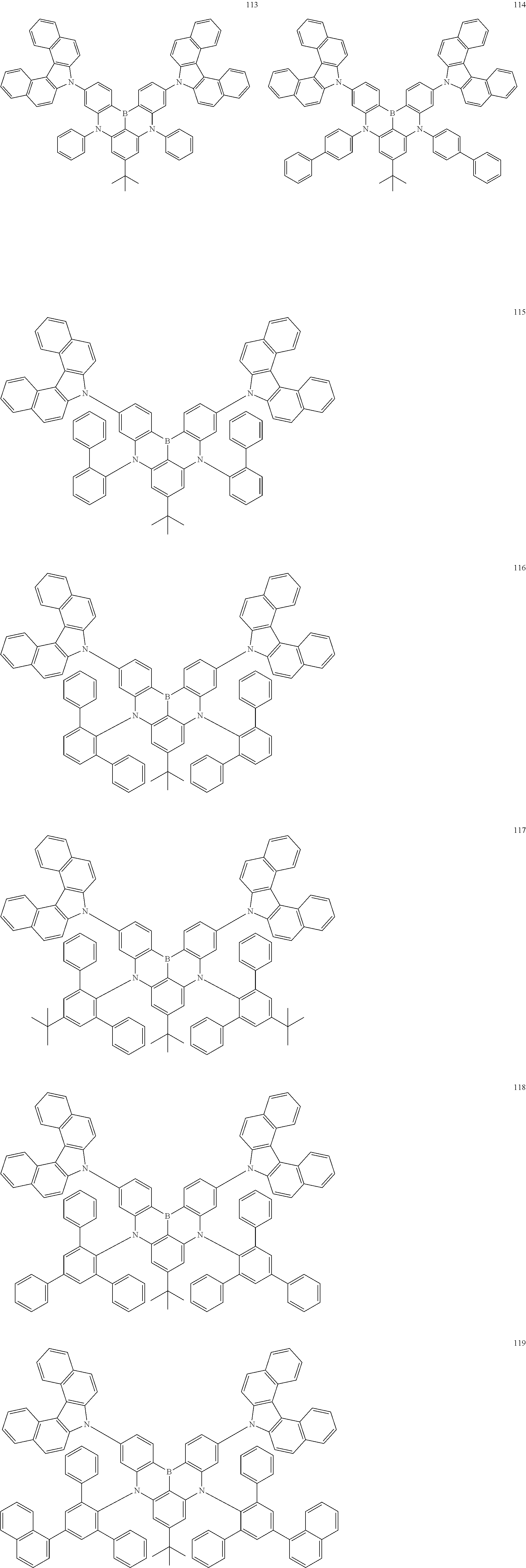 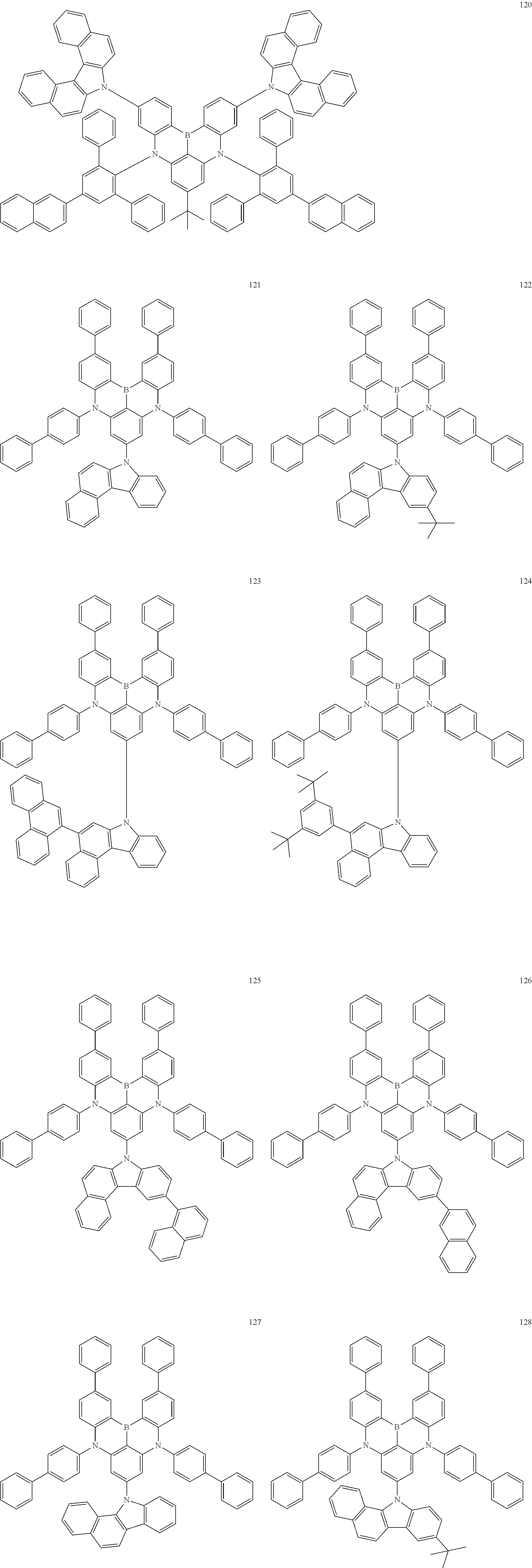 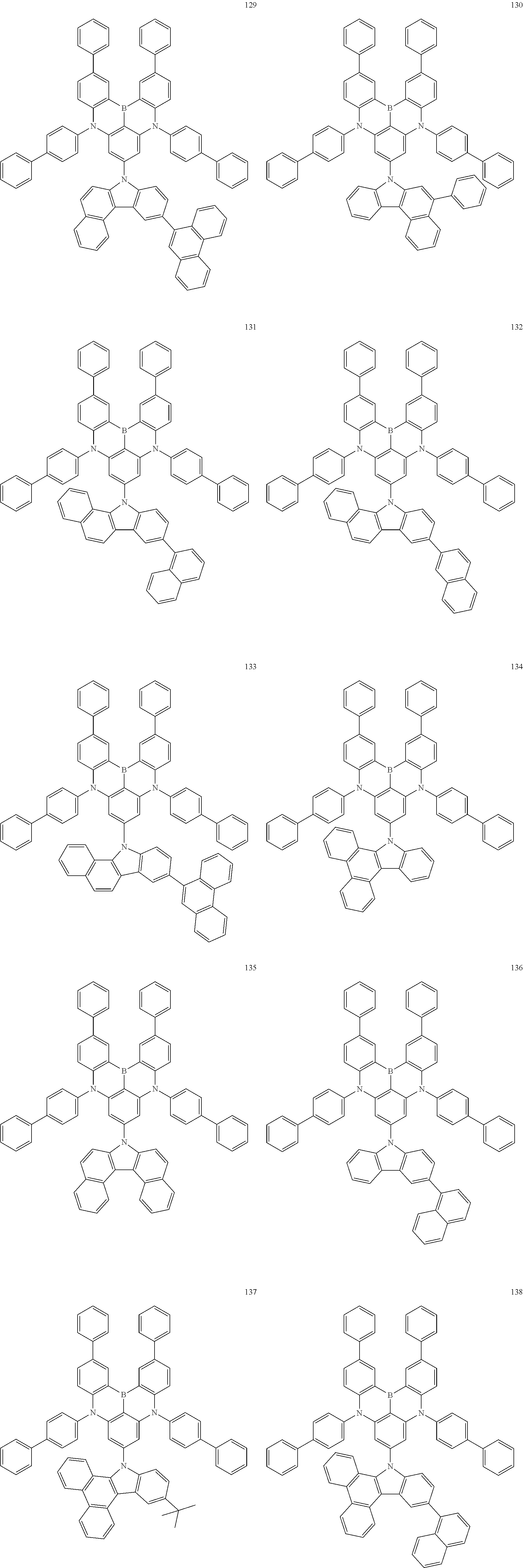 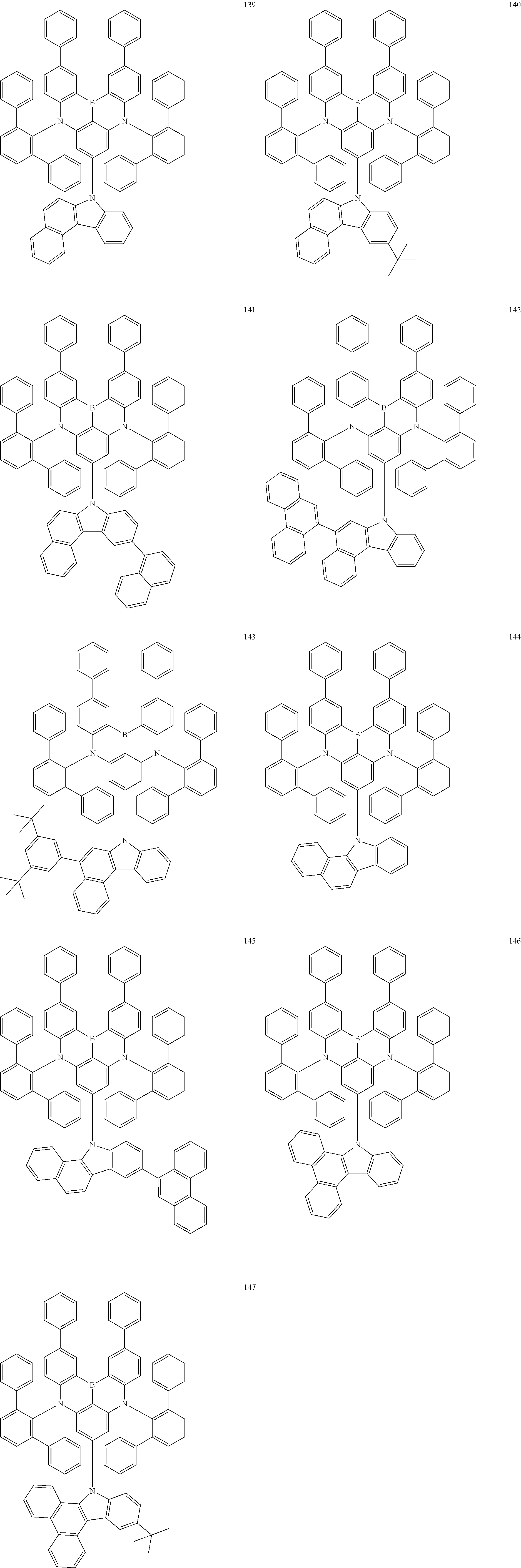 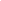 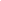 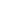 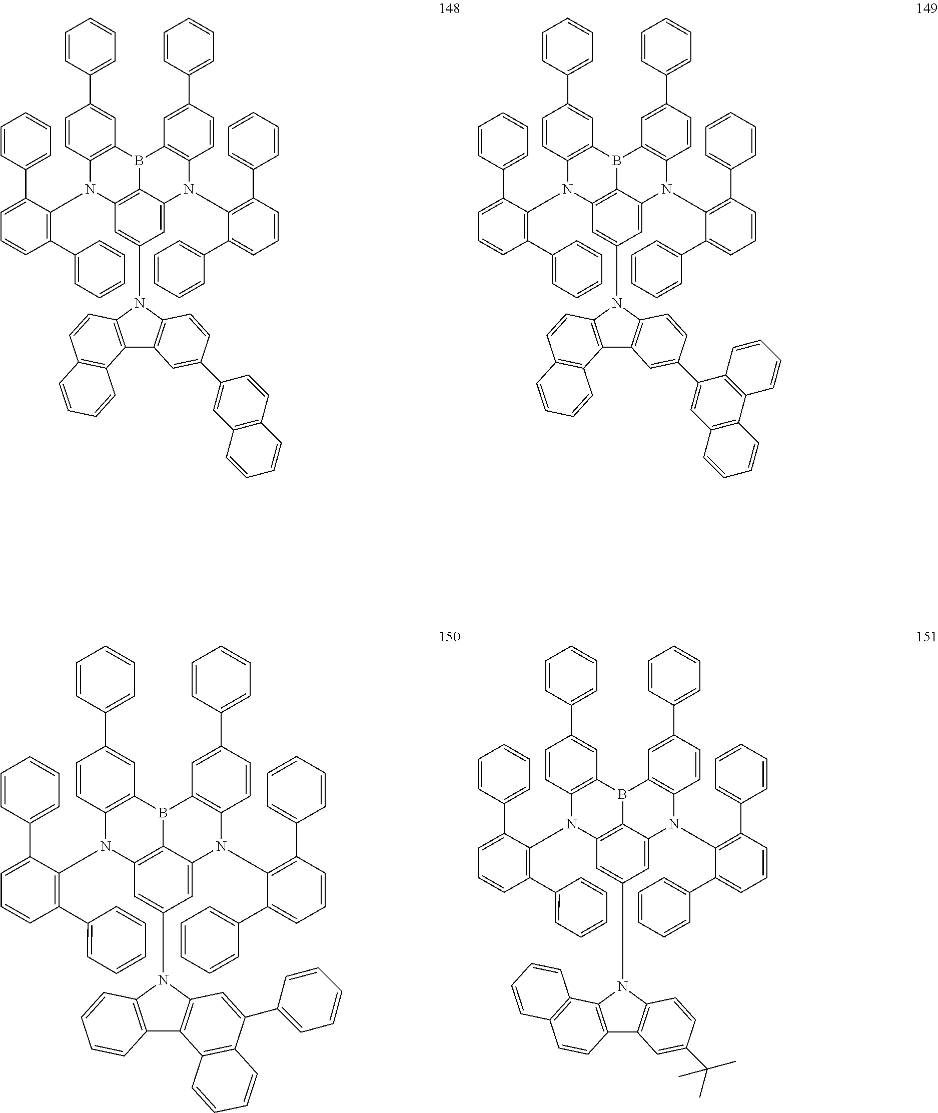 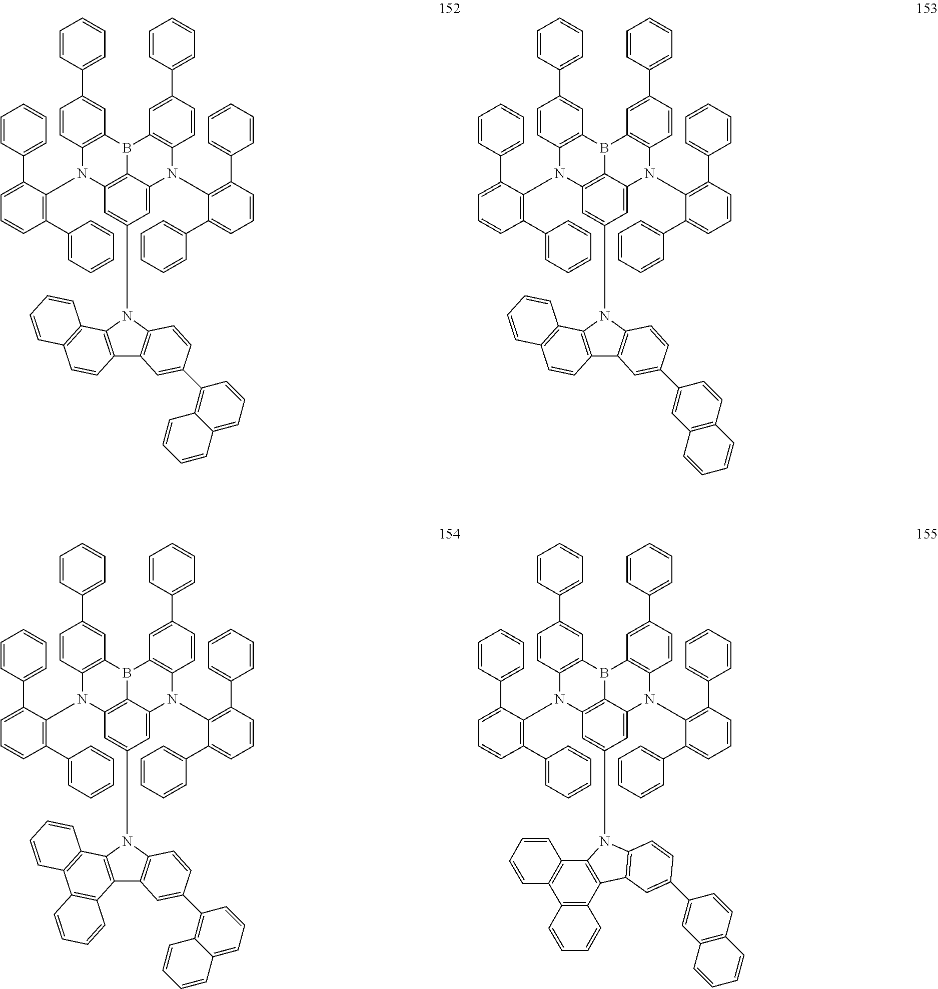 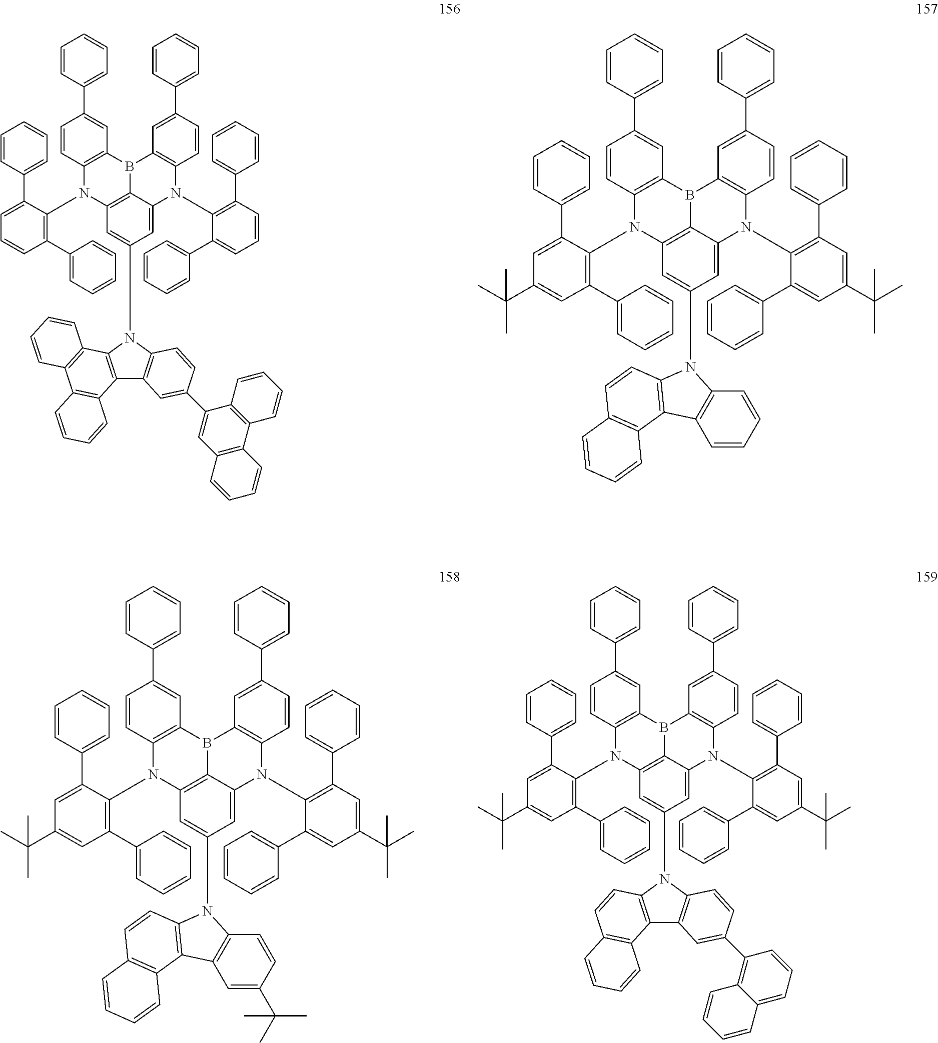 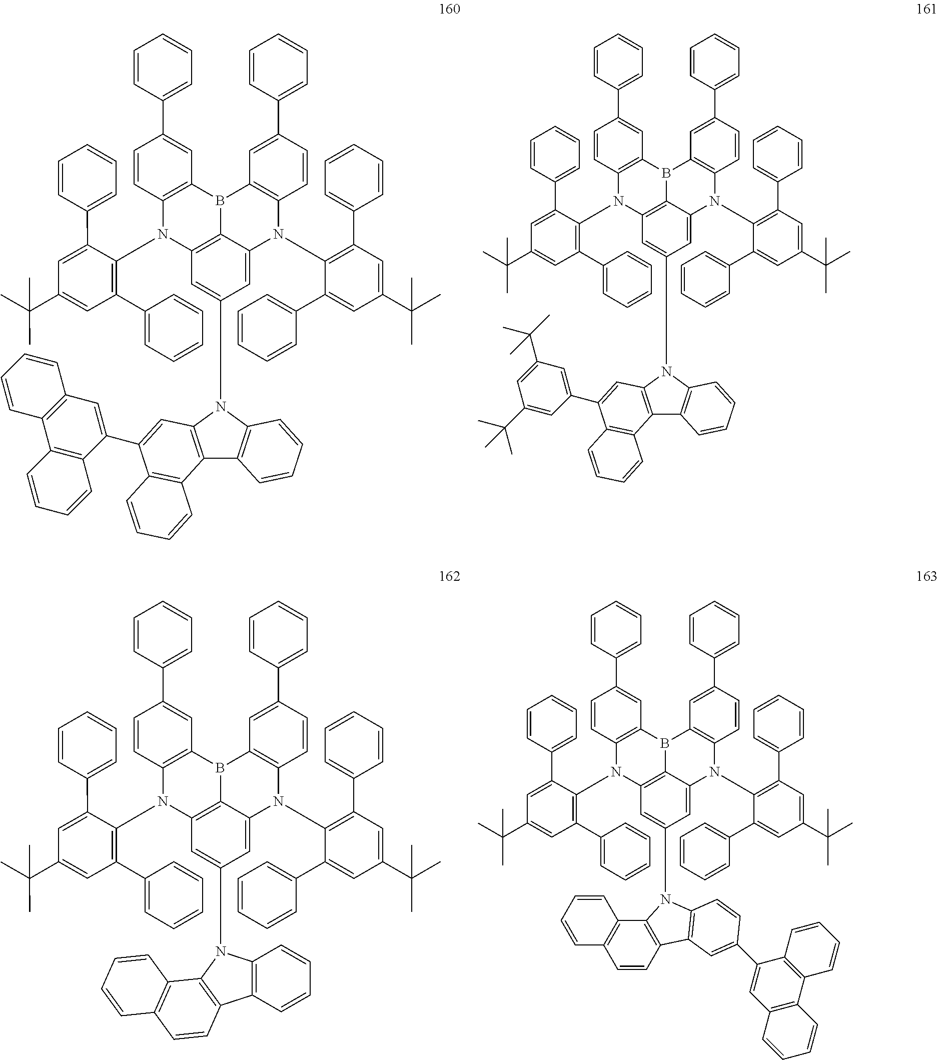 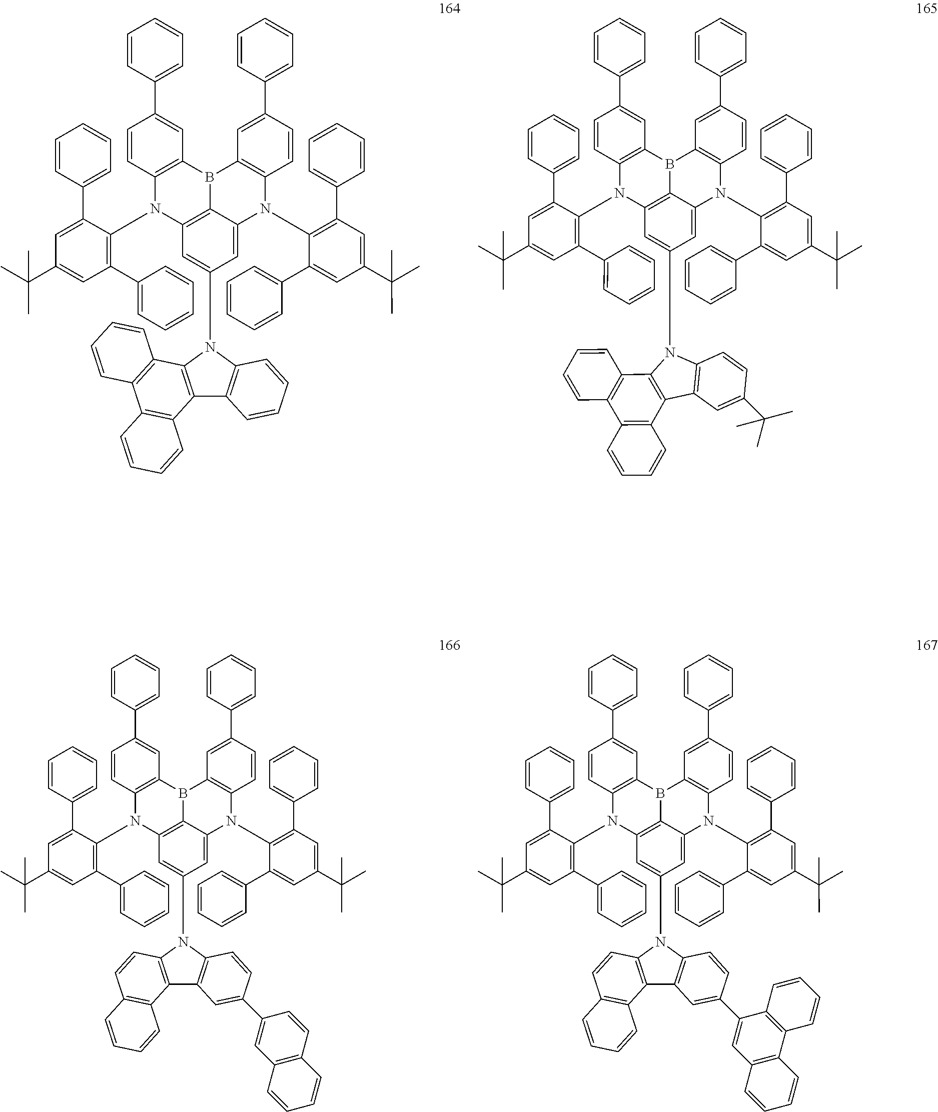 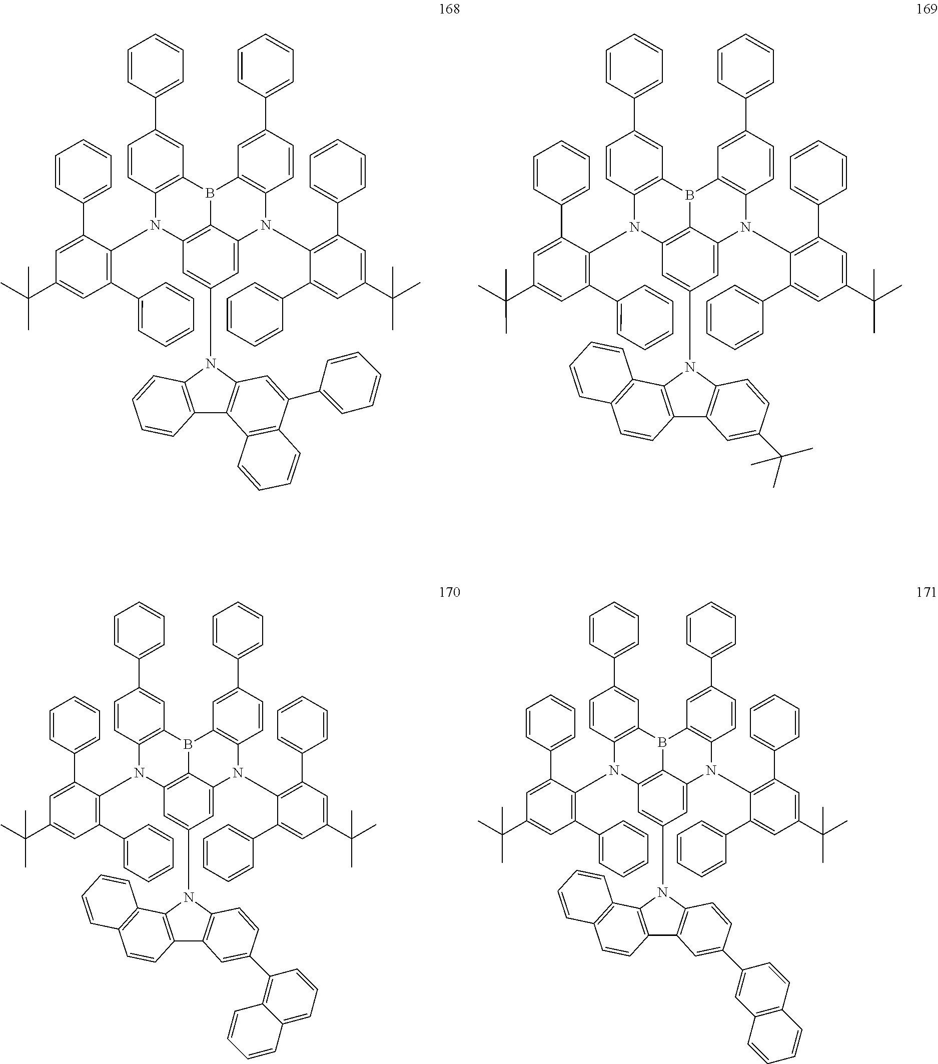 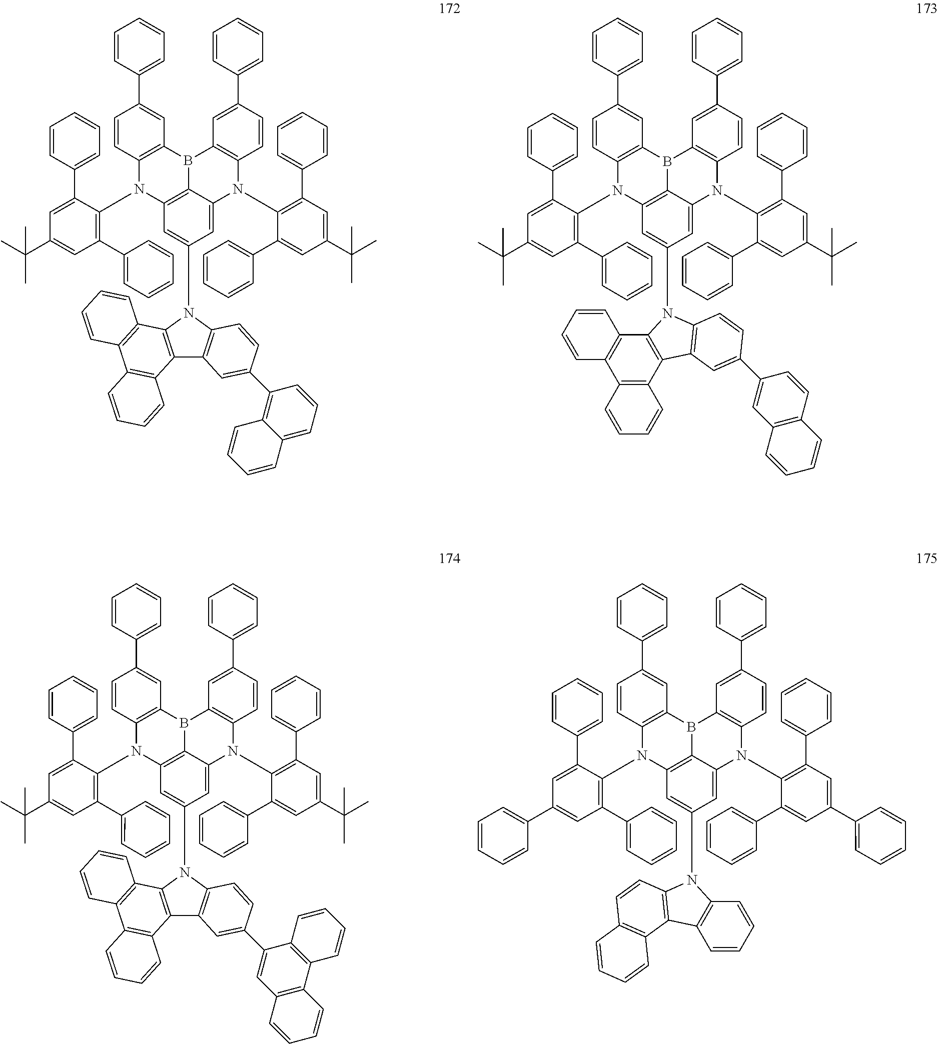 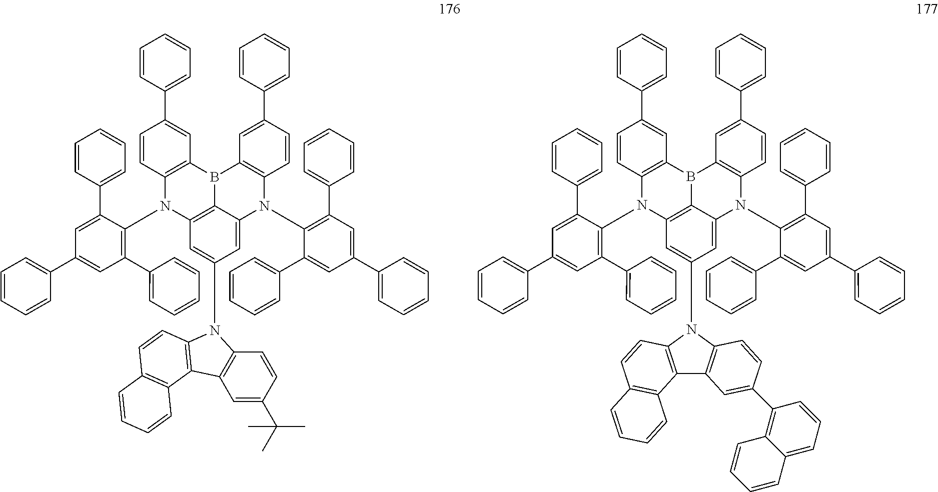 [SMILES: CC(C)(C)c1ccc2c(c1)c1c3ccccc3ccc1n2-c1cc2c3c(c1)N(c1c(-c4ccccc4)cc(-c4ccccc4)cc1-c1ccccc1)c1ccc(-c4ccccc4)cc1B3c1cc(-c3ccccc3)ccc1N2c1c(-c2ccccc2)cc(-c2ccccc2)cc1-c1ccccc1 ; c1ccc(-c2ccc3c(c2)B2c4cc(-c5ccccc5)ccc4N(c4c(-c5ccccc5)cc(-c5ccccc5)cc4-c4ccccc4)c4cc(-n5c6ccc(-c7cccc8ccccc78)cc6c6c7ccccc7ccc65)cc(c42)N3c2c(-c3ccccc3)cc(-c3ccccc3)cc2-c2ccccc2)cc1] 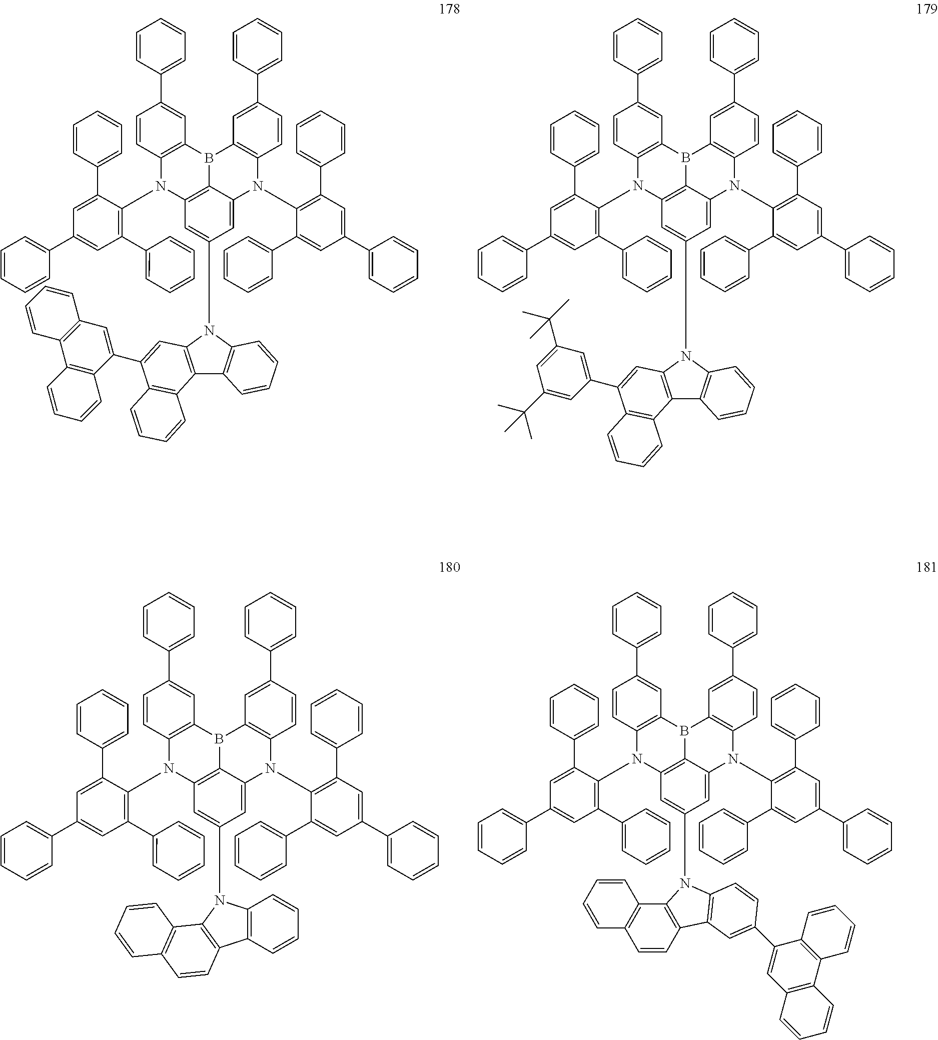 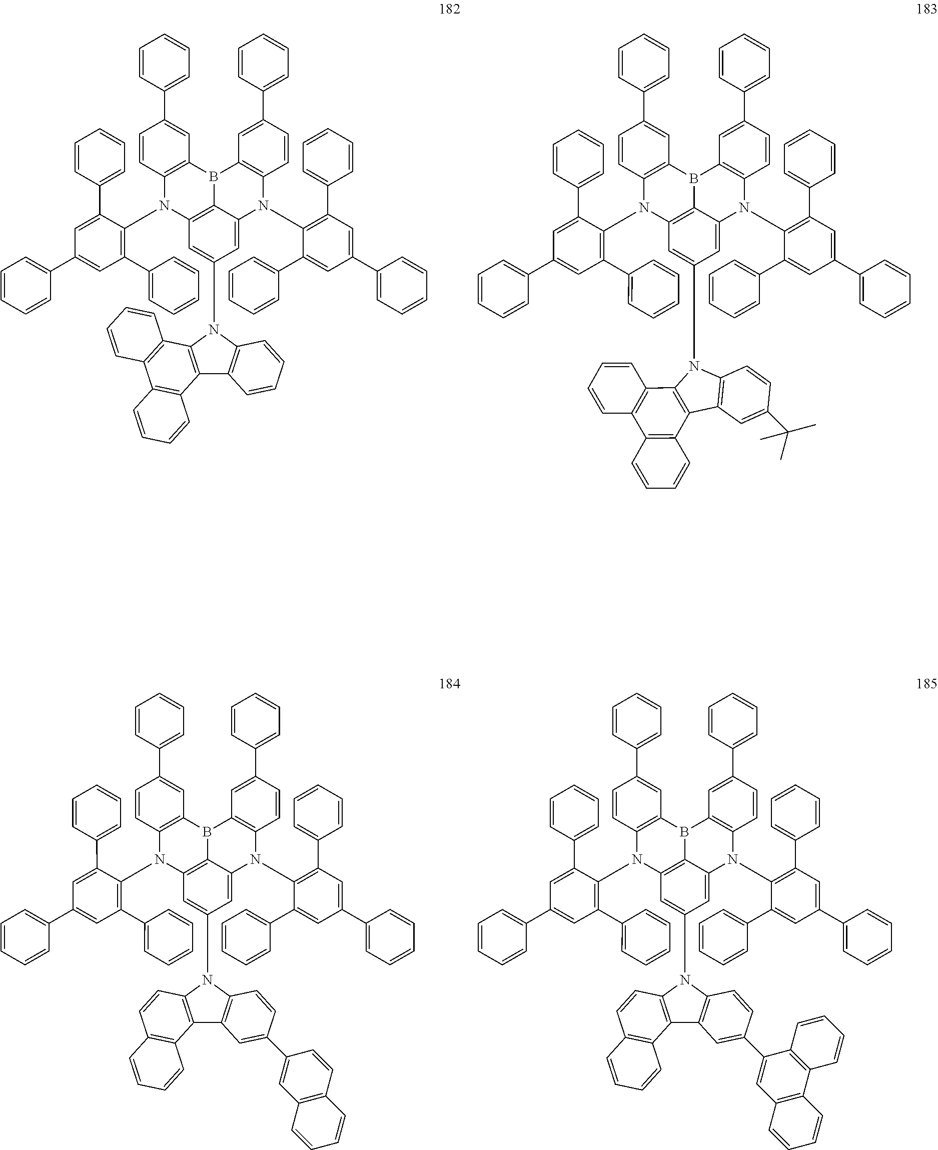 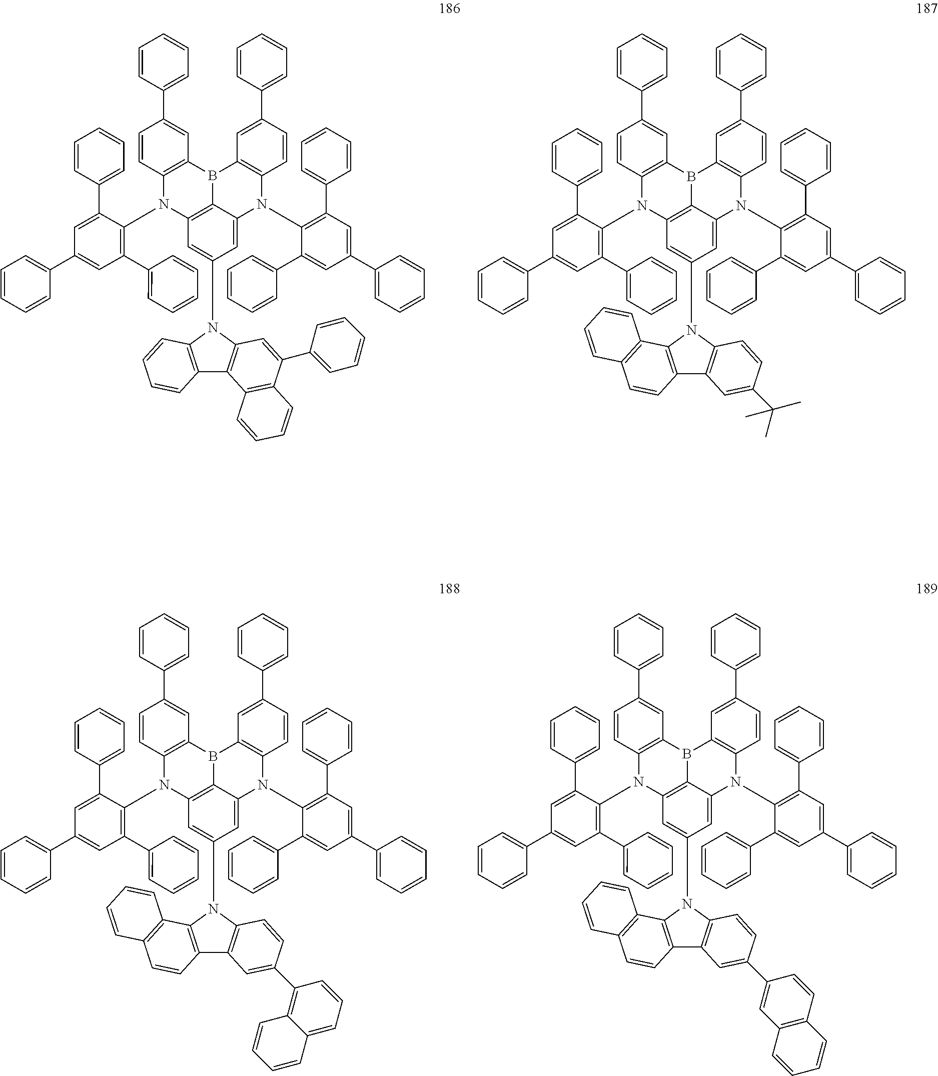 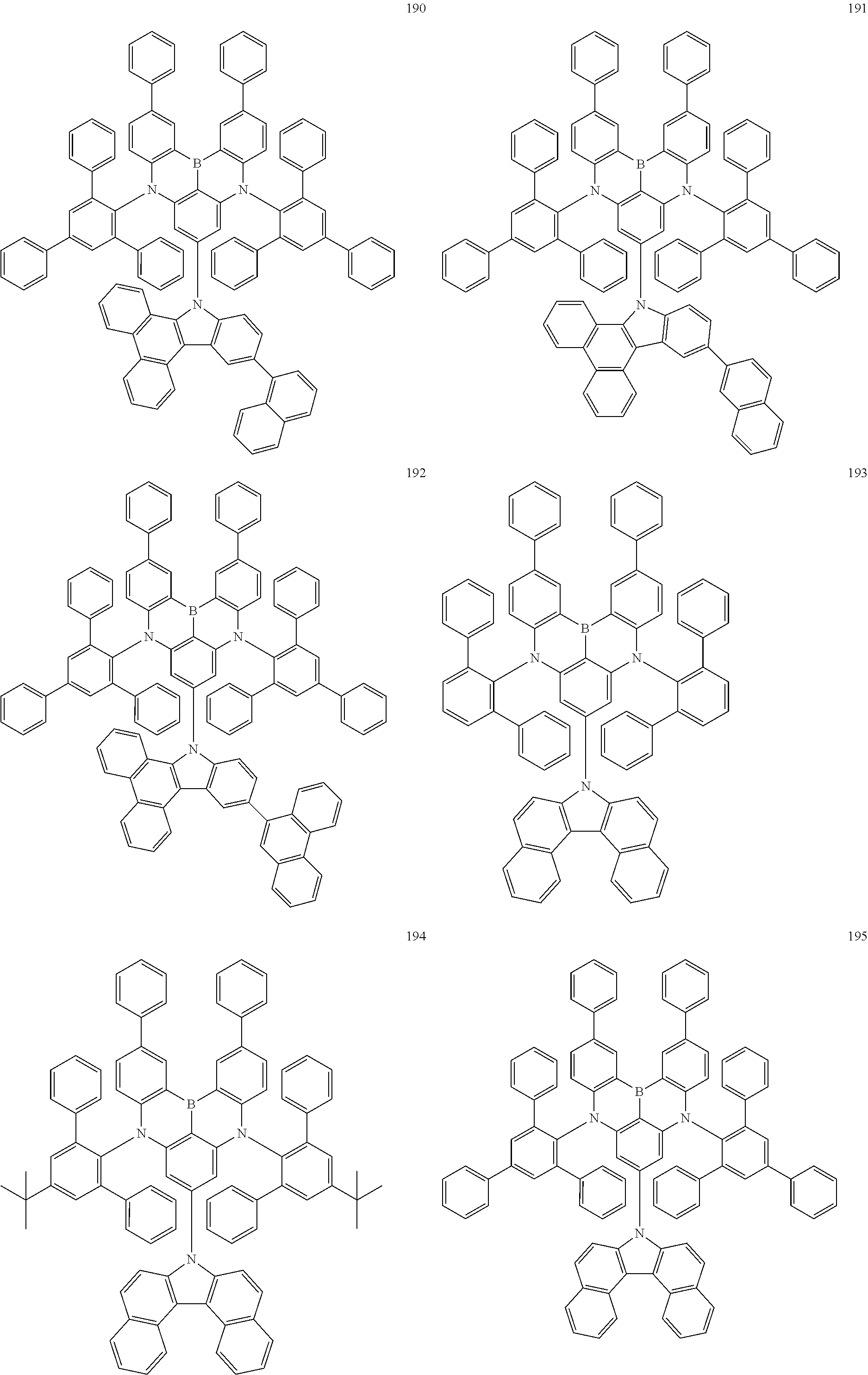 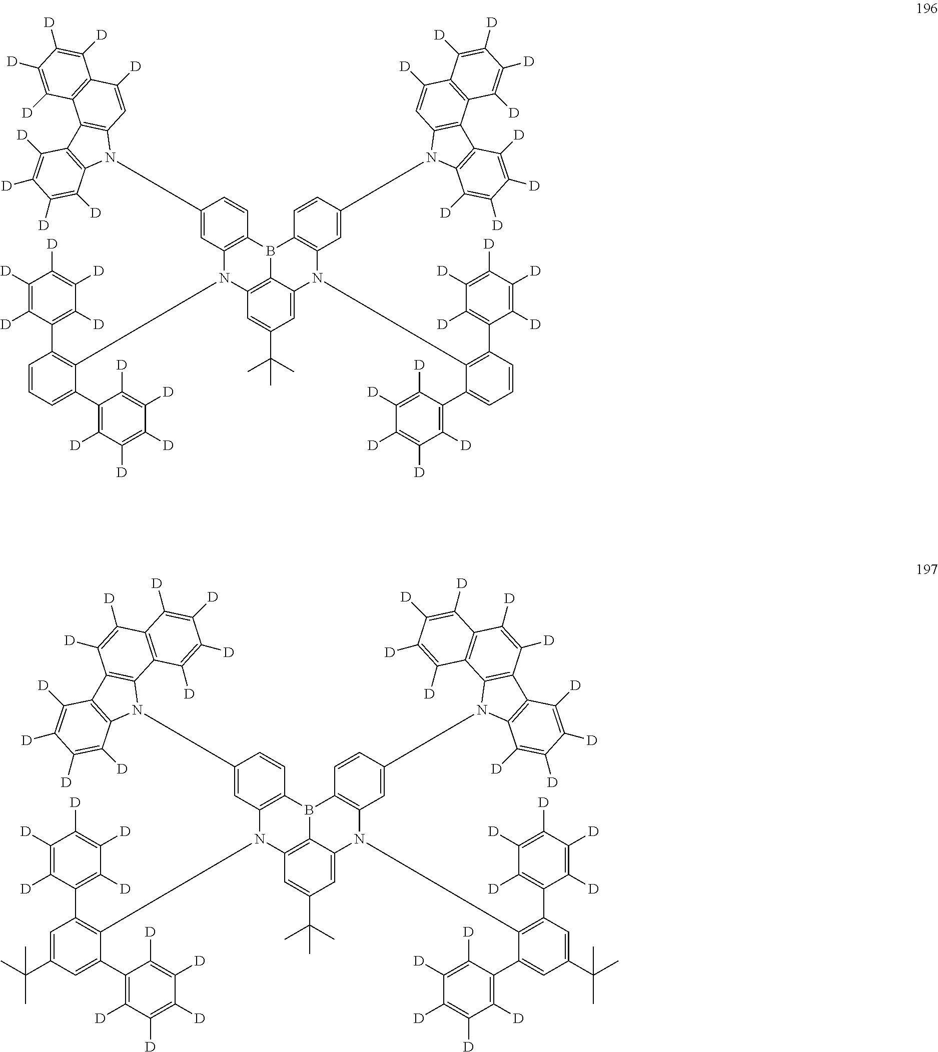 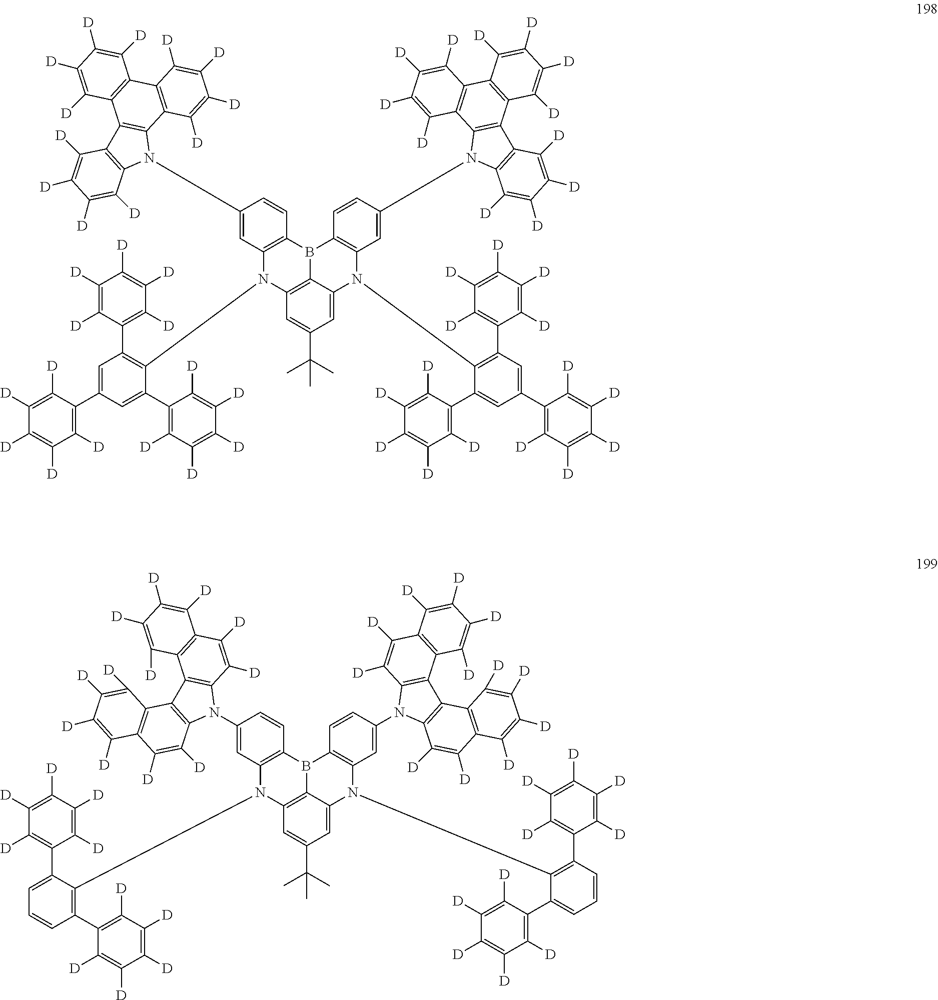 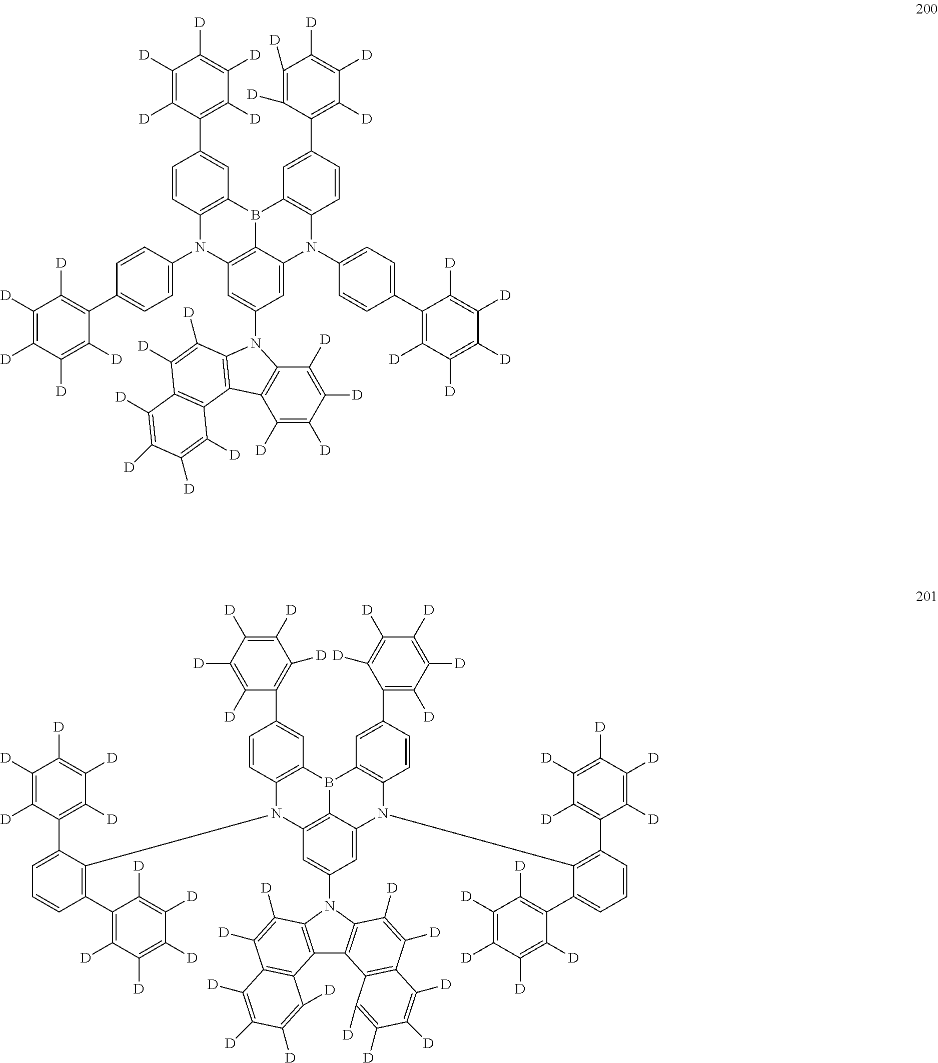 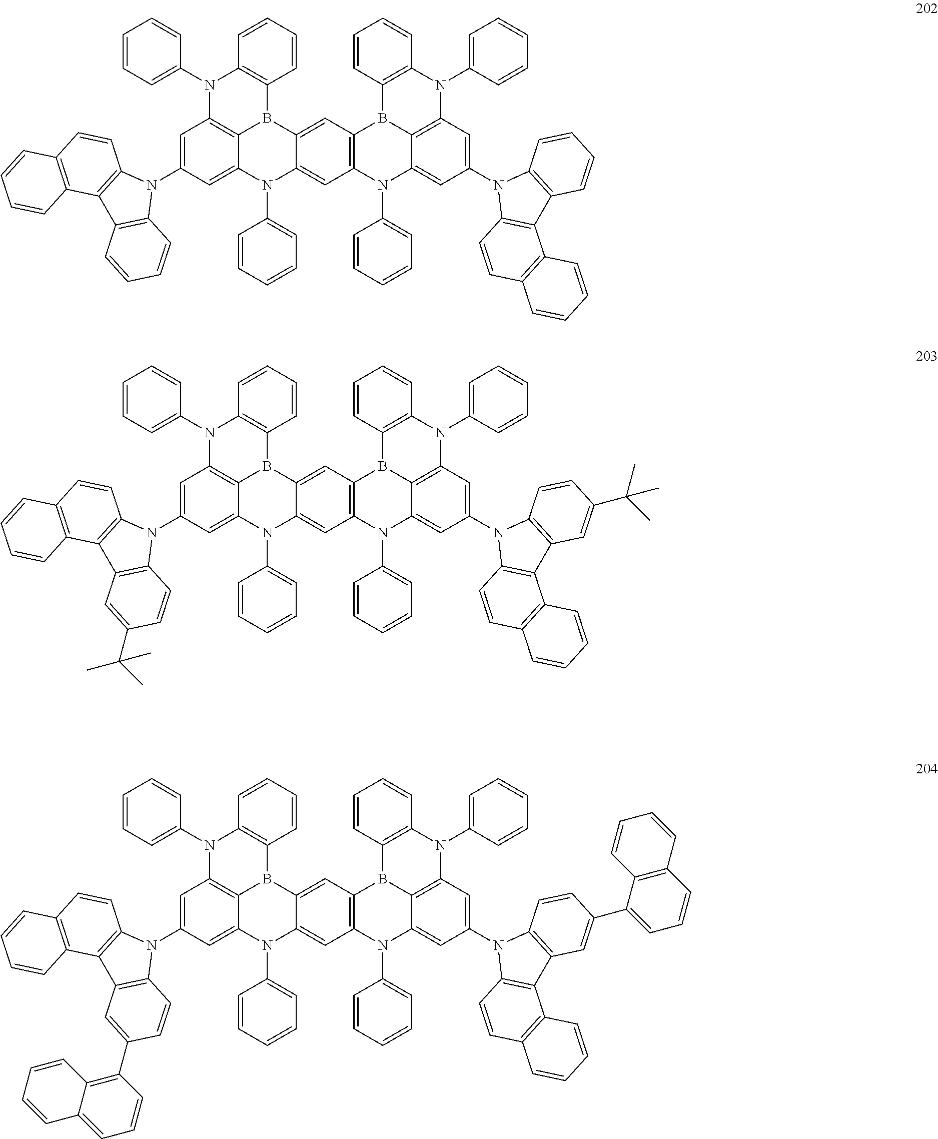 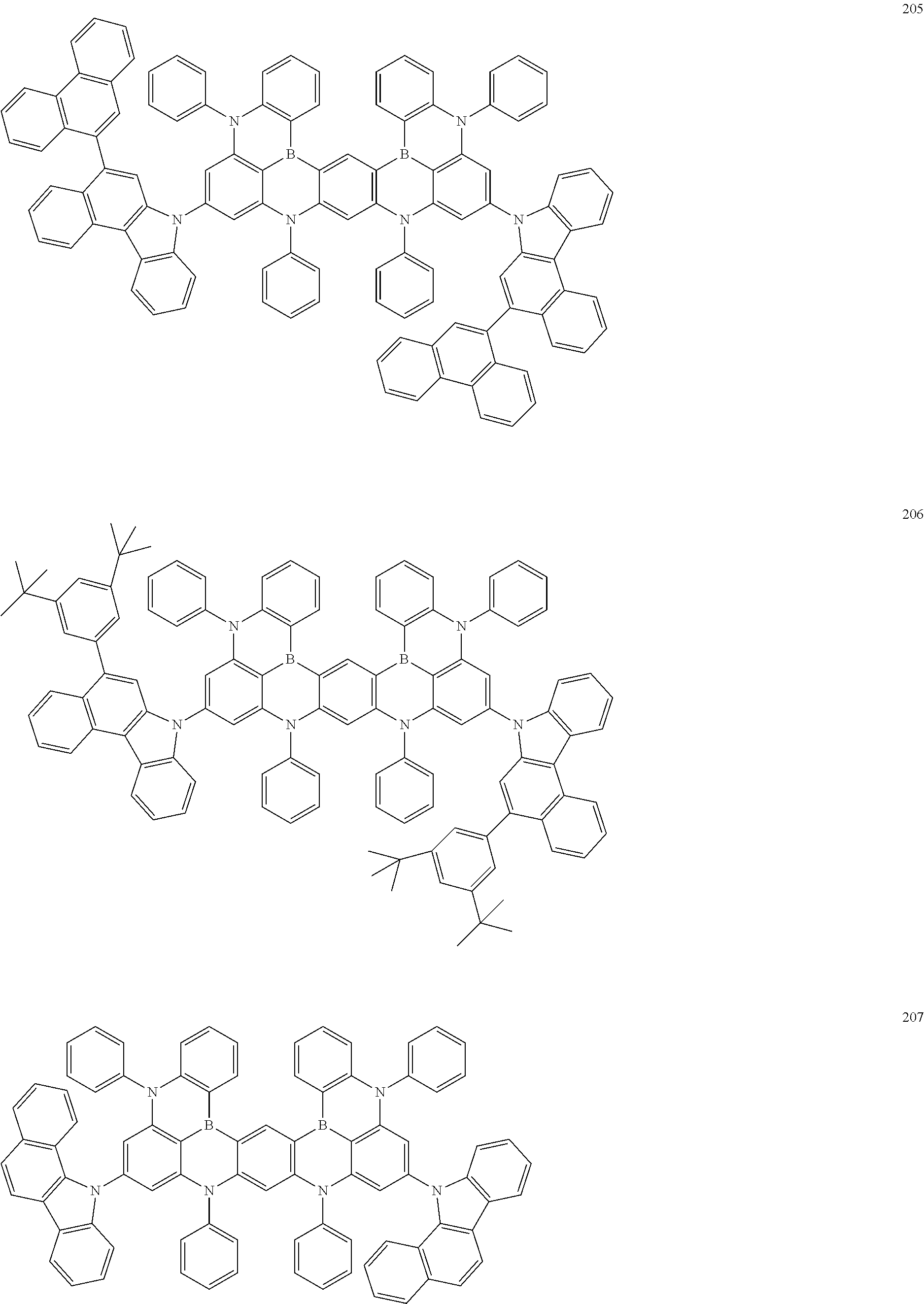 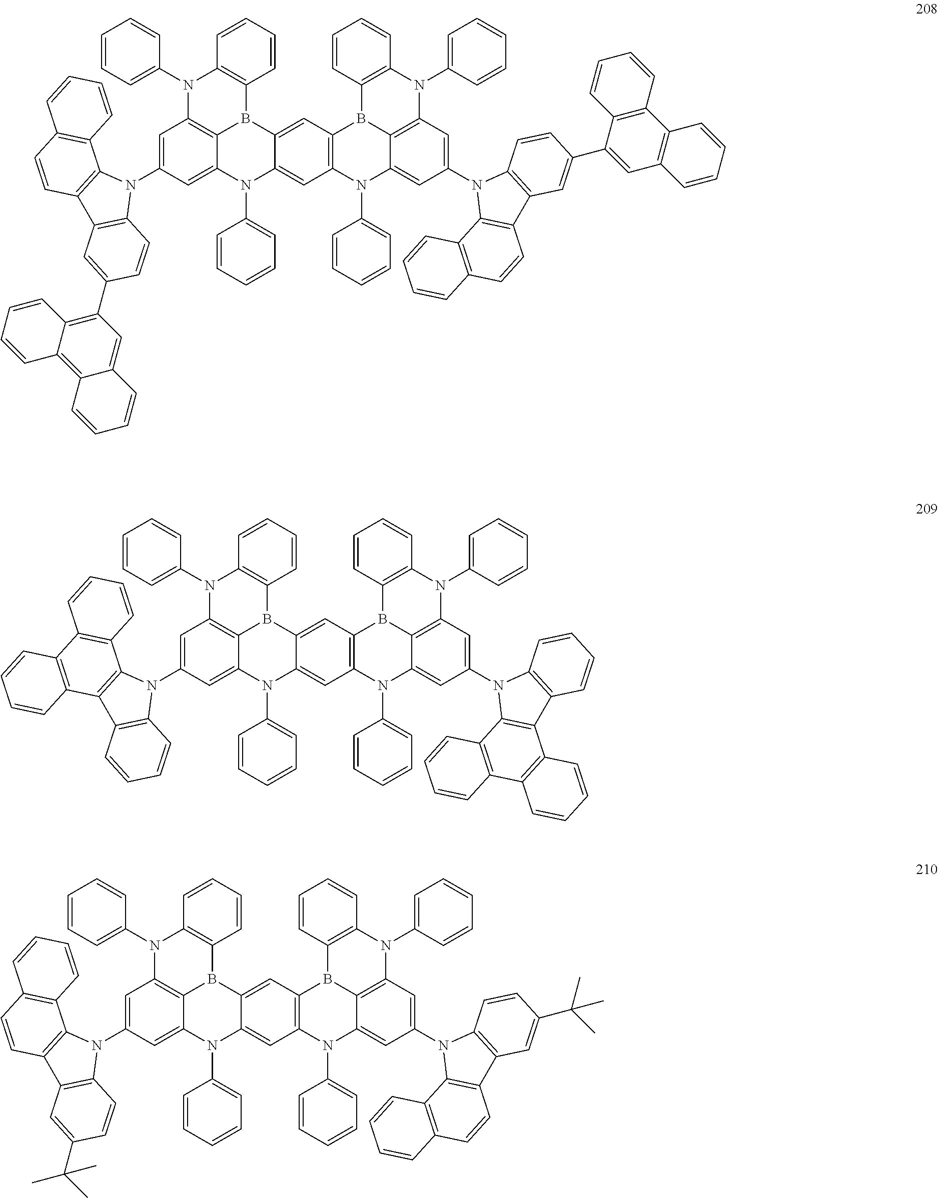 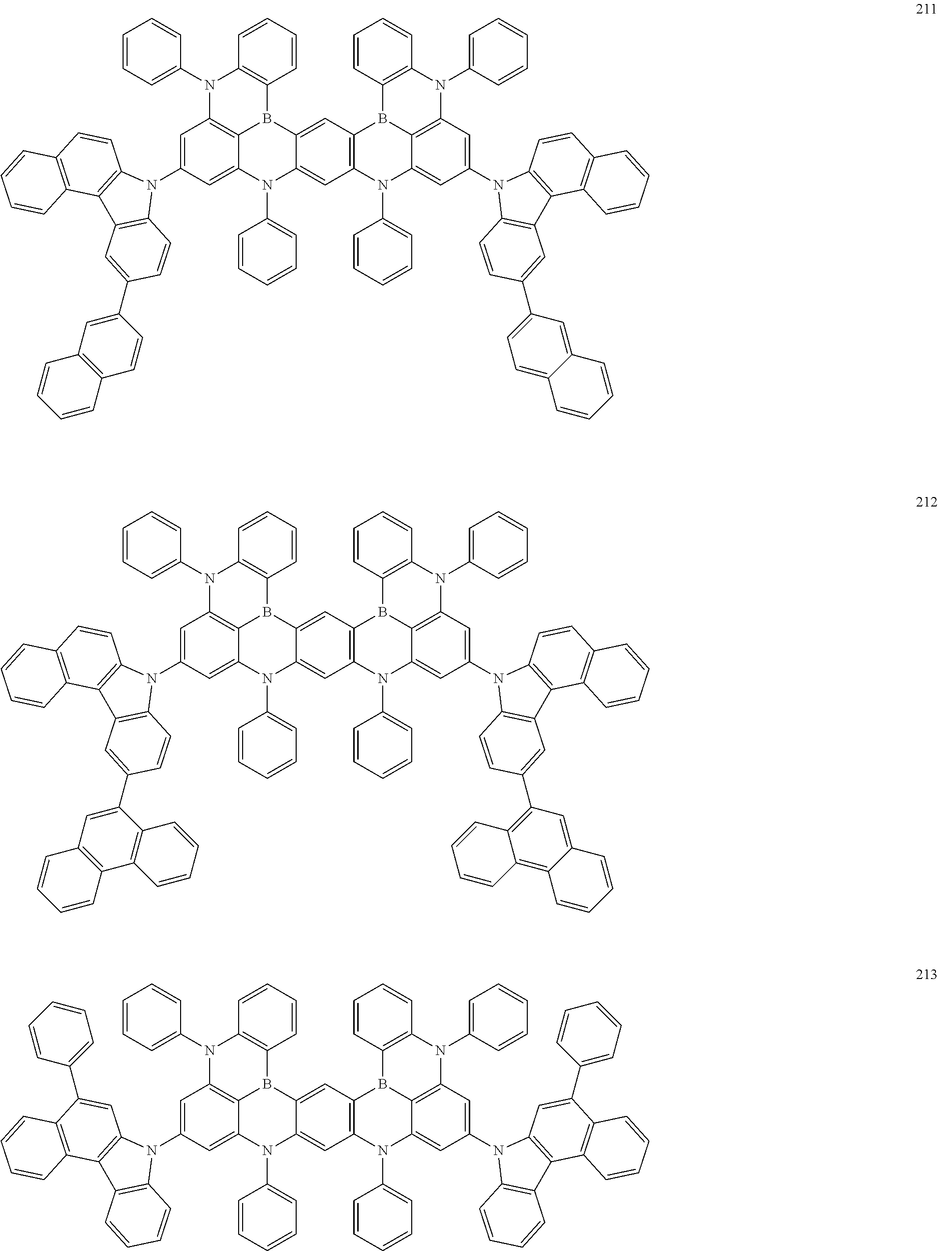 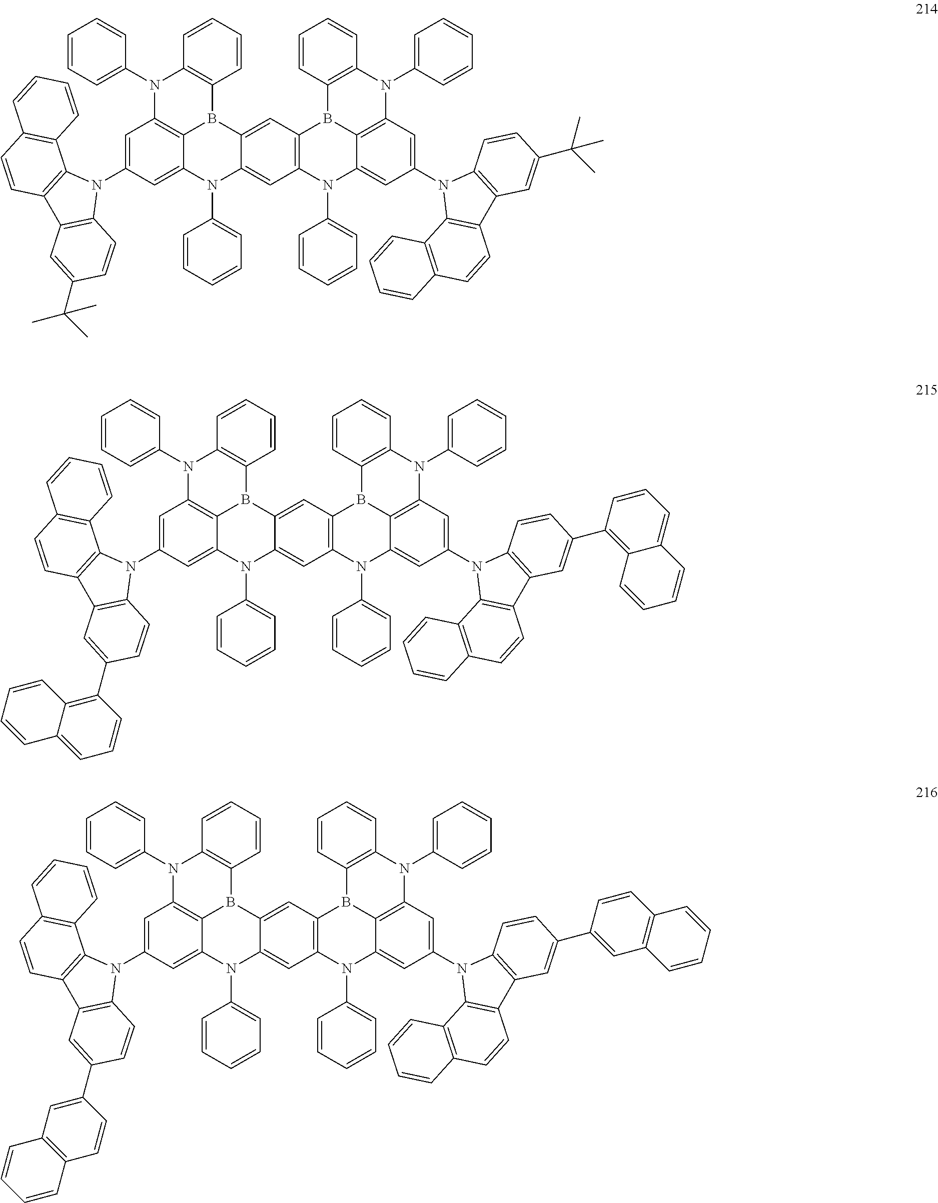 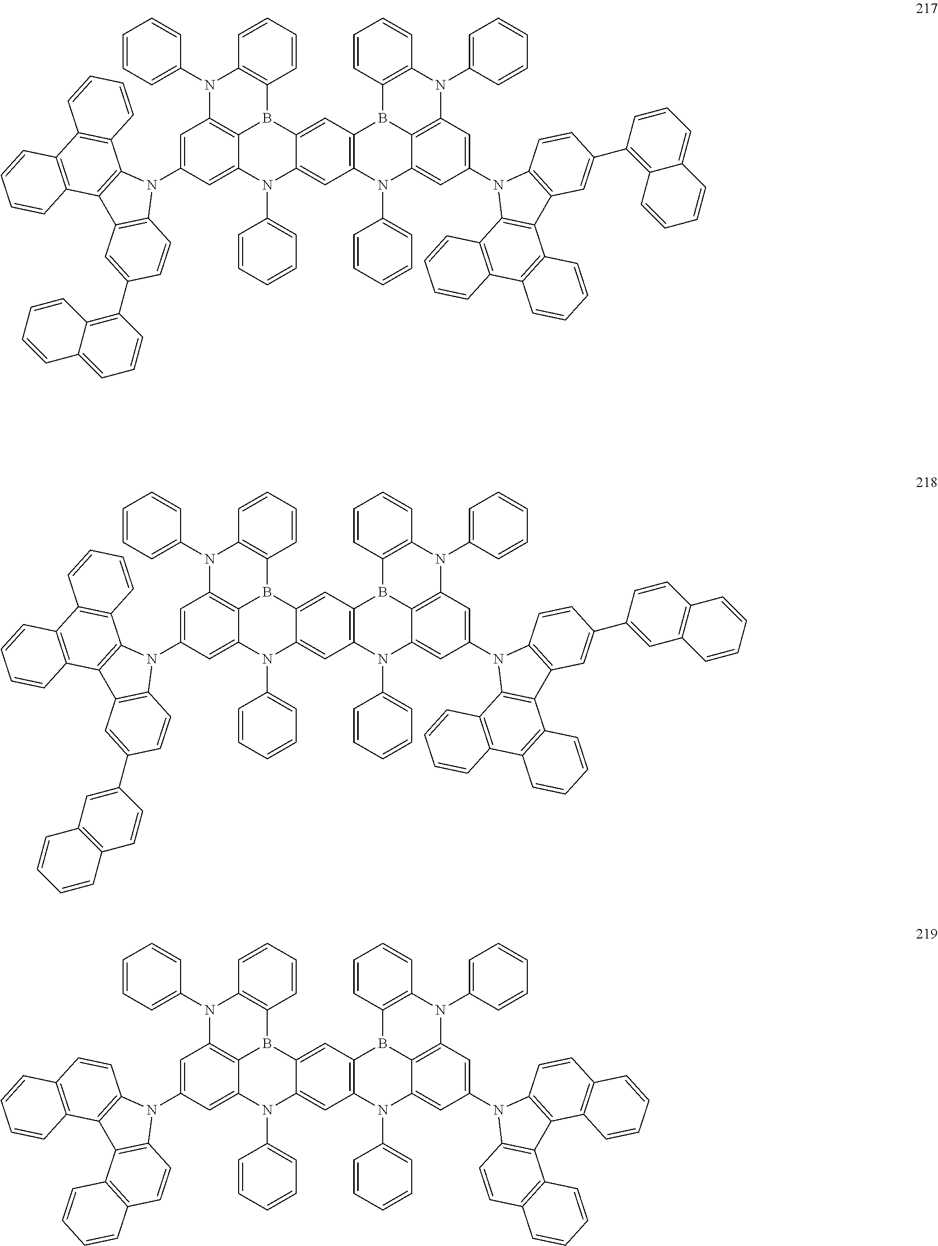 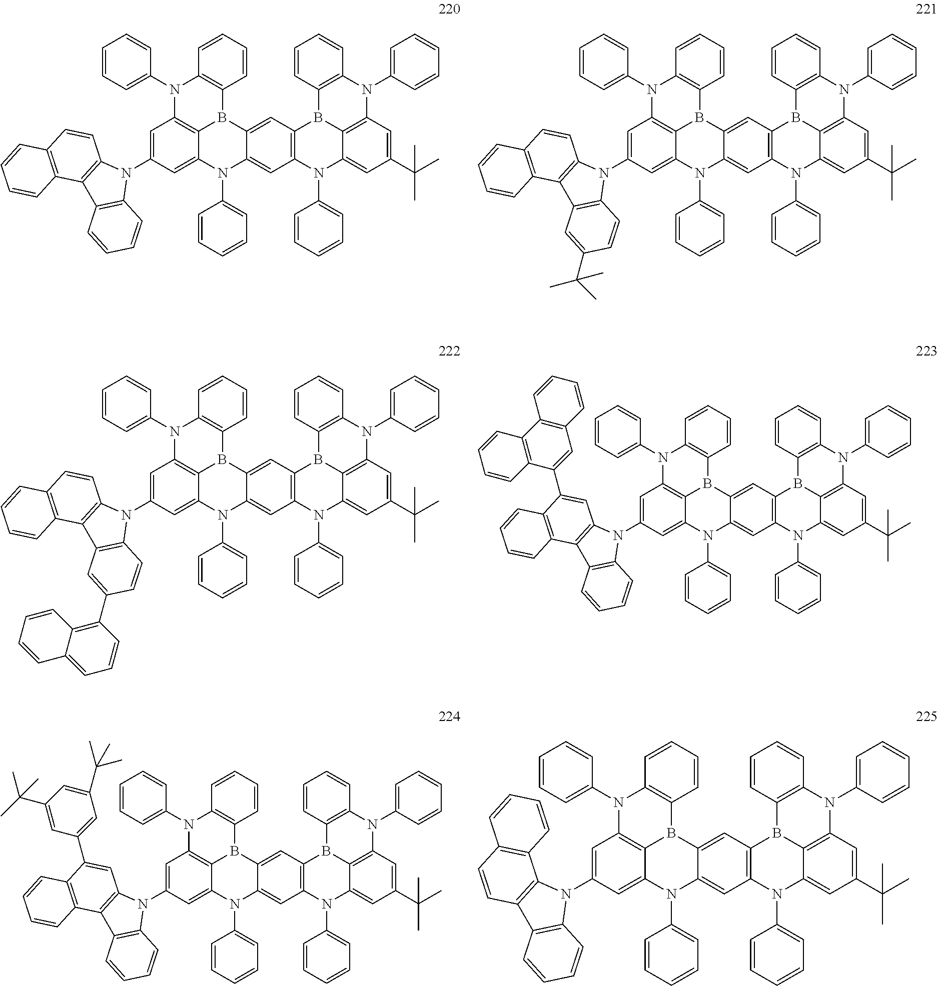 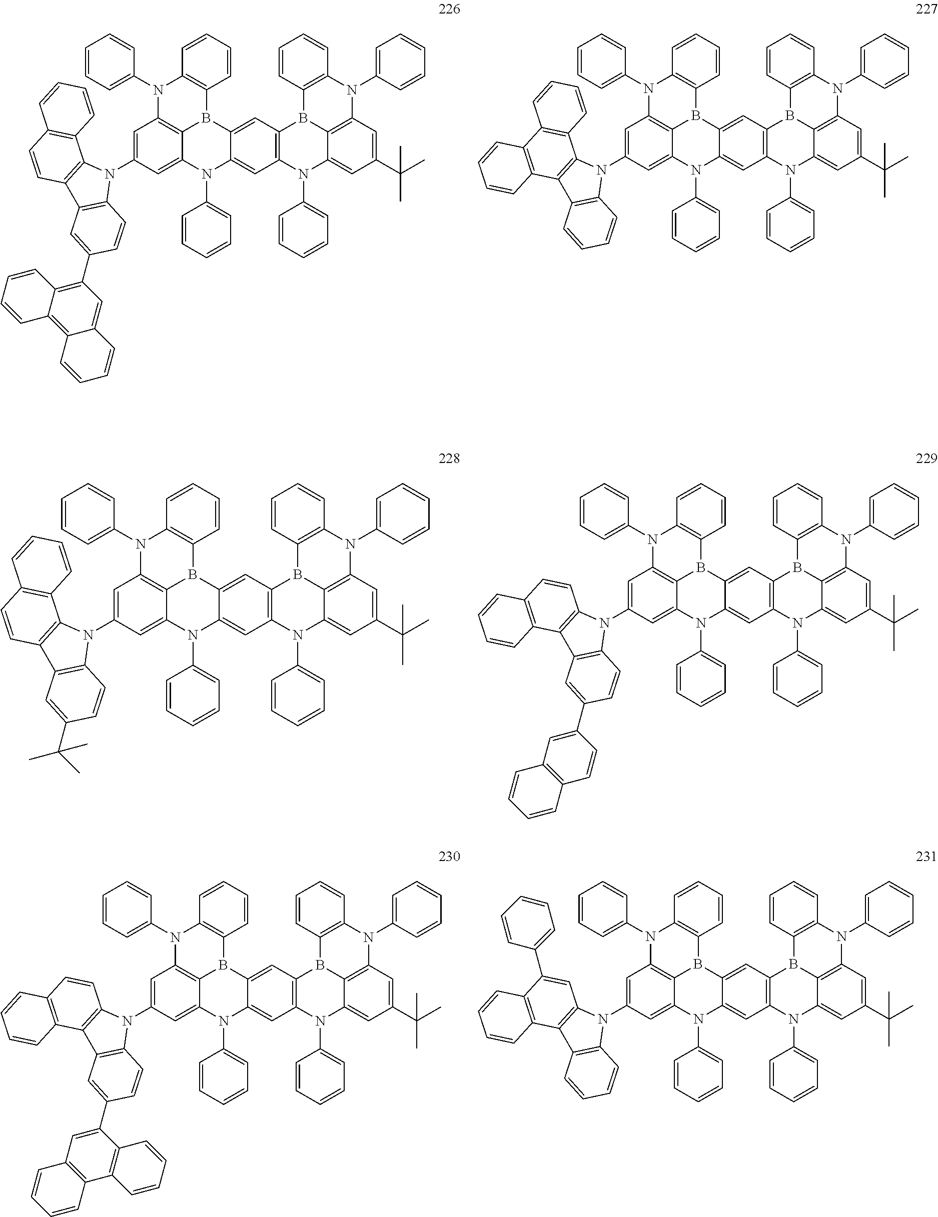 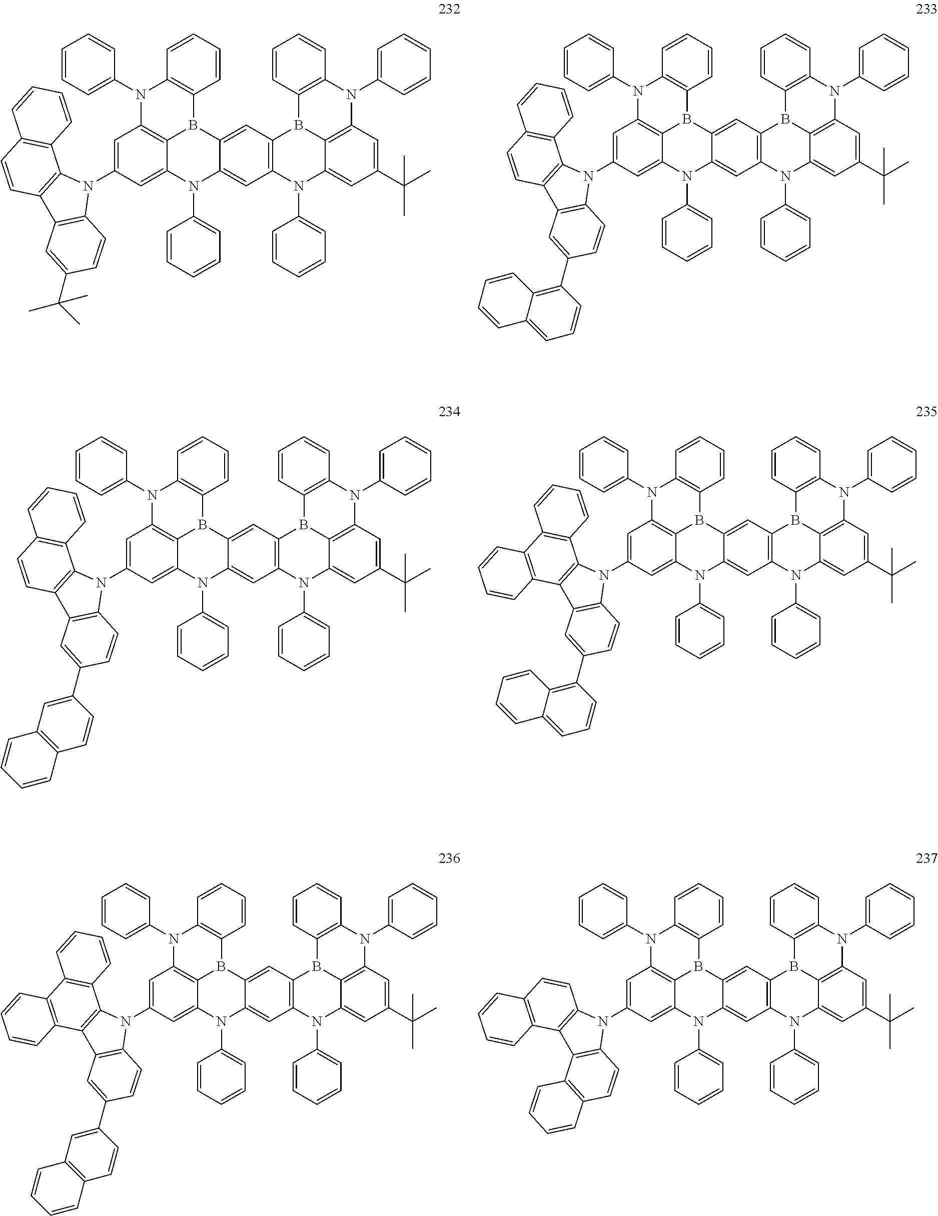 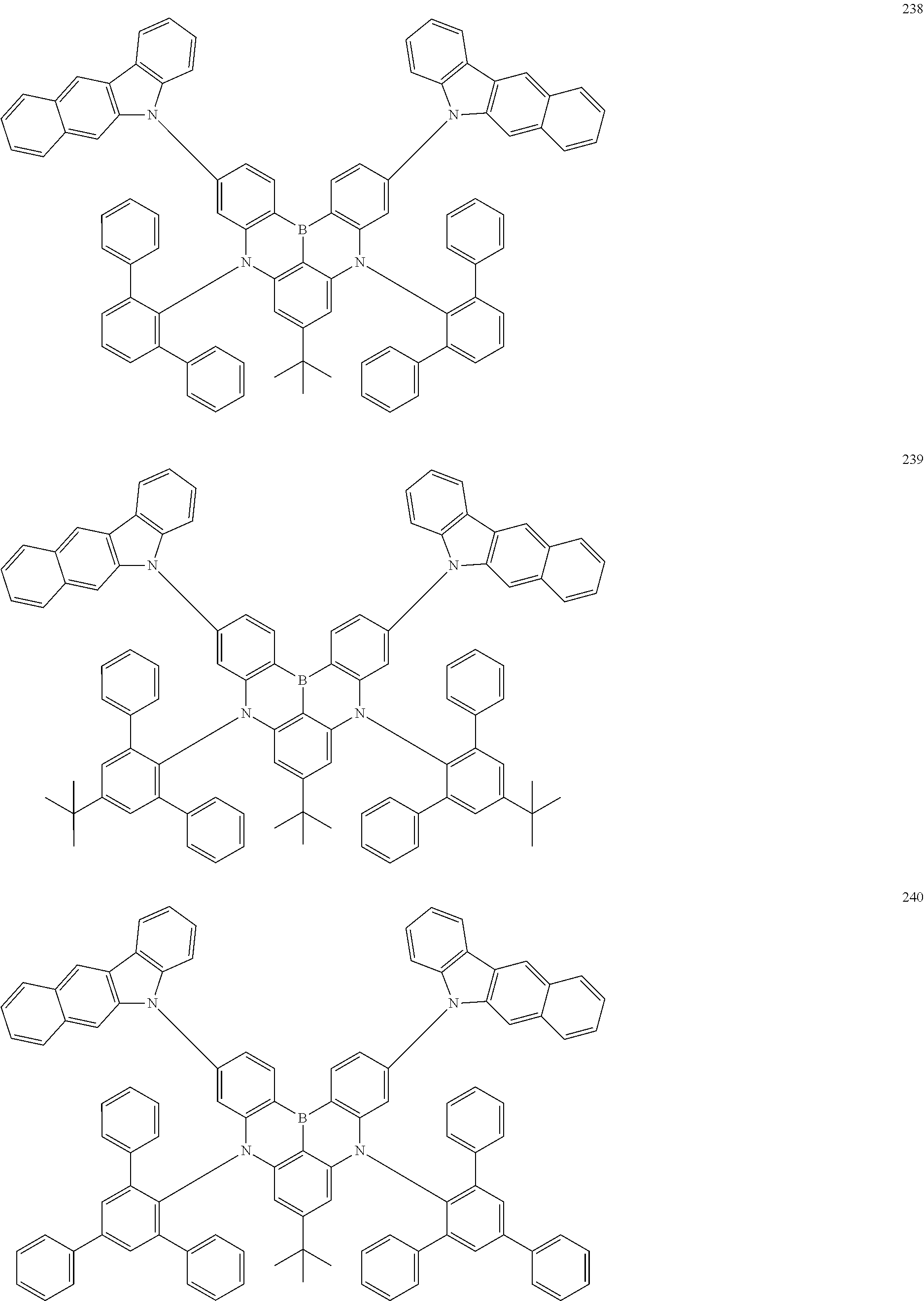 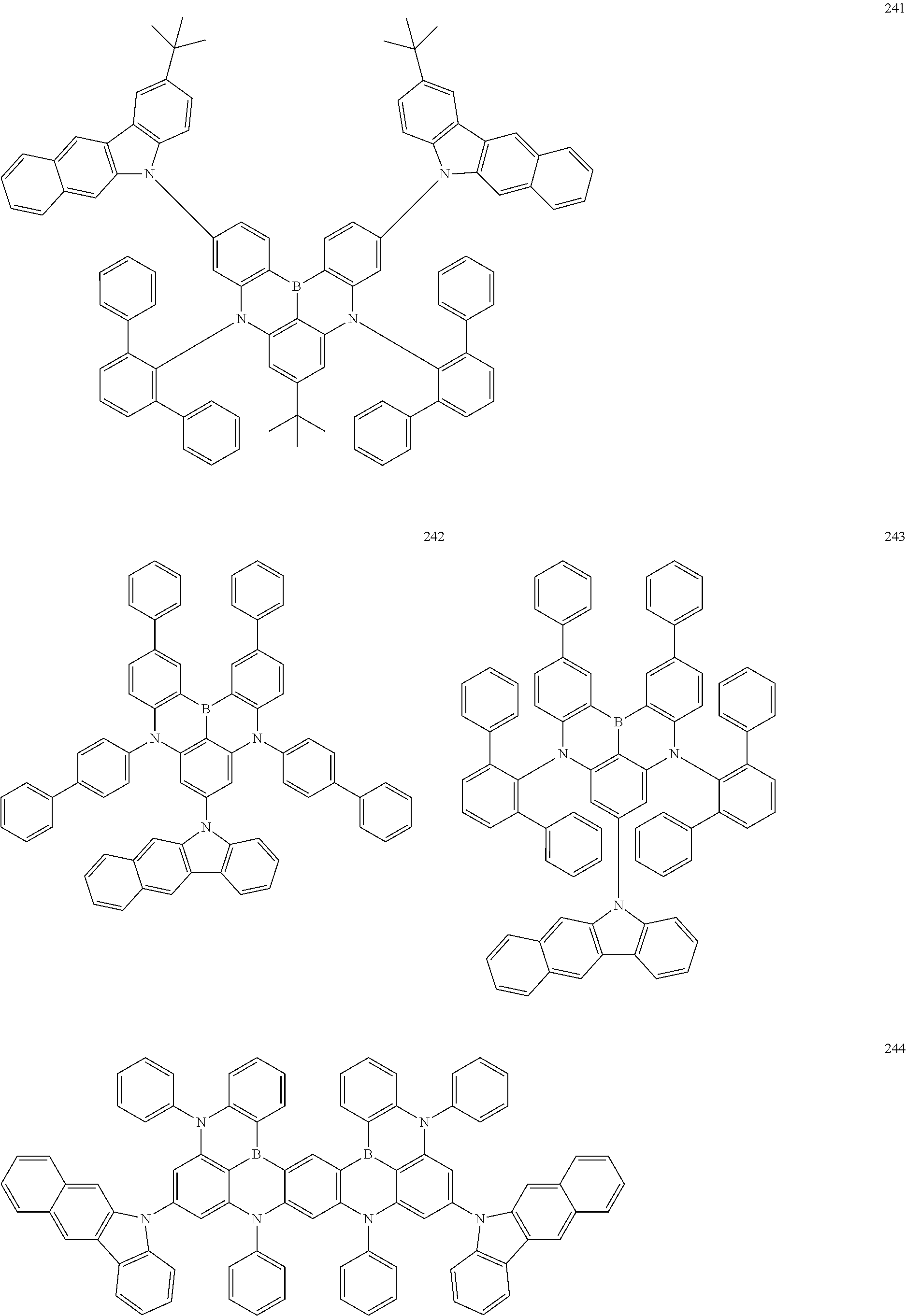 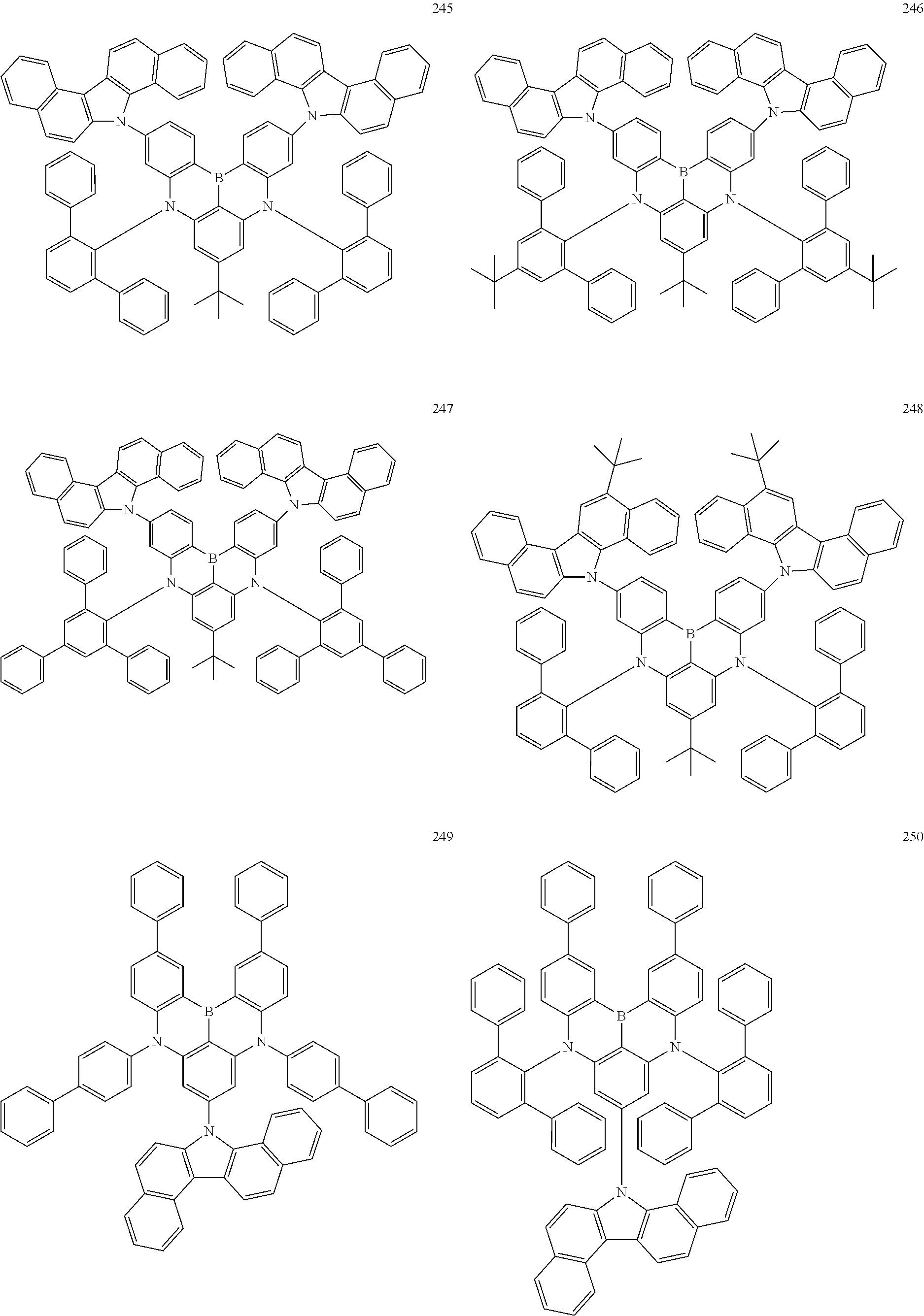 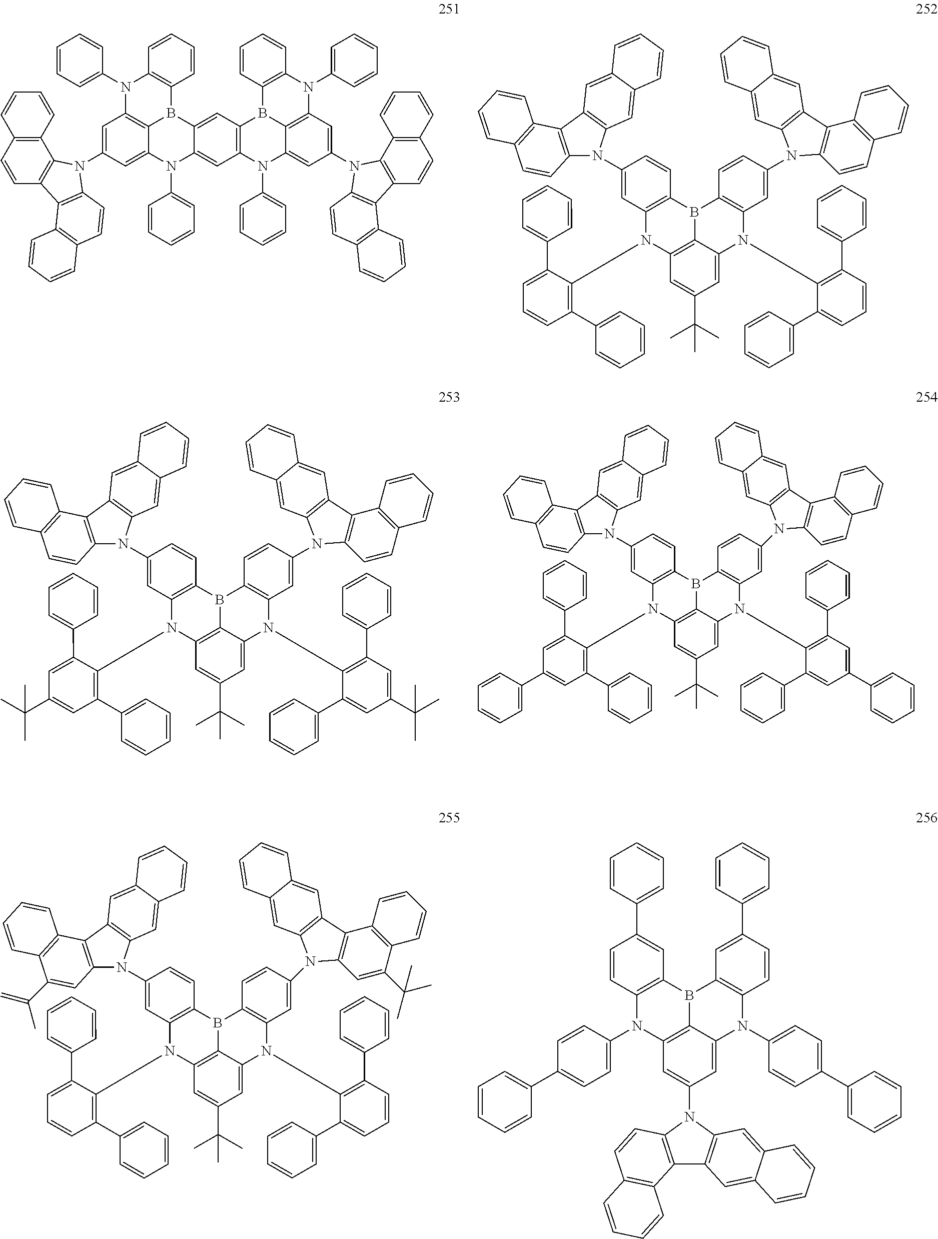 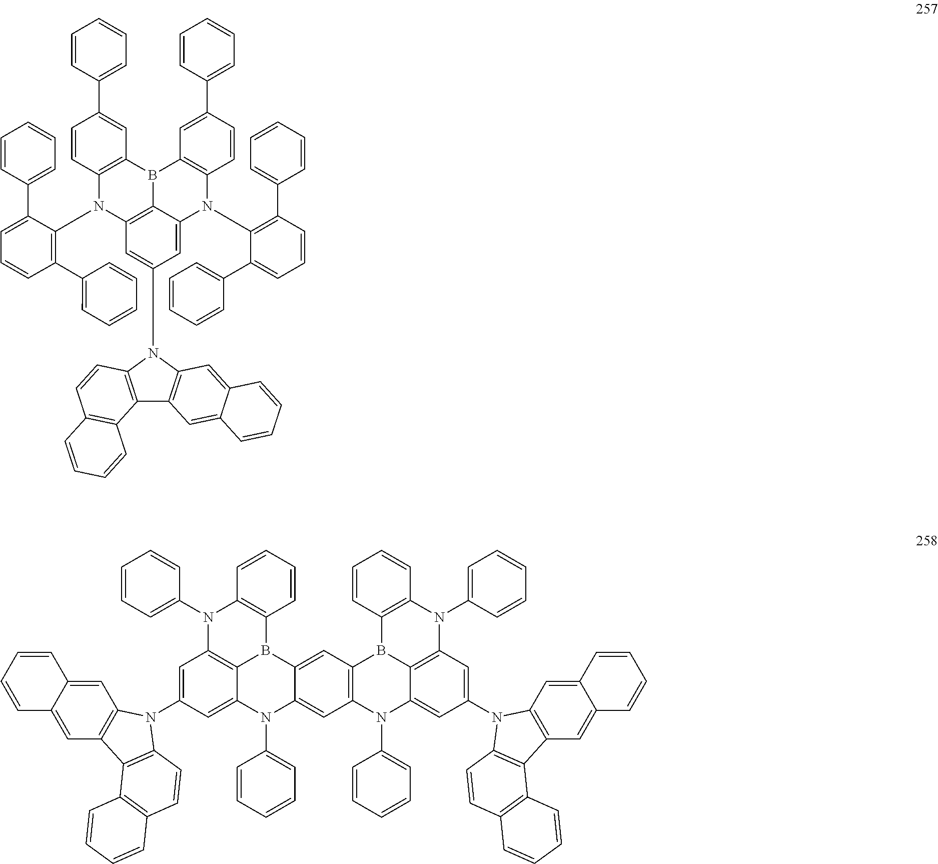 [SMILES: c1ccc(-c2ccc3c(c2)B2c4cc(-c5ccccc5)ccc4N(c4c(-c5ccccc5)cccc4-c4ccccc4)c4cc(-n5c6cc7ccccc7cc6c6c7ccccc7ccc65)cc(c42)N3c2c(-c3ccccc3)cccc2-c2ccccc2)cc1 ; c1ccc(N2c3ccccc3B3c4cc5c(cc4N(c4ccccc4)c4cc(-n6c7cc8ccccc8cc7c7c8ccccc8ccc76)cc2c43)N(c2ccccc2)c2cc(-n3c4cc6ccccc6cc4c4c6ccccc6ccc43)cc3c2B5c2ccccc2N3c2ccccc2)cc1] 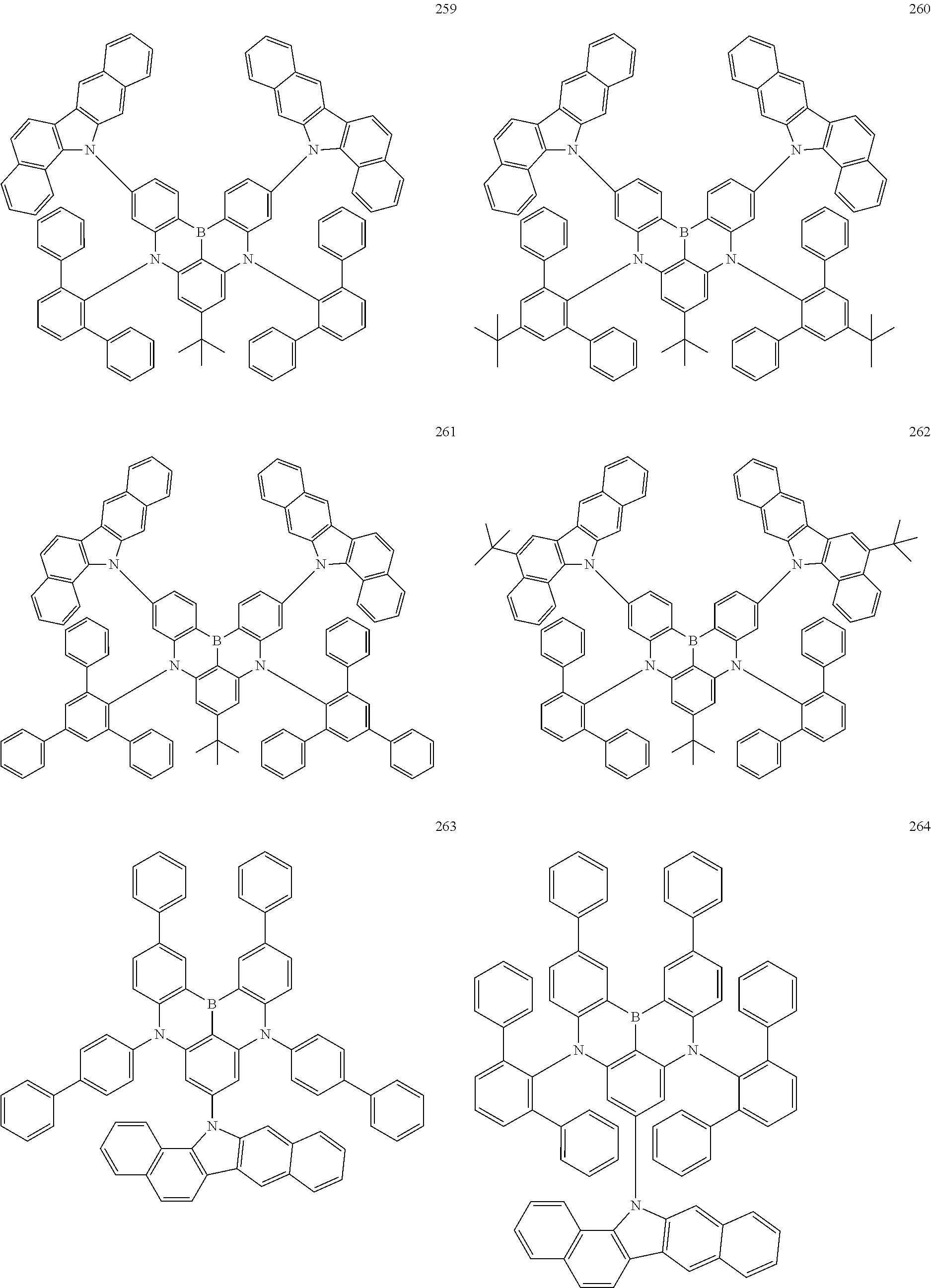 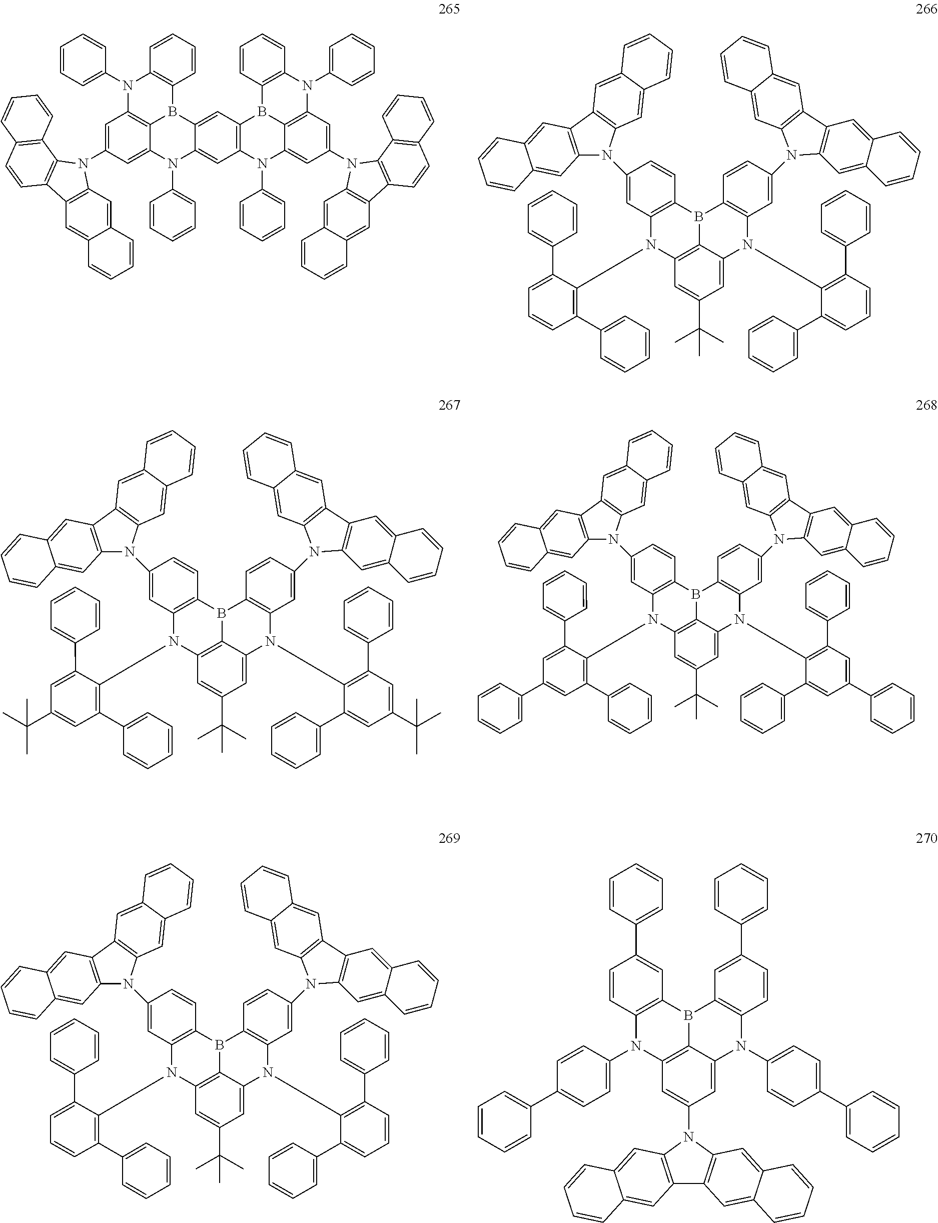 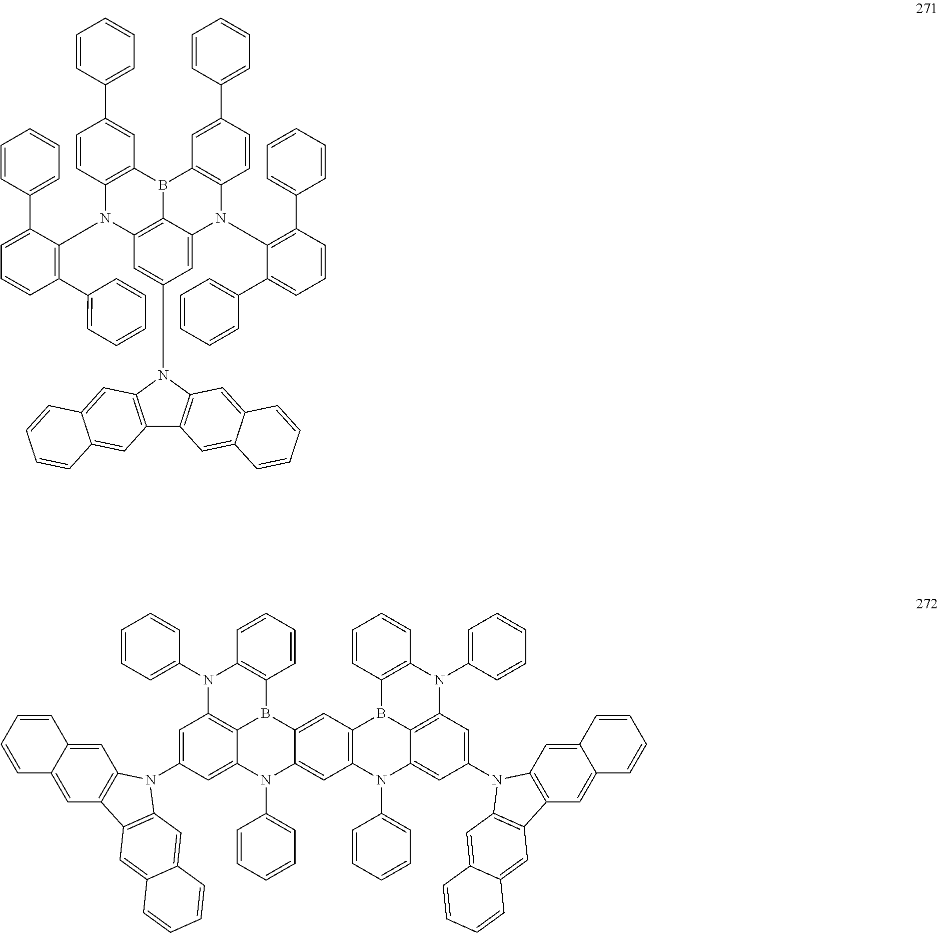 [SMILES: c1ccc(-c2ccc3c(c2)B2c4cc(-c5ccccc5)ccc4N(c4c(-c5ccccc5)cccc4-c4ccccc4)c4cc(-n5c6cc7ccccc7cc6c6cc7ccccc7cc65)cc(c42)N3c2c(-c3ccccc3)cccc2-c2ccccc2)cc1 ; c1ccc(N2c3ccccc3B3c4cc5c(cc4N(c4ccccc4)c4cc(-n6c7cc8ccccc8cc7c7cc8ccccc8cc76)cc2c43)N(c2ccccc2)c2cc(-n3c4cc6ccccc6cc4c4cc6ccccc6cc43)cc3c2B5c2ccccc2N3c2ccccc2)cc1] 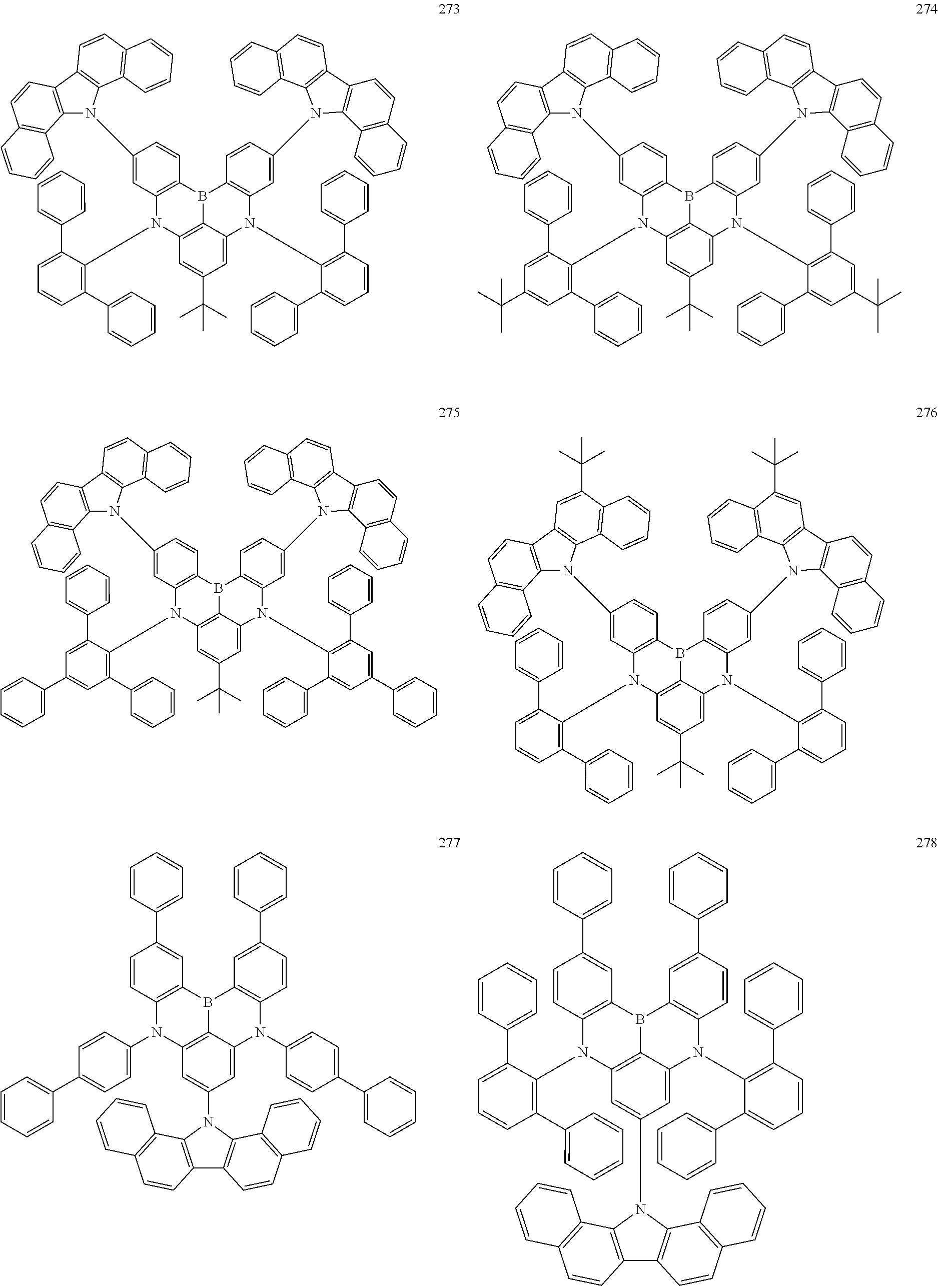 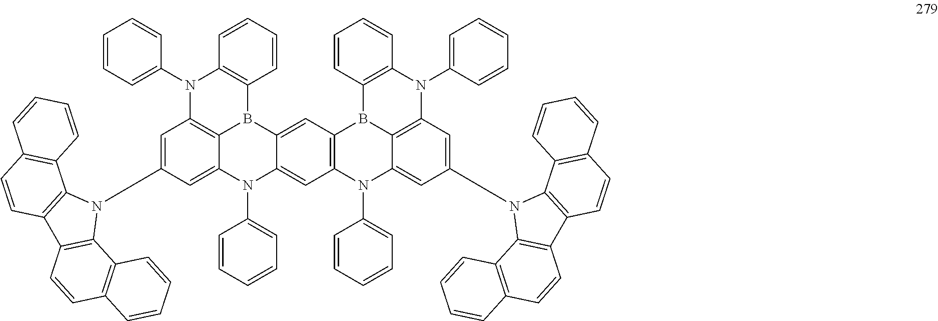 [SMILES: c1ccc(N2c3ccccc3B3c4cc5c(cc4N(c4ccccc4)c4cc(-n6c7c8ccccc8ccc7c7ccc8ccccc8c76)cc2c43)N(c2ccccc2)c2cc(-n3c4c6ccccc6ccc4c4ccc6ccccc6c43)cc3c2B5c2ccccc2N3c2ccccc2)cc1] 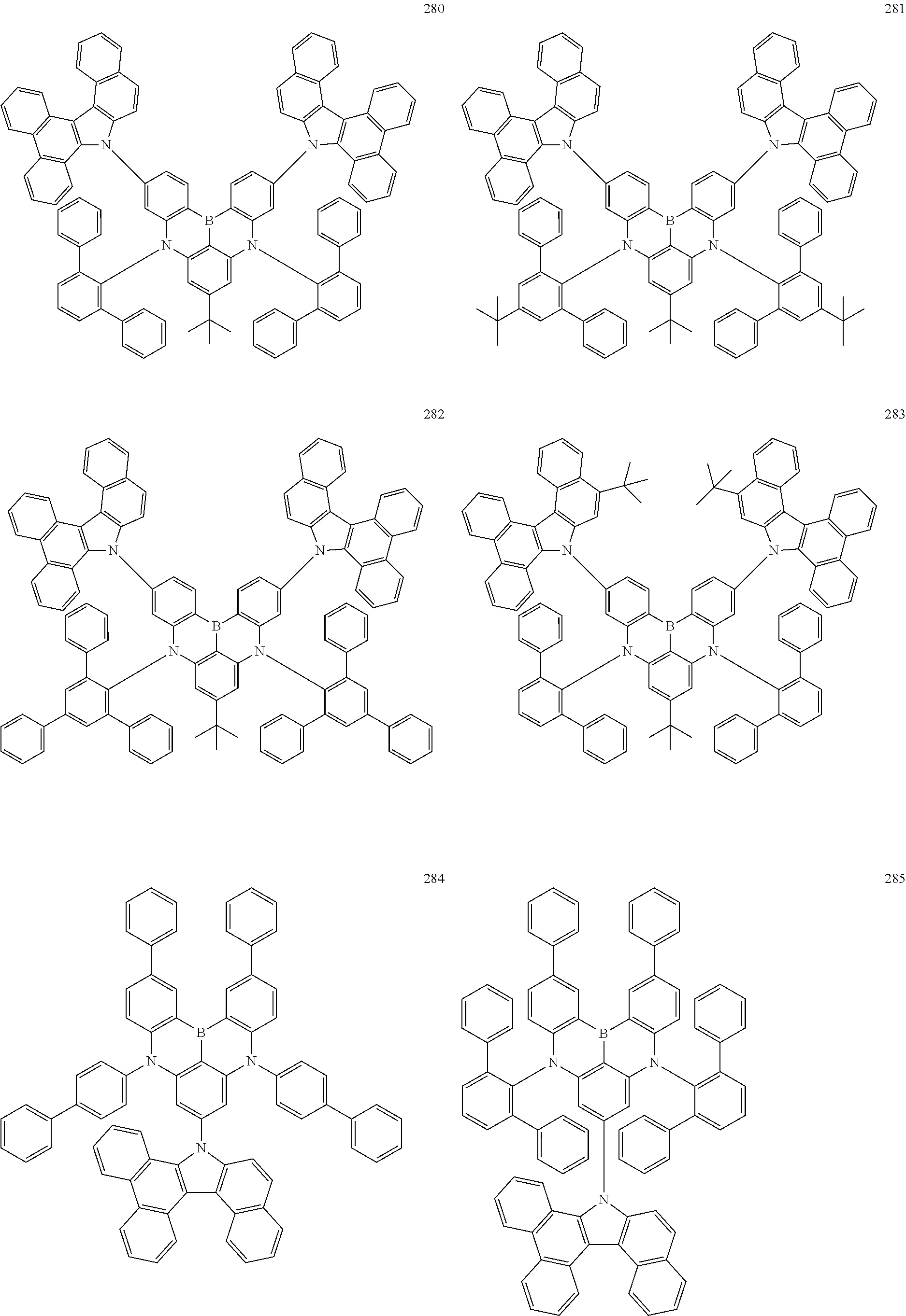 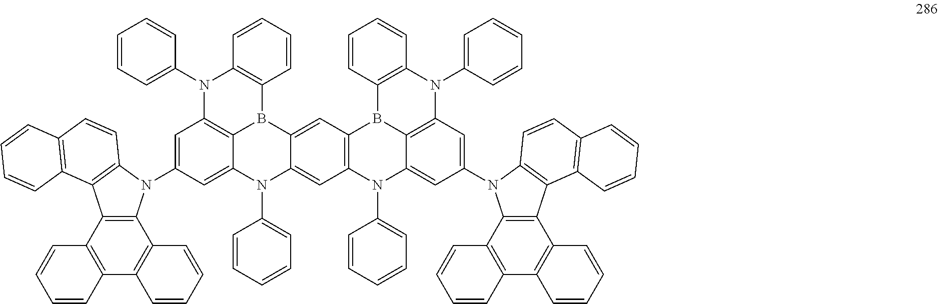 [SMILES: c1ccc(N2c3ccccc3B3c4cc5c(cc4N(c4ccccc4)c4cc(-n6c7ccc8ccccc8c7c7c8ccccc8c8ccccc8c76)cc2c43)N(c2ccccc2)c2cc(-n3c4ccc6ccccc6c4c4c6ccccc6c6ccccc6c43)cc3c2B5c2ccccc2N3c2ccccc2)cc1] 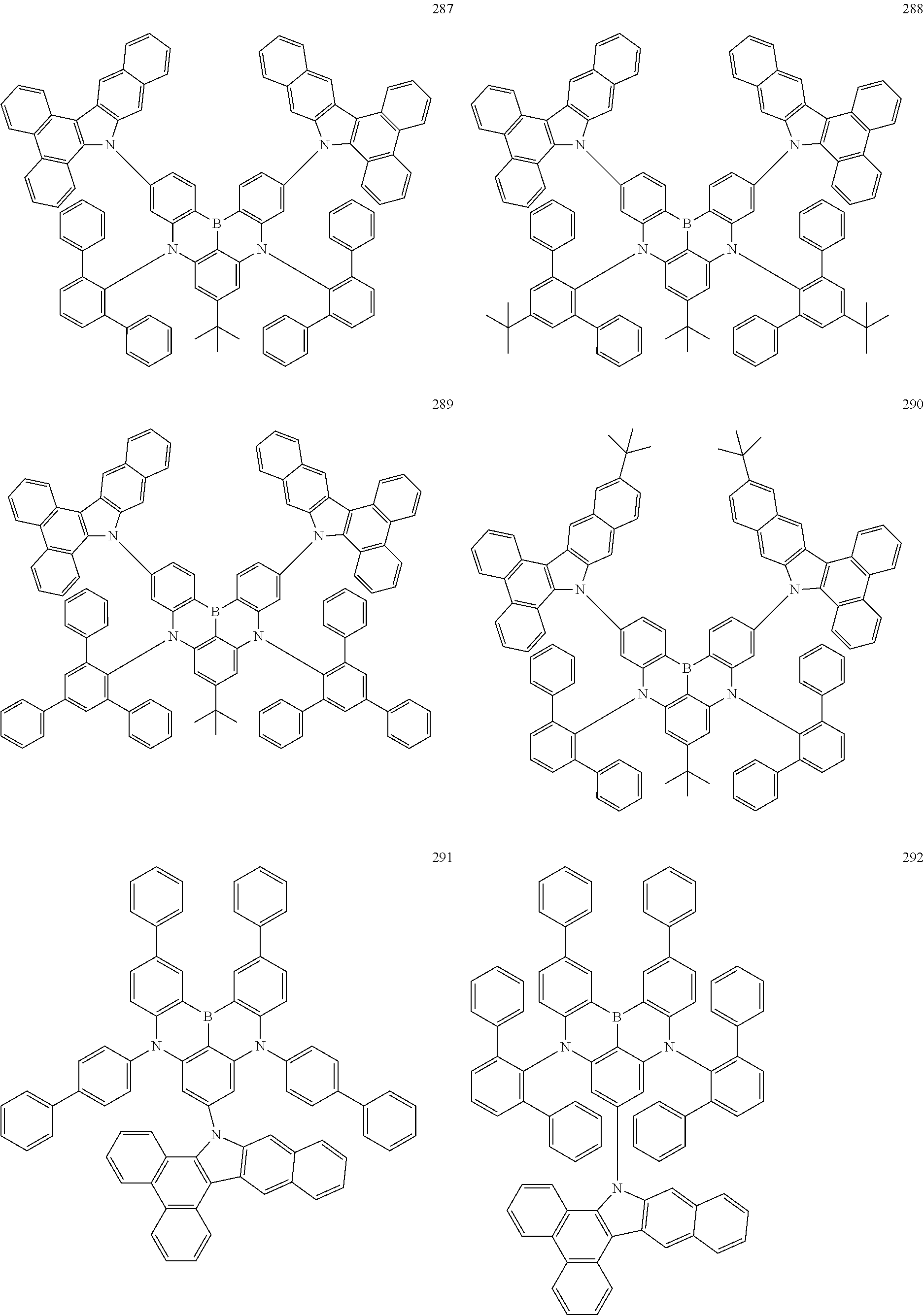 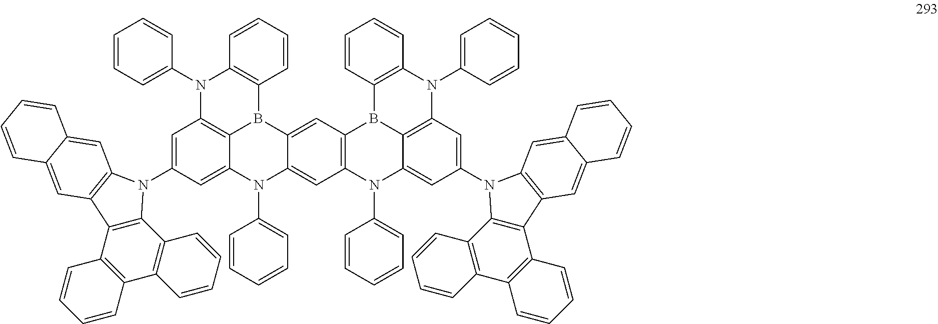 [SMILES: c1ccc(N2c3ccccc3B3c4cc5c(cc4N(c4ccccc4)c4cc(-n6c7cc8ccccc8cc7c7c8ccccc8c8ccccc8c76)cc2c43)N(c2ccccc2)c2cc(-n3c4cc6ccccc6cc4c4c6ccccc6c6ccccc6c43)cc3c2B5c2ccccc2N3c2ccccc2)cc1] 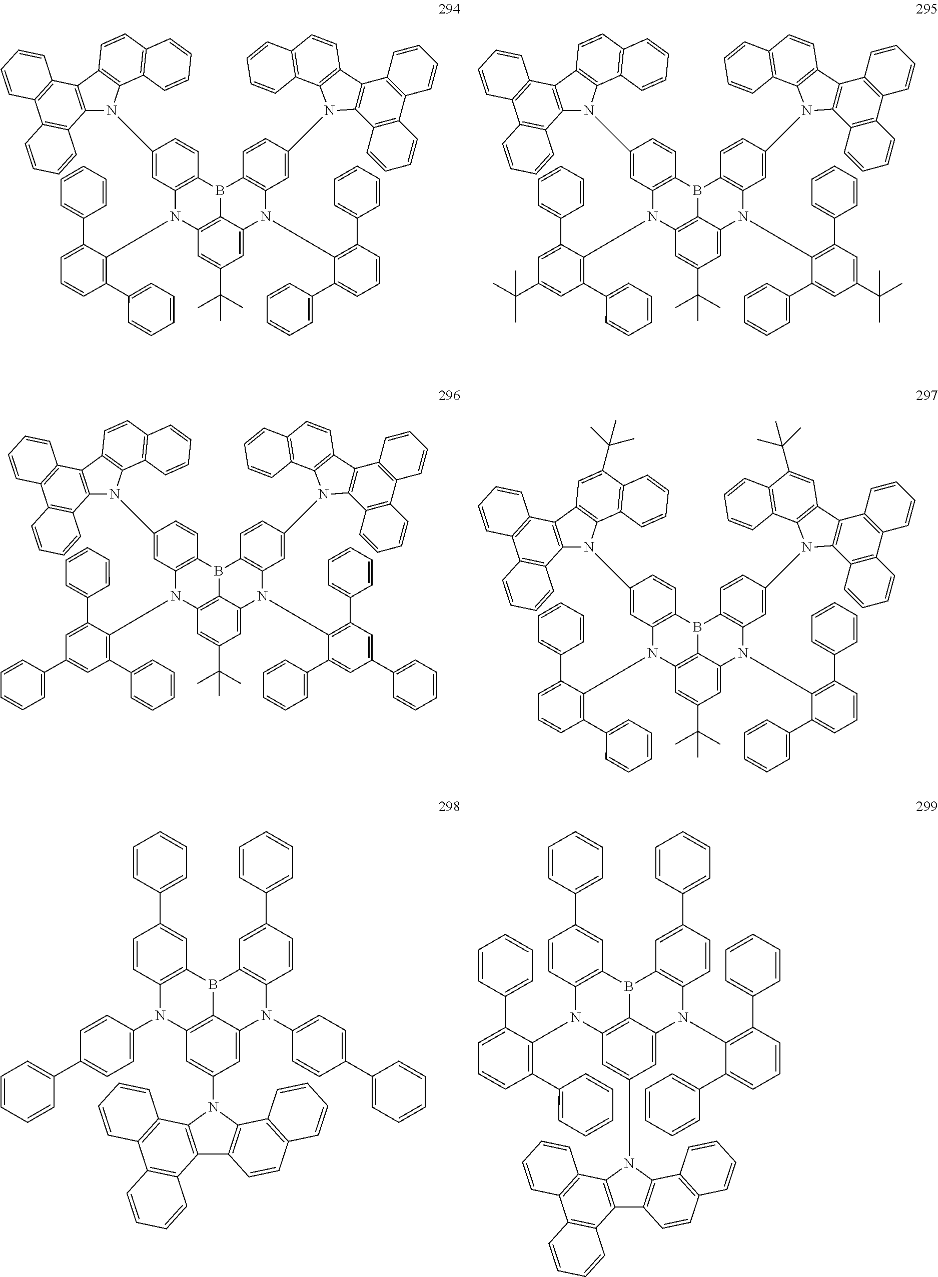 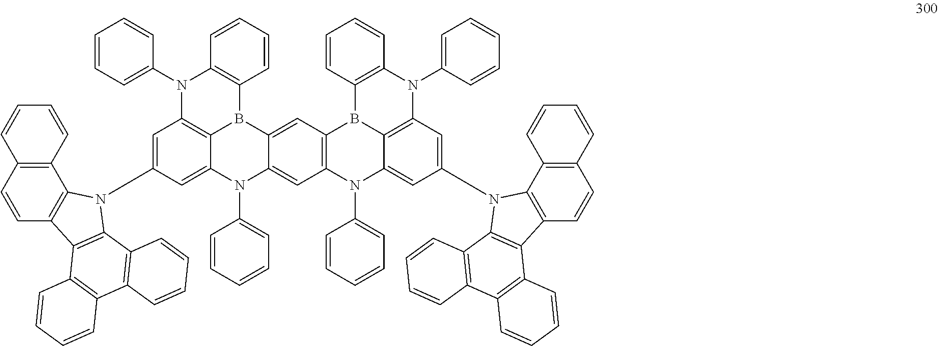 [SMILES: c1ccc(N2c3ccccc3B3c4cc5c(cc4N(c4ccccc4)c4cc(-n6c7c8ccccc8ccc7c7c8ccccc8c8ccccc8c76)cc2c43)N(c2ccccc2)c2cc(-n3c4c6ccccc6ccc4c4c6ccccc6c6ccccc6c43)cc3c2B5c2ccccc2N3c2ccccc2)cc1] 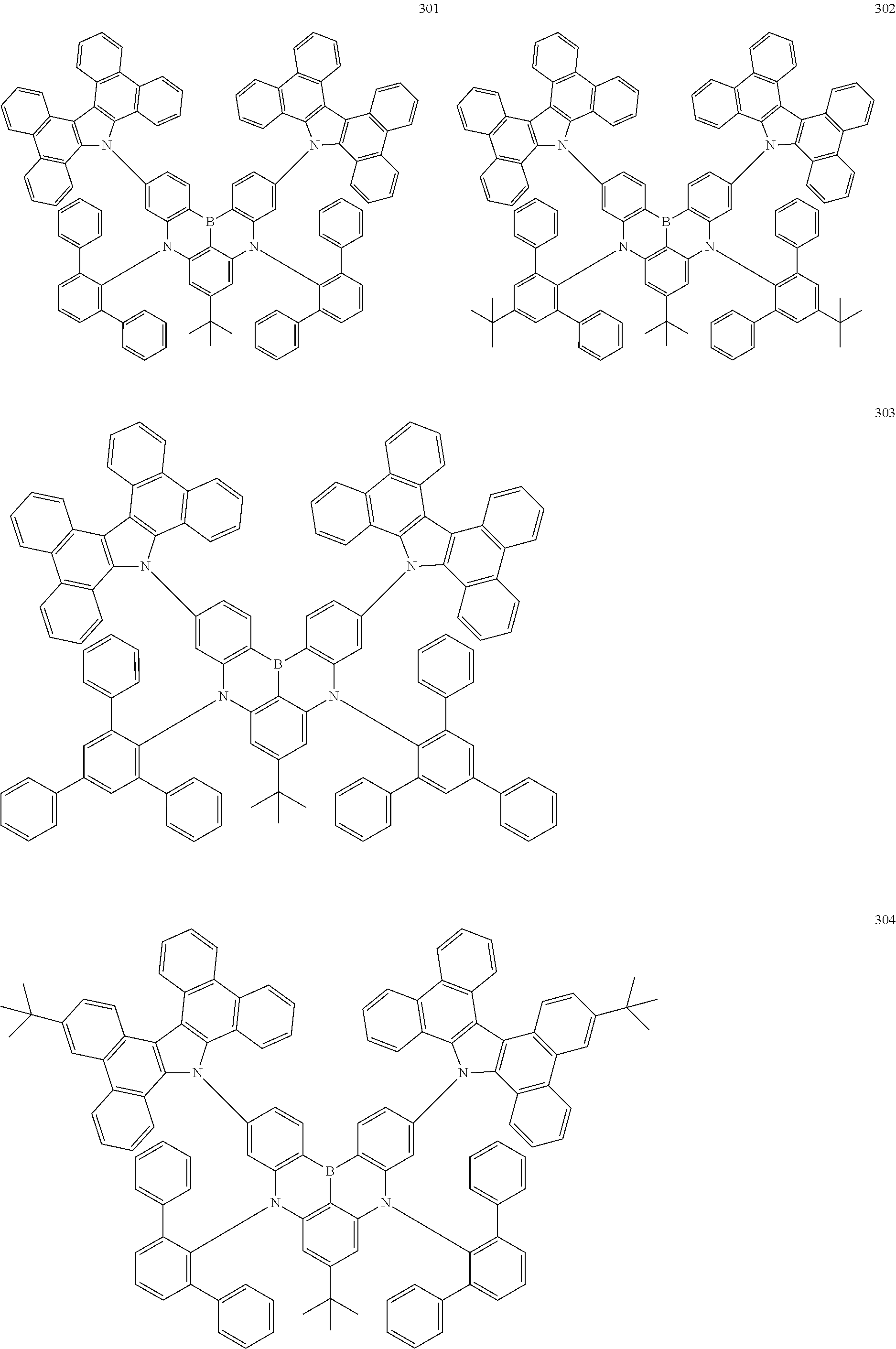 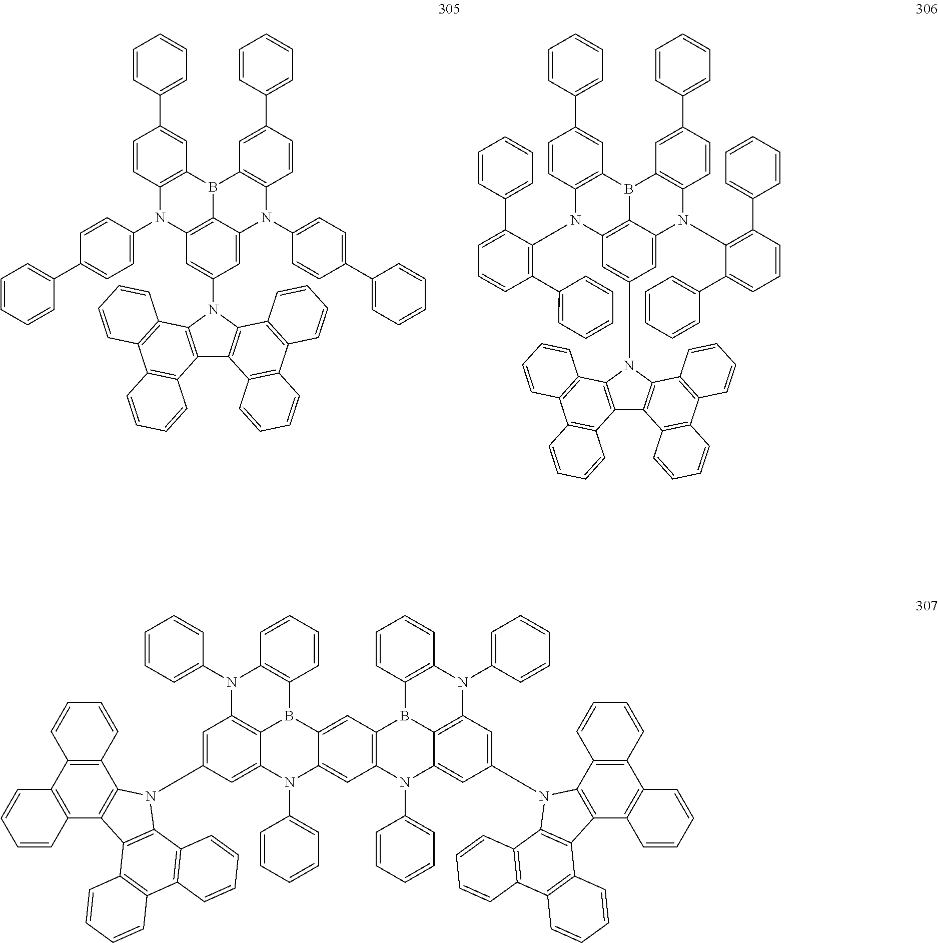 [SMILES: c1ccc(-c2ccc(N3c4ccc(-c5ccccc5)cc4B4c5cc(-c6ccccc6)ccc5N(c5ccc(-c6ccccc6)cc5)c5cc(-n6c7c8ccccc8c8ccccc8c7c7c8ccccc8c8ccccc8c76)cc3c54)cc2)cc1 ; c1ccc(-c2ccc3c(c2)B2c4cc(-c5ccccc5)ccc4N(c4c(-c5ccccc5)cccc4-c4ccccc4)c4cc(-n5c6c7ccccc7c7ccccc7c6c6c7ccccc7c7ccccc7c65)cc(c42)N3c2c(-c3ccccc3)cccc2-c2ccccc2)cc1 ; c1ccc(N2c3ccccc3B3c4cc5c(cc4N(c4ccccc4)c4cc(-n6c7c8ccccc8c8ccccc8c7c7c8ccccc8c8ccccc8c76)cc2c43)N(c2ccccc2)c2cc(-n3c4c6ccccc6c6ccccc6c4c4c6ccccc6c6ccccc6c43)cc3c2B5c2ccccc2N3c2ccccc2)cc1]
wherein in Compound Group 1,
D represents a deuterium atom.
